(19) United States
(12) Patent Application Publication
(10) Pub. No.: US 2023/0200208 A1
(43) Pub. Date: Jun. 22, 2023

(54) ORGANOMETALLIC COMPOUND AND ORGANIC LIGHT-EMITTING DIODE INCLUDING THE SAME

(71) Applicants: LG DISPLAY CO., LTD., Seoul (KR); LT MATERIALS CO., LTD., Yongin-si (KR)

(72) Inventors: Sungjin PARK, Incheon (KR); Inbum SONG, Seoul (KR); Dohan KIM, Goyang-si (KR); Jaemin MOON, Seoul (KR); Ji Young KIM, Osan-si (KR); Seokhyeon YU, Osan-si (KR); Hyun Ju LA, Osan-si (KR); Kundo KIM, Osan-si (KR)

(73) Assignees: LG DISPLAY CO., LTD., Seoul (KR); LT MATERIALS CO., LTD., Yongin-si (KR)

(21) Appl. No.: 18/086,212

(22) Filed: Dec. 21, 2022

(30) Foreign Application Priority Data
Dec. 22, 2021 (KR) 10-2021-0184523

(51) Int. Cl. H10K 85/30; C07F 15/00; C09K 11/06

(52) U.S. Cl. CPC H01L 51/0085; C07F 15/0033; C09K 11/06; H01L 51/5016

(57) ABSTRACT

Disclosed is a novel organometallic compound represented by a following Chemical Formula 1. The organometallic compound acts as a dopant of a light-emitting layer of an organic light-emitting diode. Thus, an operation voltage of the diode is lowered, and luminous efficiency and a lifespan thereof are improved:

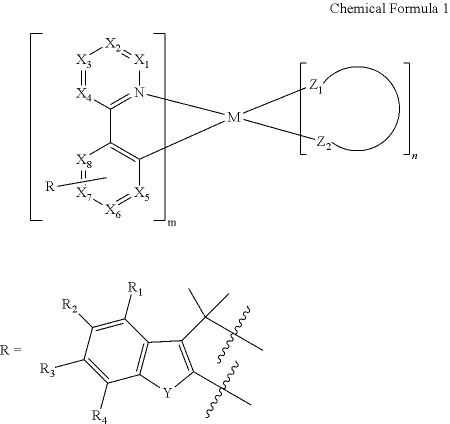

### CROSS-REFERENCE TO RELATED APPLICATION

This application claims priority, under 35 U.S.C. 119, to Korean Patent Application No. 10-2021-0184523 filed on Dec. 22, 2021 in the Republic of Korea, the entire contents of which being herein incorporated by reference into the present application.

### BACKGROUND

### Technical Field

The present disclosure relates to an organometallic compound, and more particularly, to an organometallic compound having phosphorescent properties and an organic light-emitting diode including the same.

### Description of Related Art

As a display device is applied to various fields, interest with the display device is increasing. One of the display devices is an organic light-emitting display device including an organic light-emitting diode (OLED) which is rapidly developing.

In the organic light-emitting diode, when electric charges are injected into a light-emitting layer formed between a positive electrode and a negative electrode, an electron and a hole are recombined with each other in the light-emitting layer to form an exciton and thus energy of the exciton is converted to light. Thus, the organic light-emitting diode emits the light. Compared to conventional display devices, the organic light-emitting diode can operate at a low voltage, consume relatively little power, render excellent colors, and can be used in a variety of ways because a flexible substrate can be applied thereto. Further, a size of the organic light-emitting diode can be freely adjustable.

### SUMMARY OF THE DISCLOSURE

The organic light-emitting diode (OLED) has superior viewing angle and contrast ratio compared to a liquid crystal display (LCD), and is lightweight and is ultra-thin because the OLED does not require a backlight. The organic light-emitting diode includes a plurality of organic layers between a negative electrode (electron injection electrode; cathode) and a positive electrode (hole injection electrode; anode). The plurality of organic layers can include a hole injection layer, a hole transport layer, a hole transport auxiliary layer, an electron blocking layer, and a light-emitting layer, an electron transport layer, etc.

In this organic light-emitting diode structure, when a voltage is applied across the two electrodes, electrons and holes are injected from the negative and positive electrodes, respectively, into the light-emitting layer and thus excitons are generated in the light-emitting layer and then fall to a ground state to emit light.

Organic materials used in the organic light-emitting diode can be largely classified into light-emitting materials and charge-transporting materials. The light-emitting material is an important factor determining luminous efficiency of the organic light-emitting diode. The luminescent material must have high quantum efficiency, excellent electron and hole mobility, and must exist uniformly and stably in the light-emitting layer. The light-emitting materials can be classified into light-emitting materials emitting light of blue, red, and green colors based on colors of the light. A color-generating material can include a host and dopants to increase the color purity and luminous efficiency through energy transfer.

In recent years, there is a trend to use phosphorescent materials rather than fluorescent materials for the light-emitting layer. When the fluorescent material is used, singlets as about 25% of excitons generated in the light-emitting layer are used to emit light, while most of triplets as 75% of the excitons generated in the light-emitting layer are dissipated as heat. However, when the phosphorescent material is used, singlets and triplets are used to emit light.

Conventionally, an organometallic compound is used as the phosphorescent material used in the organic light-emitting diode. Research and development of the phosphorescent material to solve low efficiency and lifetime problems are continuously required.

Accordingly, a purpose of the present invention is to provide an organometallic compound capable of lowering operation voltage, and improving efficiency, and lifespan, and an organic light-emitting diode including an organic light-emitting layer containing the same.

Purposes of the present disclosure are not limited to the above-mentioned purpose. Other purposes and advantages of the present disclosure that are not mentioned can be understood based on following descriptions, and can be more clearly understood based on embodiments of the present disclosure. Further, it will be easily understood that the purposes and advantages of the present disclosure can be realized using means shown in the claims and combinations thereof.

In order to achieve the above purpose, the present disclosure provides an organometallic compound having a novel structure represented by a following Chemical Formula 1, and an organic light-emitting diode in which a light-emitting layer contains the same as dopants thereof:

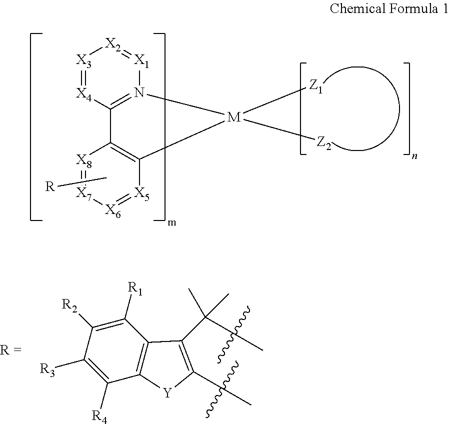

wherein in the Chemical Formula 1, M can represent one selected from a group consisting of Mo, W, Re, Ru, Os, Rh, Ir, Pd, Pt and Au;

R can represent a ring structure fused with one pair selected from a pair of X₅ and X₆, a pair of X₆ and X₇, and a pair of X₇ and X₈;

each of X₁ to X₄ can independently represent one selected from CR₅ and N;

optionally, two R₅ on the adjacent two of X₁ to X₄ can be connected to each other to form a ring structure including one selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group;

Y can represent one selected from a group consisting of BR₆, CR₆R₇, C═O, CNR₆, SiR₆R₇, NR₆, PR₆, AsR₆, SbR₆, P(O)R₆, P(S)R₆, P(Se)R₆, As(O)R₆, As(S)R₆, As(Se)R₆, Sb(O)R₆, Sb(S)R₆, Sb(Se)R₆, O, S, Se, Te, SO, SO₂, SeO, SeO₂, TeO and TeO₂;

each of X₅ to X₈ can independently represent CR₈;

each of R₅ to R₈ can independently represent one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;

(Z₁-Z₂) can represent a bidentate ligand; and

m can be 1, 2 or 3, n can be 0, 1 or 2, and a sum of m and n can be an oxidation number of the metal M.

The organometallic compound according to the present disclosure can be used as the dopant of the light-emitting layer of the organic light-emitting diode, such that the operation voltage of the organic light-emitting diode can be lowered, and the efficiency and lifespan characteristics of the organic light-emitting diode can be improved.

Effects of the present disclosure are not limited to the above-mentioned effects, and other effects as not mentioned will be clearly understood by those skilled in the art from following descriptions.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a cross-sectional view schematically showing an organic light-emitting diode in which a light-emitting layer contains an organometallic compound according to an illustrative embodiment of the present disclosure.

FIG. 2 is a cross-sectional view schematically illustrating an organic light-emitting diode having a tandem structure having two light-emitting stacks and containing an organometallic compound represented by the Chemical Formula 1 according to an illustrative embodiment of the present disclosure.

FIG. 3 is a cross-sectional view schematically illustrating an organic light-emitting diode having a tandem structure having three light-emitting stacks and containing an organometallic compound represented by the Chemical Formula 1 according to an illustrative embodiment of the present disclosure.

FIG. 4 is a cross-sectional view schematically illustrating an organic light-emitting display device including an organic light-emitting diode according to an illustrative embodiment of the present disclosure.

### DETAILED DESCRIPTION OF THE EMBODIMENTS

Advantages and features of the present disclosure, and a method of achieving the advantages and features will become apparent with reference to embodiments described later in detail together with the accompanying drawings. However, the present disclosure is not limited to the embodiments as disclosed below, but can be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

A shape, a size, a ratio, an angle, a number, etc. disclosed in the drawings for describing the embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements can modify the entire list of elements and may not modify the individual elements of the list. In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when an element or layer is referred to as being “connected to”, or “coupled to” another element or layer, it can be directly on, connected to, or coupled to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Further, as used herein, when a layer, film, region, plate, or the like is disposed “on” or “on a top” of another layer, film, region, plate, or the like, the former can directly contact the latter or still another layer, film, region, plate, or the like can be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former can directly contact the latter or still another layer, film, region, plate, or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is not indicated.

It will be understood that, although the terms “first”, “second”, “third”, and so on can be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it can be directly on, connected to, or coupled to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

The features of the various embodiments of the present disclosure can be partially or entirely combined with each other, and can be technically associated with each other or operate with each other. The embodiments can be implemented independently of each other and can be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, a phrase ‘adjacent substituents are connected to each other to form a ring (or a ring structure)’ means that adjacent substituents can bind to each other to form a substituted or unsubstituted alicyclic or aromatic ring. A phrase ‘adjacent substituent’ to a certain substituent can mean a substituent replacing an atom directly connected to an atom which the certain substituent replaces, a substituent that is sterically closest to the certain substituent, or a substituent replacing an atom replaced with the certain substituent. For example, two substituents replacing an ortho position in a benzene ring structure and two substituents replacing the same carbon in an aliphatic ring can be interpreted as ‘adjacent substituents’.

Hereinafter, a structure of an organometallic compound according to the present disclosure and an organic light emitting diode including the same will be described.

Conventionally, an organometallic compound has been used as a dopant in a light emitting layer of an organic light emitting diode. For example, 2-phenylpyridine, and 2-phenylquinoline in which a fused ring is introduced to a pyridine moiety in a structure of 2-phenylpyridine are known as a main ligand structure of the organometallic compound. However, the conventional light-emitting dopant has a limit in improving efficiency and lifetime of the organic light emitting diode. Thus, it is necessary to develop a new light-emitting dopant material. Accordingly, the inventors of the present disclosure have derived a light emitting dopant material that can further improve the efficiency and lifespan of the organic light emitting diode and thus have completed the present disclosure.

Specifically, an organometallic compound according to one implementation of the present disclosure can be represented by a following Chemical Formula 1. In a main ligand of the following Chemical Formula 1, a fused ring of a structure of “R” is introduced to a ring to which carbon (C) is connected among two rings connected to a central coordination metal M. As a result, in the organometallic compound of the present disclosure, [5-membered ring]-[5-membered ring]-[6-membered ring] are sequentially fused with [6-membered ring] as a ring to which carbon (C) is connected among two rings connected to the central coordination metal M. When the organometallic compound represented by the following Chemical Formula 1 is used as a dopant material of the light-emitting layer of the organic light-emitting diode, luminous efficiency and lifespan of the organic light emitting diode can be increased, and an operation voltage thereof can be reduced:

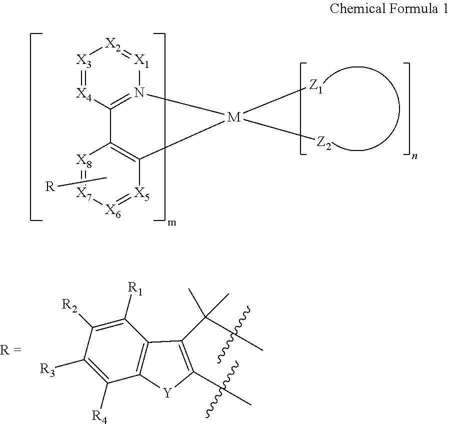

wherein in the Chemical Formula 1, M can represent one selected from a group consisting of Mo, W, Re, Ru, Os, Rh, Ir, Pd, Pt and Au;

R can represent a ring structure fused with one pair selected from a pair of X₅ and X₆, a pair of X₆ and X₇, and a pair of X₇ and X₈;

each of X₁ to X₄ can independently represent one selected from CR₅ and N;

optionally, two R₅ on the adjacent two of X₁ to X₄ can be connected to each other to form a ring structure including one selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group;

Y can represent one selected from a group consisting of BR₆, CR₆R₇, C═O, CNR₆, SiR₆R₇, NR₆, PR₆, AsR₆, SbR₆, P(O)R₆, P(S)R₆, P(Se)R₆, As(O)R₆, As(S)R₆, As(Se)R₆, Sb(O)R₆, Sb(S)R₆, Sb(Se)R₆, O, S, Se, Te, SO, SO₂, SeO, SeO₂, TeO and TeO₂;

each of X₅ to X₈ can independently represent CR₈;

each of R₅ to R₈ can independently represent one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;

(Z₁-Z₂) can represent a bidentate ligand; and

m can be 1, 2 or 3, n can be 0, 1 or 2, and a sum of m and n can be an oxidation number of the metal M.

A structure of the Chemical Formula 1 as the organometallic compound according to the present disclosure is characterized in that in the main ligand, a fused ring of “R” is introduced to a ring to which carbon (C) is connected among two rings connected to the metal M. Further, sub-structures of the organometallic compound can be classified based on a structure of a ring to which nitrogen (N) is connected among the two rings connected to the metal M.

Specifically, the sub-structure of the Chemical Formula 1 of the present disclosure can include a first sub-structure in which [6-membered ring] is fused with the ring to which nitrogen (N) is connected and a second sub-structure in which [6-membered ring] and [5-membered ring] are fused therewith. The first sub-structure can include ‘Chemical Formulas 2 to 5’ and the second sub-structure can include ‘Chemical Formulas 6 to 11’.

According to one implementation of the present disclosure, the Chemical Formula 1 can be one selected from a group consisting of following Chemical Formula 2 to Chemical Formula 5:

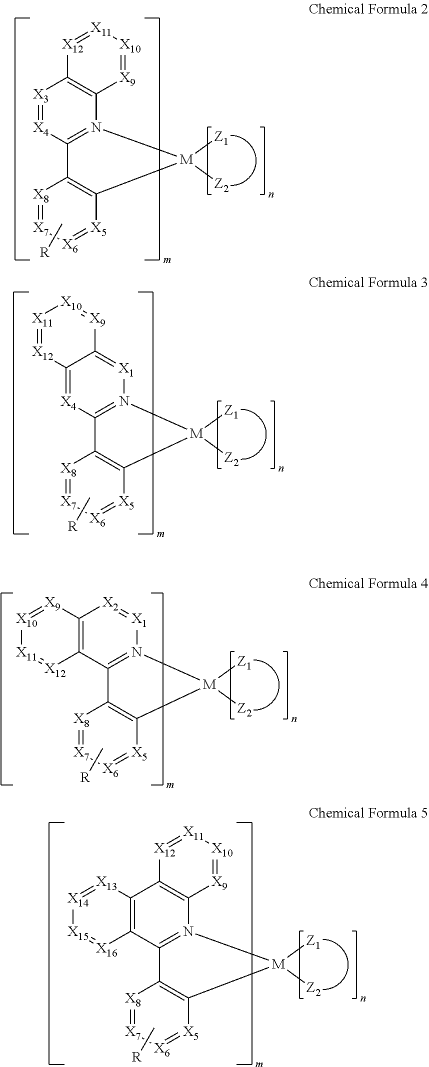

wherein in each of the Chemical Formula 2 to Chemical Formula 5,

each of X₉ to X₁₆ can independently represent one selected from CR₉ and N;

optionally, two R₉ on the adjacent two of X₉ to X₁₆ can be connected to each other to form a ring structure including one selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group;

R₉ can represent one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group; and

M, Y, X₁ to X₈, R, R₁ to R₈, (Z₁-Z₂), m and n can be the same as defined above or in claims.

According to another implementation of the present disclosure, the Chemical Formula 1 can be one selected from a group consisting of following Chemical Formulas 6 to 11:

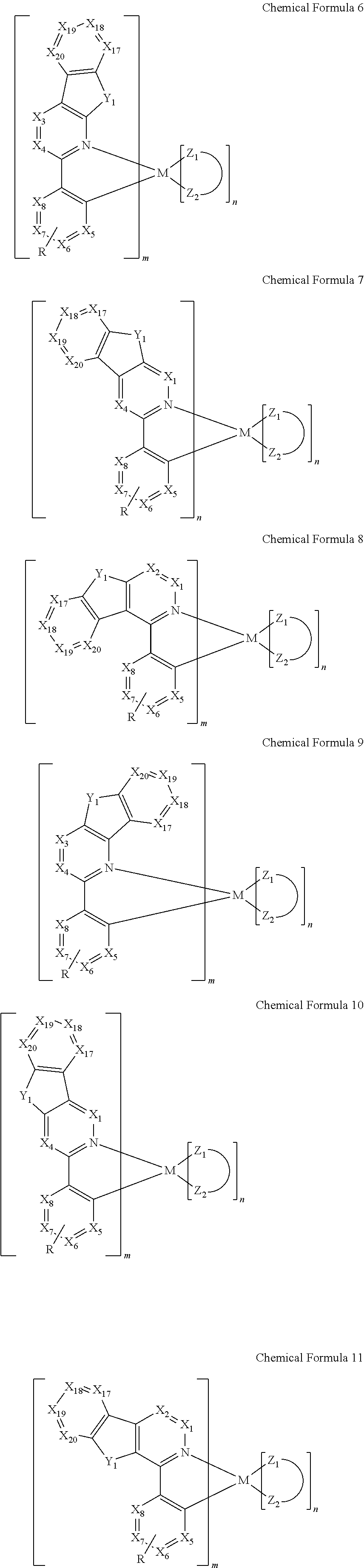

wherein in each of the Chemical Formula 6 to Chemical Formula 11,

each of X₁₇ to X₂₀ can independently represent one selected from CR₁₀ and N;

optionally, two R₁₀ on the adjacent two of X₁₇ to X₂₀ can be connected to each other to form a ring structure including one selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group;

Y₁ can represent one selected from a group consisting of CR₁₁R₁₂, NR₁₁, O and S;

each of R₁₀ to R₁₂ can independently represent one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group; and

M, Y, X₁ to X₈, R, R₁ to R₈, (Z₁-Z₂), m and n can be the same as defined above or in claims.

When a metal complex of iridium (Ir) or platinum (Pt) with a large atomic number is used, phosphorescence can be efficiently obtained even at room temperature. Thus, in the organometallic compound according to an implementation of the present disclosure, a central coordination metal (M) is preferably one of iridium (Ir) or platinum (Pt), for example, more preferably, iridium (Ir). However, the present disclosure is not limited thereto.

In the organometallic compound according to an implementation of the present disclosure, an ancillary ligand bound to the central coordination metal can be the bidentate ligand. The bidentate ligand can contain an electron donor, thereby increasing an amount of MLCT (metal to ligand charge transfer), thereby allowing the organic light-emitting diode to exhibit improved luminous properties such as high luminous efficiency and high external quantum efficiency.

The organometallic compound according to an implementation of the present disclosure can have a heteroleptic or homoleptic structure. For example, the organometallic compound according to an embodiment of the present disclosure can have a heteroleptic structure in which in the Chemical Formula 1, m is 1 and n is 2; or a heteroleptic structure where m is 2 and n is 1; or a homoleptic structure where m is 3 and n is 0.

A specific example of the compound represented by the Chemical Formula 1 of the present disclosure can include one selected from a group consisting of following compounds 1 to 884. However, the specific example of the compound represented by the Chemical Formula 1 of the present disclosure is not limited thereto as long as it meets the above definition of the Chemical Formula 1:

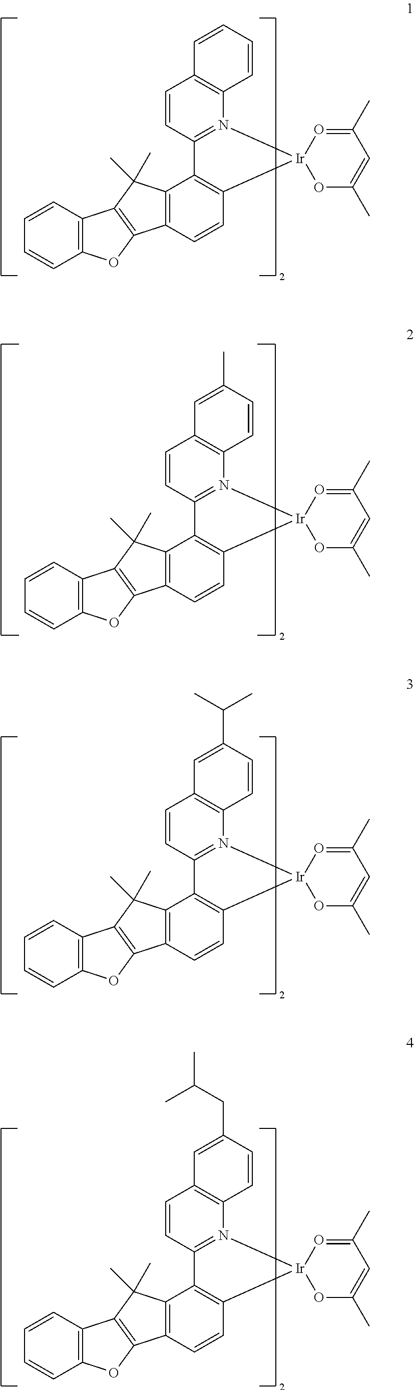

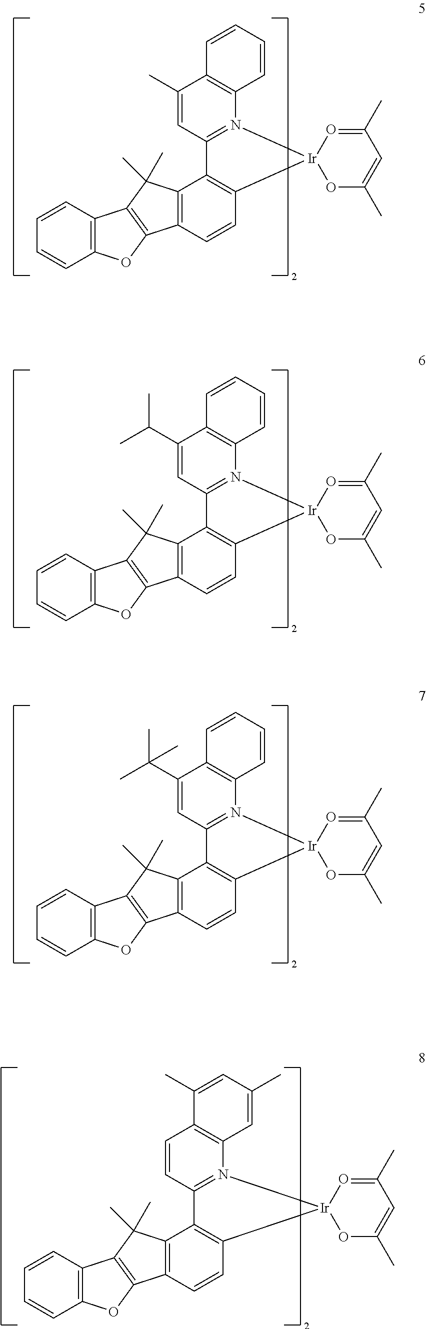

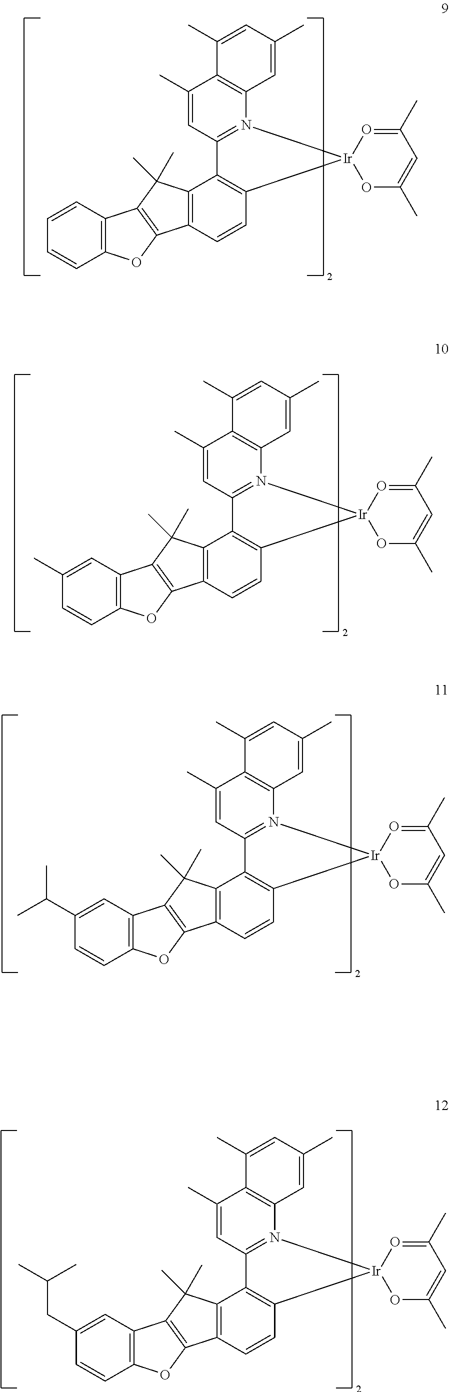

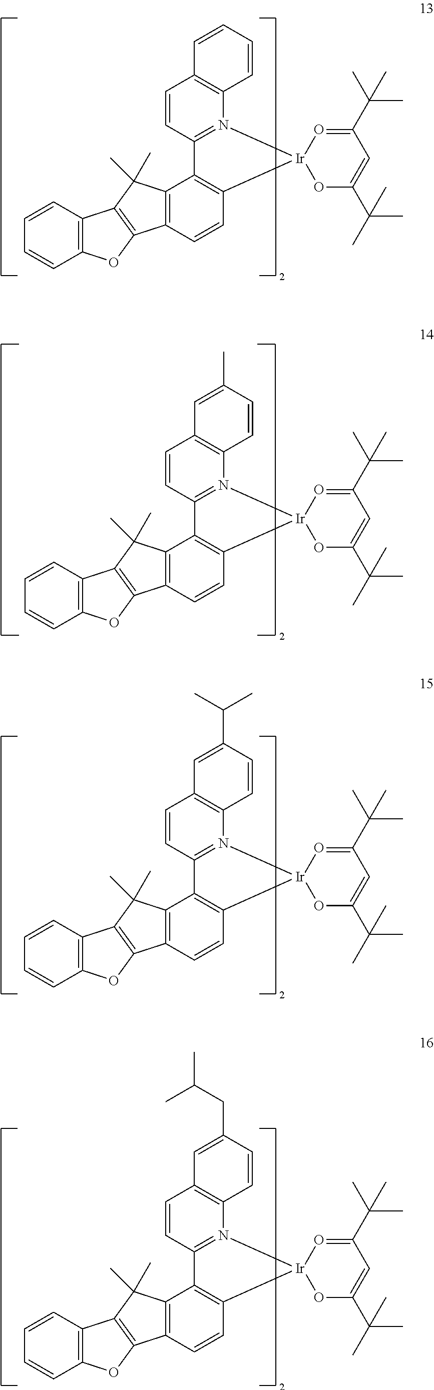

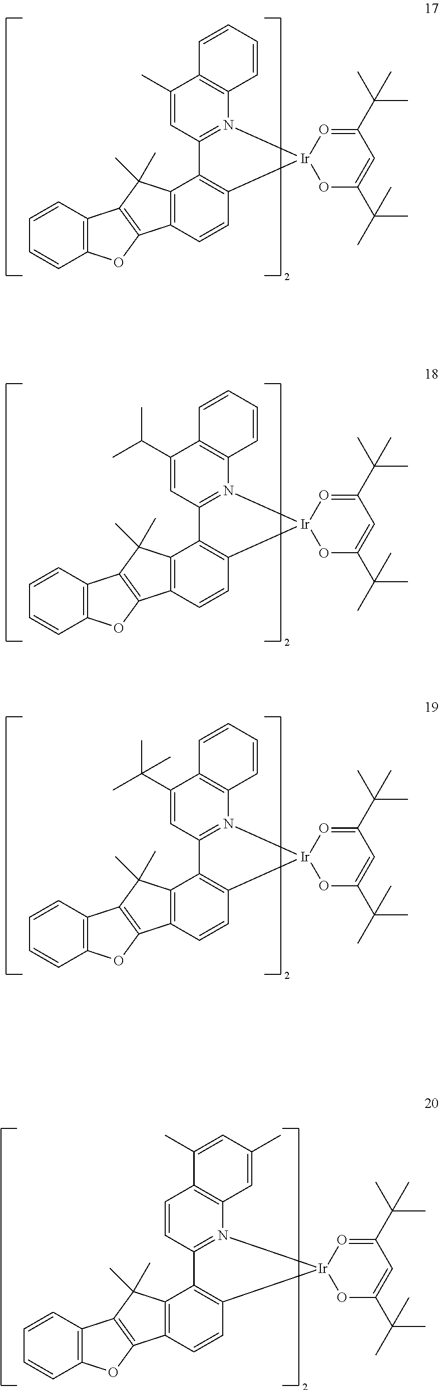

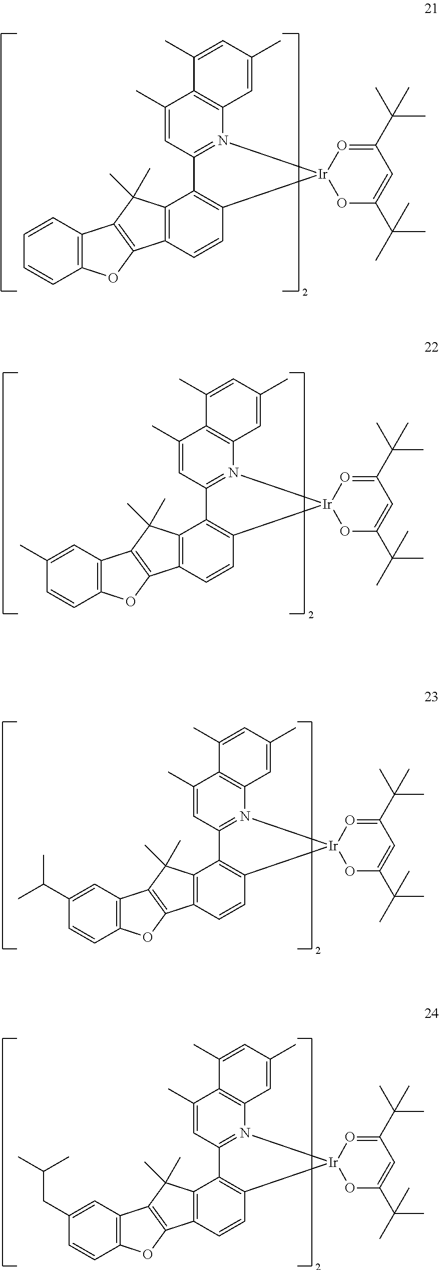

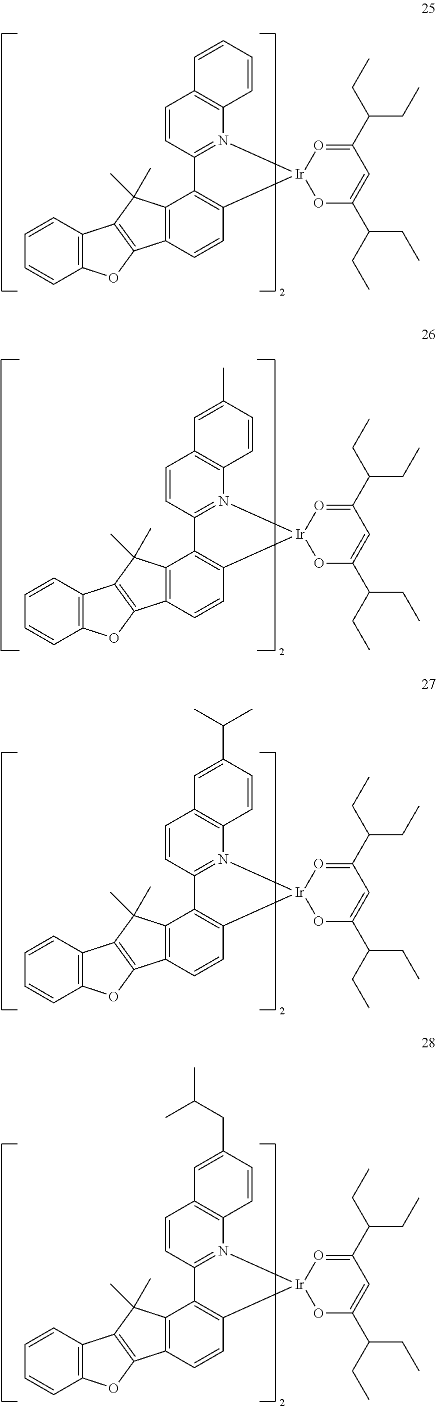

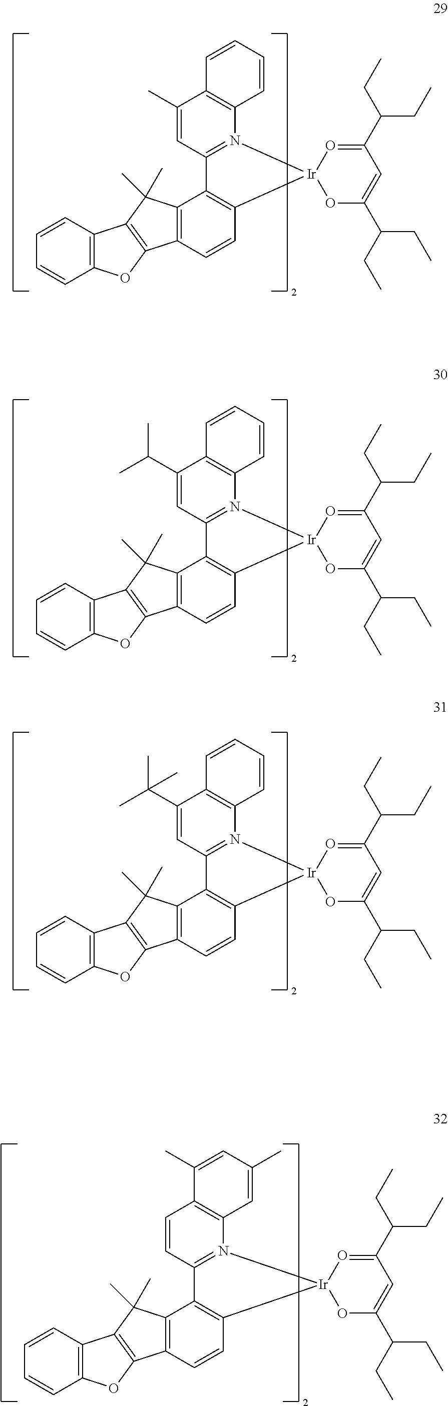

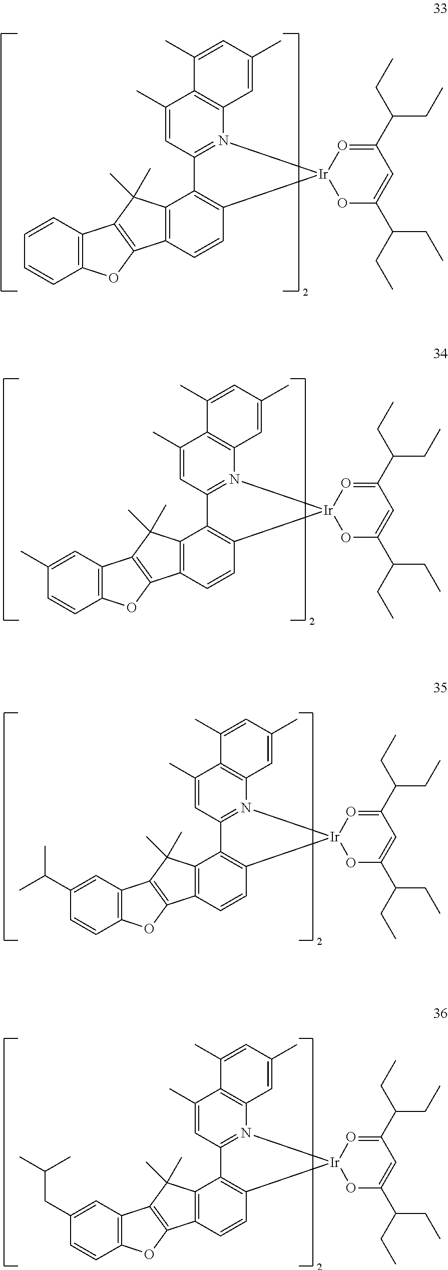

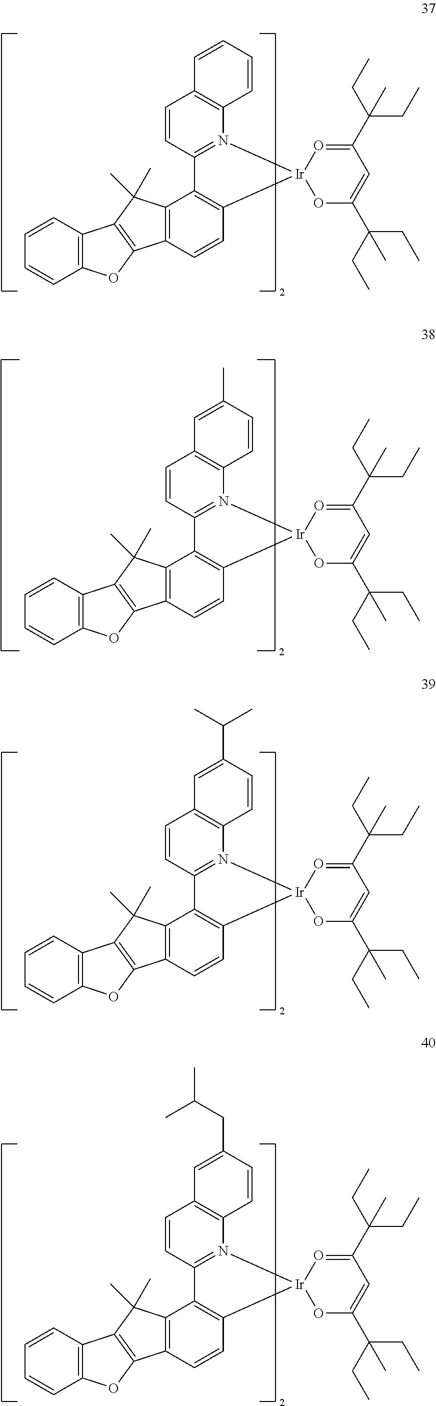

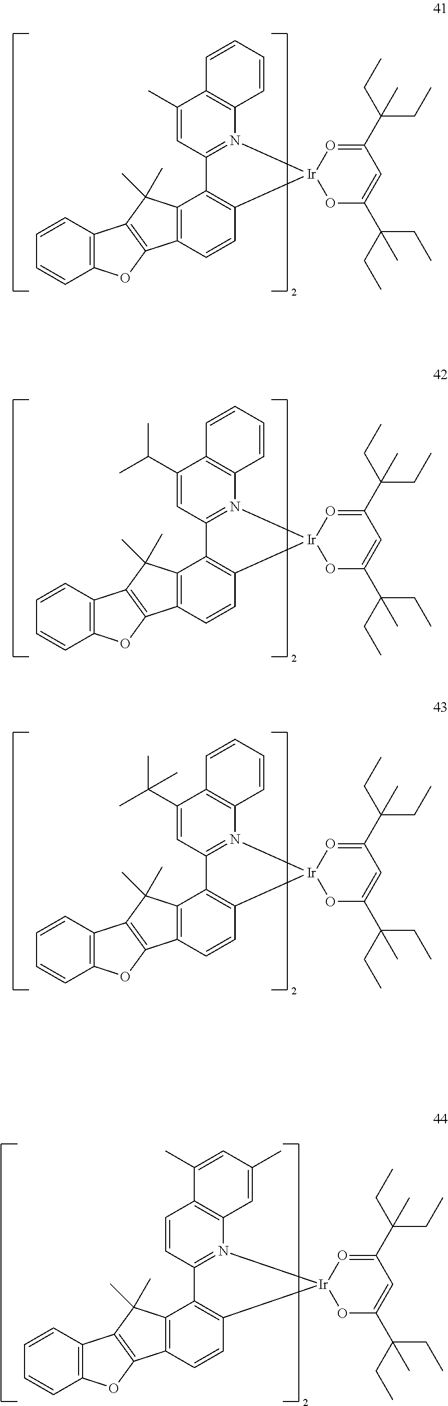

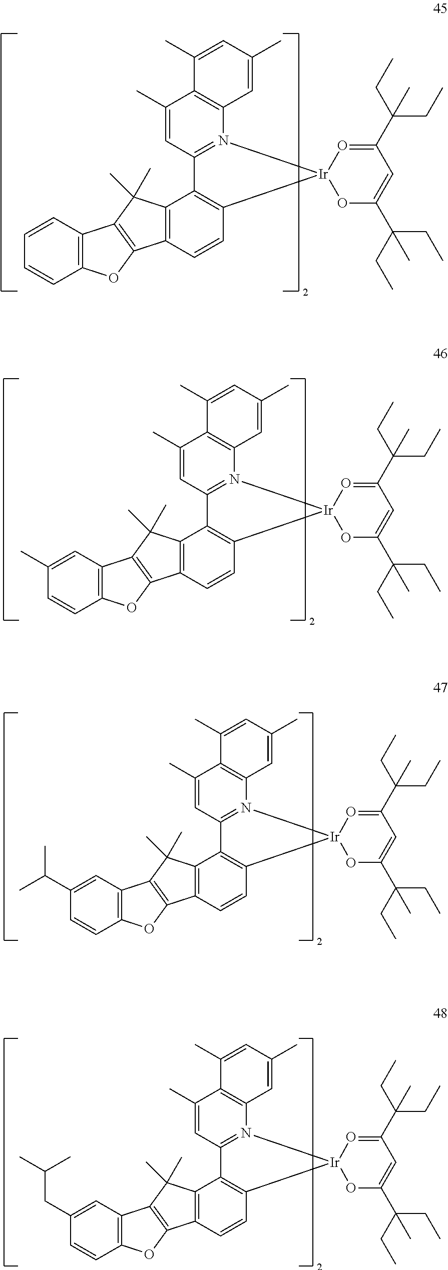

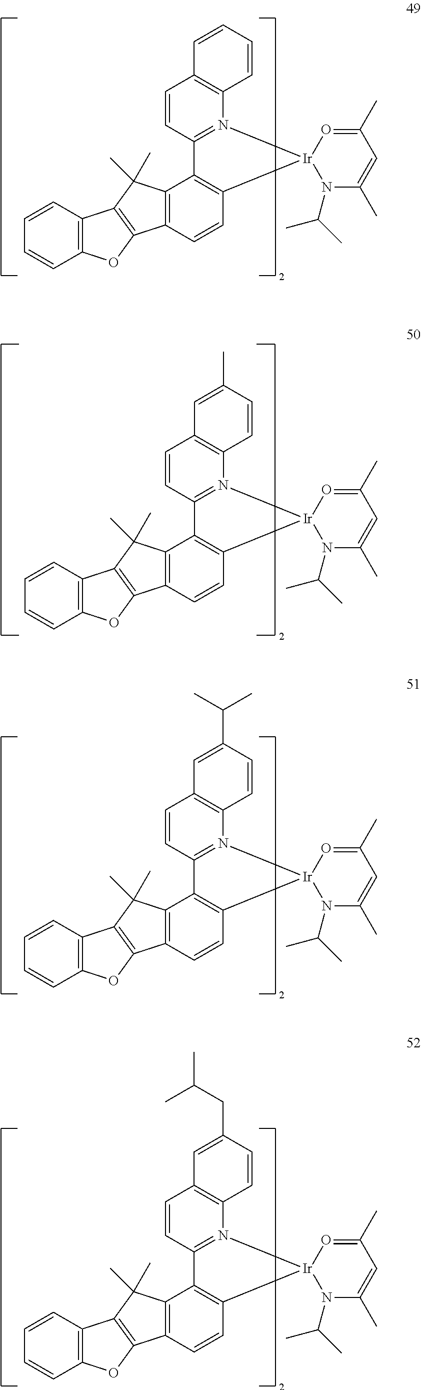

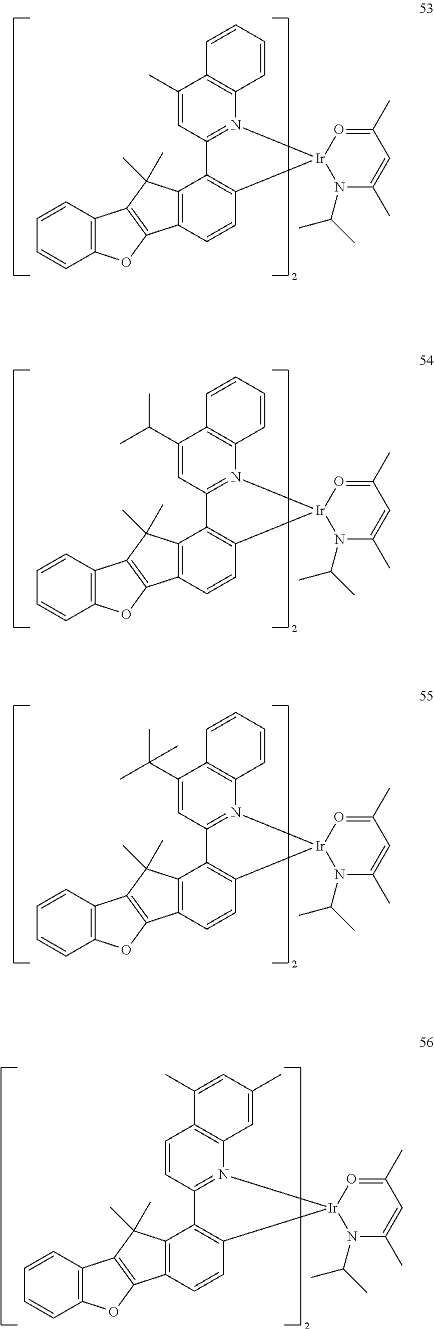

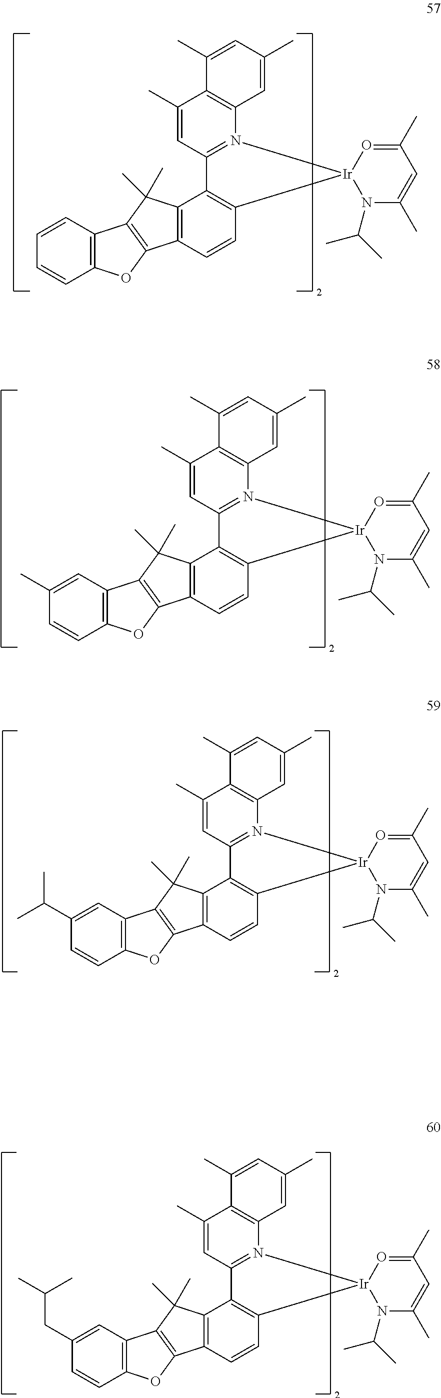

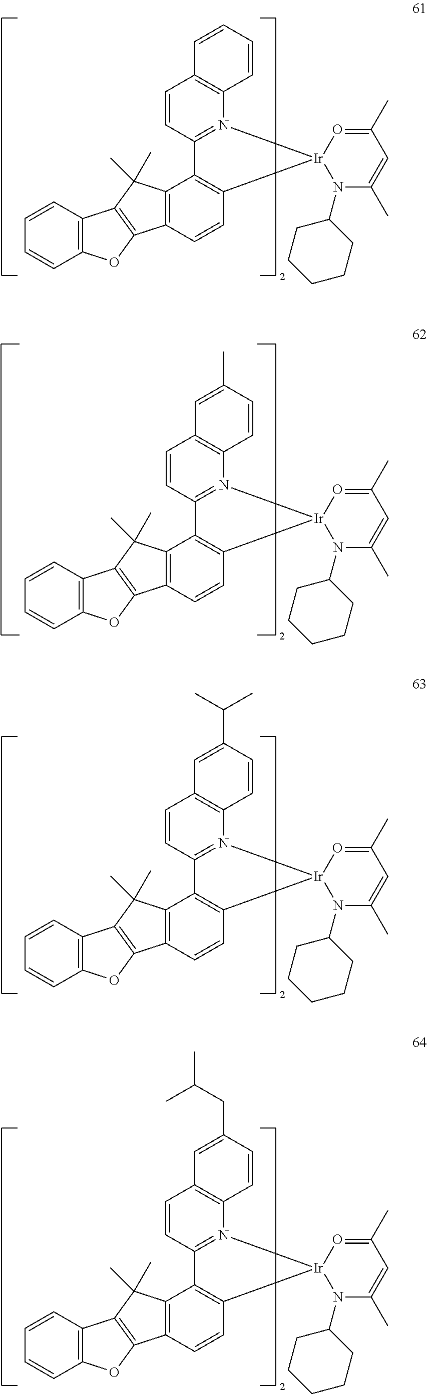

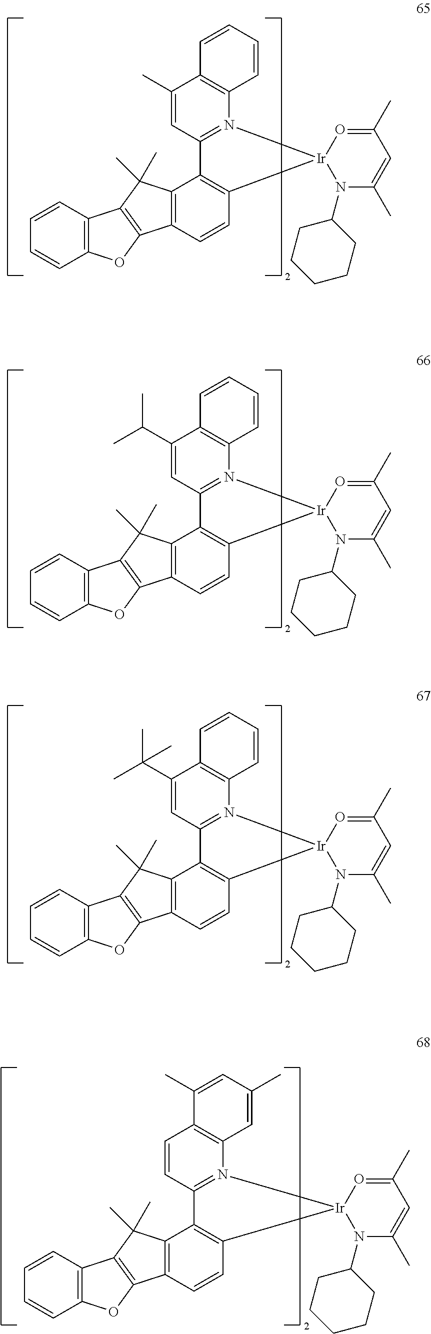

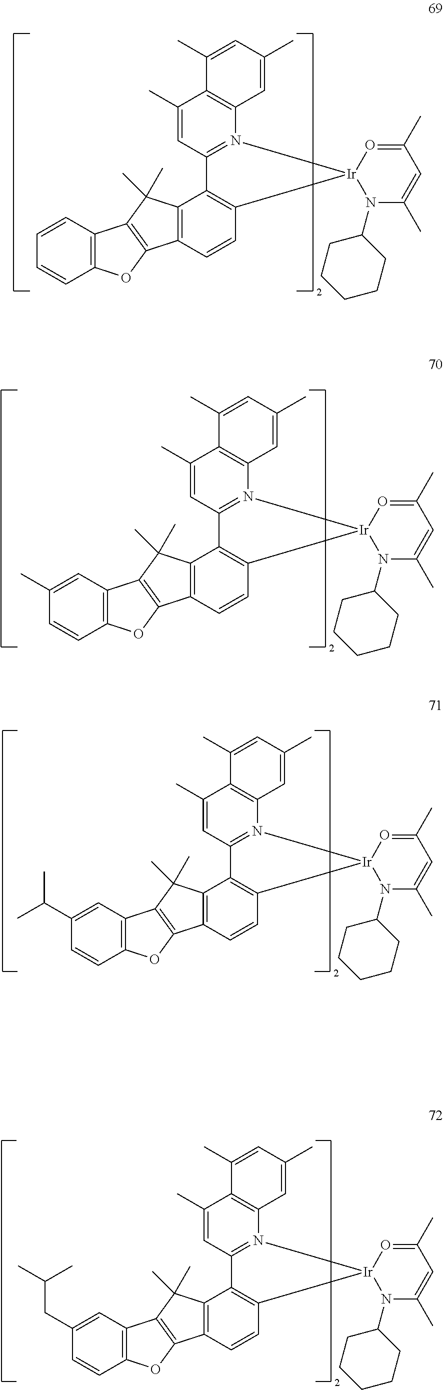

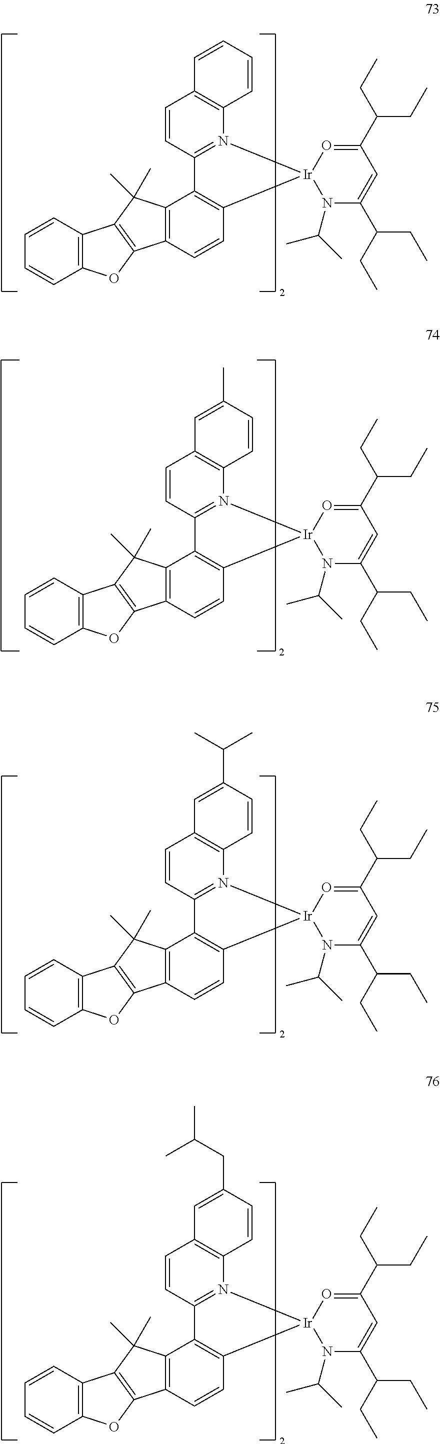

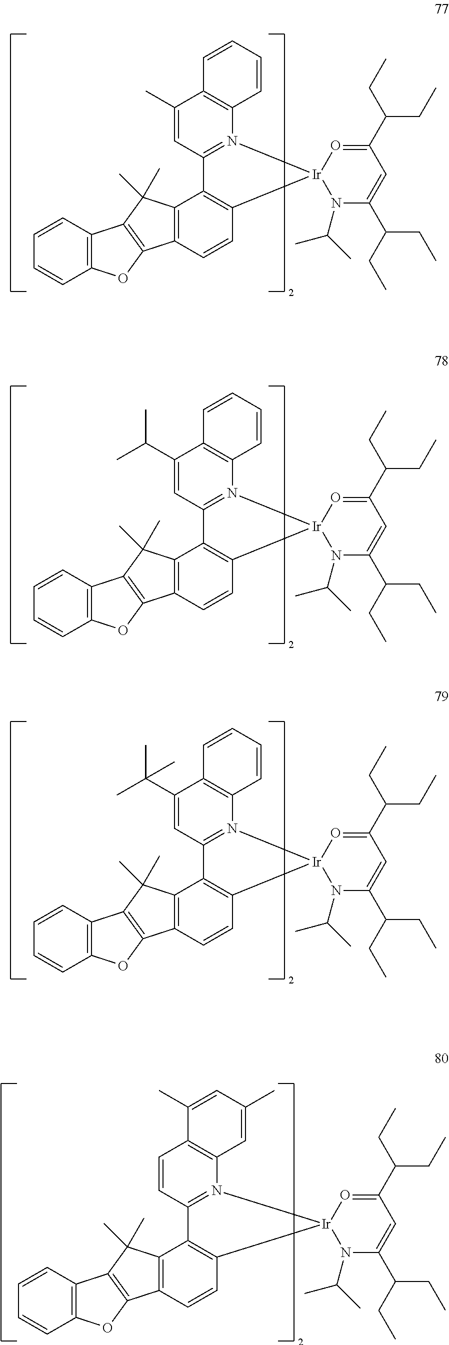

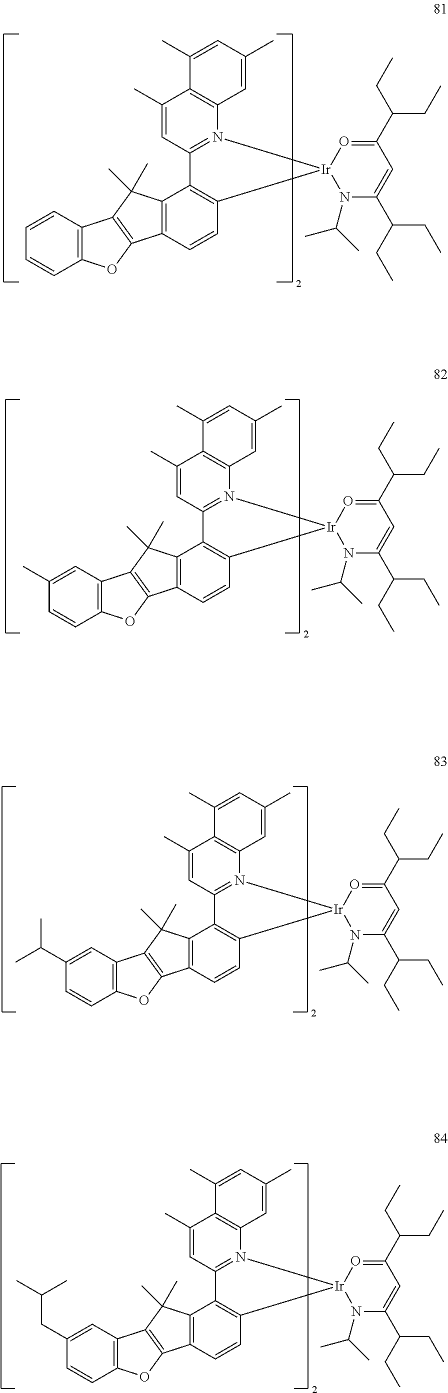

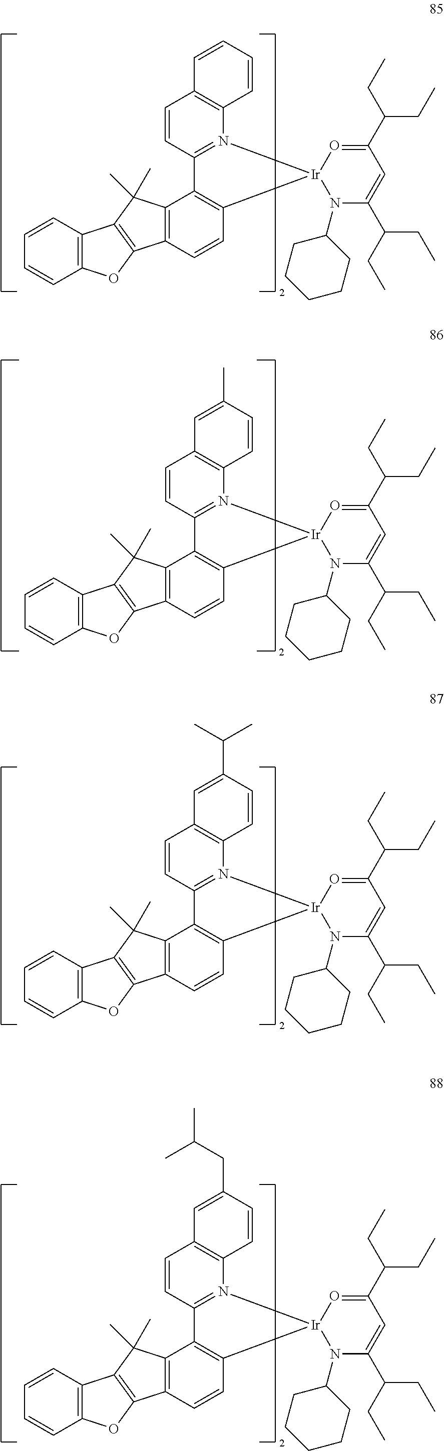

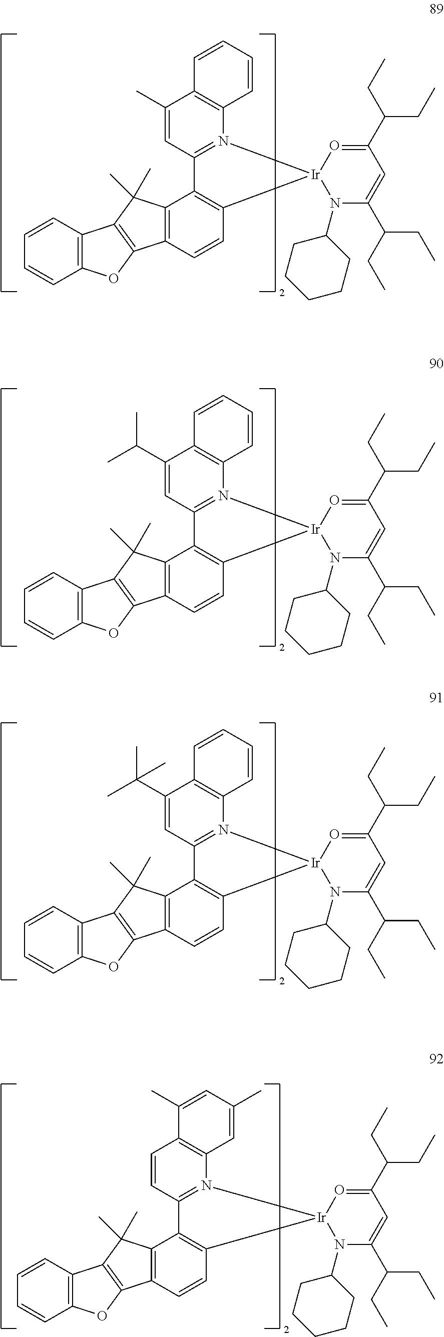

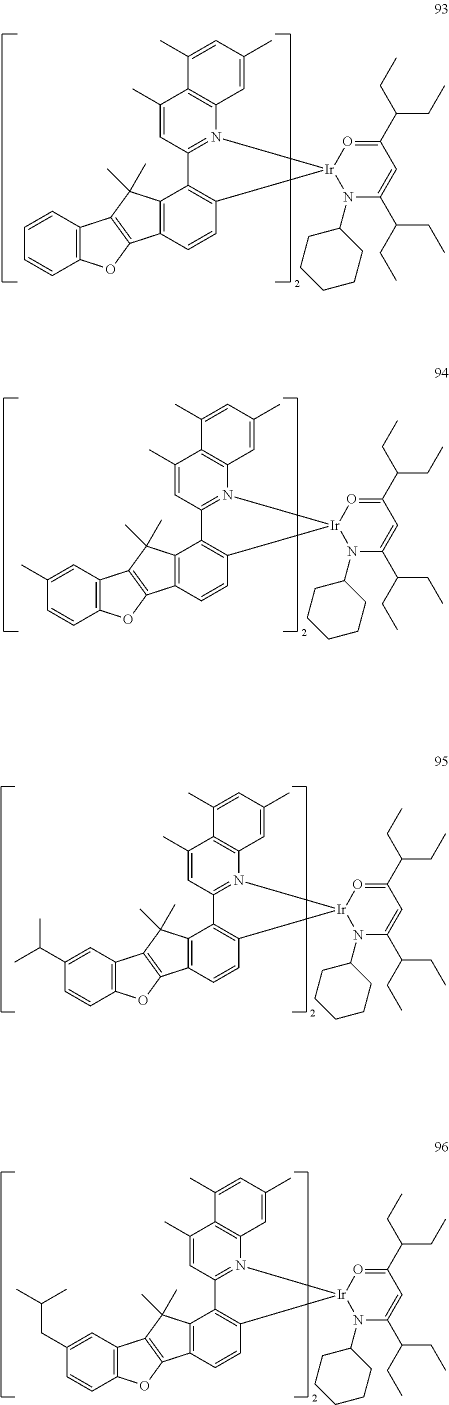

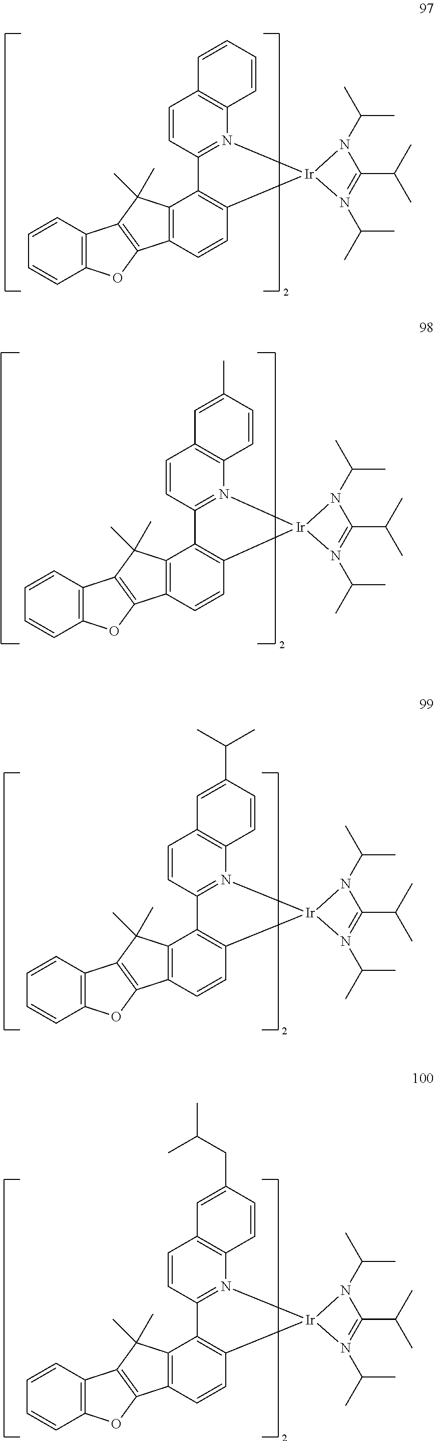

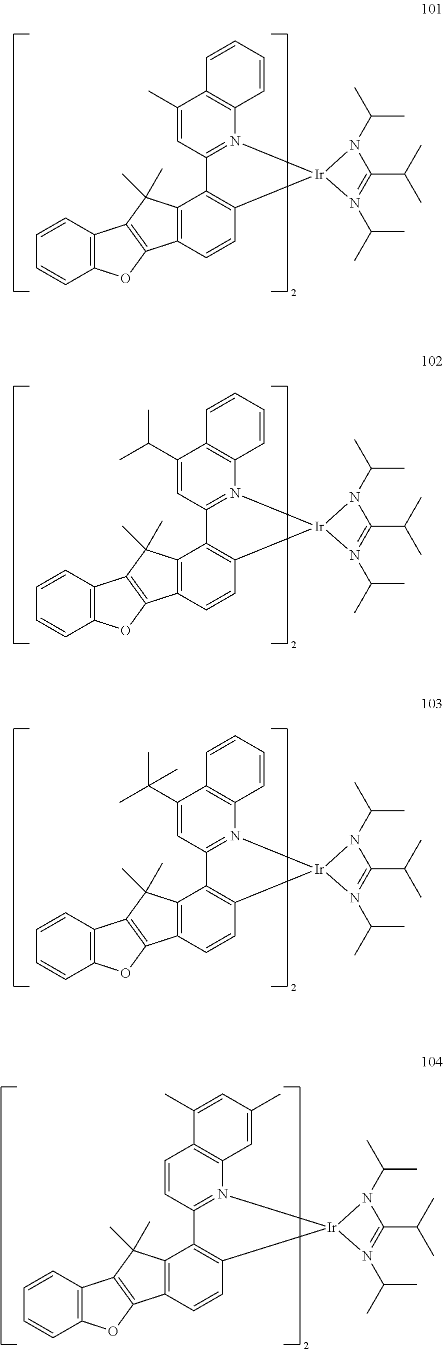

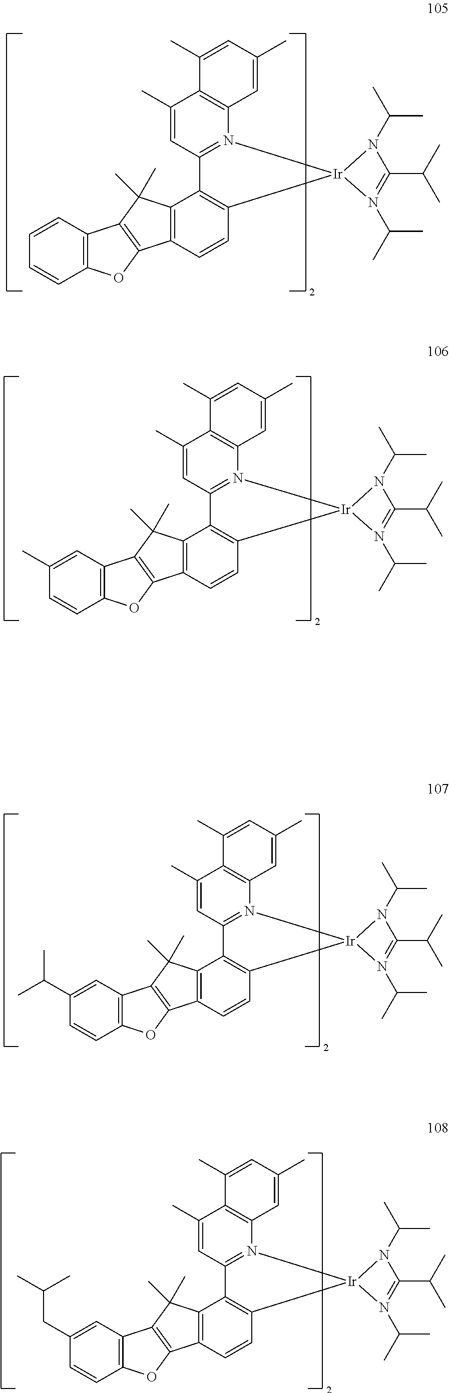

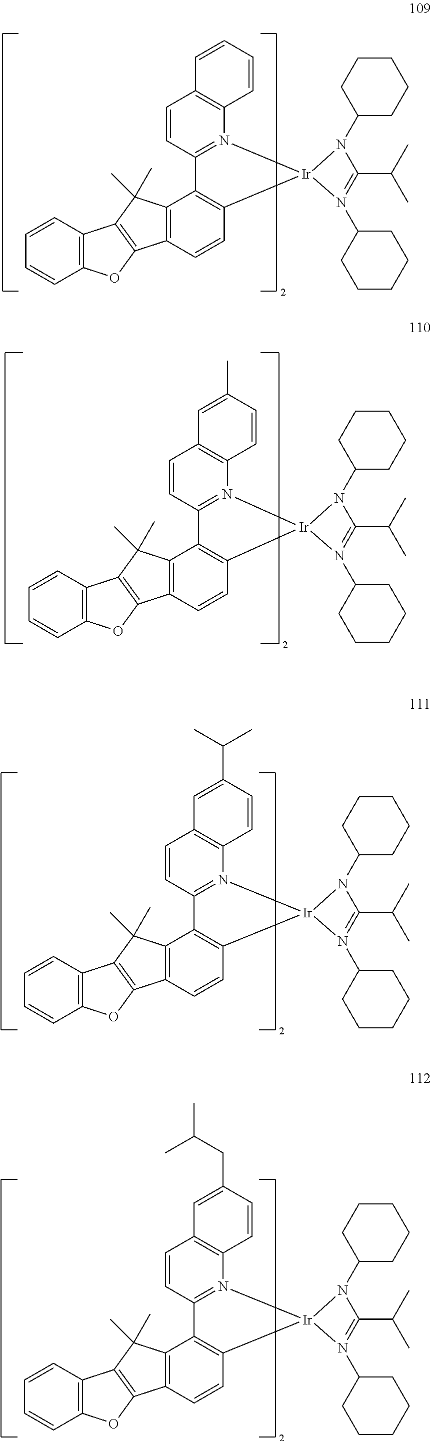

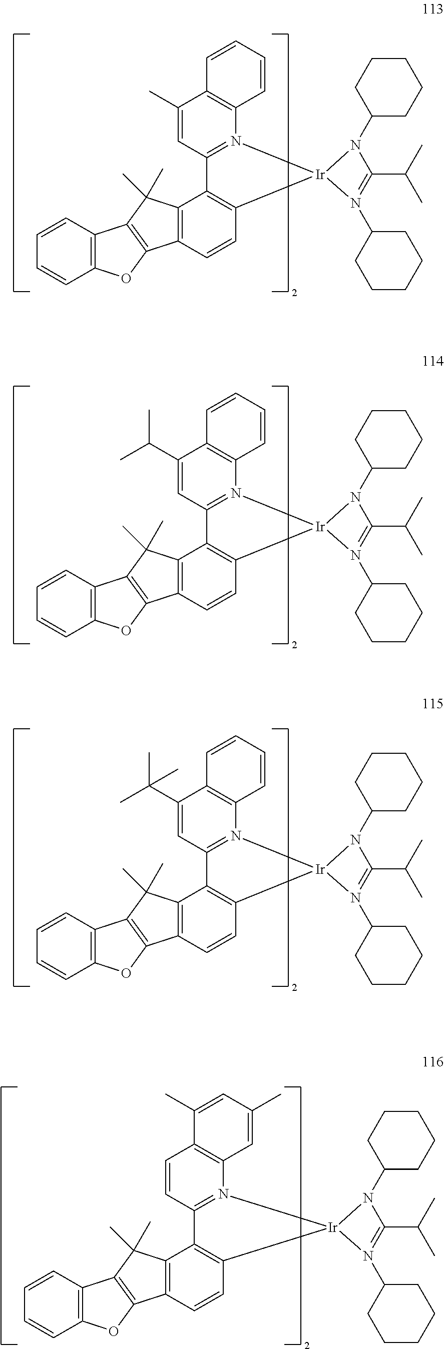

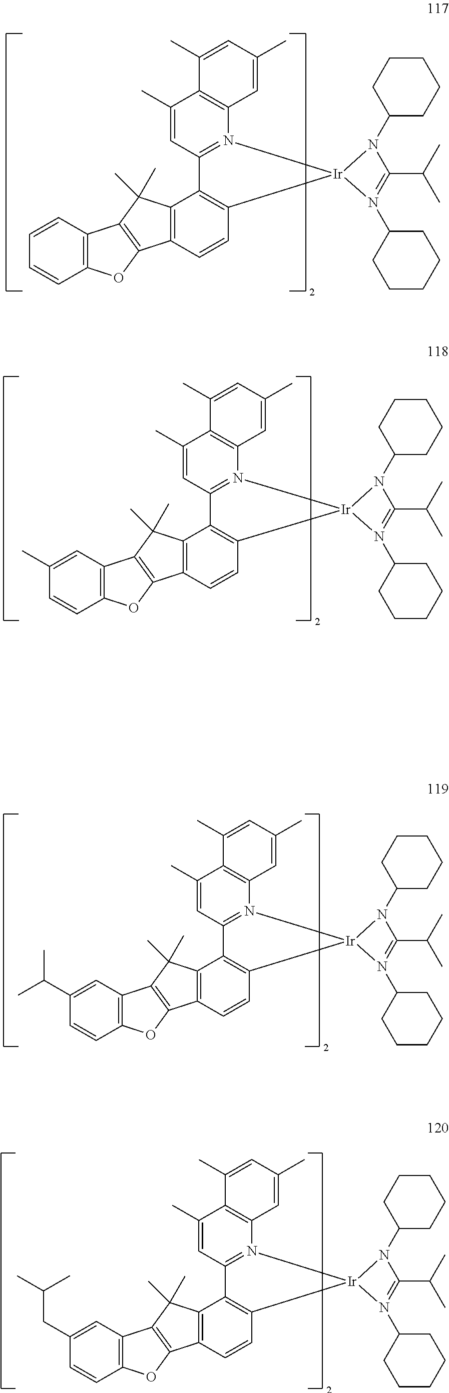

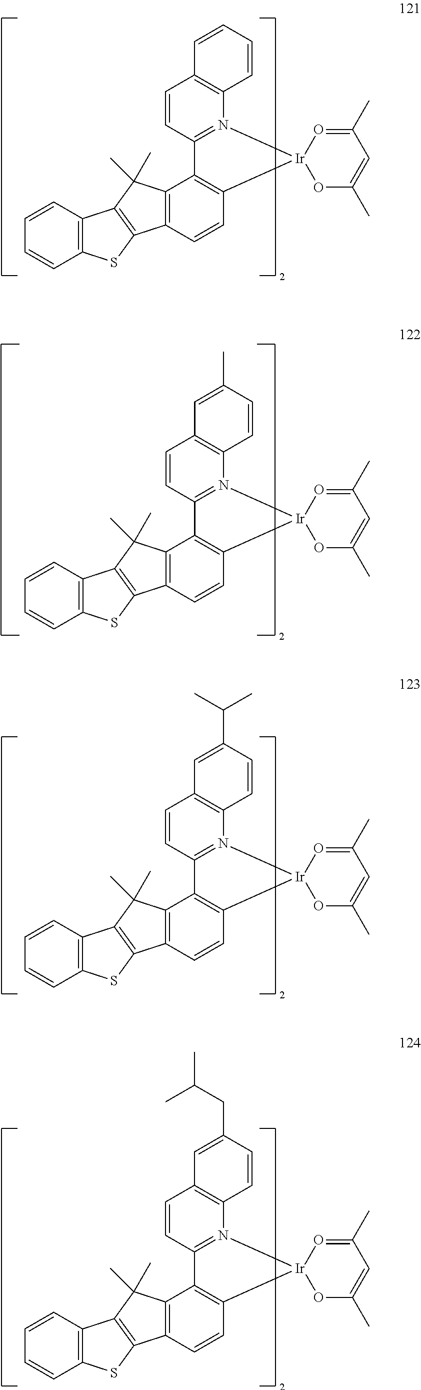

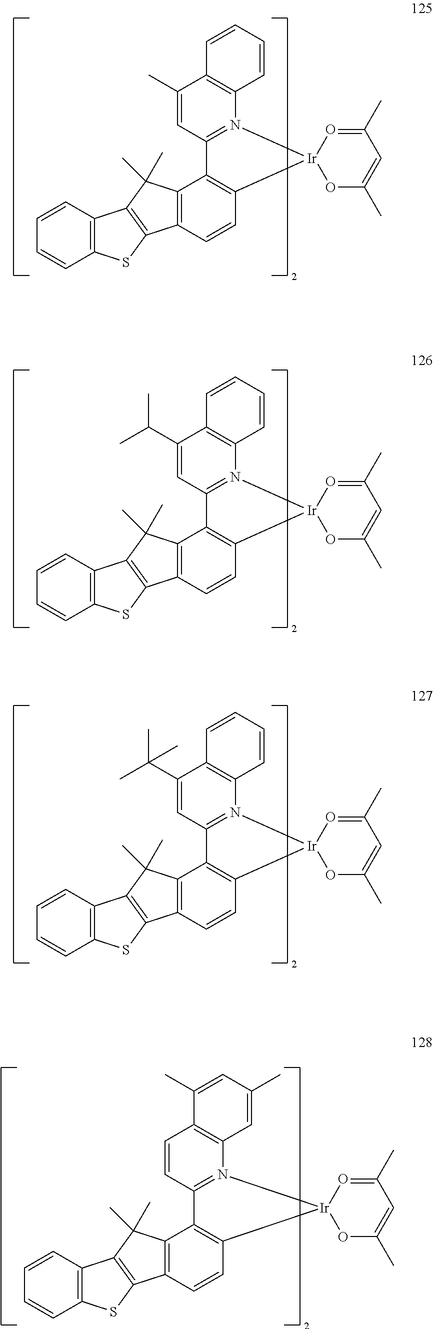

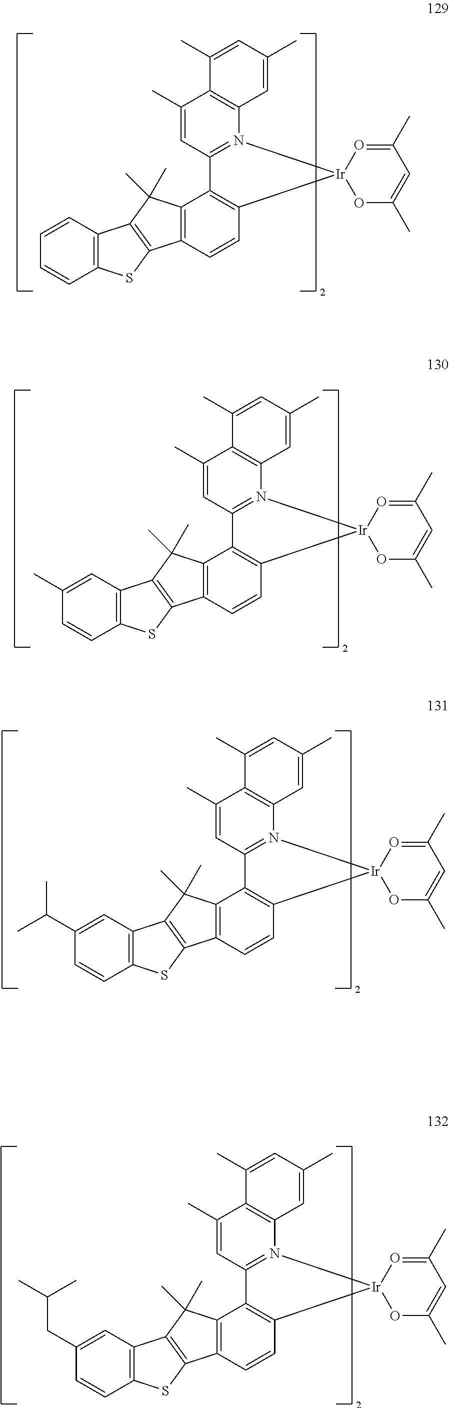

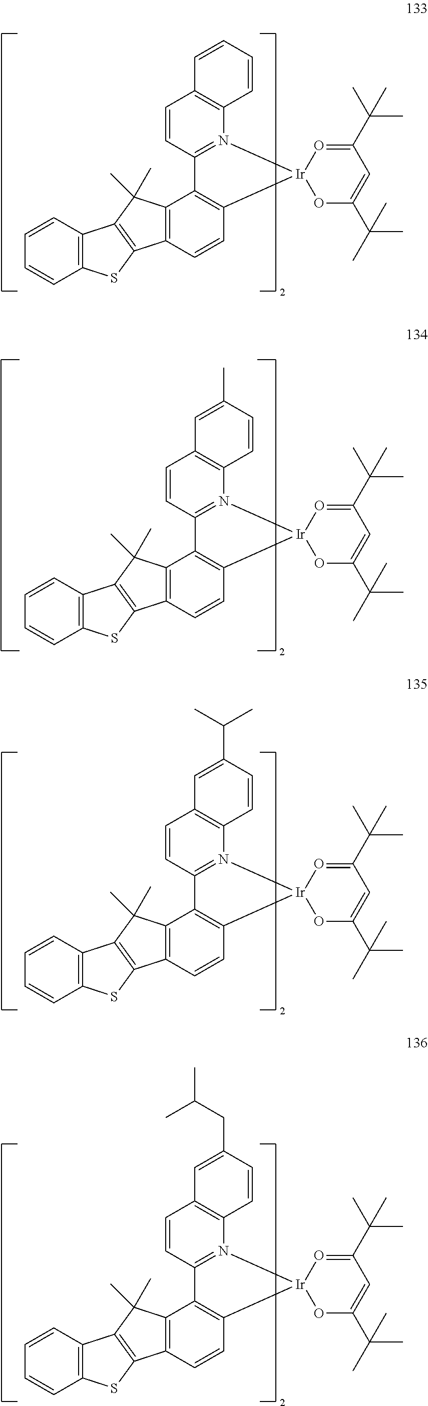

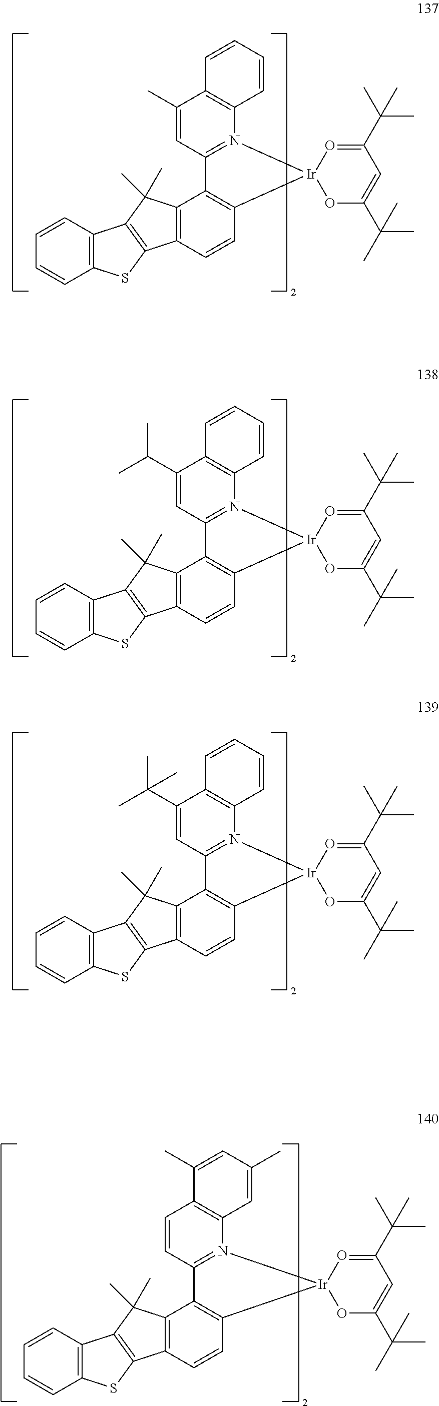

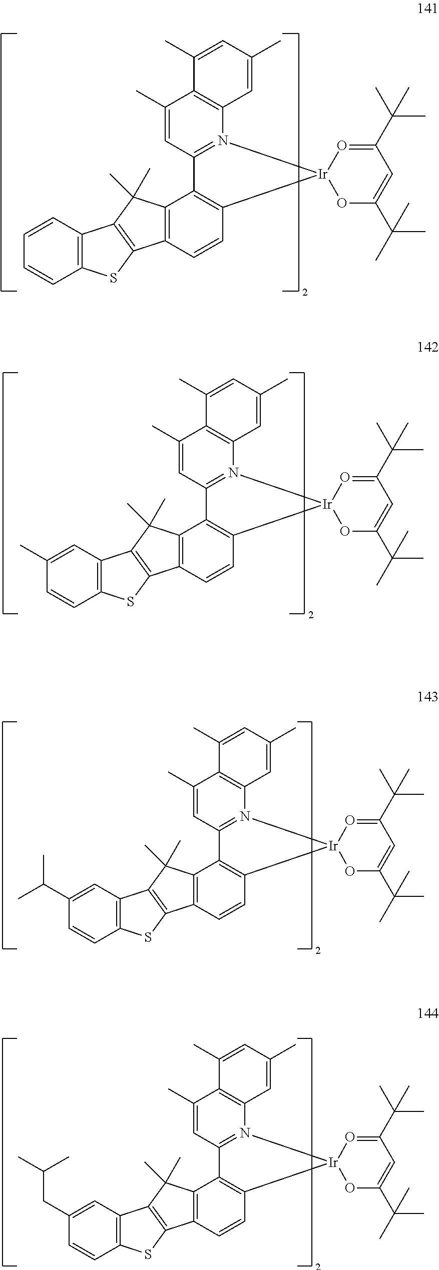

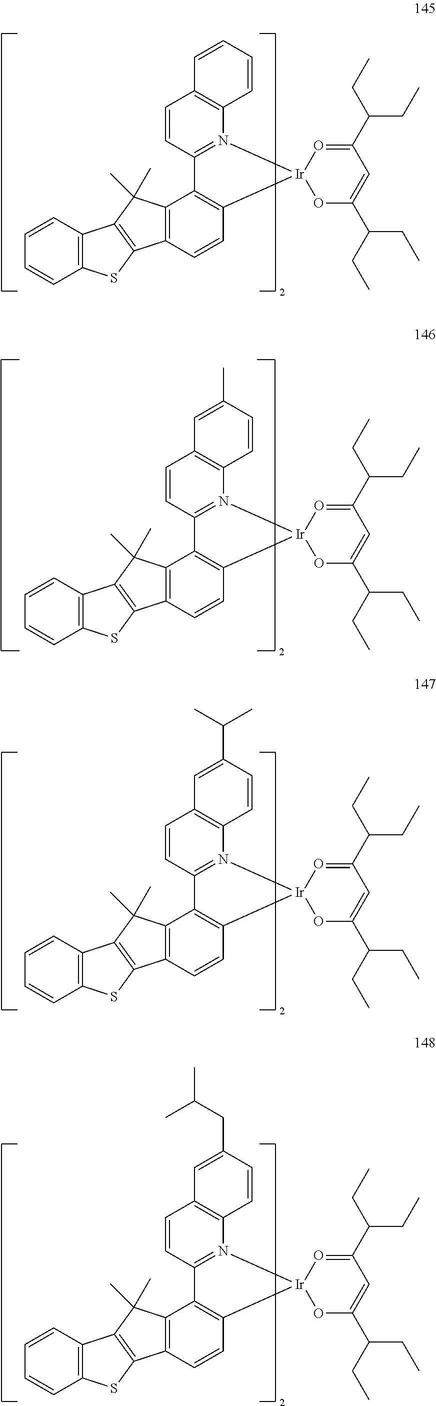

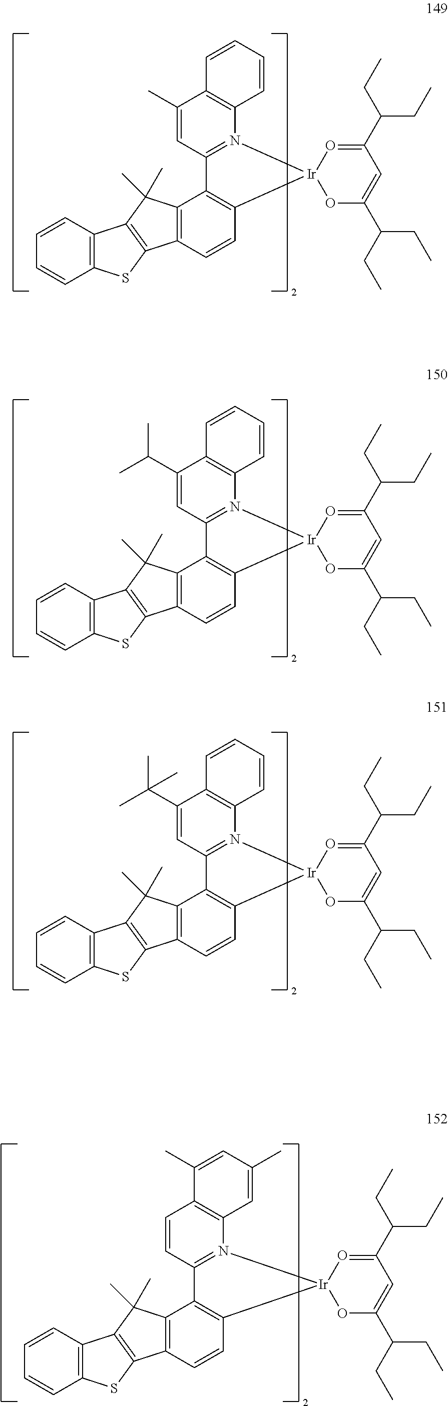

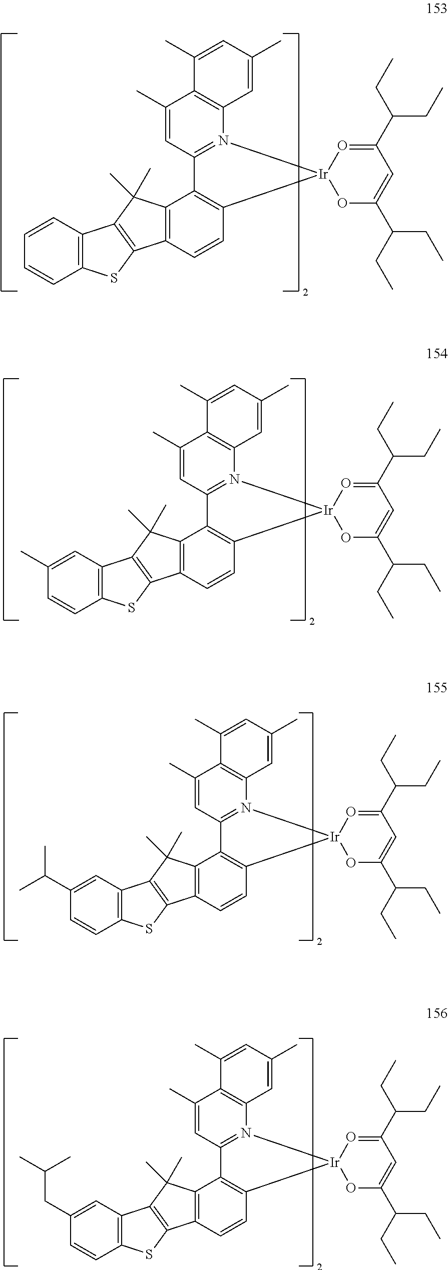

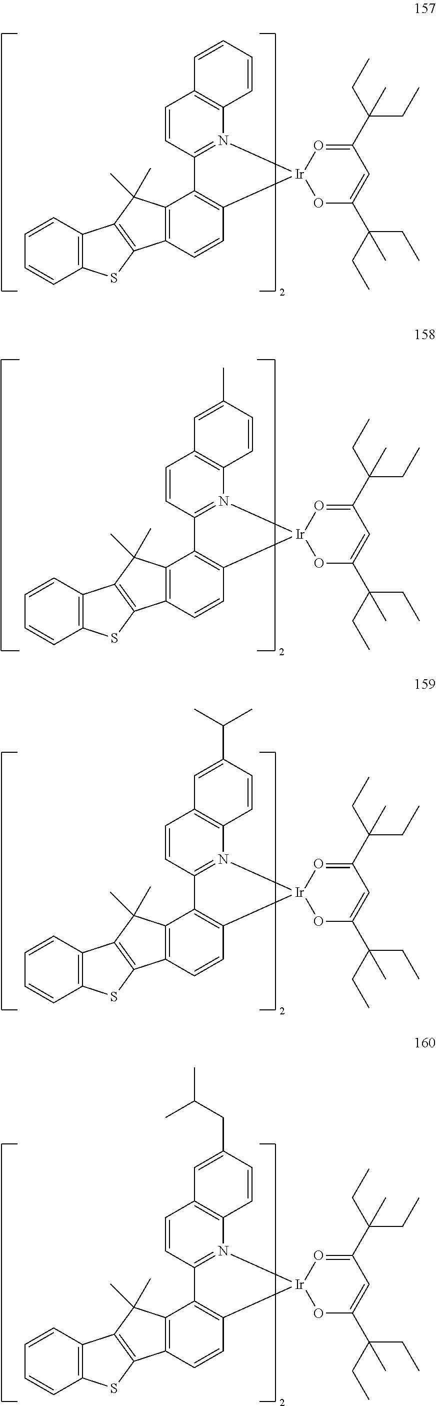

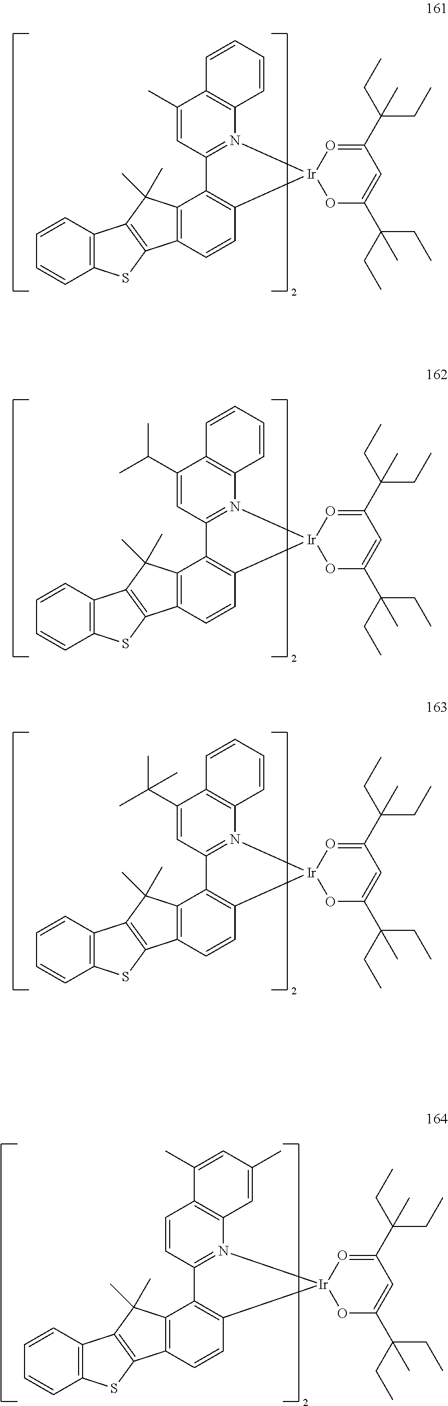

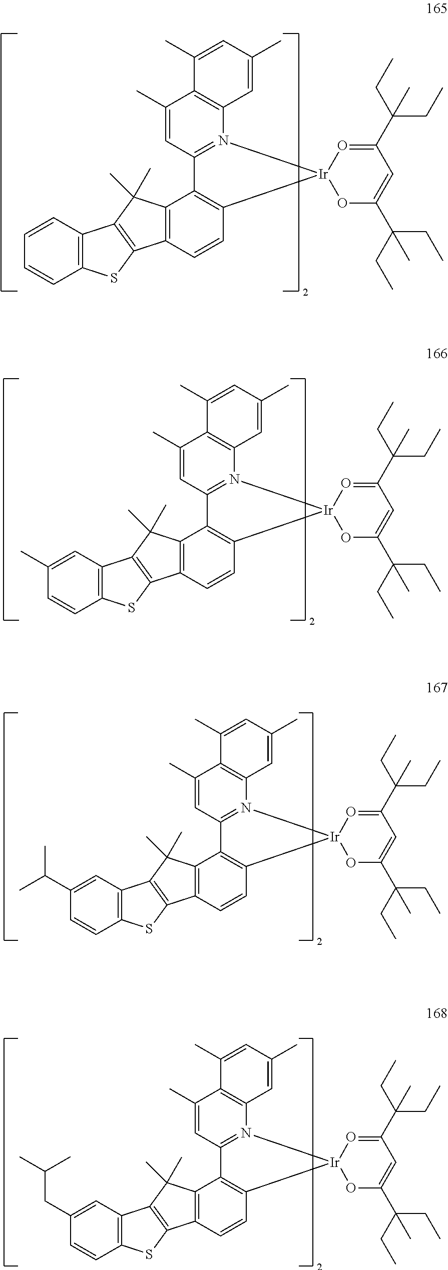

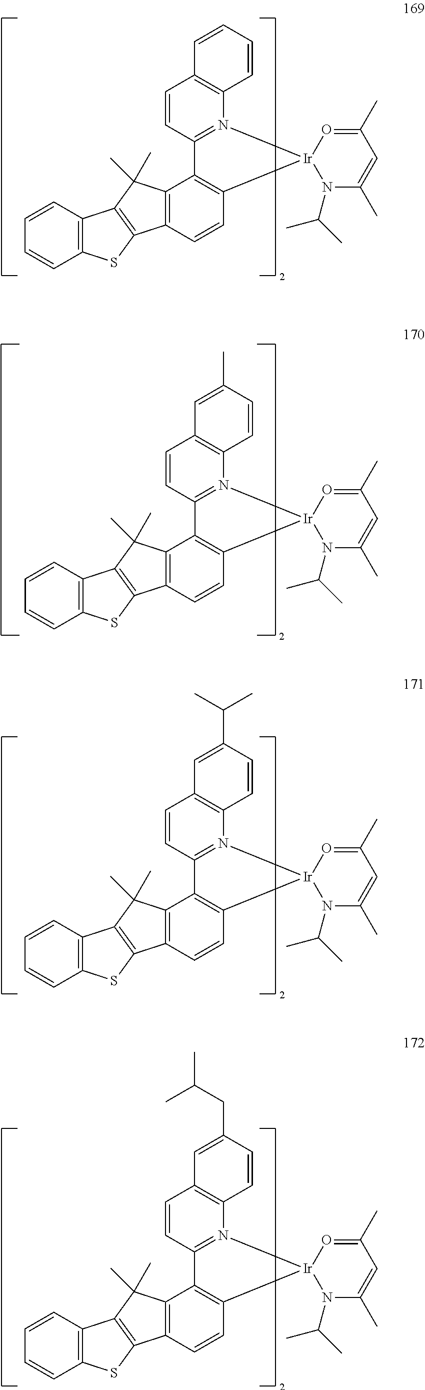

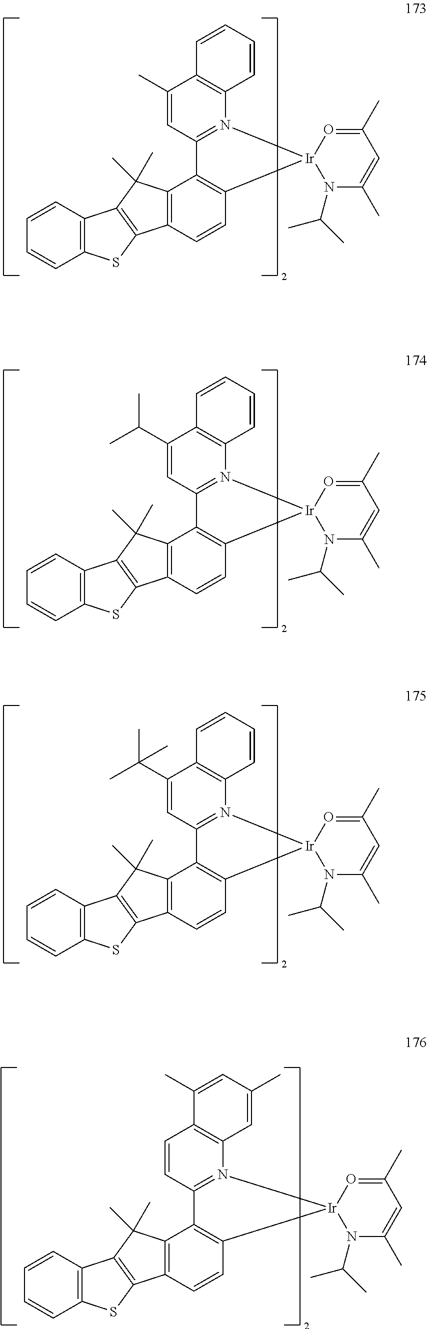

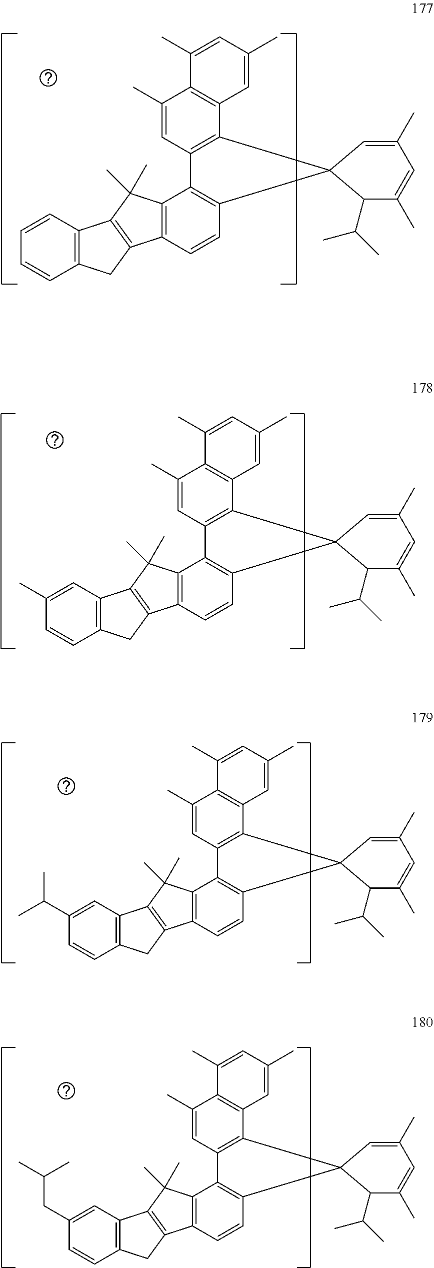

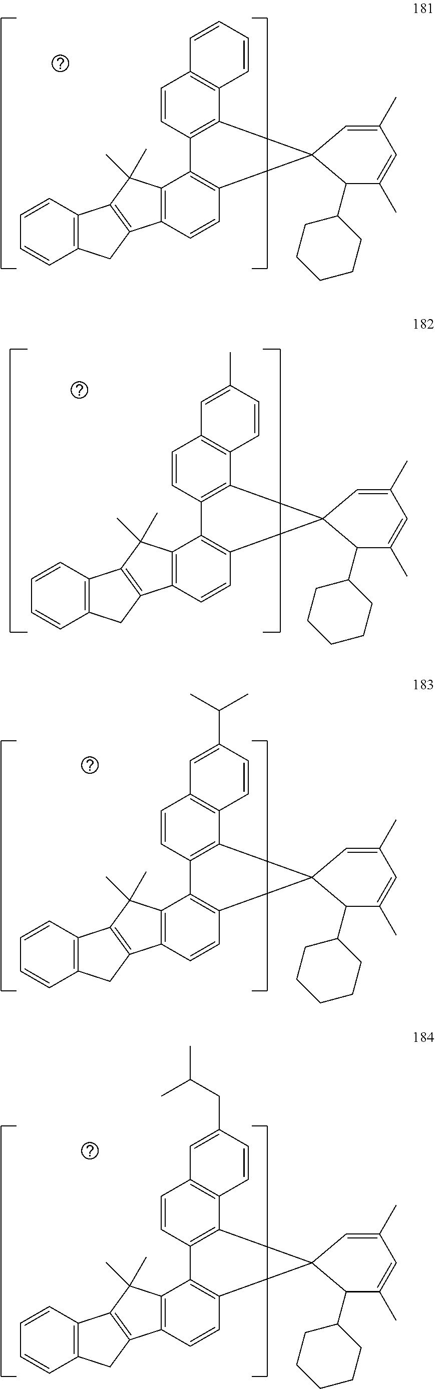

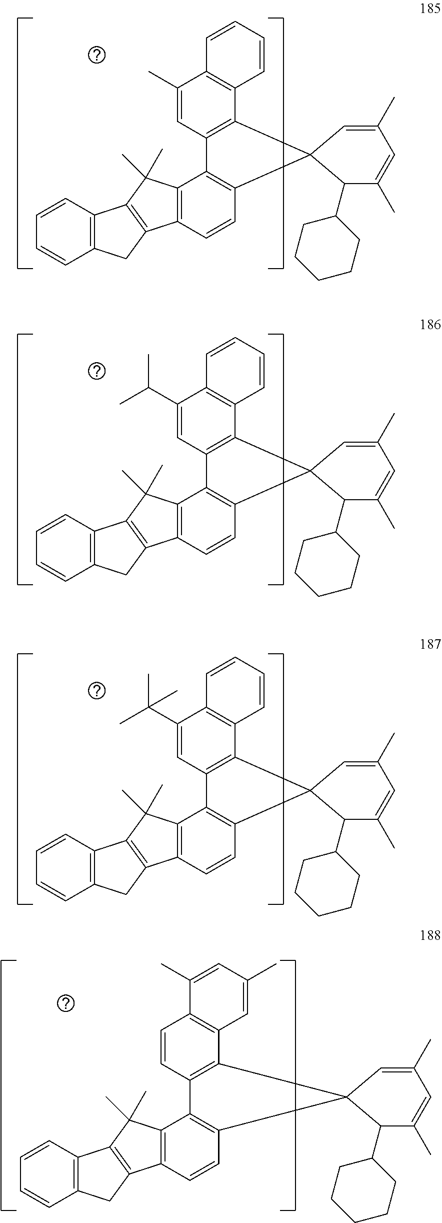

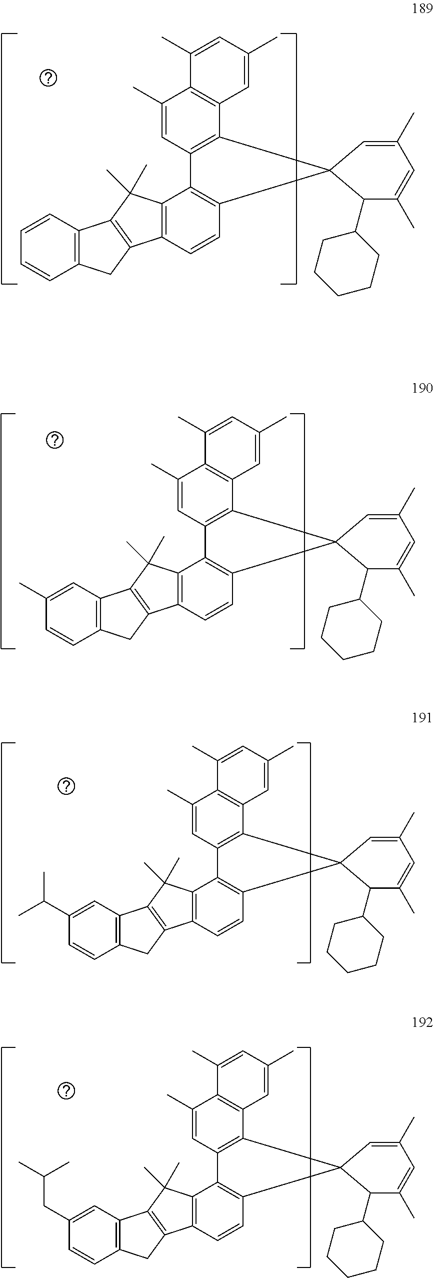

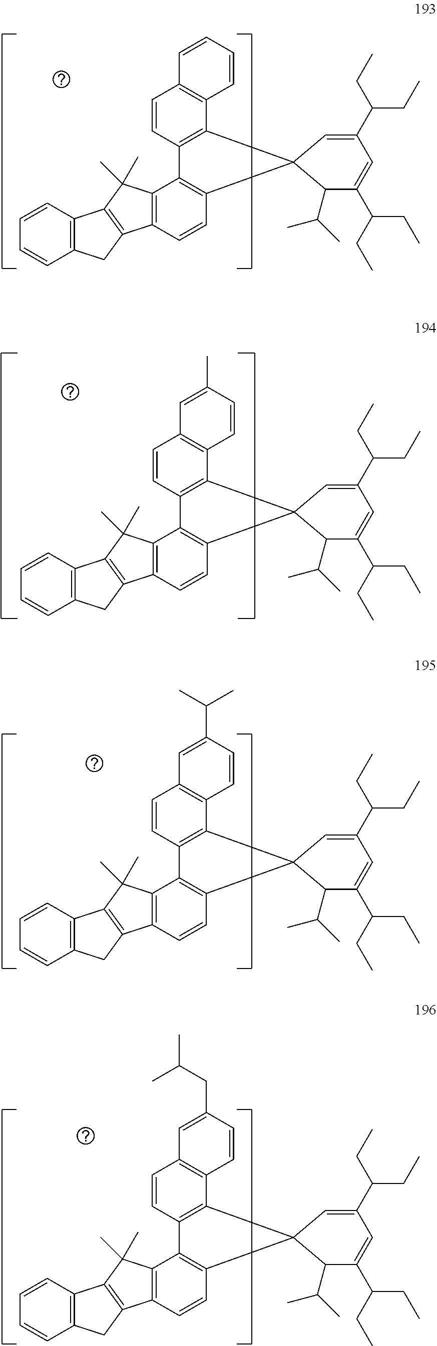

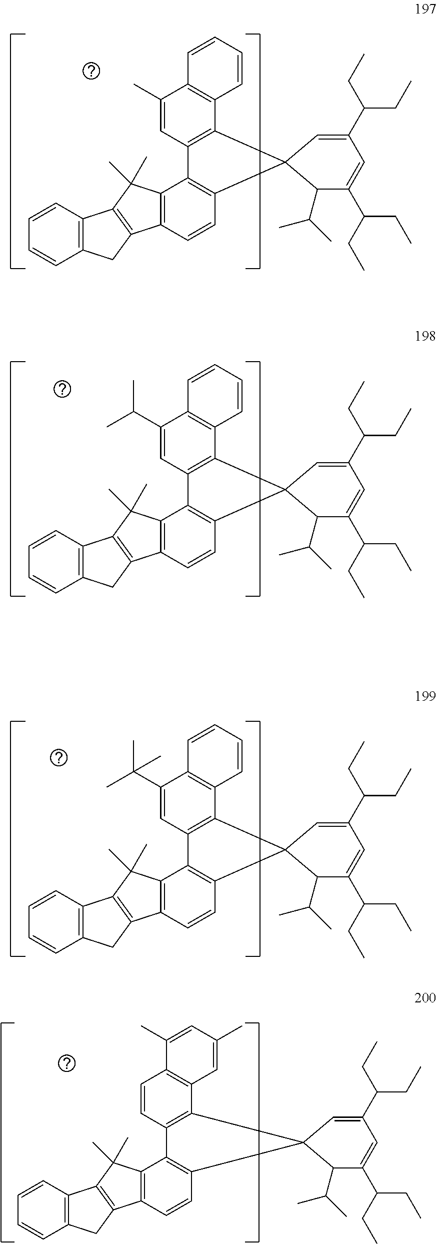

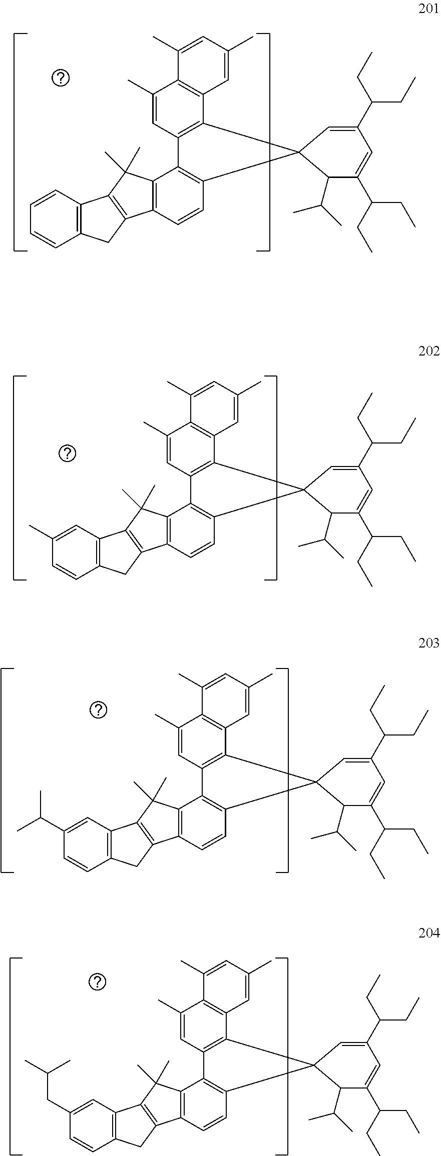

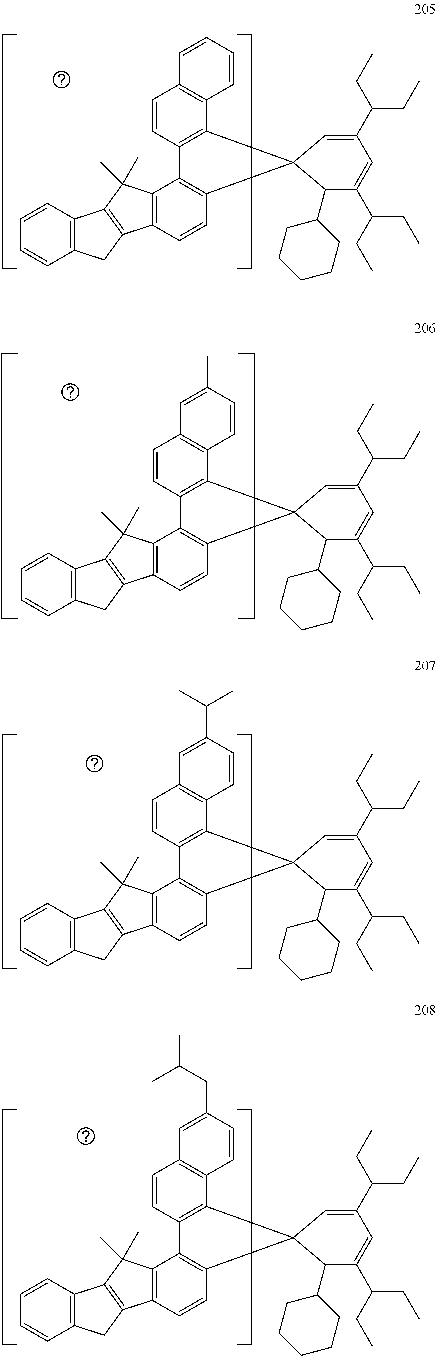

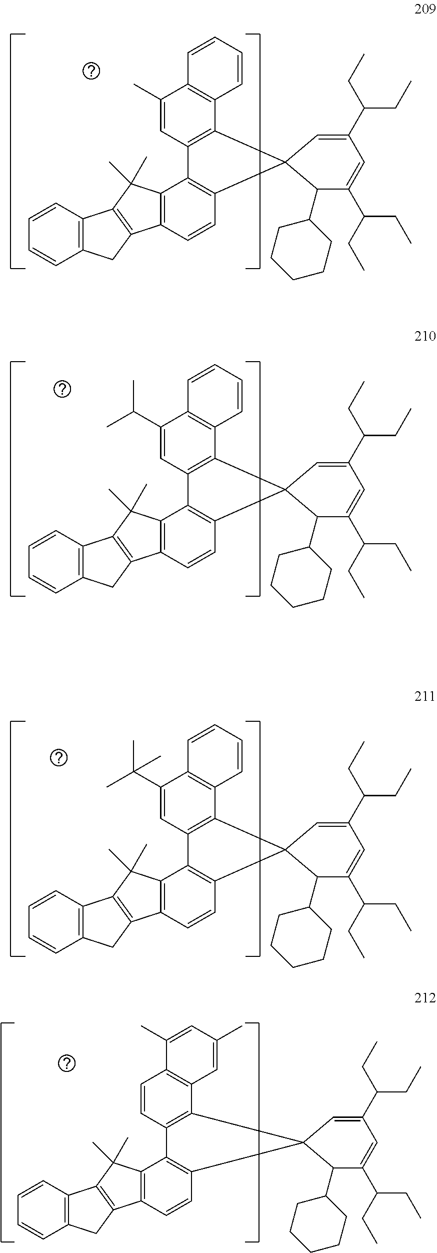

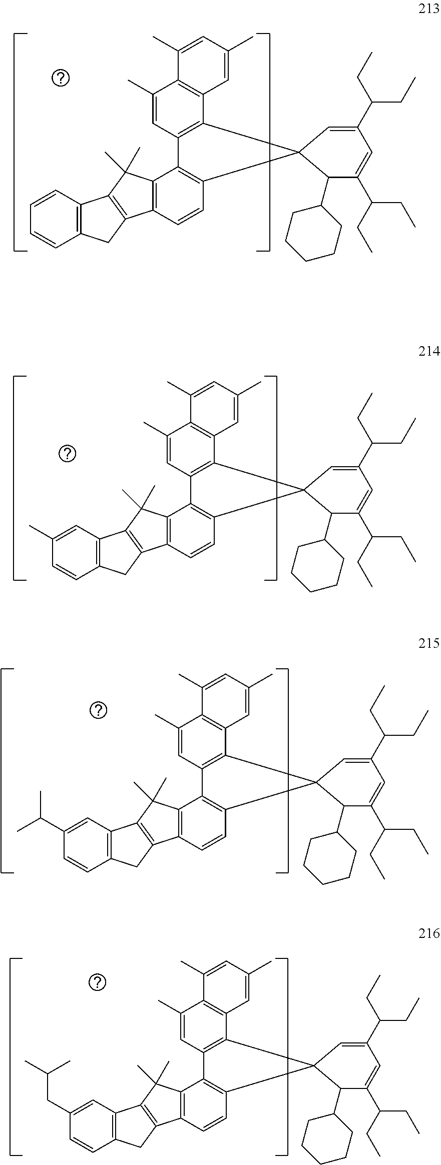

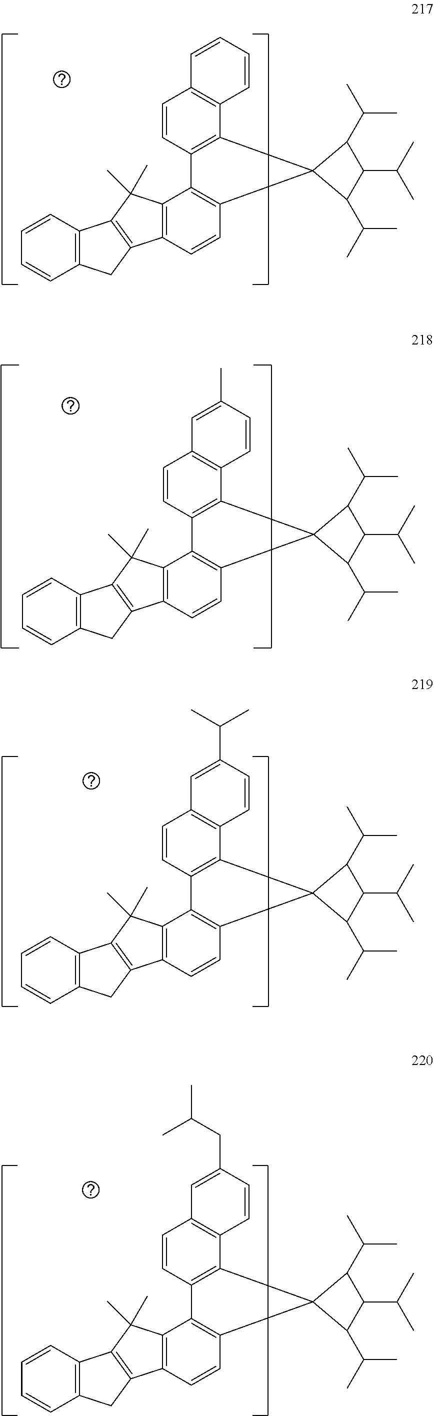

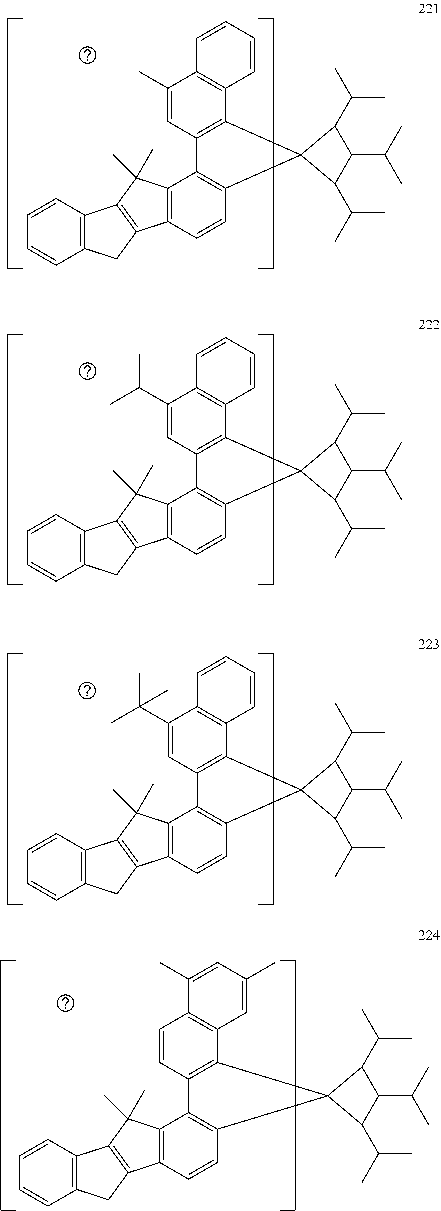

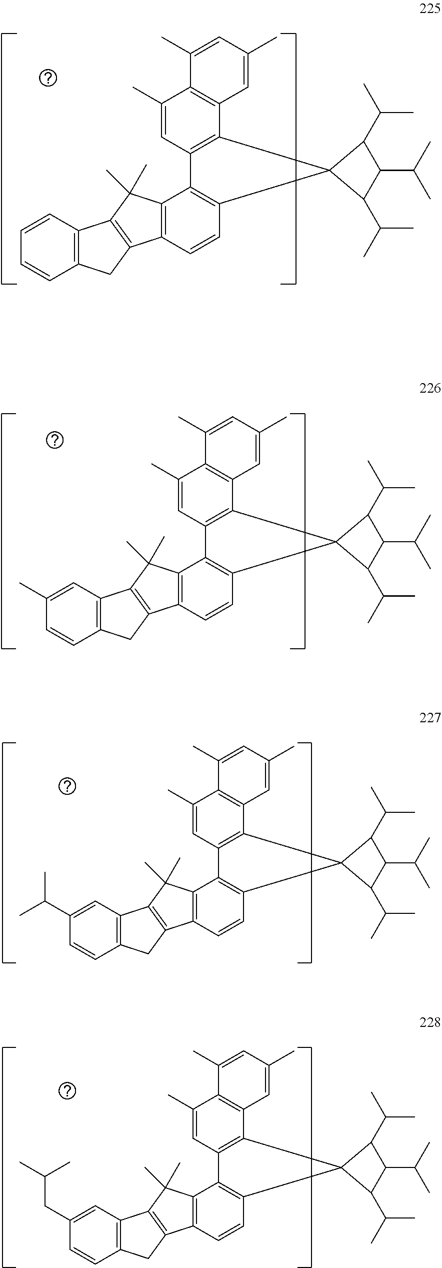

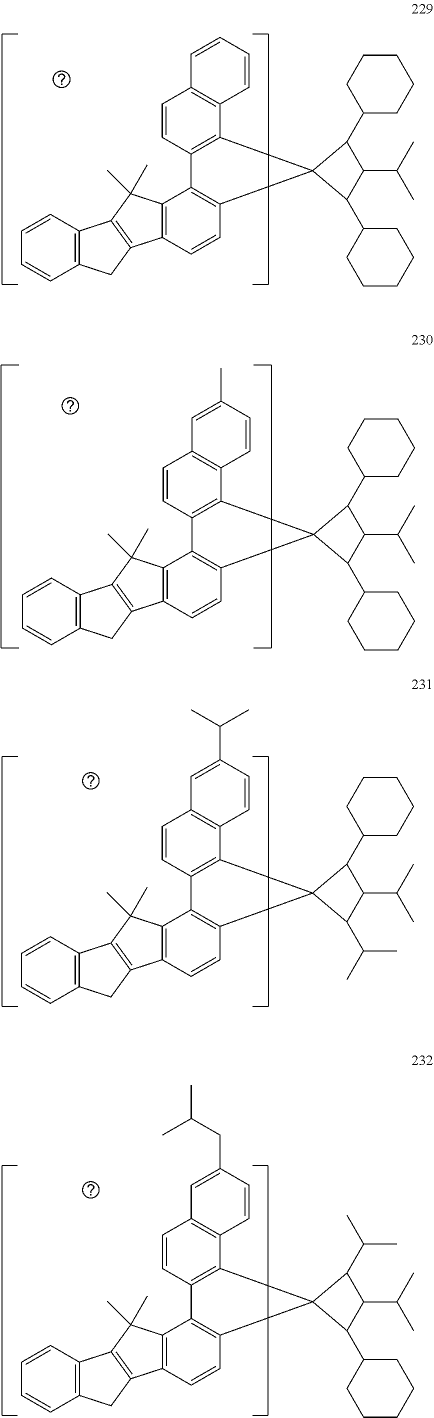

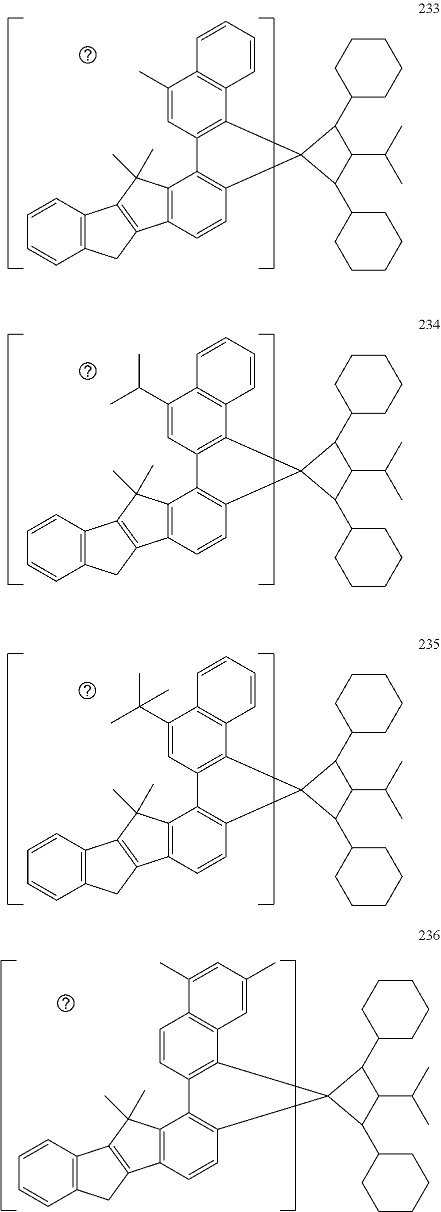

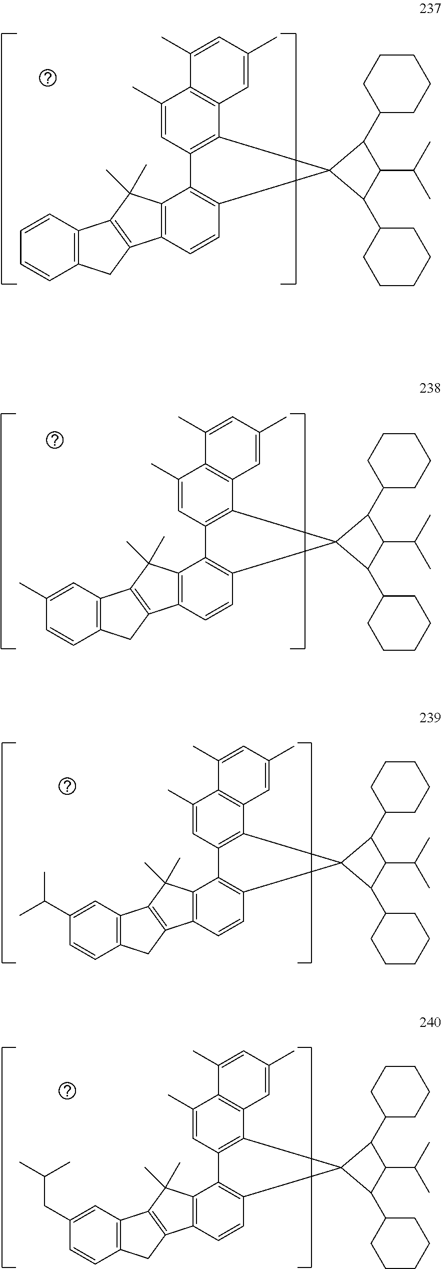

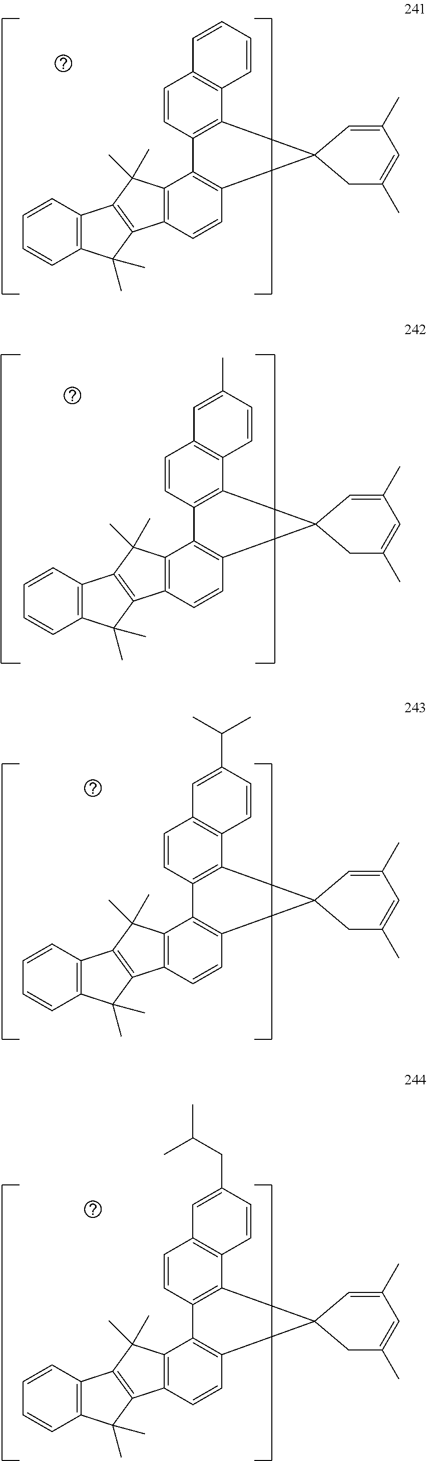

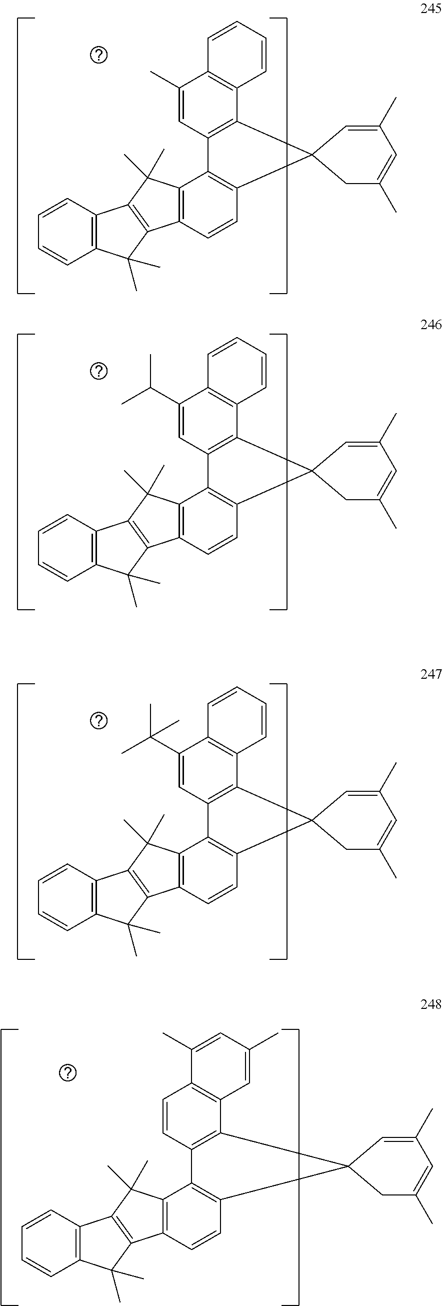

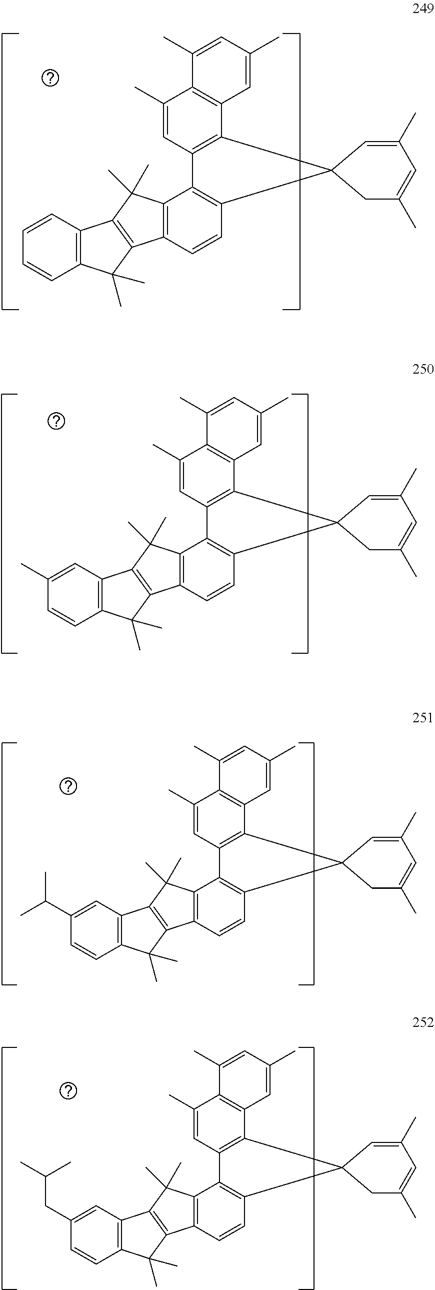

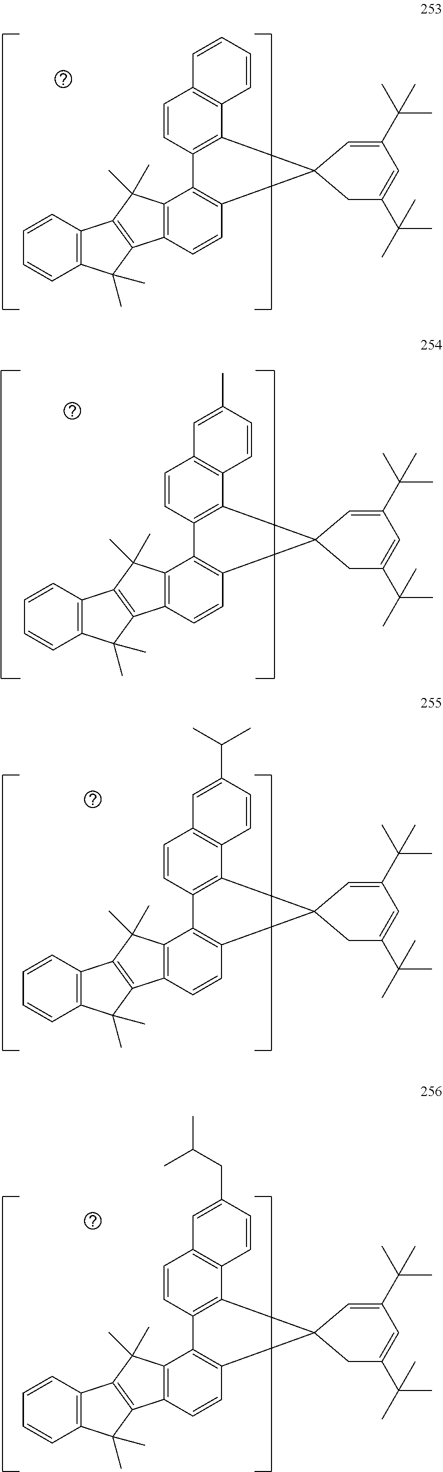

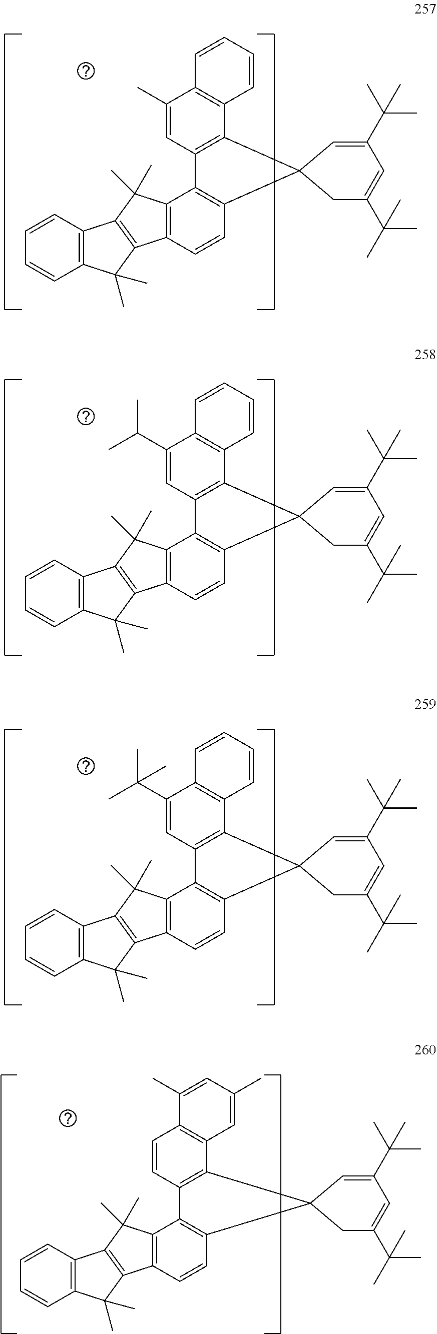

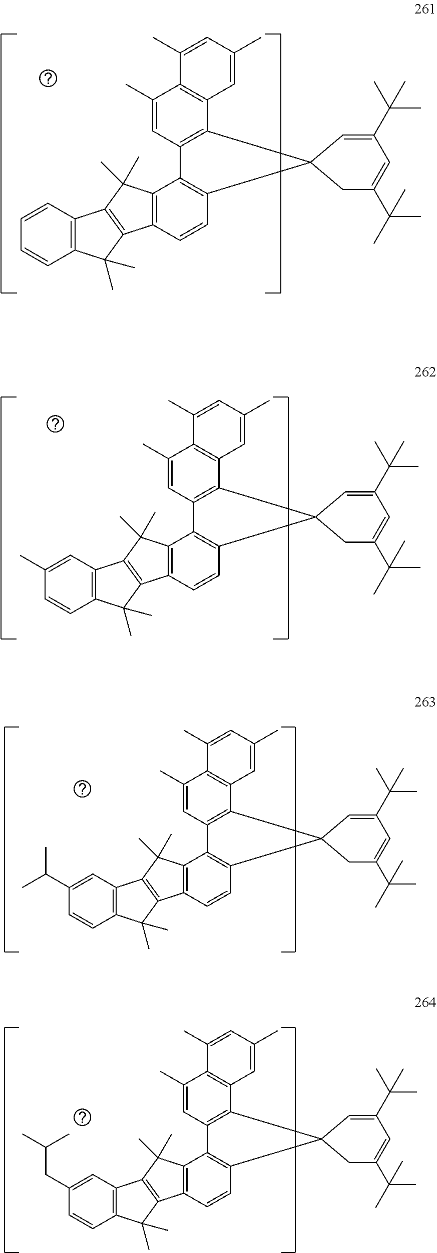

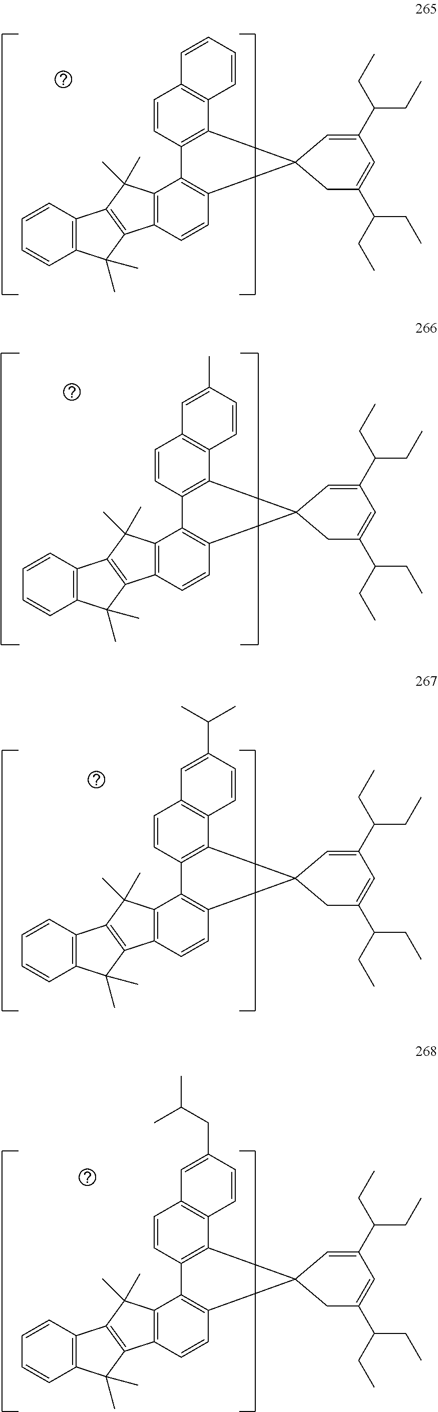

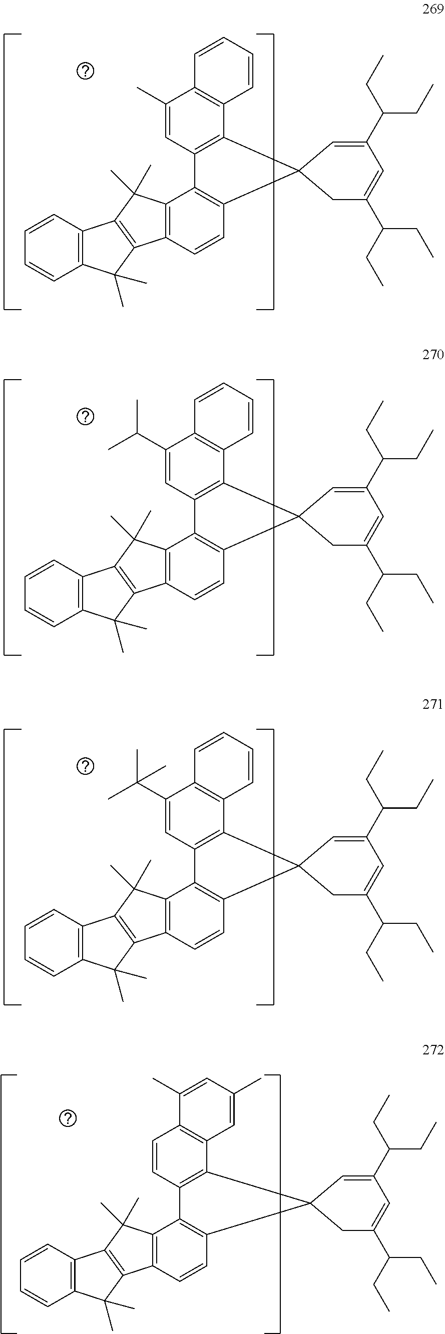

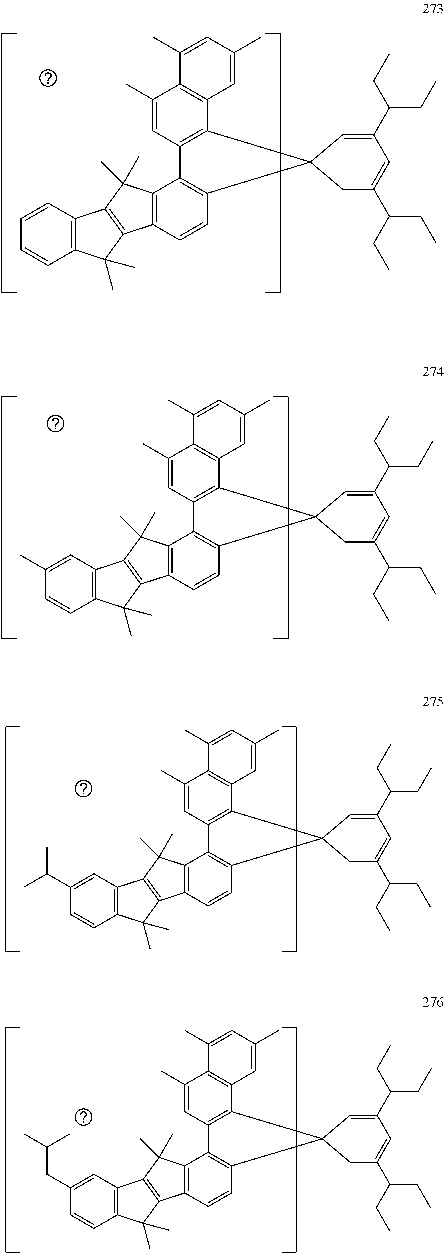

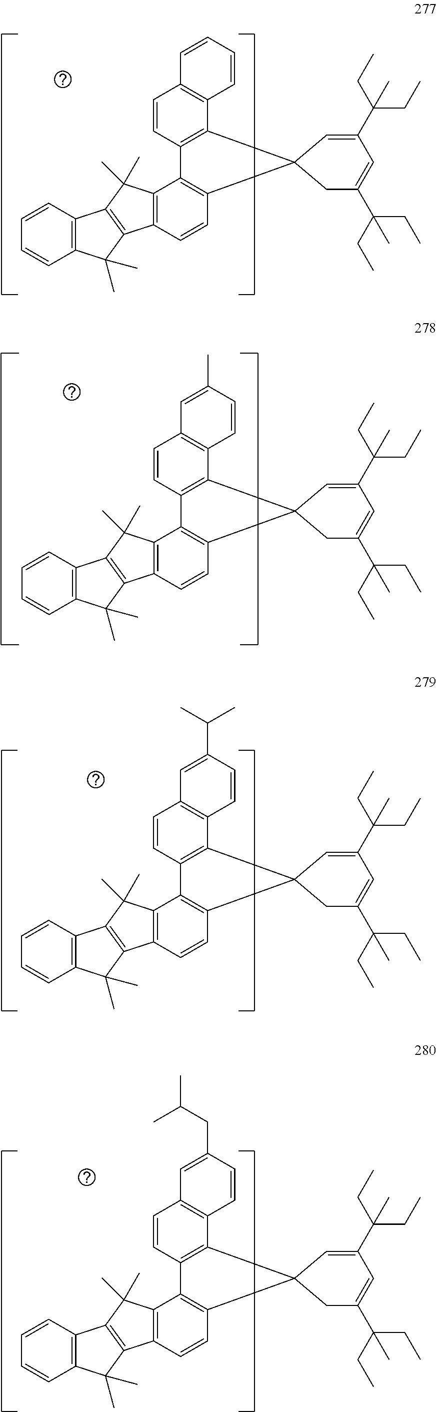

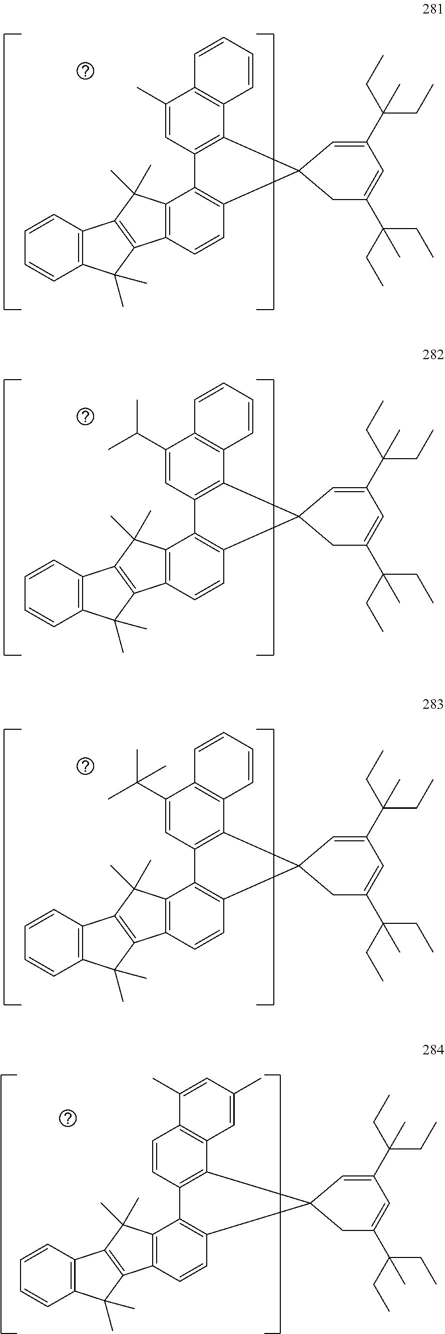

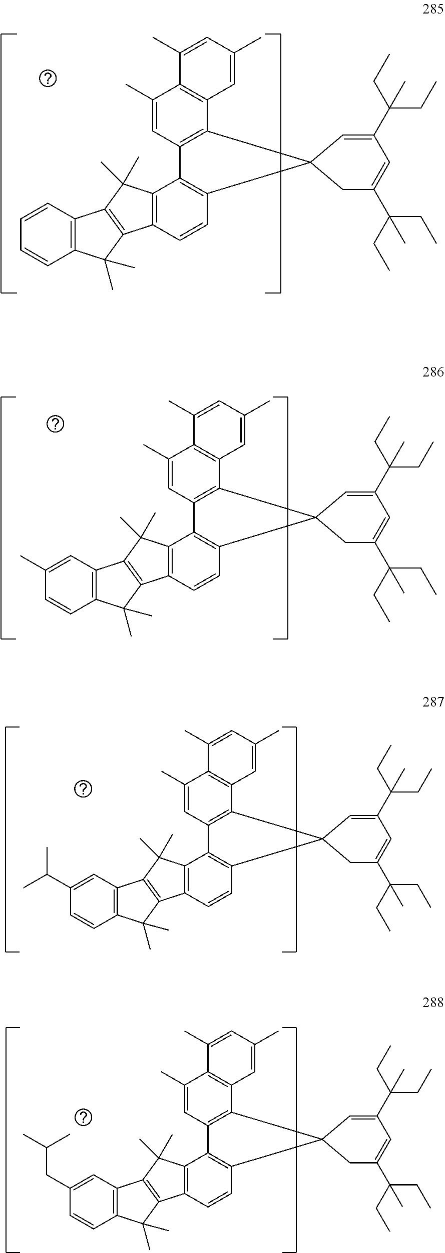

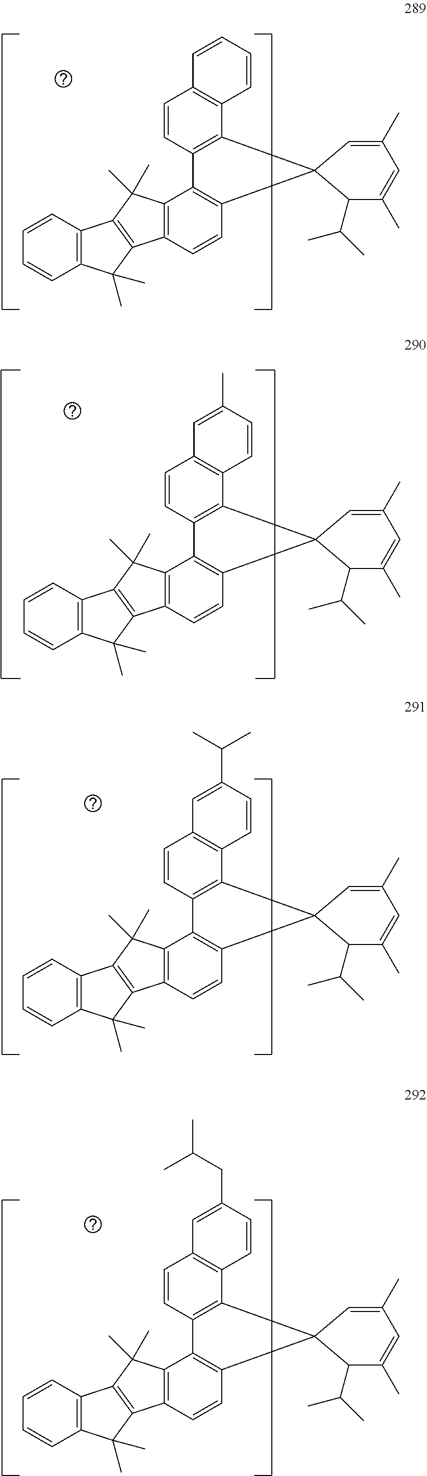

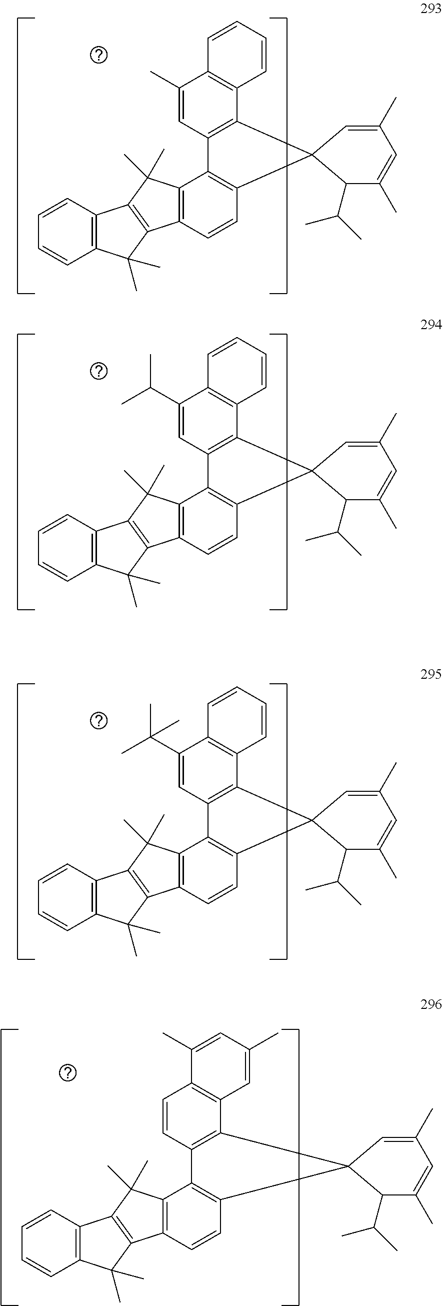

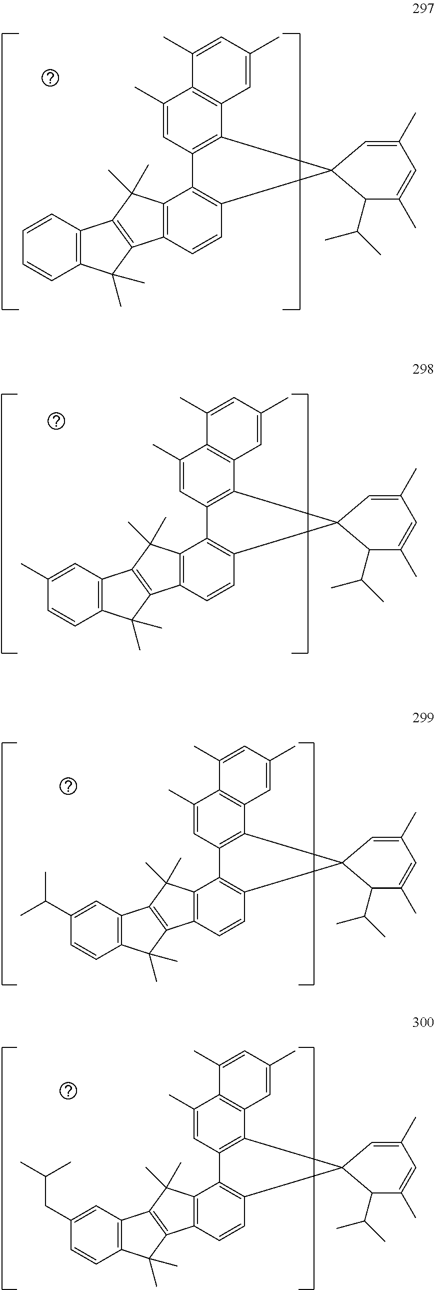

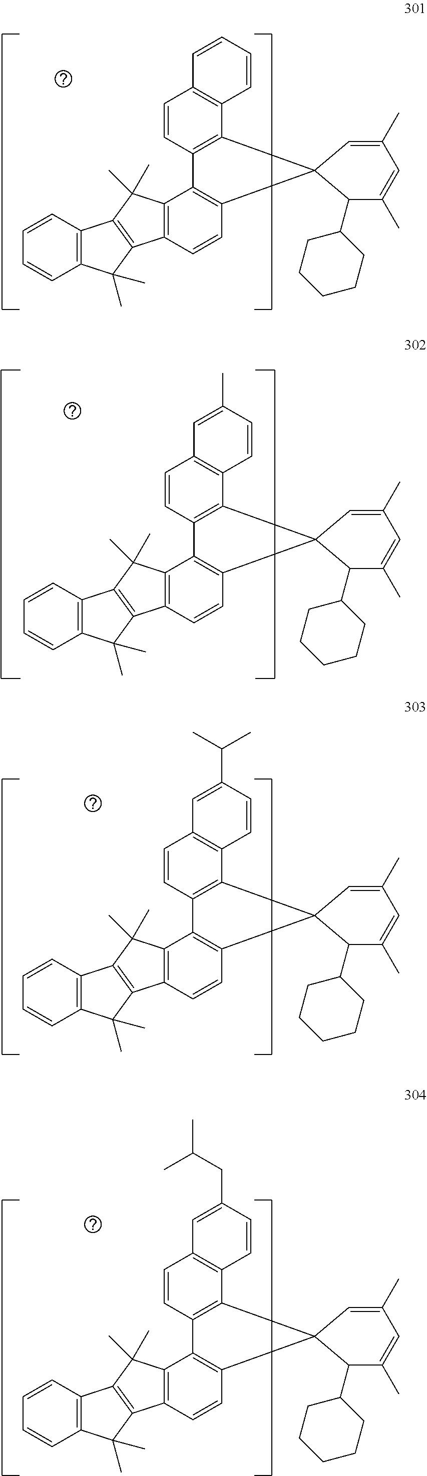

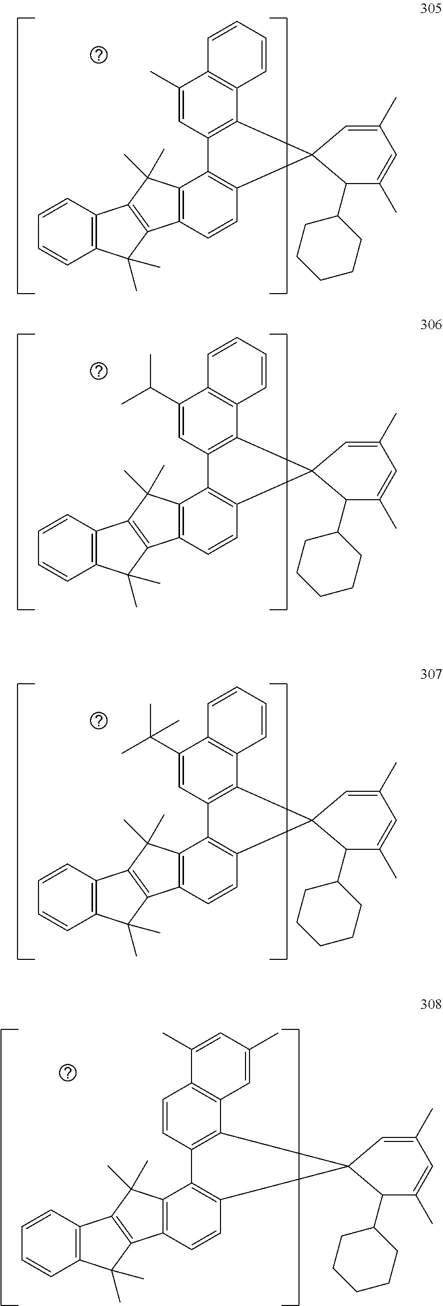

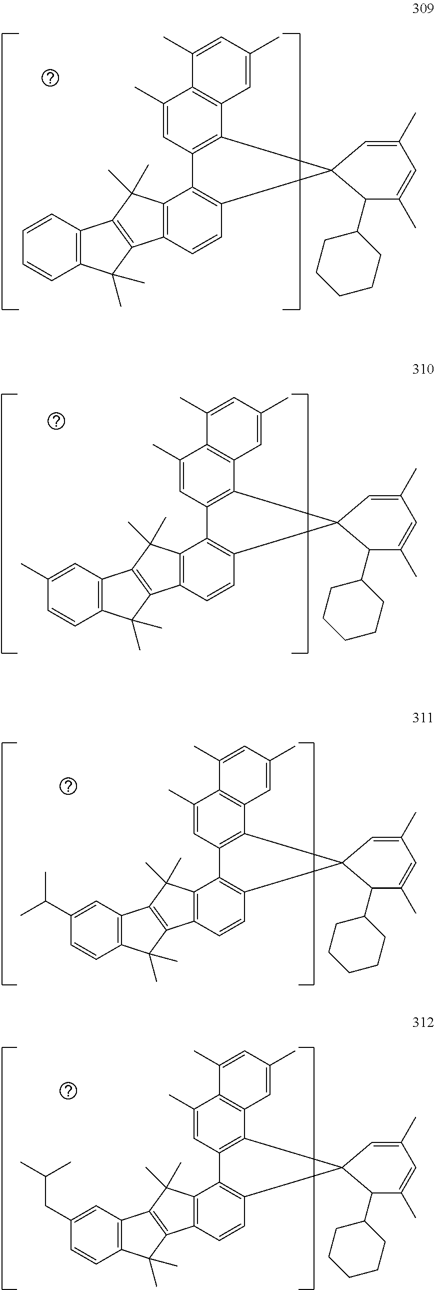

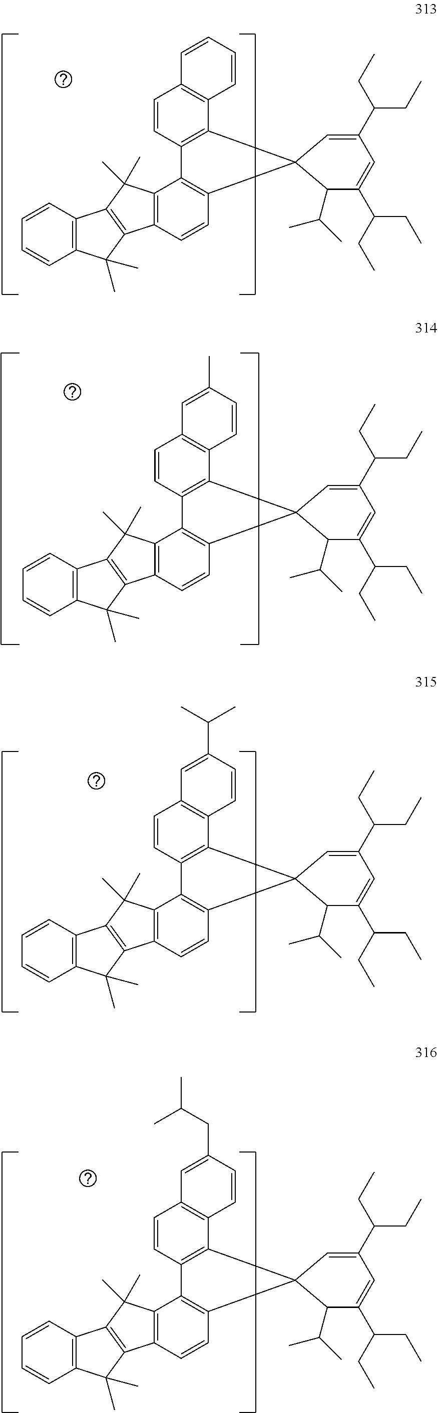

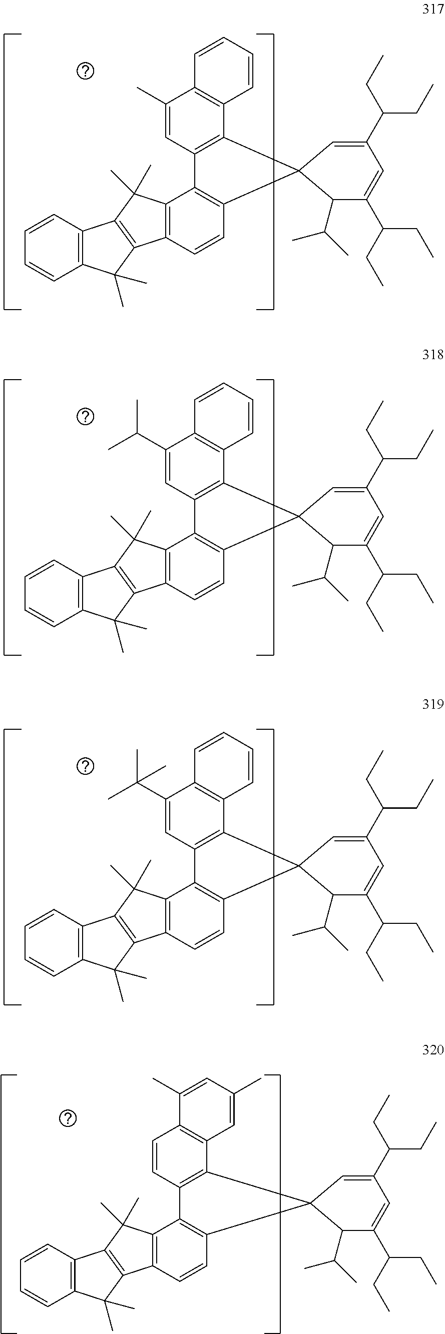

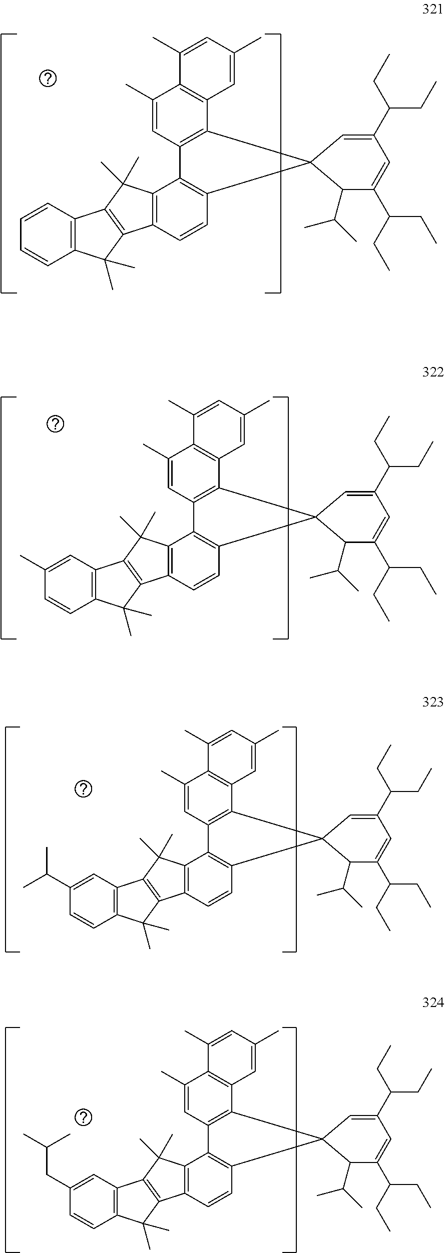

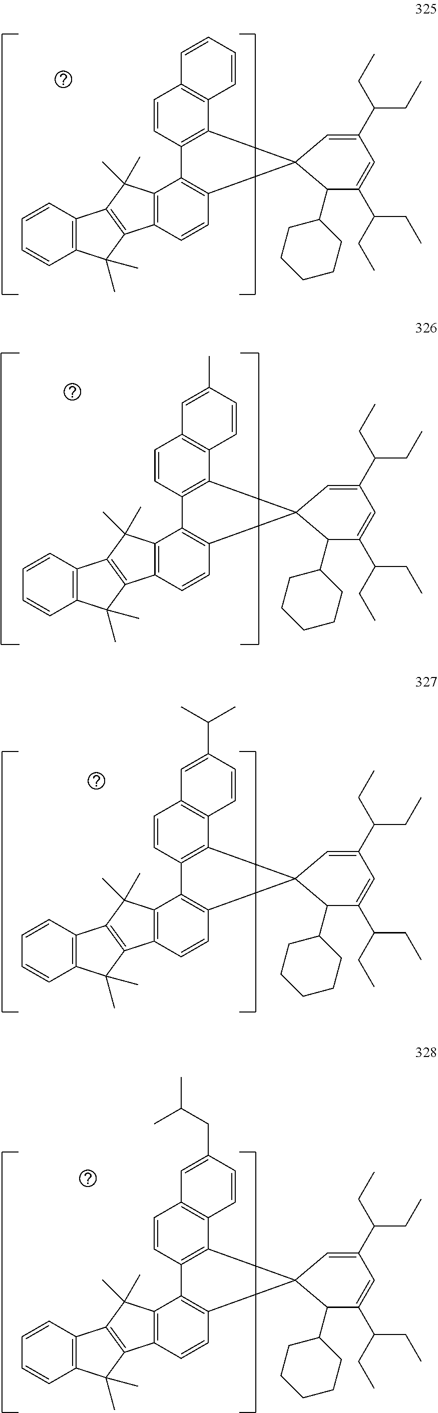

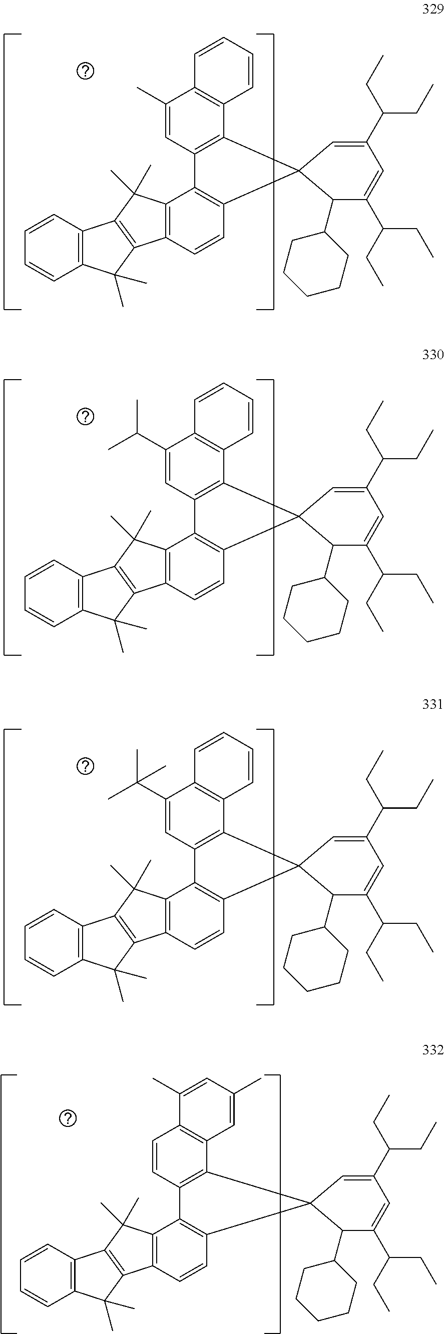

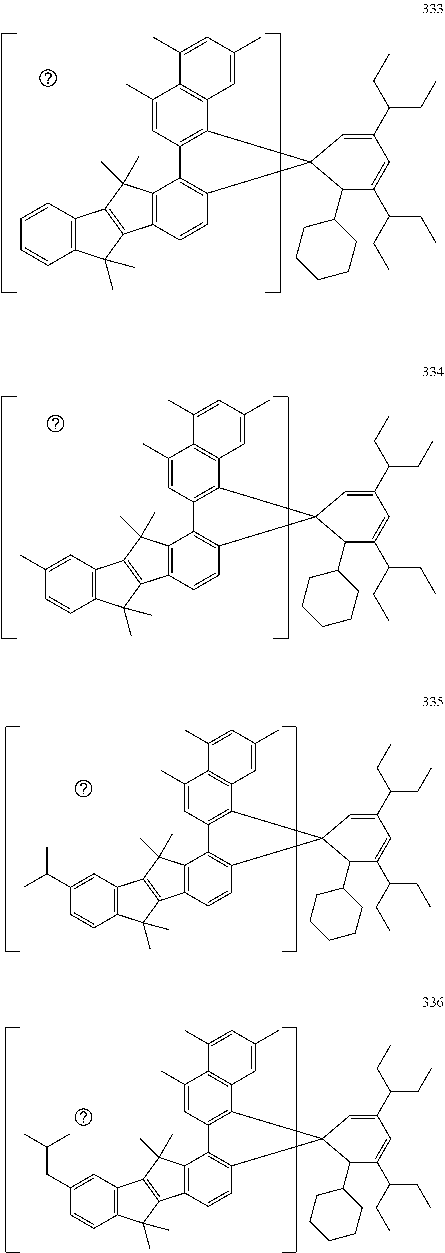

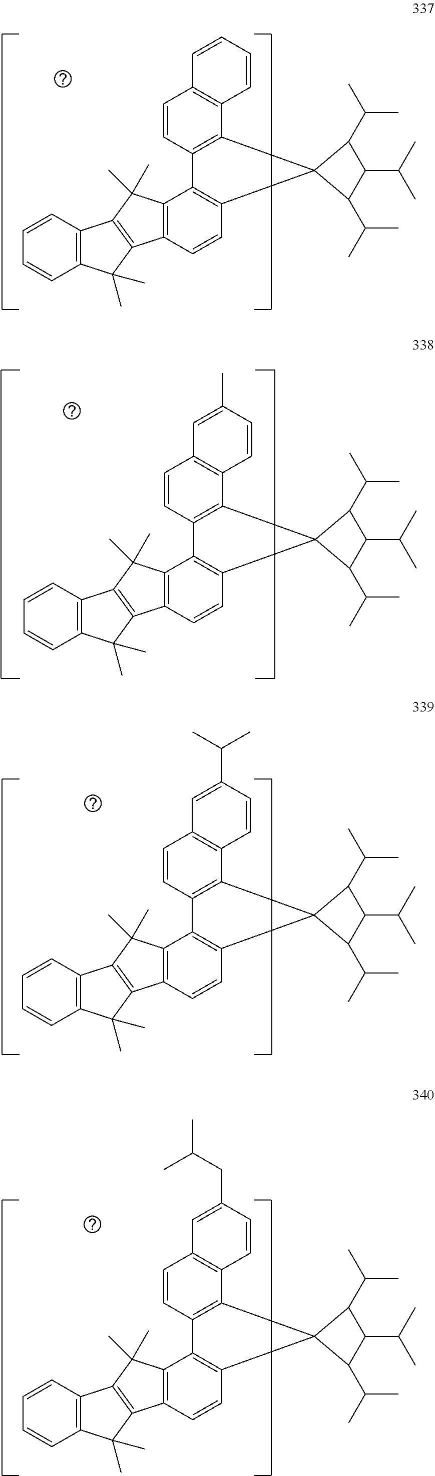

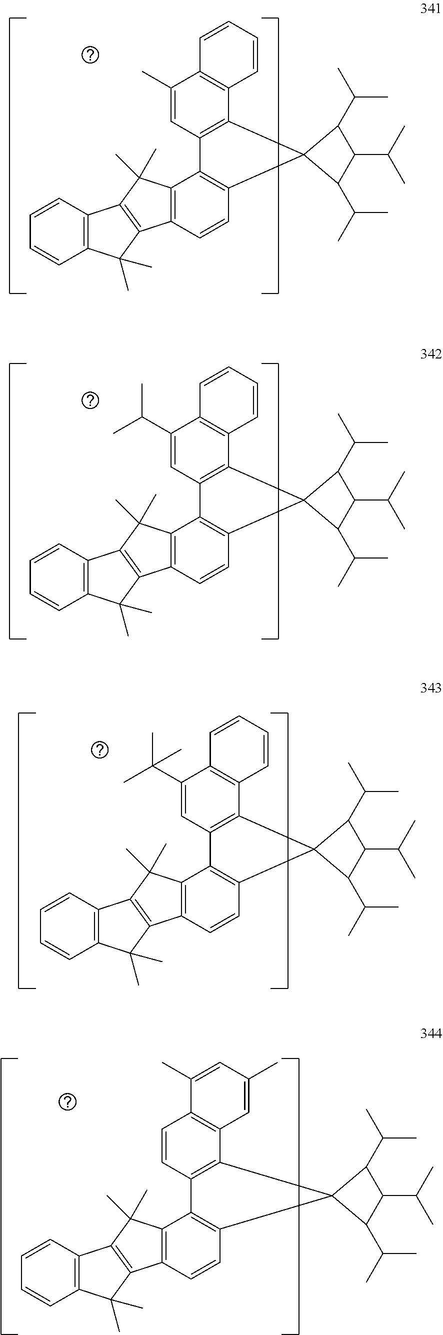

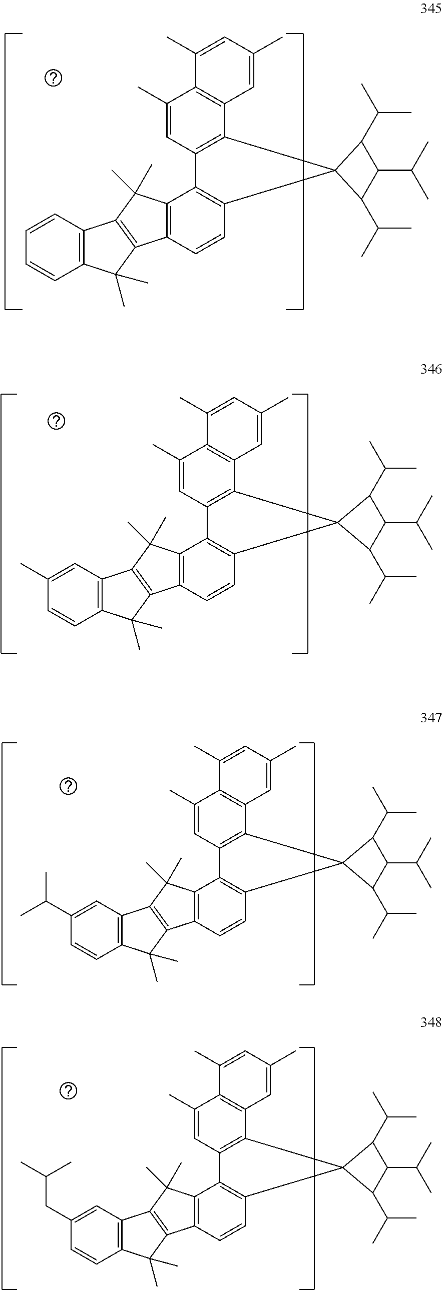

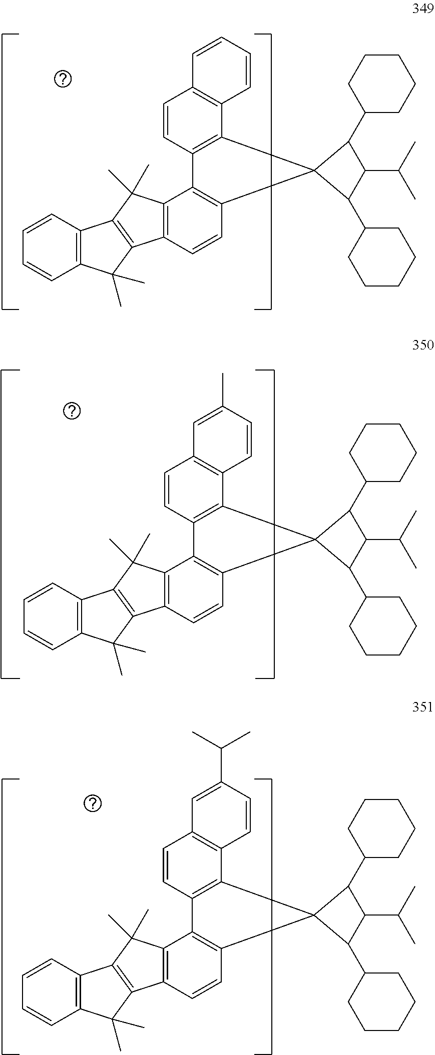

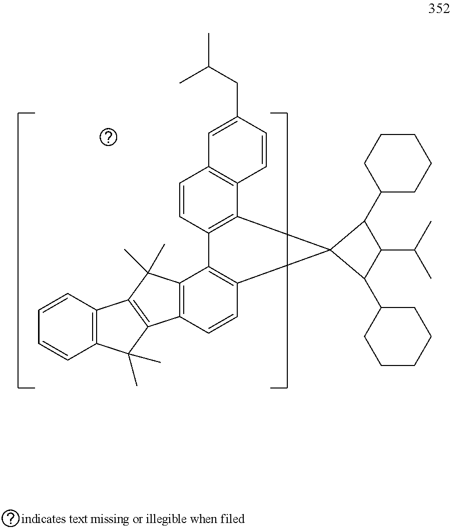

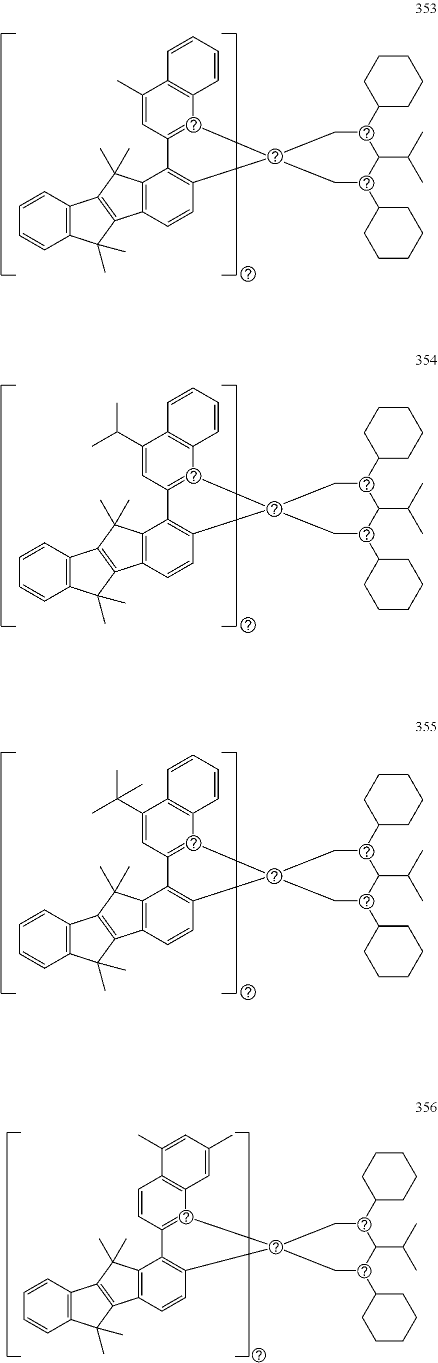

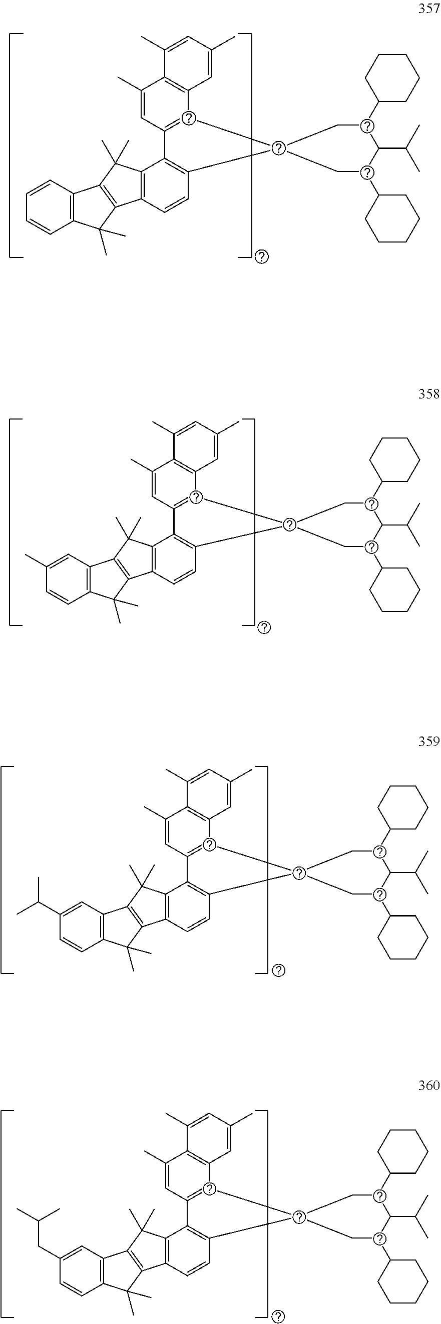

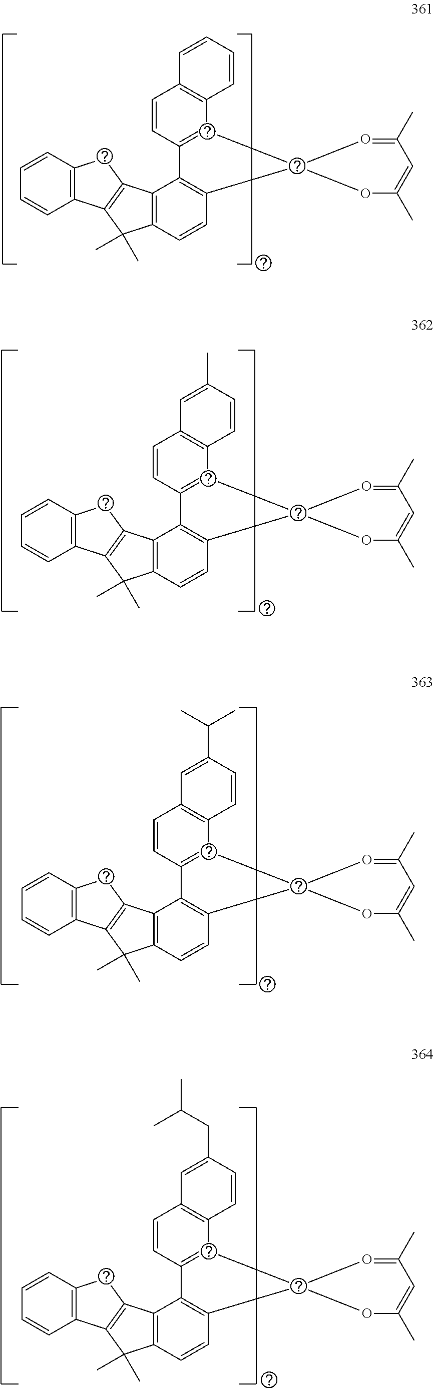

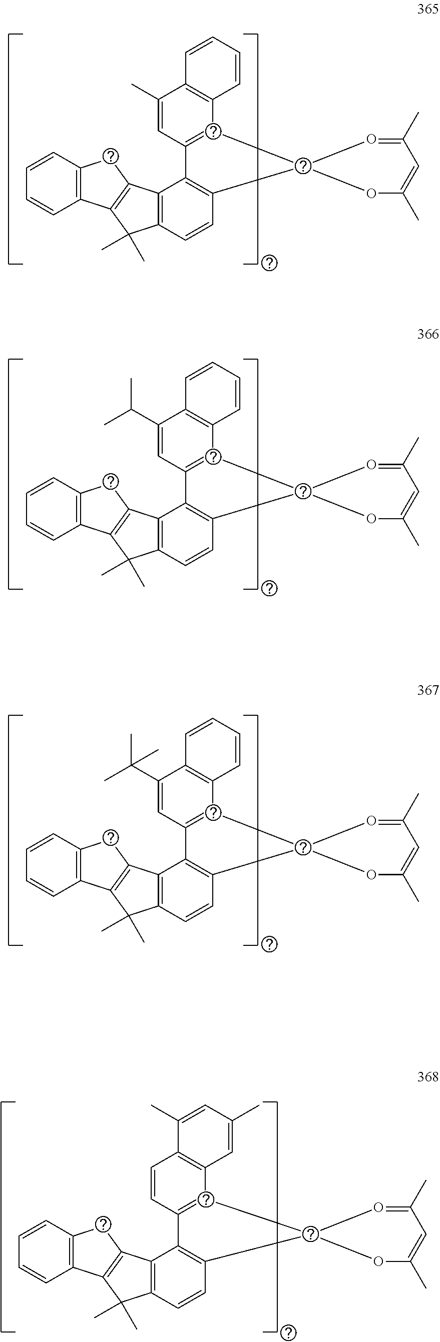

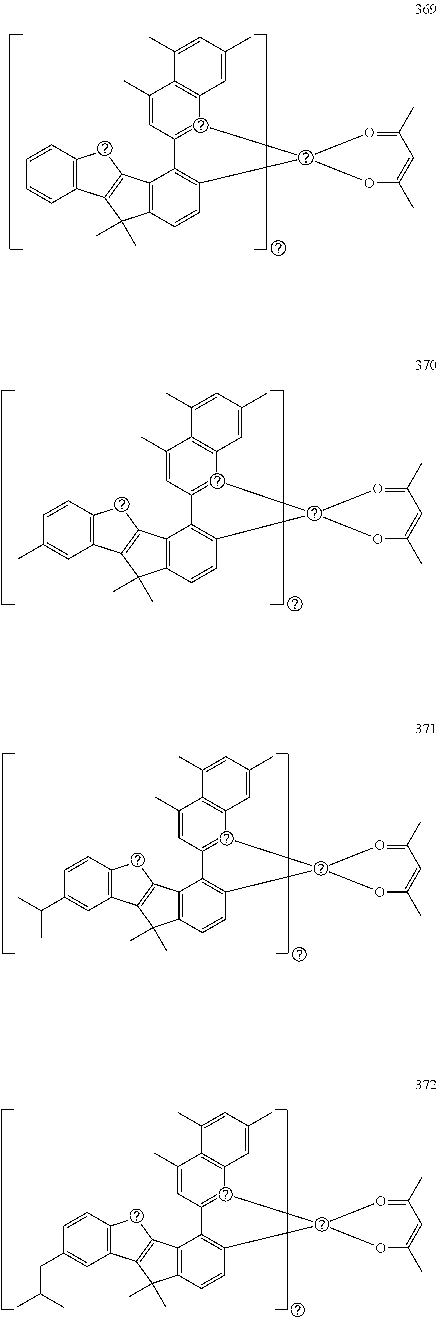

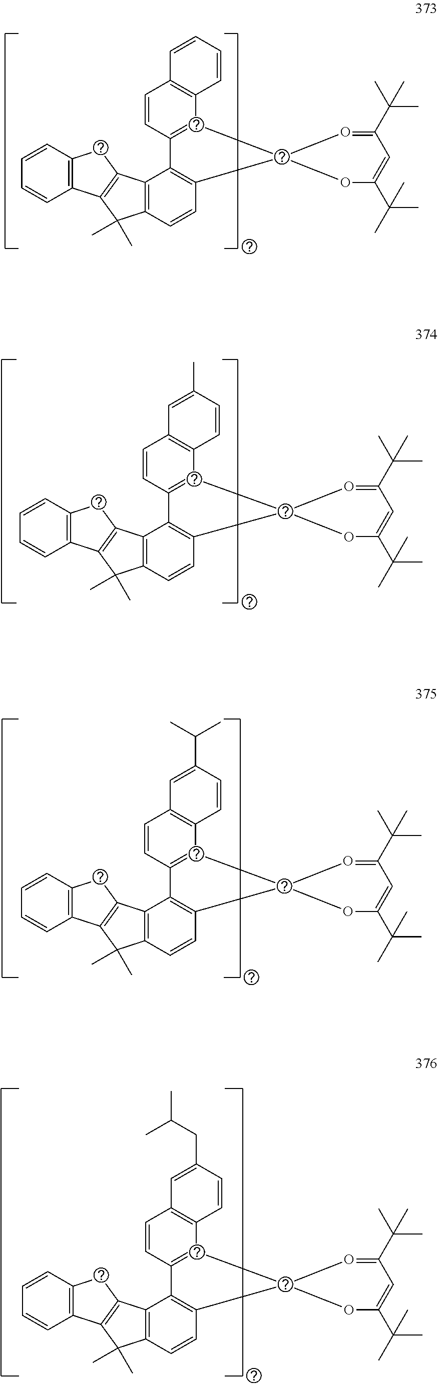

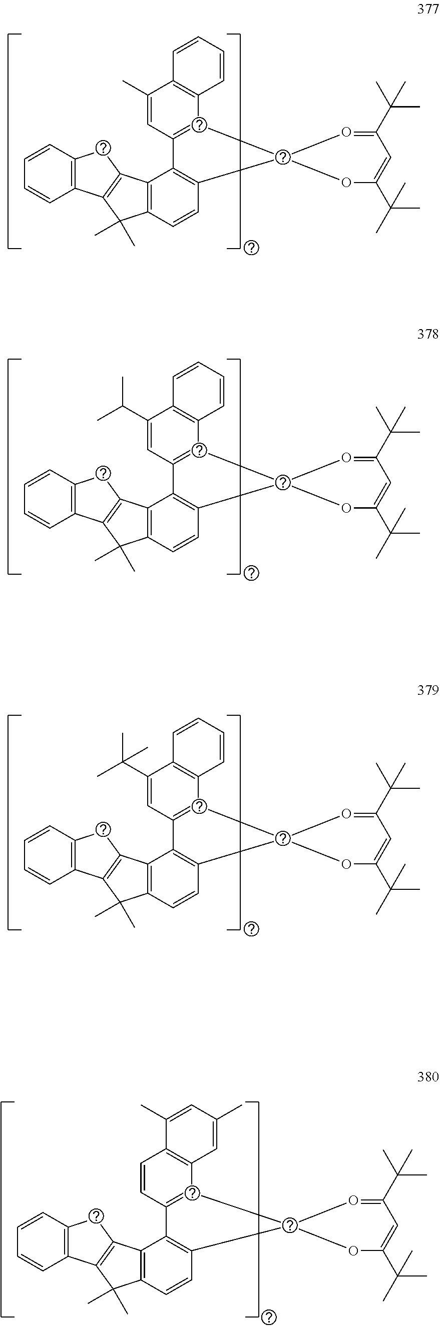

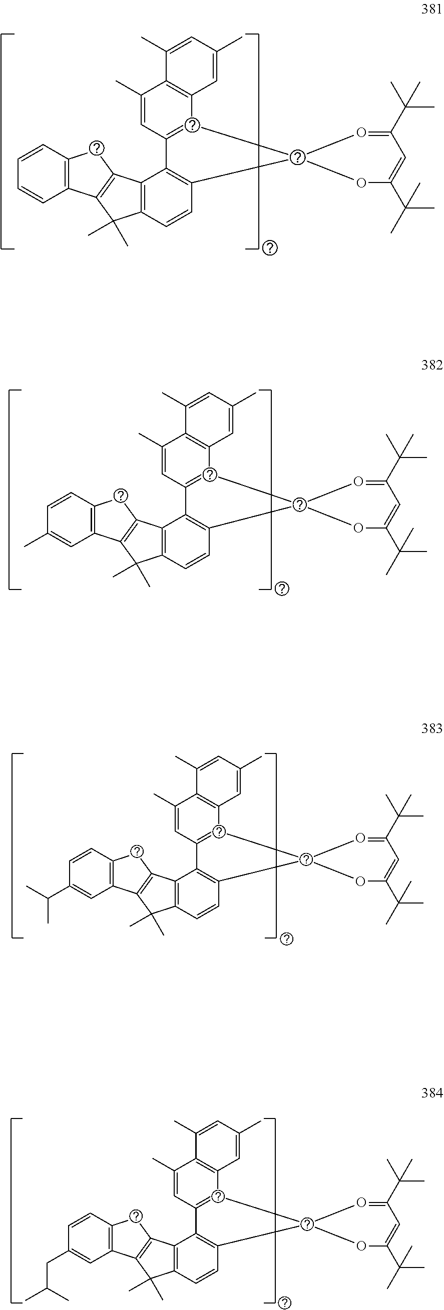

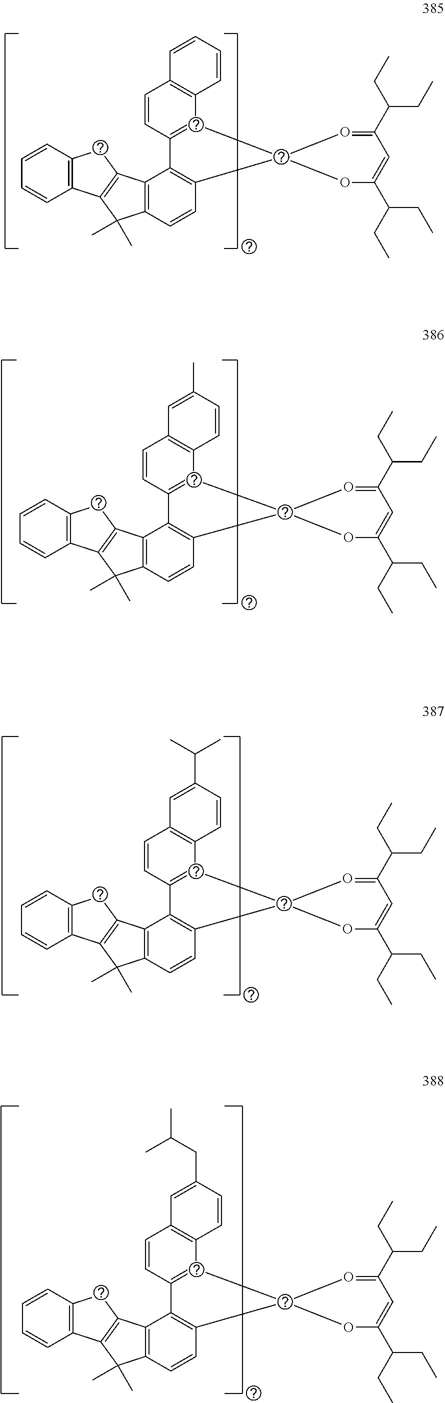

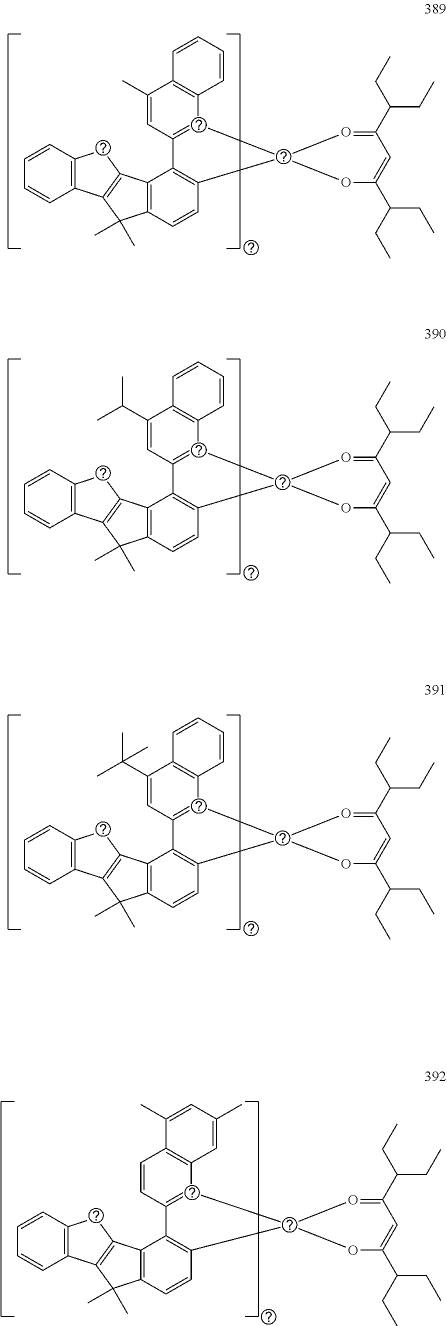

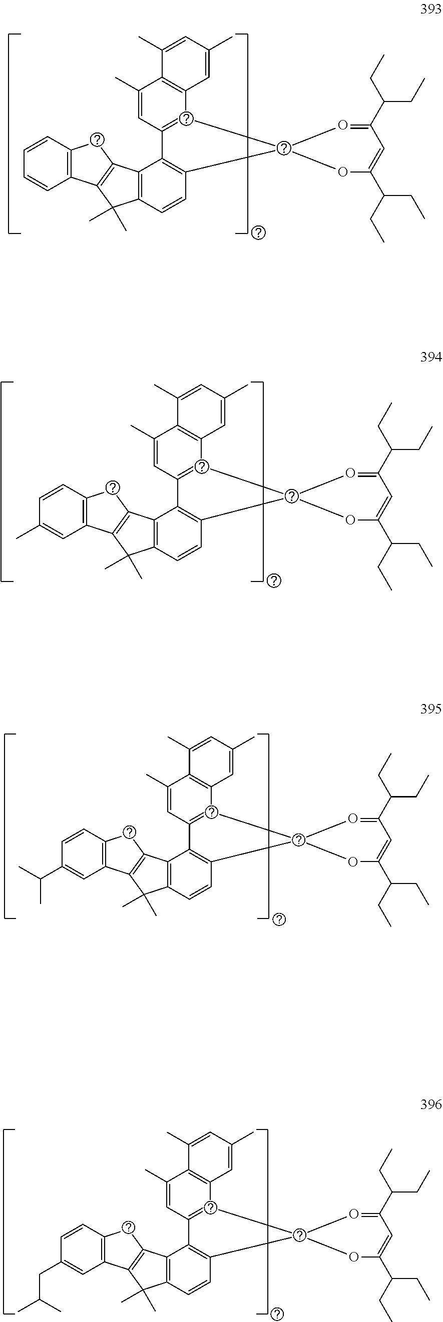

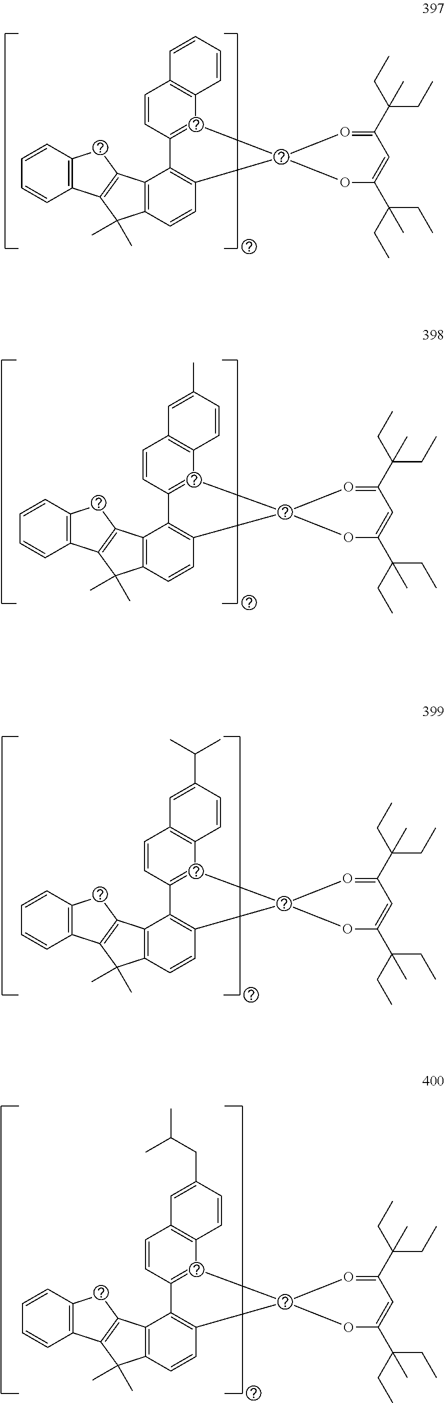

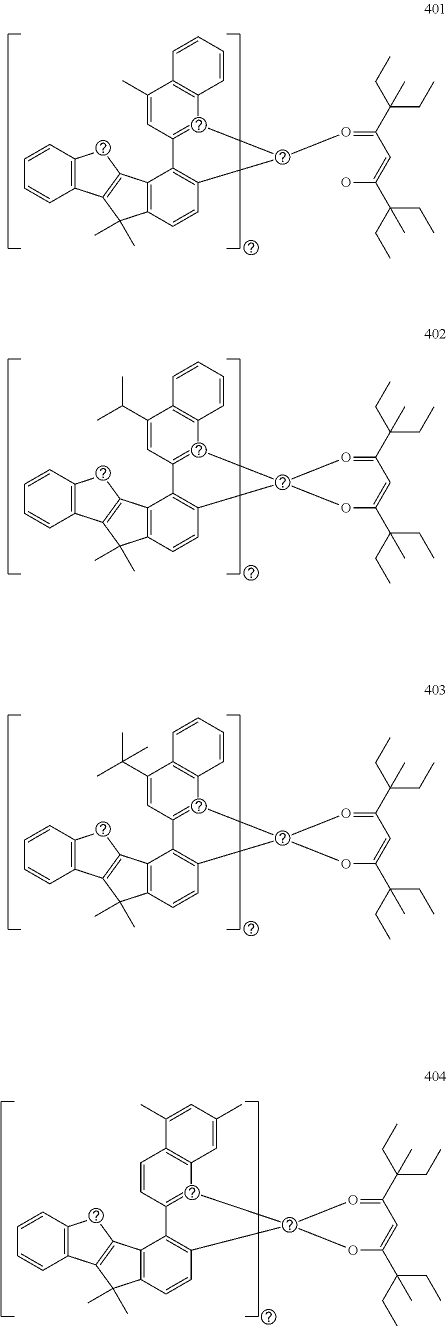

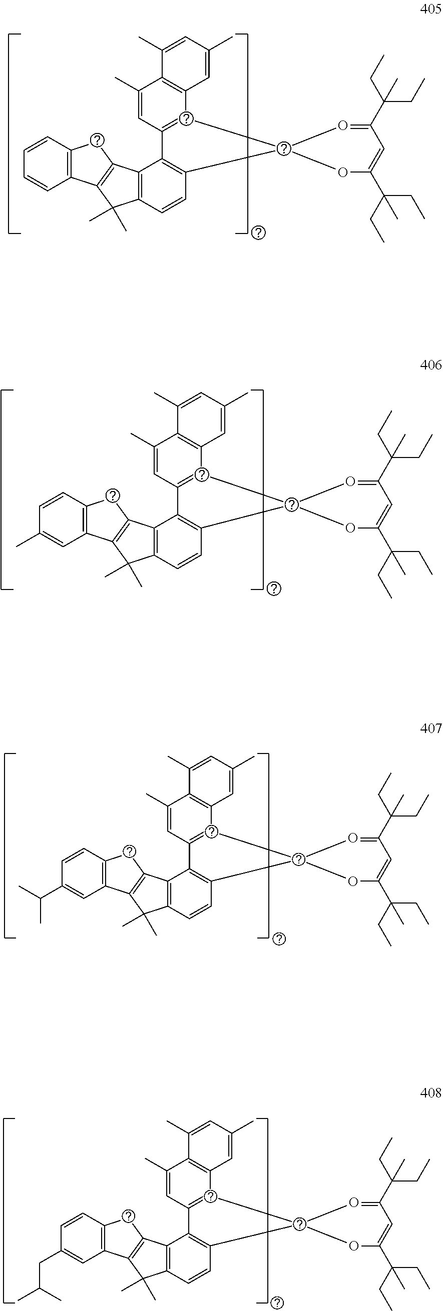

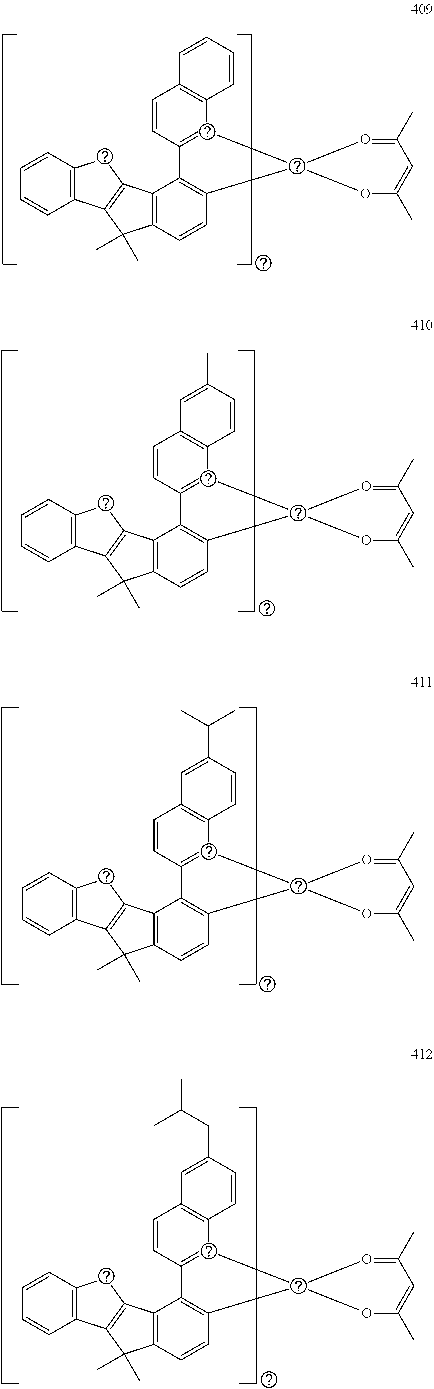

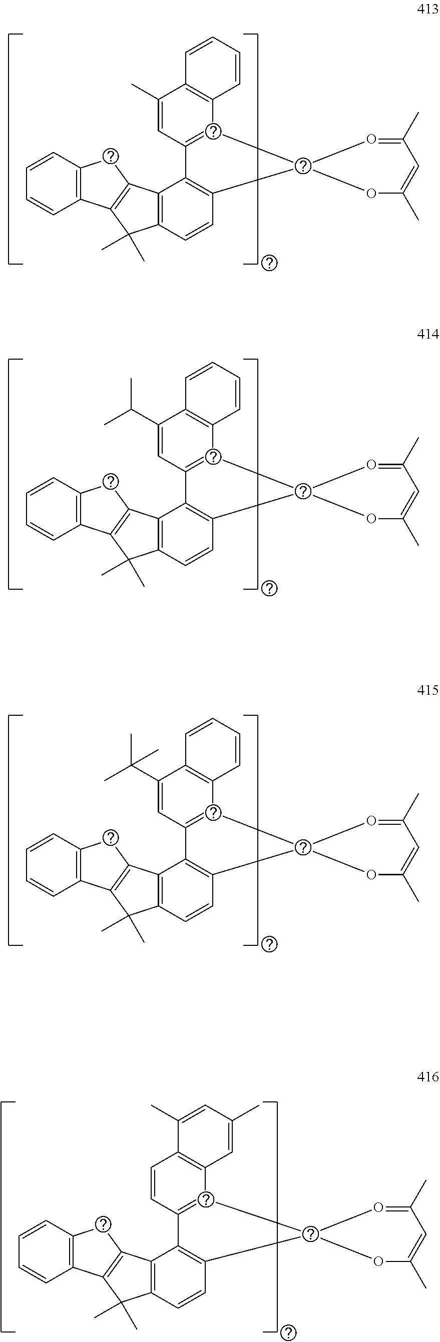

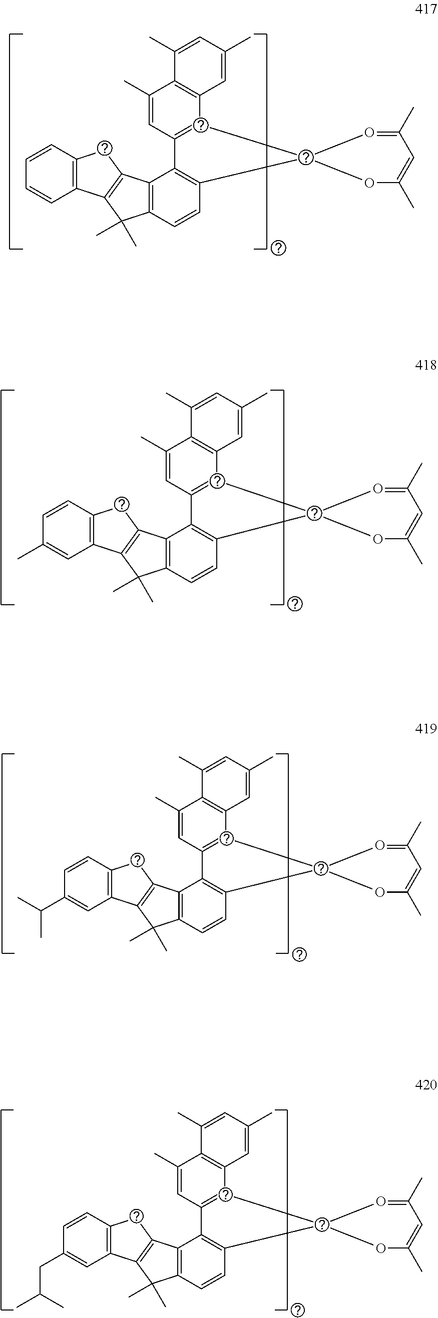

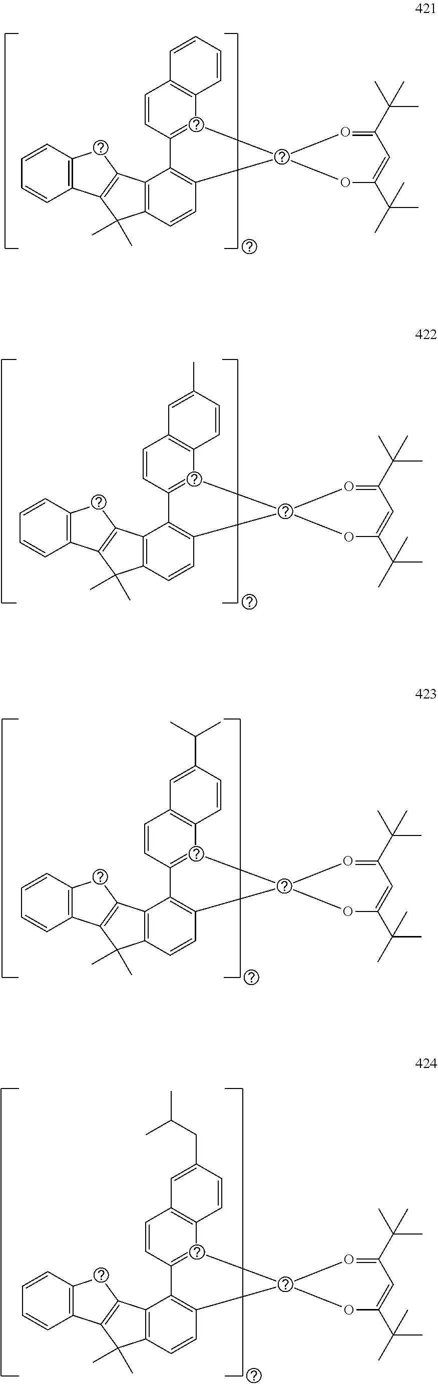

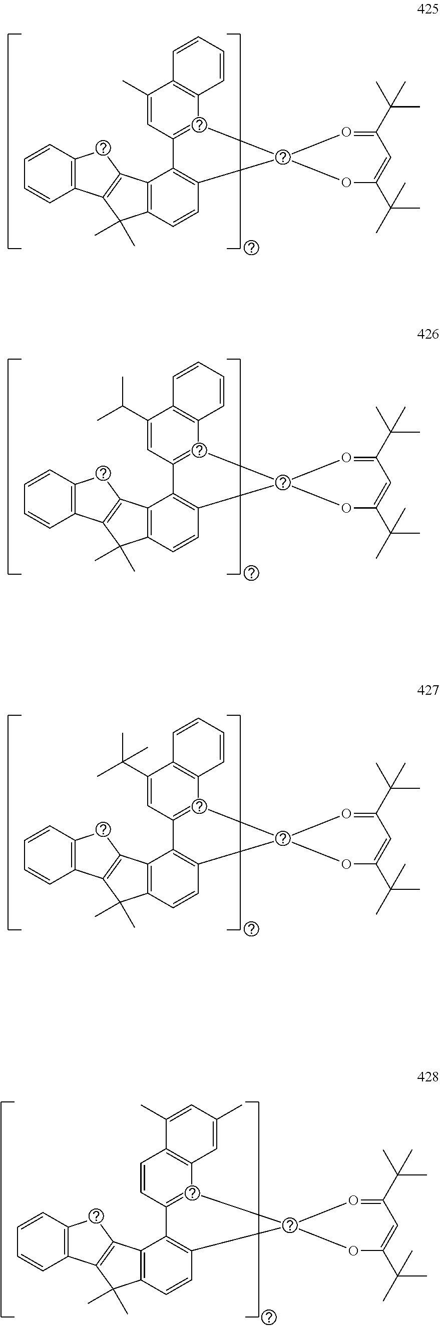

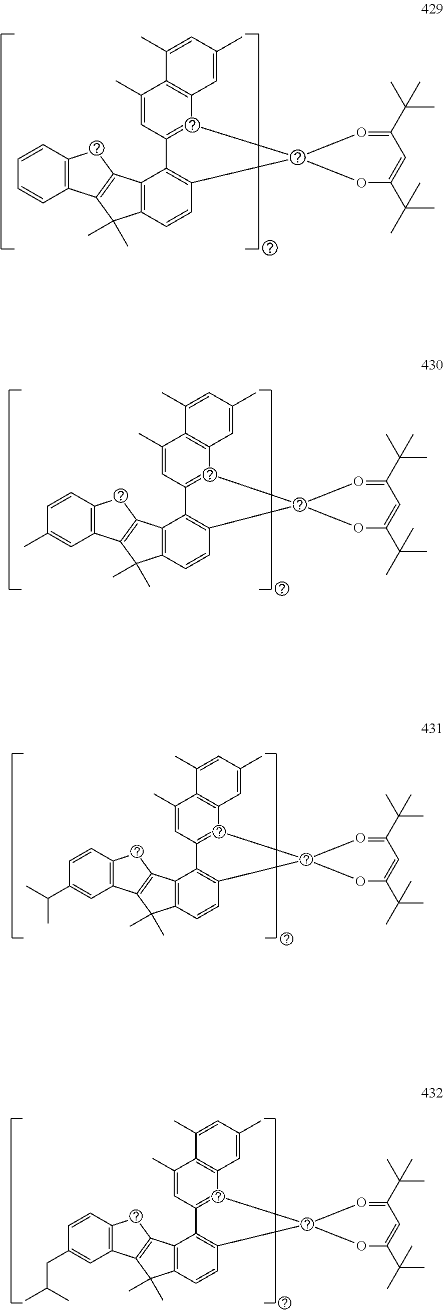

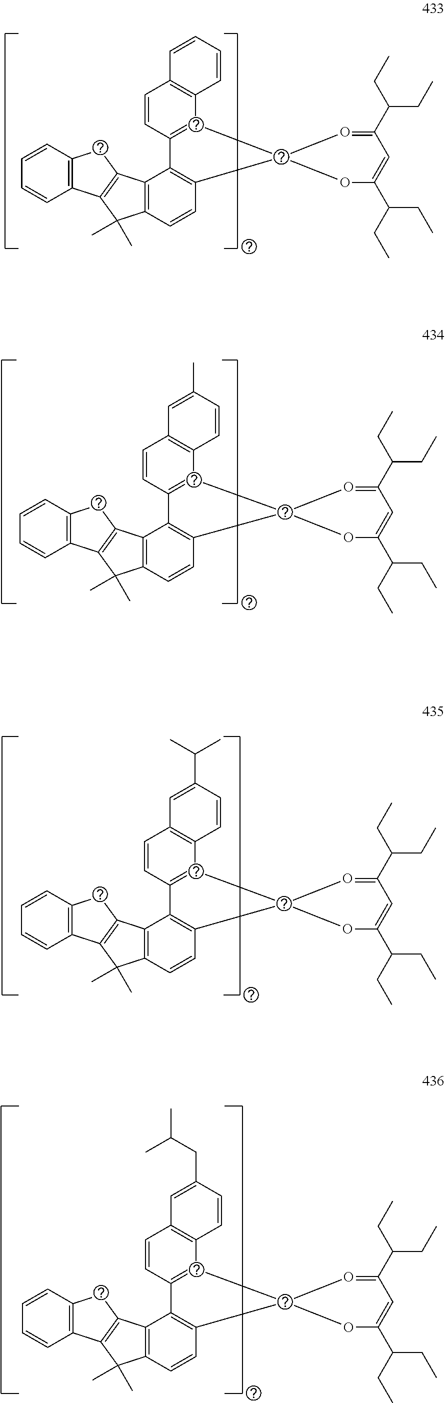

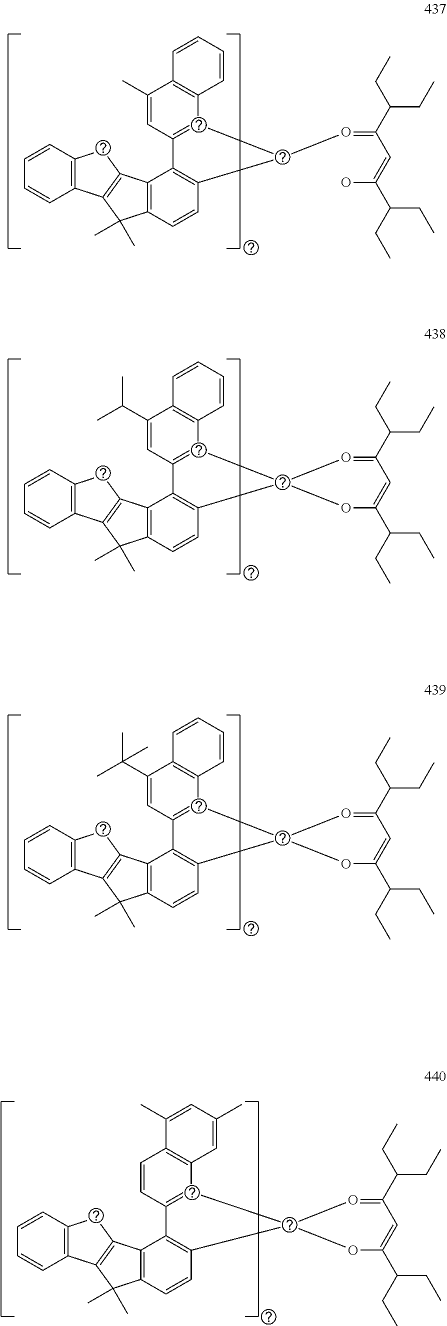

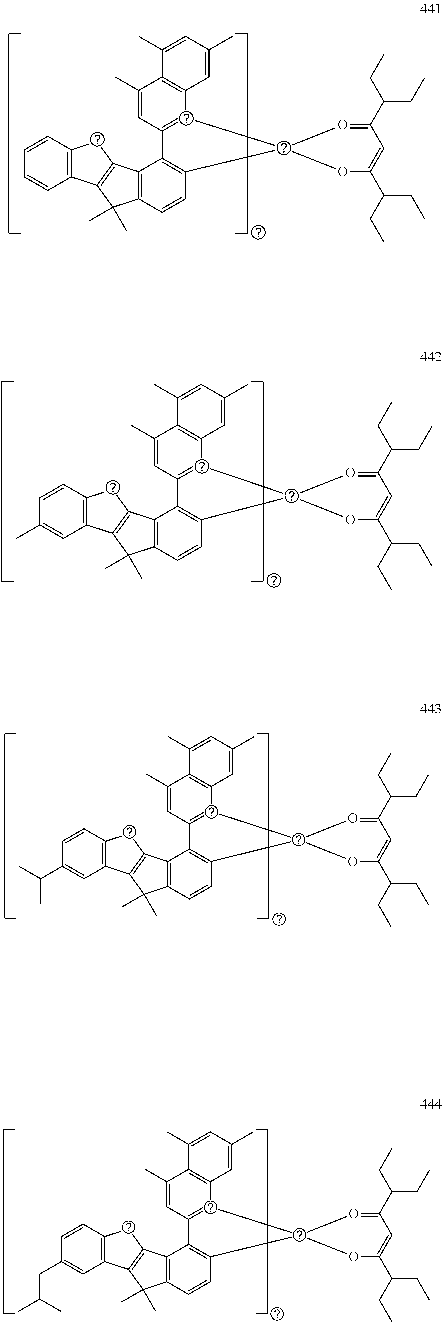

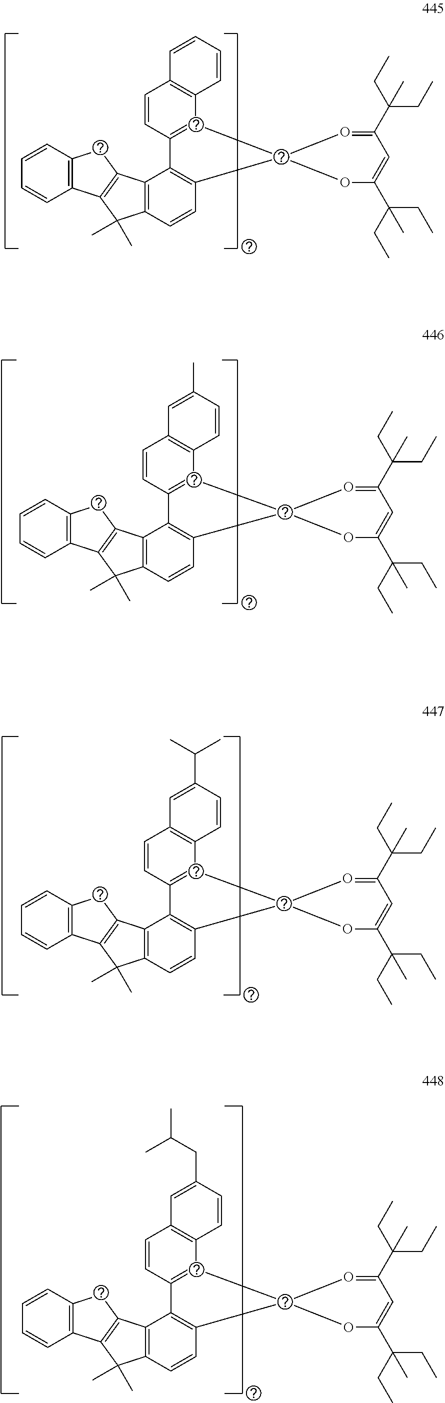

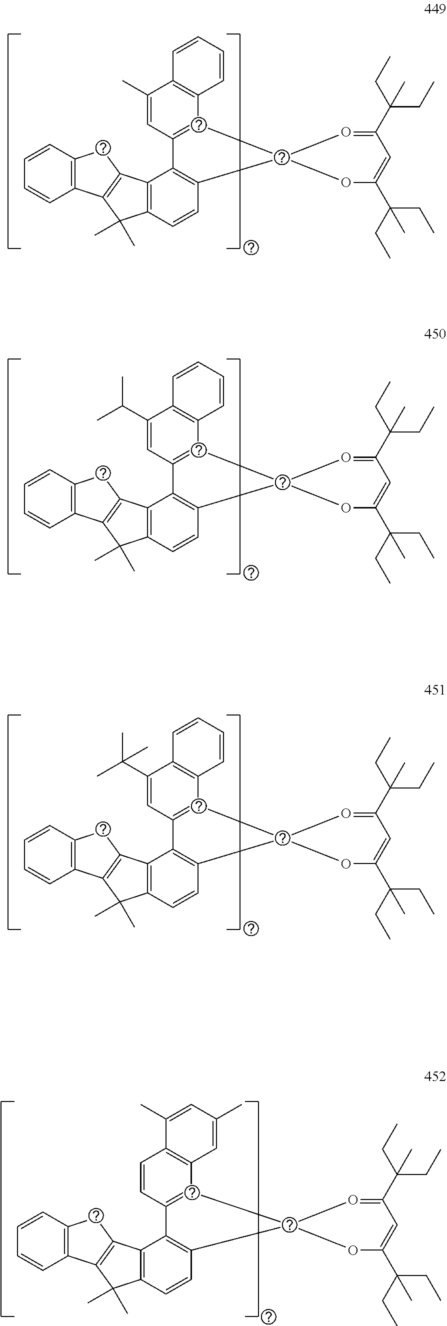

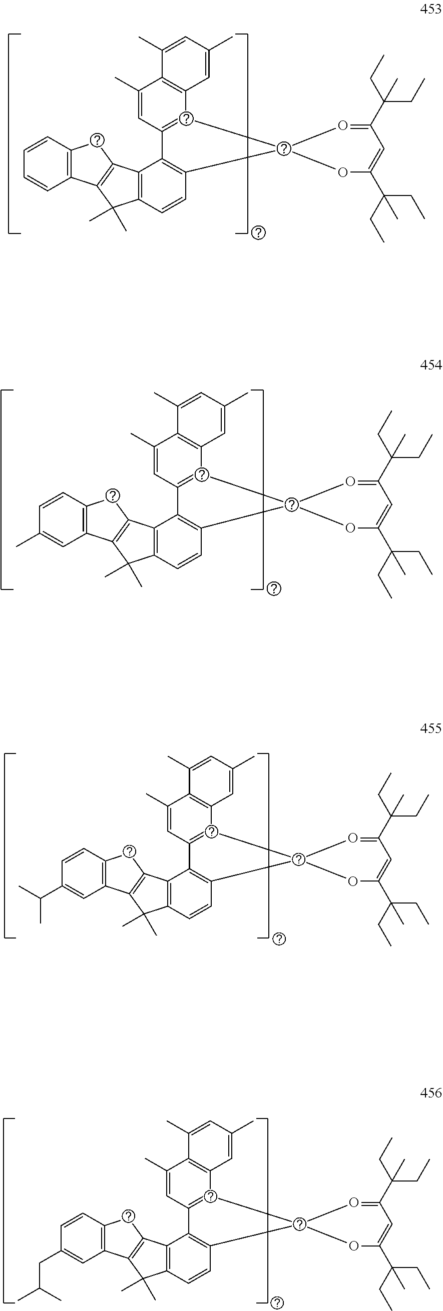

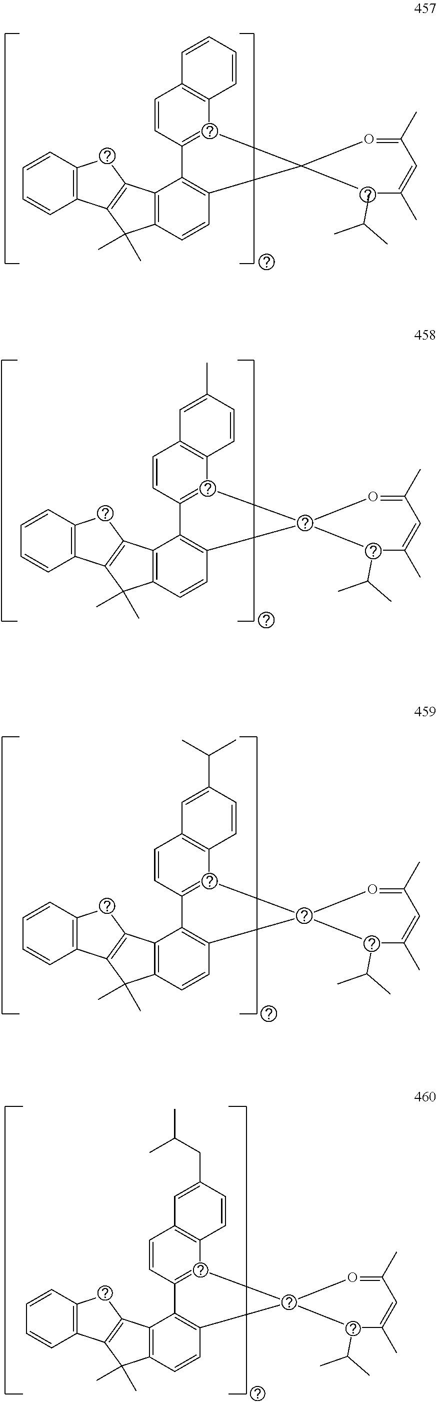

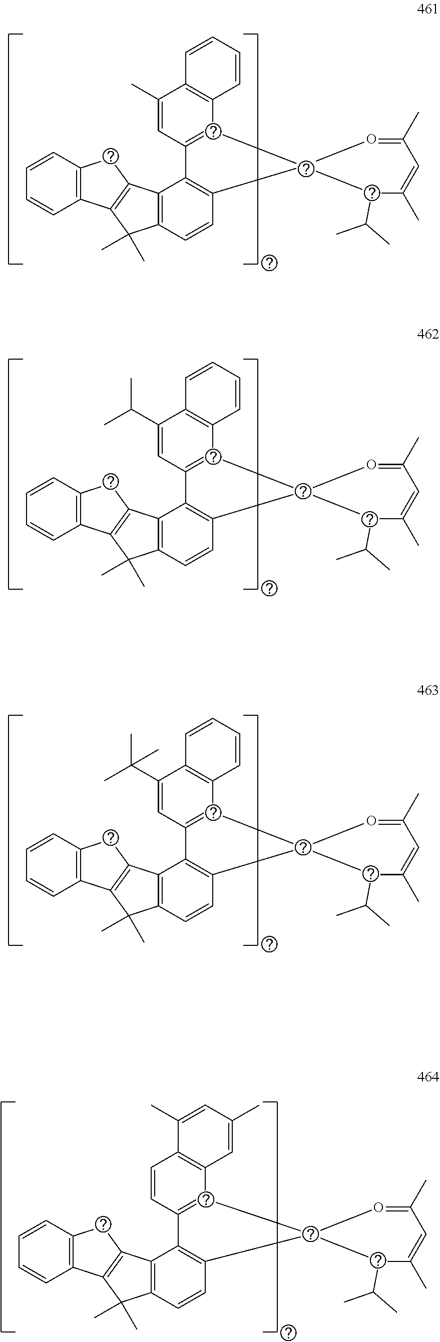

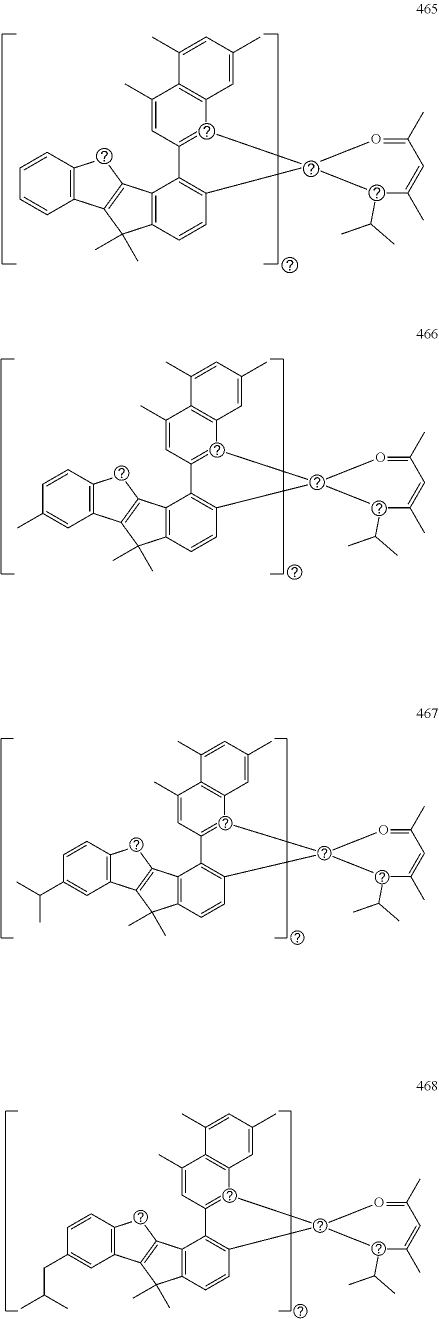

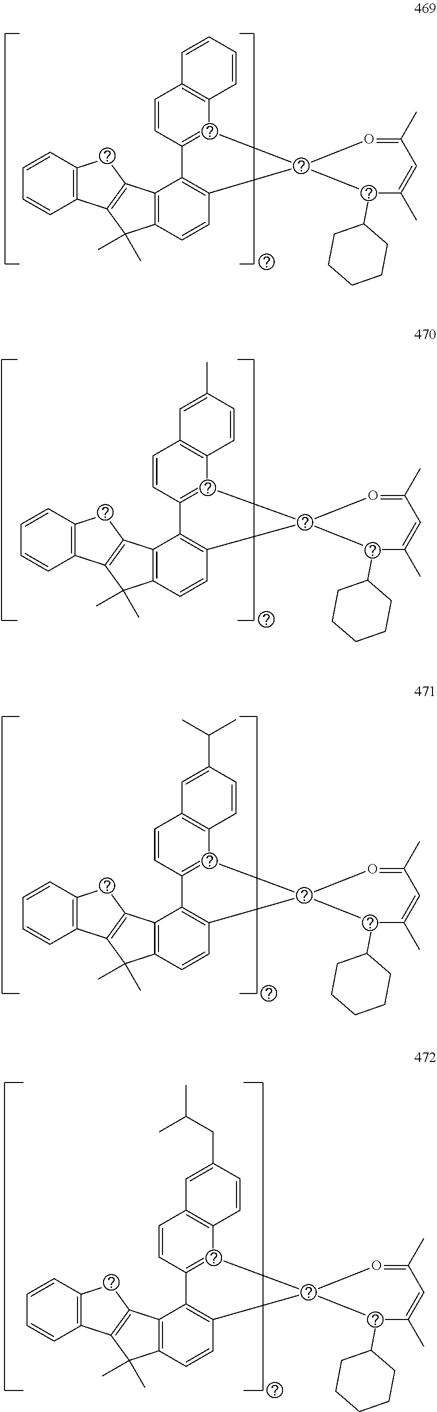

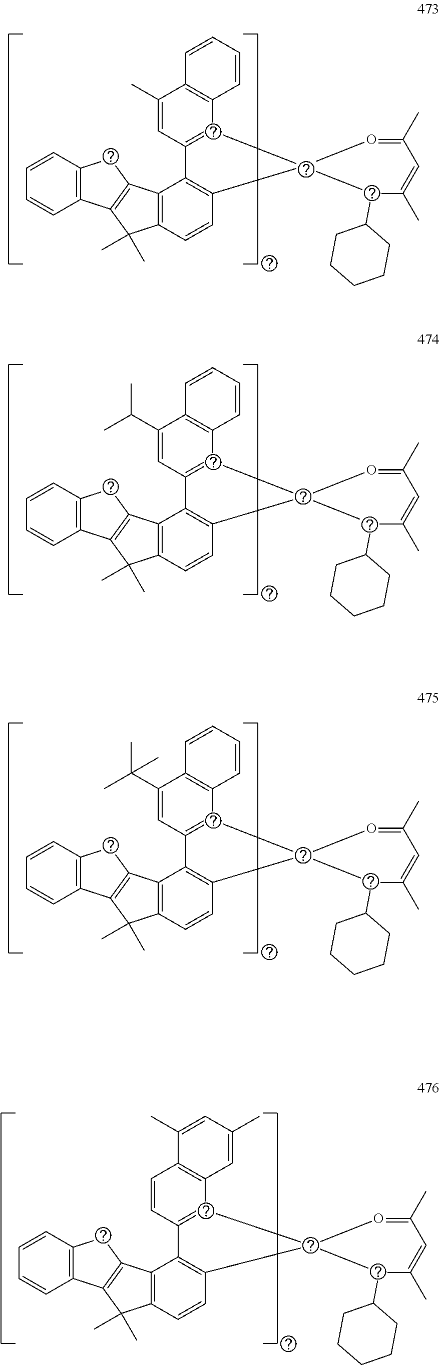

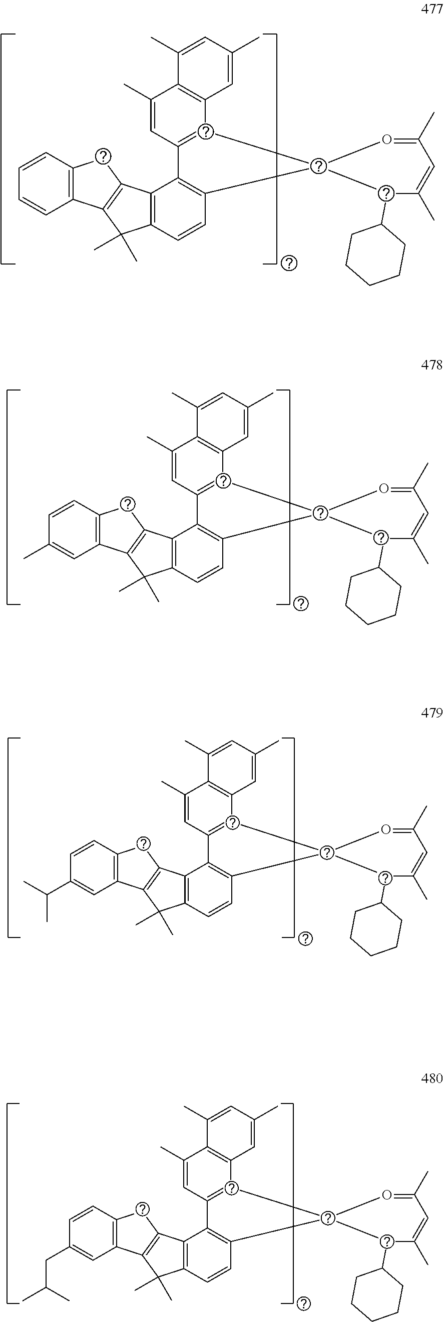

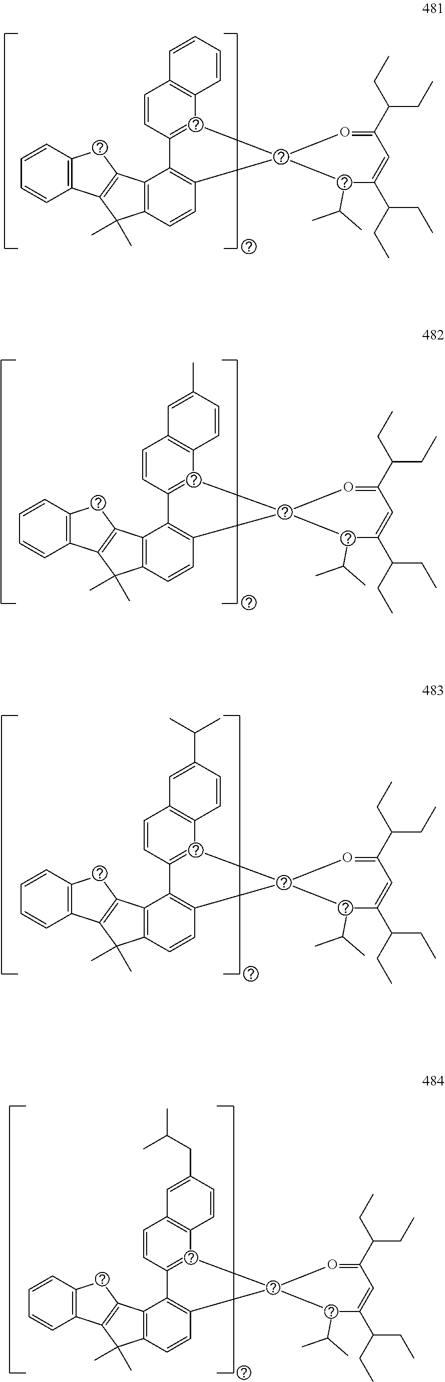

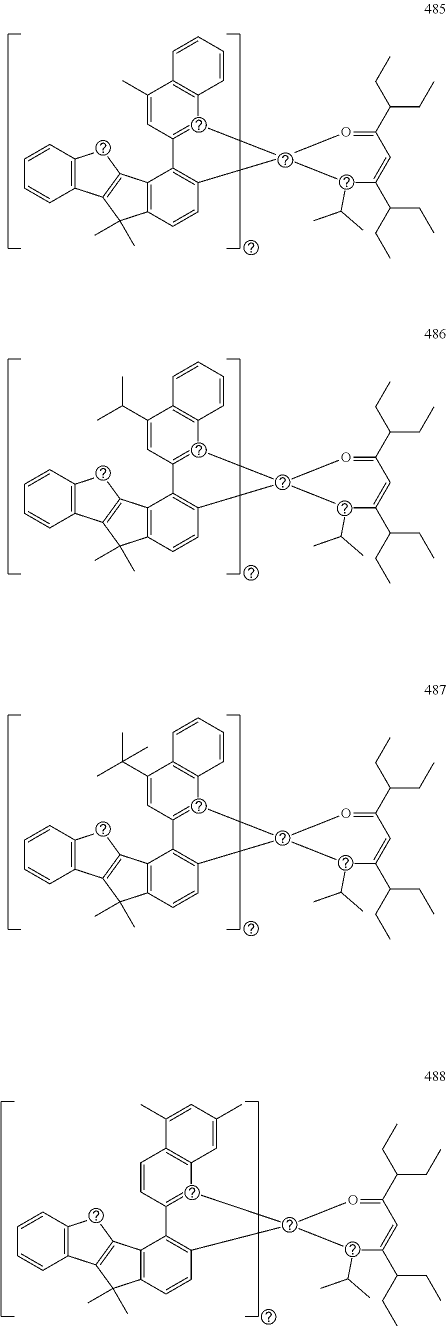

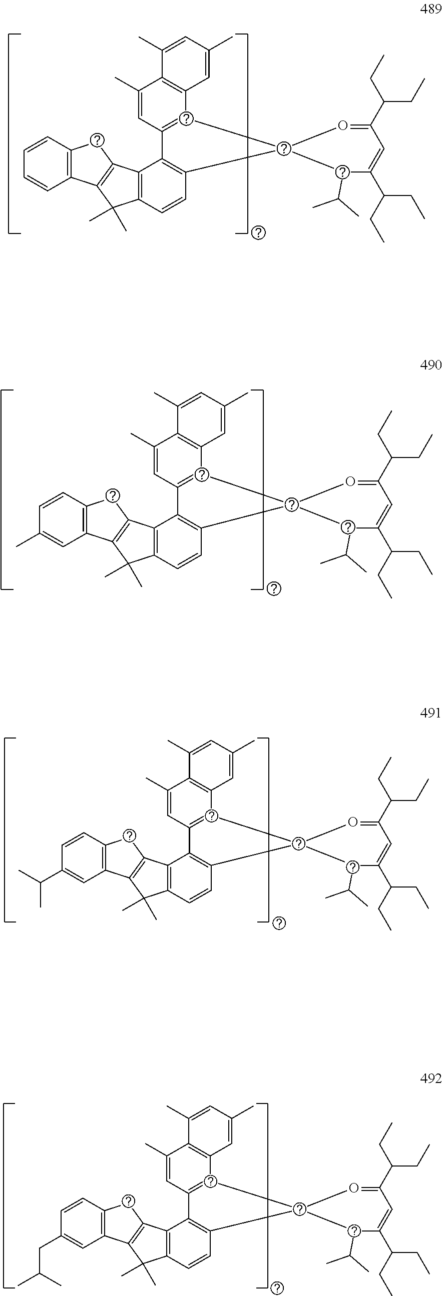

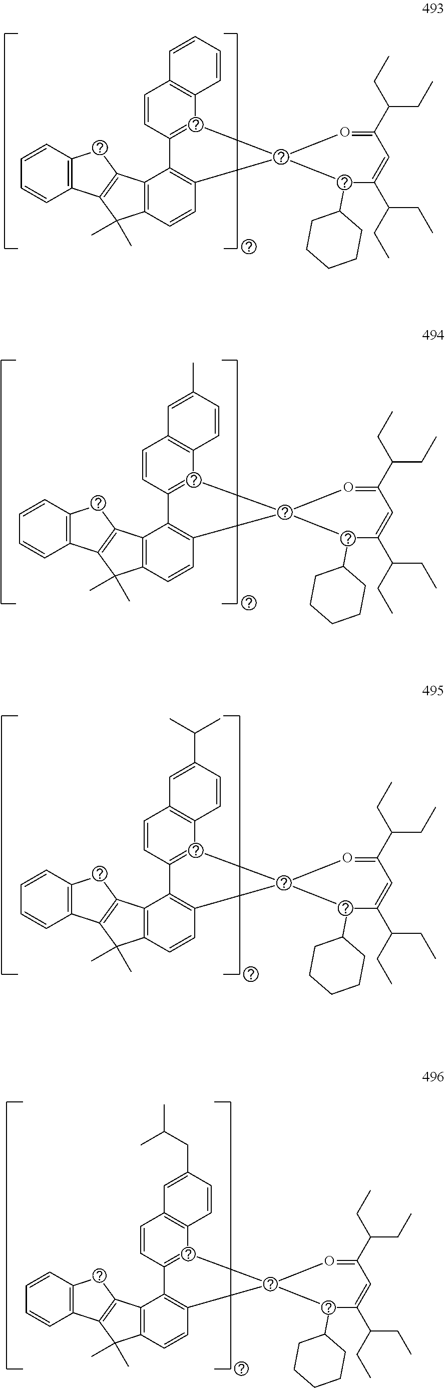

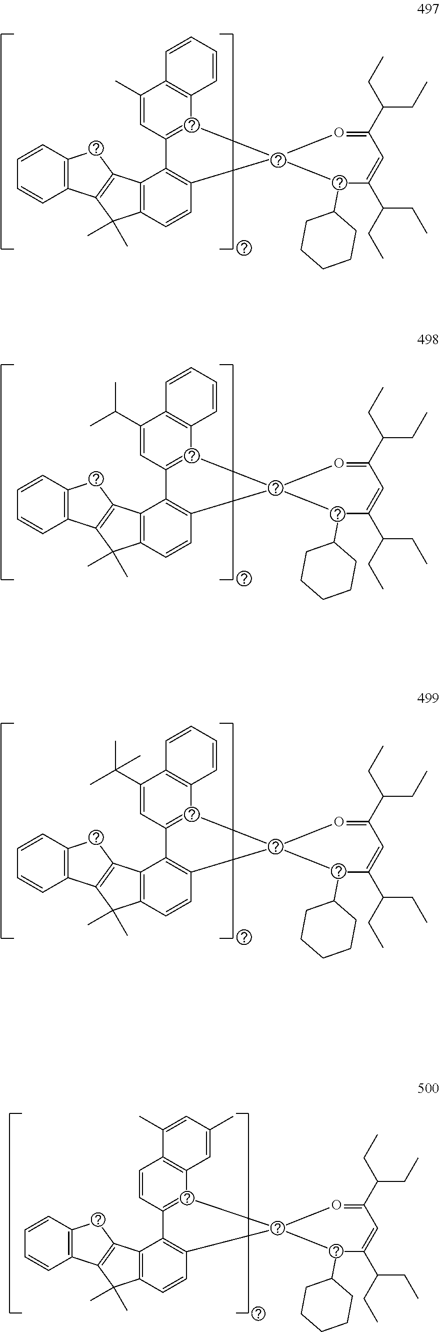

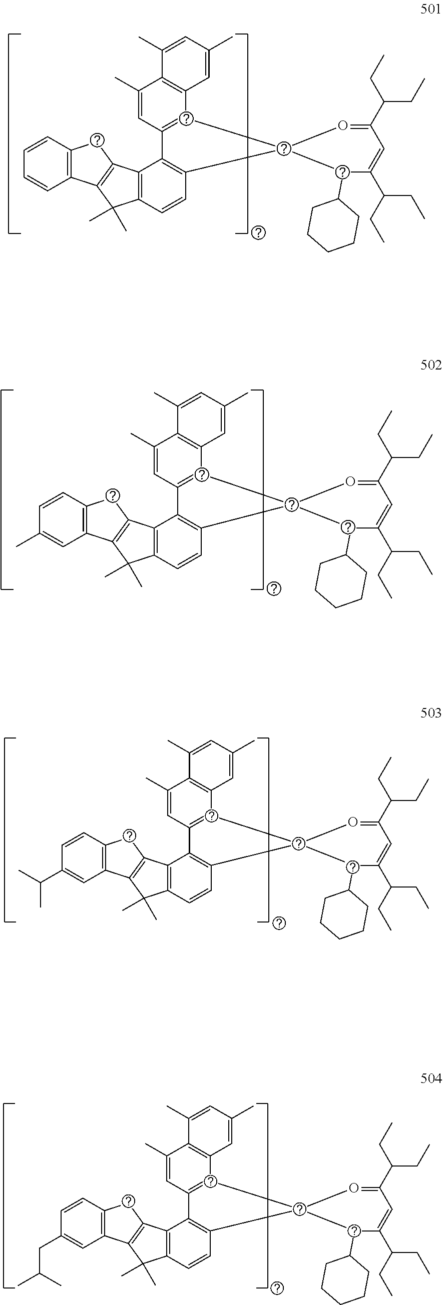

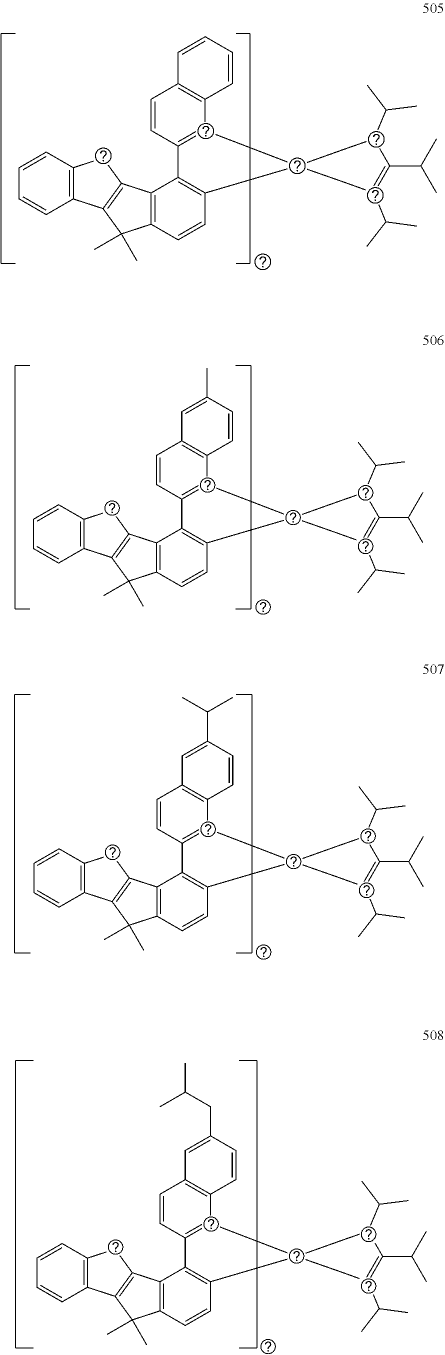

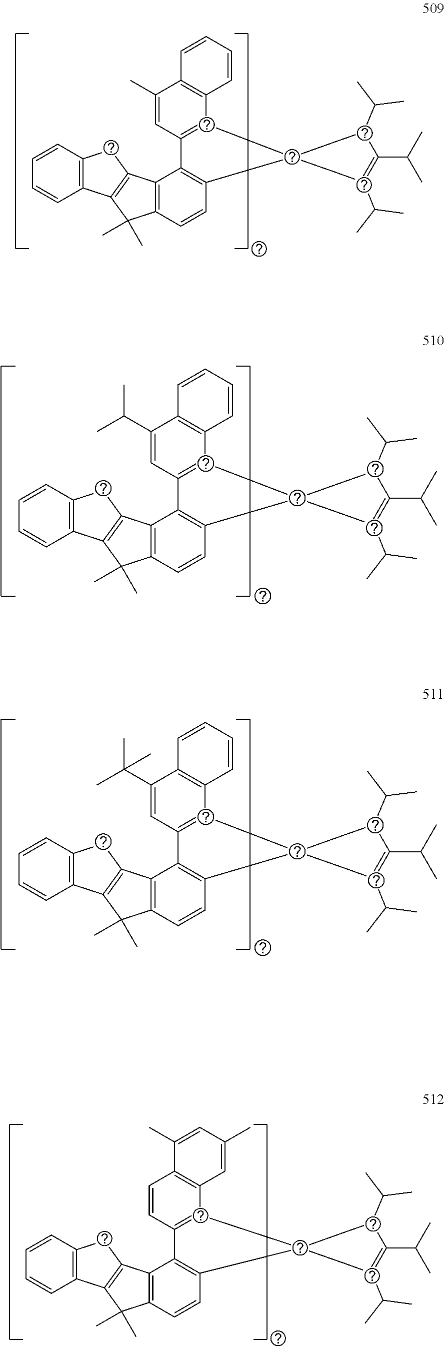

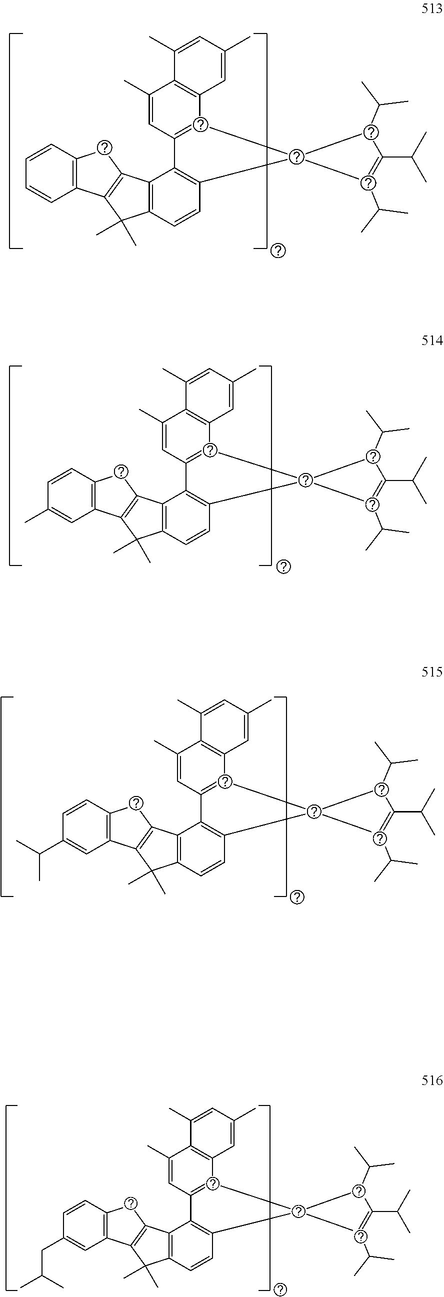

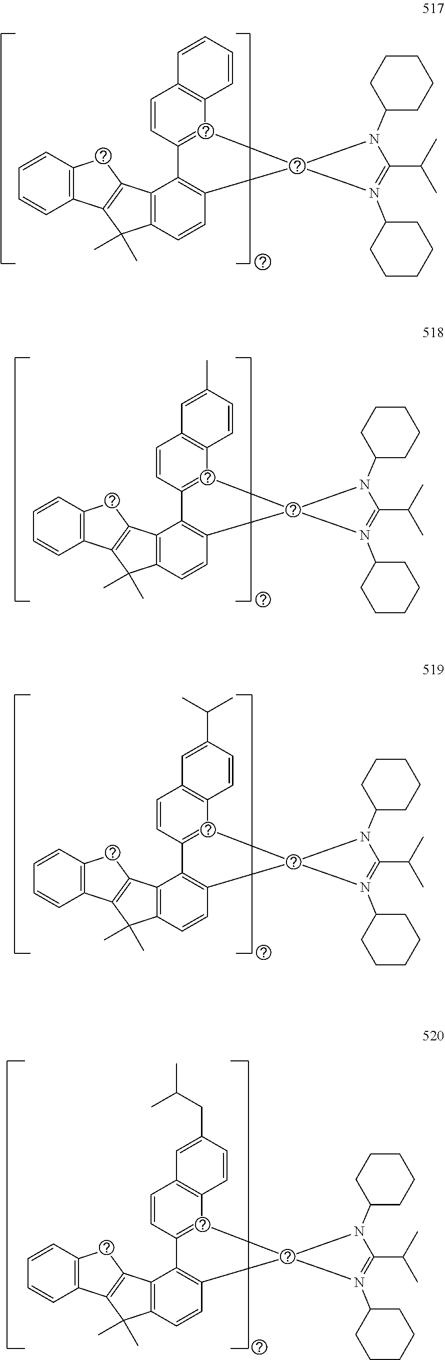

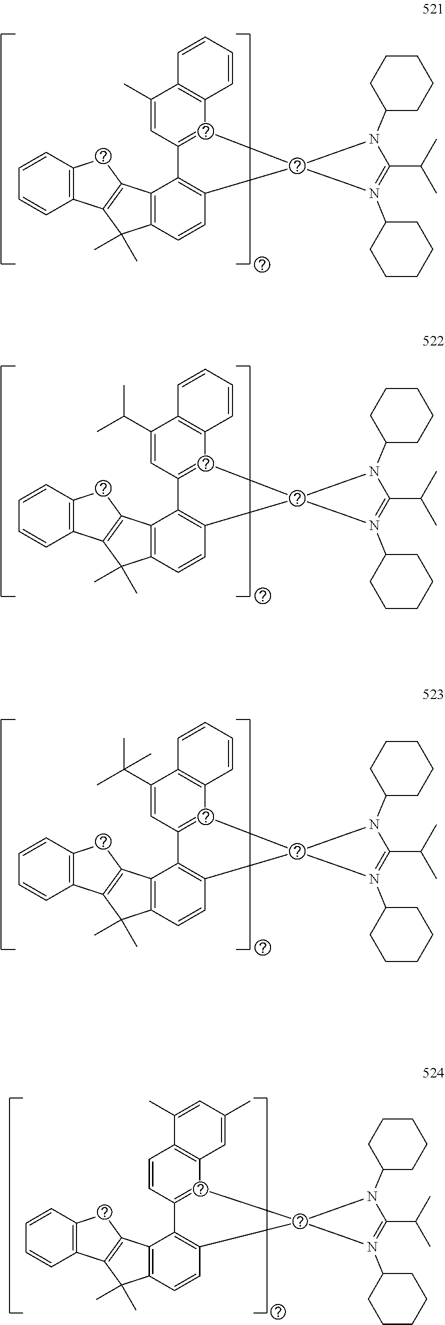

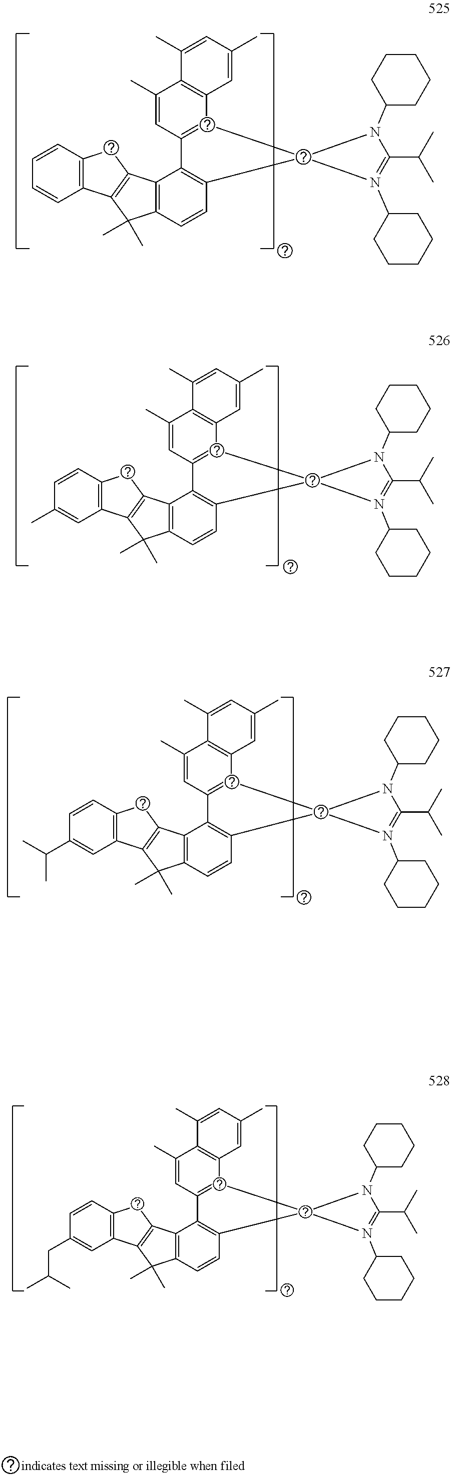

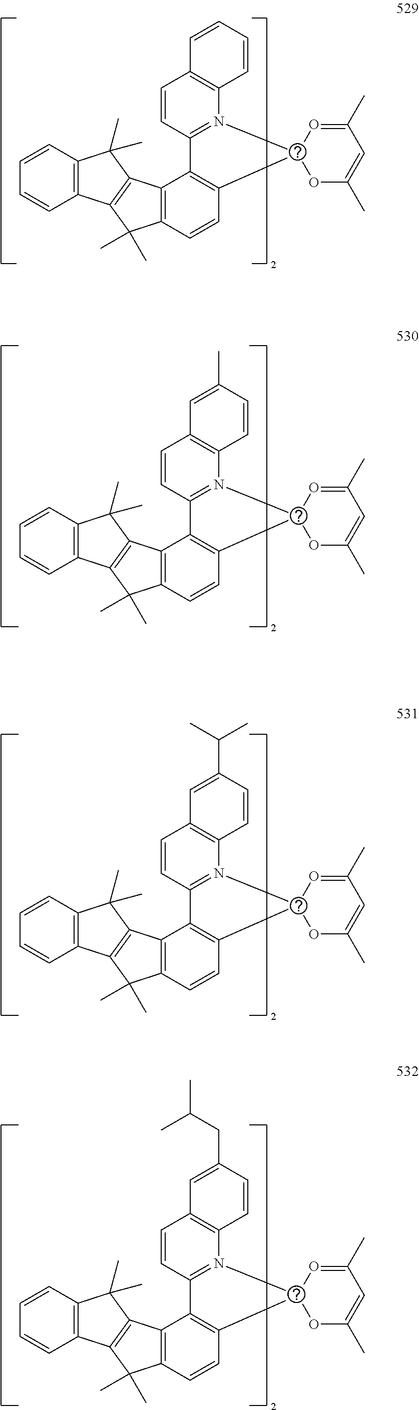

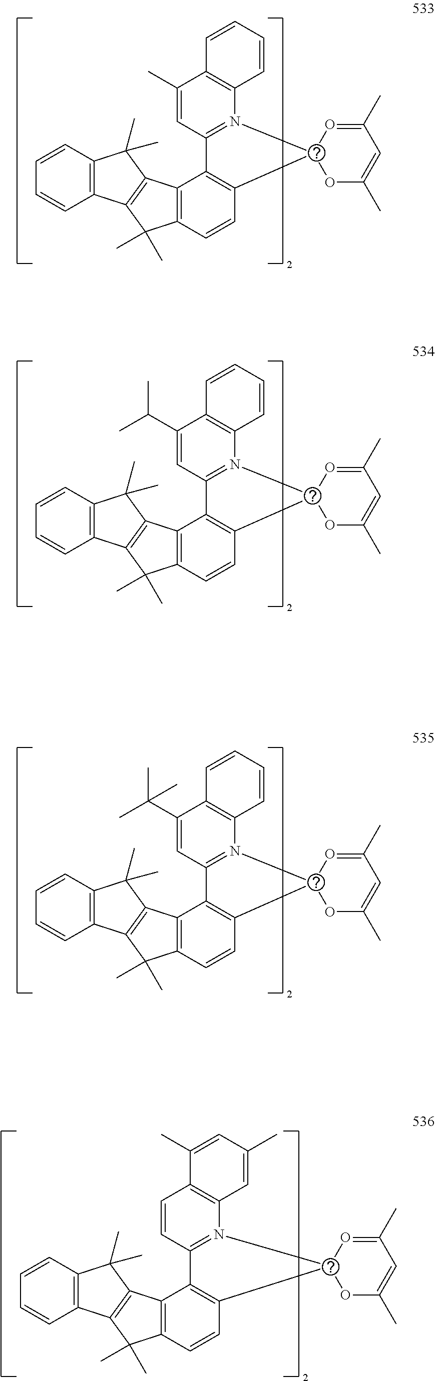

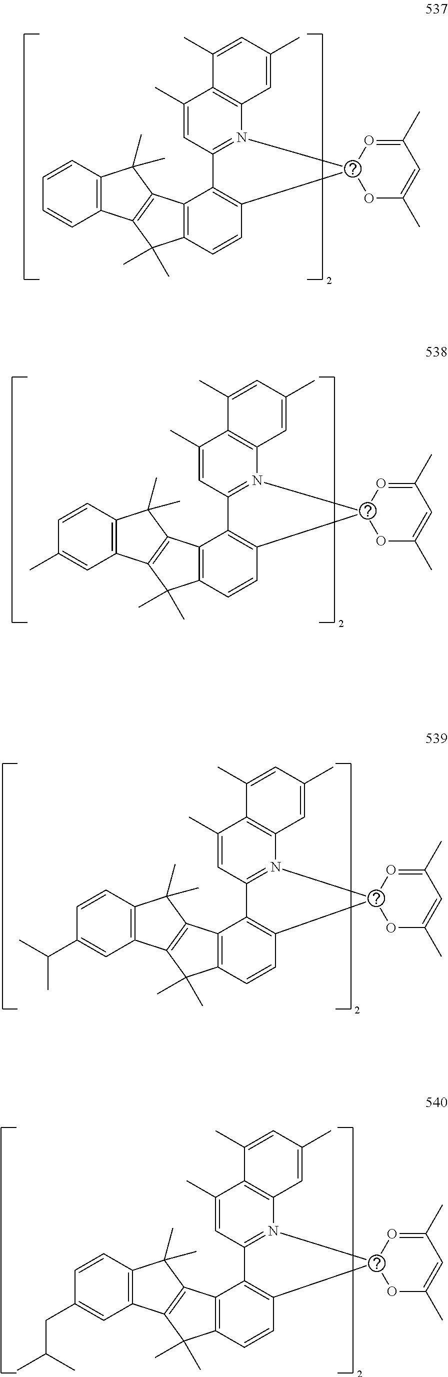

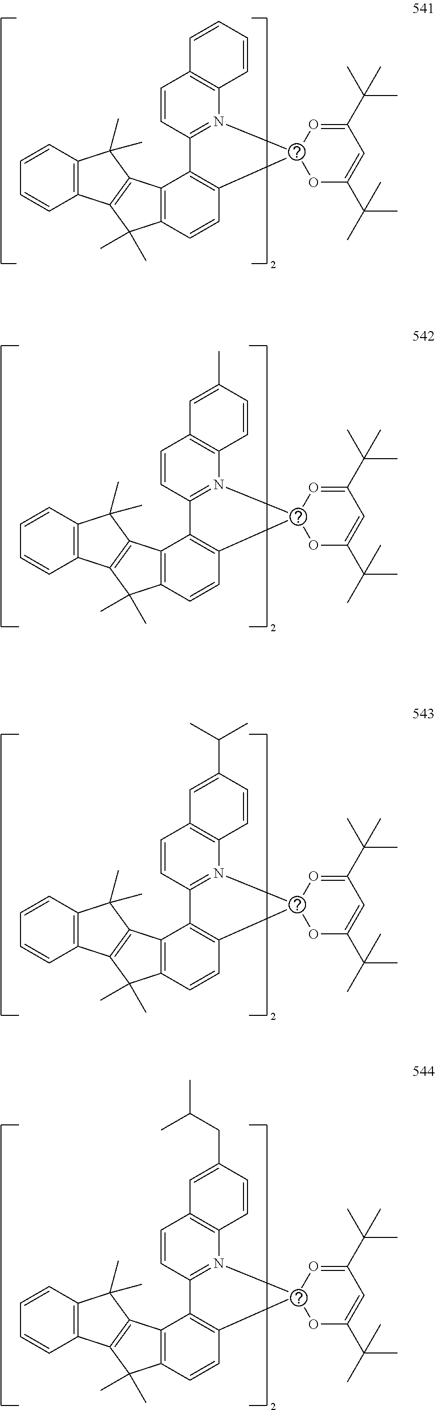

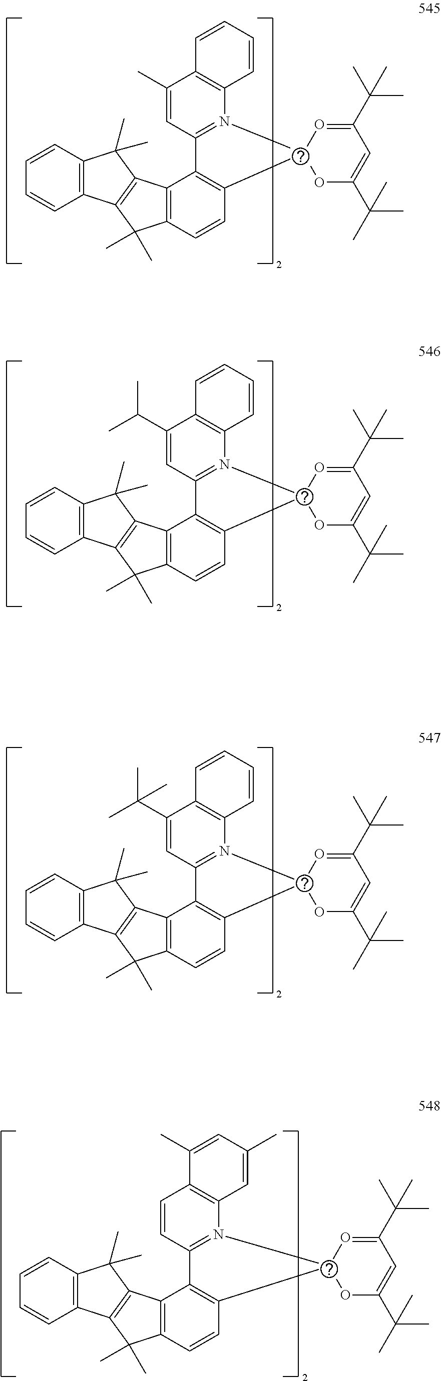

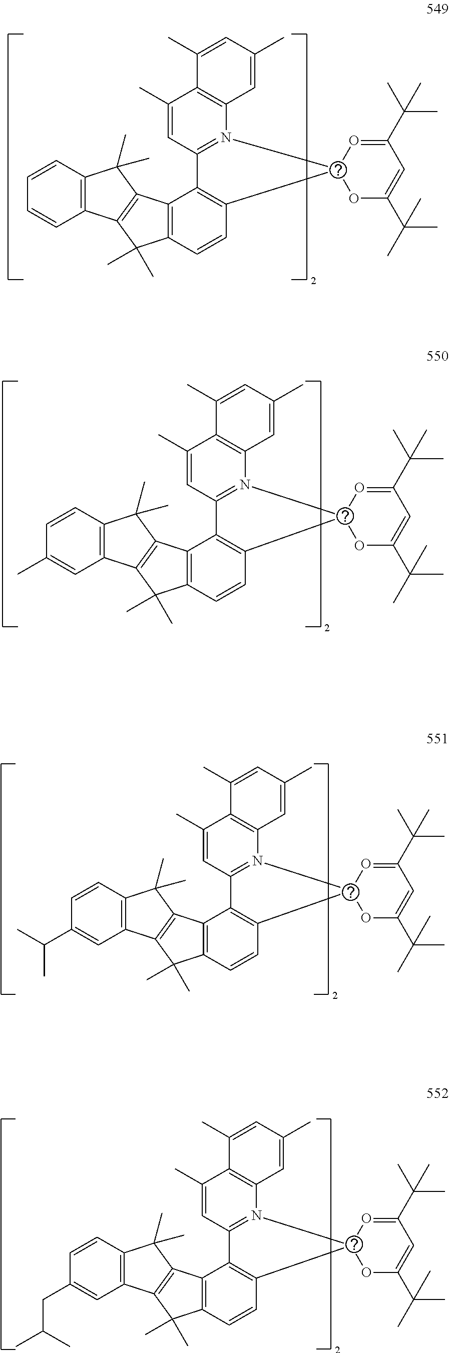

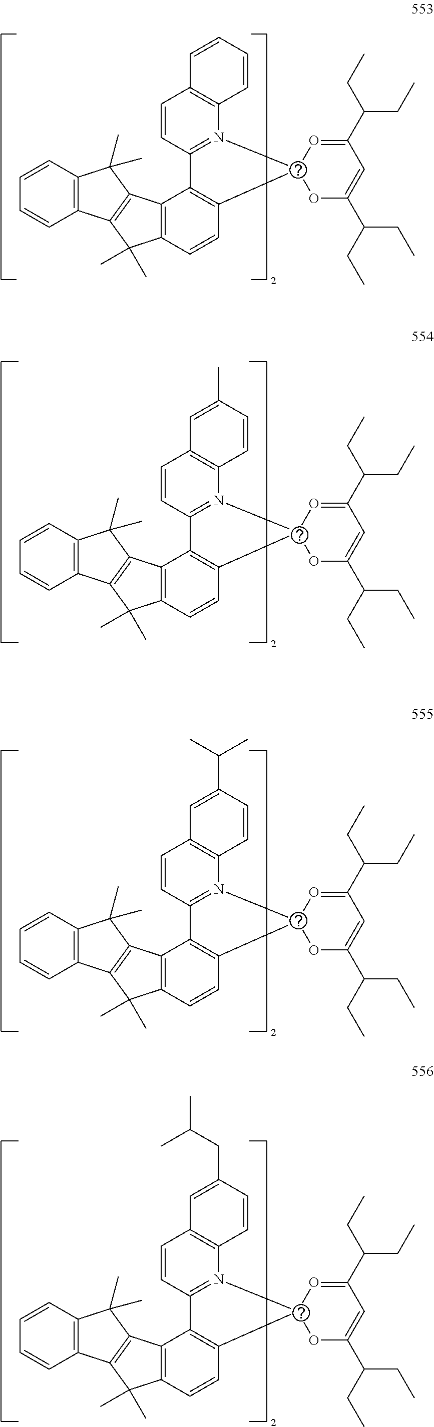

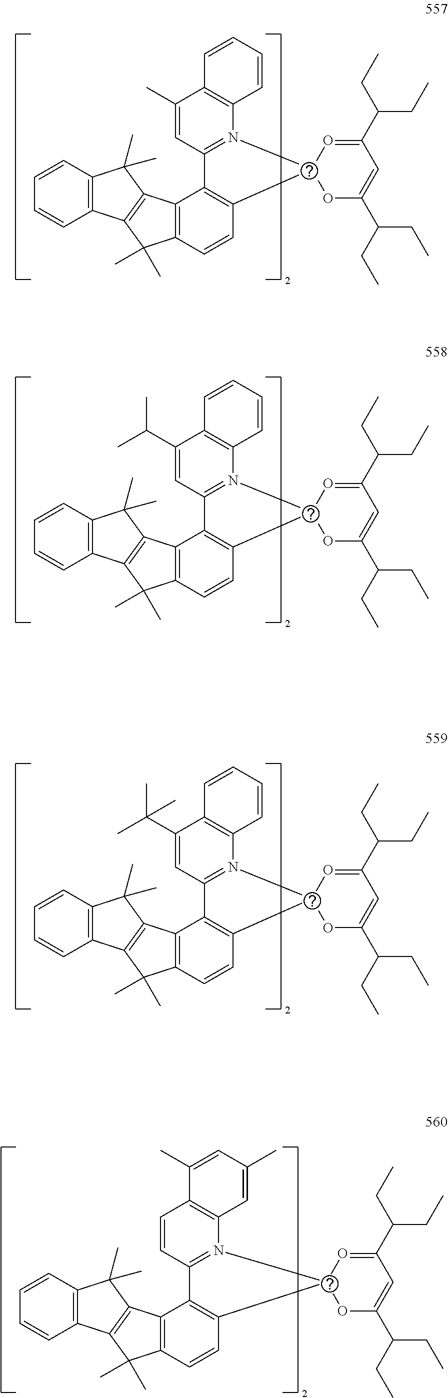

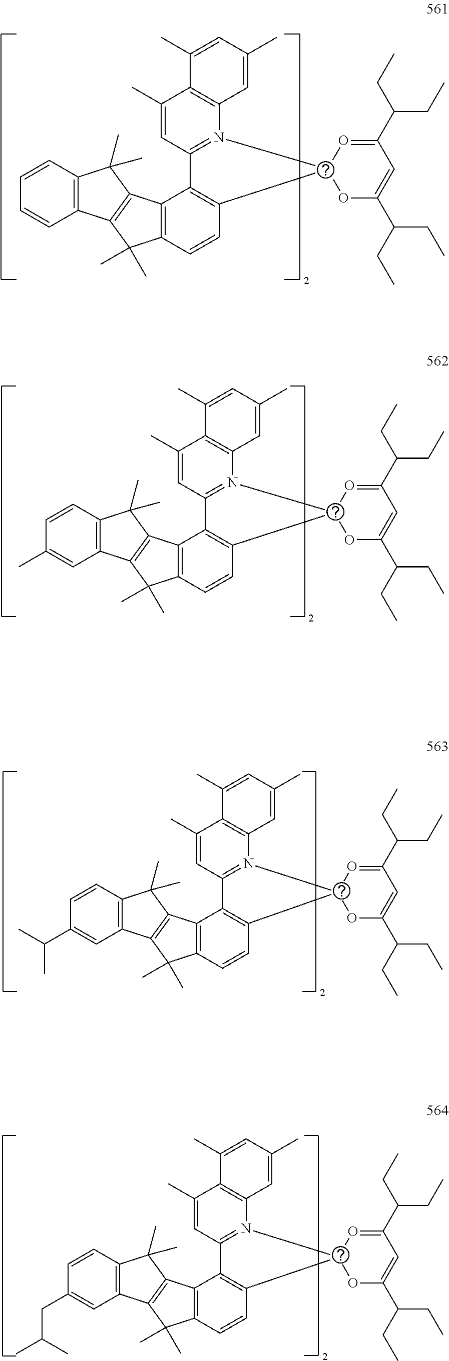

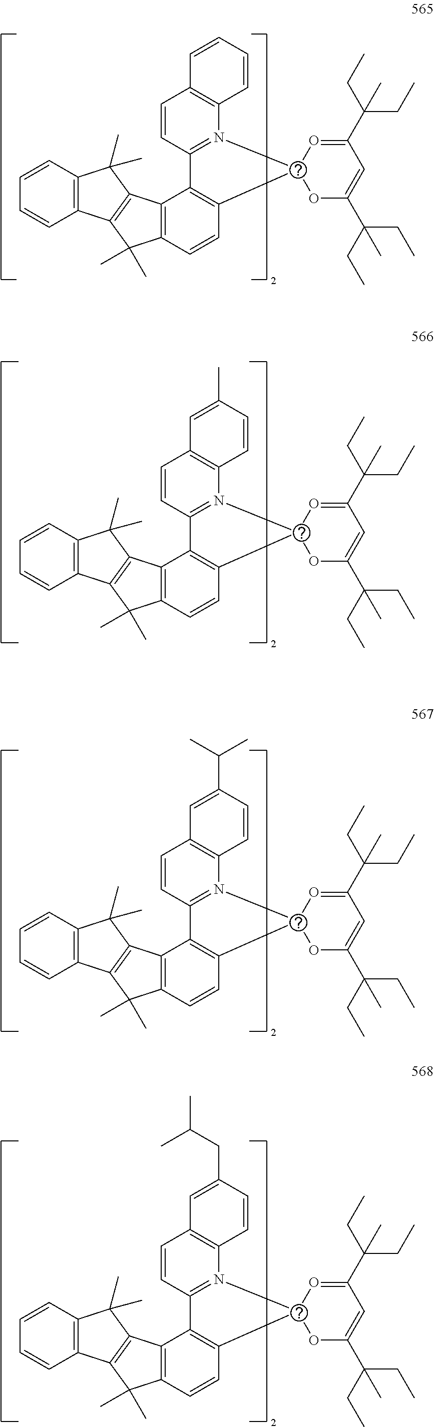

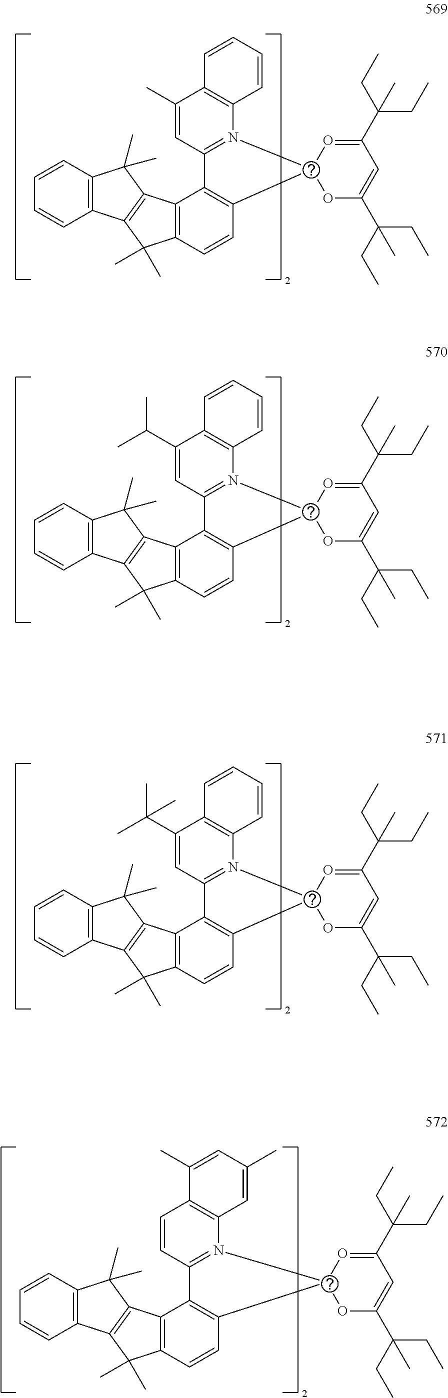

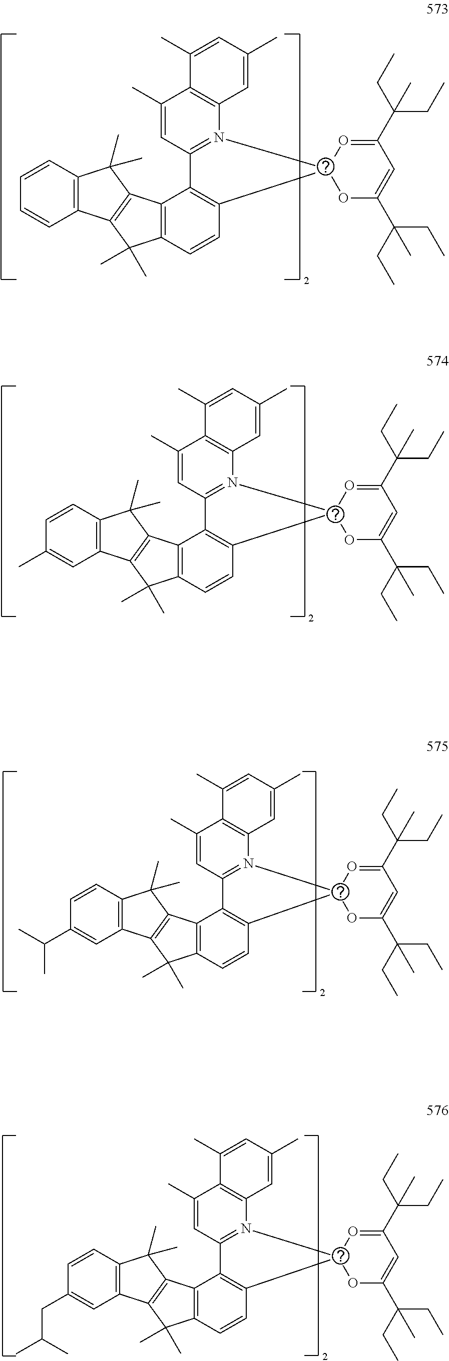

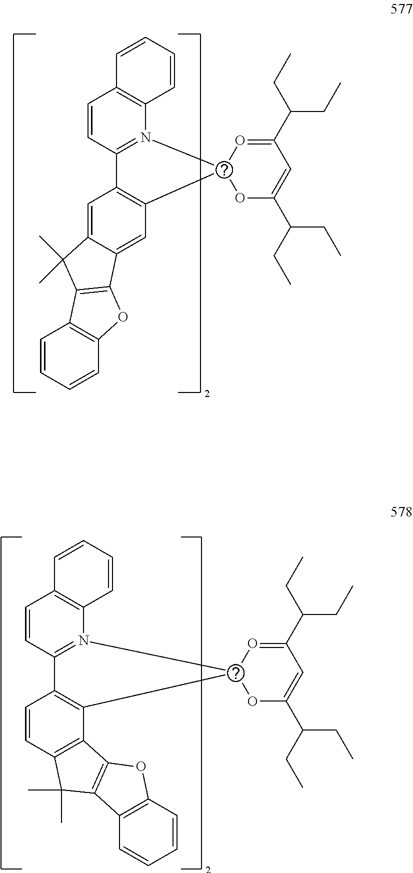

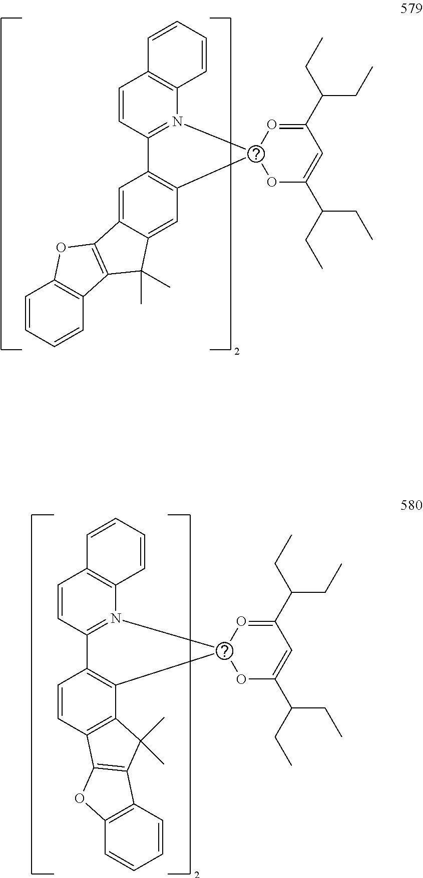

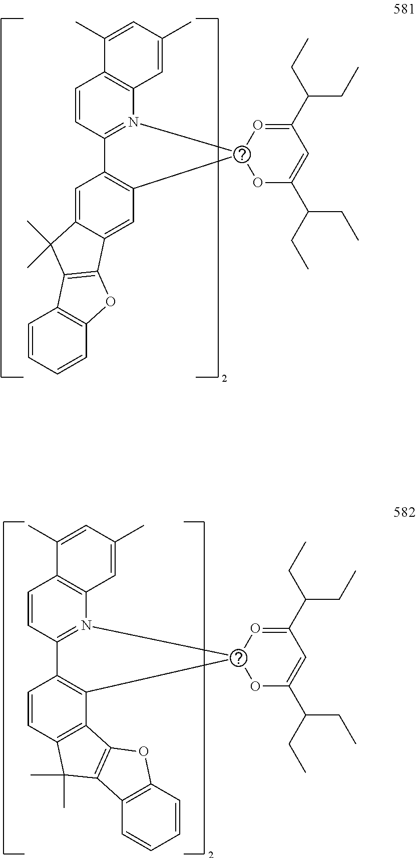

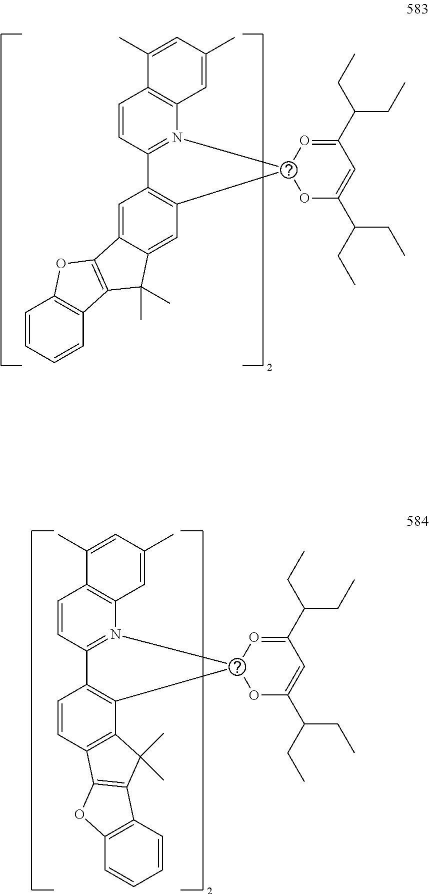

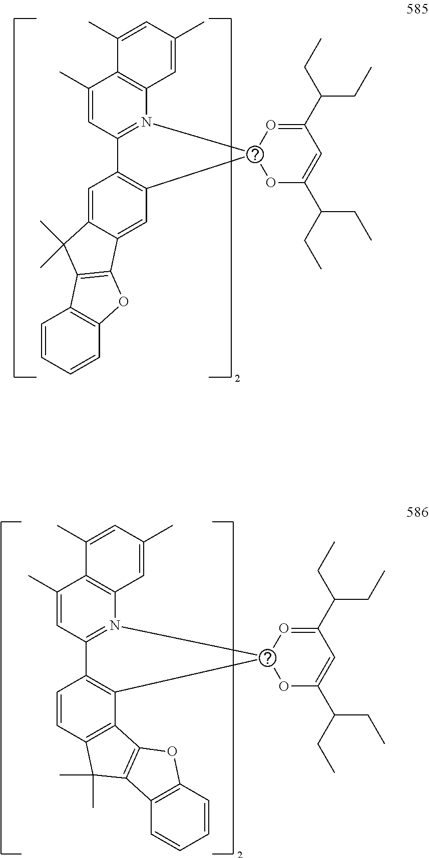

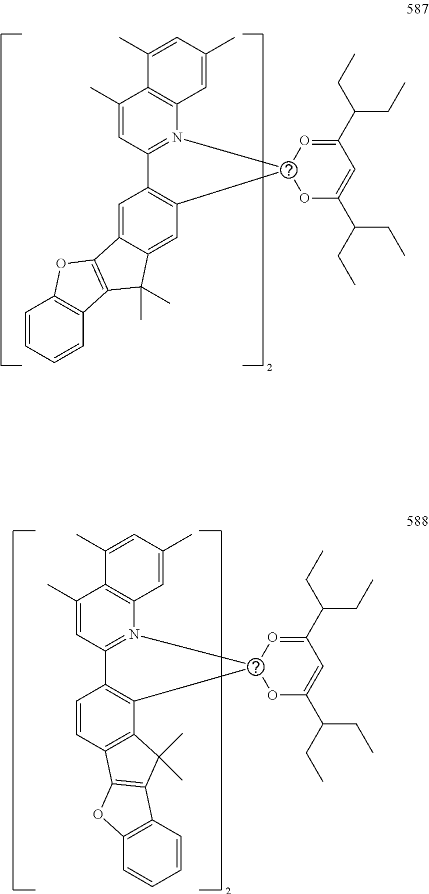

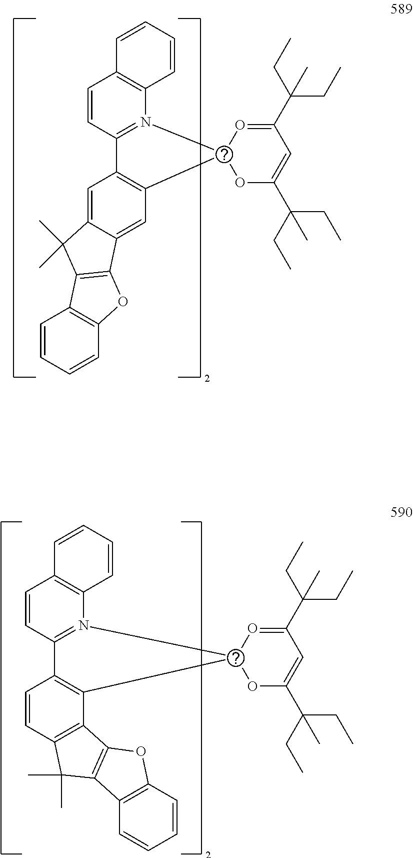

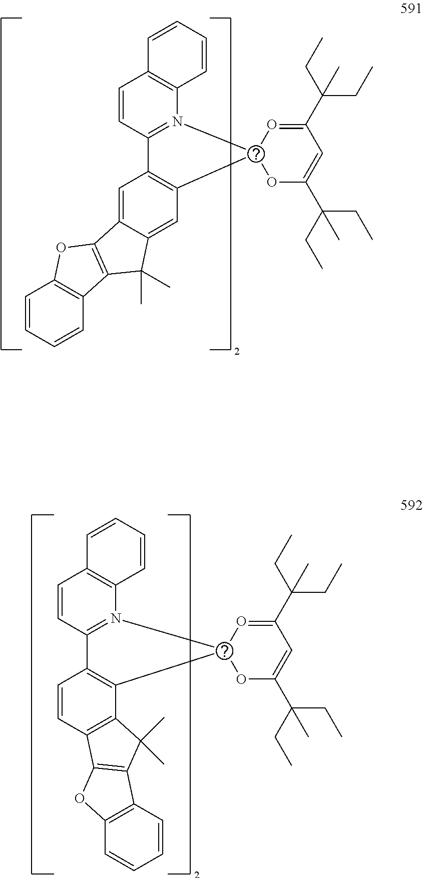

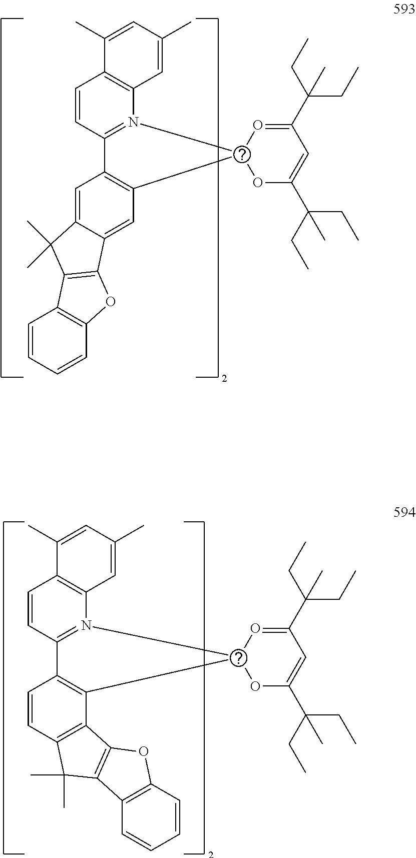

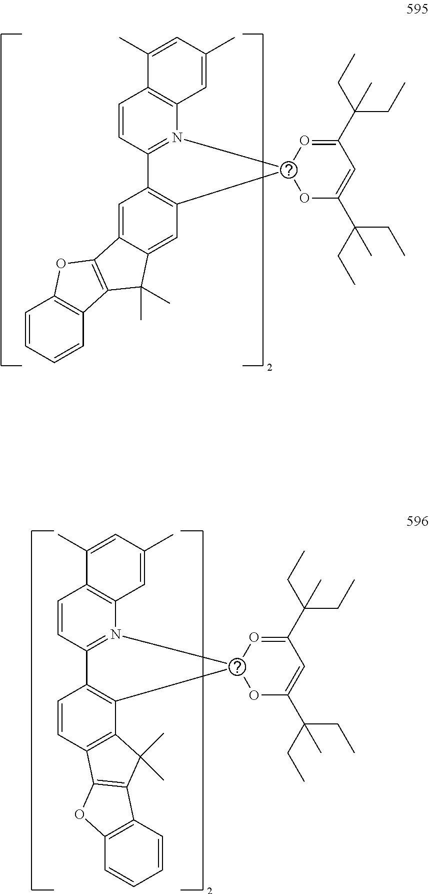

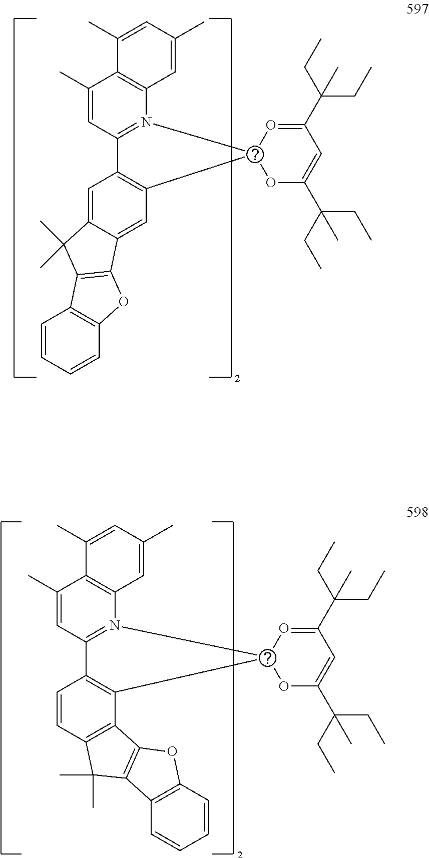

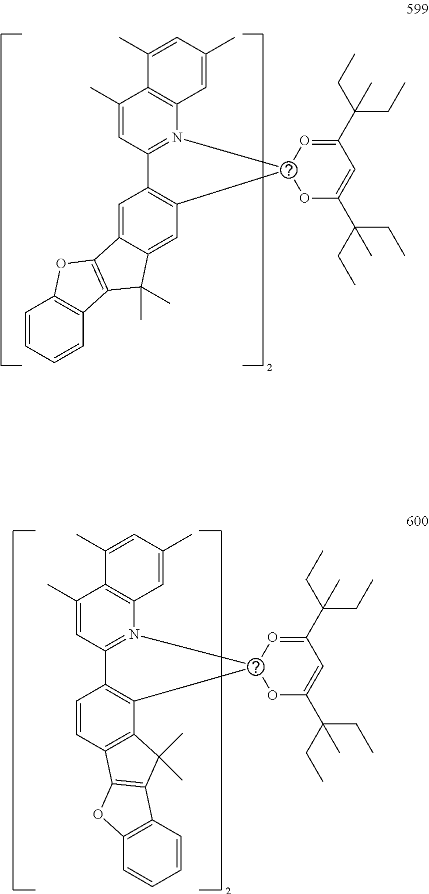

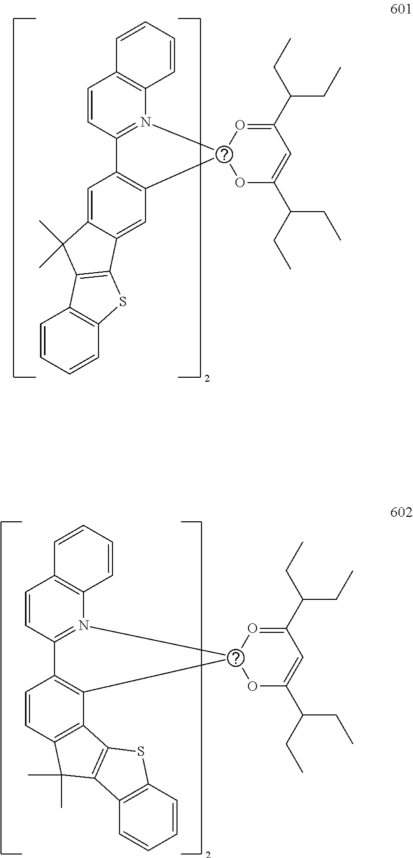

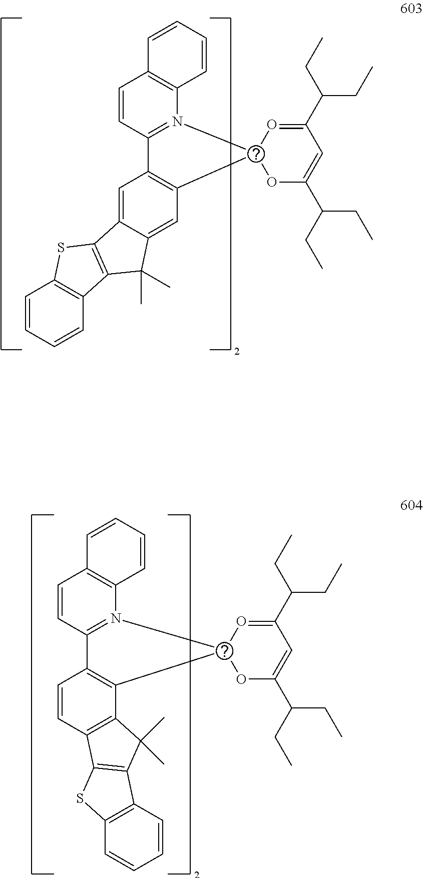

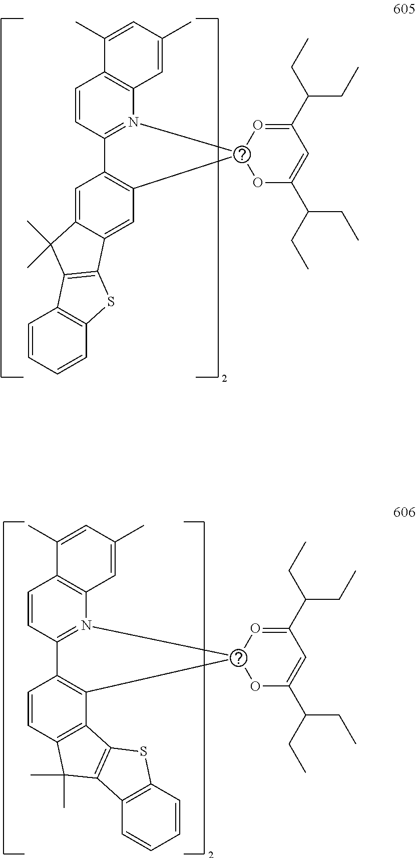

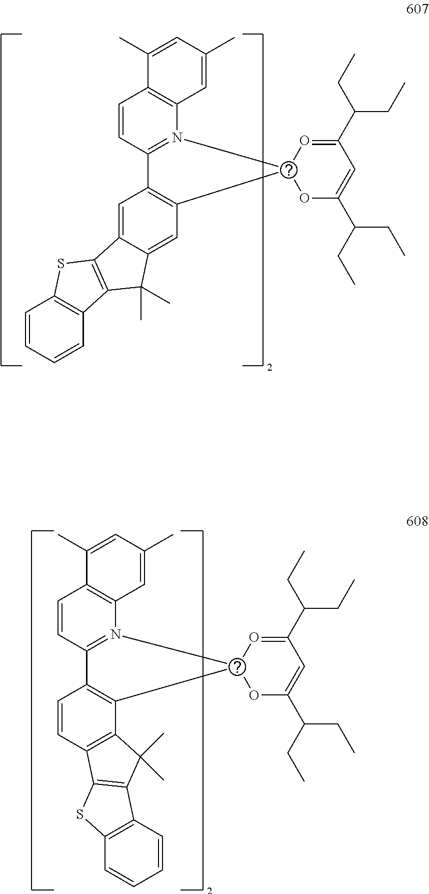

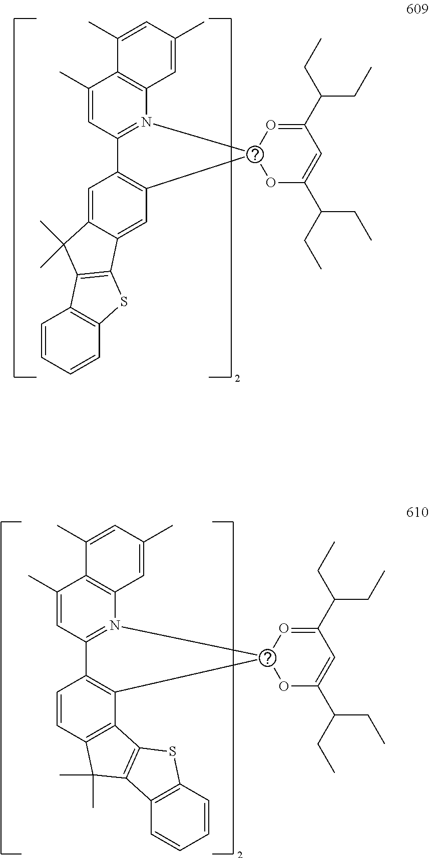

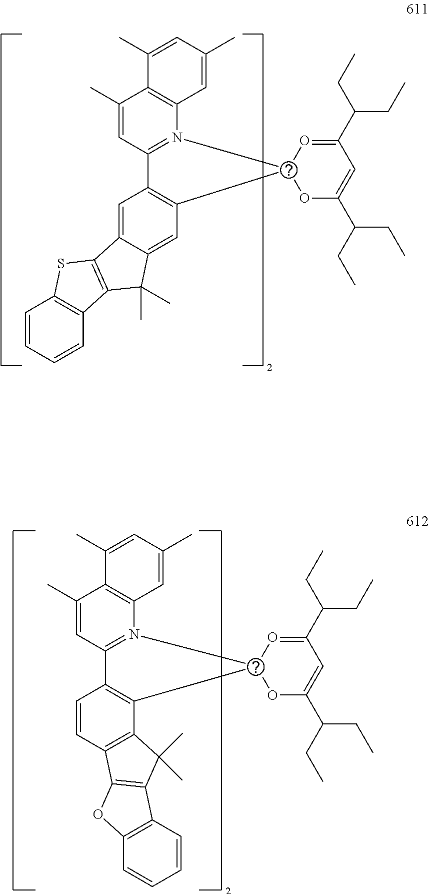

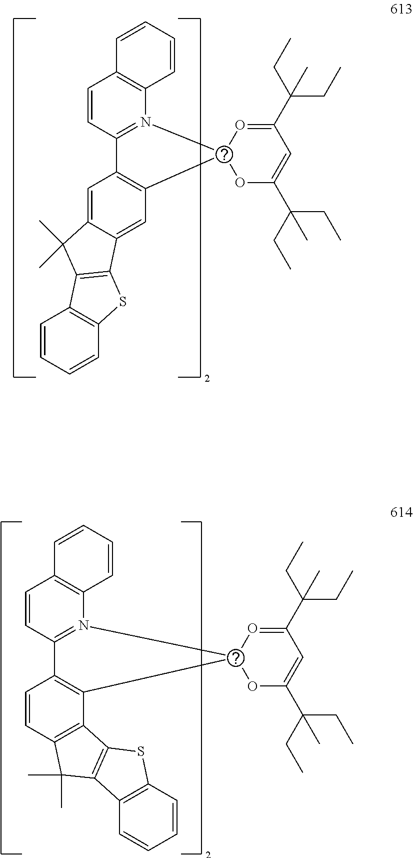

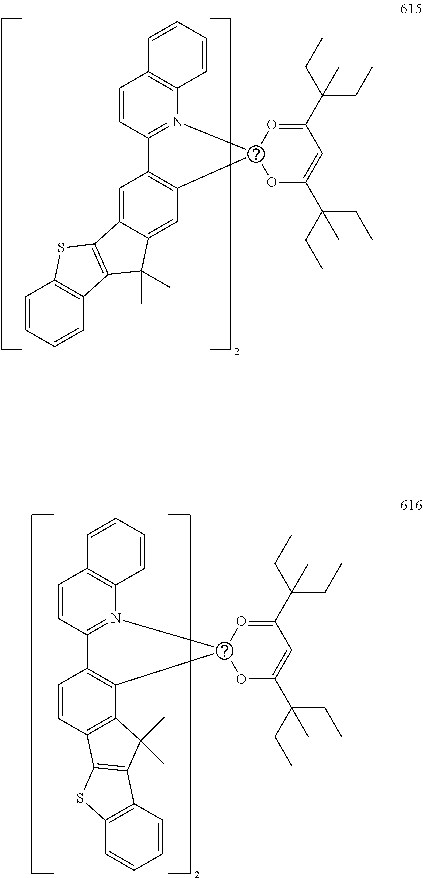

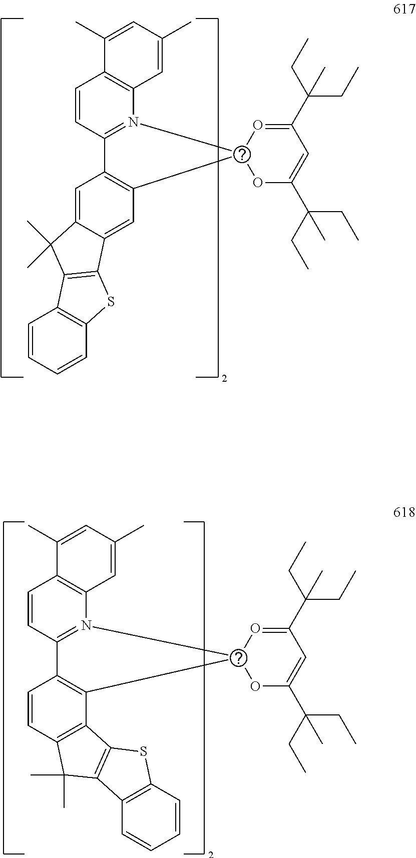

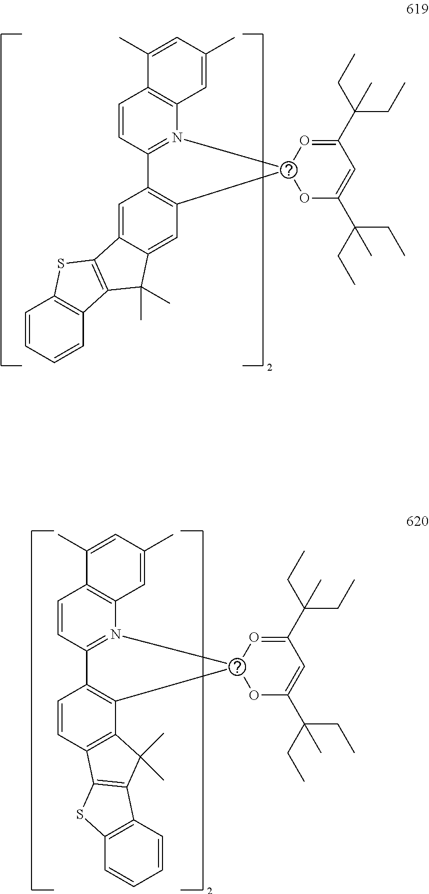

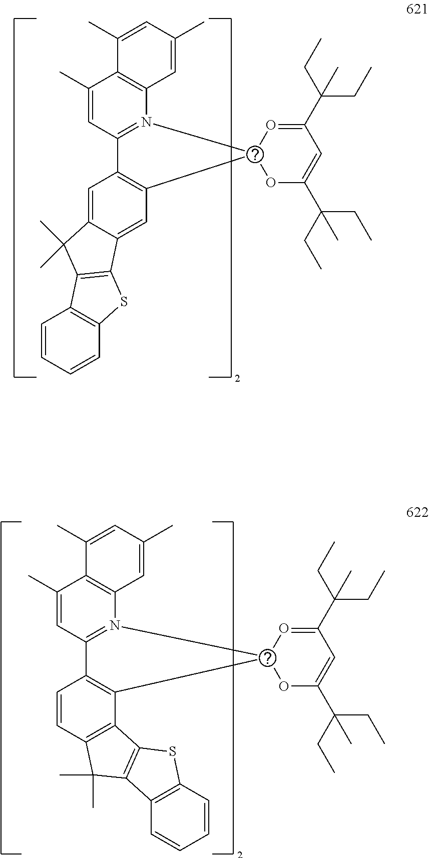

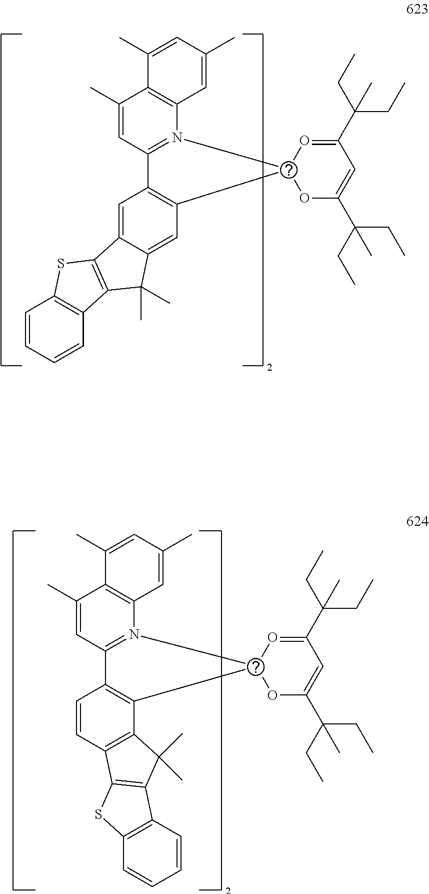

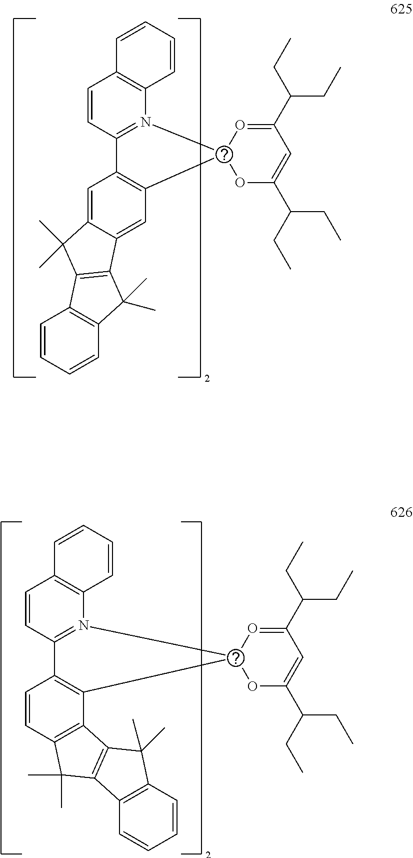

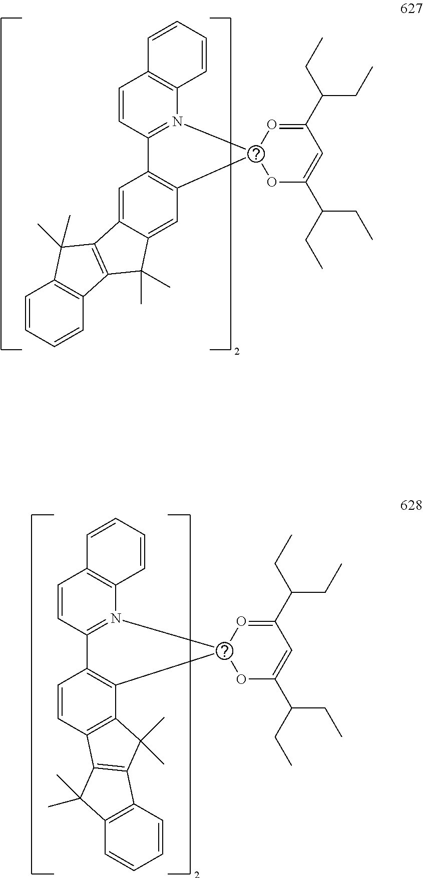

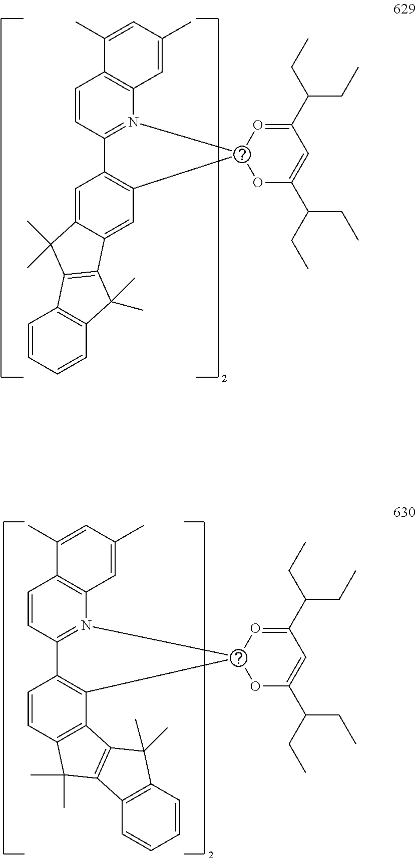

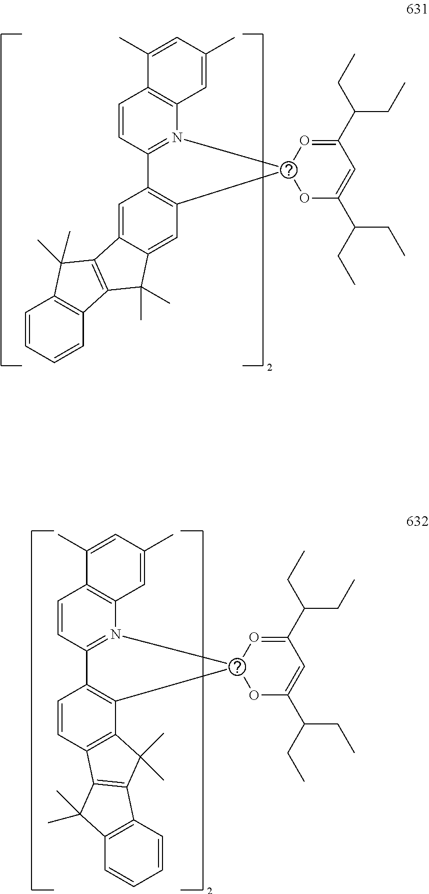

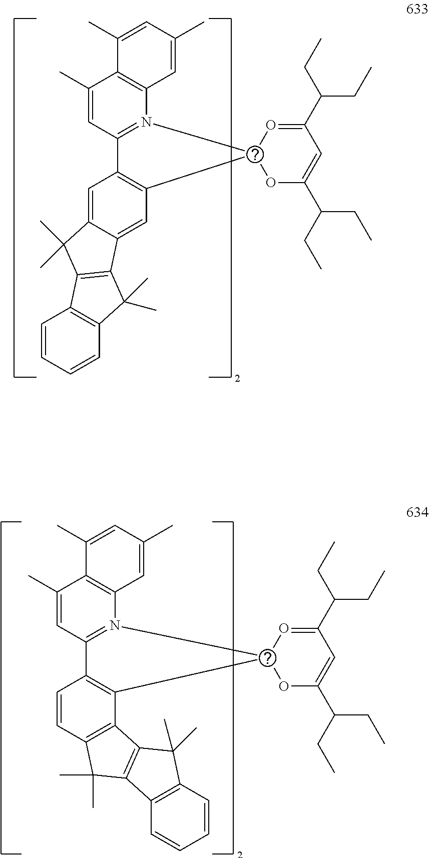

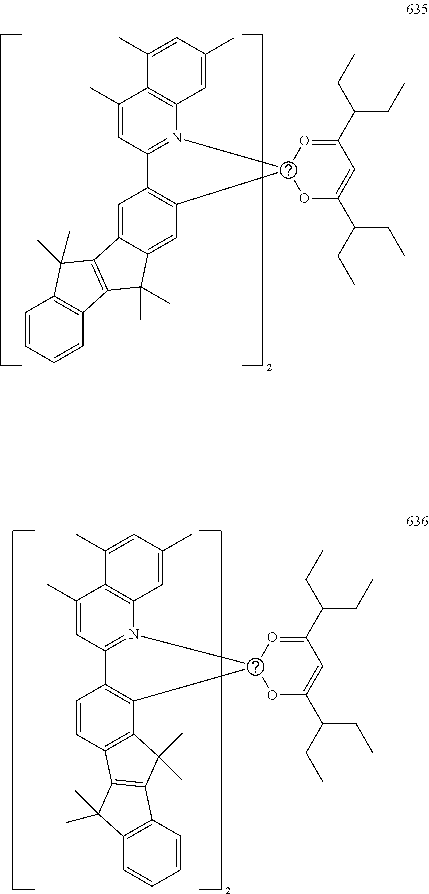

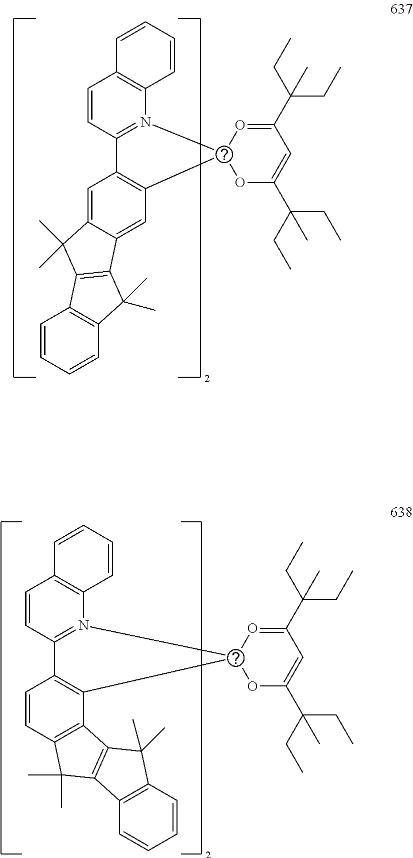

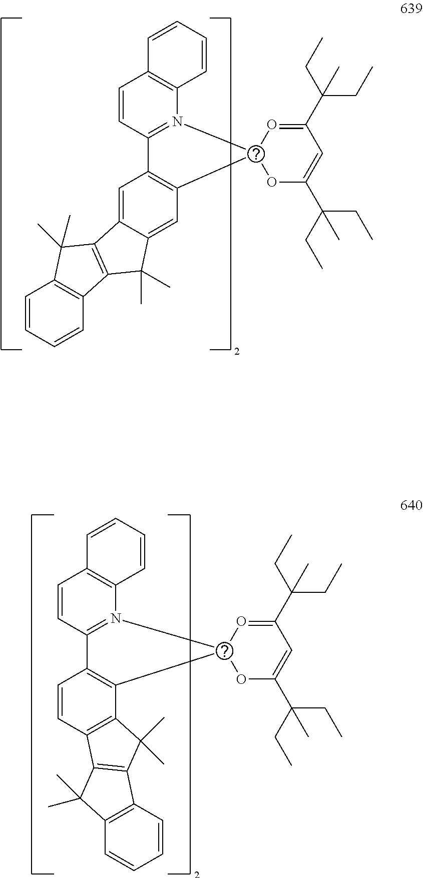

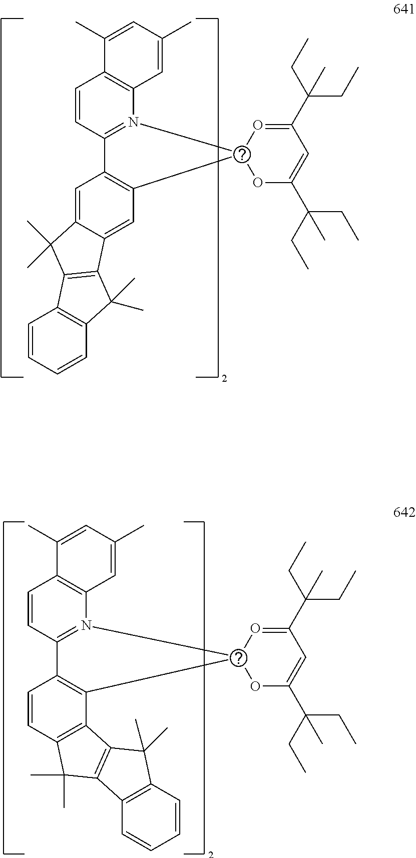

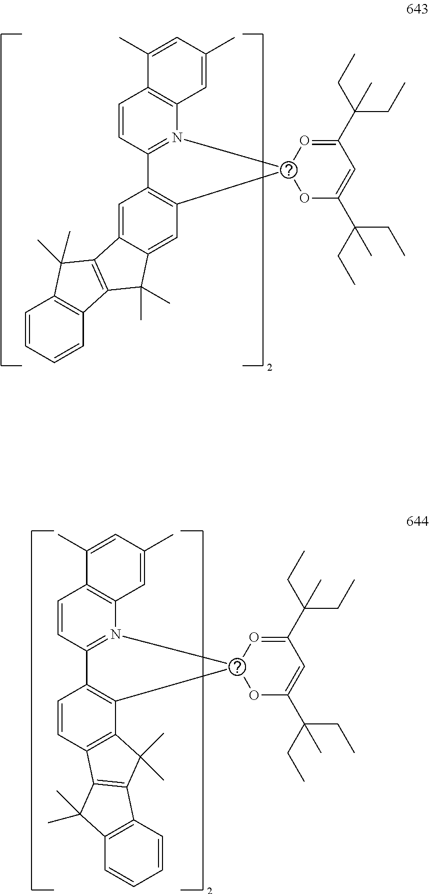

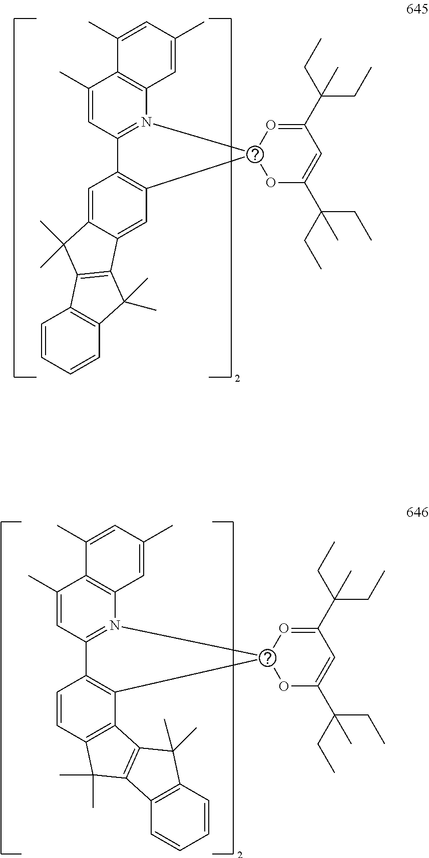

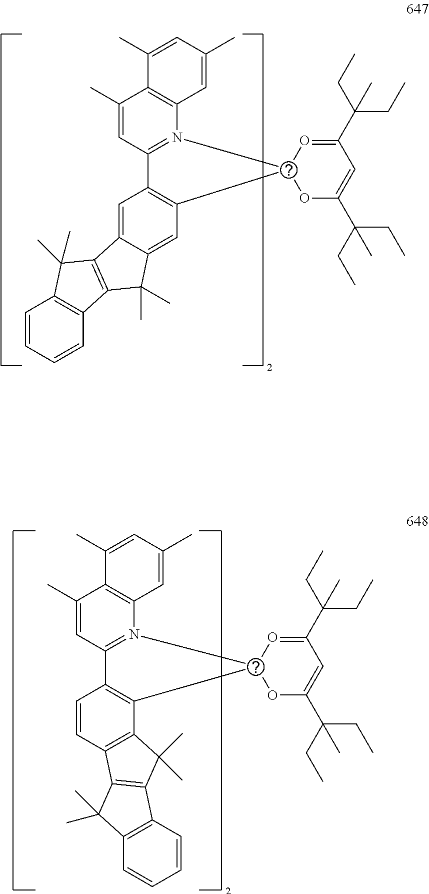

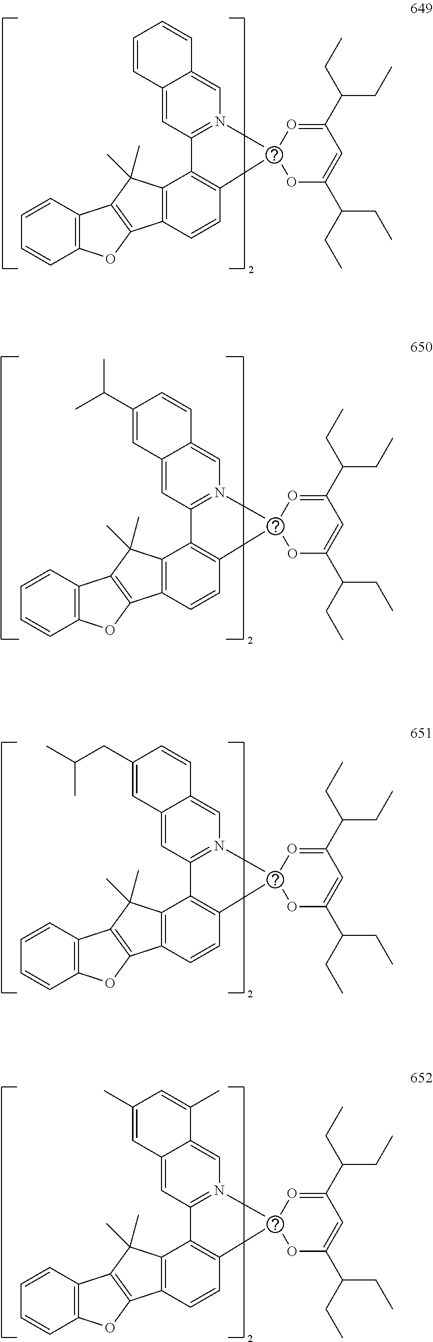

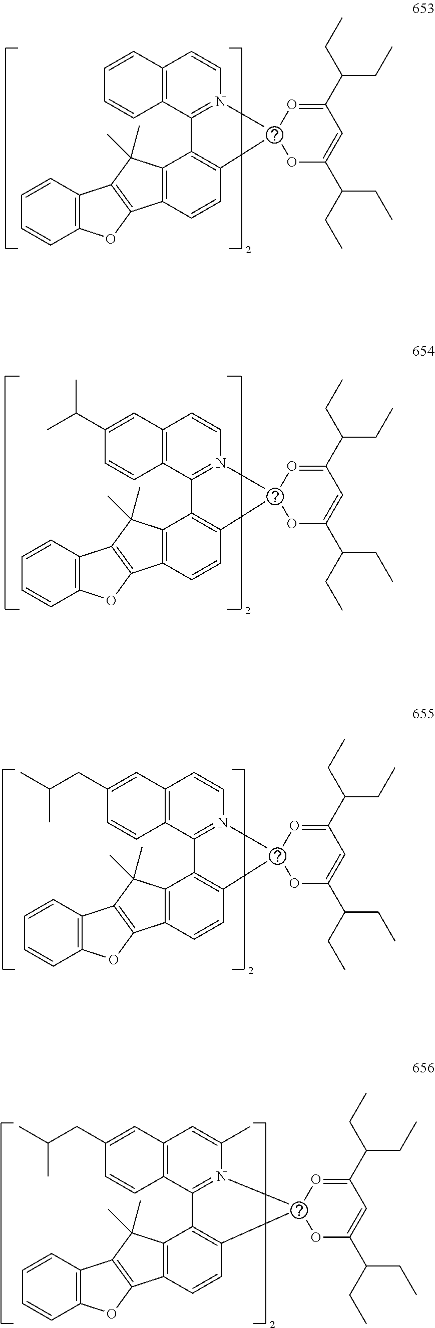

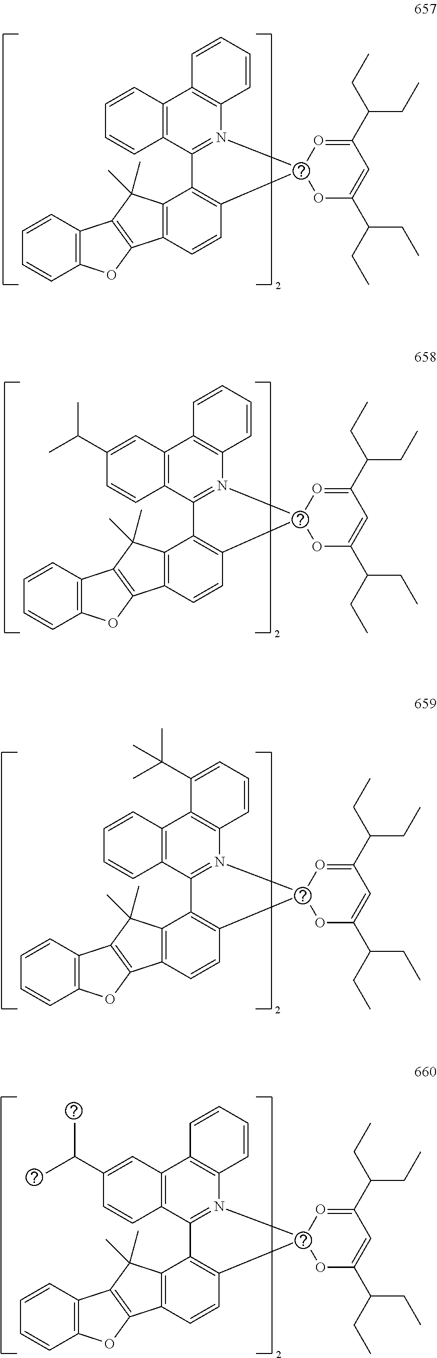

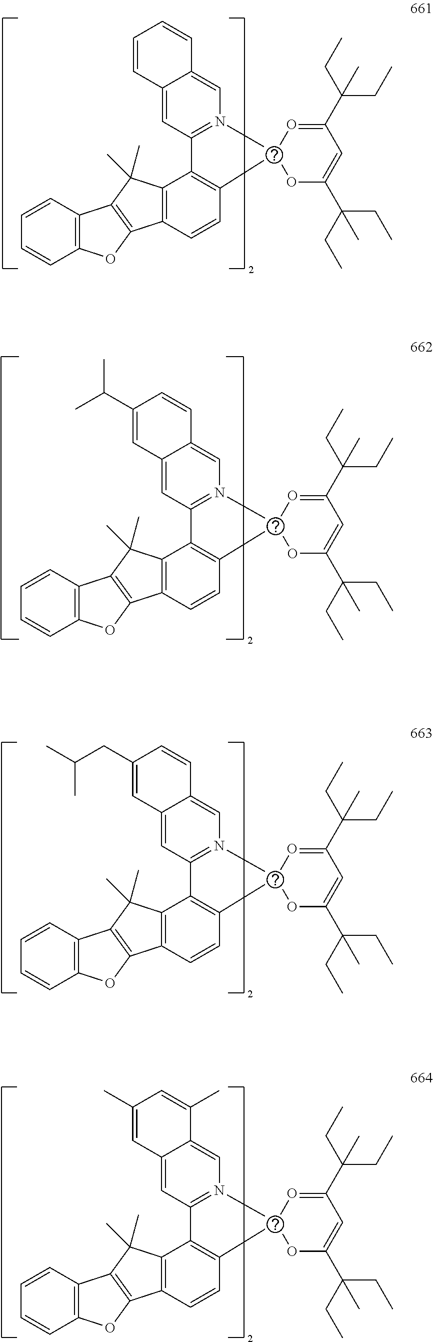

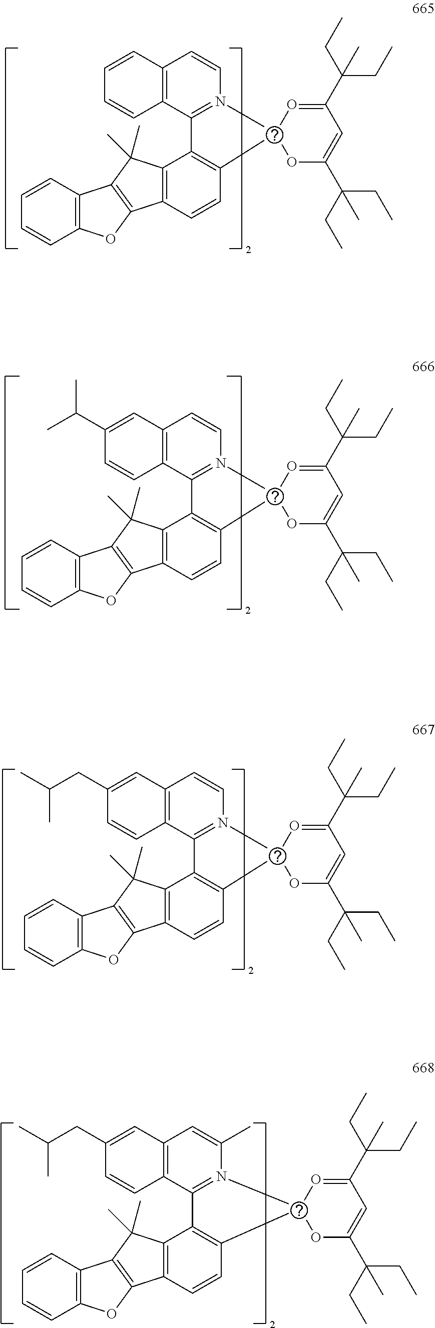

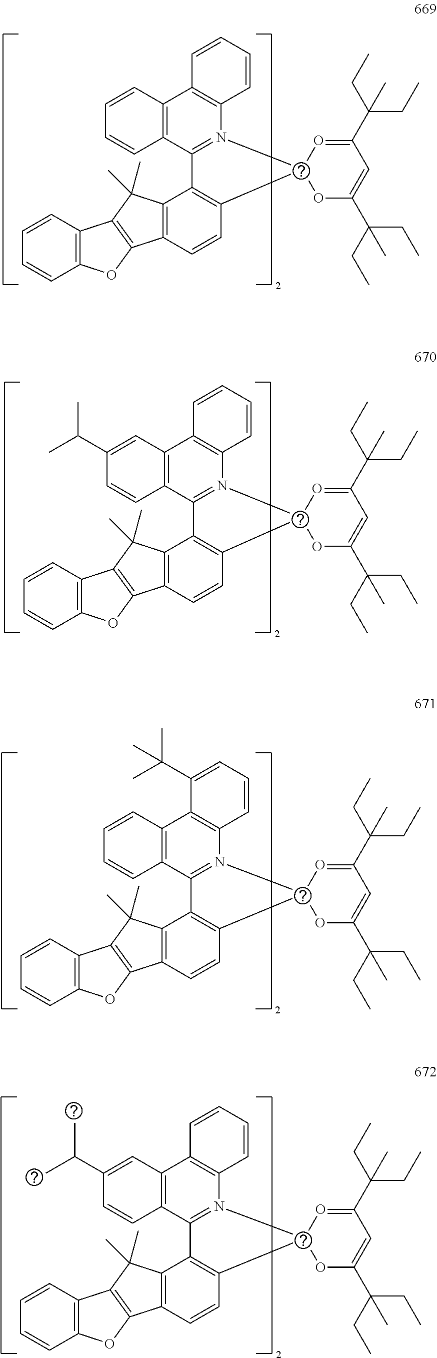

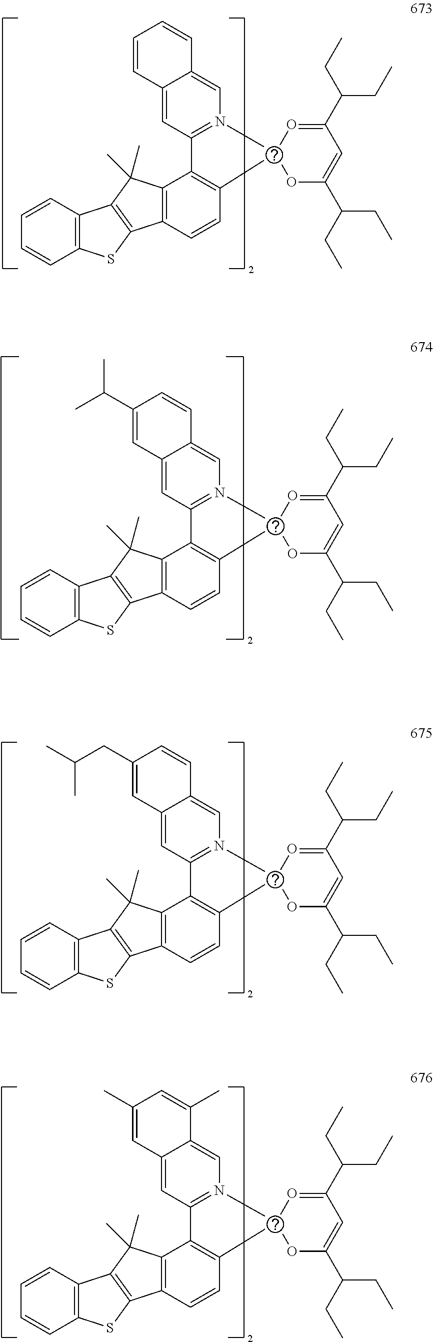

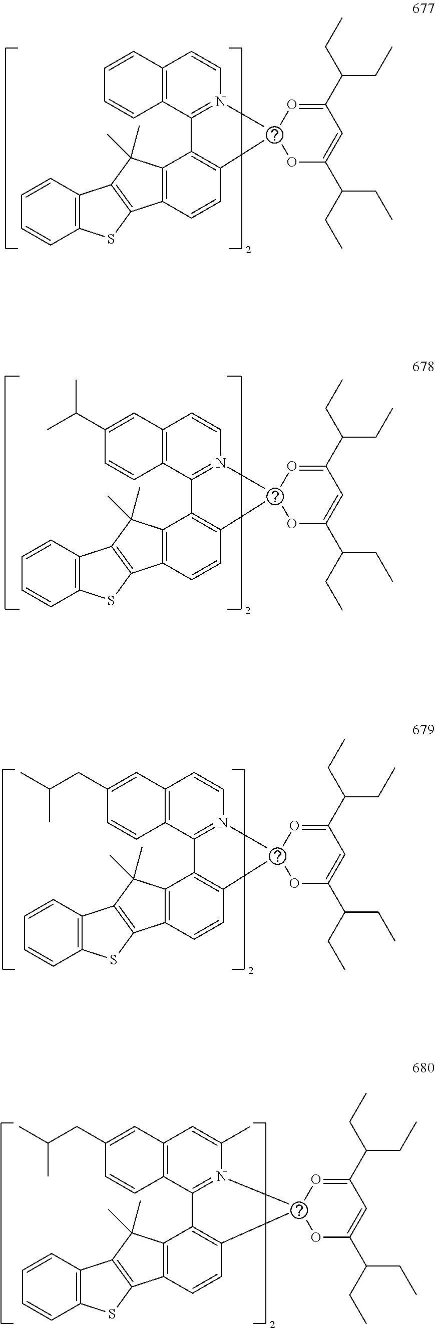

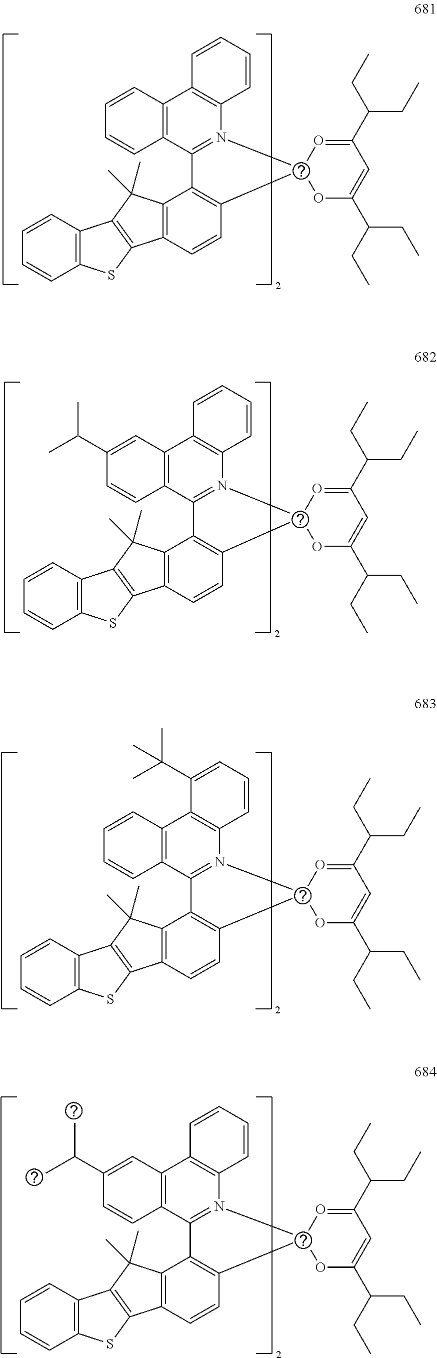

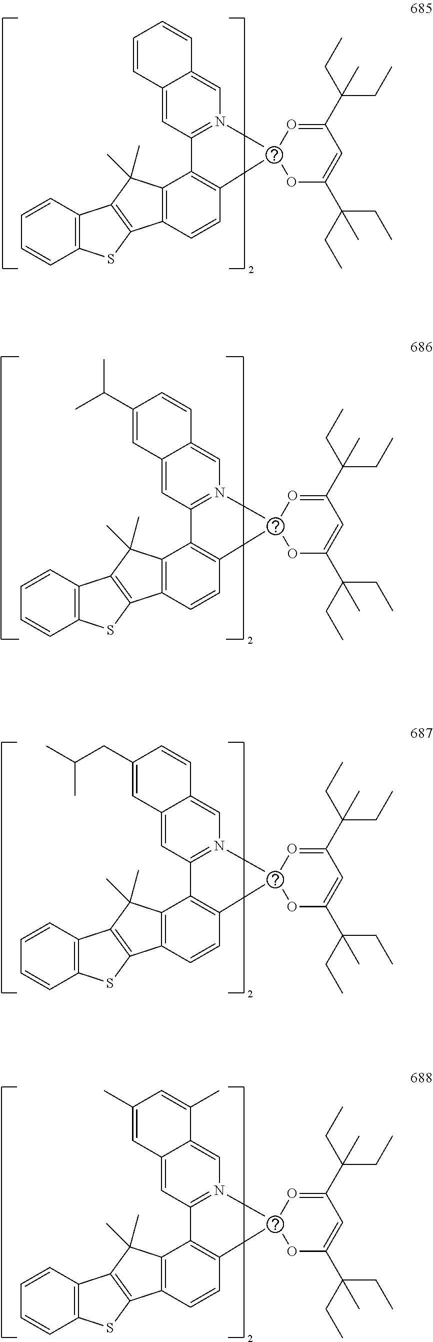

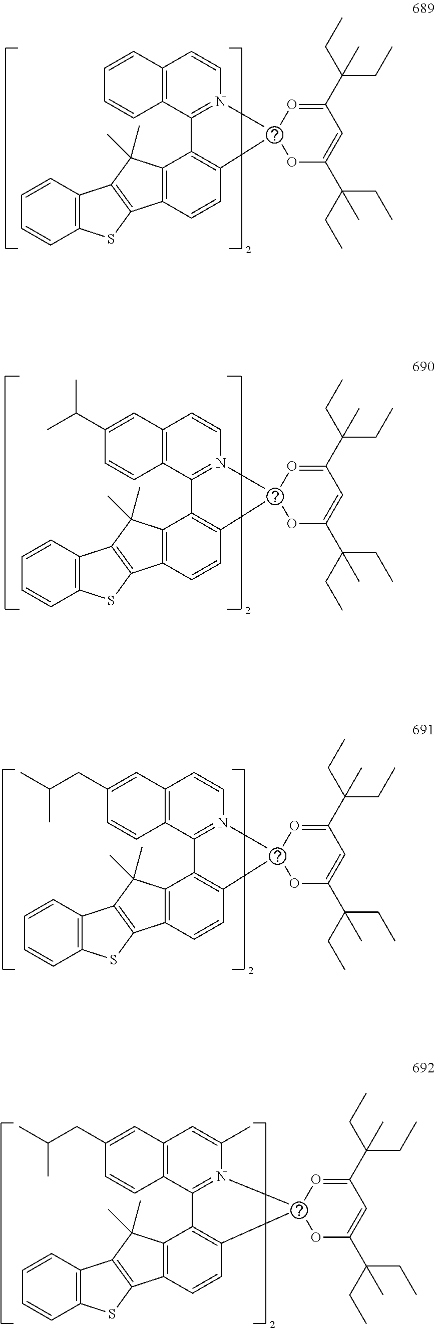

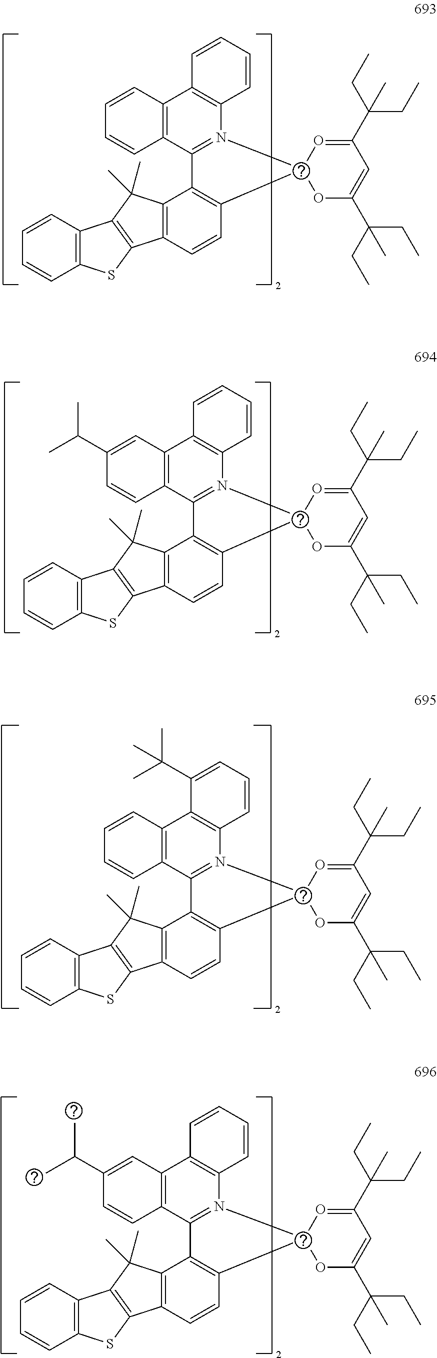

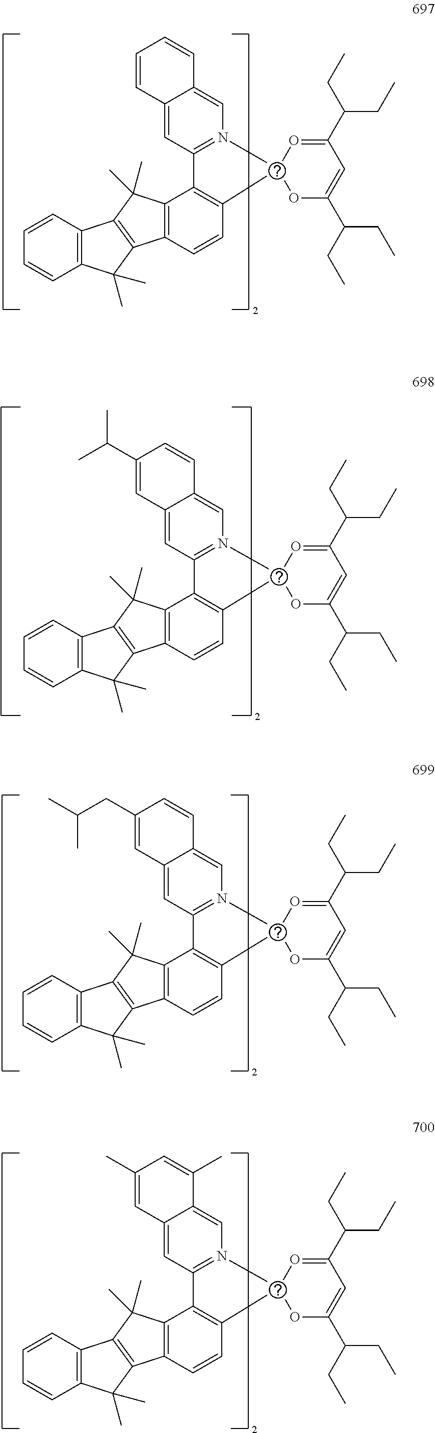

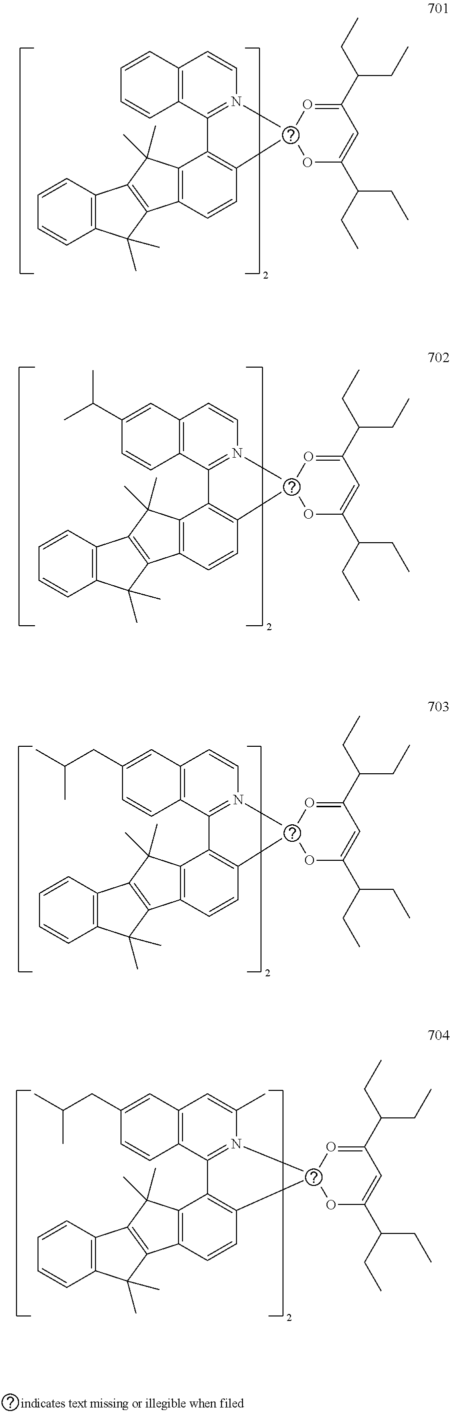

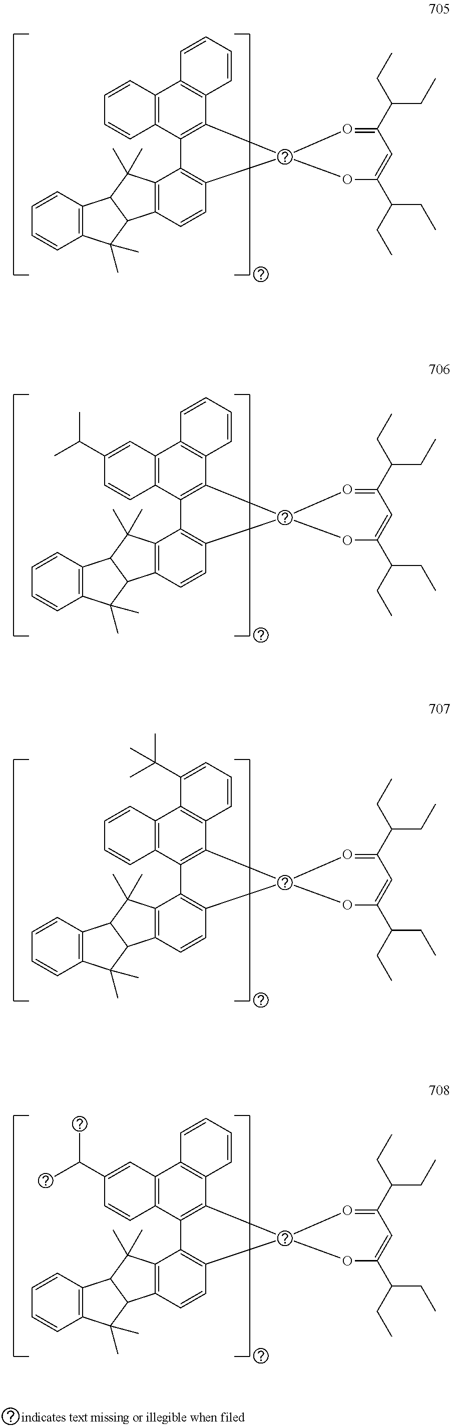

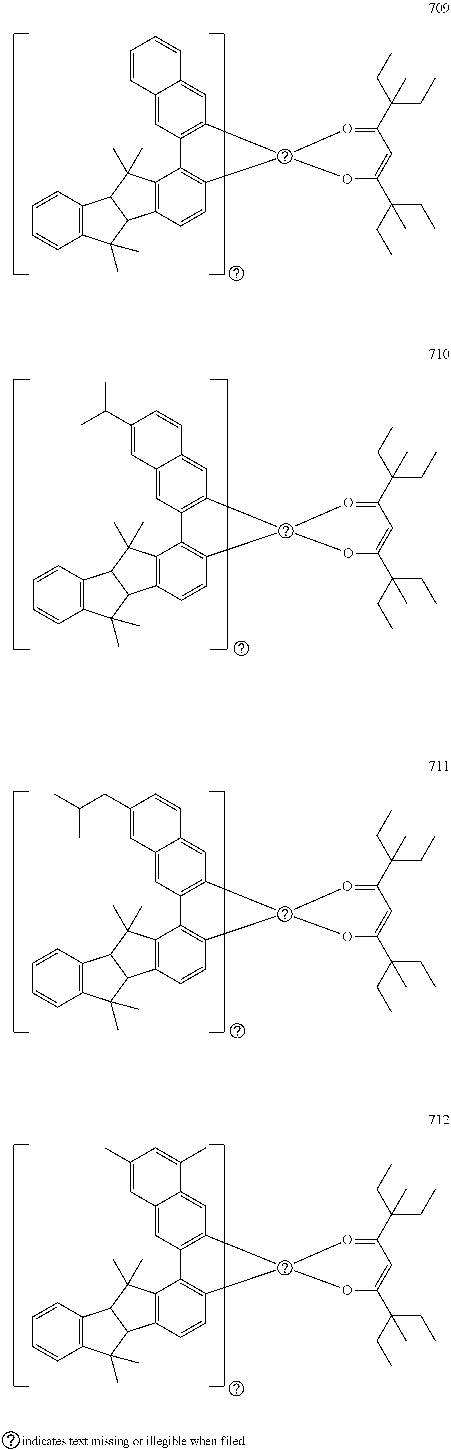

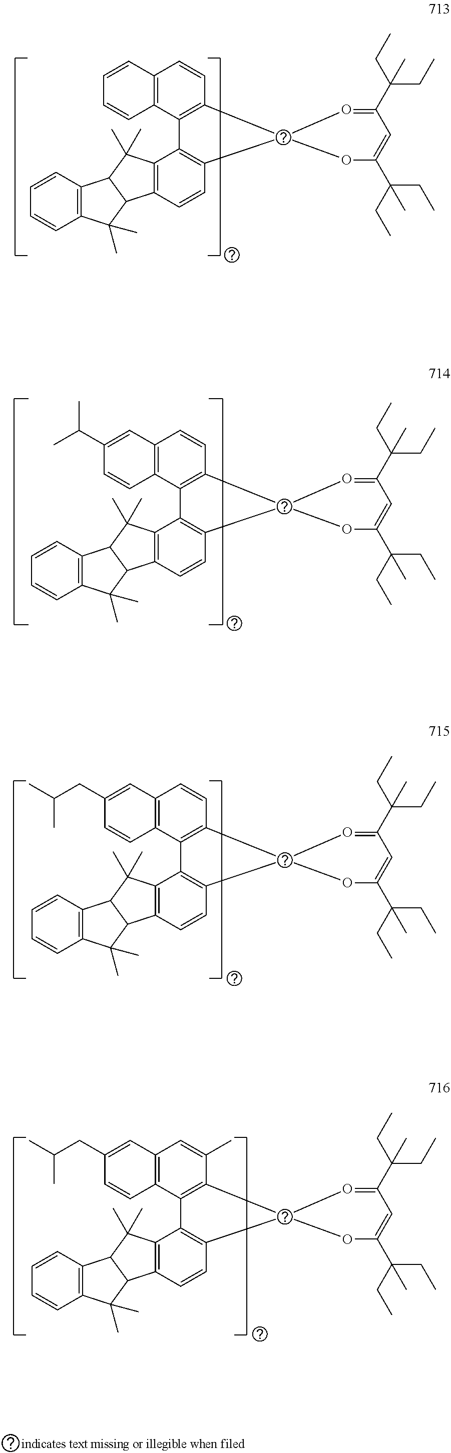

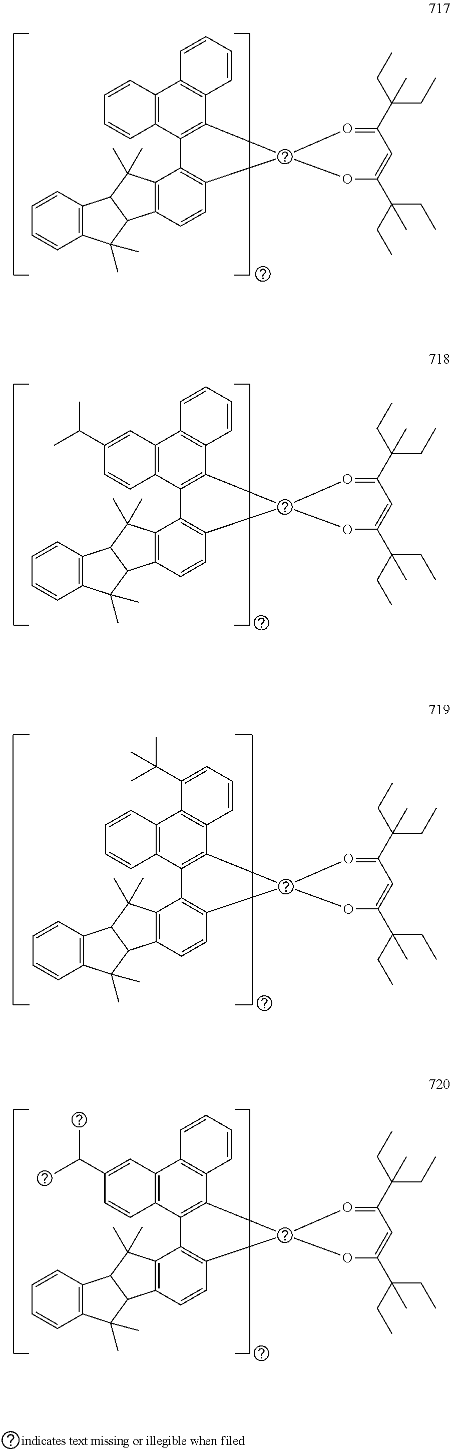

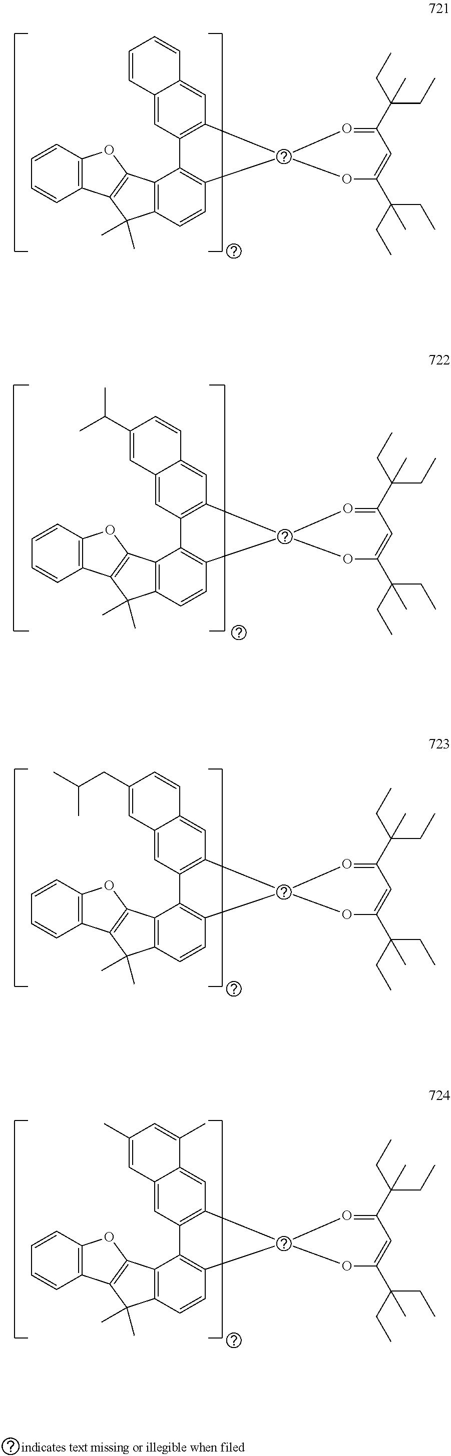

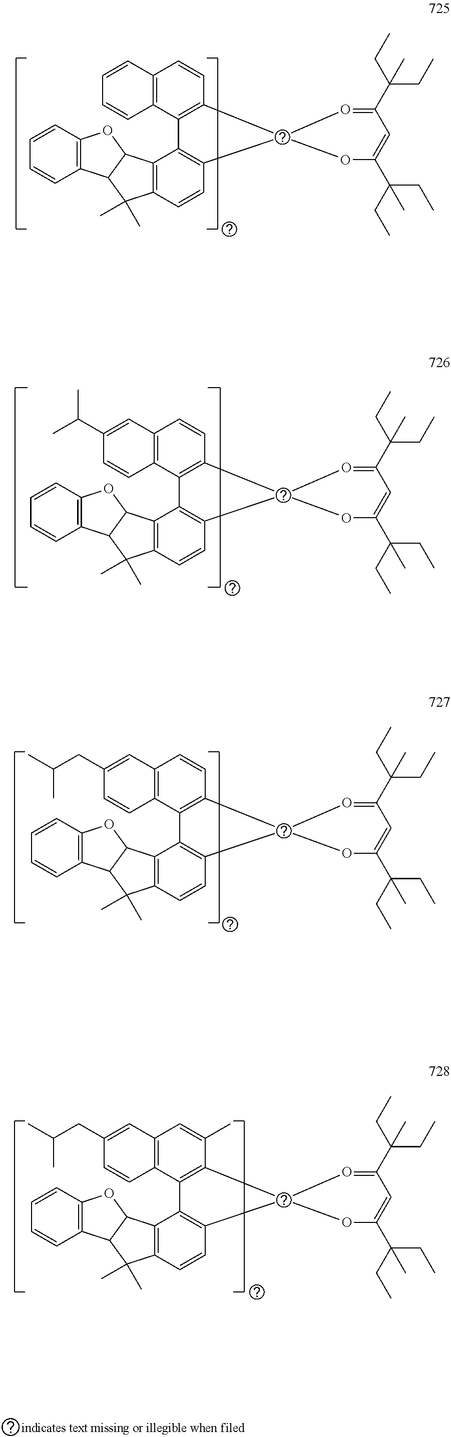

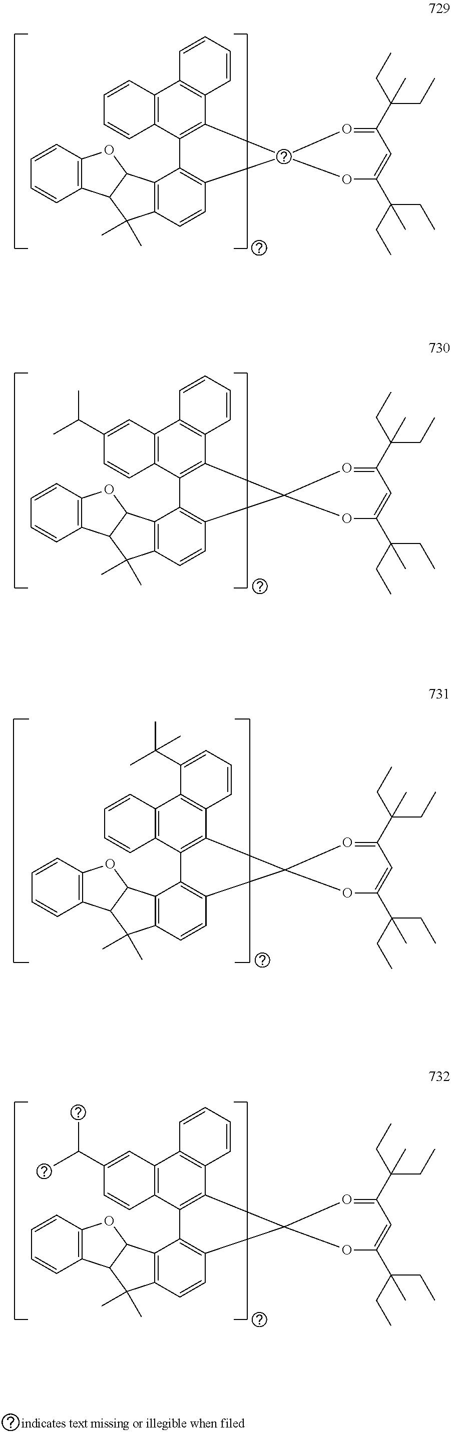

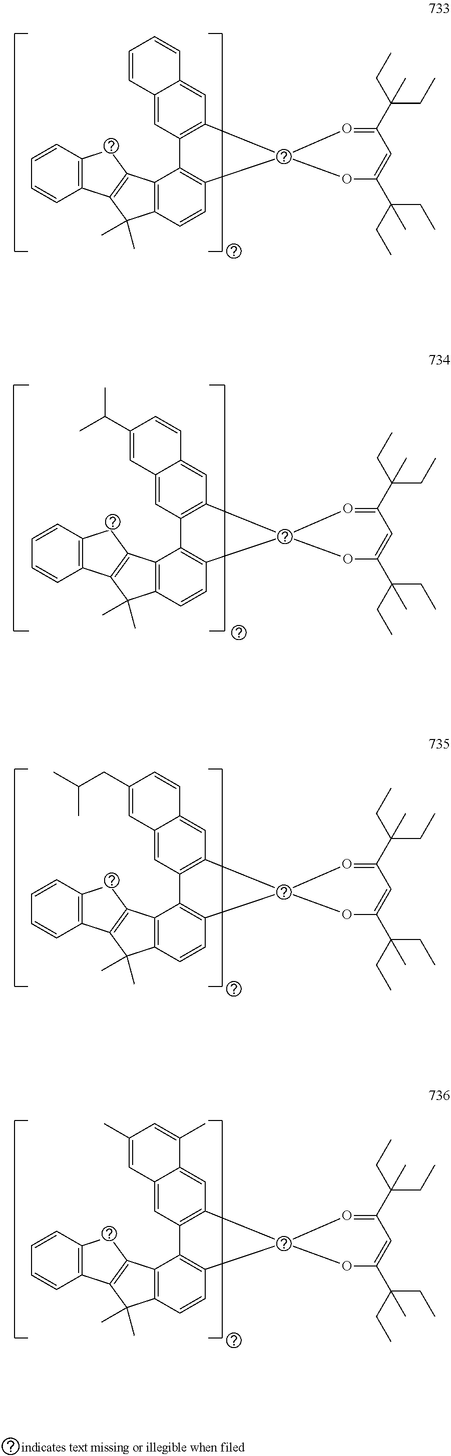

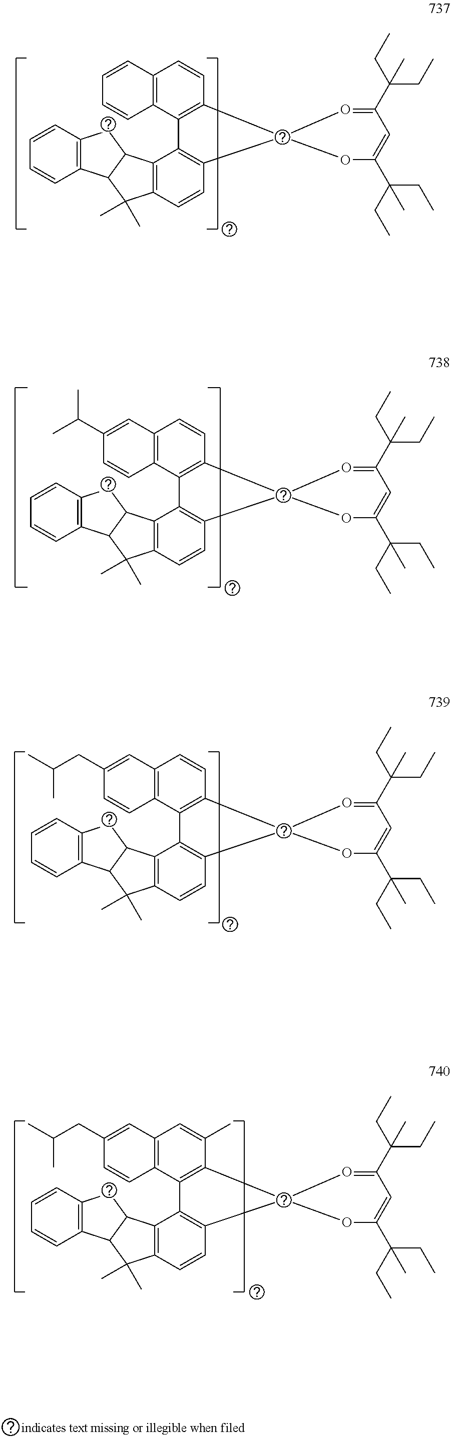

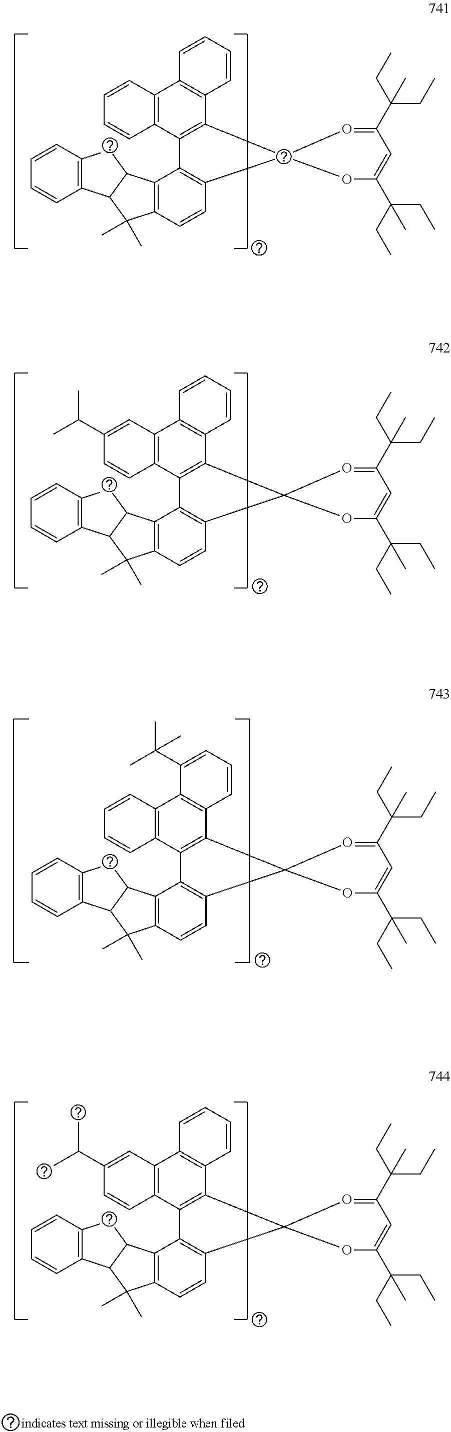

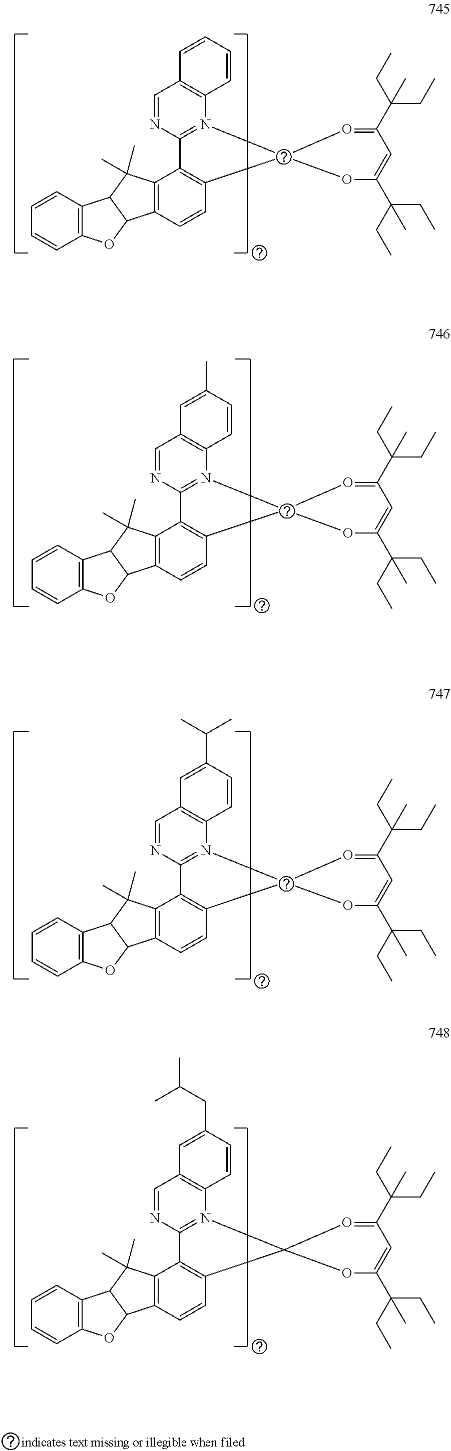

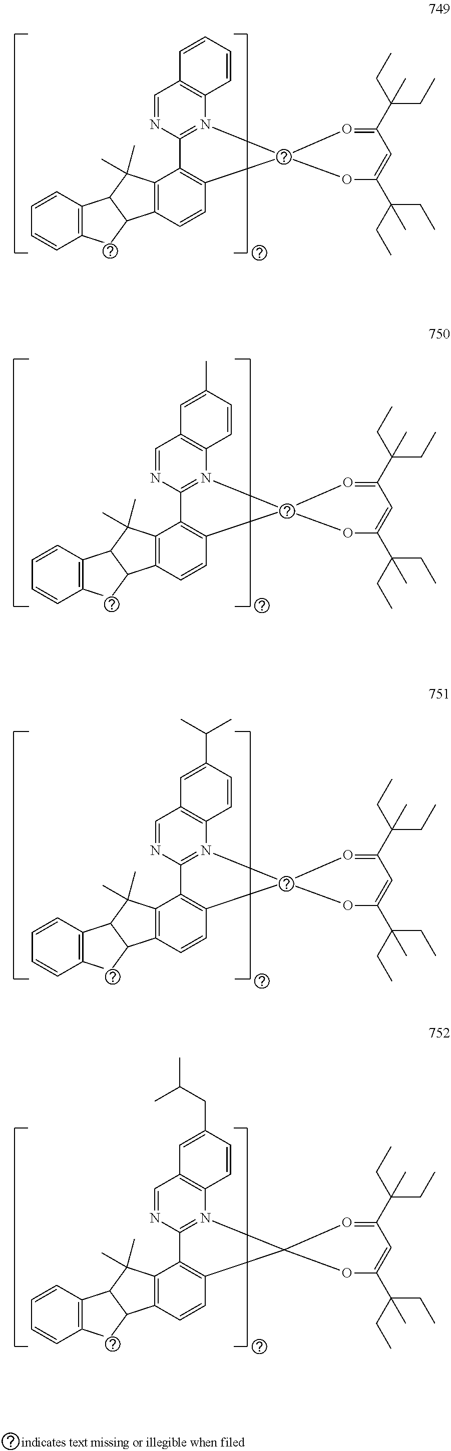

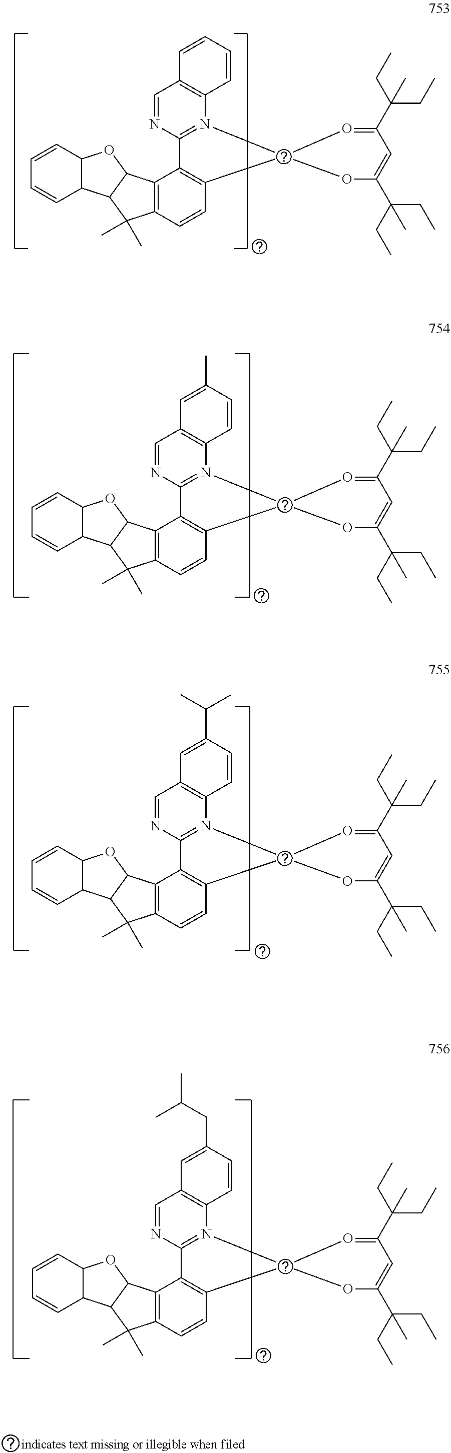

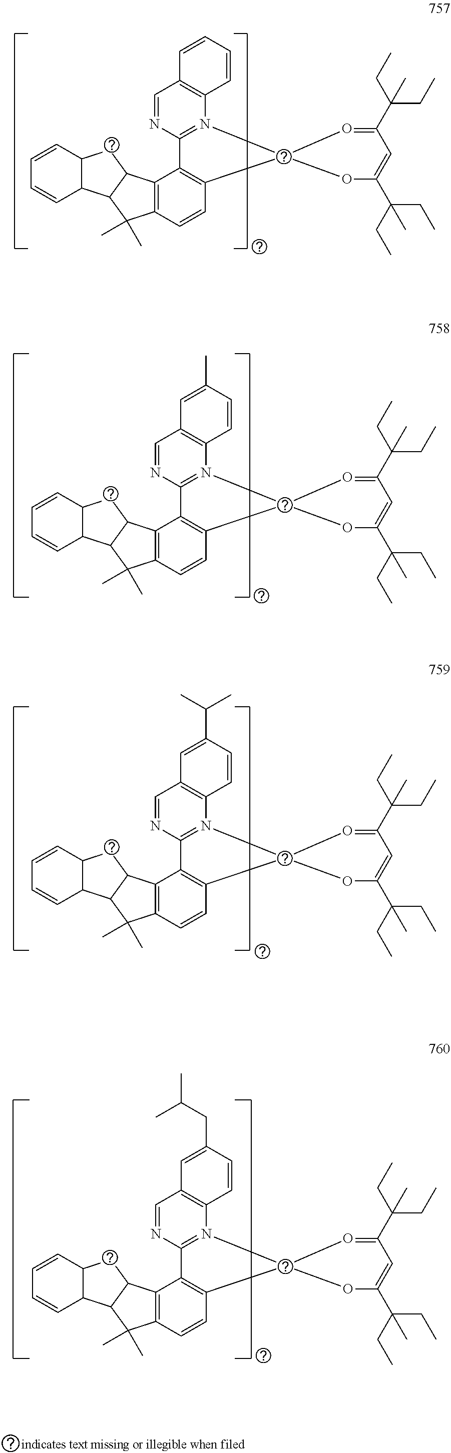

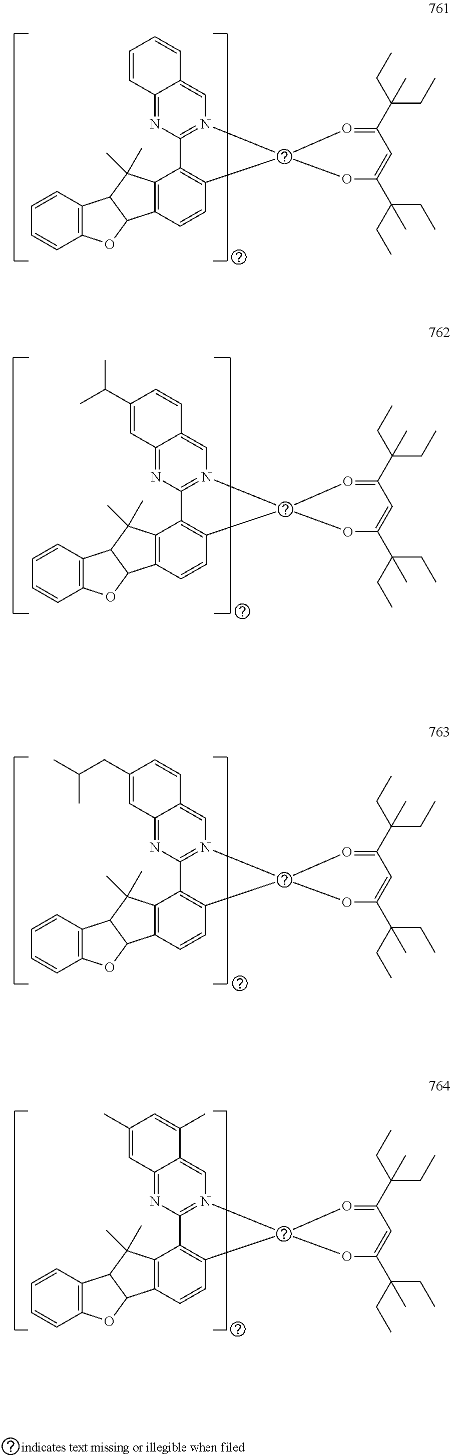

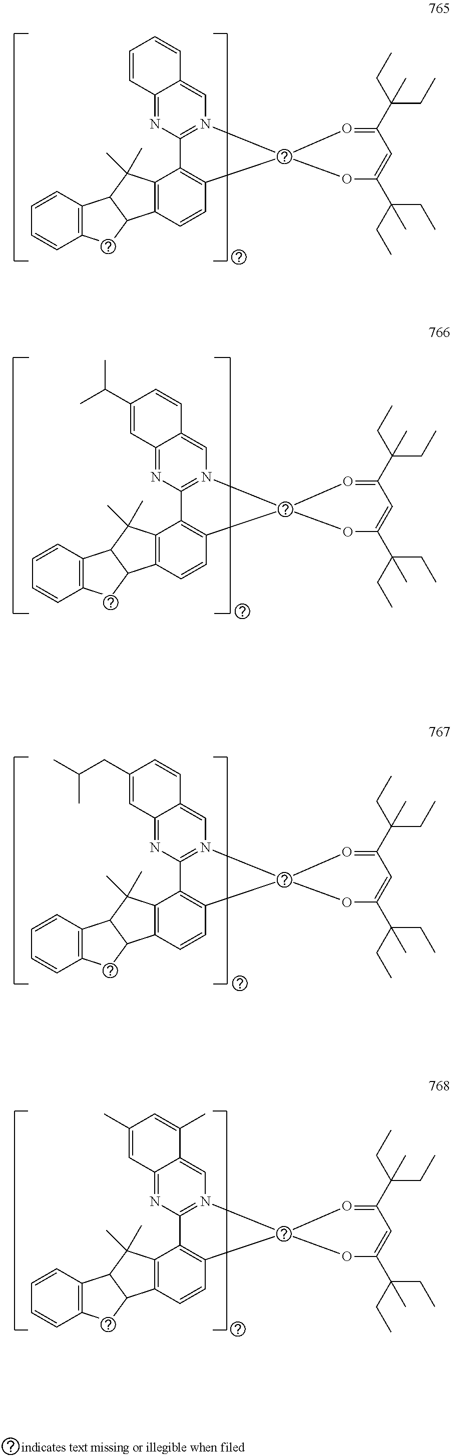

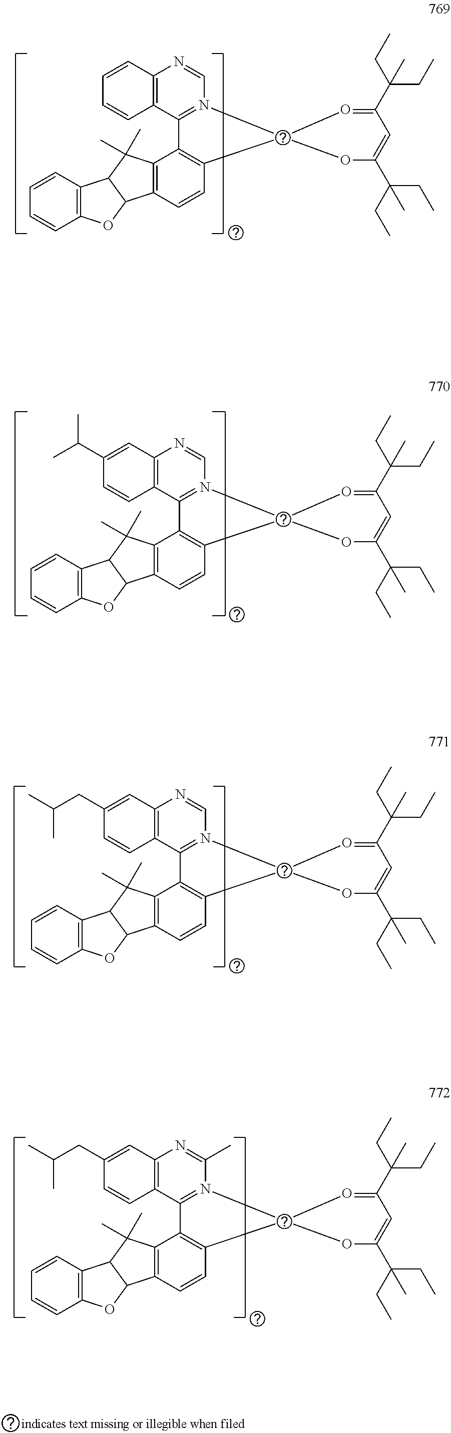

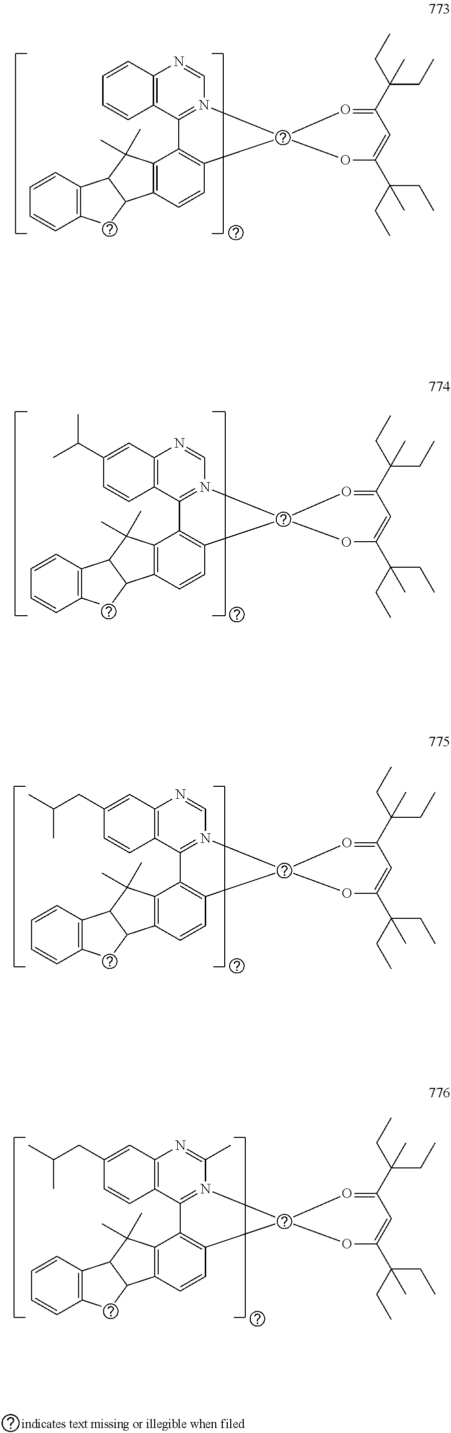

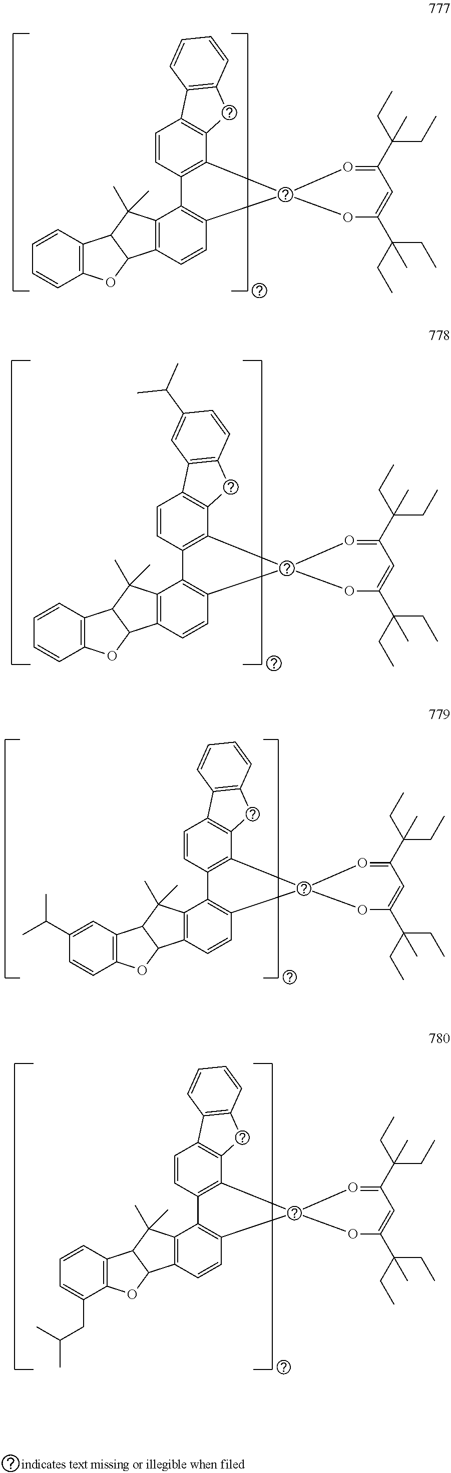

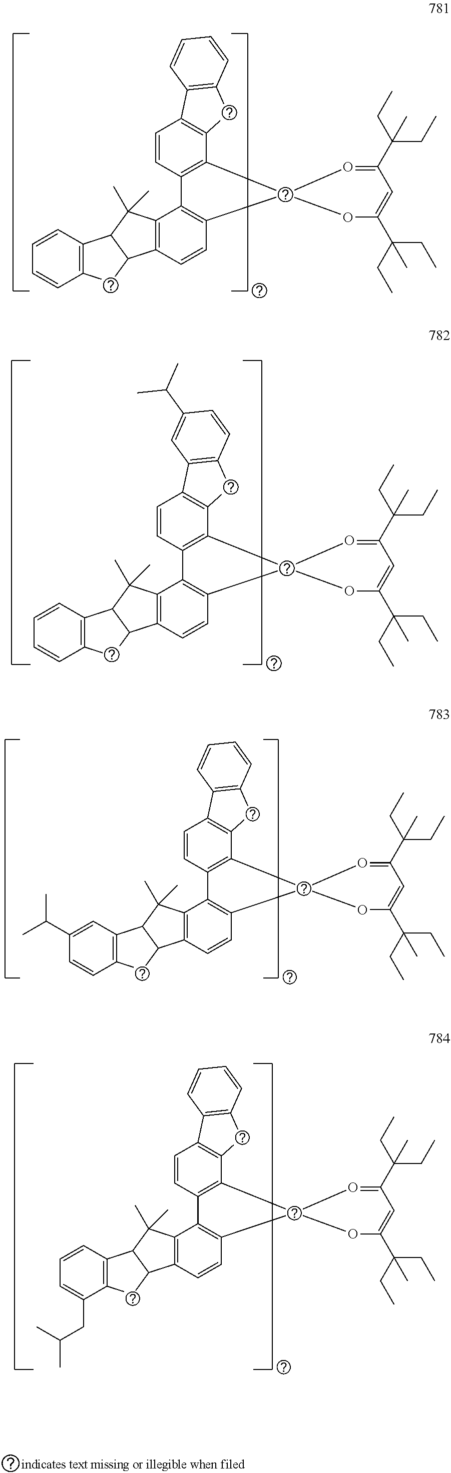

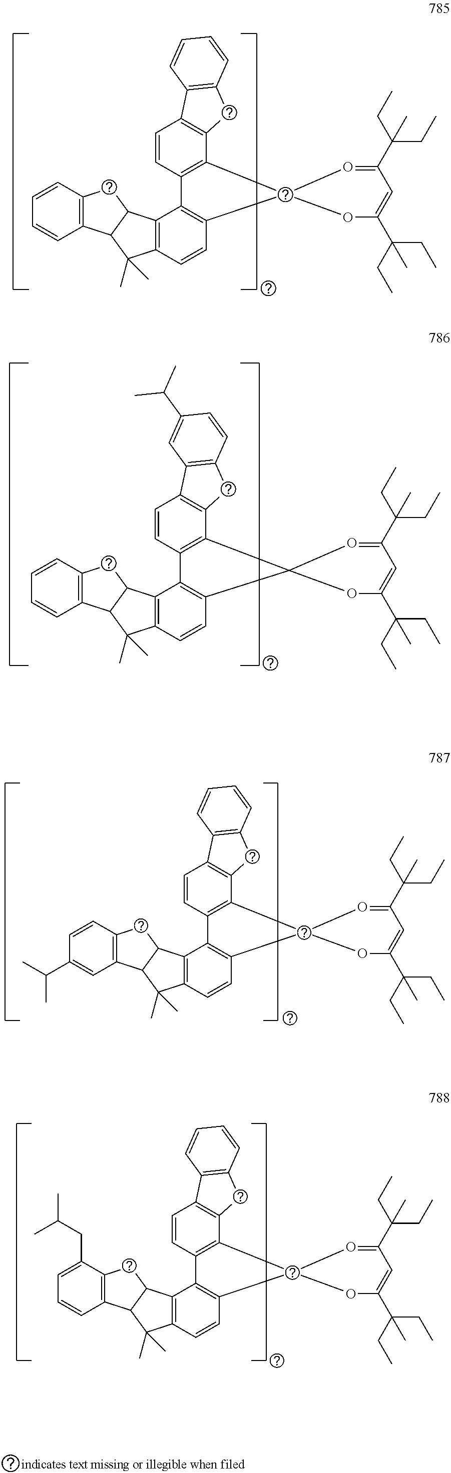

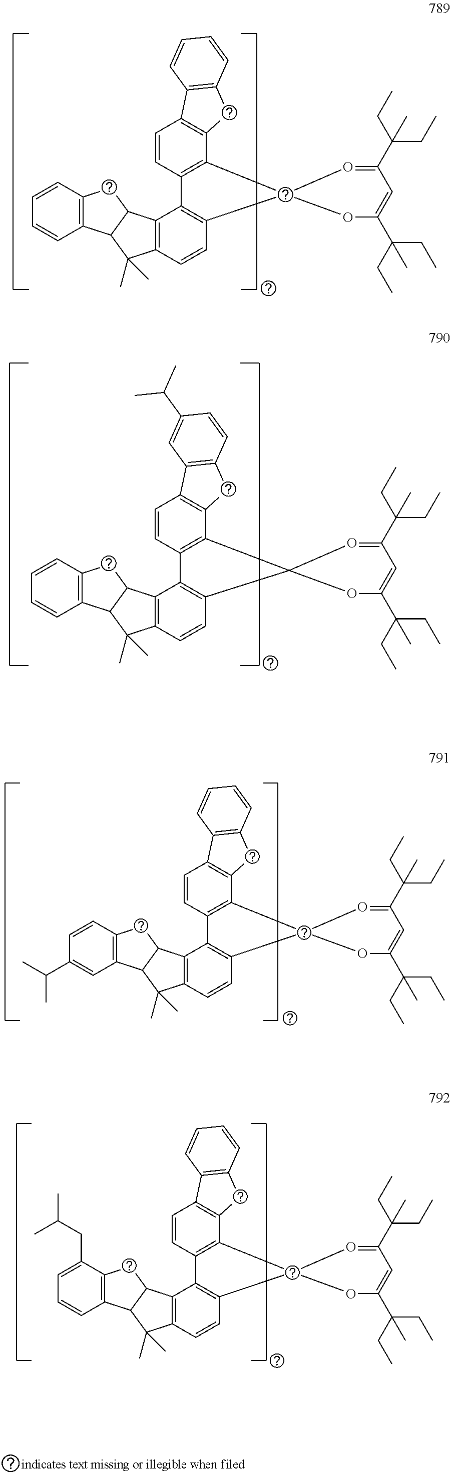

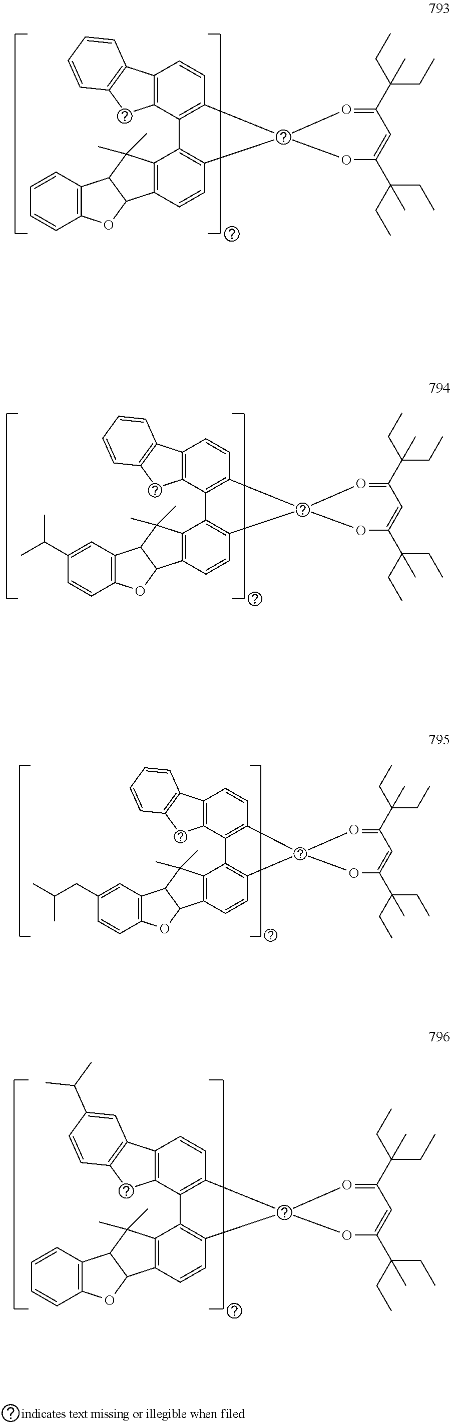

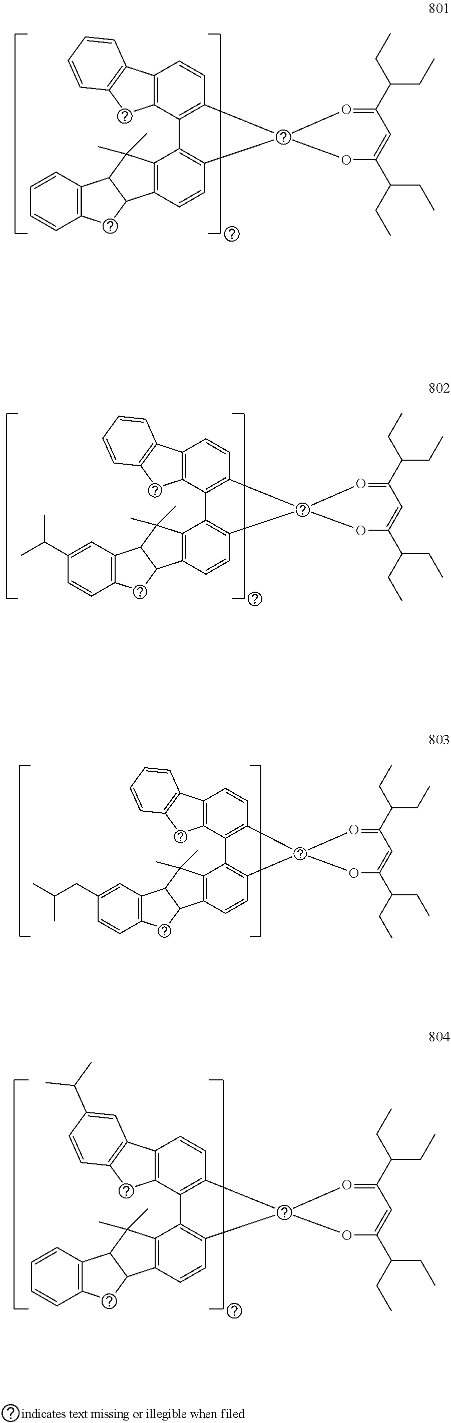

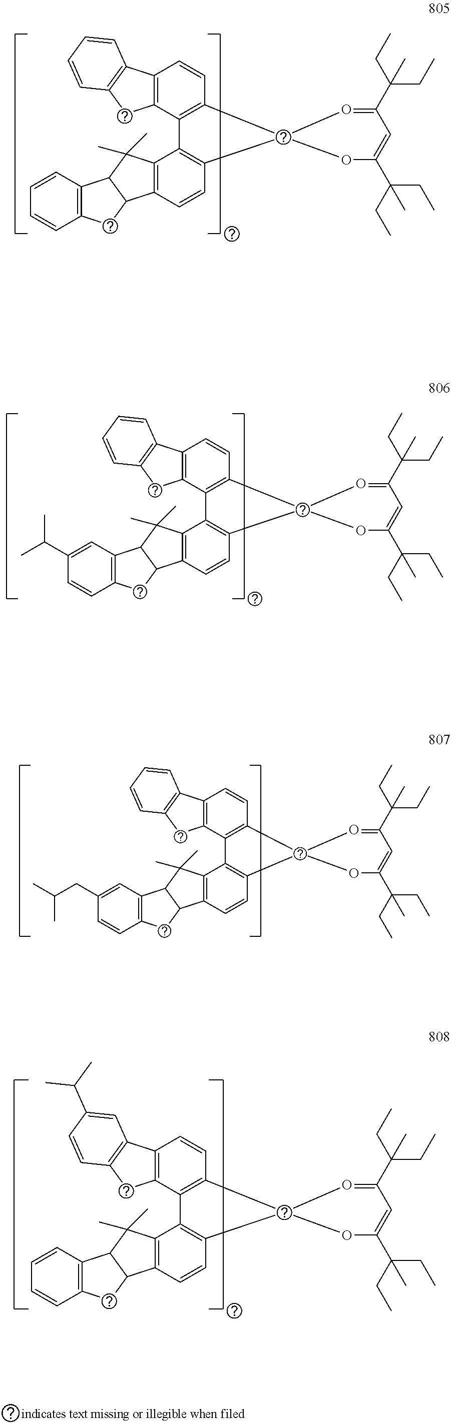

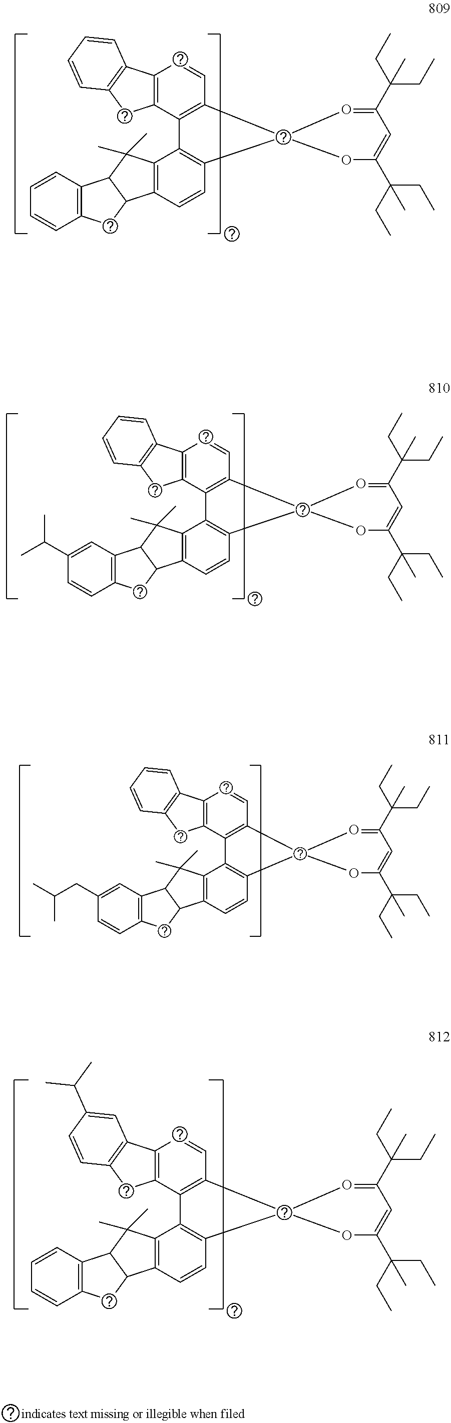

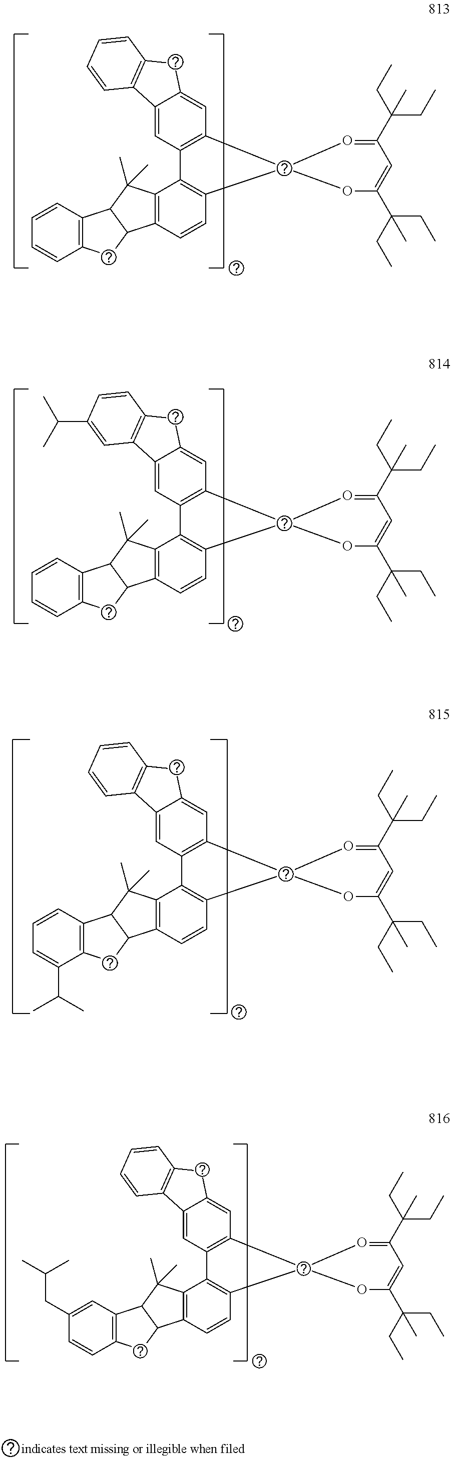

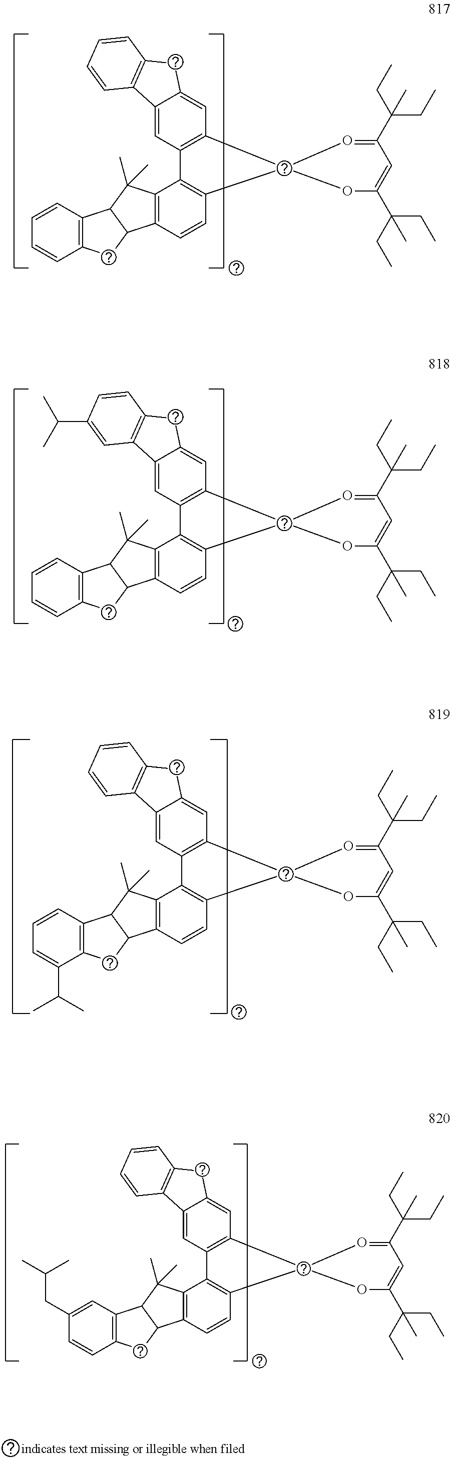

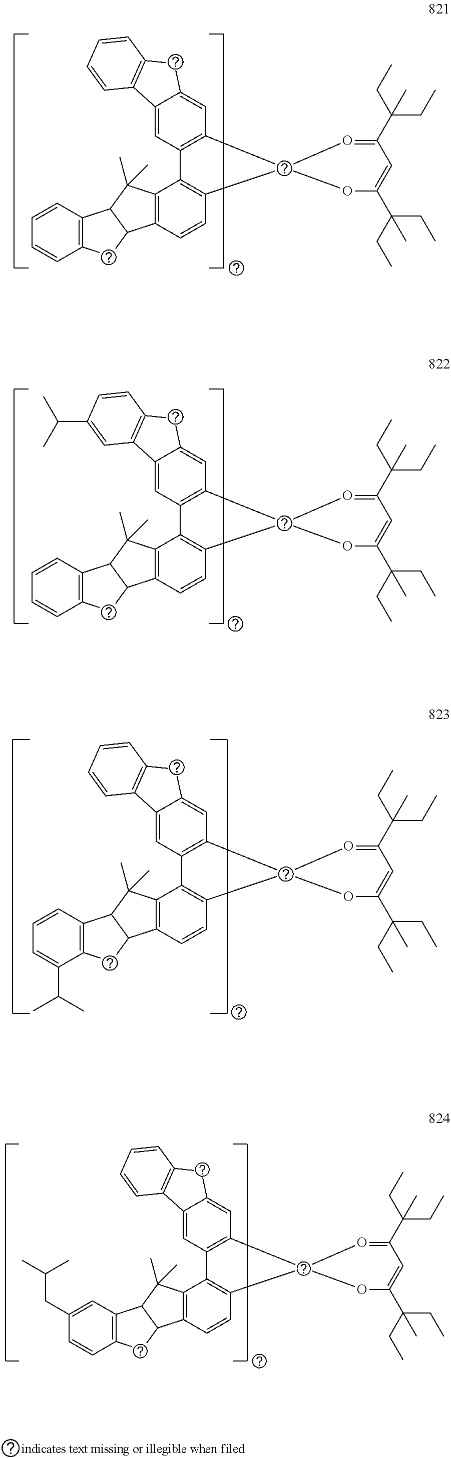

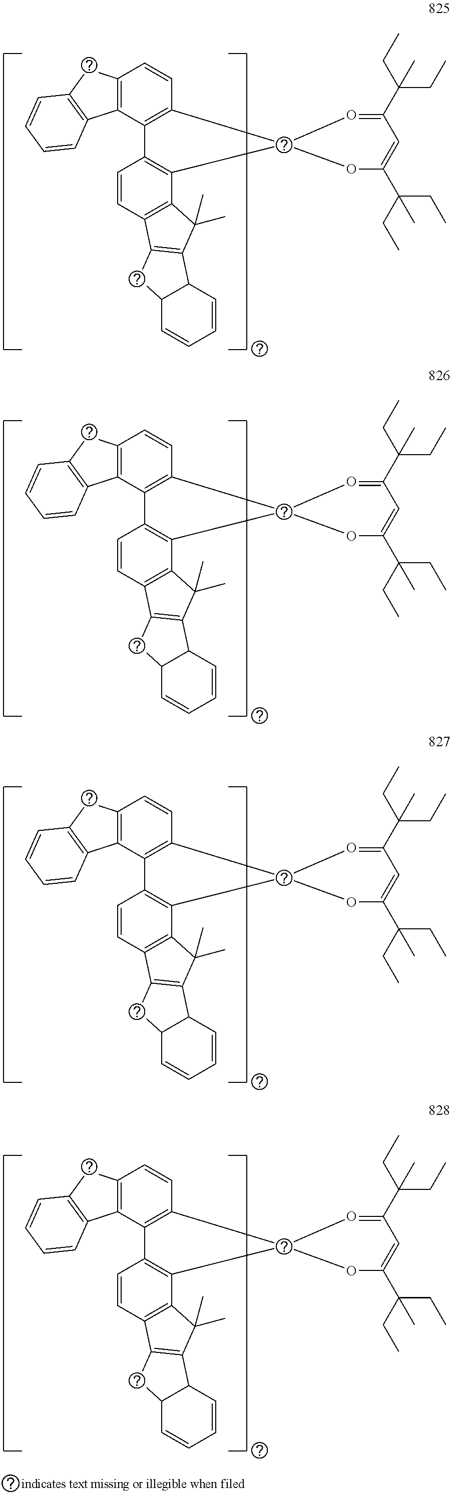

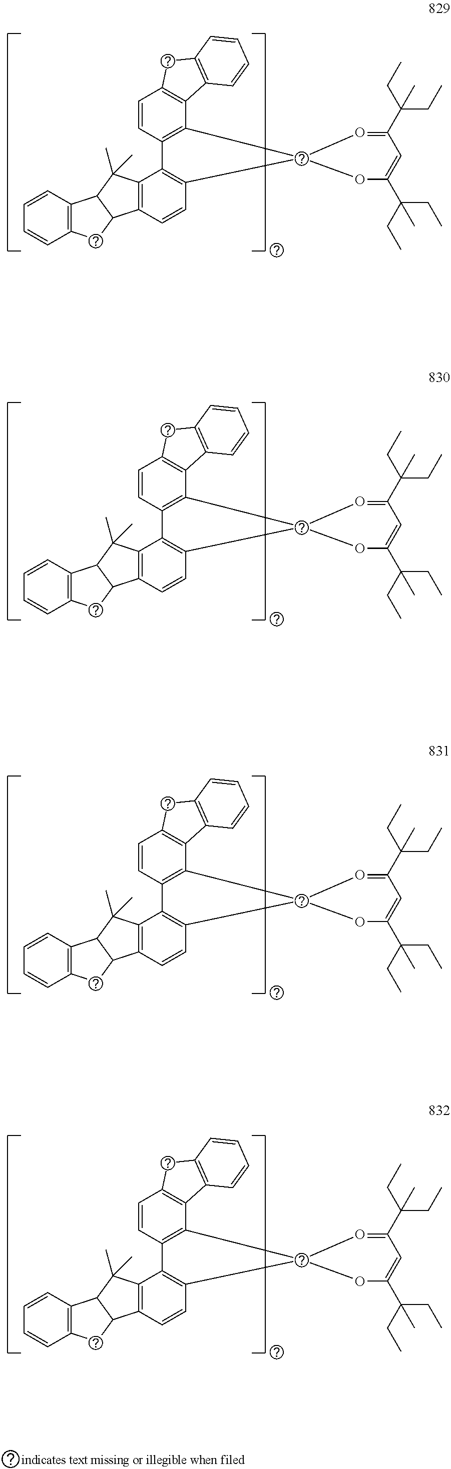

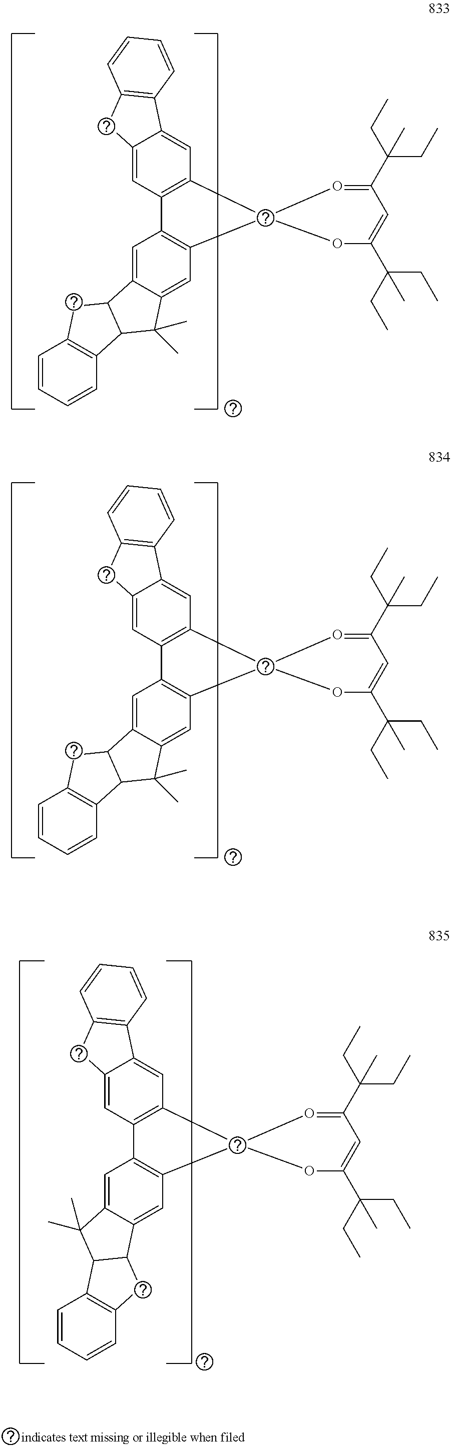

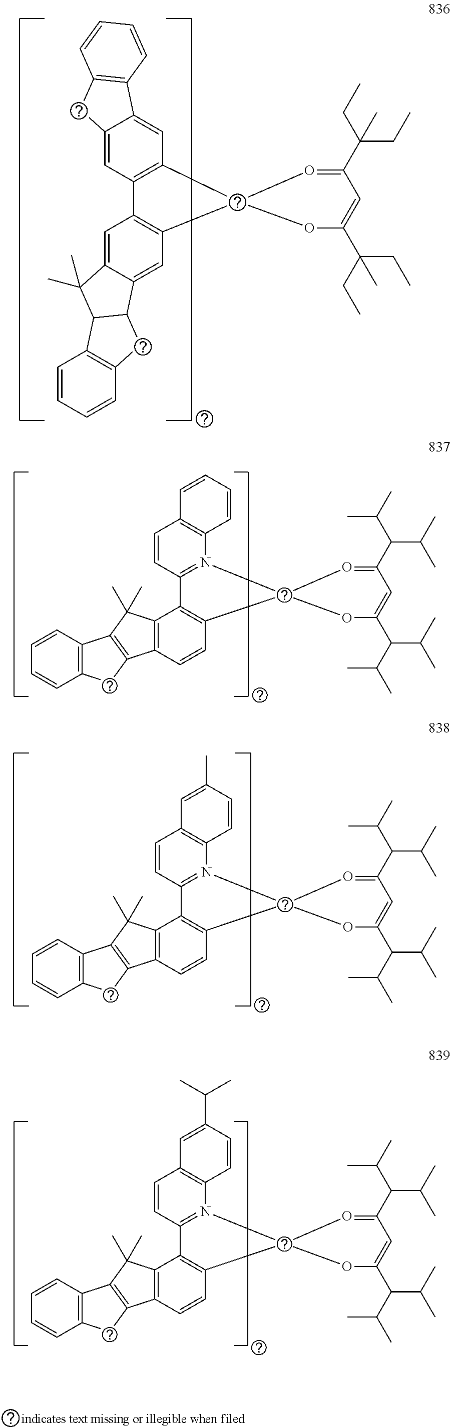

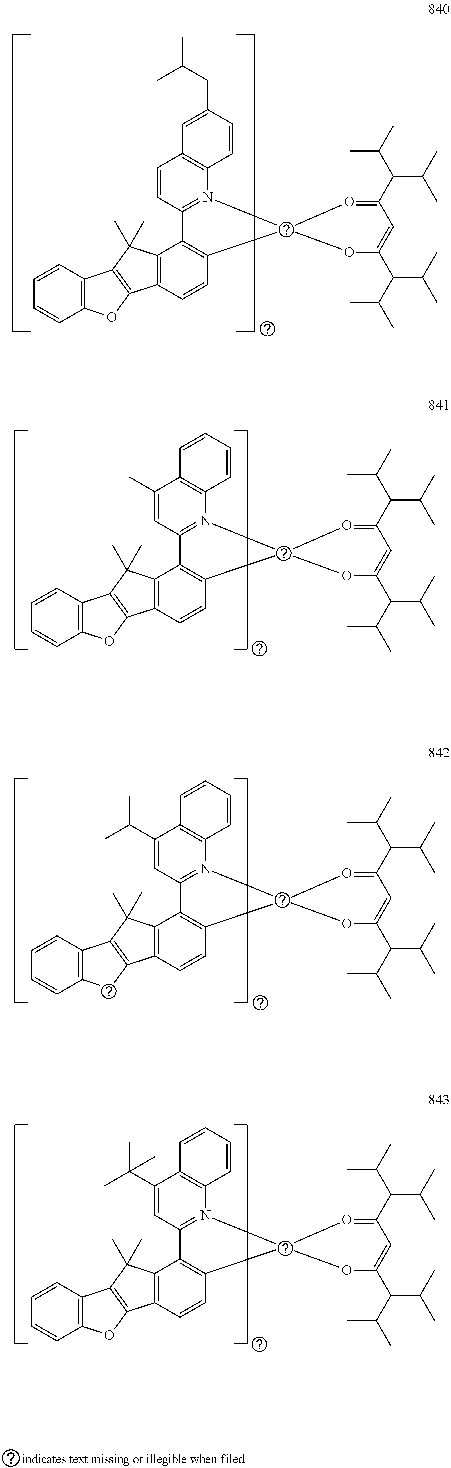

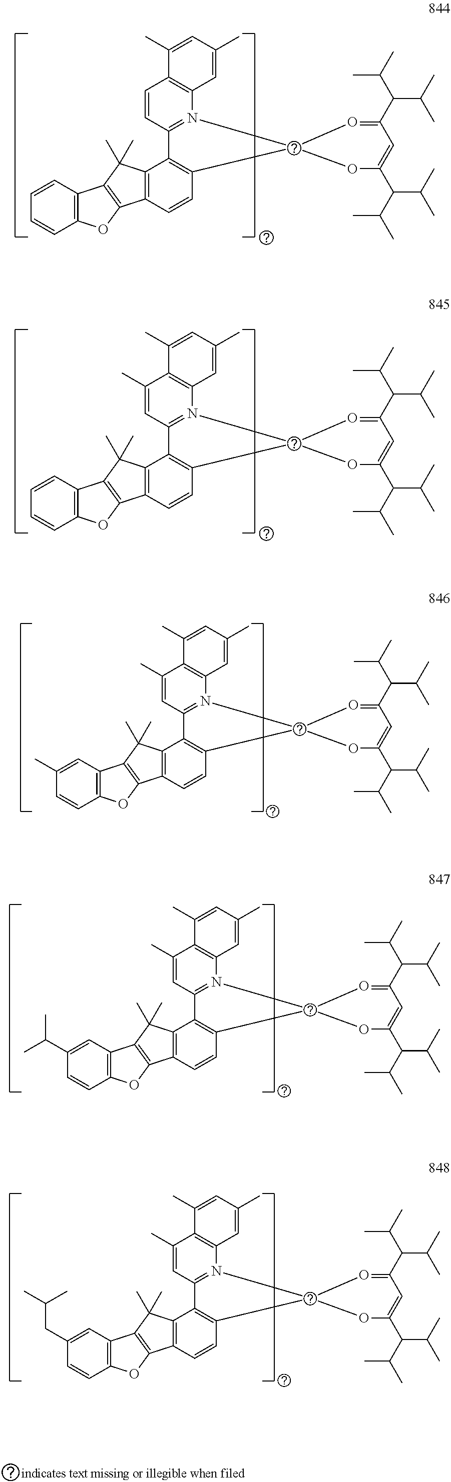

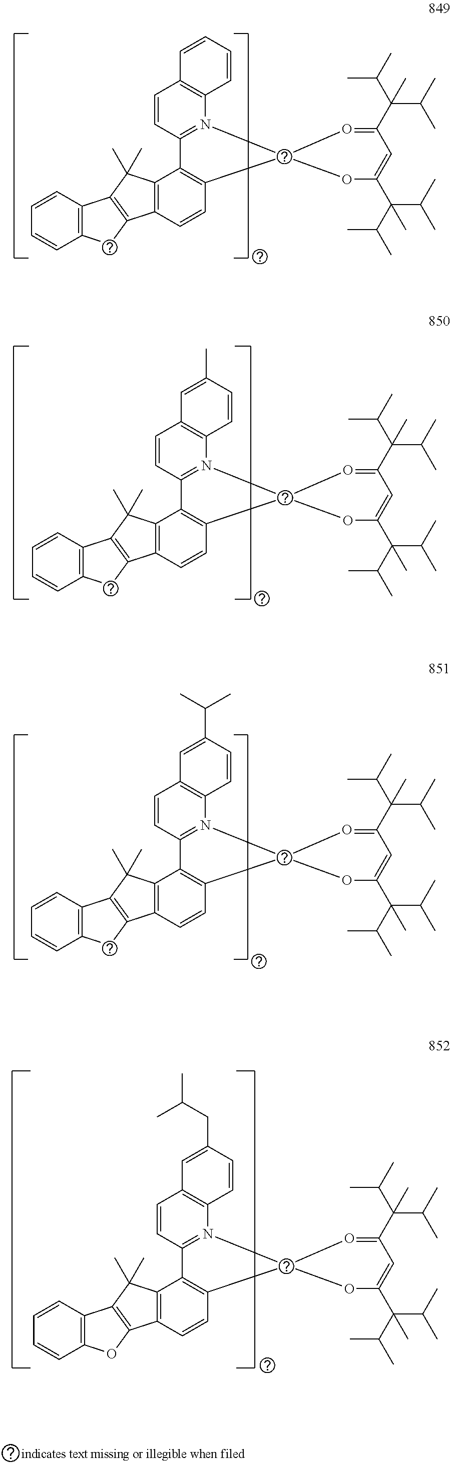

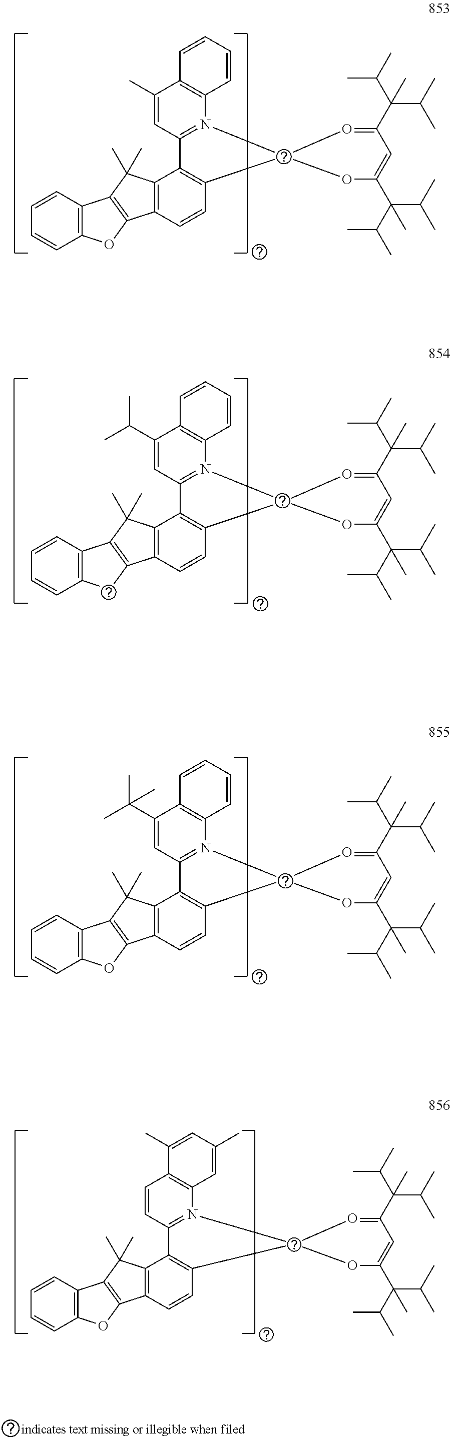

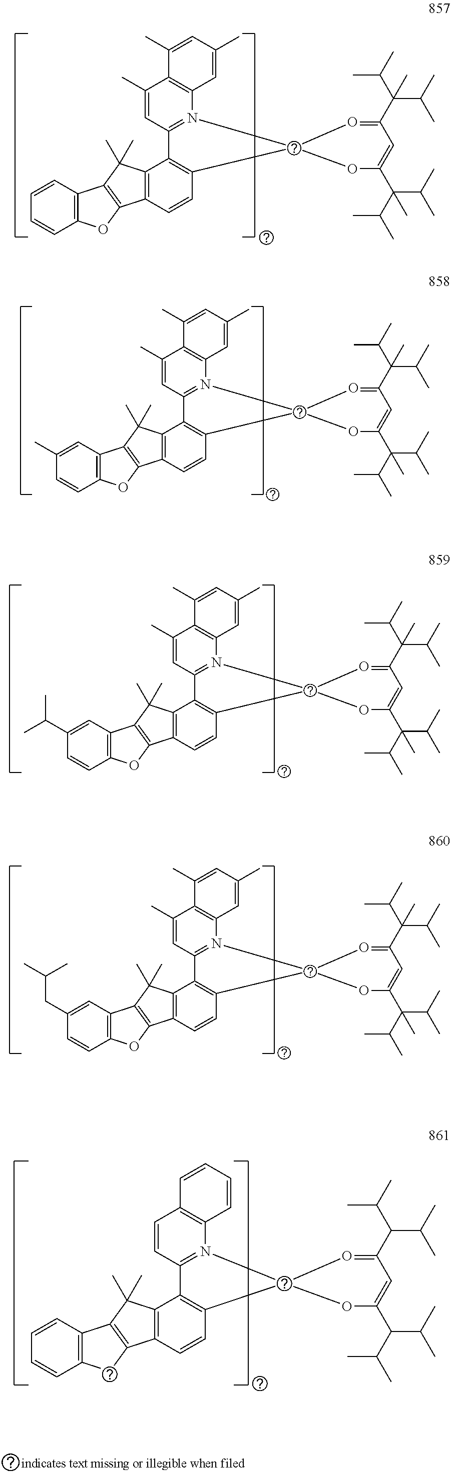

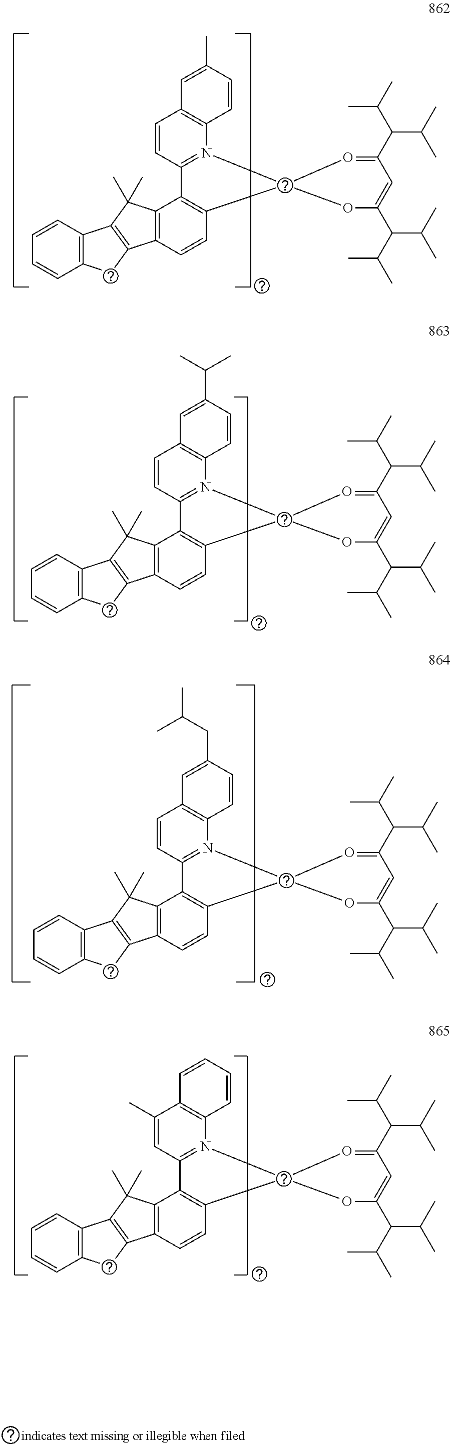

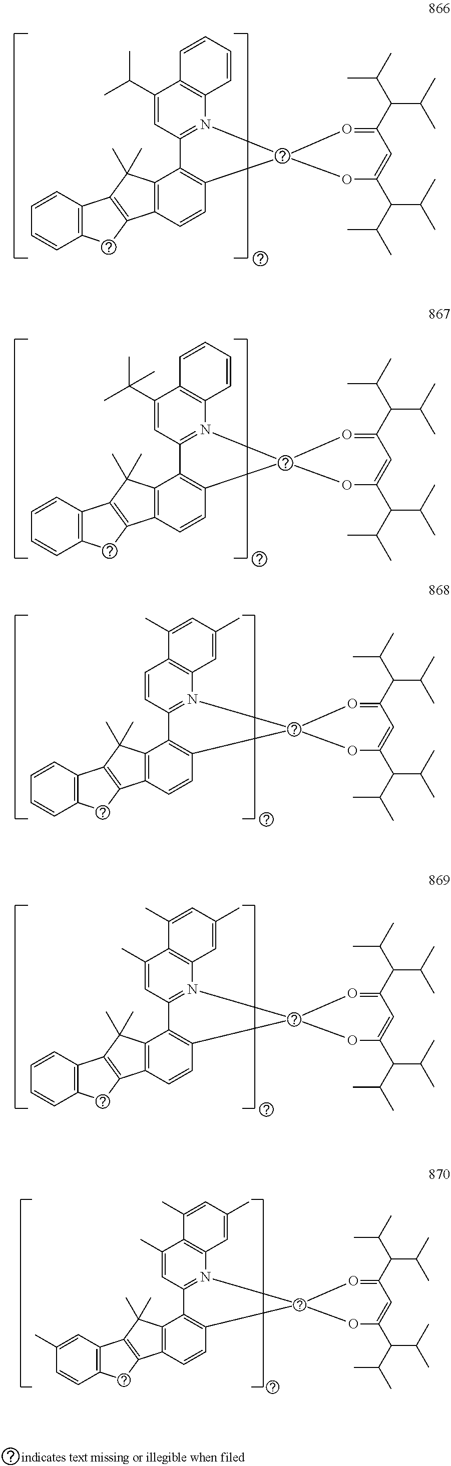

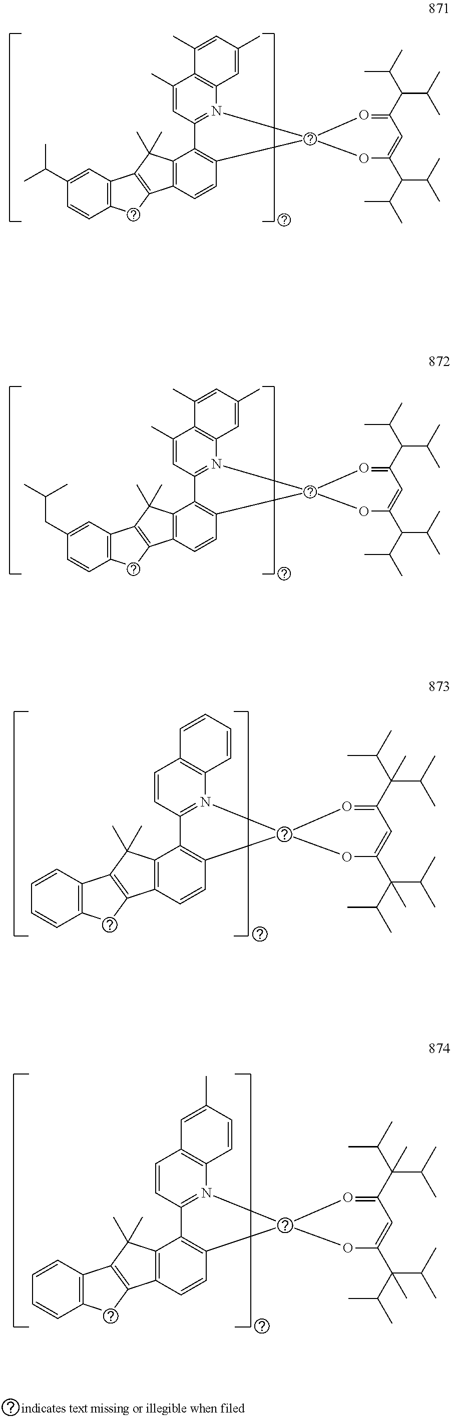

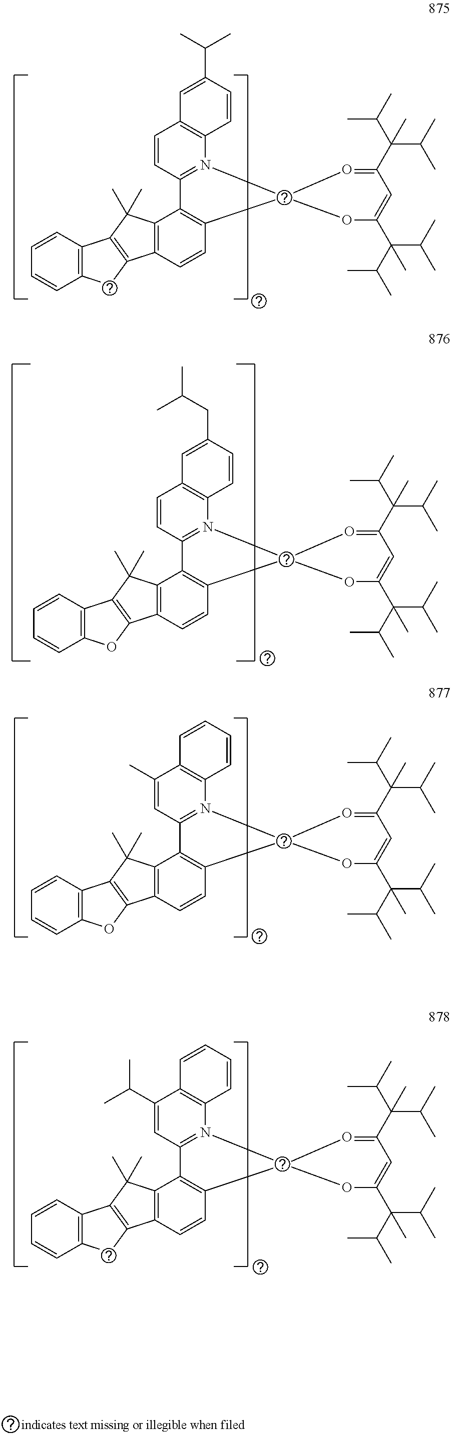

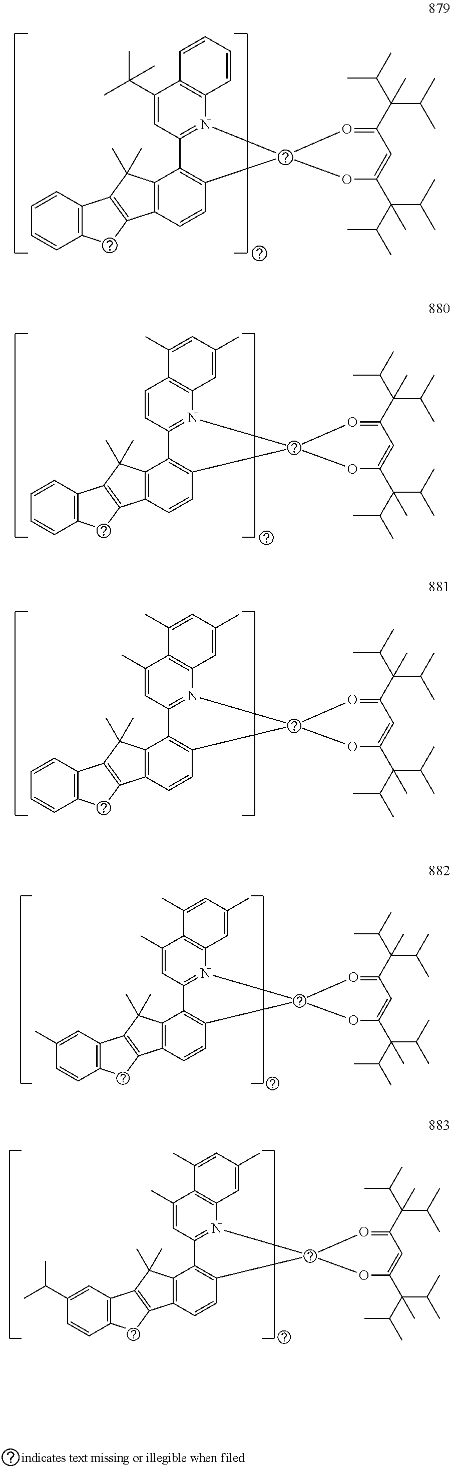

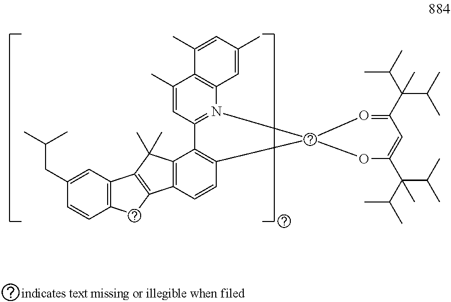

According to one implementation of the present disclosure, the organometallic compound represented by the Chemical Formula 1 of the present disclosure can be used as a dopant material achieving red phosphorescent or a green phosphorescence, preferably, as a dopant material achieving the red phosphorescence.

Referring to FIG. 1 according to one implementation of the present disclosure, an organic light-emitting diode 100 can be provided which includes a first electrode 110: a second electrode 120 facing the first electrode 110; and an organic layer 130 disposed between the first electrode 110 and the second electrode 120. The organic layer 130 can include a light-emitting layer 160, and the light-emitting layer 160 can include a host material 160′ and dopants 160″. The dopants 160″ can be made of the organometallic compound represented by the Chemical Formula 1. In addition, in the organic light-emitting diode 100, the organic layer 130 disposed between the first electrode 110 and the second electrode 120 can be formed by sequentially stacking a hole injection layer 140 (HIL), a hole transport layer 150, (HTL), a light emission layer 160 (EML), an electron transport layer 170 (ETL) and an electron injection layer 180 (EIL) on the first electrode 110. The second electrode 120 can be formed on the electron injection layer 180, and a protective layer can be formed thereon.

Further, although not shown explicitly in FIG. 1, a hole transport auxiliary layer can be further added between the hole transport layer 150 and the light-emitting layer 160. The hole transport auxiliary layer can contain a compound having good hole transport properties, and can reduce a difference between HOMO energy levels of the hole transport layer 150 and the light-emitting layer 160 so as to adjust the hole injection properties. Thus, accumulation of holes at an interface between the hole transport auxiliary layer and the light-emitting layer 160 can be reduced, thereby reducing a quenching phenomenon in which excitons disappear at the interface due to polarons. Accordingly, deterioration of the element can be reduced and the element can be stabilized, thereby improving efficiency and lifespan thereof.

The first electrode 110 can act as a positive electrode, and can be made of ITO, IZO, tin-oxide, or zinc-oxide as a conductive material having a relatively large work function value. However, the present disclosure is not limited thereto.

The second electrode 120 can act as a negative electrode, and can include Al, Mg, Ca, or Ag as a conductive material having a relatively small work function value, or an alloy or combination thereof. However, the present disclosure is not limited thereto.

The hole injection layer 140 can be positioned between the first electrode 110 and the hole transport layer 150. The hole injection layer 140 can have a function of improving interface characteristics between the first electrode 110 and the hole transport layer 150, and can be selected from a material having appropriate conductivity. The hole injection layer 140 can include one or more compounds selected from a group consisting of MTDATA, CuPc, TCTA, HATCN, TDAPB, PEDOT/PSS, and N1,N1′-([1,1′-biphenyl]-4,4′-diyl)bis(N1,N4,N4)-triphenylbenzene-1,4-diamine). Preferably, the hole injection layer 140 can include N1,N1′-([1,1′-biphenyl]-4,4′-diyl)bis(N1,N4,N4-triphenylbenzene-1,4-diamine). However, the present disclosure is not limited thereto.

The hole transport layer 150 can be positioned adjacent to the light-emitting layer and between the first electrode 110 and the light-emitting layer 160. A material of the hole transport layer 150 can include a compound selected from a group consisting of TPD, NPB, CBP, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl)-4-amine, etc. Preferably, the material of the hole transport layer 150 can include NPB. However, the present disclosure is not limited thereto.

According to the present disclosure, the light-emitting layer 160 can be formed by doping a host material 160′ with the organometallic compound represented by the Chemical Formula 1 as a dopant 160″ in order to improve luminous efficiency of the diode 100. The dopant 160″ can be used as a green or red light emitting material, and preferably as a red phosphorescent material.

A doping concentration of the dopant 160″ according to the present disclosure can be adjusted to be within a range of 1 to 30% by weight based on a total weight of the host material 160′. However, the disclosure is not limited thereto. For example, the doping concentration can be in a range of 2 to 20 wt %, for example, 3 to 15 wt %, for example, 5 to 10 wt %, for example, 3 to 8 wt %, for example, 2 to 6 wt %, for example, 2 to 5 wt %, or for example, 2 to 3 wt %.

The light-emitting layer 160 according to the present disclosure contains the host material 160′ which is known in the art and can achieve an effect of the present disclosure while the layer 160 contains the organometallic compound represented by the Chemical Formula 1 as the dopant 160″. For example, in accordance with the present disclosure, the host material 160′ can include a compound containing a carbazole group, and can preferably include one host material selected from a group consisting of CBP (carbazole biphenyl), mCP (1,3-bis(carbazol-9-yl), and the like. However, the disclosure is not limited thereto.

Further, the electron transport layer 170 and the electron injection layer 180 can be sequentially stacked between the light-emitting layer 160 and the second electrode 120. A material of the electron transport layer 170 requires high electron mobility such that electrons can be stably supplied to the light-emitting layer under smooth electron transport.

For example, the material of the electron transport layer 170 can include a compound selected from a group consisting of Alq3 (tris(8-hydroxyquinolino)aluminum), Liq (8-hydroxyquinolinolatolithium), PBD (2-(4-biphenylyl)-5-(4-tert-butylphenyl)-1,3,4oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminum), SAlq, TPBi (2,2′,2-(1,3,5-benzinetriyl)-tris(1-phenyl-1-H-benzimidazole), oxadiazole, triazole, phenanthroline, benzoxazole, benzthiazole, and 2-(4-(9,10-di(naphthalen-2-yl)anthracen-2-yl)phenyl)-1-phenyl-1H-benzo[d]imidazole. Preferably, the material of the electron transport layer 170 can include 2-(4-(9,10-di(naphthalen-2-yl)anthracen-2-yl)phenyl)-1-phenyl-1H-benzo[d]imidazole. However, the present disclosure is not limited thereto.

The electron injection layer 180 serves to facilitate electron injection, and a material of the electron injection layer can include a compound selected from a group consisting of Alq3 (tris(8-hydroxyquinolino)aluminum), PBD, TAZ, spiro-PBD, BAlq, SAlq, etc. However, the present disclosure is not limited thereto. Alternatively, the electron injection layer 180 can be made of a metal compound. The metal compound can include, for example, one or more selected from a group consisting of Liq, LiF, NaF, KF, RbF, CsF, FrF, BeF₂, MgF₂, CaF₂, SrF₂, BaF₂ and RaF₂. However, the present disclosure is not limited thereto.

The organic light-emitting diode according to the present disclosure can be embodied as a white light-emitting diode having a tandem structure. The tandem organic light-emitting diode according to an illustrative embodiment of the present disclosure can be formed in a structure in which adjacent ones of two or more light-emitting stacks are connected to each other via a charge generation layer (CGL). The organic light-emitting diode can include at least two light-emitting stacks disposed on a substrate, wherein each of the at least two light-emitting stacks includes first and second electrodes facing each other, and the light-emitting layer disposed between the first and second electrodes to emit light in a specific wavelength band.

In this case, the light-emitting layer included in at least one of the plurality of light-emitting stacks can contain the organometallic compound represented by the Chemical Formula 1 according to the present disclosure as the dopants. Adjacent ones of the plurality of light-emitting stacks in the tandem structure can be connected to each other via the charge generation layer CGL including an N-type charge generation layer and a P-type charge generation layer.

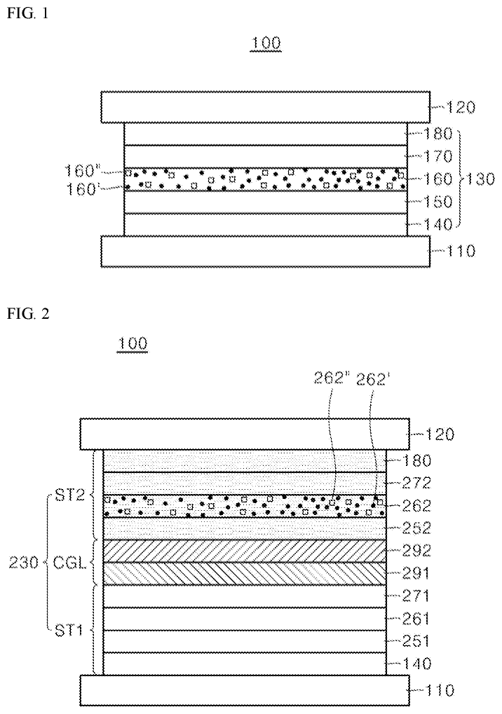

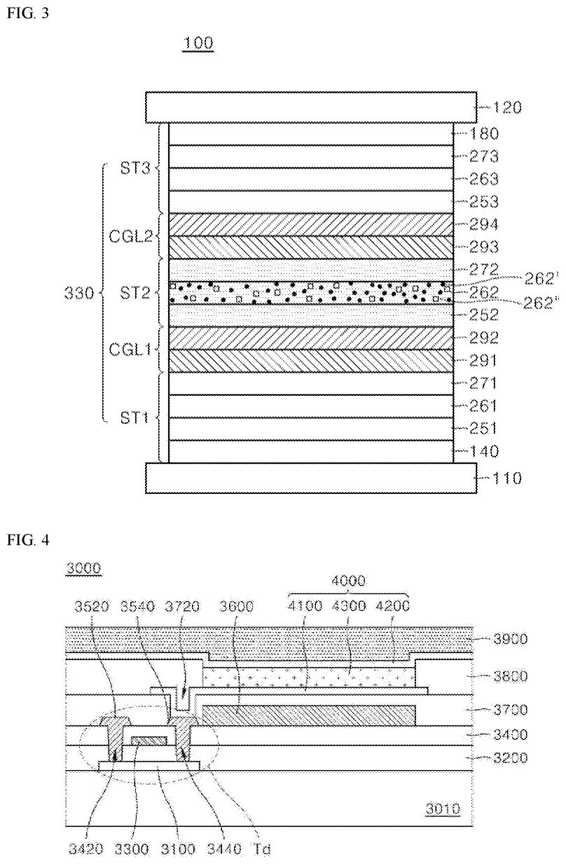

FIG. 2 and FIG. 3 are cross-sectional views schematically showing an organic light-emitting diode in a tandem structure having two light-emitting stacks and an organic light-emitting diode in a tandem structure having three light-emitting stacks, respectively, according to some implementations of the present disclosure.

As shown in FIG. 2, an organic light-emitting diode 100 according to the present disclosure include a first electrode 110 and a second electrode 120 facing each other, and an organic layer 230 positioned between the first electrode 110 and the second electrode 120. The organic layer 230 can be positioned between the first electrode 110 and the second electrode 120 and can include a first light-emitting stack ST1 including a first light-emitting layer 261, a second light-emitting stack ST2 positioned between the first light-emitting stack ST1 and the second electrode 120 and including a second light-emitting layer 262, and the charge generation layer CGL positioned between the first and second light-emitting stacks ST1 and ST2. The charge generation layer CGL can include an N-type charge generation layer 291 and a P-type charge generation layer 292. At least one of the first light-emitting layer 261 and the second light-emitting layer 262 can contain the organometallic compound represented by the Chemical Formula 1 according to the present disclosure as the dopants. For example, as shown in FIG. 2, the second light-emitting layer 262 of the second light-emitting stack ST2 can contain a host material 262′, and dopants 262″ made of the organometallic compound represented by the Chemical Formula 1 doped therein.

As shown in FIG. 3, the organic light-emitting diode 100 according to the present disclosure include the first electrode 110 and the second electrode 120 facing each other, and an organic layer 330 positioned between the first electrode 110 and the second electrode 120. The organic layer 330 can be positioned between the first electrode 110 and the second electrode 120 and can include the first light-emitting stack ST1 including the first light-emitting layer 261, the second light-emitting stack ST2 including the second light-emitting layer 262, a third light-emitting stack ST3 including a third light-emitting layer 263, a first charge generation layer CGL1 positioned between the first and second light-emitting stacks ST1 and ST2, and a second charge generation layer CGL2 positioned between the second and third light-emitting stacks ST2 and ST3. The first charge generation layer CGL1 can include a N-type charge generation layers 291 and a P-type charge generation layer 292. The second charge generation layer CGL2 can include a N-type charge generation layers 293 and a P-type charge generation layer 294. At least one of the first light-emitting layer 261, the second light-emitting layer 262, and the third light-emitting layer 263 can contain the organometallic compound represented by the Chemical Formula 1 according to the present disclosure as the dopants. For example, as shown in FIG. 3, the second light-emitting layer 262 of the second light-emitting stack ST2 can contain the host material 262′, and the dopants 262″ made of the organometallic compound represented by the Chemical Formula 1 doped therein.

Furthermore, an organic light-emitting diode according to an embodiment of the present disclosure can include a tandem structure in which four or more light-emitting stacks and three or more charge generating layers are disposed between the first electrode and the second electrode.

The organic light-emitting diode according to the present disclosure can be used as a light-emitting element of each of an organic light-emitting display device and a lighting device. In one implementation, FIG. 4 is a cross-sectional view schematically illustrating an organic light-emitting display device including the organic light-emitting diode according to some embodiments of the present disclosure as a light-emitting element thereof.

As shown in FIG. 4, an organic light-emitting display device 3000 includes a substrate 3010, an organic light-emitting diode 4000, and an encapsulation film 3900 covering the organic light-emitting diode 4000. A driving thin-film transistor Td as a driving element, and the organic light-emitting diode 4000 connected to the driving thin-film transistor Td are positioned on the substrate 3010.

Although not shown explicitly in FIG. 4, a gate line and a data line that intersect each other to define a pixel area, a power line extending parallel to and spaced from one of the gate line and the data line, a switching thin film transistor connected to the gate line and the data line, and a storage capacitor connected to one electrode of the thin film transistor and the power line are further formed on the substrate 3010.

The driving thin-film transistor Td is connected to the switching thin film transistor, and includes a semiconductor layer 3100, a gate electrode 3300, a source electrode 3520, and a drain electrode 3540.

The semiconductor layer 3100 can be formed on the substrate 3010 and can be made of an oxide semiconductor material or polycrystalline silicon. When the semiconductor layer 3100 is made of an oxide semiconductor material, a light-shielding pattern can be formed under the semiconductor layer 3100. The light-shielding pattern prevents light from being incident into the semiconductor layer 3100 to prevent the semiconductor layer 3100 from being deteriorated due to the light. Alternatively, the semiconductor layer 3100 can be made of polycrystalline silicon. In this case, both edges of the semiconductor layer 3100 can be doped with impurities.

The gate insulating layer 3200 made of an insulating material is formed over an entirety of a surface of the substrate 3010 and on the semiconductor layer 3100. The gate insulating layer 3200 can be made of an inorganic insulating material such as silicon oxide or silicon nitride.

The gate electrode 3300 made of a conductive material such as a metal is formed on the gate insulating layer 3200 and corresponds to a center of the semiconductor layer 3100. The gate electrode 3300 is connected to the switching thin film transistor.

The interlayer insulating layer 3400 made of an insulating material is formed over the entirety of the surface of the substrate 3010 and on the gate electrode 3300. The interlayer insulating layer 3400 can be made of an inorganic insulating material such as silicon oxide or silicon nitride, or an organic insulating material such as benzocyclobutene or photo-acryl.

The interlayer insulating layer 3400 has first and second semiconductor layer contact holes 3420 and 3440 defined therein respectively exposing both opposing sides of the semiconductor layer 3100. The first and second semiconductor layer contact holes 3420 and 3440 are respectively positioned on both opposing sides of the gate electrode 3300 and are spaced apart from the gate electrode 3300.

The source electrode 3520 and the drain electrode 3540 made of a conductive material such as metal are formed on the interlayer insulating layer 3400. The source electrode 3520 and the drain electrode 3540 are positioned around the gate electrode 3300, and are spaced apart from each other, and respectively contact both opposing sides of the semiconductor layer 3100 via the first and second semiconductor layer contact holes 3420 and 3440, respectively. The source electrode 3520 is connected to a power line.

The semiconductor layer 3100, the gate electrode 3300, the source electrode 3520, and the drain electrode 3540 constitute the driving thin-film transistor Td. The driving thin-film transistor Td has a coplanar structure in which the gate electrode 3300, the source electrode 3520, and the drain electrode 3540 are positioned on top of the semiconductor layer 3100.

Alternatively, the driving thin-film transistor Td can have an inverted staggered structure in which the gate electrode is disposed under the semiconductor layer while the source electrode and the drain electrode are disposed above the semiconductor layer. In this case, the semiconductor layer can be made of amorphous silicon. In one example, the switching thin-film transistor can have substantially the same structure as that of the driving thin-film transistor (Td).

In one example, the organic light-emitting display device 3000 can include a color filter 3600 absorbing the light generated from the electroluminescent element (light-emitting diode) 4000. For example, the color filter 3600 can absorb red (R), green (G), blue (B), and white (W) light. In this case, red, green, and blue color filter patterns that absorb light can be formed separately in different pixel areas. Each of these color filter patterns can be disposed to overlap each organic layer 4300 of the organic light-emitting diode 4000 to emit light of a wavelength band corresponding to each color filter. Adopting the color filter 3600 can allow the organic light-emitting display device 3000 to realize full-color.

For example, when the organic light-emitting display device 3000 is of a bottom emission type, the color filter 3600 absorbing light can be positioned on a portion of the interlayer insulating layer 3400 corresponding to the organic light-emitting diode 4000. In an optional embodiment, when the organic light-emitting display device 3000 is of a top emission type, the color filter can be positioned on top of the organic light-emitting diode 4000, that is, on top of a second electrode 4200. For example, the color filter 3600 can be formed to have a thickness of 2 to 5 μm.

In one example, a protective layer 3700 having a drain contact hole 3720 defined therein exposing the drain electrode 3540 of the driving thin-film transistor Td is formed to cover the driving thin-film transistor Td.

On the protective layer 3700, each first electrode 4100 connected to the drain electrode 3540 of the driving thin-film transistor Td via the drain contact hole 3720 is formed individually in each pixel area.

The first electrode 4100 can act as a positive electrode (anode), and can be made of a conductive material having a relatively large work function value. For example, the first electrode 4100 can be made of a transparent conductive material such as ITO, IZO or ZnO.

In one example, when the organic light-emitting display device 3000 is of a top-emission type, a reflective electrode or a reflective layer can be further formed under the first electrode 4100. For example, the reflective electrode or the reflective layer can be made of one of aluminum (Al), silver (Ag), nickel (Ni), and an aluminum-palladium-copper (APC) alloy.

A bank layer 3800 covering an edge of the first electrode 4100 is formed on the protective layer 3700. The bank layer 3800 exposes a center of the first electrode 4100 corresponding to the pixel area.

An organic layer 4300 is formed on the first electrode 4100. If necessary, the organic light-emitting diode 4000 can have a tandem structure. Regarding the tandem structure, reference can be made to FIG. 2 to FIG. 4 which show some embodiments of the present disclosure, and the above descriptions thereof.

The second electrode 4200 is formed on the substrate 3010 on which the organic layer 4300 has been formed. The second electrode 4200 is disposed over the entirety of the surface of the display area and is made of a conductive material having a relatively small work function value and can be used as a negative electrode (a cathode). For example, the second electrode 4200 can be made of one of aluminum (Al), magnesium (Mg), and an aluminum-magnesium alloy (Al—Mg).

The first electrode 4100, the organic layer 4300, and the second electrode 4200 constitute the organic light-emitting diode 4000.

An encapsulation film 3900 is formed on the second electrode 4200 to prevent external moisture from penetrating into the organic light-emitting diode 4000. Although explicitly in FIG. 4, the encapsulation film 3900 can have a triple-layer structure in which a first inorganic layer, an organic layer, and an inorganic layer are sequentially stacked. However, the present disclosure is not limited thereto.

Hereinafter, Preparation Example and Present Example of the present disclosure will be described. However, following Present Example is only one example of the present disclosure. The present disclosure is not limited thereto.

<Preparation of Precursor Compound>

[Preparation of Compound A1]

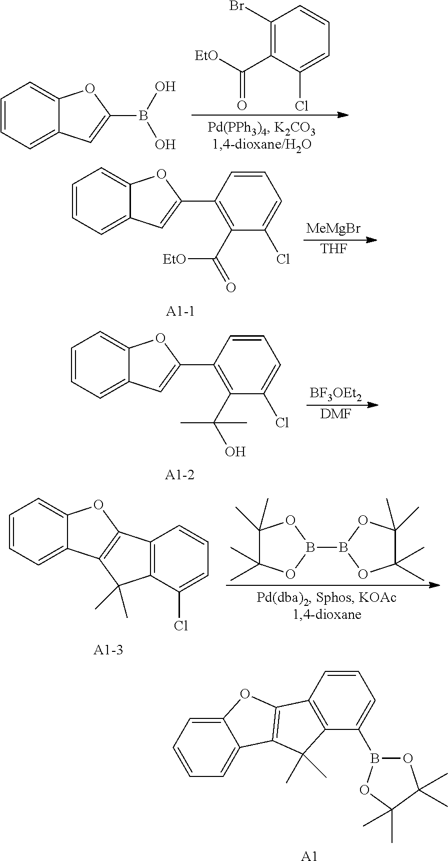

Preparation of Compound A1-1

Ethyl 2-bromo-6-chlorobenzoate (30 g, 113.84 mmol), benzofuran-2-ylboronic acid (22.1 g, 136.61 mmol), Pd(PPh₃)₄ (6.58 g, 5.69 mmol) and K₂CO₃ (47.20 g, 341.53 mmol) were dissolved in 1,4-dioxane (500 ml) and distilled water (100 ml) in a reaction vessel and a mixture was refluxed for 12 hours. After completion of a reaction, a temperature was lowered to room temperature, followed by extraction using dichloromethane and distilled water. MgSO₄ was added to an organic layer, and filtering was performed thereon to remove moisture therefrom, and then the solvent was removed therefrom under reduced pressure. Column chromatography was carried out with hexane and dichloromethane to obtain the Compound A1-1 (28.1 g, a yield 82%).

MS (m/z): 300.06

Preparation of Compound A1-2

A1-1 (28.1 g, 93.44 mmol) was dissolved in THF (400 ml) in a reaction vessel, and MeMgBr in 1.6 M diethyl ether (175 ml, 280.31 mmol) was added dropwise thereto at −78° C. for 1 hour, followed by stirring for 12 hours. NH₄Cl was added thereto to terminate a reaction, and the mixture was stirred at room temperature for 30 minutes, followed by extraction using dichloromethane and distilled water. MgSO₄ was added to an organic layer, and filtering was performed thereon to remove moisture therefrom, and then the solvent was removed therefrom under reduced pressure. Column chromatography was carried out with hexane and dichloromethane. Thus, the Compound A1-2 (24.38 g, a yield 91%) was obtained.

MS (m/z): 286.08

Preparation of Compound A1-3

A1-2 (24.38 g, 85.02 mmol) and DMF (500 ml) were input into a reaction vessel, and BF₃OEt₂ (12.07 g, 85.02 mmol) was added dropwise thereto at 0° C. for 1 hour, followed by stirring at room temperature for 1 hour. NaHCO₃ was added thereto to terminate the reaction and then, extraction was performed thereon using dichloromethane and distilled water. MgSO₄ was added to an organic layer, and filtering was performed thereon to remove moisture therefrom, and then the solvent was removed therefrom under reduced pressure. Column chromatography was carried out with hexane and dichloromethane. Thus, the Compound A1-3 (16.91 g, a yield 74%) was obtained.

MS (m/z): 286.08

Preparation of Compound A1

In a reaction vessel, A1-3 (16.91 g, 62.92 mmol), 4,4,4′,4′,5,5,5′,5′-octamethyl-2,2′-bi(1,3,2-dioxaborolane) (19.25 g, 75.51 mmol), Pd(dba)₂ (3.63 g, 6.29 mmol), Sphos (5.17 g, 12.58 mmol), and KOAc (18.53 g, 188.77 mmol) were dissolved in 1,4-dioxane (500 ml) and a mixture was refluxed for 12 hours. After completion of a reaction, a temperature was lowered to room temperature, followed by extraction using dichloromethane and distilled water. MgSO₄ was added to an organic layer, and filtering was performed thereon to remove moisture therefrom, and then the solvent was removed therefrom under reduced pressure. Column chromatography was carried out with hexane and dichloromethane to obtain the Compound A1 (18.81 g, a yield 83%).

MS (m/z): 360.19

[Preparation of Compound A2]

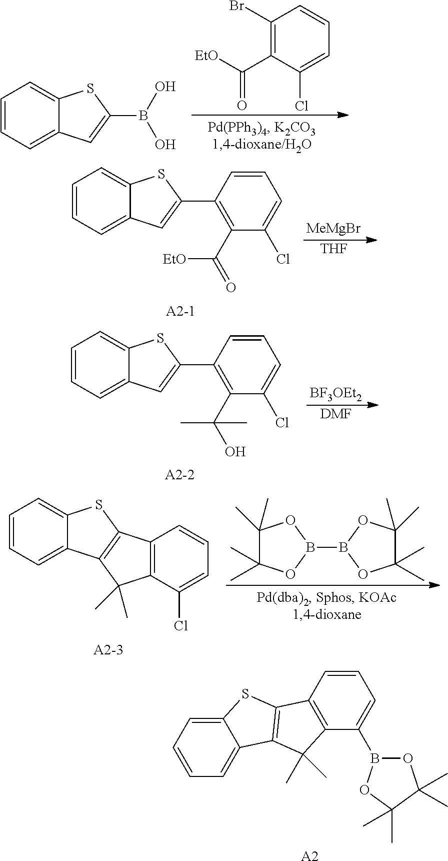

Preparation of Compound A2-1

The compound A2-1 (28.85 g, a yield 80%) was obtained in the same method as in the preparation method of the Compound A1-1 except that benzo[b]thiophen-2-ylboronic acid (24.32 g, 136.61 mmol) was used instead of benzofuran-2-ylboronic acid (22.1 g, 136.61 mmol).

MS (m/z): 316.03

Preparation of Compound A2-2

The compound A2-2 (24.54 g, a yield 89%) was obtained in the same method as in the preparation method of the Compound A1-2 except that A2-1 (28.85 g, 91.06 mmol) was used instead of A1-1 (28.1 g, 93.44 mmol).

MS (m/z): 302.05

Preparation of Compound A2-3

The compound A2-3 (17.31 g, a yield 75%) was obtained in the same method as in the preparation method of the Compound A1-3 except that A2-2 (24.54 g, 81.04 mmol) was used instead of A1-2 (24.38 g, 85.02 mmol).

MS (m/z): 284.04

Preparation of Compound A2

The compound A2 (19.44 g, a yield 85%) was obtained in the same method as in the preparation method of the Compound A1 except that A2-3 (17.31 g, 60.78 mmol) was used instead of A1-3 (16.91 g, 62.92 mmol).

MS (m/z): 376.17

[Preparation of Compound A3]

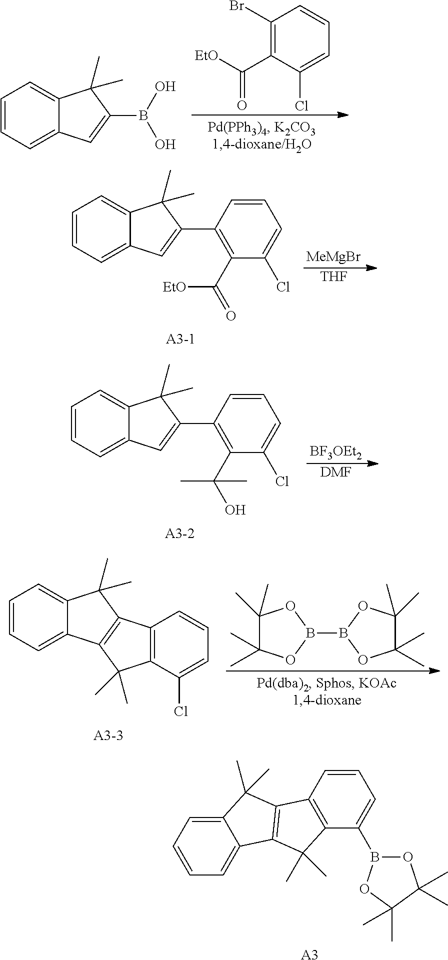

Preparation of Compound A3-1

The compound A3-1 (31.25 g, a yield 84%) was obtained in the same method as in the preparation method of the Compound A1-1 except that 1,1-dimethyl-1H-inden-2-ylboronic acid (25.69 g, 136.61 mmol) was used instead of benzofuran-2-ylboronic acid (22.1 g, 136.61 mmol).

MS (m/z): 326.11

Preparation of Compound A3-2

The compound A3-2 (27.82 g, a yield 93%) was obtained in the same method as in the preparation method of the Compound A1-2 except that A3-1 (31.25 g, 95.63 mmol) was used instead of A1-1 (28.1 g, 93.44 mmol).

MS (m/z): 312.13

Preparation of Compound A3-3

The compound A3-3 (20.45 g, a yield 78%) was obtained in the same method as in the preparation method of the Compound A1-3 except that A3-2 (32.76 g, 88.93 mmol) was used instead of A1-2 (24.38 g, 85.02 mmol).

MS (m/z): 294.12

Preparation of Compound A3

The compound A3 (23.32 g, a yield 87%) was obtained in the same method as in the preparation method of the Compound A1 except that A3-3 (20.45 g, 69.37 mmol) was used instead of A1-3 (16.91 g, 62.92 mmol).

MS (m/z): 386.33

[Preparation of Compound A4]

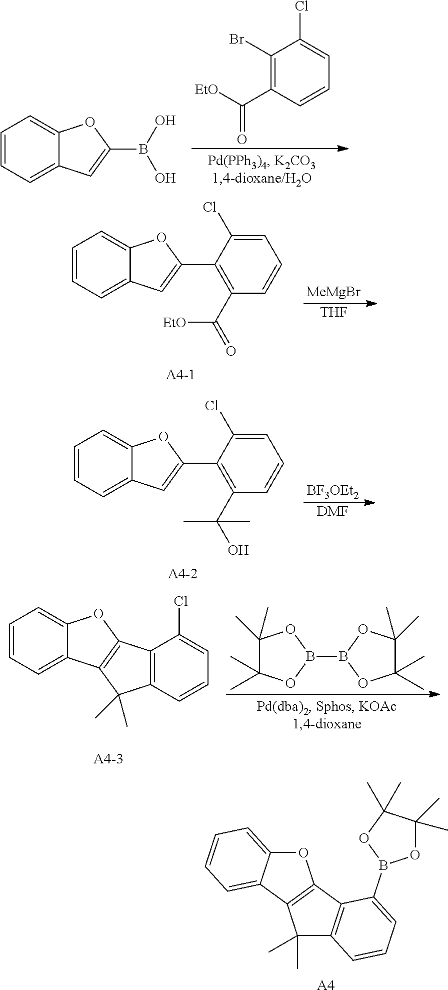

Preparation of Compound A4-1

The compound A4-1 (27.73 g, a yield 81%) was obtained in the same method as in the preparation method of the Compound A1-1 except that ethyl 2-bromo-3-chlorobenzoate (30 g, 113.84 mmol) was used instead of ethyl 2-bromo-6-chlorobenzoate (30 g, 113.84 mmol).

MS (m/z): 300.06

Preparation of Compound A4-2

The compound A4-2 (23.80 g, a yield 90%) was obtained in the same method as in the preparation method of the Compound A1-2 except that A4-1 (27.73 g, 92.21 mmol) was used instead of A1-1 (28.1 g, 93.44 mmol).

MS (m/z): 286.08

Preparation of Compound A4-3

The compound A4-3 (16.73 g, a yield 75%) was obtained in the same method as in the preparation method of the Compound A1-3 except that A4-2 (23.80 g, 82.99 mmol) was used instead of A1-2 (24.38 g, 85.02 mmol).

MS (m/z): 268.74

Preparation of Compound A4

The compound A4 (19.19 g, a yield 84%) was obtained in the same method as in the preparation method of the Compound A1 except that A4-3 (16.73 g, 63.42 mmol) was used instead of A1-3 (16.91 g, 62.92 mmol).

MS (m/z): 360.19

[Preparation of Compound A5]

Preparation of Compound A5-1

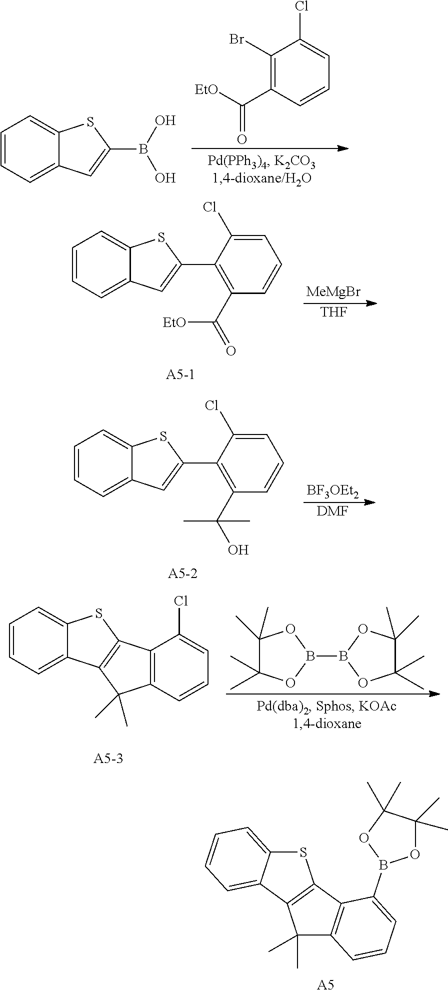

The compound A5-1 (29.93 g, a yield 83%) was obtained in the same method as in the preparation method of the Compound A1-1 except that ethyl 2-bromo-3-chlorobenzoate (30 g, 113.84 mmol) benzo[b]thiophen-2-ylboronic acid (24.32 g, 136.61 mmol) were respectively used instead of ethyl 2-bromo-6-chlorobenzoate (30 g, 113.84 mmol) and benzofuran-2-ylboronic acid (22.1 g, 136.61 mmol).

MS (m/z): 316.03

Preparation of Compound A5-2

The compound A5-2 (24.32 g, a yield 85%) was obtained in the same method as in the preparation method of the Compound A1-2 except that A5-1 (29.93 g, 94.49 mmol) was used instead of A1-1 (28.1 g, 93.44 mmol).

MS (m/z): 302.05

Preparation of Compound A5-3

The compound A5-3 (16.24 g, a yield 71%) was obtained in the same method as in the preparation method of the Compound A1-3 except that A5-2 (24.32 g, 80.32 mmol) was used instead of A1-2 (24.38 g, 85.02 mmol).

MS (m/z): 284.04

Preparation of Compound A5

The compound A5 (17.17 g, a yield 80%) was obtained in the same method as in the preparation method of the Compound A1 except that A5-3 (16.24 g, 57.02 mmol) was used instead of A1-3 (16.91 g, 62.92 mmol).

MS (m/z): 376.17

[Preparation of Compound A6]

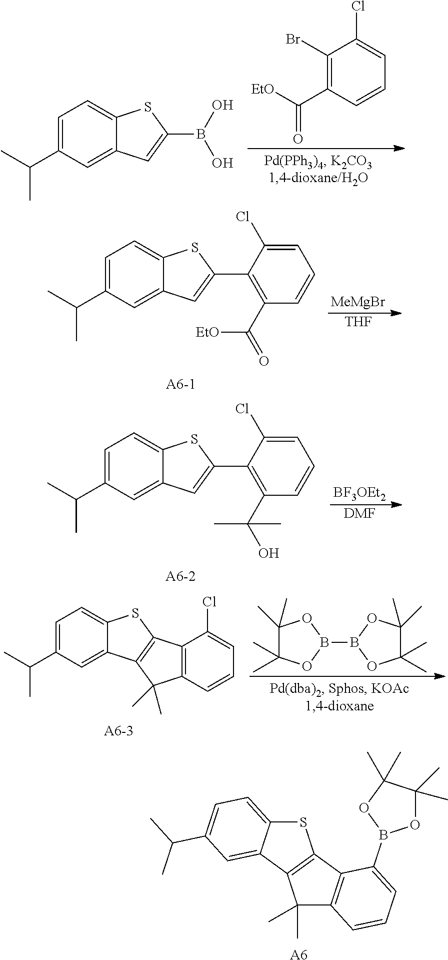

Preparation of Compound A6-1

The compound A6-1 (34.73 g, a yield 85%) was obtained in the same method as in the preparation method of the Compound A1-1 except that ethyl 2-bromo-3-chlorobenzoate (30 g, 113.84 mmol) and 5-isopropylbenzo[b]thiophen-2-ylboronic acid (30.07 g, 136.61 mmol) were respectively used instead of ethyl 2-bromo-6-chlorobenzoate (30 g, 113.84 mmol) and benzofuran-2-ylboronic acid (22.1 g, 136.61 mmol).

MS (m/z): 350.08

Preparation of Compound A6-2

The compound A6-2 (25.70 g, a yield 77%) was obtained in the same method as in the preparation method of the Compound A1-2 except that A6-1 (34.73 g, 96.77 mmol) was used instead of A1-1 (28.1 g, 93.44 mmol).

MS (m/z): 344.10

Preparation of Compound A6-3

The compound A6-3 (15.83 g, a yield 65%) was obtained in the same method as in the preparation method of the Compound A1-3 except that A6-2 (25.70 g, 74.51 mmol) was used instead of A1-2 (24.38 g, 85.02 mmol).

MS (m/z): 326.09

Preparation of Compound A6

The compound A6 (16.41 g, a yield 81%) was obtained in the same method as in the preparation method of the Compound A1 except that A6-3 (15.83 g, 48.43 mmol) was used instead of A1-3 (16.91 g, 62.92 mmol).

MS (m/z): 418.21

[Preparation of Compound A7]

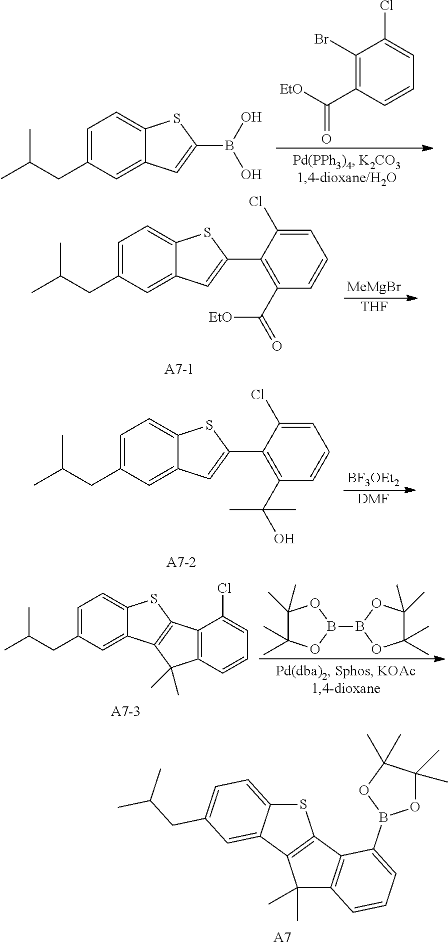

Preparation of Compound A7-1

The compound A7-1 (36.93 g, a yield 87%) was obtained in the same method as in the preparation method of the Compound A1-1 except that ethyl 2-bromo-3-chlorobenzoate (30 g, 113.84 mmol) and 5-isobutylbenzo[b]thiophen-2-ylboronic acid (31.98 g, 136.61 mmol) were respectively used instead of ethyl 2-bromo-6-chlorobenzoate (30 g, 113.84 mmol) and benzofuran-2-ylboronic acid (22.1 g, 136.61 mmol).

MS (m/z): 372.10

Preparation of Compound A7-2

The compound A7-2 (29.86 g, a yield 84%) was obtained in the same method as in the preparation method of the Compound A1-2 except that A7-1 (36.93 g, 99.04 mmol) was used instead of A1-1 (28.1 g, 93.44 mmol).

MS (m/z): 358.12

Preparation of Compound A7-3

The compound A7-3 (22.12 g, a yield 78%) was obtained in the same method as in the preparation method of the Compound A1-3 except that A7-2 (29.86 g, 83.20 mmol) was used instead of A1-2 (24.38 g, 85.02 mmol).

MS (m/z): 340.11

Preparation of Compound A7

The compound A7 (22.45 g, a yield 80%) was obtained in the same method as in the preparation method of the Compound A1 except that A7-3 (22.12 g, 64.89 mmol) was used instead of A1-3 (16.91 g, 62.92 mmol).

MS (m/z): 432.23

[Preparation of Compound A8]

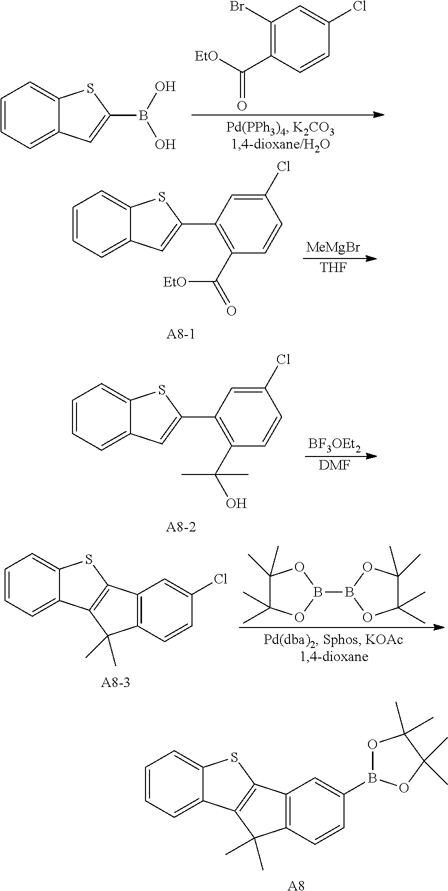

Preparation of Compound A8-1

The compound A8-1 (29.93 g, a yield 83%) was obtained in the same method as in the preparation method of the Compound A1-1, except that ethyl 2-bromo-4-chlorobenzoate (30 g, 113.84 mmol) and benzo[b]thiophen-2-ylboronic acid (24.32 g, 136.61 mmol) were respectively used instead of ethyl 2-bromo-6-chlorobenzoate (30 g, 113.84 mmol) and benzofuran-2-ylboronic acid (22.1 g, 136.61 mmol).

MS (m/z): 316.03

Preparation of Compound A8-2

The Compound A8-2 (23.46 g, a yield 82%) was obtained in the same method as in the preparation method of the Compound A1-2 except that A8-1 (29.93 g, 94.49 mmol) was used instead of A1-1 (28.1 g, 93.44 mmol).

MS (m/z): 302.05

Preparation of Compound A8-3

The compound A8-3 (17.0 g, a yield 77%) was obtained in the same method as in the preparation method of the Compound A1-3 except that A8-2 (23.46 g, 77.48 mmol) was used instead of A1-2 (24.38 g, 85.02 mmol).

MS (m/z): 284.04

Preparation of Compound A8

The compound A8 (17.51 g, a yield 78%) was obtained in the same method as in the preparation method of the Compound A1 except that A8-3 (17.0 g, 59.66 mmol) was used instead of A1-3 (16.91 g, 62.92 mmol).

MS (m/z): 376.17

[Preparation of Compound A9]

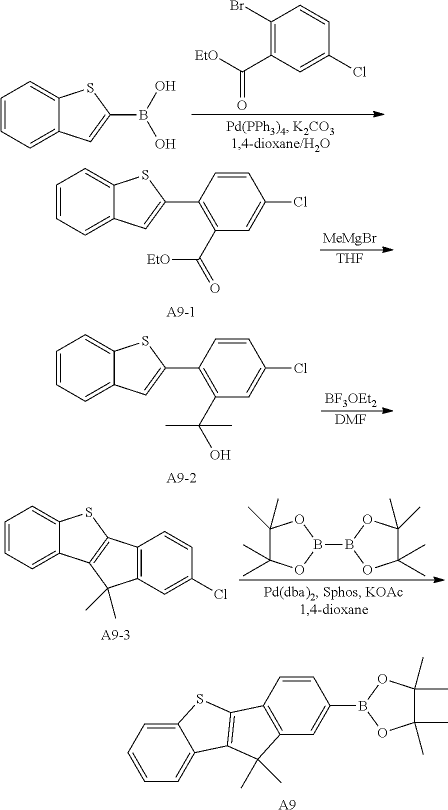

Preparation of Compound A9-1

The compound A9-1 (29.57 g, a yield 82%) was obtained in the same method as in the preparation method of the Compound A1-1, except that ethyl 2-bromo-5-chlorobenzoate (30 g, 113.84 mmol) and benzo[b]thiophen-2-ylboronic acid (24.32 g, 136.61 mmol) were respectively used instead of ethyl 2-bromo-6-chlorobenzoate (30 g, 113.84 mmol) and benzofuran-2-ylboronic acid (22.1 g, 136.61 mmol).

MS (m/z): 316.03

Preparation of Compound A9-2

The compound A9-2 (24.31 g, a yield 86%) was obtained in the same method as in the preparation method of the Compound A1-2 except that A9-1 (29.57 g, 93.35 mmol) was used instead of A1-1 (28.1 g, 93.44 mmol).

MS (m/z): 302.05

Preparation of Compound A9-3

The compound A9-3 (18.75 g, a yield 82%) was obtained in the same method as in the preparation method of the Compound A1-3 except that A9-2 (24.31 g, 80.28 mmol) was used instead of A1-2 (24.38 g, 85.02 mmol).

MS (m/z): 284.04

Preparation of Compound A9

The compound A9 (20.81 g, a yield 84%) was obtained in the same method as in the preparation method of the Compound A1 except that A9-3 (18.75 g, 65.83 mmol) was used instead of A1-3 (16.91 g, 62.92 mmol).

MS (m/z): 376.17

[Preparation of Compounds L1 to L24]

Preparation of Compound L1

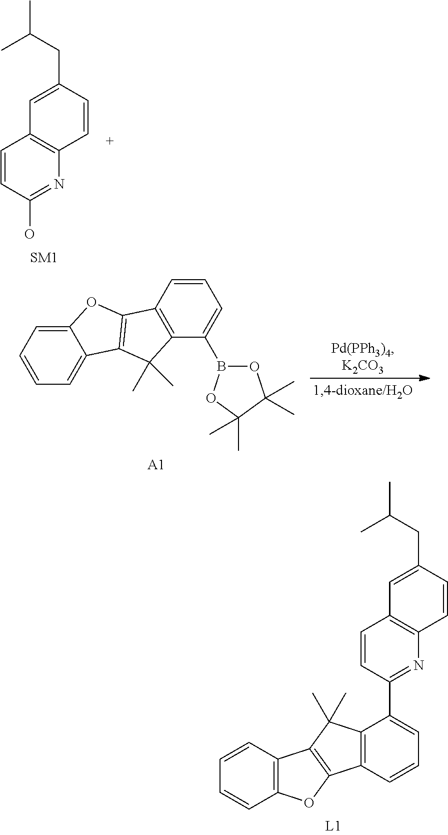 [SMILES: CC(C)Cc1ccc2nc(O)ccc2c1 ; CC1(C)c2c(B3OC(C)(C)C(C)(C)O3)cccc2-c2oc3ccccc3c21 ; "A1" ; CC(C)Cc1ccc2nc(-c3cccc4c3C(C)(C)c3c-4oc4ccccc34)ccc2c1]

In a reaction vessel, SM1 (2-chloro-6-isobutylquinoline) (10 g, 45.51 mmol), A1 (18.04 g, 50.67 mmol), Pd(PPh₃)₄ (2.63 g, 2.28 mmol) and K₂CO₃ (18.87 g, 136.54 mmol) were dissolved in 1,4-dioxane (300 ml) and distilled water (100 ml) and a mixture was refluxed for 12 hours. After completion of a reaction, a temperature was lowered to room temperature, followed by extraction using dichloromethane and distilled water. MgSO₄ was added to an organic layer, and filtering was performed thereon to remove moisture therefrom, and then the solvent was removed therefrom under reduced pressure. Column chromatography was performed with hexane and dichloromethane to obtain the Compound L1 (15.01 g, a yield 79%).

MS (m/z): 417.21

Preparation of Compound L2

The Compound L2 (14.71 g, a yield 75%) was obtained in the same method as in the preparation method of the Compound L1, except that SM2 (2-chloro-4,5,7-trimethylquinoline) (10 g, 48.62 mmol) was used instead of SM1 (2-chloro-6-isobutylquinoline) (10 g, 45.51 mmol).

MS (m/z): 403.19

Preparation of Compound L3

The Compound L3 (16.47 g, a yield 78%) was obtained in the same method as in the preparation method of the Compound L1, except that SM3 (2-chloro-6-methylquinoline) (10 g, 56.30 mmol) was used instead of SM1 (2-chloro-6-isobutylquinoline) (10 g, 45.51 mmol).

MS (m/z): 375.16

Preparation of Compound L4

The Compound L4 (14.80 g, a yield 75%) was obtained in the same method as in the preparation method of the Compound L1 except that A2 (18.83 g, 50.05 mmol) was used instead of A1 (18.04 g, 50.67 mmol).

MS (m/z): 433.19

Preparation of Compound L5

The Compound L5 (15.91 g, a yield 78%) was obtained in the same method as in the preparation method of the Compound L1, except that SM2 (2-chloro-4,5,7-trimethylquinoline) (10 g, 48.62 mmol) and A2 (20.13 g, 53.48 mmol) were respectively used instead of SM1 (2-chloro-6-isobutylquinoline) (10 g, 45.51 mmol) and A1 (18.04 g, 50.67 mmol).

MS (m/z): 419.17

Preparation of Compound L6

The Compound L6 (15.79 g, a yield 80%) was obtained in the same method as in the preparation method of the Compound L1, except that SM4 (4-tert-butyl-2-chloroquinoline) (10 g, 45.51 mmol) and A2 (18.84 g, 50.07 mmol) were respectively used instead of SM1 (2-chloro-6-isobutylquinoline) (10 g, 45.51 mmol) and A1 (18.04 g, 50.67 mmol).

MS (m/z): 433.19

Preparation of Compound L7

The Compound L7 (17.13 g, a yield 79%) was obtained in the same method as in the preparation method of the Compound L1, except that SM5 (2-chloro-5,7-dimethylquinoline) (10 g, 52.18 mmol) and A3 (22.17 g, 57.39 mmol) were respectively used instead of SM1 (2-chloro-6-isobutylquinoline) (10 g, 45.51 mmol) and A1 (18.04 g, 50.67 mmol).

MS (m/z): 415.23

Preparation of Compound L8

The Compound L8 (16.66 g, a yield 82%) was obtained in the same method as in the preparation method of the Compound L1, except that SM5 (2-chloro-5,7-dimethylquinoline) (10 g, 52.18 mmol) and A4 (20.68 g, 57.39 mmol) were respectively used instead of SM1 (2-chloro-6-isobutylquinoline) (10 g, 45.51 mmol) and A1 (18.04 g, 50.67 mmol).

MS (m/z): 389.18

Preparation of Compound L9

The Compound L9 (17.77 g, a yield 77%) was obtained in the same method as in the preparation method of the Compound L1, except that SM6 (2-chloroquinoline) (10 g, 61.12 mmol) and A5 (25.30 g, 67.24 mmol) were respectively used instead of SM1 (2-chloro-6-isobutylquinoline) (10 g, 45.51 mmol) and A1 (18.04 g, 50.67 mmol).

MS (m/z): 377.12

Preparation of Compound L10

The Compound L10 (13.77 g, a yield 75%) was obtained in the same method as in the preparation method of the Compound L1, except that SM2 (2-chloro-4,5,7-trimethylquinoline) (10 g, 48.62 mmol) and A6 (22.38 g, 53.48 mmol) were respectively used instead of SM1 (2-chloro-6-isobutylquinoline) (10 g, 45.51 mmol) and A1 (18.04 g, 50.67 mmol).

MS (m/z): 377.12

Preparation of Compound L11

The Compound L11 (17.11 g, a yield 74%) was obtained in the same method as in the preparation method of the Compound L1, except that SM2 (2-chloro-4,5,7-trimethylquinoline) (10 g, 48.62) and A7 (23.13 g, 53.48 mmol) were respectively used instead of SM1 (2-chloro-6-isobutylquinoline) (10 g, 45.51 mmol) and A1 (18.04 g, 50.67 mmol) mmol).

MS (m/z): 475.23

Preparation of Compound L12

The compound L12 (17.63 g, a yield 80%) was obtained in the same method as in the preparation method of the Compound L1, except that SM3 (2-chloro-6-methylquinoline) (10 g, 56.30 mmol) and A5 (23.30 g, 61.93 mmol) were respectively used instead of SM1 (2-chloro-6-isobutylquinoline) (10 g, 45.51 mmol) and A1 (18.04 g, 50.67 mmol).

MS (m/z): 391.14

Preparation of Compound L13

The Compound L13 (15.30 g, a yield 75%) was obtained in the same method as in the preparation method of the Compound L1, except that SM2 (2-chloro-4,5,7-trimethylquinoline) (10 g, 48.62 mmol) and A8 (20.13 g, 53.48 mmol) were respectively used instead of SM1 (2-chloro-6-isobutylquinoline) (10 g, 45.51 mmol) and A1 (18.04 g, 50.67 mmol).

MS (m/z): 419.17

Preparation of Compound L14

The Compound L14 (12.92 g, a yield 77%) was obtained in the same method as in the preparation method of the Compound L1, except that SM7 (3-bromo-6-isopropylisoquinoline) (10 g, 40.0 mmol) and A2 (16.54 g, 43.98 mmol) were respectively used instead of SM1 (2-chloro-6-isobutylquinoline) (10 g, 45.51 mmol) and A1 (18.04 g, 50.67 mmol).

MS (m/z): 419.17

Preparation of Compound L15

The Compound L15 (14.61 g, a yield 73%) was obtained in the same method as in the preparation method of the Compound L1, except that SM8 (6-chlorophenanthridine) (10 g, 46.80 mmol) and A2 (19.37 g, 51.48 mmol) were respectively used instead of SM1 (2-chloro-6-isobutylquinoline) (10 g, 45.51 mmol) and A1 (18.04 g, 50.67 mmol).

MS (m/z): 427.14

Preparation of Compound L16

The Compound L16 (14.94 g, a yield 78%) was obtained in the same method as in the preparation method of the Compound L1, except that SM9 (1-chloro-6-isobutyl-3-methylisoquinoline) (10 g, 42.78 mmol) and A2 (17.71 g, 47.06 mmol) were respectively used instead of SM1 (2-chloro-6-isobutylquinoline) (10 g, 45.51 mmol) and A1 (18.04 g, 50.67 mmol).

MS (m/z): 447.20

Preparation of Compound L17

The Compound L17 (17.48 g, a yield 76%) was obtained in the same method as in the preparation method of the Compound L1, except that SM10 (2-chloroquinazoline) (10 g, 60.76 mmol) and A2 (25.15 g, 66.83 mmol) were respectively used instead of SM1 (2-chloro-6-isobutylquinoline) (10 g, 45.51 mmol) and A1 (18.04 g, 50.67 mmol).

MS (m/z): 378.12

Preparation of Compound L18

The compound L18 (16.01 g, a yield 79%) was obtained in the same method as in the preparation method of the Compound L1, except that SM11 (2-chloro-5,7-dimethylquinazoline) (10 g, 51.91 mmol) was used instead of SM1 (2-chloro-6-isobutylquinoline) (10 g, 45.51 mmol).

MS (m/z): 390.17

Preparation of Compound L19

The compound L19 (15.18 g, a yield 77%) was obtained in the same method as in the preparation method of the Compound L1, except that SM12 (2-chlorobenzofuro[2,3-b]pyridine) (10 g, 49.11 mmol) was used instead of SM1 (2-chloro-6-isobutylquinoline) (10 g, 45.51 mmol).

MS (m/z): 401.14

Preparation of Compound L20

The Compound L20 (16.93 g, a yield 75%) was obtained in the same method as in the preparation method of the Compound L1, except that SM12 (2-chlorobenzofuro[2,3-b]pyridine) (10 g, 49.11 mmol) and A6 (22.60 g, 54.02 mmol) were respectively used instead of SM1 (2-chloro-6-isobutylquinoline) (10 g, 45.51 mmol) and A1 (18.04 g, 50.67 mmol).

MS (m/z): 459.17

Preparation of Compound L21

The Compound L21 (16.16 g, a yield 79%) was obtained in the same method as in the preparation method of the Compound L1, except that SM13 (4-chlorobenzofuro[3,2-d]pyrimidine) (10 g, 48.87 mmol) and A2 (20.23 g, 53.76 mmol) were respectively used instead of SM1 (2-chloro-6-isobutylquinoline) (10 g, 45.51 mmol) and A1 (18.04 g, 50.67 mmol).

MS (m/z): 418.11

Preparation of Compound L22

The Compound L22 (15.17 g, a yield 74%) was obtained in the same method as in the preparation method of the Compound L1, except that SM14 (2-chlorobenzofuro[3,2-b]pyridine) (10 g, 49.11 mmol) and A9 (20.33 g, 54.02 mmol) were respectively used instead of SM1 (2-chloro-6-isobutylquinoline) (10 g, 45.51 mmol) and A1 (18.04 g, 50.67 mmol).

MS (m/z): 417.12

Preparation of Compound L23

The compound L23 (14.23 g, a yield 70%) was obtained in the same method as in the preparation method of the Compound L1, except that SM15 (2-chloro-5,7-dimethylquinoline) (10 g, 52.18 mmol) was used instead of SM1 (2-chloro-6-isobutylquinoline) (10 g, 45.51 mmol).

MS (m/z): 389.18

Preparation of Compound L24

The compound L24 (15.30 g, a yield 75%) was obtained in the same method as in the preparation method of the Compound L1, except that SM16 (2-chloro-6-isopropylquinoline) (10 g, 48.62 mmol) and A2 (19.27 g, 53.48 mmol) were respectively used instead of SM1 (2-chloro-6-isobutylquinoline) (10 g, 45.51 mmol) and A1 (18.04 g, 50.67 mmol).

MS (m/z): 419.17

<Preparation of Organometallic Compound >

(1) Preparation of Compound 40

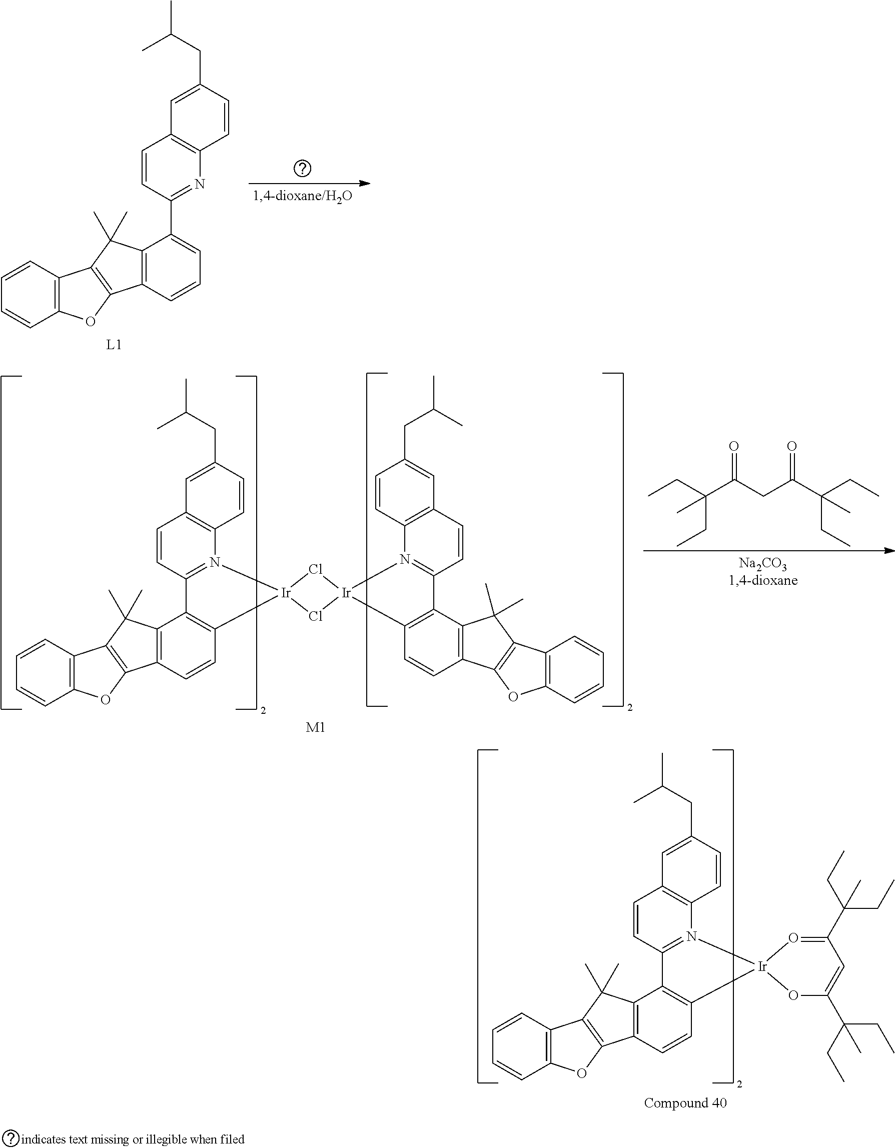

Preparation of Compound M1

L1 (10 g, 23.95 mmol), 1,4-dioxane 200 ml, and distilled water 50 ml were put into a reaction vessel and nitrogen bubbling was performed for 1 hour, then IrCl₃xH₂O (3.80 g, 8.44 mmol) was added thereto and a mixture was refluxed for 24 hours. After a reaction was completed, a temperature was slowly lowered to room temperature and a resulting solid was filtered. The filtered solid was washed with methanol and dried to obtain an intermediate M1 (5.10 g, a yield 57%).

Preparation of Compound 40

The intermediate M1 (5.10 g, 2.41 mmol), 3,7-diethyl-3,7-dimethylnonane-4,6-dione (1.73 g, 7.22 mmol), Na₂CO₃ (5.10 g, 48.11 mmol), and 100 ml of 1,4-dioxane were input into a reaction vessel, and a mixture was refluxed for 24 hours under a nitrogen atmosphere. After a reaction was completed, dichloromethane was added to a reaction mixture to dissolve the reaction mixture, and then the reaction mixture was subjected to extraction with dichloromethane and distilled water. MgSO₄ was used to remove water from an organic layer, and after filtering, the solvent was removed therefrom under reduced pressure. Column chromatography was carried out with hexane and dichloromethane. Thus, the Compound 40 (2.43 g, a yield 40%) was obtained.

MS (m/z): 1264.57

(2) Preparation of Compound 45

Intermediate M2 (4.97 g, a yield 55%) was obtained in the same method as in the preparation method of the intermediate M1, except that L2 (10 g, 24.78 mmol) was used instead of L1 (10 g, 23.95 mmol).

The compound 45 (2.38 g, a yield 48%) was obtained in the same method as in the preparation method of the Compound 40 except that M2 (4.97 g, 2.41 mmol) was used instead of M1 (5.10 g, 2.41 mmol).

MS (m/z): 1236.54

(3) Preparation of Compound 98

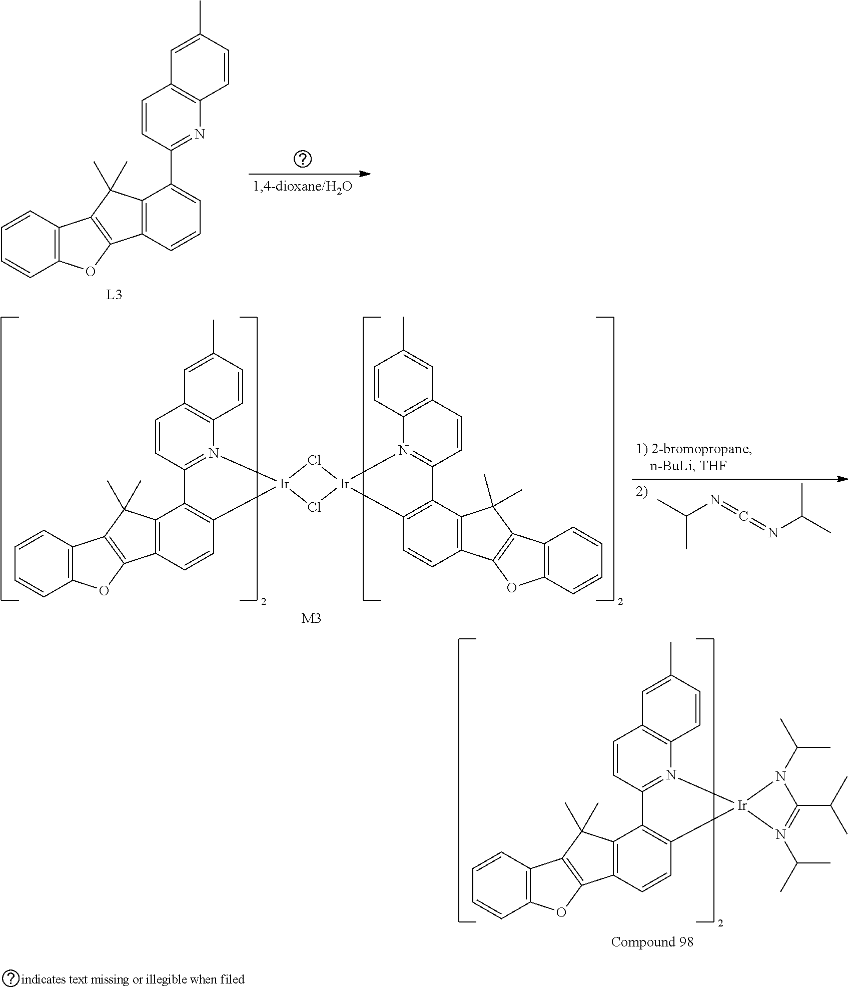

Intermediate M3 (4.98 g, a yield 54%) was obtained in the same method in the preparation method of the intermediate M1 except that L3 (10 g, 26.63 mmol) was used instead of L1 (10 g, 23.95 mmol).

Then, 2-bromopropane (1.25 g, 10.19 mmol) and 100 ml of THF were put into a reaction vessel under a nitrogen stream, and a temperature was lowered to −78° C., and then n-BuLi (4.08 ml, 2.5 M in hexane) was slowly added thereto. After 30 minutes, while the temperature was maintained, N,N′-diisopropylcarbodiimide (1.29 g, 10.19 mmol) was slowly added thereto and a mixture was stirred for 30 minutes. The reaction mixture was added to a reaction vessel in which M3 (4.98 g, 2.55 mmol) was dissolved in 200 ml THF and the mixture was stirred at 80° C. for 8 hours. A temperature of the reaction mixture was lowered to room temperature, and volatile substances were removed therefrom, and recrystallization thereof was performed using THF/pentane and dichloromethane/hexane to obtain the Compound 98 (2.26 g, a yield 50%).

MS (m/z): 1110.44

(4) Preparation of Compound 124

An intermediate M4 (4.66 g, a yield 52%) was obtained in the same method as in the preparation method of the intermediate M1, except that L4 (10 g, 23.06 mmol) was used instead of L1 (10 g, 23.95 mmol).

The Compound 124 (1.97 g, a yield 52%) was obtained in the same method as in the preparation method of the Compound 40, except that M4 (4.66 g, 2.13 mmol) and pentane-2,4-dione (0.64 g, 6.39 mmol) were respectively used instead of M1 (5.10 g, 2.41 mmol) and 3,7-diethyl-3,7-dimethylnonane-4,6-dione (1.73 g, 7.22 mmol).

MS (m/z): 1156.36

(5) Preparation of Compound 153

An intermediate M5 (4.25 g, a yield 47%) was obtained in the same method as in the preparation method of the intermediate M1, except that L5 (10 g, 23.83 mmol) was used instead of L1 (10 g, 23.95 mmol).

The compound 153 (1.98 g, a yield 45%) was obtained in the same method as in the preparation method of the Compound 40, except that M5 (4.25 g, 2.00 mmol) and 3,7-diethylnonane-4,6-dione (1.27 g, 5.99 mmol) were respectively used instead of M1 (5.10 g, 2.41 mmol) and 3,7-diethyl-3,7-dimethylnonane-4,6-dione (1.73 g, 7.22 mmol)

MS (m/z): 1240.46

(6) Preparation of Compound 160

An intermediate M4 (4.68 g, a yield 52%) was obtained in the same method as in the preparation method of the intermediate M1 except that L4 (10 g, 23.06 mmol) was used instead of L1 (10 g, 23.95 mmol).

The Compound 160 (2.22 g, a yield 43%) was obtained in the same method as in the preparation method of the Compound 40, except that M4 (4.68 g, 2.14 mmol) was used instead of M1 (5.10 g, 2.41 mmol).

MS (m/z): 1296.52

(7) Preparation of Compound 163

An intermediate M6 (4.97 g, a yield 55%) was obtained in the same method as in the preparation method of the intermediate M1 except that L6 (10 g, 23.06 mmol) was used instead of L1 (10 g, 23.95 mmol).

The Compound 163 (2.36 g, a yield 49%) was obtained in the same method in the preparation method of the Compound 40 except that M6 (4.97 g, 2.27 mmol) was used instead of M1 (5.10 g, 2.41 mmol).

MS (m/z): 1296.52

(8) Preparation of Compound 272

An intermediate M7 (4.20 g, a yield 46%) was obtained in the same method as in the preparation method of the intermediate M1 except that L7 (10 g, 24.06 mmol) was used instead of L1 (10 g, 23.95 mmol).

The Compound 272 (1.96 g, a yield 47%) was obtained in the same method as in the preparation method of the Compound 40, except that M7 (4.20 g, 1.99 mmol) and 3,7-diethylnonane-4,6-dione (1.27 g, 5.97 mmol) were respectively used instead of M1 (5.10 g, 2.41 mmol) and 3,7-diethyl-3,7-dimethylnonane-4,6-dione (1.73 g, 7.22 mmol).

MS (m/z): 1232.58

(9) Preparation of Compound 380

An intermediate M8 (4.37 g, a yield 47%) was obtained in the same method as in the preparation method of the intermediate M1 except that L8 (10 g, 25.67 mmol) was used instead of L1 (10 g, 23.95 mmol).

The Compound 380 (2.00 g, a yield 54%) was obtained in the same method as in the preparation method of the Compound 40, except that M8 (4.37 g, 2.17 mmol) and 2,2,6,6-tetramethylheptane-3,5-dione (1.20 g, 6.52 mmol) were respectively used instead of M1 (5.10 g, 2.41 mmol) and 3,7-diethyl-3,7-dimethylnonane-4,6-dione (1.73 g, 7.22 mmol).

MS (m/z): 1152.44

(10) Preparation of Compound 433

An intermediate M9 (4.60 g, a yield 49%) was obtained in the same method as in the preparation method of the intermediate M1 except that L9 (10 g, 26.49 mmol) was used instead of L1 (10 g, 23.95 mmol).

The Compound 433 (2.17 g, a yield 510%) was obtained in the same method as in the preparation method of the Compound 40, except that M9 (4.60 g, 2.35 mmol) and 3,7-diethylnonane-4,6-dione (1.49 g, 7.04 mmol) were respectively used instead of M1 (5.10 g, 2.41 mmol) and 3,7-diethyl-3,7-dimethylnonane-4,6-dione (1.73 g, 7.22 mmol).

MS (m/z): 1156.36

(11) Preparation of Compound 443

An intermediate M10 (4.69 g, a yield 52%) was obtained in the same method as in the preparation method of the intermediate M1 except that L10 (10 g, 21.66 mmol) was used instead of L1 (10 g, 23.95 mmol).

The Compound 443 (2.16 g, a yield 44%) was obtained in the same method as in the preparation method of the Compound 40, except that M10 (4.69 g, 2.04 mmol) and 3,7-diethylnonane-4,6-dione (1.30 g, 6.12 mmol) were respectively used instead of M1 (5.10 g, 2.41 mmol) and 3,7-diethyl-3,7-dimethylnonane-4,6-dione (1.73 g, 7.22 mmol).

MS (m/z): 1324.55

(12) Preparation of Compound 492

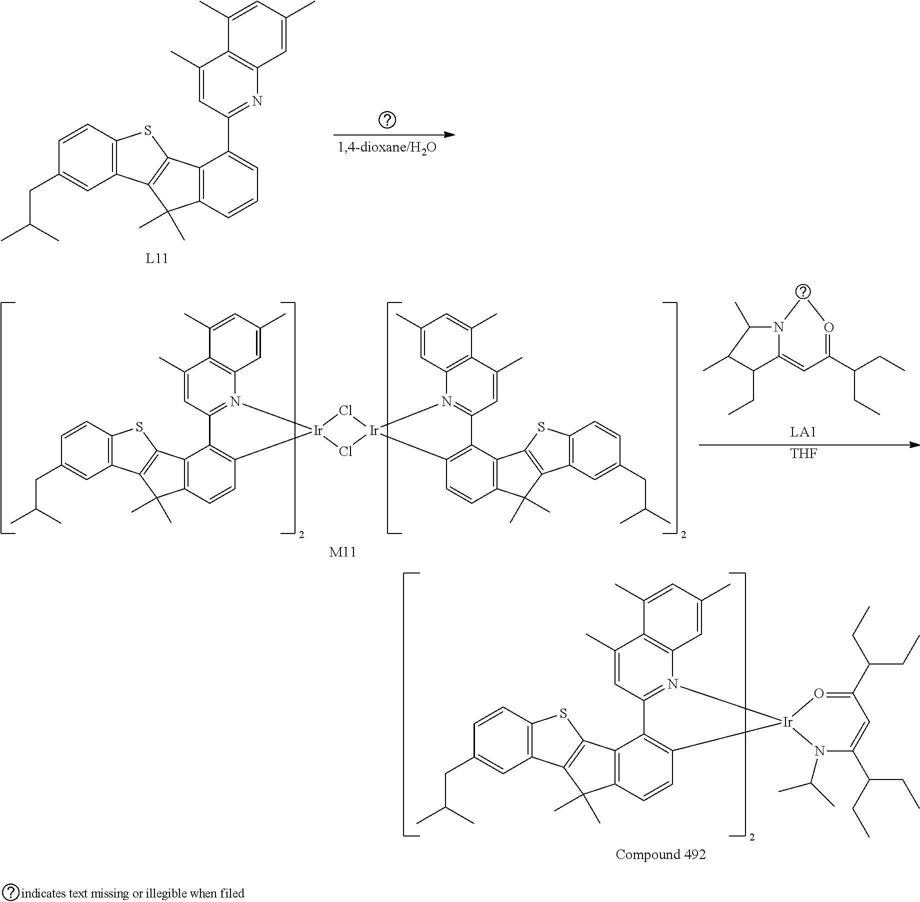

An intermediate M11 (4.95 g, a yield 55%) was obtained in the same method as in the preparation method of the intermediate M1, except that L11 (10 g, 21.02 mmol) was used instead of L1 (10 g, 23.95 mmol).

Then, M11 (4.95 g, 2.10 mmol) and 100 ml of THF were put in a reaction vessel under a nitrogen stream, and LA1 (3.67 g, 12.6 mmol) dissolved in THF was slowly added thereto, followed by stirring at room temperature for 8 hours. After completion of a reaction, THF was removed therefrom and then, extraction was performed using toluene. Then, the solvent was removed therefrom. Diethyl ether was added thereto. Thus, the Compound 492 (2.34 g, a yield 43%) was obtained.

MS (m/z): 1393.65

(13) Preparation of Compound 518

An intermediate M12 (5.45 g, a yield 58%) was obtained in the same method as in the preparation method of the intermediate M1 except for using L12 (10 g, 25.54 mmol) instead of L1 (10 g, 23.95 mmol).

The Compound 518 (2.64 g, a yield 47%) was obtained in the same method as in the preparation method of the Compound 98, except that M12 (5.45 g, 2.70 mmol) and N,N′-methanediylidenedicyclohexanamine (2.23 g, 10.80 mmol) were respectively used instead of M3 (4.98 g, 2.55 mmol) and N,N′-diisopropylcarbodiimide (1.29 g, 10.19 mmol).

MS (m/z): 1222.46

(14) Preparation of Compound 623

An intermediate M13 (4.54 g, a yield 49%) was obtained in the same method in the preparation method of the intermediate M1 except that L13 (10 g, 23.83 mmol) was used instead of L1 (10 g, 23.95 mmol).

The Compound 623 (2.17 g, a yield 50%) was obtained in the same method as in the preparation method of the Compound 40 except that M13 (4.54 g, 2.13 mmol) was used instead of M1 (5.10 g, 2.41 mmol).

MS (m/z): 1268.49

(15) Preparation of Compound 674

An intermediate M14 (4.65 g, a yield 50%) was obtained in the same method as in the preparation method of the intermediate M1 except that L14 (10 g, 23.83 mmol) was used instead of L1 (10 g, 23.95 mmol).

The Compound 674 (2.17 g, a yield 53%) was obtained in the same method as in the preparation method of the Compound 40, except that M14 (4.65 g, 2.18 mmol) and 3,7-diethylnonane-4,6-dione (1.39 g, 6.55 mmol) were respectively used instead of M1 (5.10 g, 2.41 mmol) and 3,7-diethyl-3,7-dimethylnonane-4,6-dione (1.73 g, 7.22 mmol).

MS (m/z): 1240.46

(16) Preparation of Compound 681

An intermediate M15 (4.74 g, a yield 51%) was obtained in the same method as in the preparation method of the intermediate M1 except that L15 (10 g, 23.39 mmol) was used instead of L1 (10 g, 23.95 mmol).

The Compound 681 (2.20 g, a yield 51%) was obtained in the same method as in the preparation method of the Compound 40, except that M15 (4.74 g, 2.19 mmol) and 3,7-diethylnonane-4,6-dione (1.40 g, 6.57 mmol) were respectively used instead of M1 (5.10 g, 2.41 mmol) and 3,7-diethyl-3,7-dimethylnonane-4,6-dione (1.73 g, 7.22 mmol).

MS (m/z): 1256.40

(17) Preparation of Compound 692

An intermediate M16 (4.14 g, a yield 44%) was obtained in the same method as in the preparation method of the intermediate M1 except that L16 (10 g, 23.06 mmol) was used instead of L1 (10 g, 23.95 mmol).

The Compound 692 (1.94 g, a yield 49%) was obtained in the same method as in the preparation method of the Compound 40 except that M16 (4.14 g, 1.87 mmol) was used instead of M1 (5.10 g, 2.41 mmol).

MS (m/z): 1296.52

(18) Preparation of Compound 749

An intermediate M17 (4.60 g, a yield 48%) was obtained in the same method as in the preparation method of the intermediate M1 except that L17 (10 g, 26.42 mmol) was used instead of L1 (10 g, 23.95 mmol).

The Compound 749 (2.22 g, a yield 46%) was obtained in the same method as in the preparation method of the Compound 40, except that M17 (4.60 g, 2.34 mmol) was used instead of M1 (510 g, 2.41 mmol).

MS (m/z): 1186.39

(19) Preparation of Compound 764

An intermediate M18 (4.30 g, a yield 45%) was obtained in the same method as in the preparation method of the intermediate M1 except that L18 (10 g, 24.91 mmol) was used instead of L1 (10 g, 23.95 mmol).

The Compound 764 (2.07 g, a yield 48%) was obtained in the same method as in the preparation method of the Compound 40 except that M18 (4.30 g, 2.13 mmol) was used instead of M1 (5.10 g, 2.41 mmol).

MS (m/z): 1210.49

(20) Preparation of Compound 781

An intermediate M19 (4.00 g, a yield 42%) was obtained in the same method as in the preparation method of the intermediate M1 except that L19 (10 g, 24.91 mmol) was used instead of L1 (10 g, 23.95 mmol).

The Compound 781 (1.92 g, a yield 54%) was obtained in the same method as in the preparation method of the Compound 40 except that M19 (4.00 g, 1.94 mmol) was used instead of M1 (5.10 g, 2.41 mmol).

MS (m/z): 1232.43

(21) Preparation of Compound 791

An intermediate M20 (4.55 g, a yield 49%) was obtained in the same method as in the preparation method of the intermediate M1, except that L20 (10 g, 21.76 mmol) was used instead of L1 (10 g, 23.95 mmol).

The Compound 791 (2.14 g, a yield 55%) was obtained in the same method as in the preparation method of the Compound 40, except that M20 (4.55 g, 1.99 mmol) was used instead of M1 (5.10 g, 2.41 mmol).

MS (m/z): 1348.48

(22) Preparation of Compound 809

An intermediate M21 (4.93 g, a yield 52%) was obtained in the same method as in the preparation method of the intermediate M1 except that L21 (10 g, 23.89 mmol) was used instead of L1 (10 g, 23.95 mmol).

The Compound 809 (2.35 g, a yield 52%) was obtained in the same method as in the preparation method of the Compound 40 except that M21 (4.93 g, 2.32 mmol) was used instead of M1 (5.10 g, 2.41 mmol).

MS (m/z): 1266.38

(23) Preparation of Compound 832

An intermediate M22 (4.85 g, a yield 51%) was obtained in the same method as in the preparation method of the intermediate M1 except for using L22 (10 g, 23.95 mmol) instead of L1 (10 g, 23.95 mmol).

The Compound 832 (2.31 g, a yield 45%) was obtained in the same method as in the preparation method of the Compound 40, except that M22 (4.85 g, 2.29 mmol) was used instead of M1 (5.10 g, 2.41 mmol).

MS (m/z): 1264.39

(24) Preparation of Compound 844

An intermediate M23 (4.79 g, a yield 52%) was obtained in the same method as in the preparation method of the intermediate M1 except for using L23 (10 g, 25.67 mmol) instead of L1 (10 g, 23.95 mmol).

The Compound 844 (2.77 g, a yield 47%) was obtained in the same method as in the preparation method of the Compound 40, except that M23 (4.79 g, 2.41 mmol) and 3,7-diisopropyl-2,8-dimethylnonane-4,6-dione (1.92 g, 7.15 mmol) were respectively used instead of M1 (5.10 g, 2.41 mmol) and 3,7-diethyl-3,7-dimethylnonane-4,6-dione (1.73 g, 7.22 mmol).

MS (m/z): 1236.60

(25) Preparation of Compound 875

An intermediate M24 (4.35 g, a yield 48%) was obtained in the same method as in the preparation method of the intermediate M1 except that L24 (10 g, 23.83 mmol) was used instead of L1 (10 g, 23.95 mmol).

The Compound 875 (2.44 g, a yield 45%) was obtained in the same method as in the preparation method of the Compound 40, except that M24 (4.35 g, 2.04 mmol) and 3,7-diisopropyl-2,3,7,8-tetramethylnonane-4,6-dione (0.64 g, 6.39 mmol) were respectively used instead of M1 (5.10 g, 2.41 mmol) and 3,7-diethyl-3,7-dimethylnonane-4,6-dione (1.73 g, 7.22 mmol).

MS (m/z): 1324.55

### Present Example 1

A glass substrate having a thin film of ITO (indium tin oxide) having a thickness of 1,000 Å coated thereon was washed, followed by ultrasonic cleaning with a solvent such as isopropyl alcohol or acetone. Then, the glass substrate was dried. Thus, an ITO transparent electrode was formed. HI-1 as a hole injection material was deposited on the ITO transparent electrode in a thermal vacuum deposition manner. Thus, a hole injection layer having a thickness of 60 nm was formed. Then, NPB as a hole transport material was deposited on the hole injection layer in a thermal vacuum deposition manner. Thus, a hole transport layer having a thickness of 80 nm was formed. Then, CBP as a host material of a light-emitting layer was deposited on the hole transport layer in a thermal vacuum deposition manner. The Compound 40 as a dopant was doped into the host material at a doping concentration of 5%. Thus, the light-emitting layer of a thickness of 30 nm was formed. ET-1:Liq (1:1) (30 nm) as a material for an electron transport layer and an electron injection layer was deposited on the light-emitting layer. Then, 100 nm thick aluminum was deposited thereon to form a negative electrode. In this way, an organic light-emitting diode was manufactured.

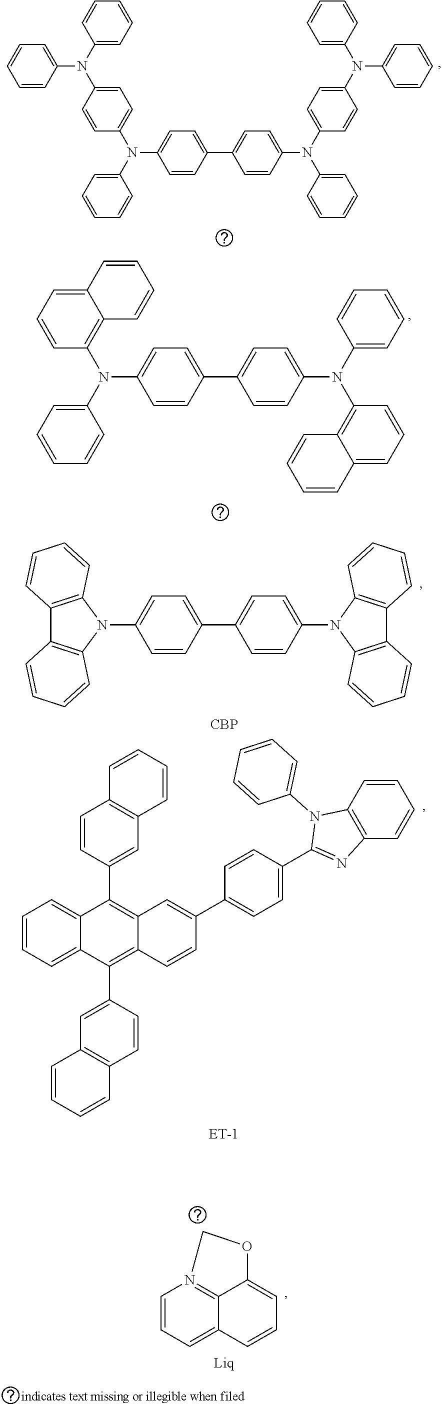

The HI-1 means N1,N1′-([1,1′-biphenyl]-4,4′-diyl)bis(N1,N4,N4-triphenylbenzene-1,4-diamine).

The ET-1 means 2-(4-(9,10-di(naphthalen-2-yl)anthracen-2-yl)phenyl)-1-phenyl-1H-benzo[d]imidazole.

### Present Examples 2 to 25 and Comparative Examples 1 to 2

Organic light-emitting diodes of Present Examples 2 to 25 and Comparative Examples 1 to 2 were manufactured in the same method as in Present Example 1, except that Compounds indicated in following Tables 1 and 2 were used instead of the Compound 40 as the dopant in the Present Example 1.

<Performance Evaluation of Organic Light-Emitting Diodes>

Regarding the organic light emitting diodes prepared according to Present Examples 1 to 25 and Comparative Examples 1 to 2, operation voltages and efficiency characteristics at 10 mA/cm² current, and lifetime characteristics when being accelerated at 20 mA/cm² were measured. Thus, operation voltage (V), EQE (%), and LT95(%) were measured, and results are shown in Tables 1 to 2 below. LT95 refers to a lifetime evaluation scheme and means a time it takes for an organic light-emitting diode to lose 5% of initial brightness thereof.

In this regard, a performance evaluation value of each of Present Examples 1 to 21 in the following Table 1 is a relative value to a value of Comparative Example 1. A performance evaluation value of each of Present Examples 22 to 25 in the following Table 2 is a relative value to a value of Comparative Example 2.

TABLE 1

| | | Operation | | |
|---|---|---|---|---|
| | | voltage | EQE | LT95 |
| | | (V, relative | (%, relative | (%, relative |
| Examples | Dopant | value) | value) | value) |
| Comparative Example 1 | RD-1 | 100 | 100 | 100 |
| Present Example 1 | Compound 40 | 97.5 | 115 | 151 |
| Present Example 2 | Compound 45 | 98.7 | 120 | 145 |
| Present Example 3 | Compound 98 | 94.1 | 125 | 112 |
| Present Example 4 | Compound 124 | 97.4 | 117 | 131 |
| Present Example 5 | Compound 153 | 98.2 | 119 | 134 |
| Present Example 6 | Compound 160 | 97.5 | 124 | 133 |
| Present Example 7 | Compound 163 | 97.6 | 122 | 131 |
| Present Example 8 | Compound 272 | 98.4 | 121 | 128 |
| Present Example 9 | Compound 380 | 97.7 | 113 | 115 |
| Present Example 10 | Compound 433 | 96.8 | 136 | 140 |
| Present Example 11 | Compound 443 | 96.9 | 132 | 143 |
| Present Example 12 | Compound 492 | 93.5 | 128 | 113 |
| Present Example 13 | Compound 518 | 96.6 | 125 | 130 |
| Present Example 14 | Compound 623 | 95.8 | 122 | 127 |
| Present Example 15 | Compound 674 | 96.7 | 120 | 121 |
| Present Example 16 | Compound 681 | 97.5 | 110 | 112 |
| Present Example 17 | Compound 692 | 98.2 | 105 | 116 |
| Present Example 18 | Compound 749 | 93.1 | 124 | 108 |
| Present Example 19 | Compound 764 | 94.4 | 121 | 110 |
| Present Example 20 | Compound 844 | 97.2 | 117 | 153 |
| Present Example 21 | Compound 875 | 97.0 | 124 | 133 |

A structure of RD-1 as a dopant material of Comparative Example 1 of the Table 1 is as follows.

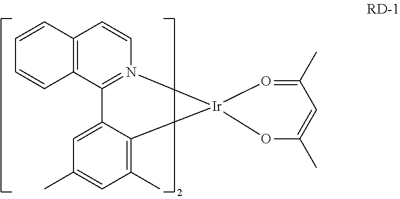

TABLE 2

| | | Operation | | |
|---|---|---|---|---|
| | | voltage | EQE | LT95 |
| | | (V, relative | (%, relative | (%, relative |
| Examples | Dopant | value) | value) | value) |
| Comparative Example 2 | RD-2 | 100 | 100 | 100 |
| Present Example 22 | Compound 781 | 98.4 | 110 | 122 |
| Present Example 23 | Compound 791 | 97.7 | 121 | 132 |
| Present Example 24 | Compound 809 | 95.2 | 118 | 102 |
| Present Example 25 | Compound 832 | 96.7 | 108 | 110 |

A structure of RD-2 as a dopant material of Comparative Example 2 of the Table 2 is as follows.

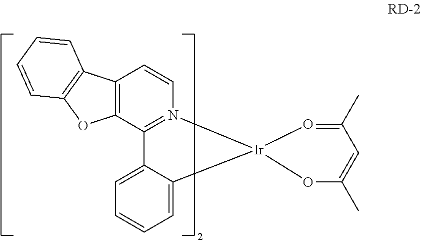

It can be identified from the results of the above Table 1 that in the organic light-emitting diode in which the organometallic compound of each of Present Examples 1 to 21 according to the present disclosure is used as the dopant of the light-emitting layer of the diode, the operation voltage of the diode is lowered, and external quantum efficiency (EQE) and lifetime (LT95) of the diode are improved, compared to those in Comparative Example 1.

It can be identified from the results of the above Table 2 that in the organic light-emitting diode in which the organometallic compound of each of Present Examples 22 to 25 according to the present disclosure is used as the dopant of the light-emitting layer of the diode, the operation voltage of the diode is lowered, and external quantum efficiency (EQE) and lifetime (LT95) of the diode are improved, compared to those in Comparative Example 2.

A scope of protection of the present disclosure should be construed by the scope of the claims, and all technical ideas within the scope equivalent thereto should be construed as being included in the scope of the present disclosure. Although the embodiments of the present disclosure have been described in more detail with reference to the accompanying drawings, the present disclosure is not necessarily limited to these embodiments. The present disclosure can be implemented in various modified manners within the scope not departing from the technical idea of the present disclosure. Accordingly, the embodiments disclosed in the present disclosure are not intended to limit the technical idea of the present disclosure, but to describe the present disclosure. The scope of the technical idea of the present disclosure is not limited by the embodiments. Therefore, it should be understood that the embodiments as described above are illustrative and non-limiting in all respects. The scope of protection of the present disclosure should be interpreted by the claims, and all technical ideas within the scope of the present disclosure should be interpreted as being included in the scope of the present disclosure.

What is claimed is:

1. An organometallic compound represented by a following Chemical Formula 1: 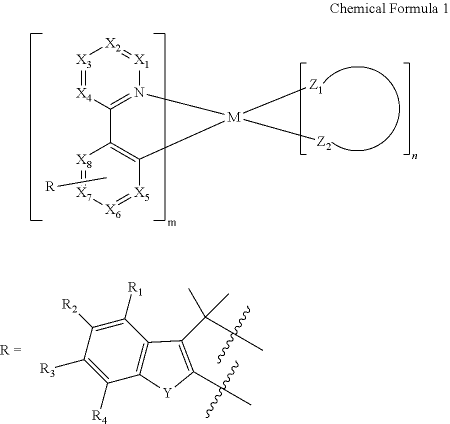
wherein in the Chemical Formula 1, M represents one selected from a group consisting of Mo, W, Re, Ru, Os, Rh, Ir, Pd, Pt and Au;
R represents a ring structure fused with one pair selected from a pair of X₅ and X₆, a pair of X₆ and X₇, and a pair of X₇ and X₈;
each of X₁ to X₄ independently represents one selected from CR₅ and N;
optionally, two R₅ on the adjacent two of X₁ to X₄ are connected to each other to form a ring structure including one selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group;
Y represents one selected from a group consisting of BR₆, CR₆R₇, C═O, CNR₆, SiR₆R₇, NR₆, PR₆, AsR₆, SbR₆, P(O)R₆, P(S)R₆, P(Se)R₆, As(O)R₆, As(S)R₆, As(Se)R₆, Sb(O)R₆, Sb(S)R₆, Sb(Se)R₆, O, S, Se, Te, SO, SO₂, SeO, SeO₂, TeO and TeO₂;
each of X₅ to X₈ independently represents CR₈;
each of R₅ to R₈ independently represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
(Z₁-Z₂) represents a bidentate ligand; and
m is 1, 2 or 3, n is 0, 1 or 2, and a sum of m and n is an oxidation number of the M.

2. The organometallic compound of claim 1, wherein the Chemical Formula 1 is one selected from a group consisting of following Chemical Formulas 2 to 5: 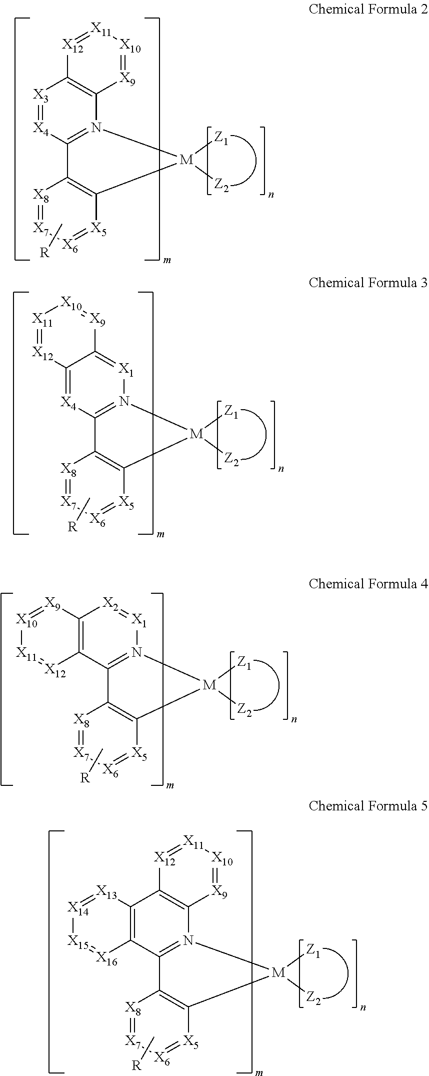
wherein in each of the Chemical Formula 2 to Chemical Formula 5,
each of X₉ to X₁₆ independently represents one selected from CR₉ and N;
optionally, two R₉ on the adjacent two of X₉ to X₁₆ are connected to each other to form a ring structure including one selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group;
R₉ represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
M, Y, X₁ to X₈, R, R₁ to R₈, (Z₁-Z₂), m and n are the same as defined in claim 1.

3. The organometallic compound of claim 1, wherein the Chemical Formula 1 is one selected from a group consisting of following Chemical Formulas 6 to 11: 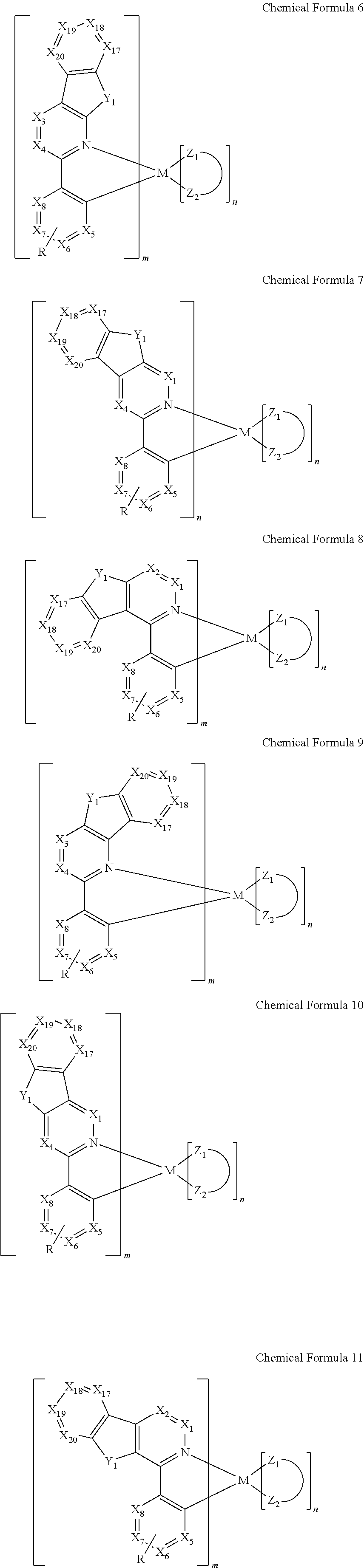
wherein in each of the Chemical Formula 6 to Chemical Formula 11,
each of X₁₇ to X₂₀ independently represents one selected from CR₁₀ and N;
optionally, R₁₀ on the adjacent two of X₁₇ to X₂₀ are connected to each other to form a ring structure including one selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group;
Y₁ represents one selected from a group consisting of CR₁₁R₁₂, NR₁₁, O and S;
each of R₁₀ to R₁₂ independently represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
M, Y, X₁ to X₈, R, R₁ to R₈, (Z₁-Z₂), m and n are the same as defined in claim 1.

4. The organometallic compound of claim 1, wherein M is iridium (Ir).

5. The organometallic compound of claim 1, wherein m is 1 and n is 2.

6. The organometallic compound of claim 1, wherein m is 2 and n is 1.

7. The organometallic compound of claim 1, wherein m is 3 and n is 0.

8. The organometallic compound of claim 1, wherein the compound represented by the Chemical Formula 1 includes one selected from a group consisting of following compounds 1 to 884:

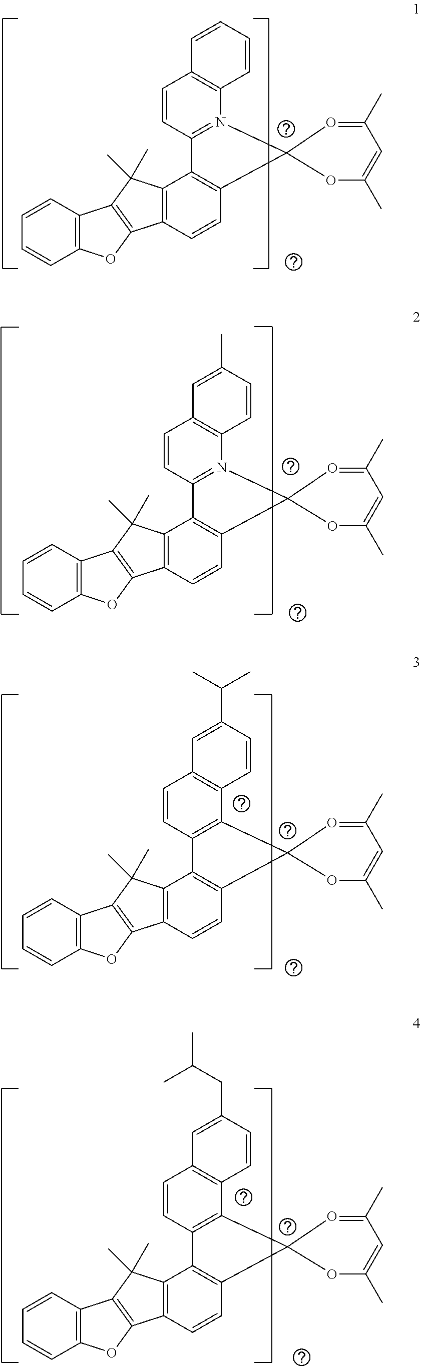

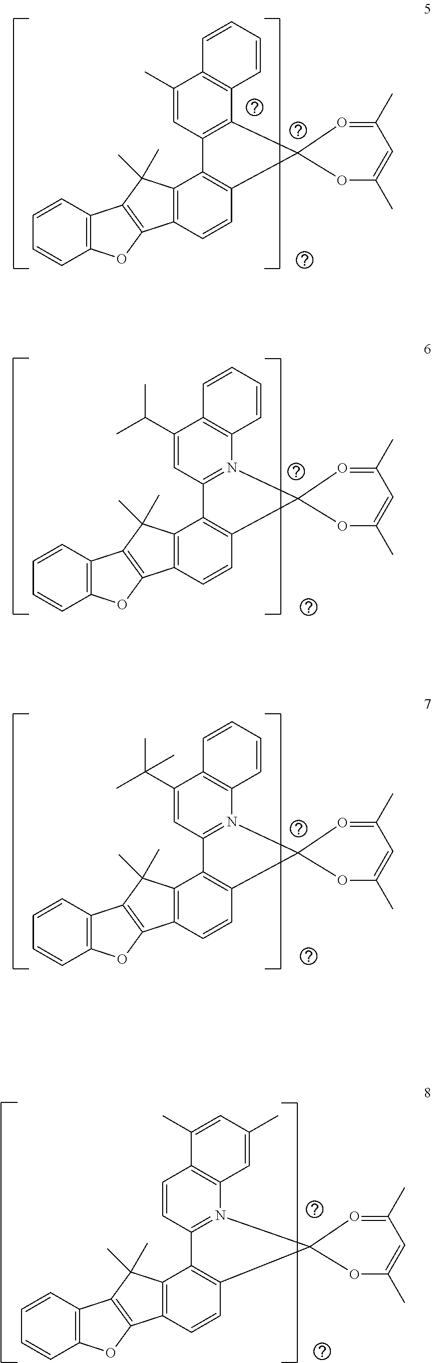

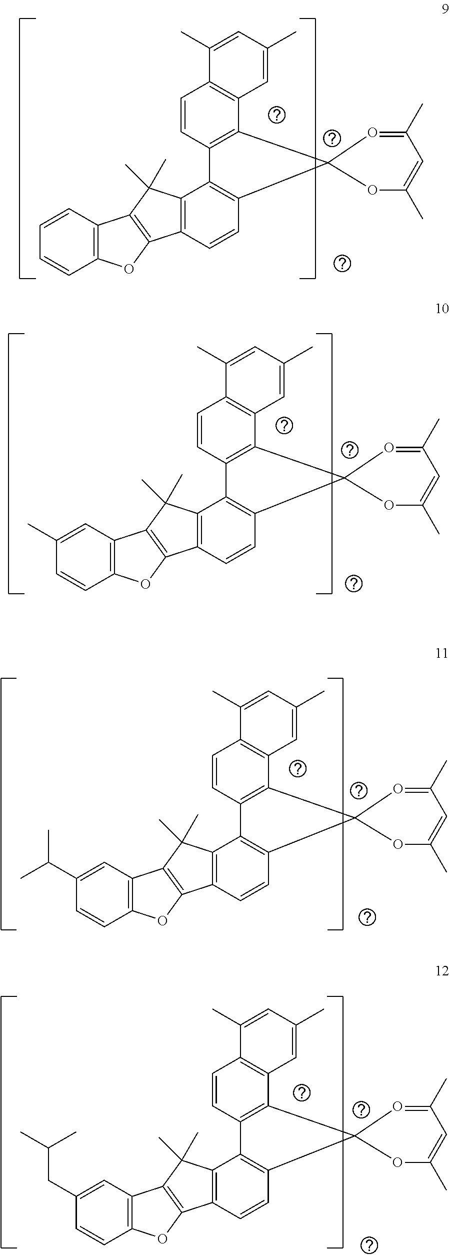

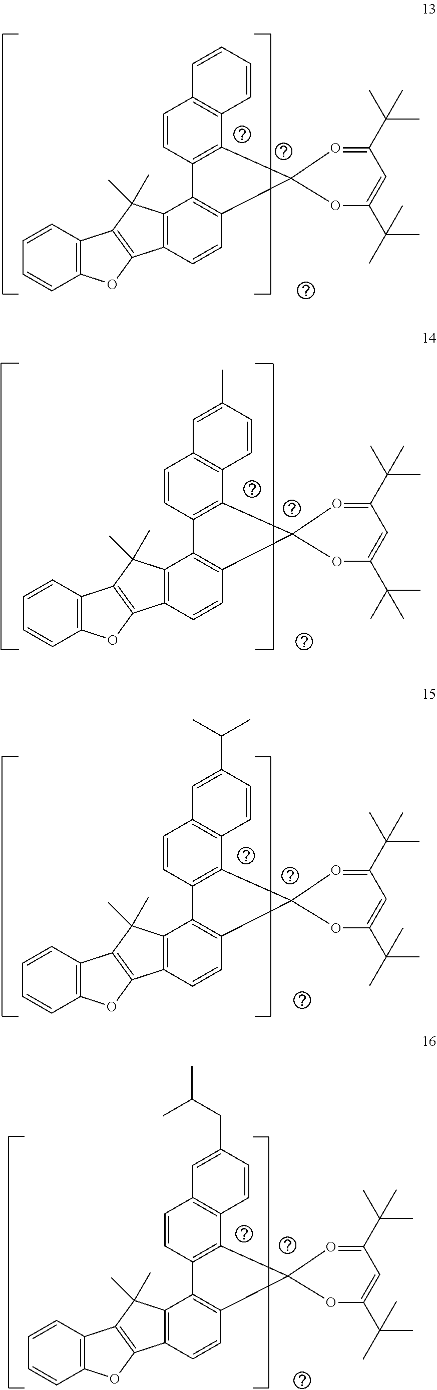

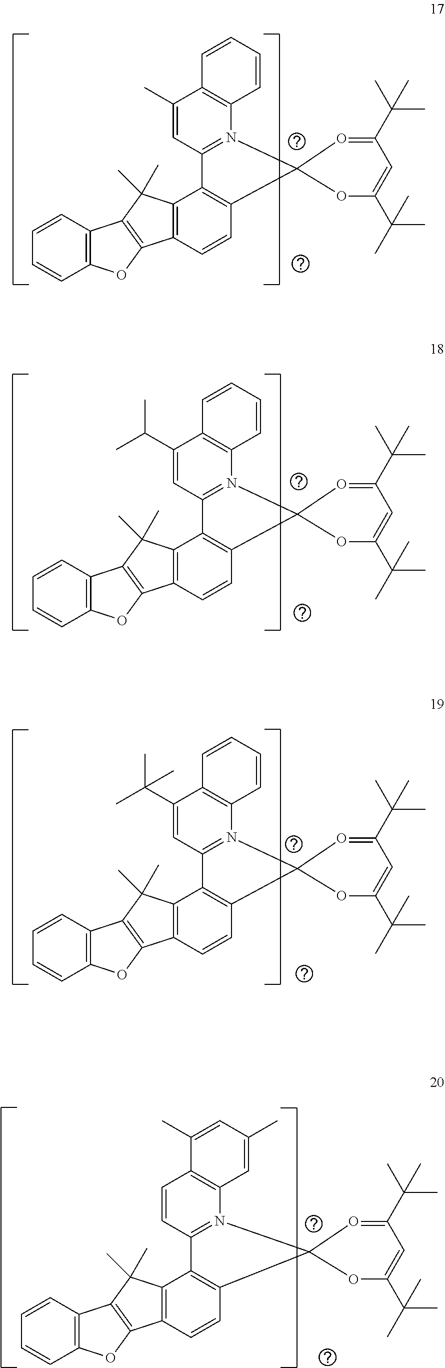

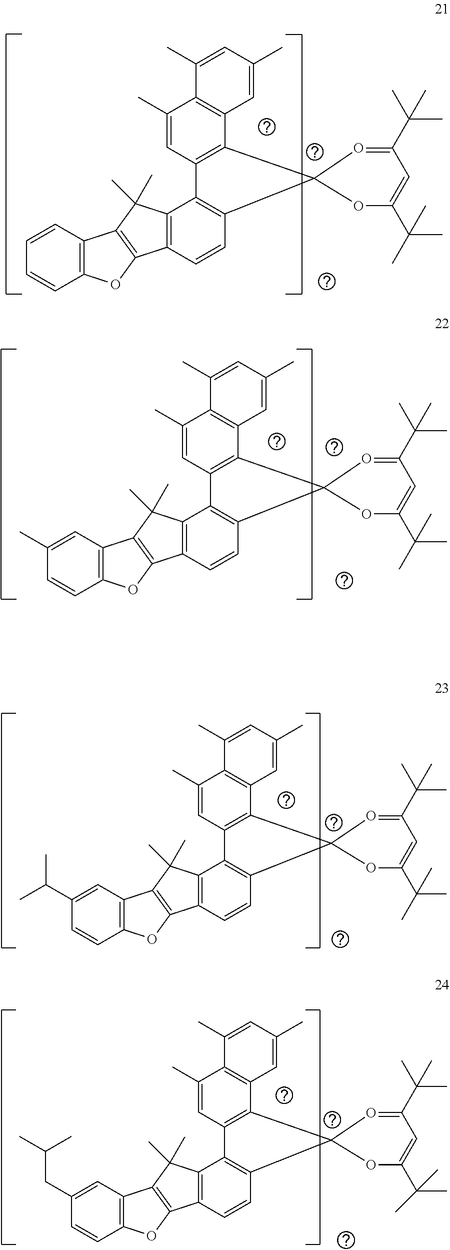

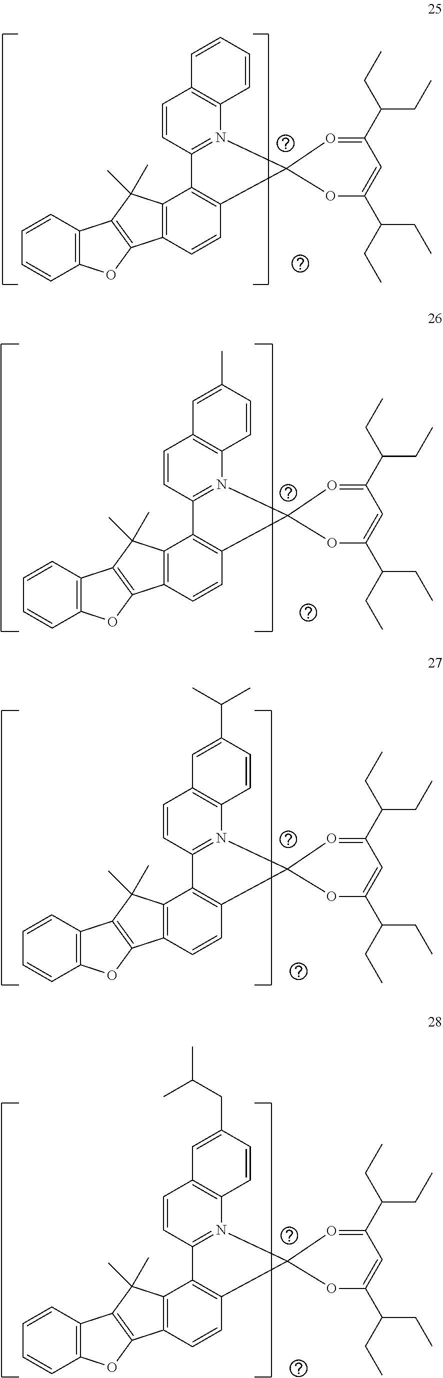

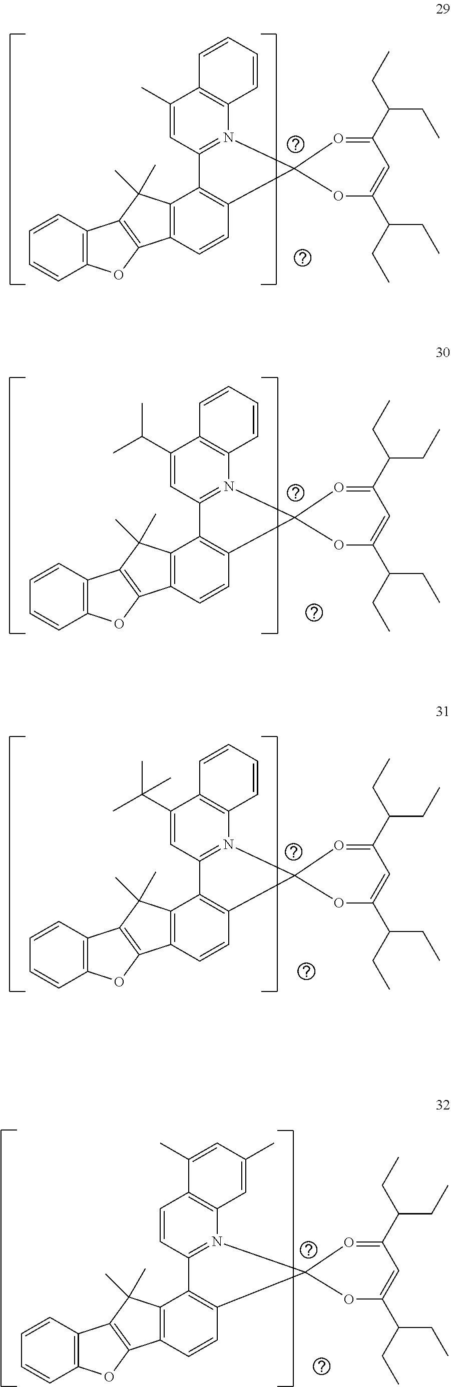

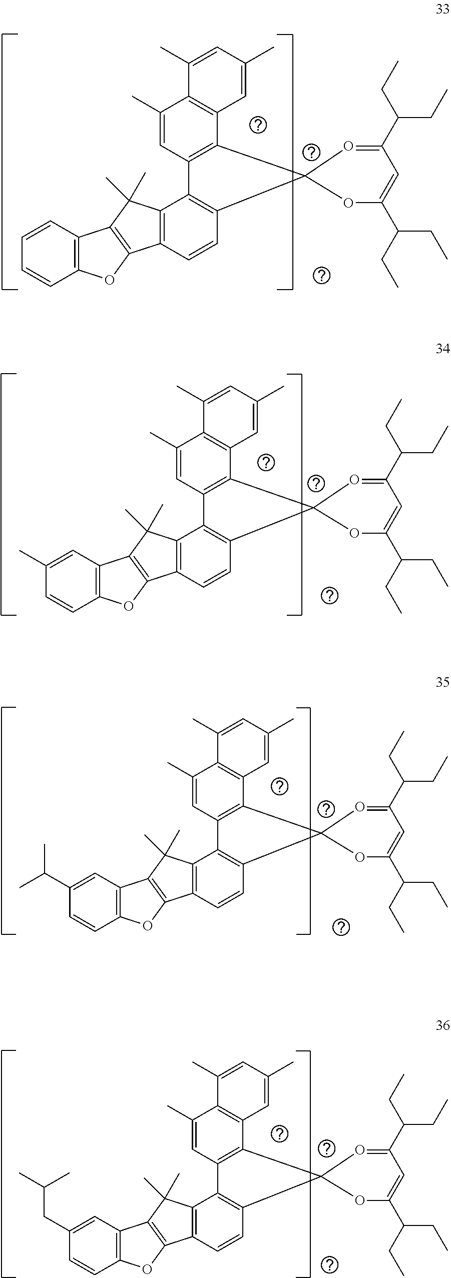

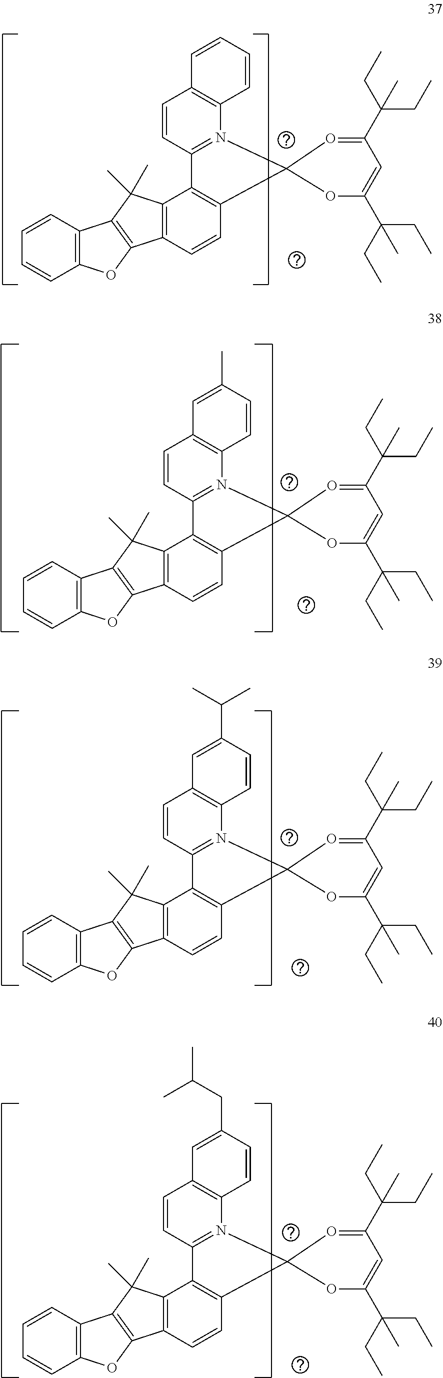

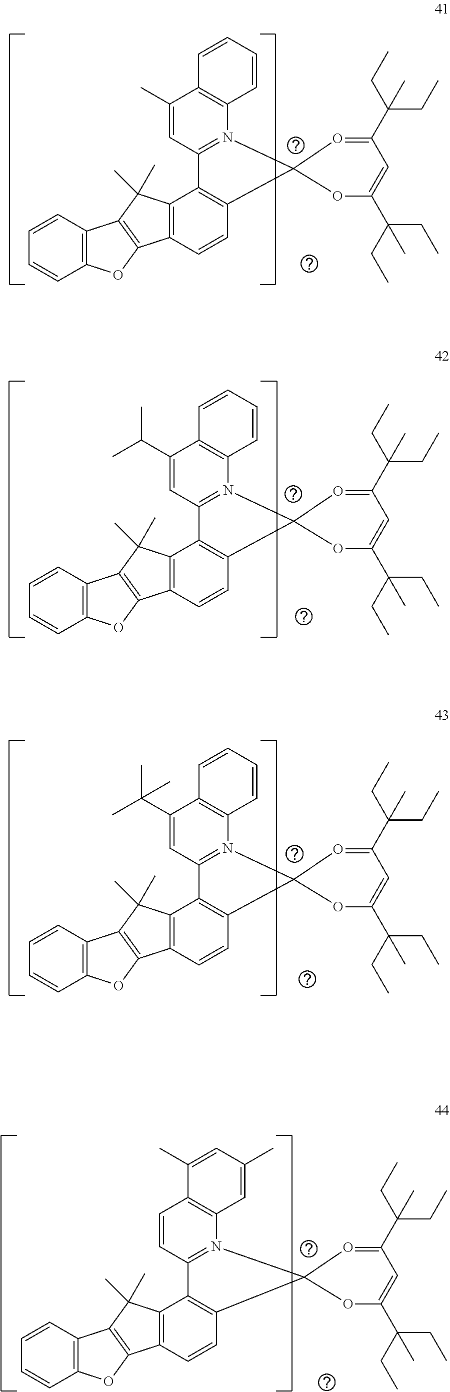

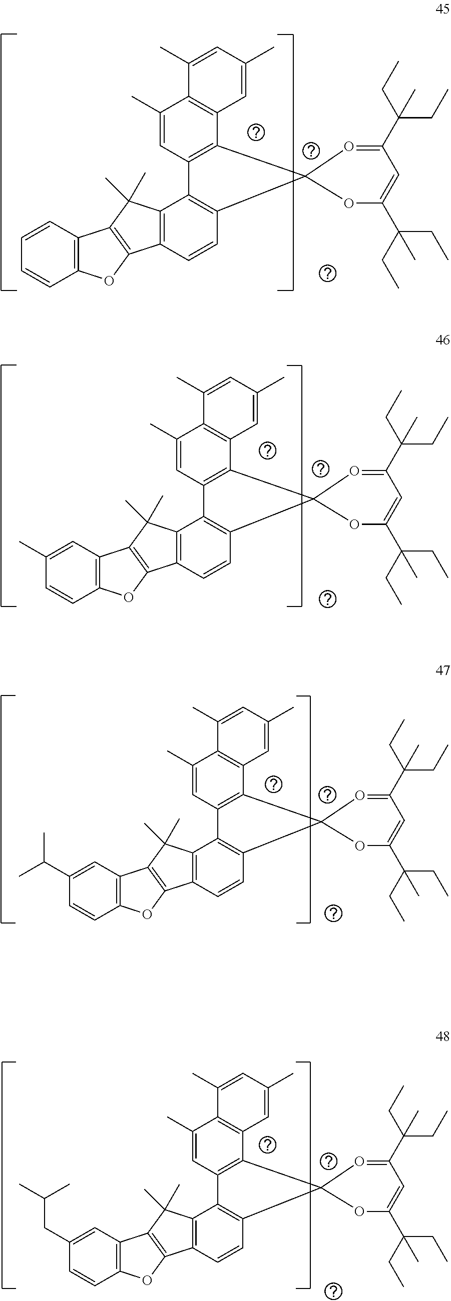

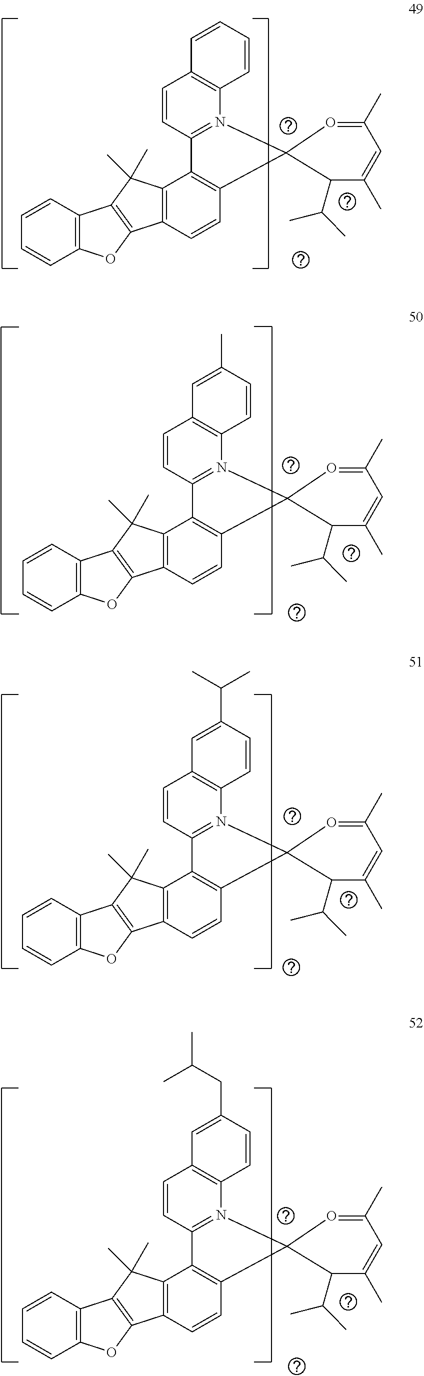

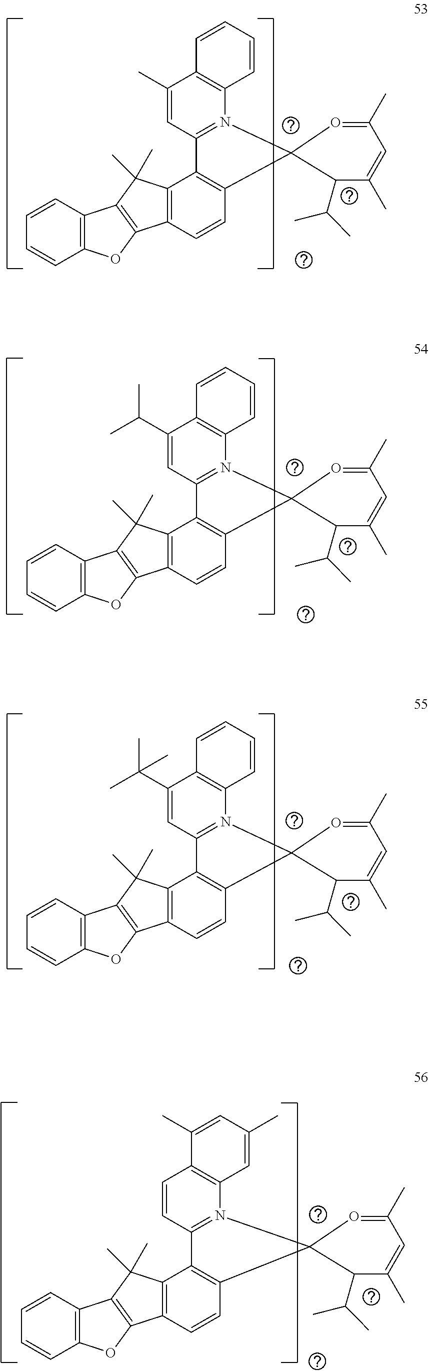

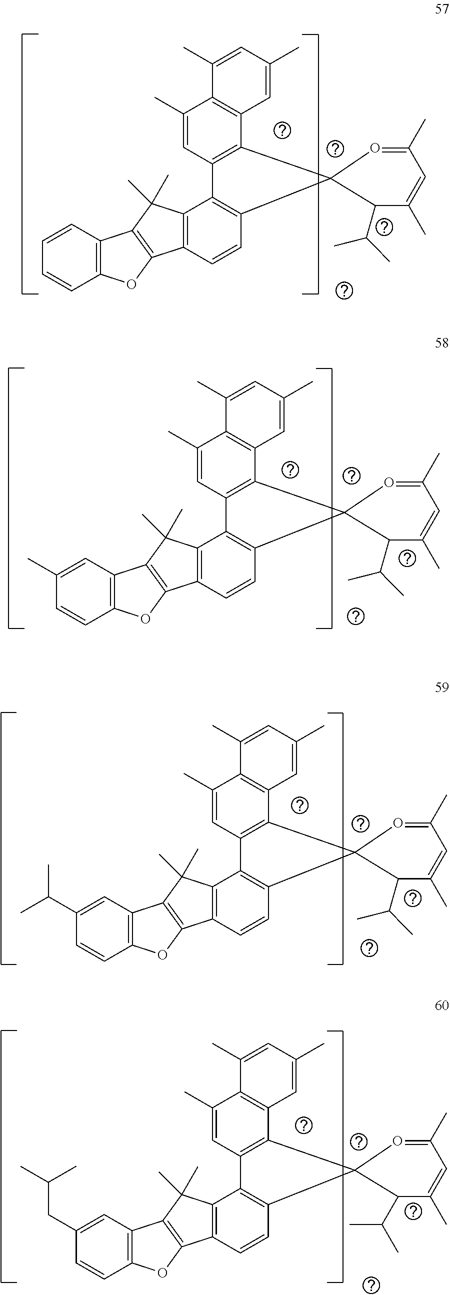

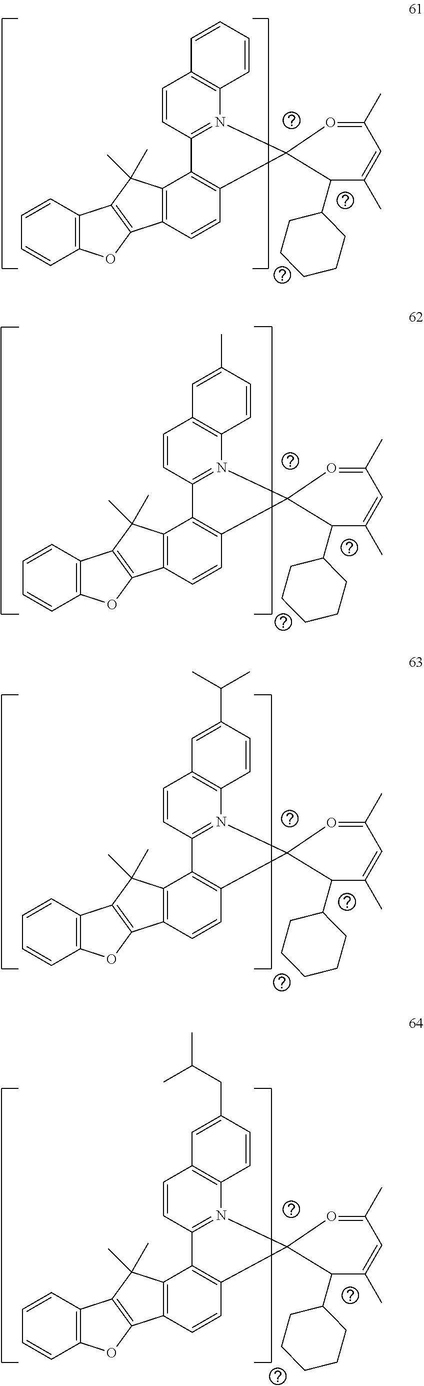

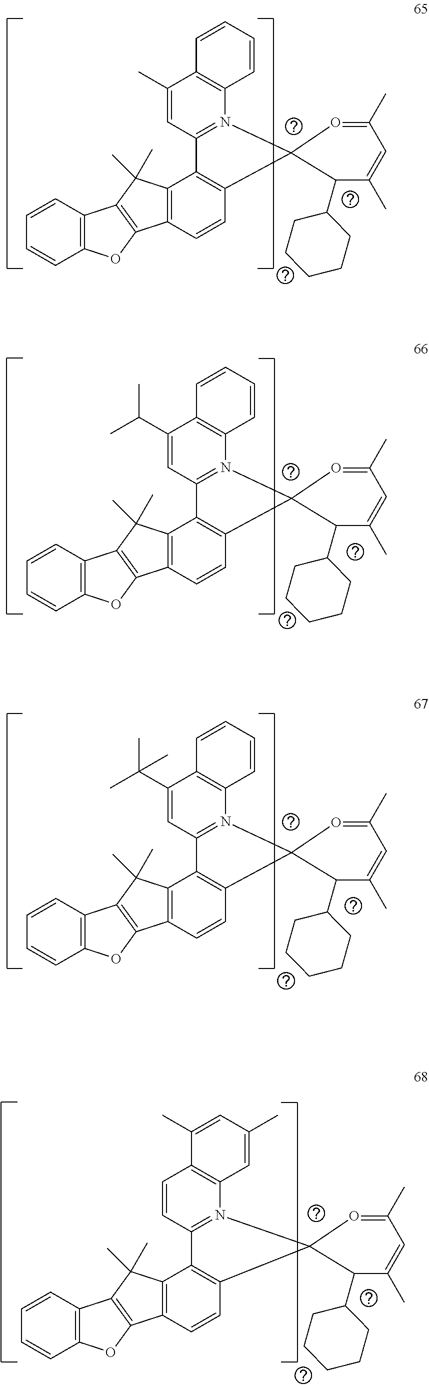

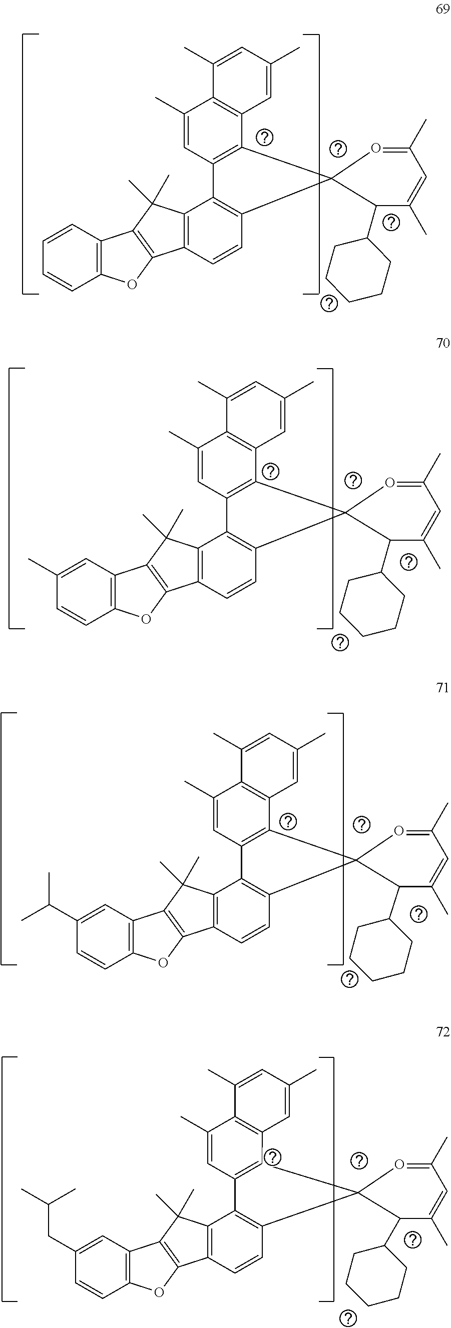

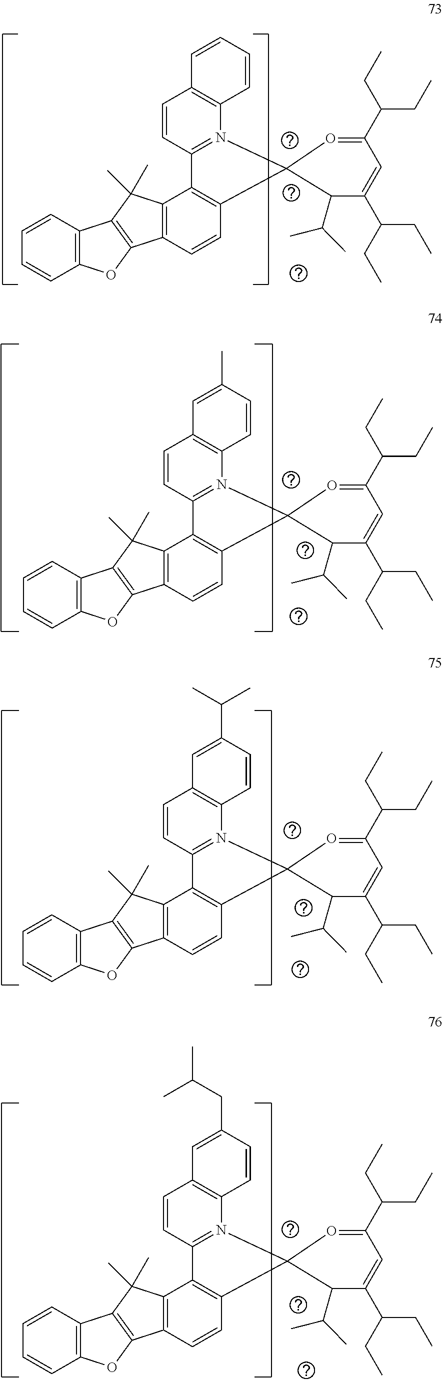

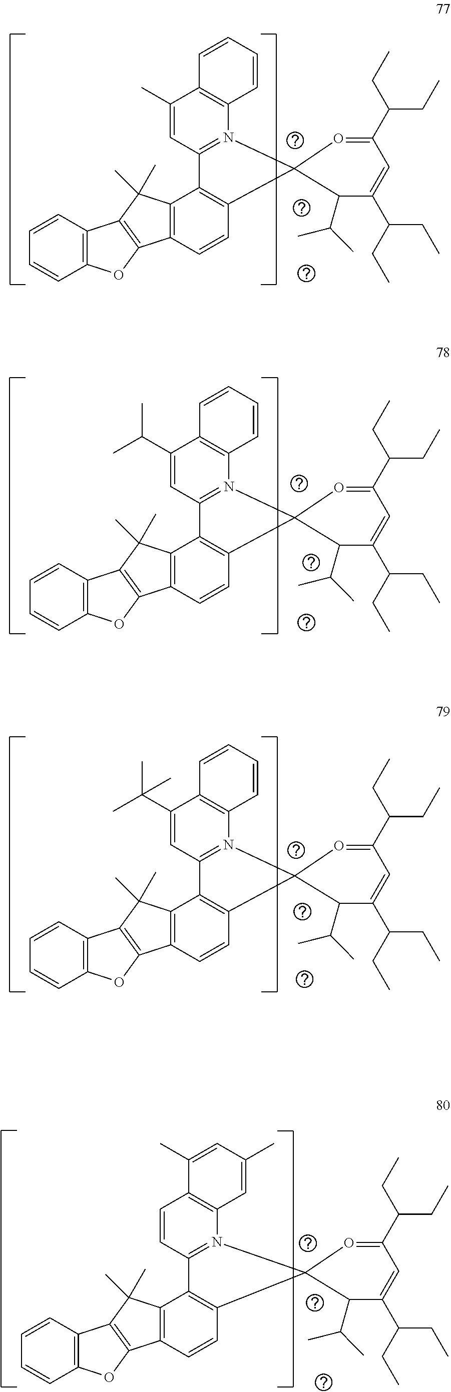

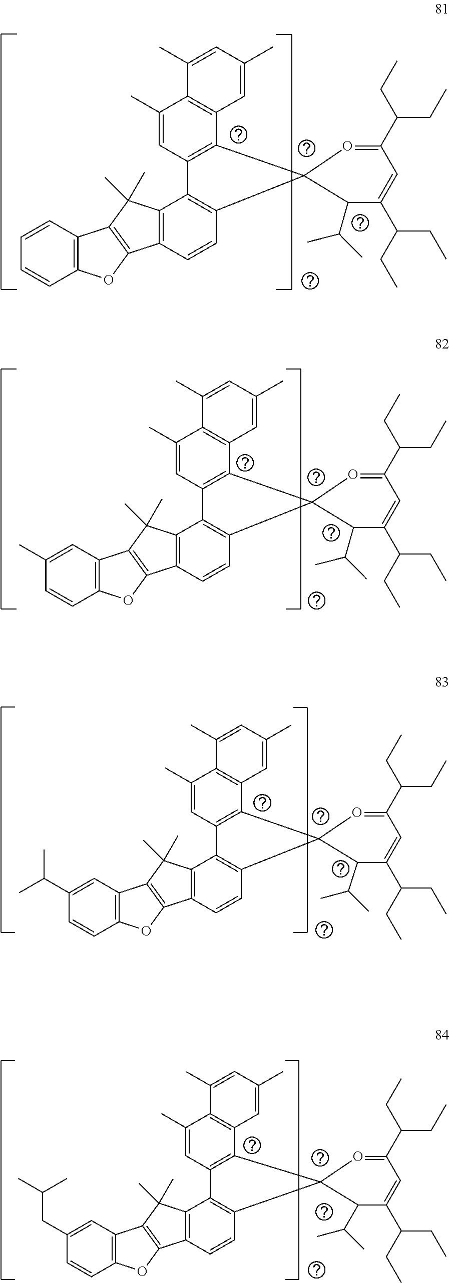

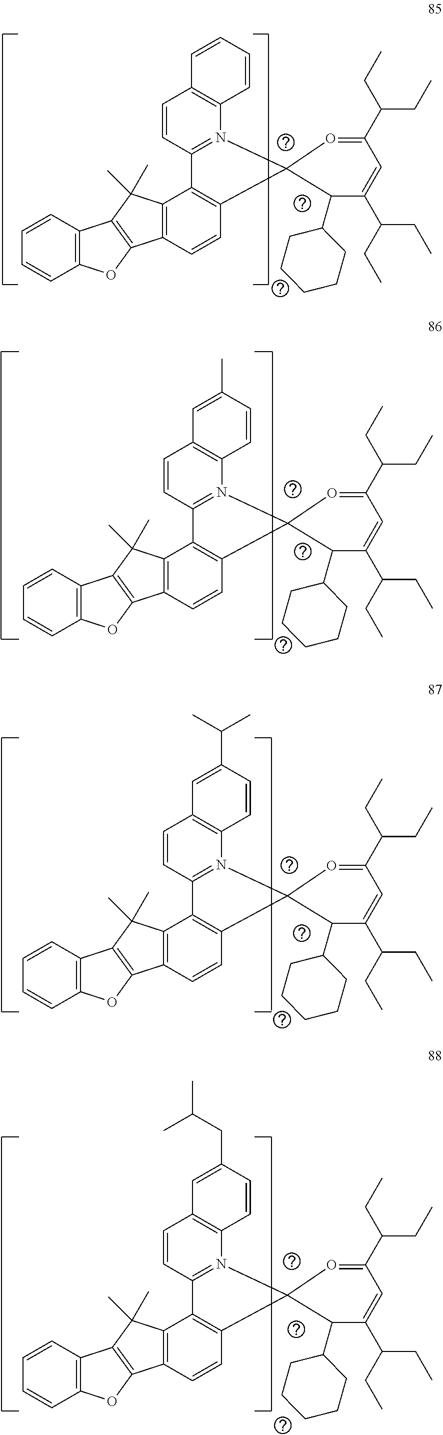

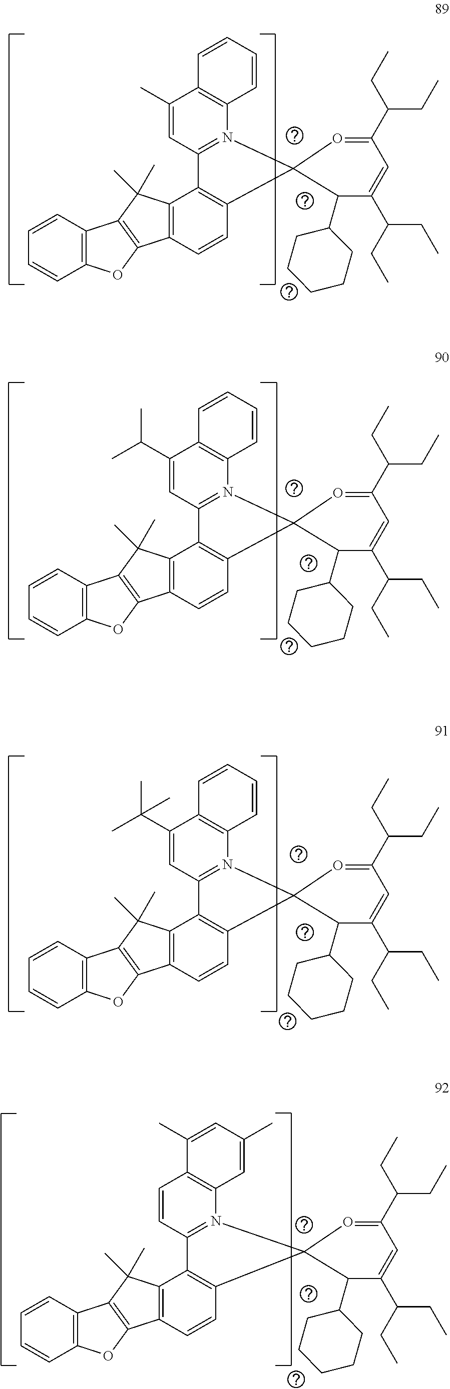

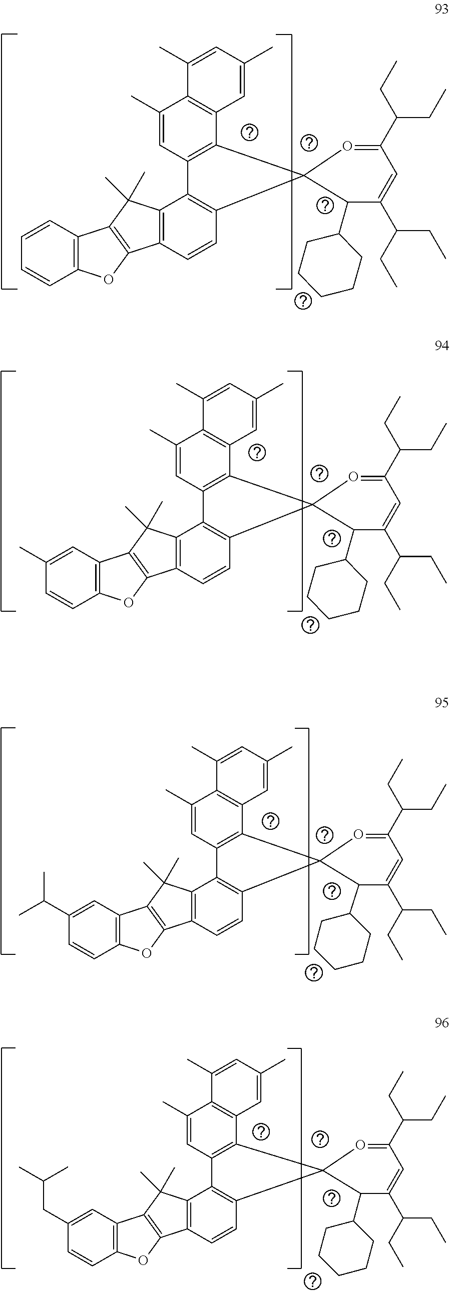

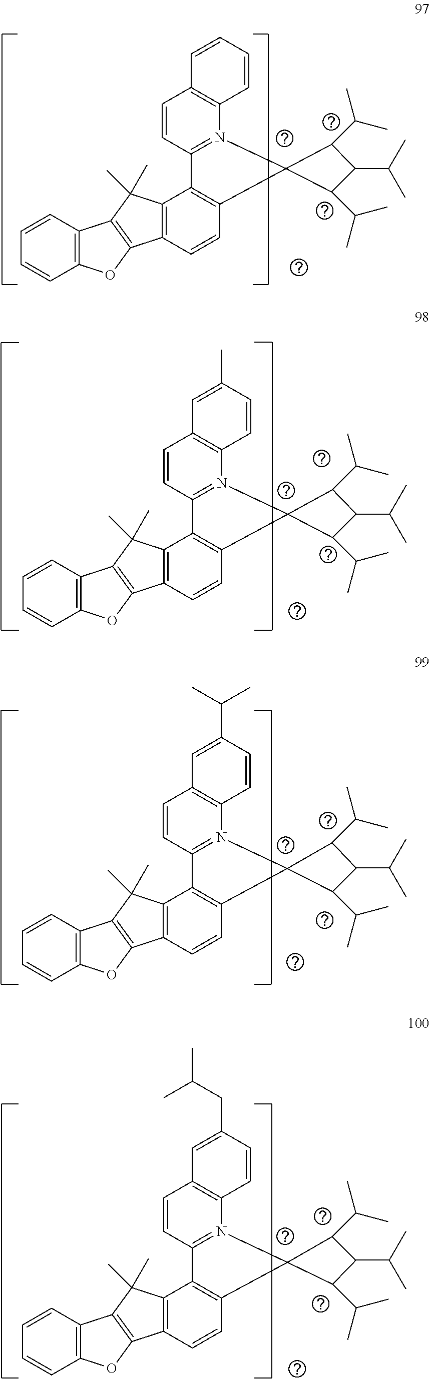

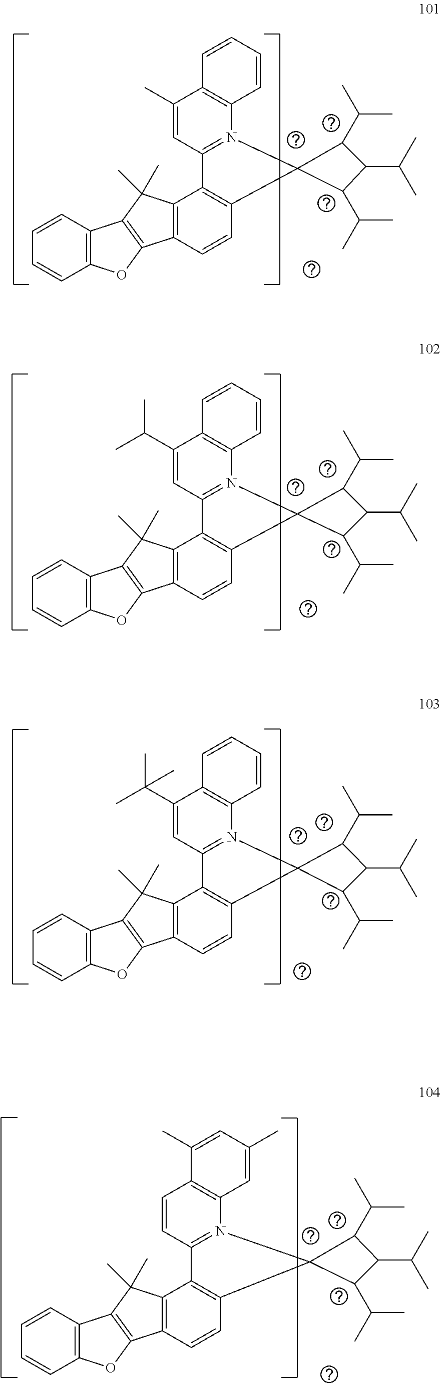

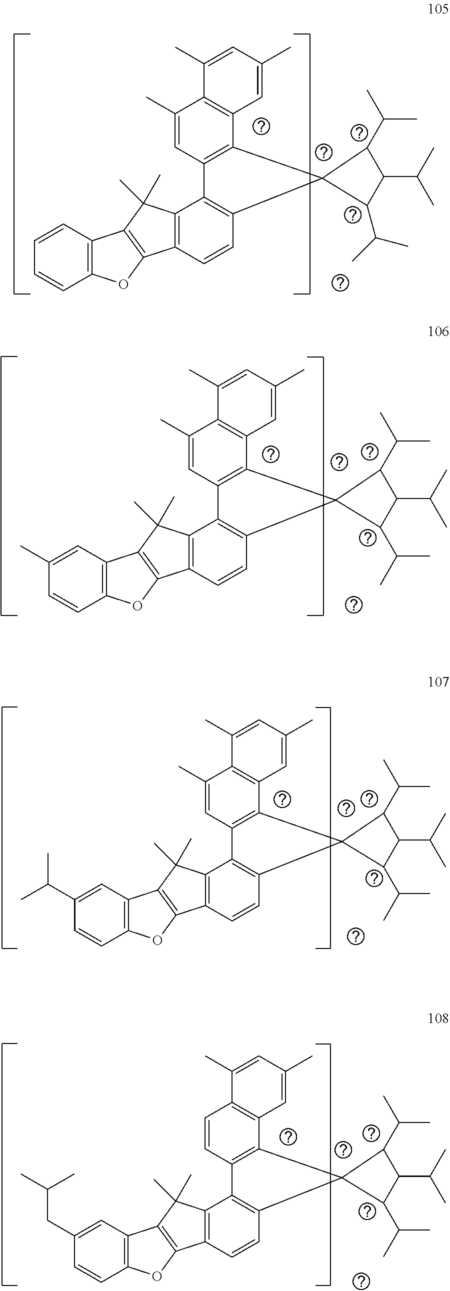

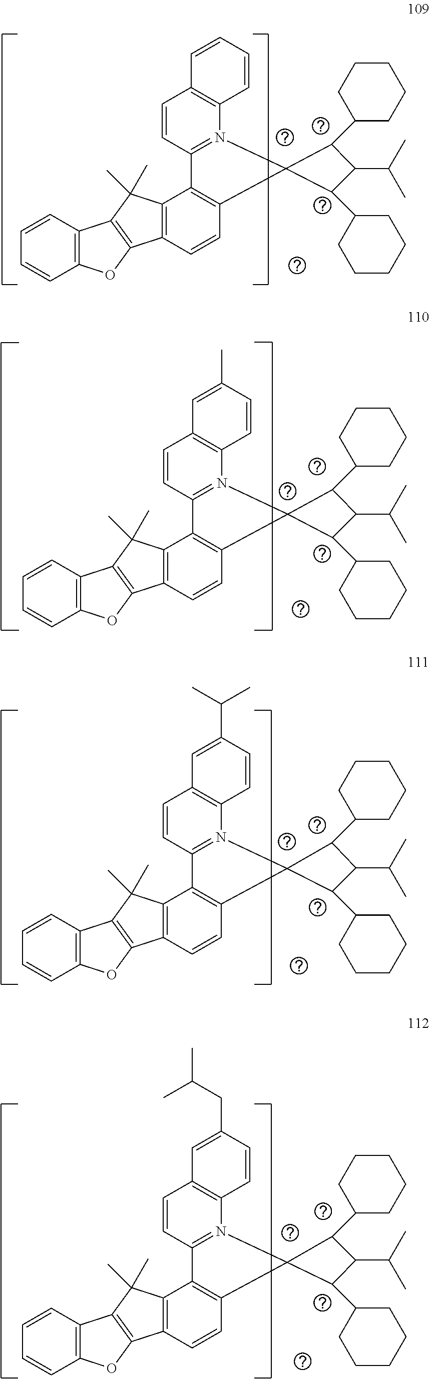

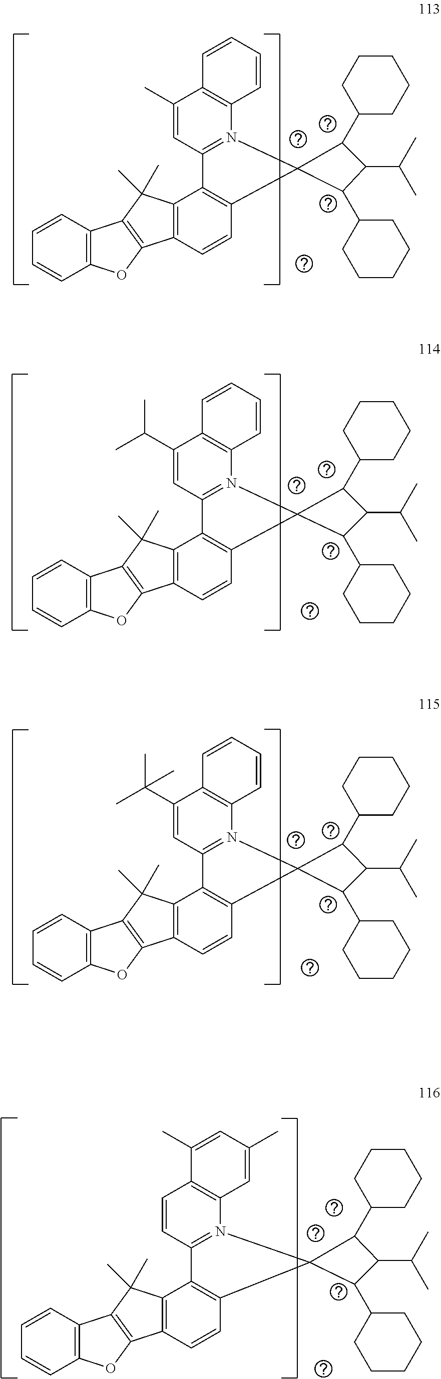

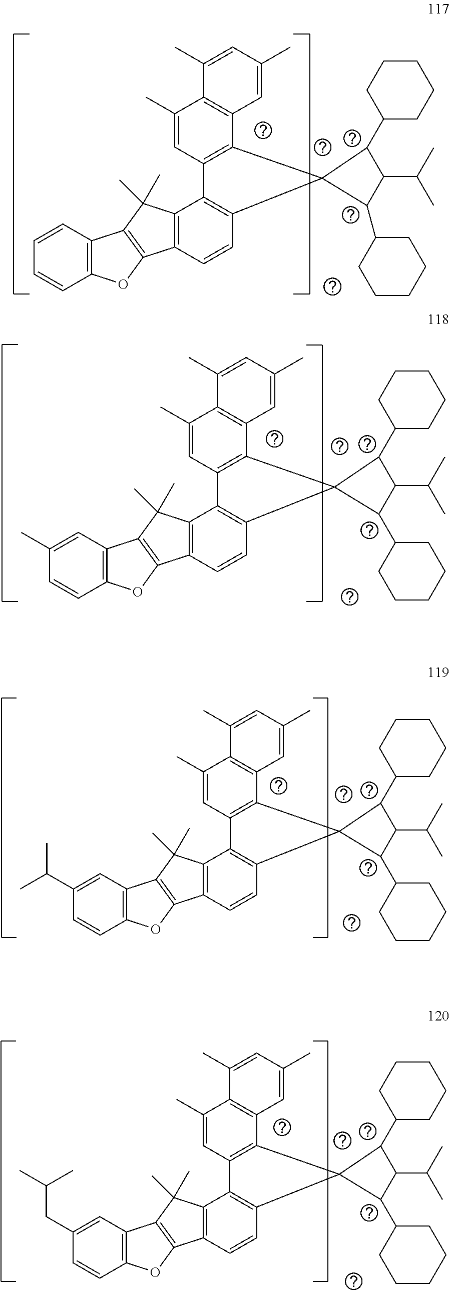

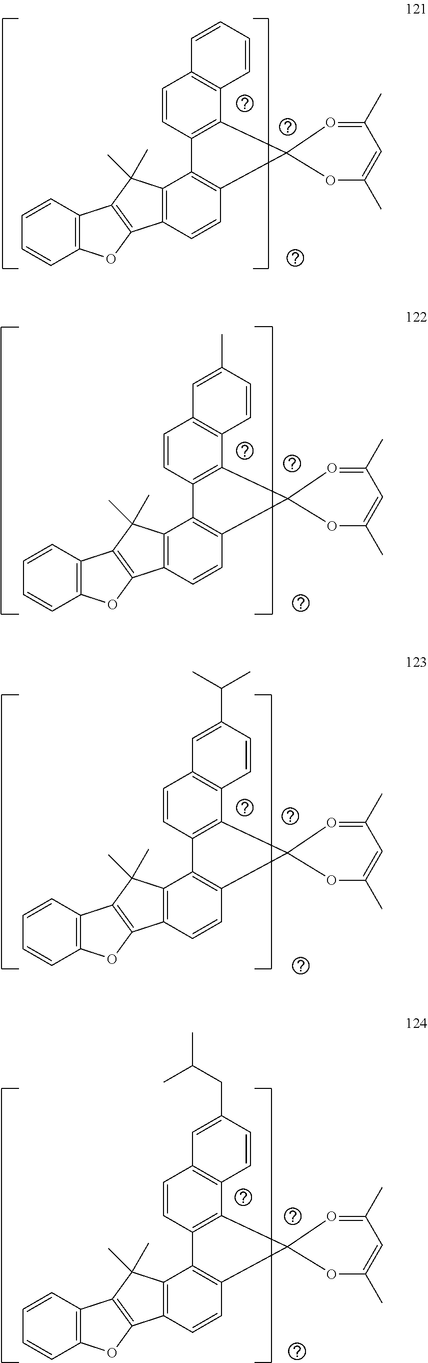

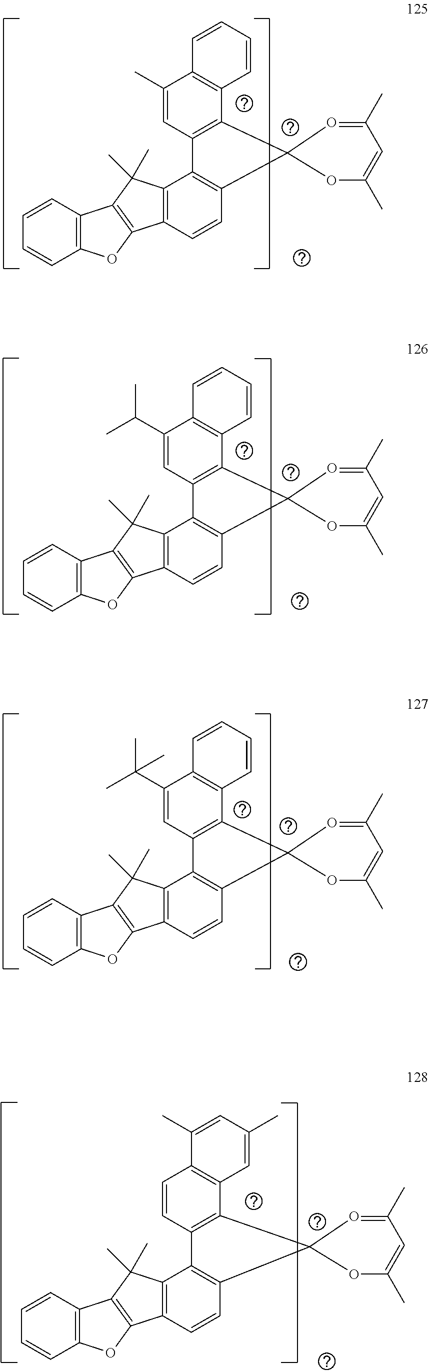

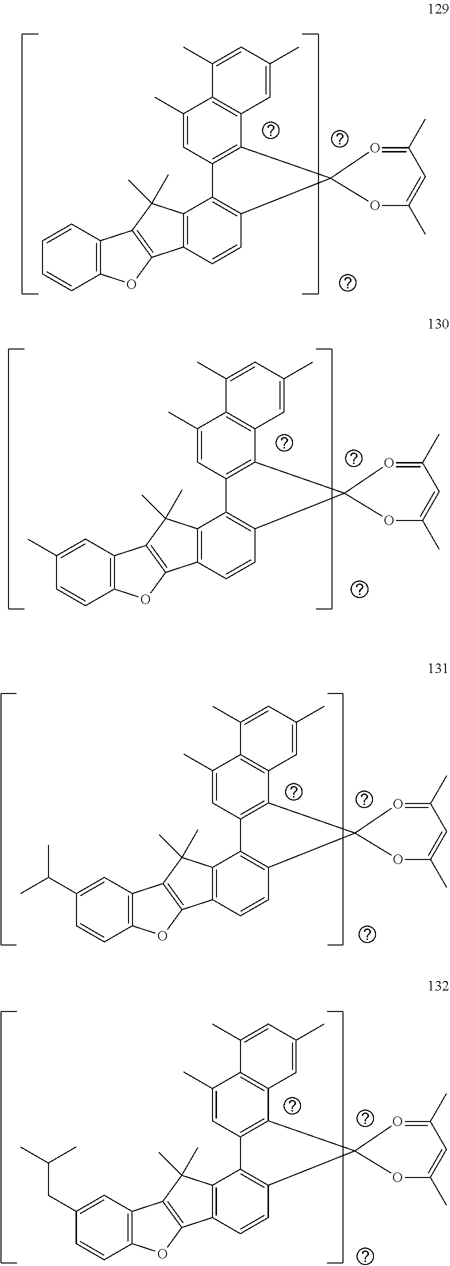

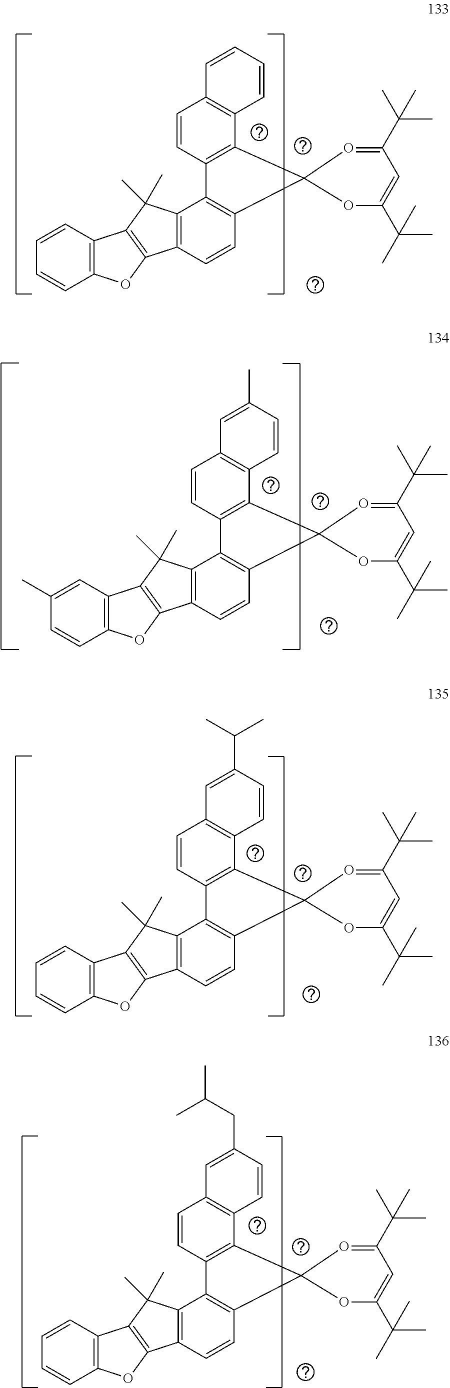

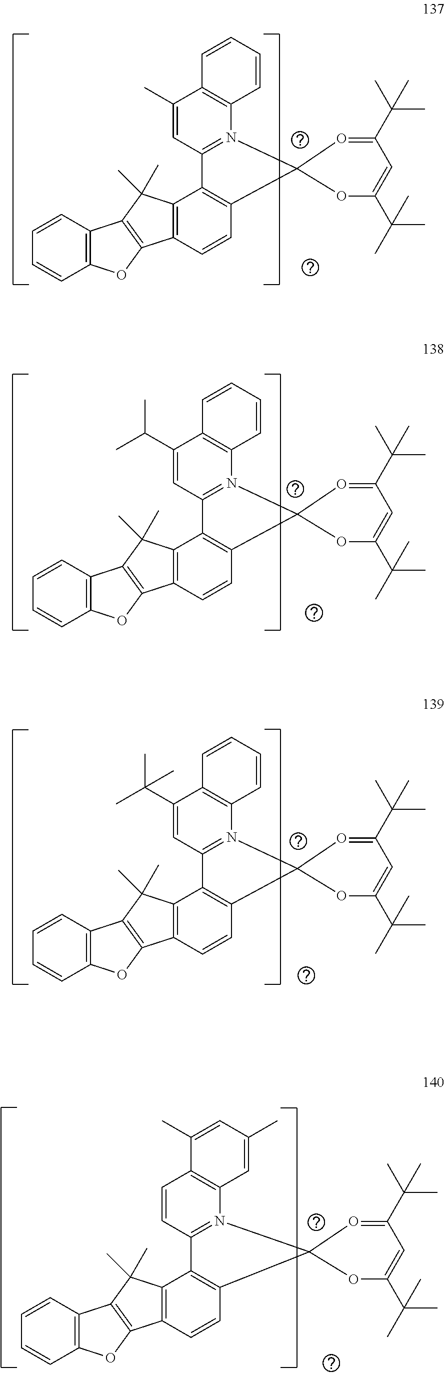

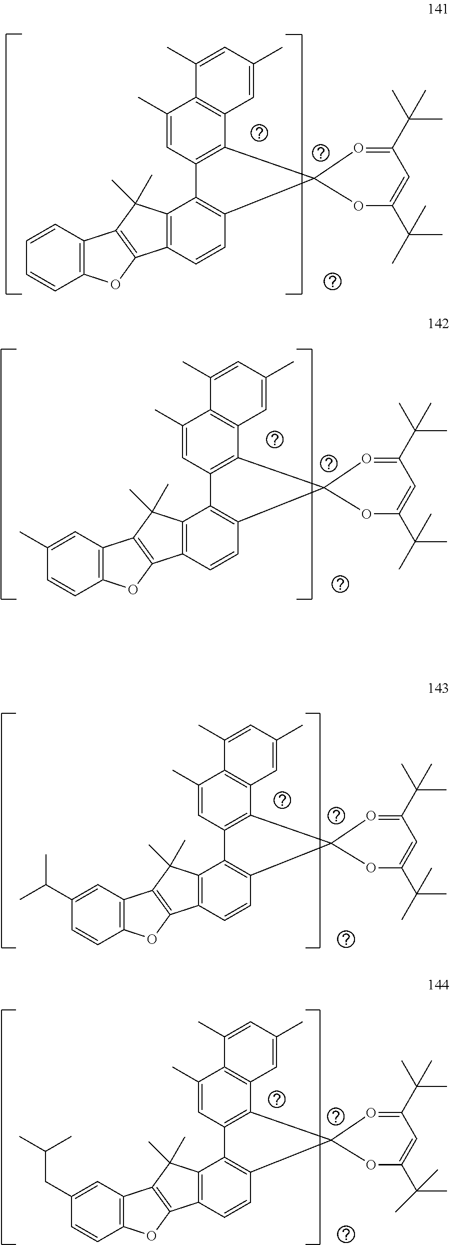

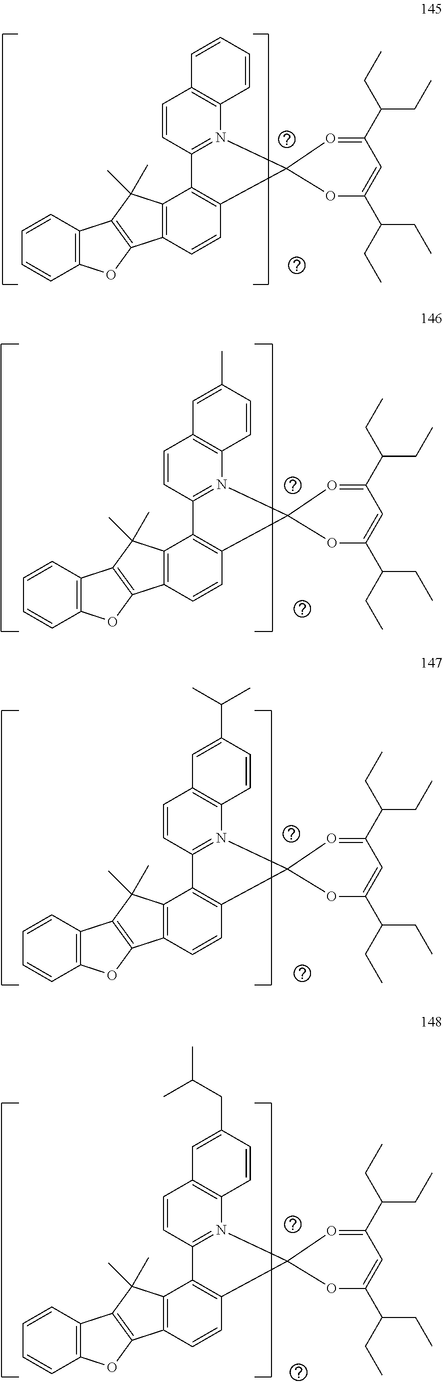

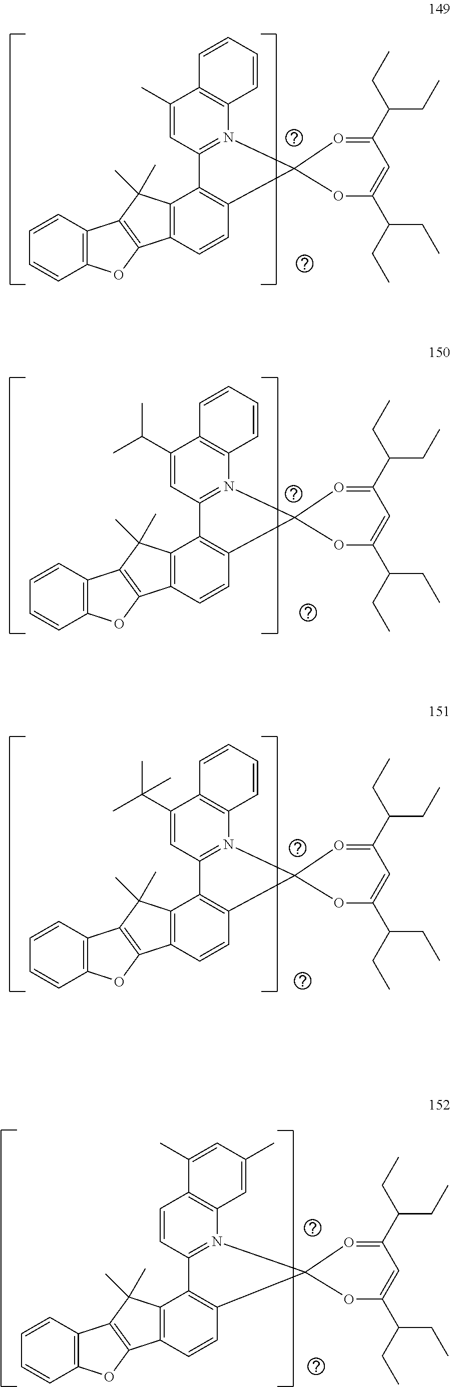

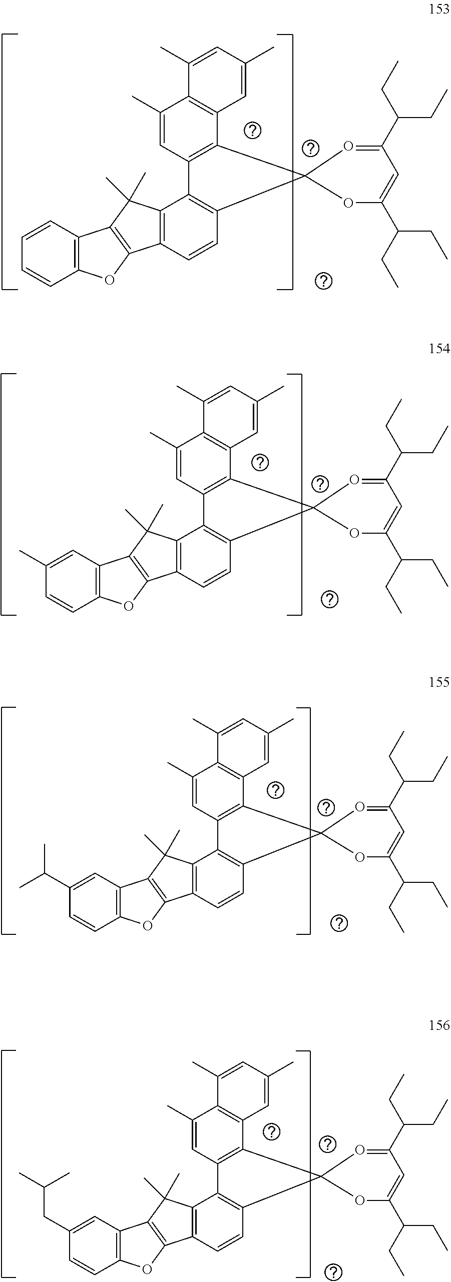

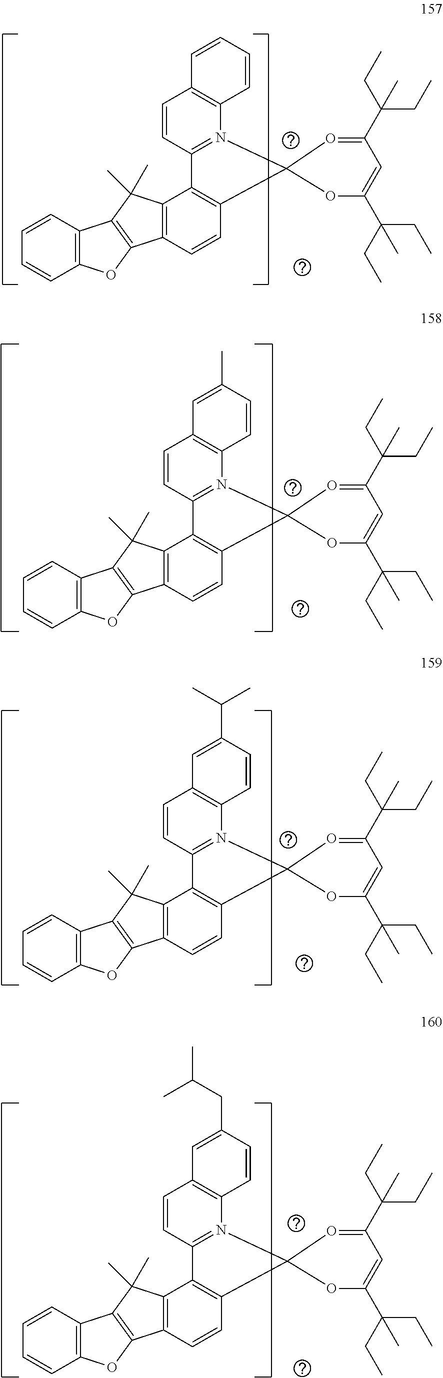

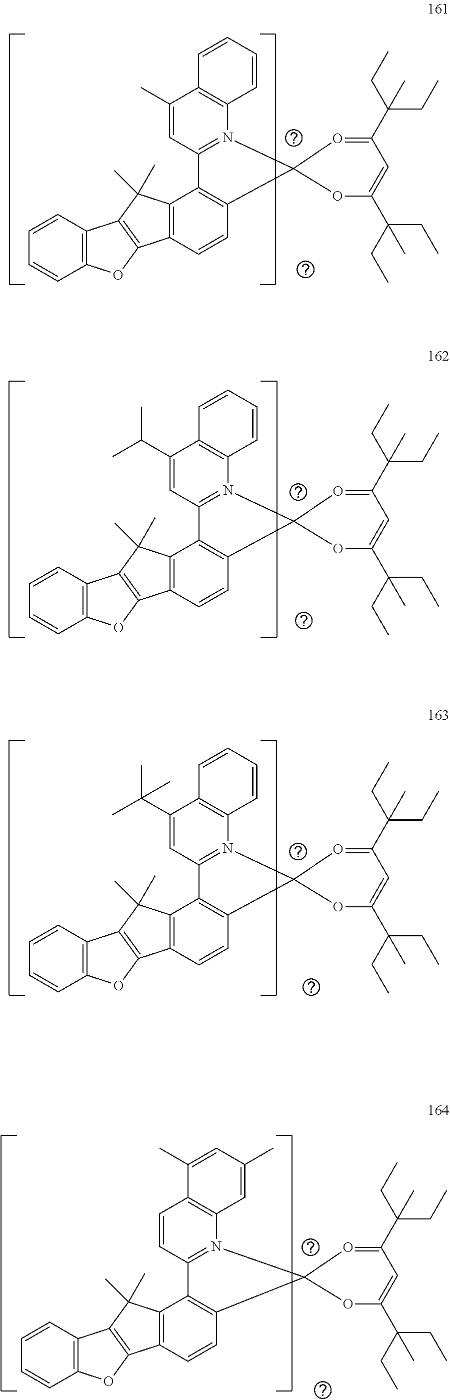

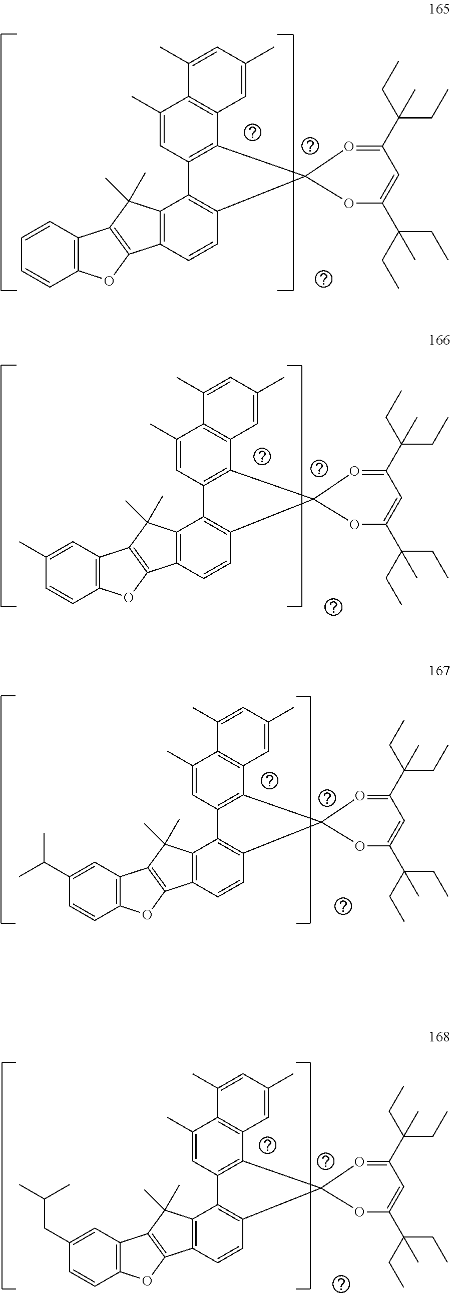

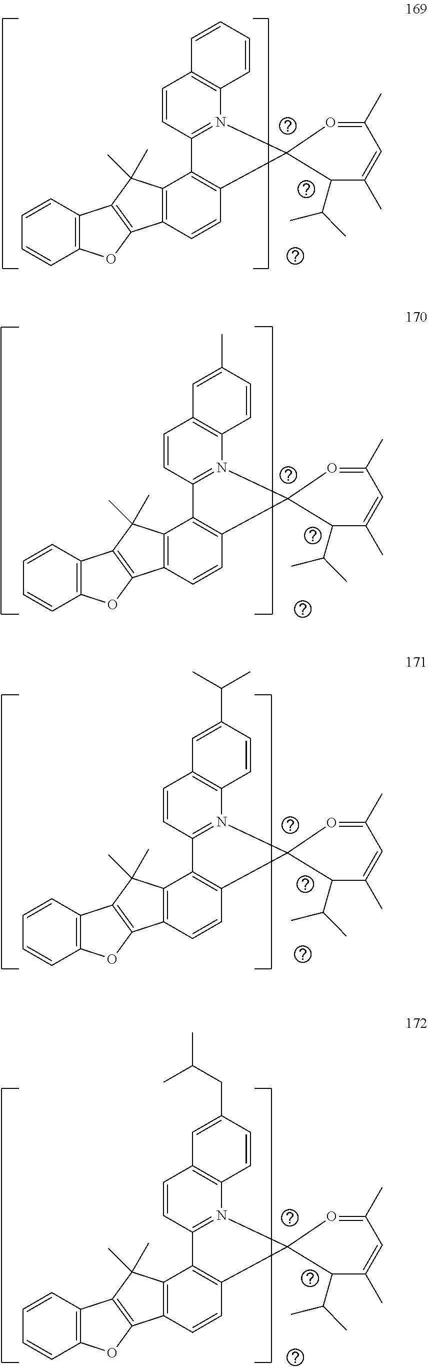

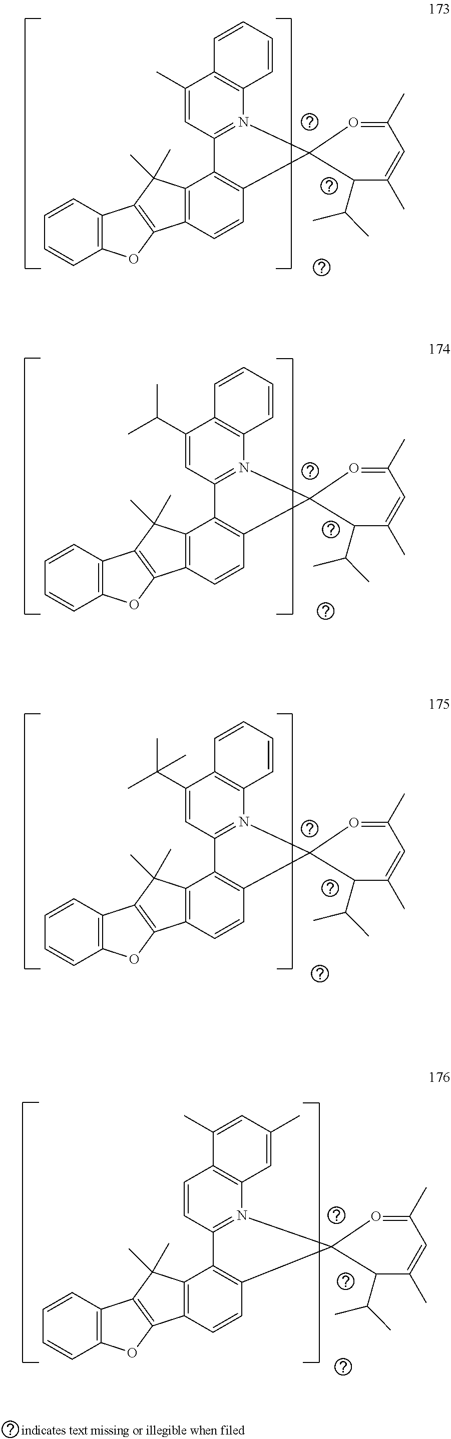

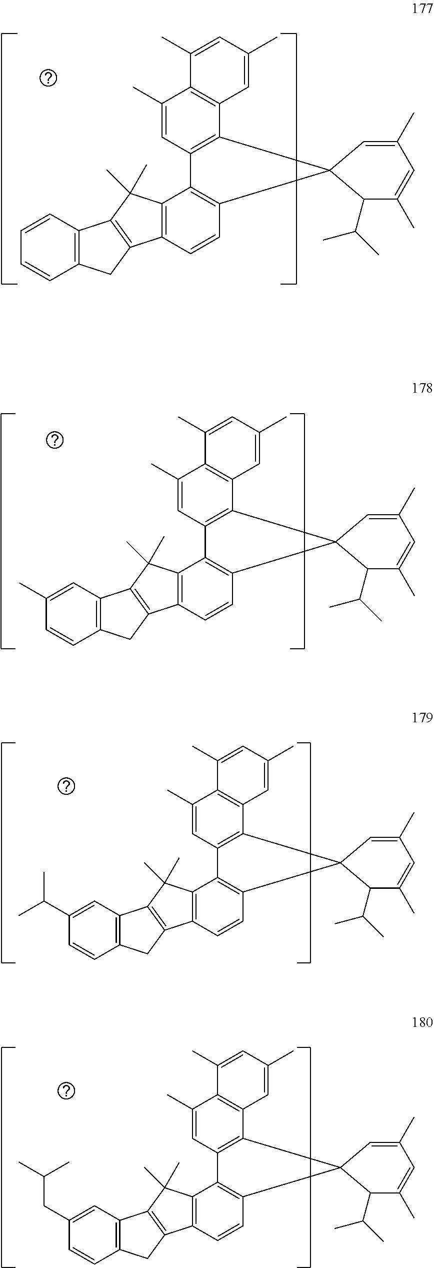

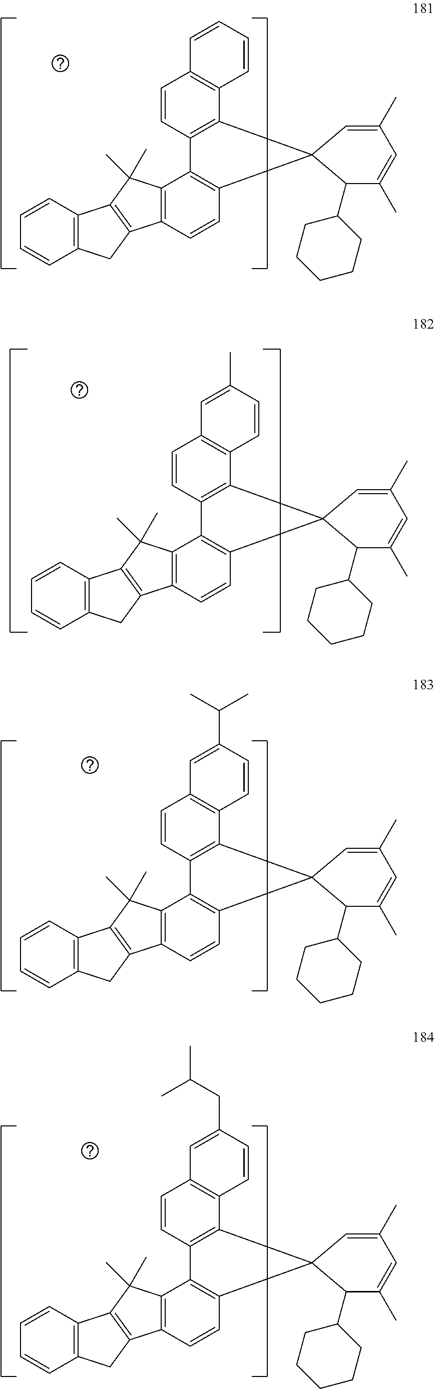

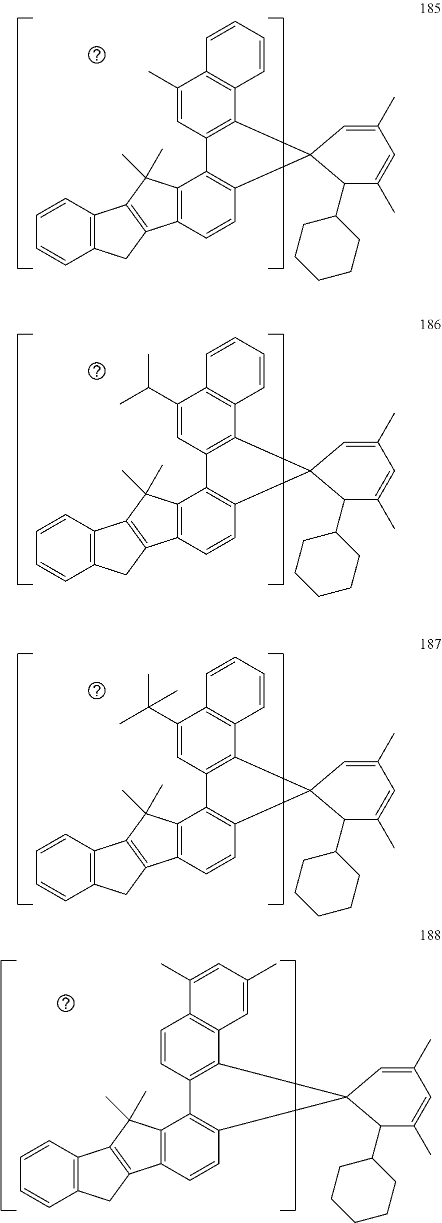

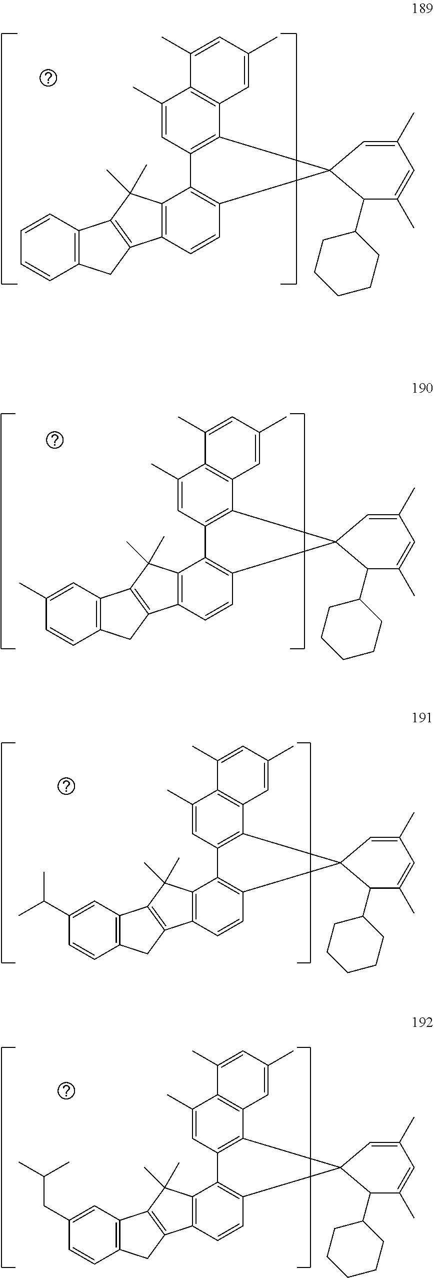

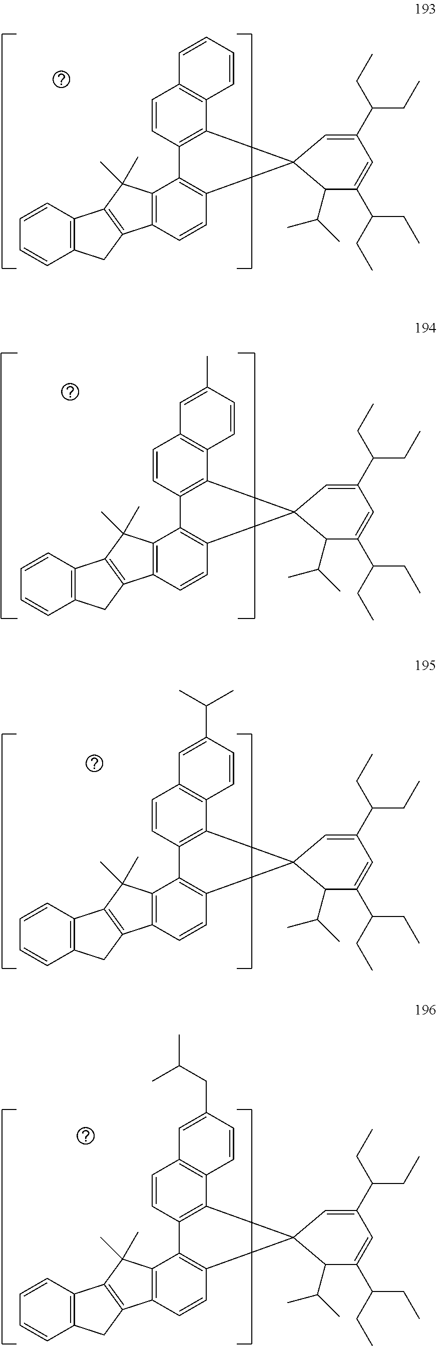

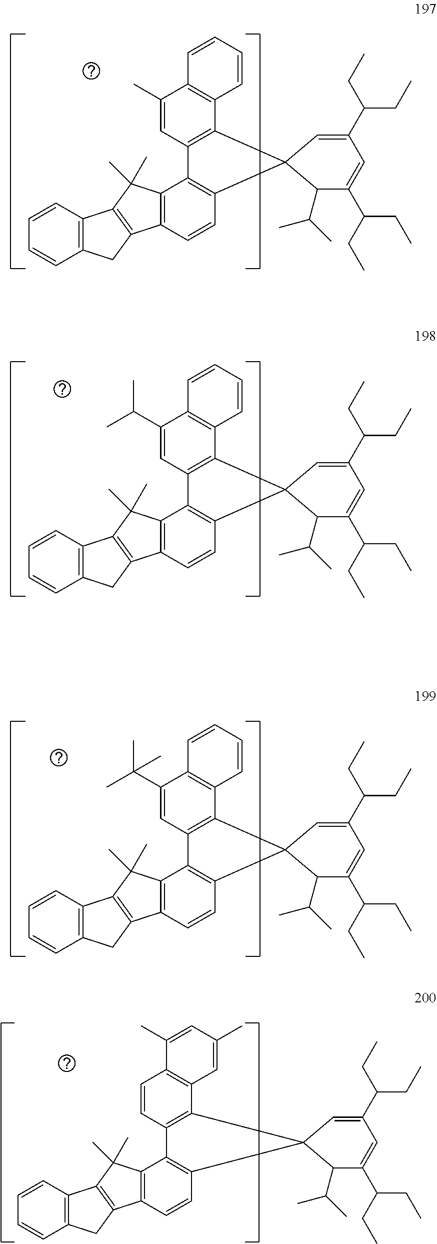

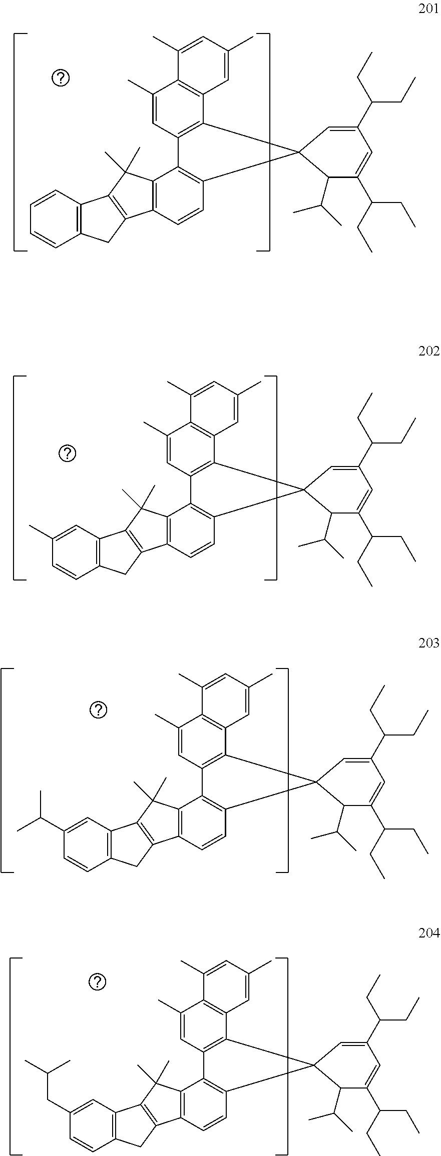

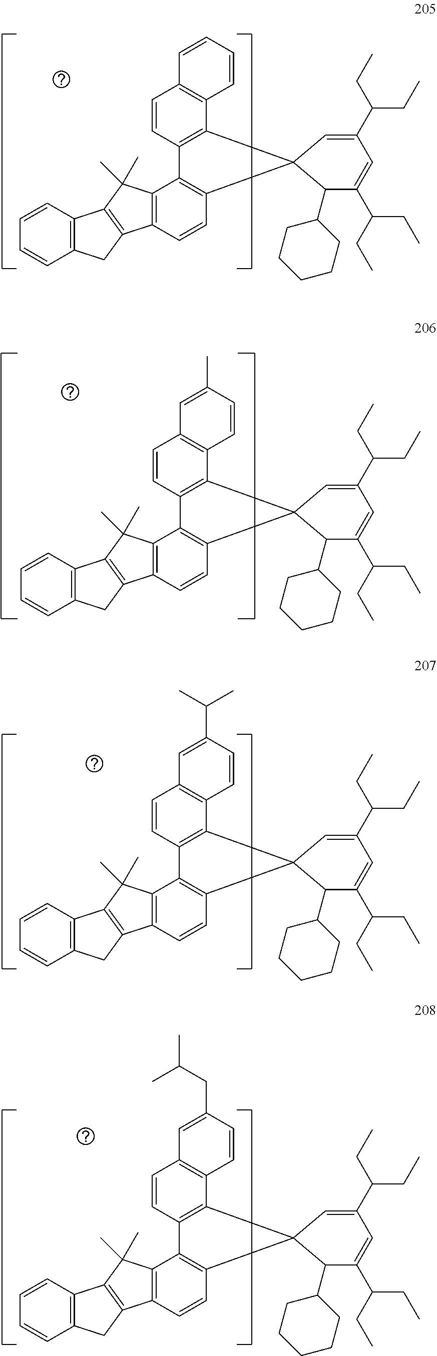

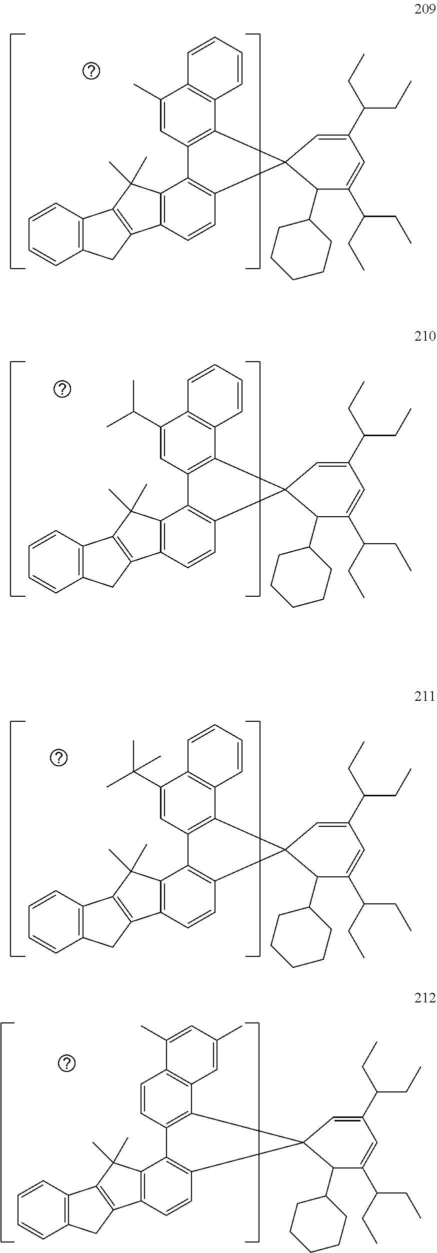

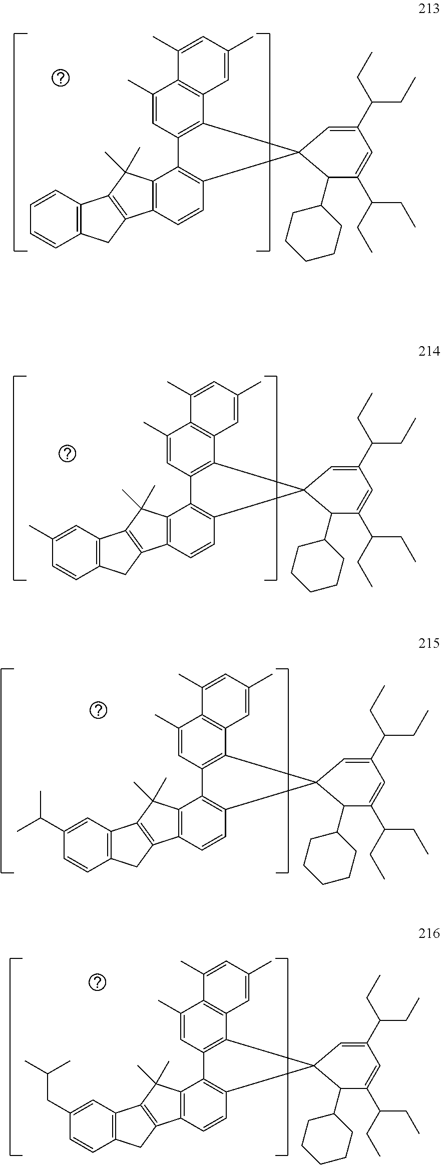

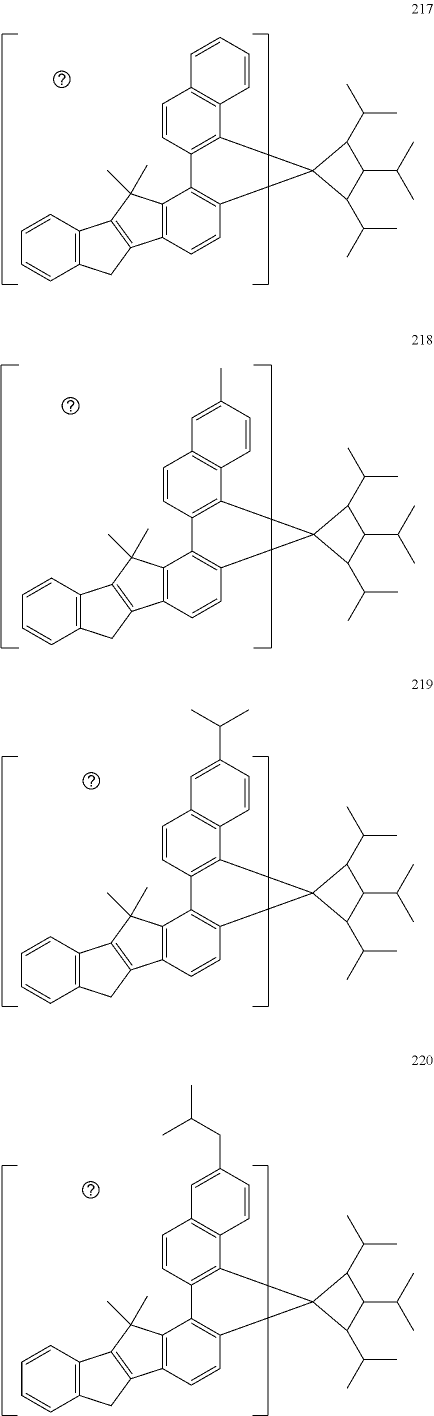

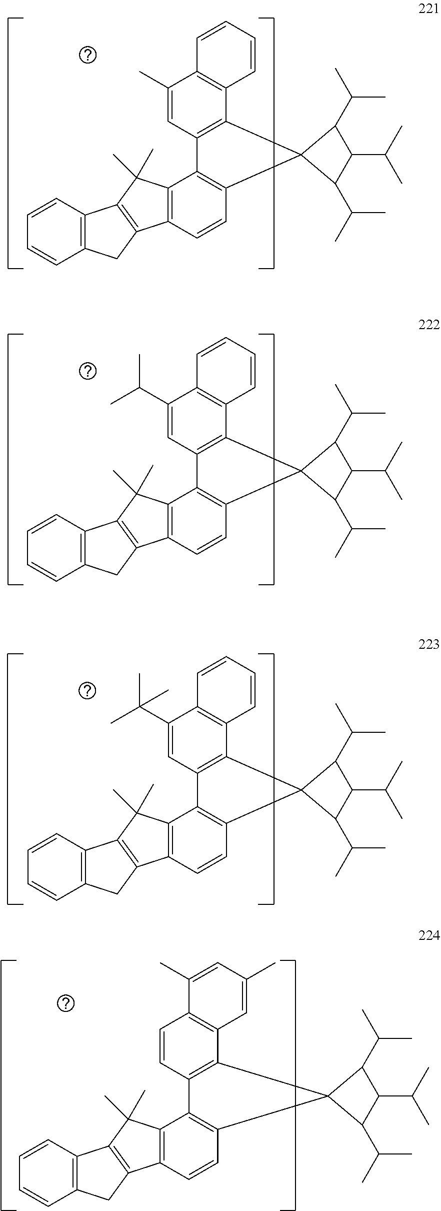

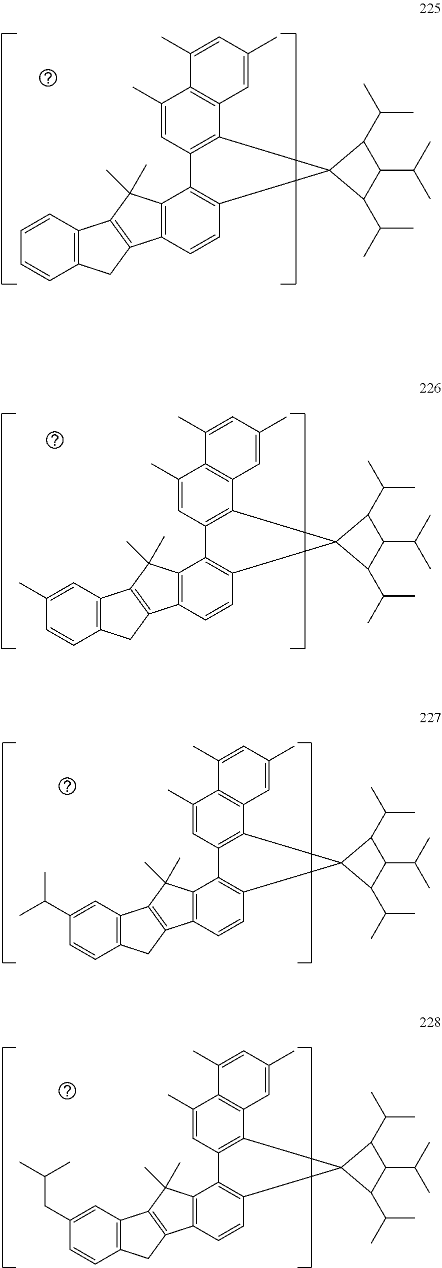

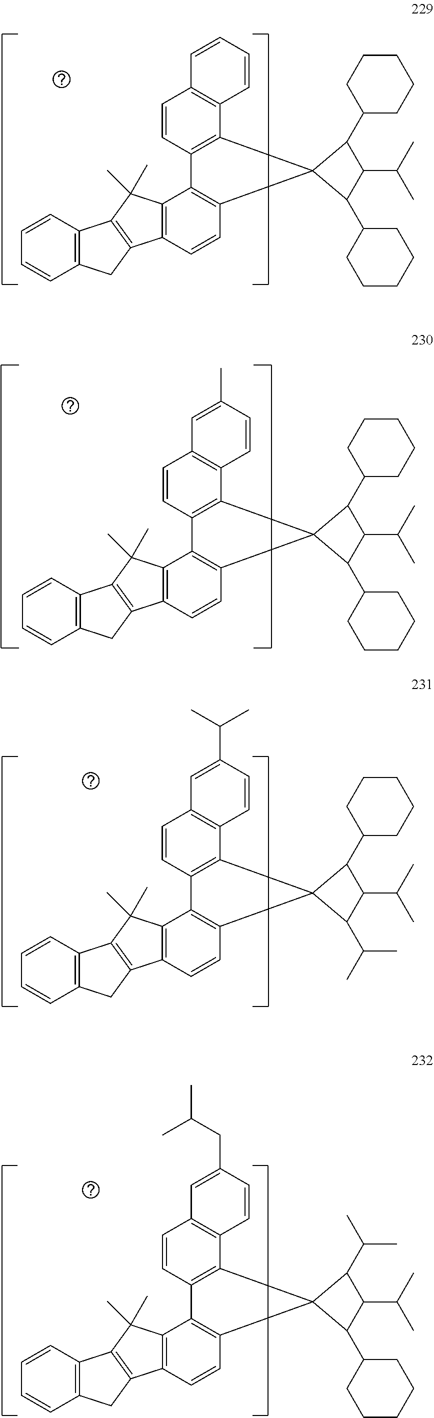

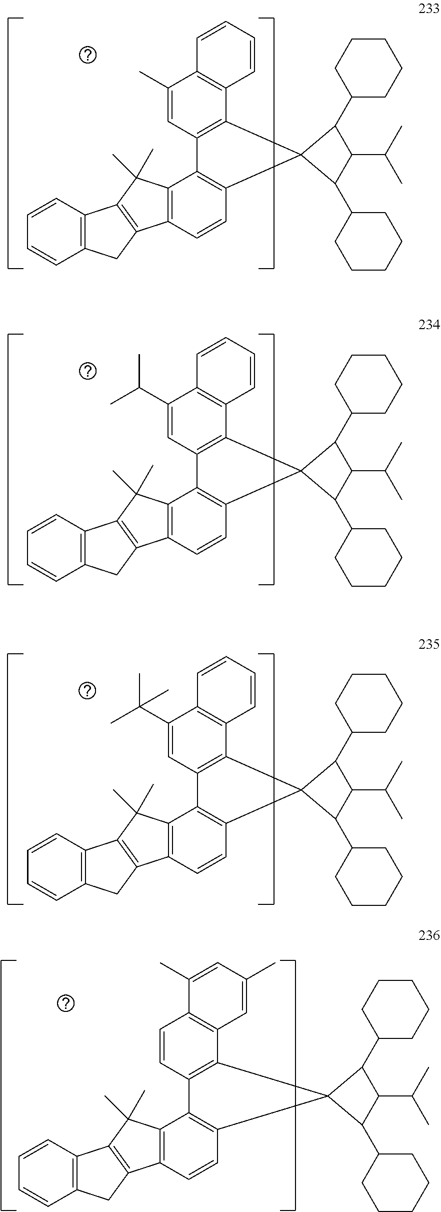

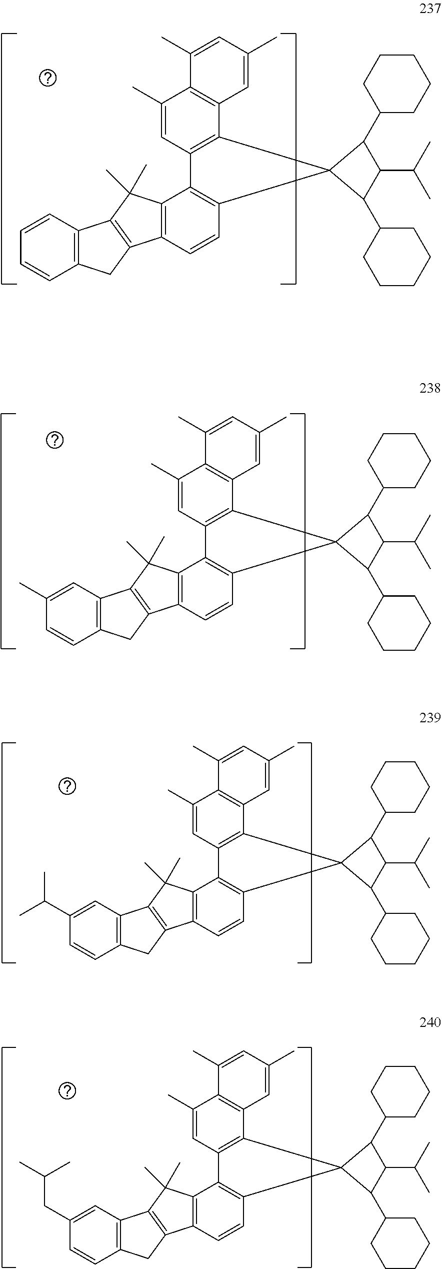

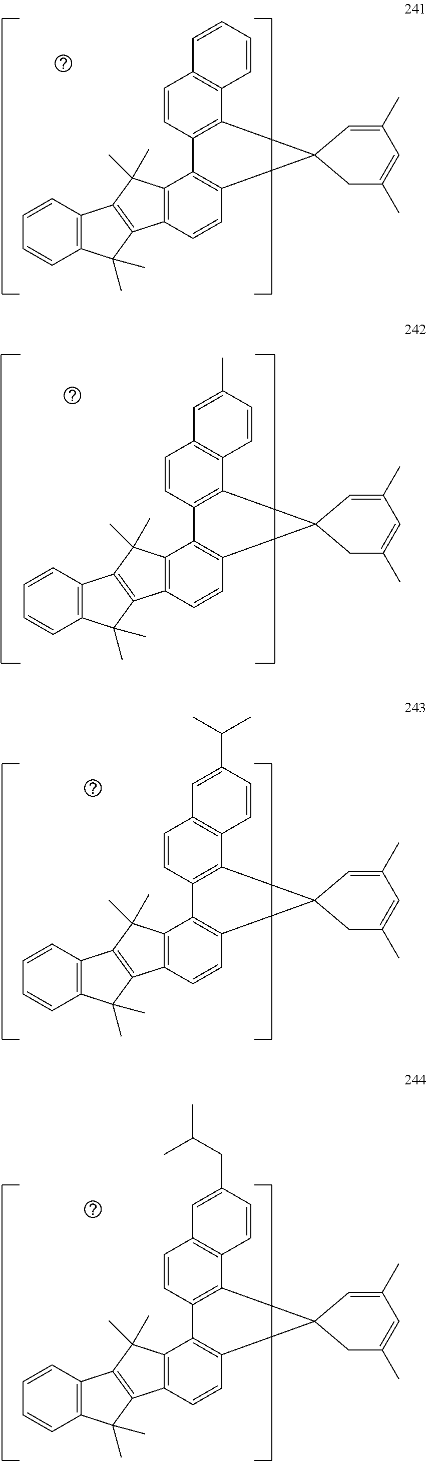

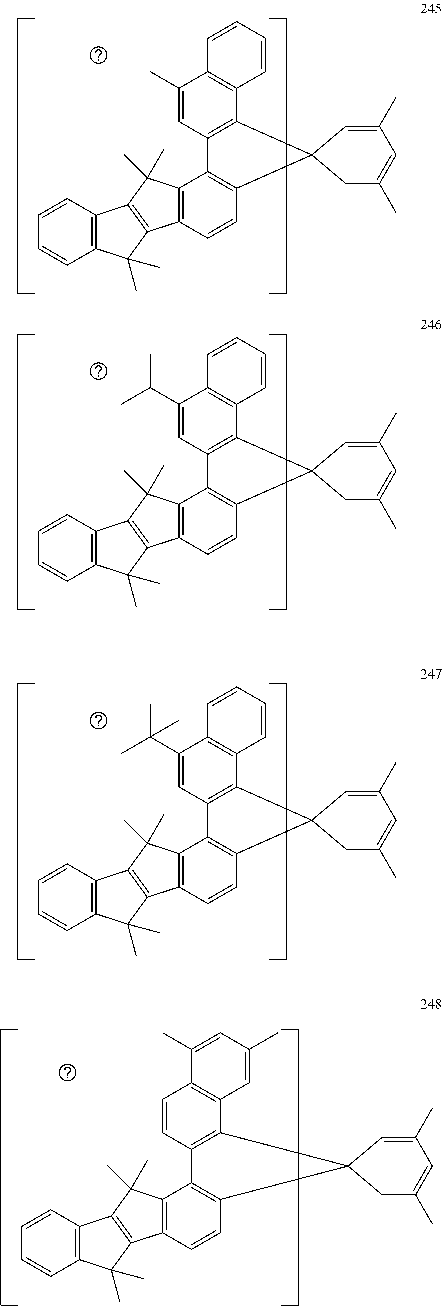

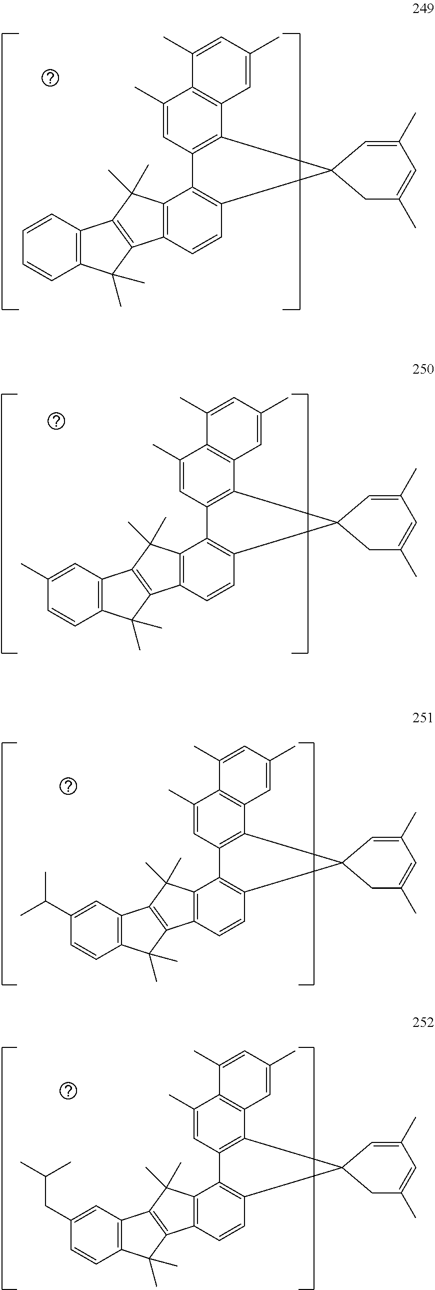

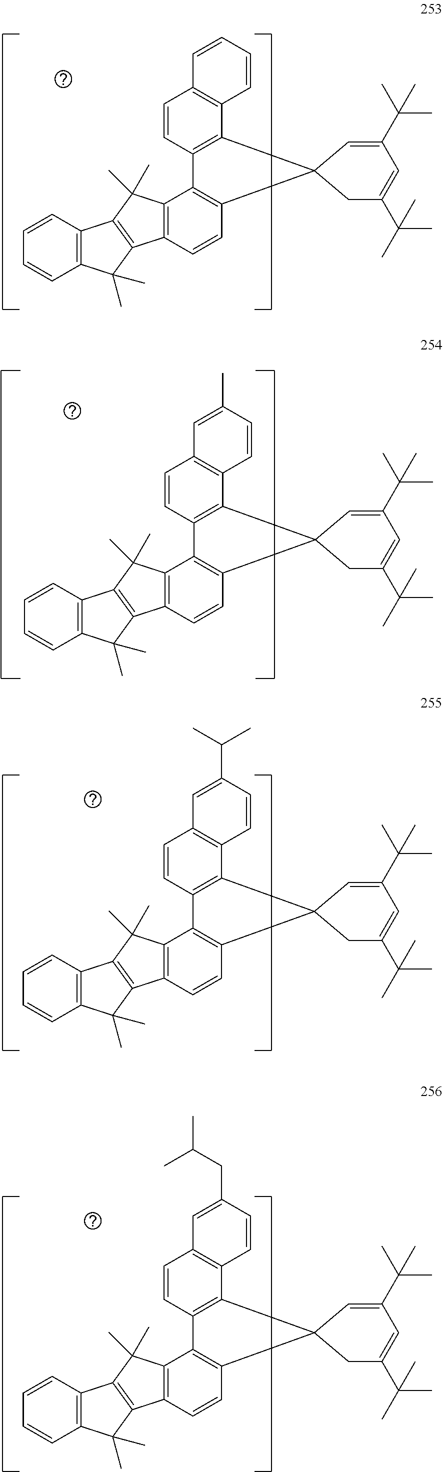

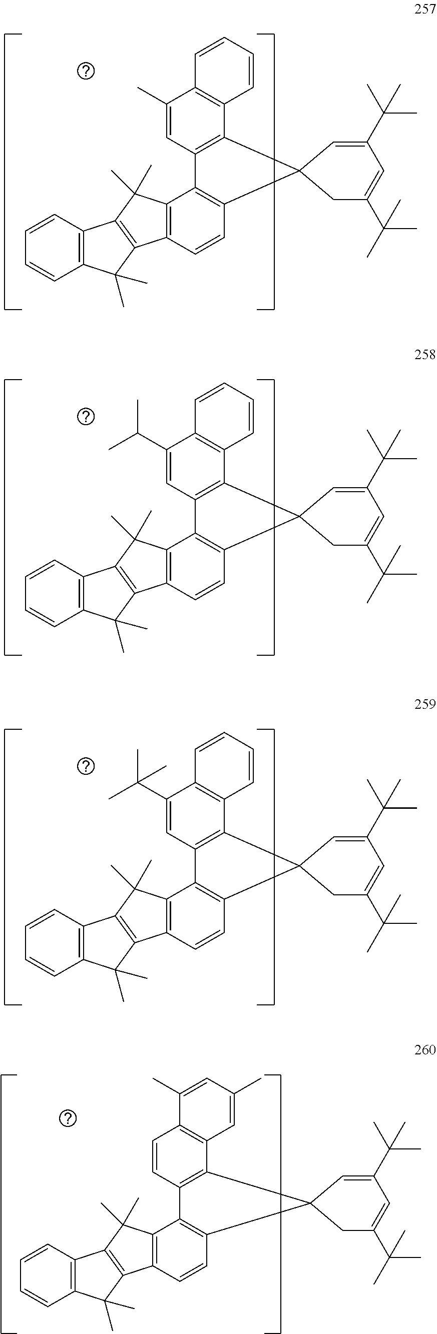

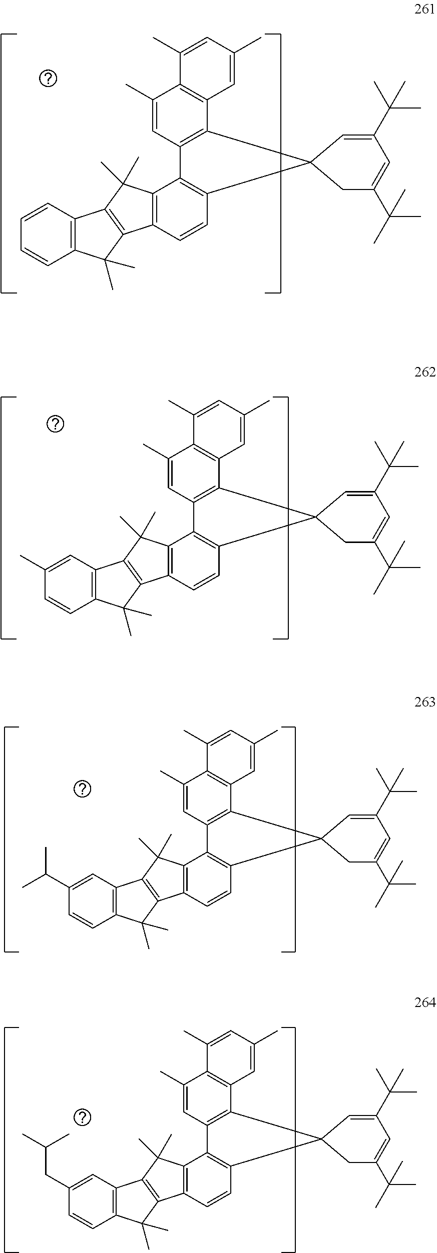

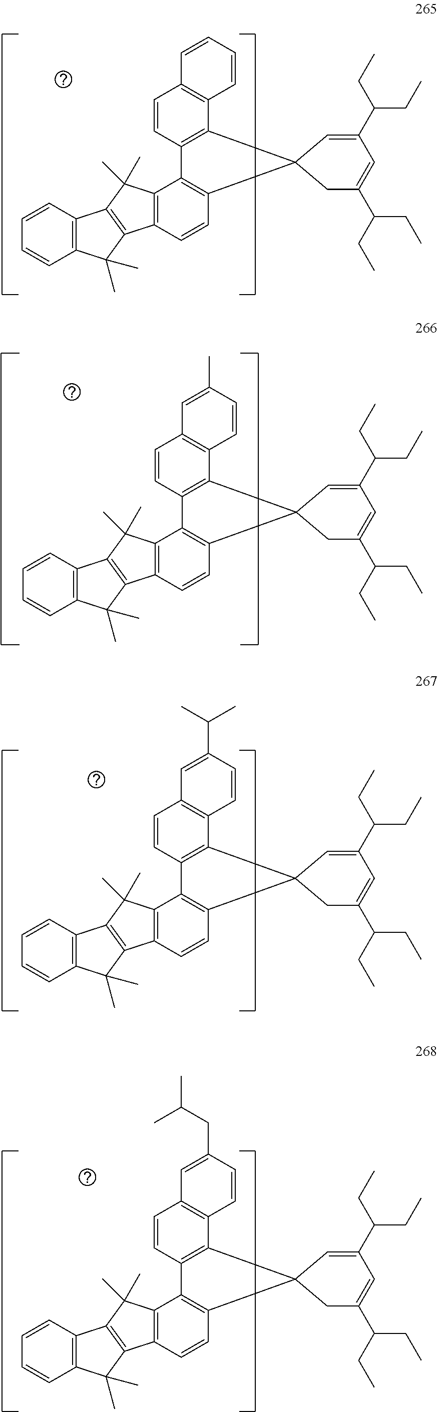

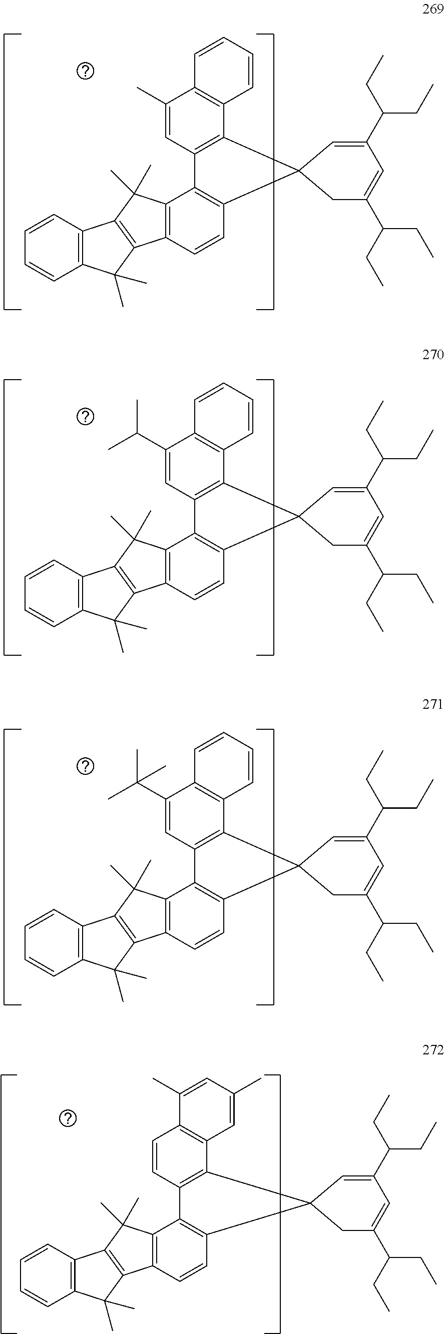

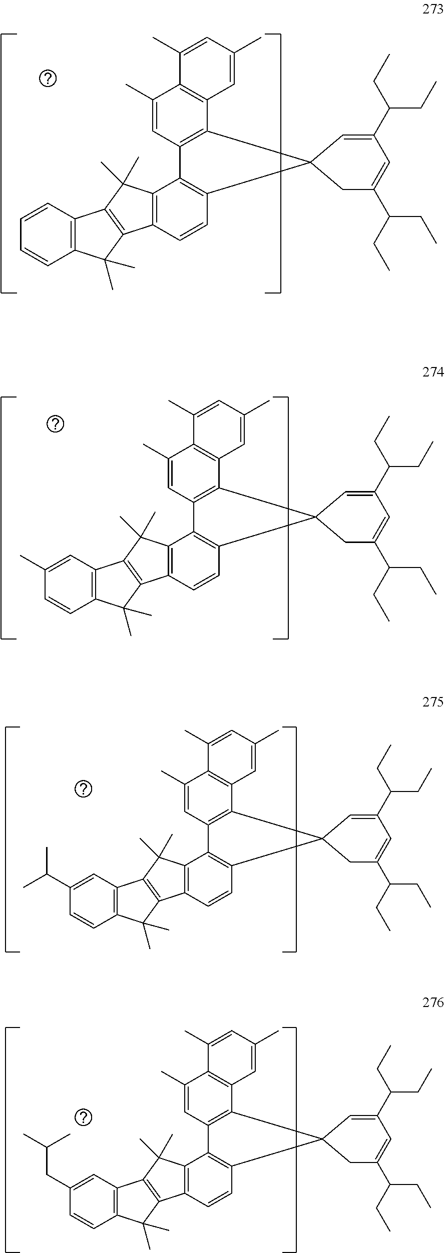

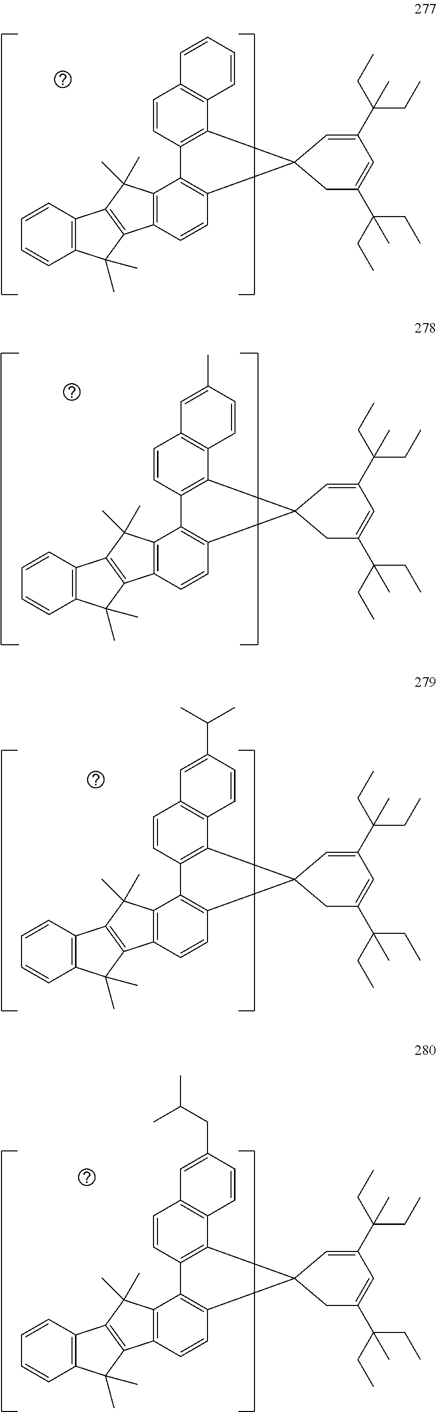

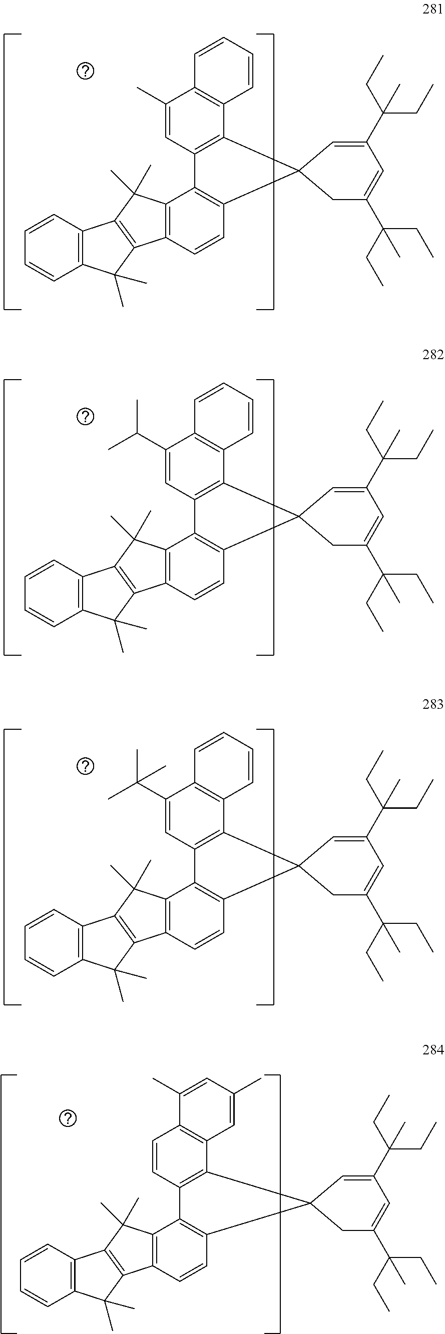

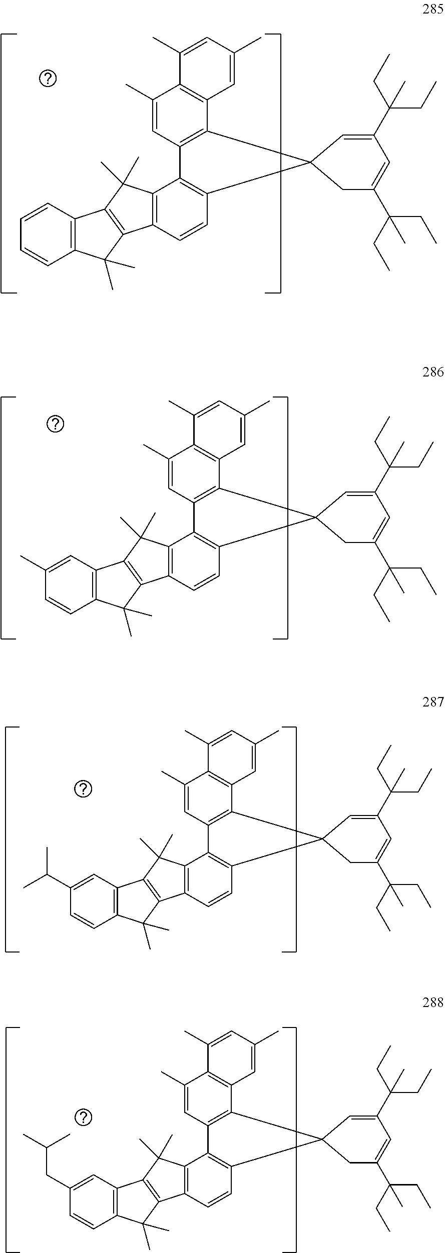

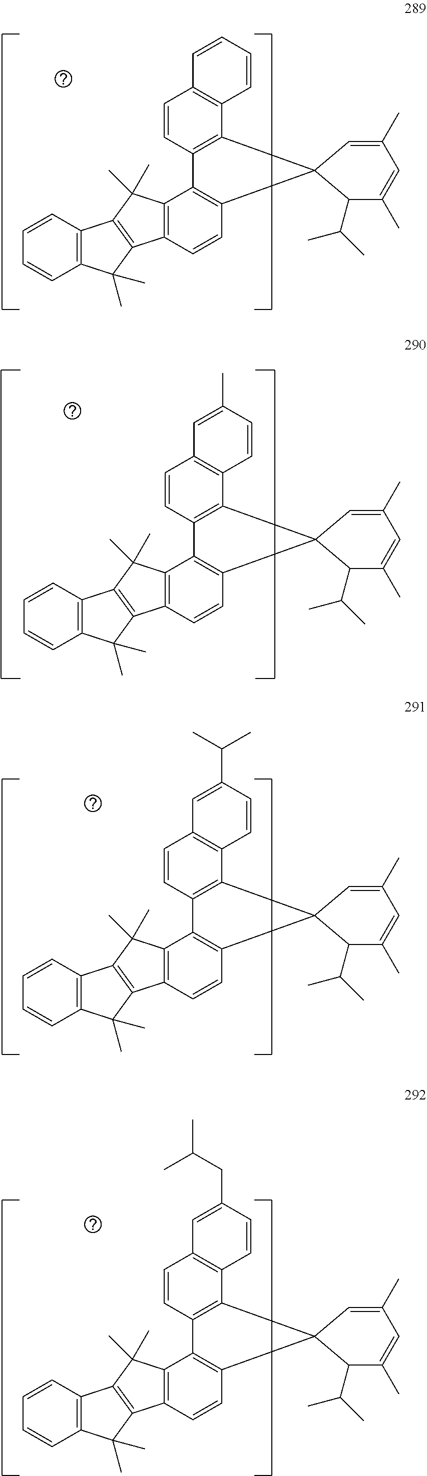

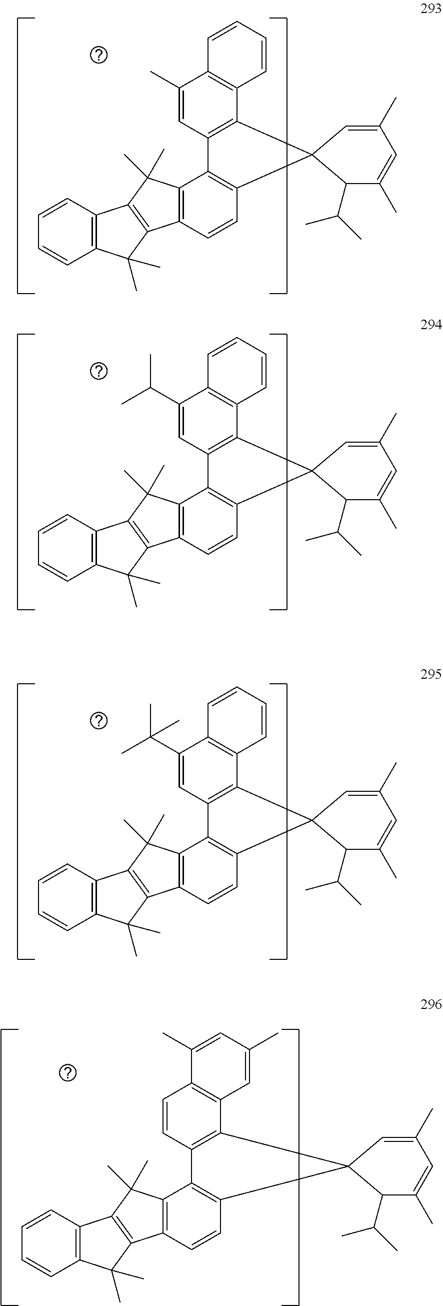

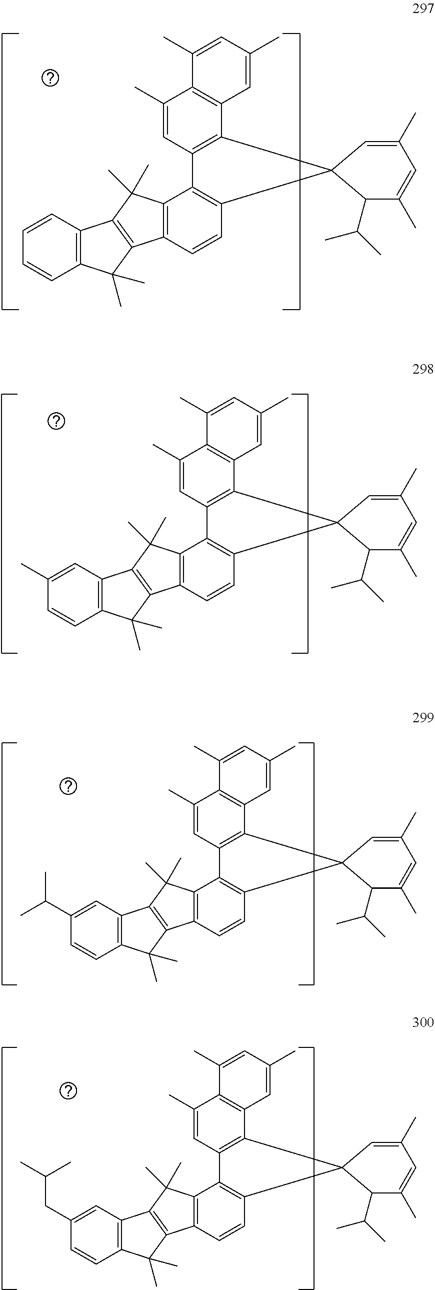

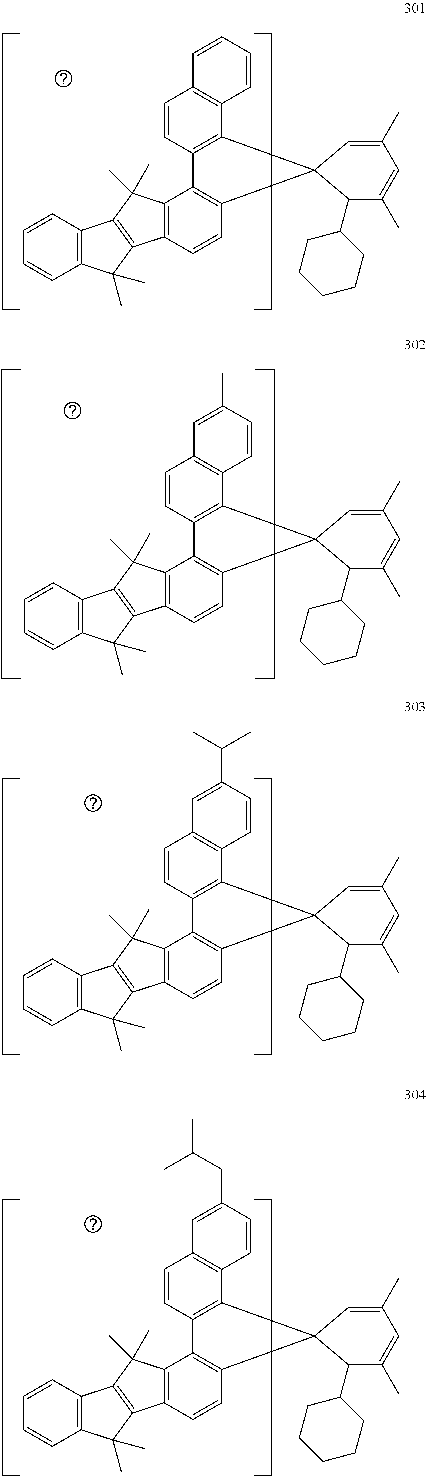

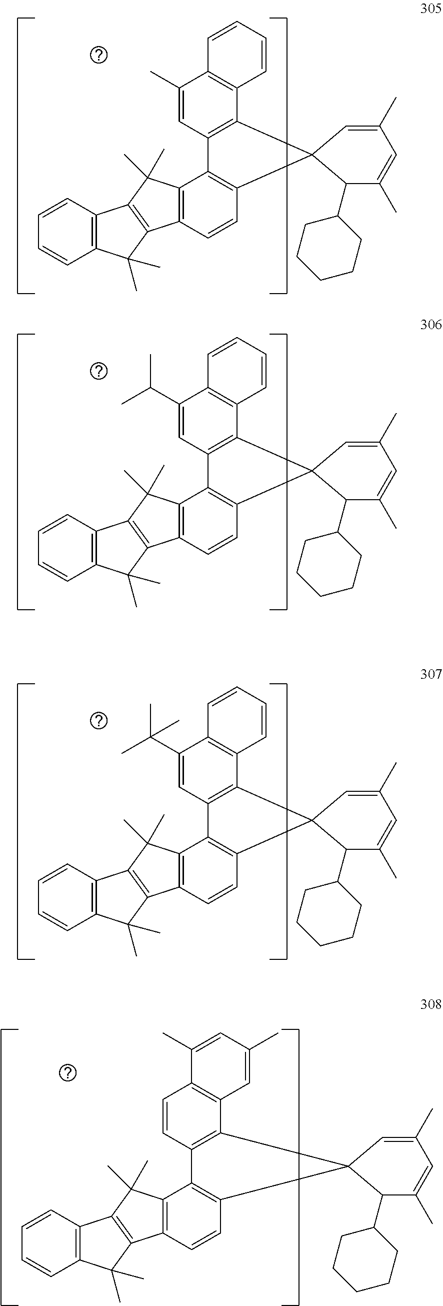

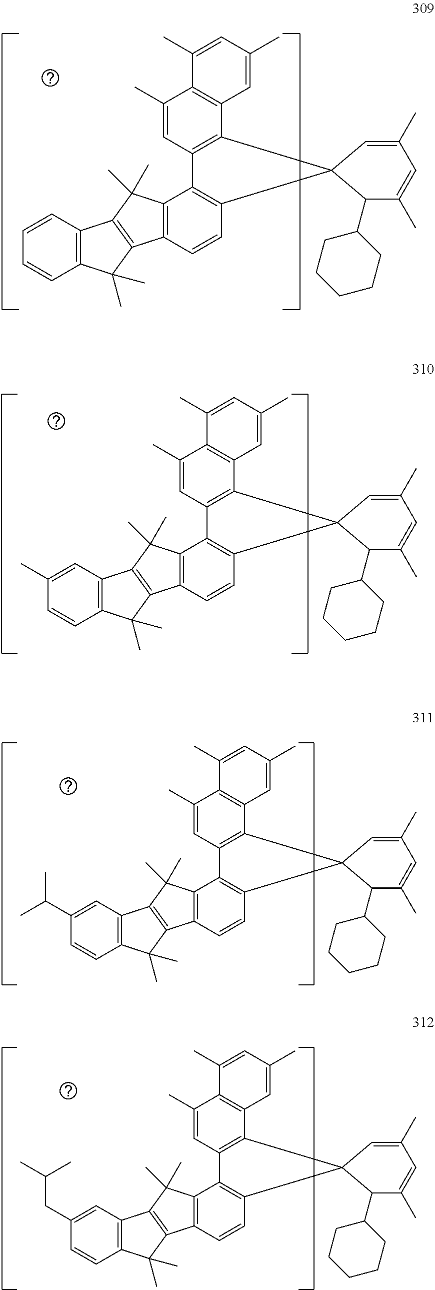

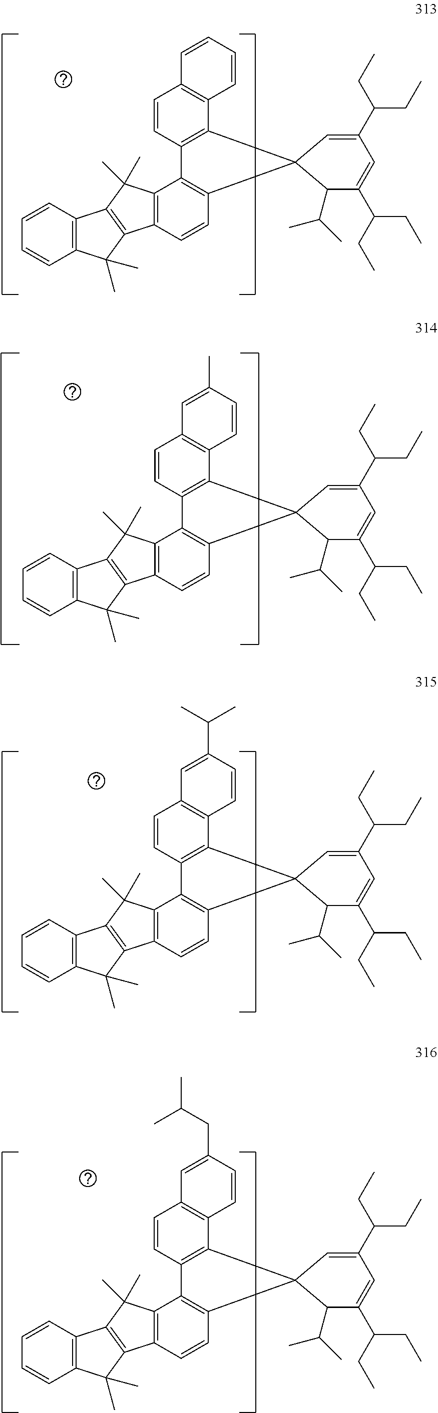

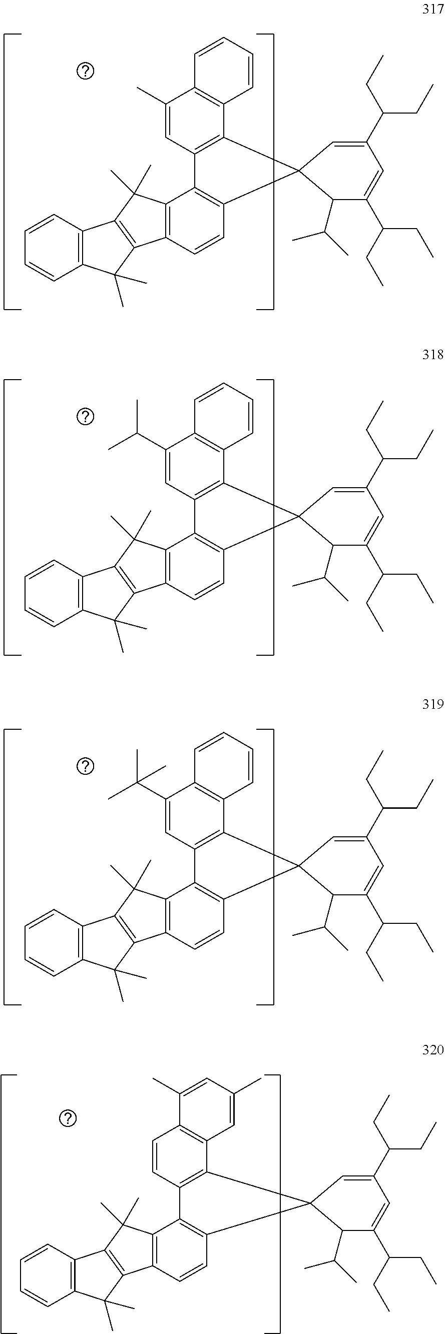

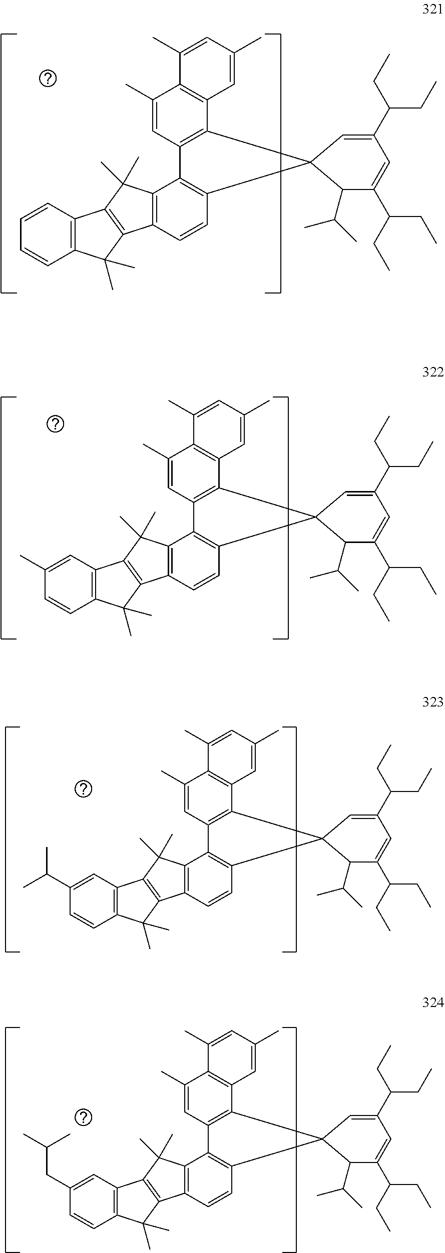

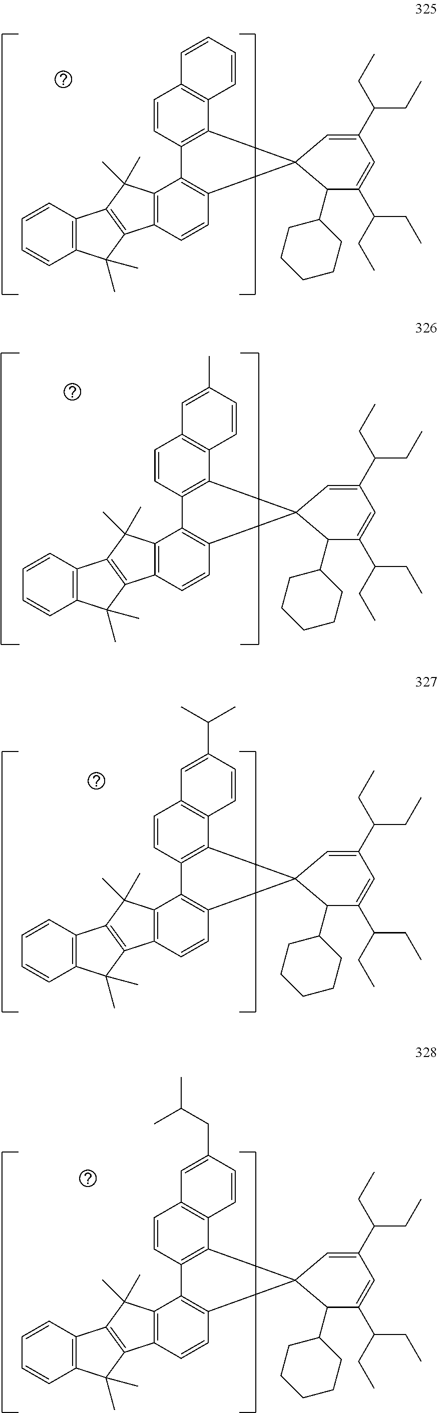

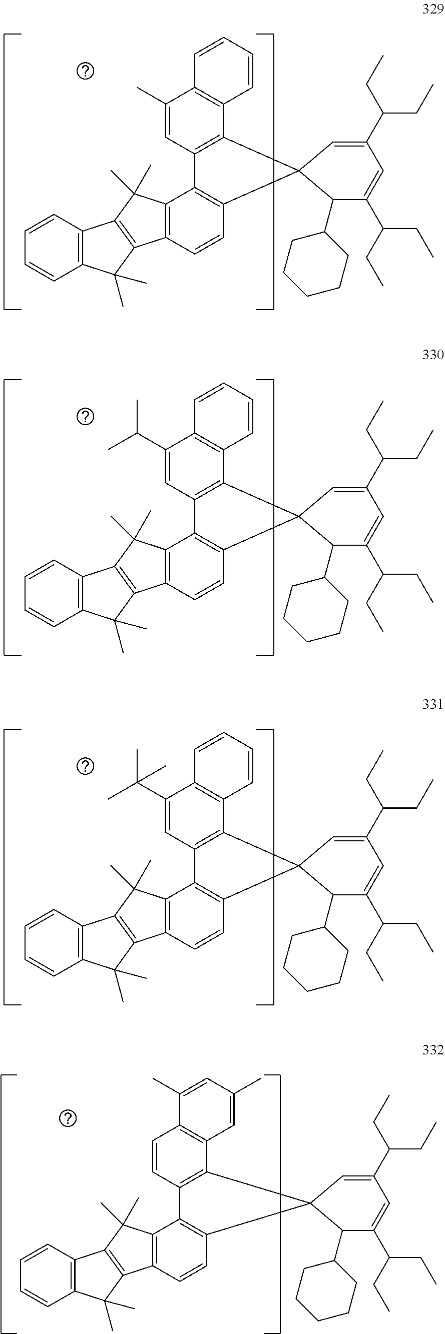

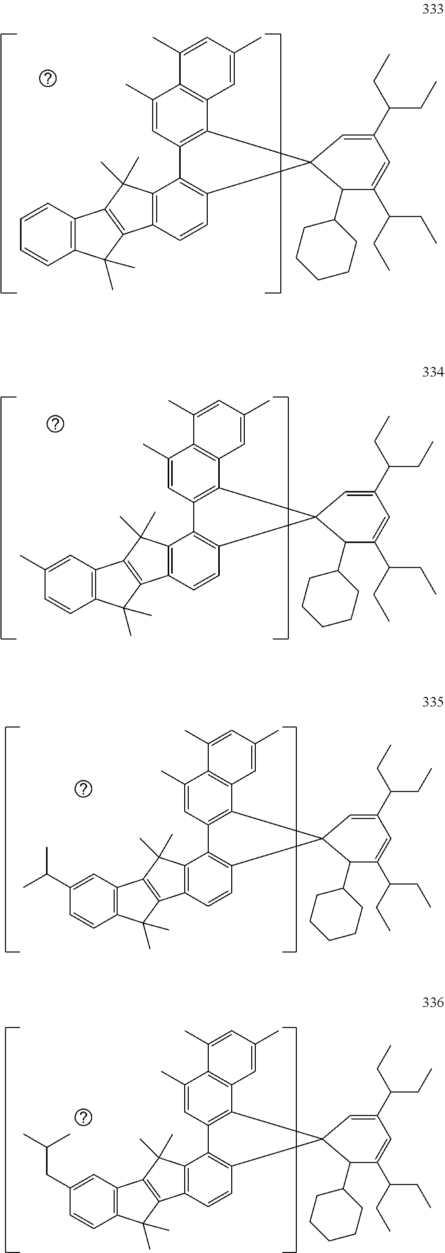

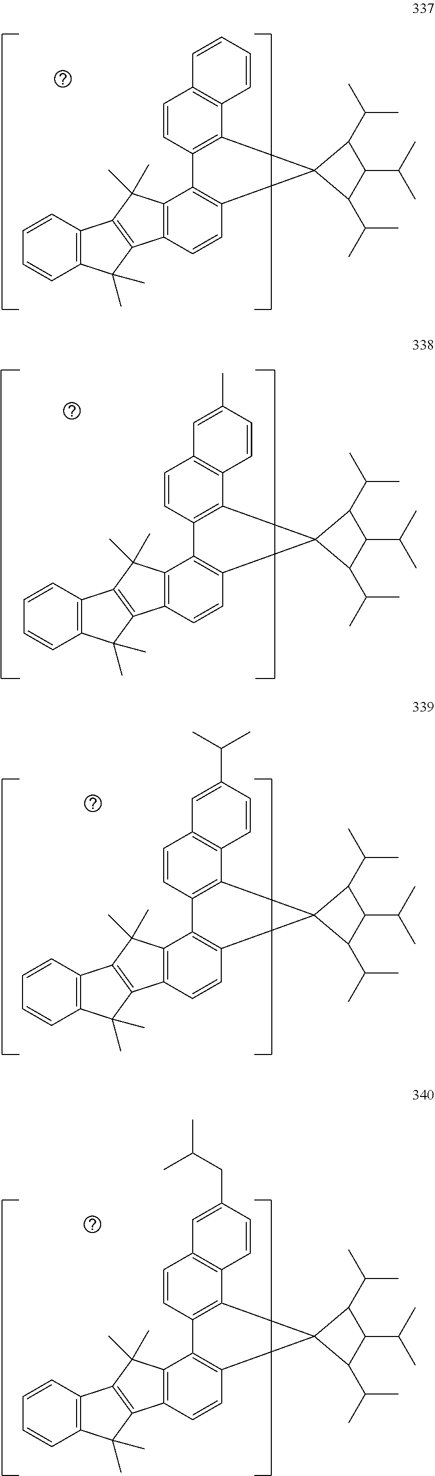

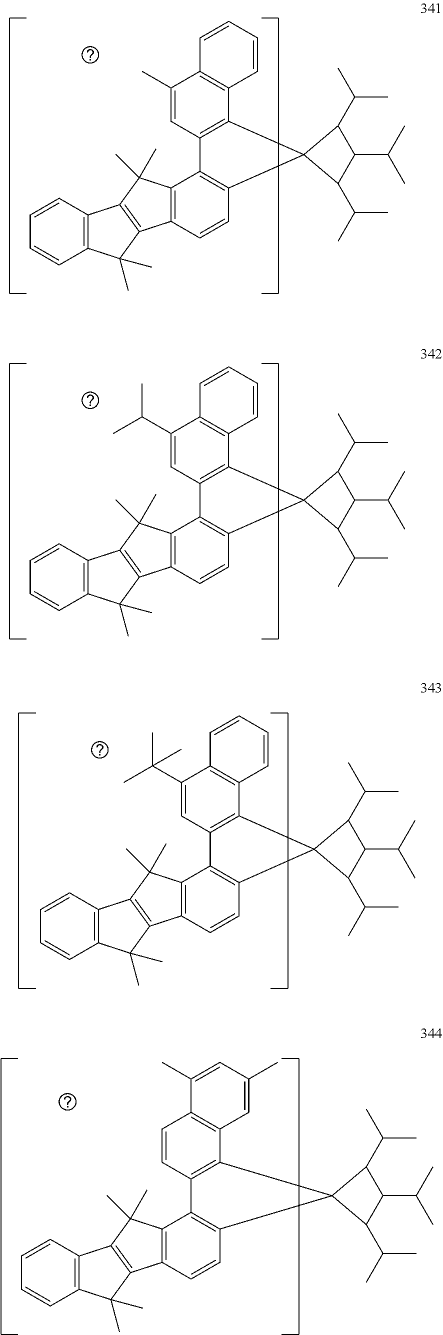

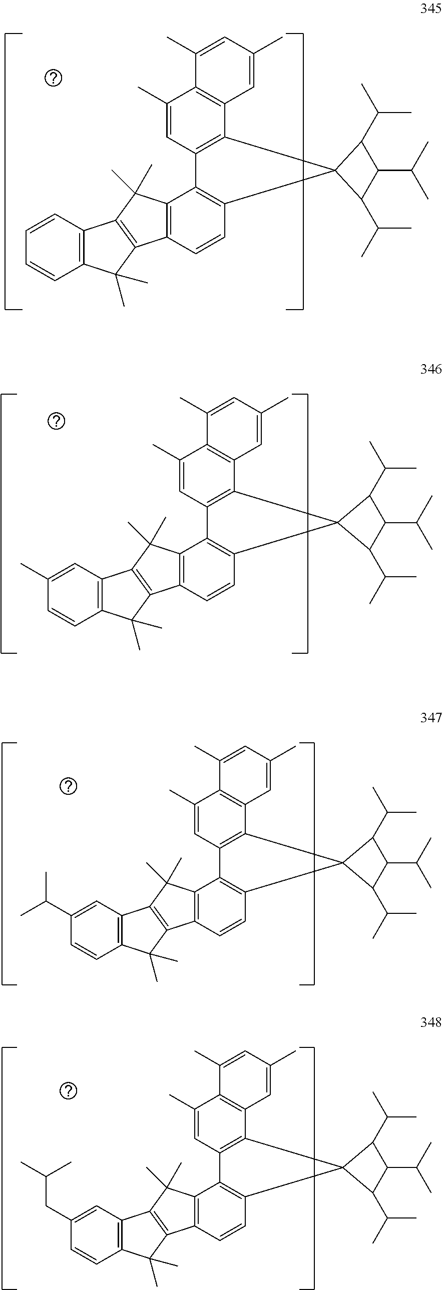

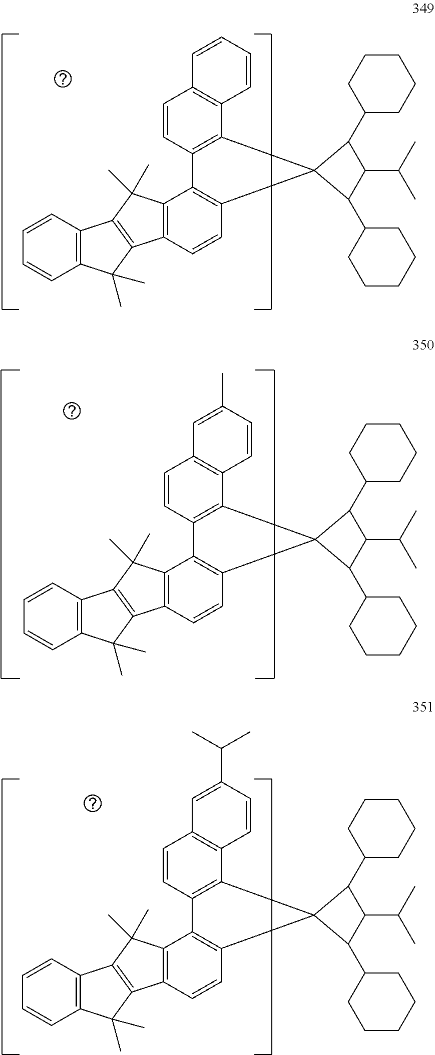

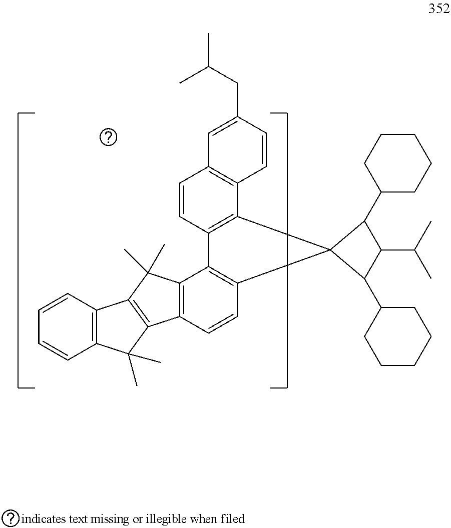

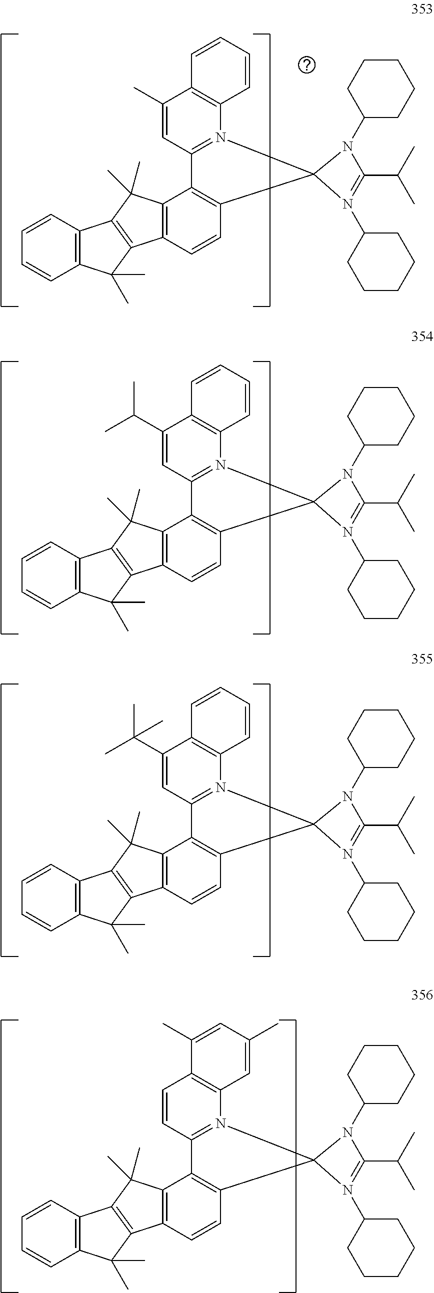

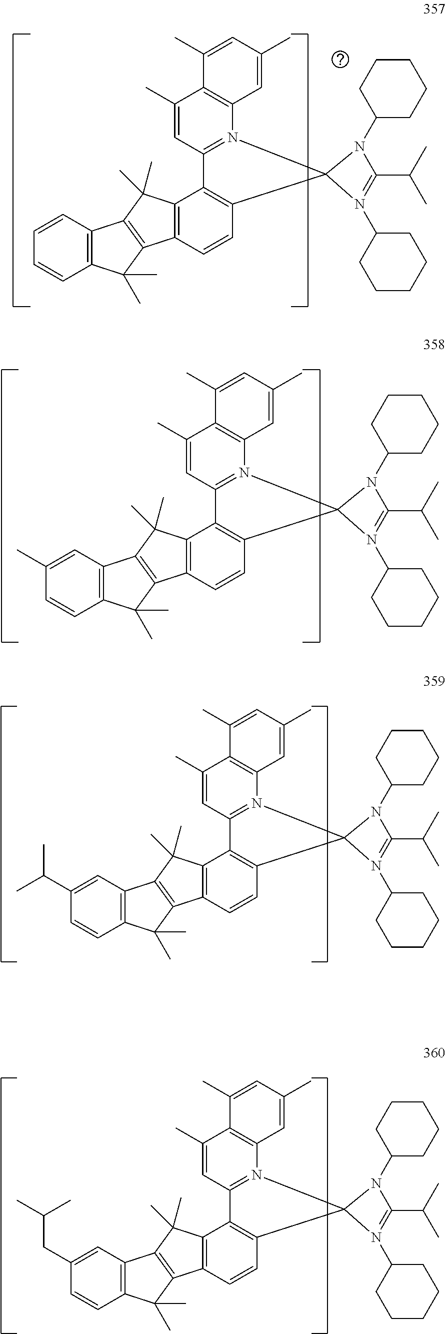

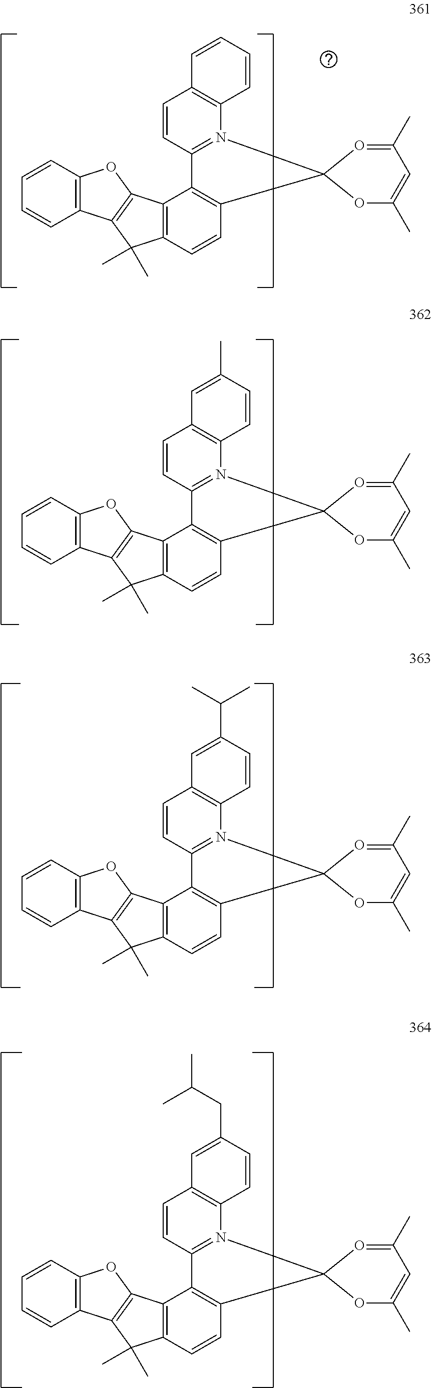

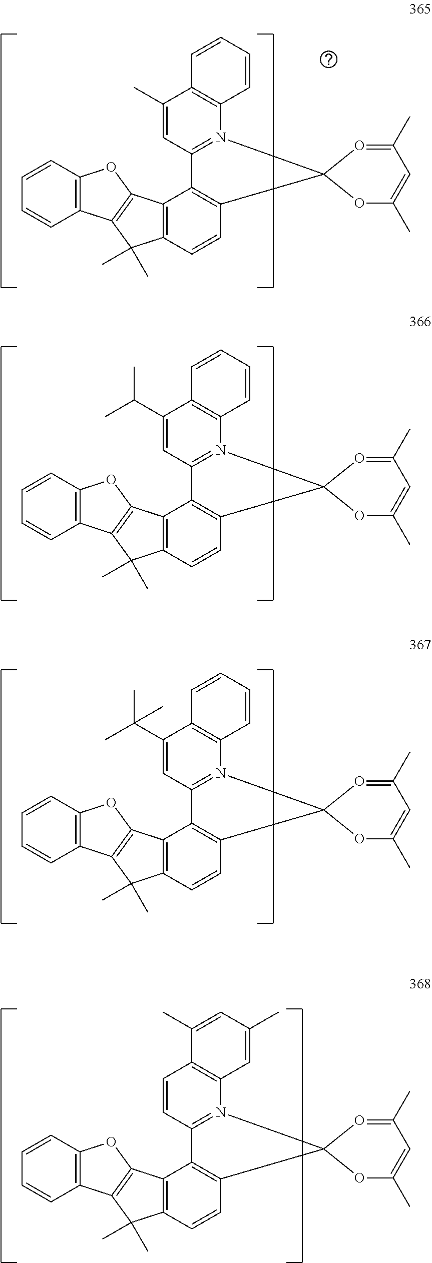

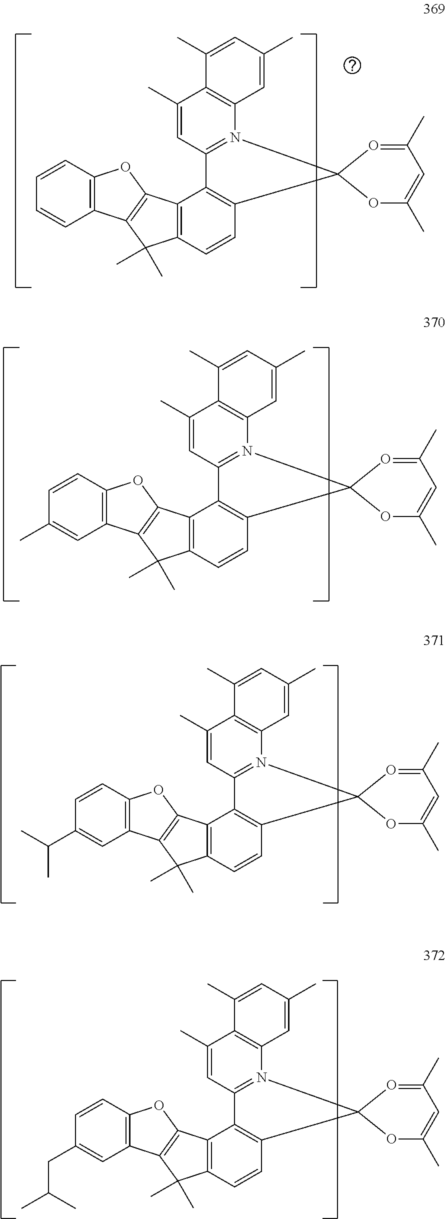

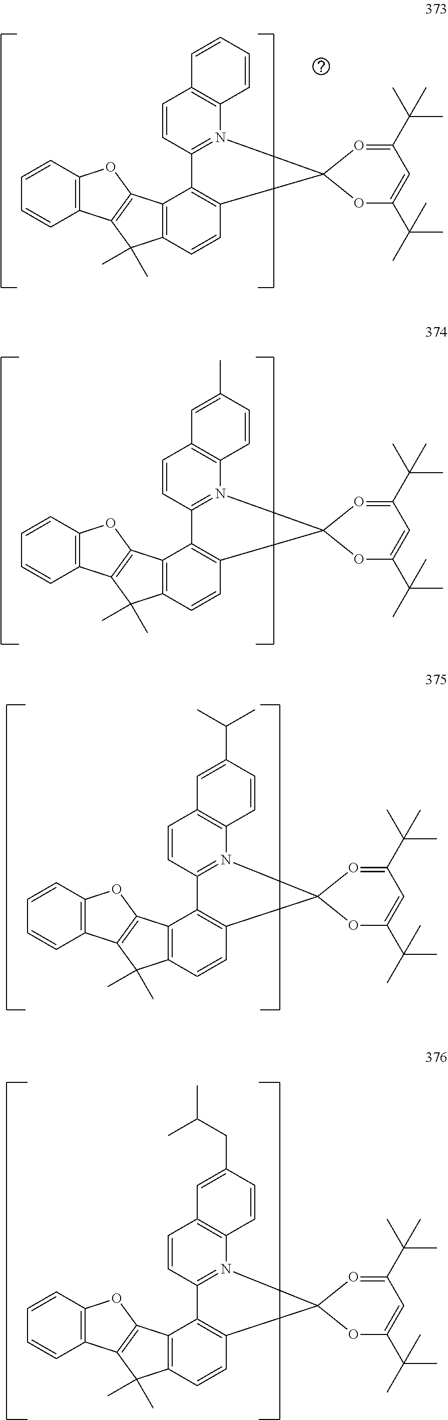

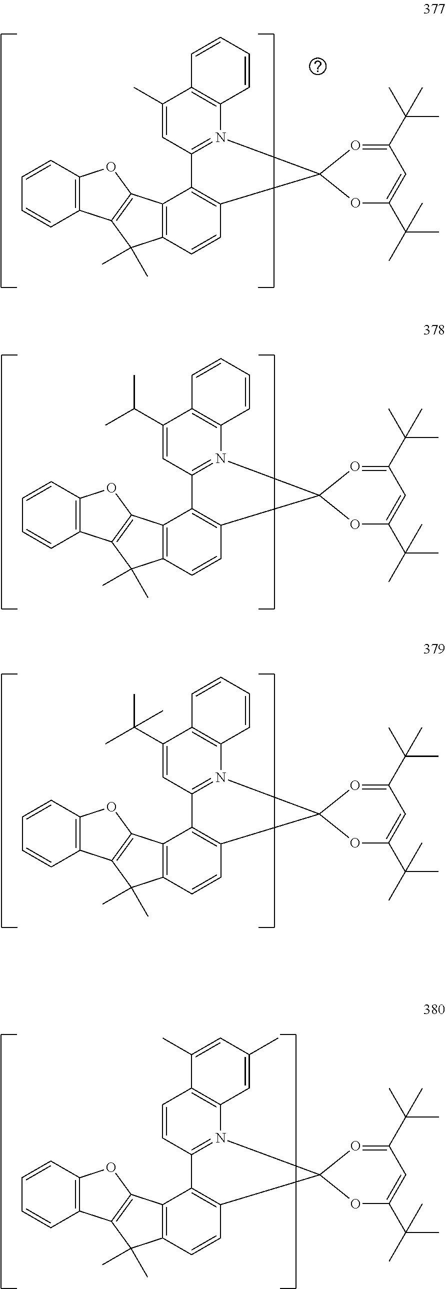

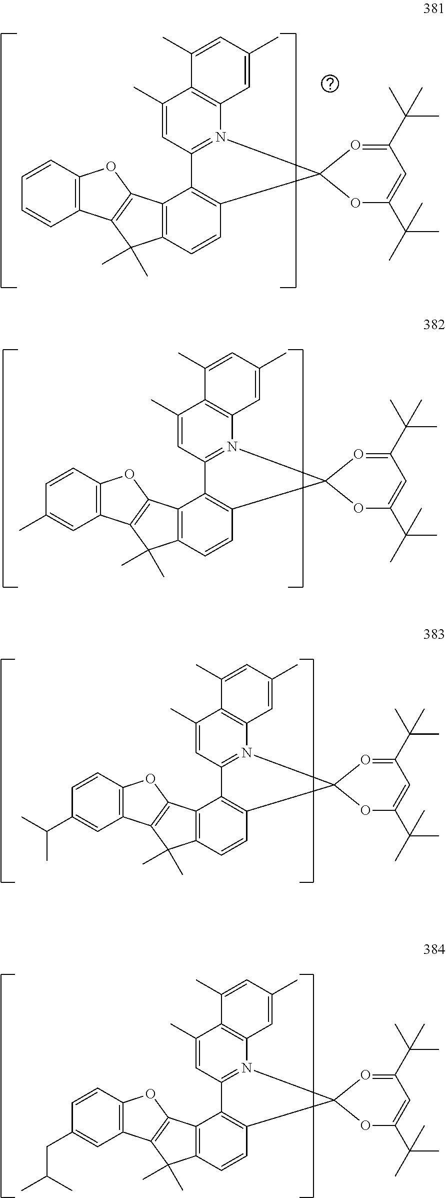

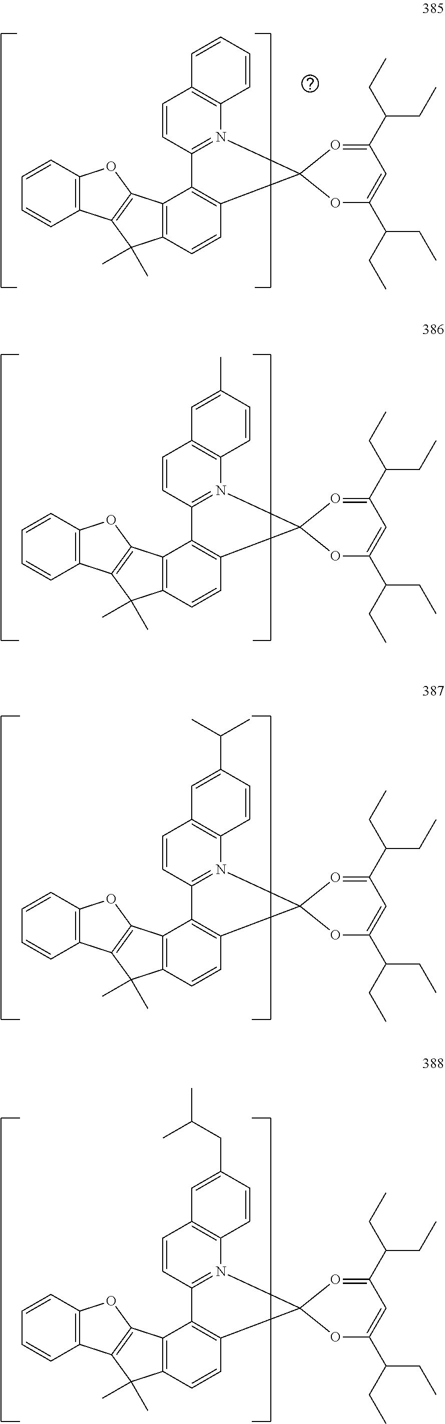

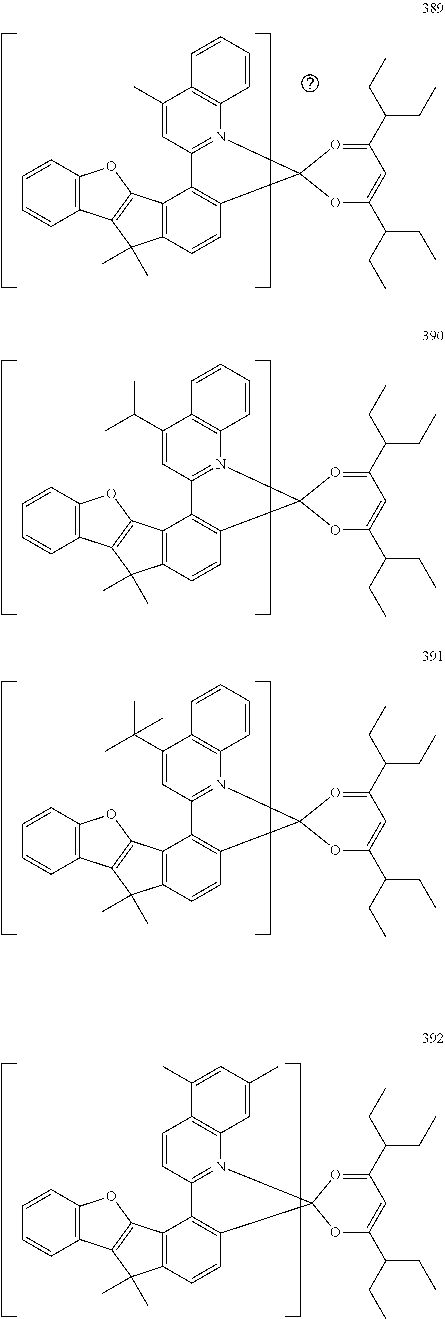

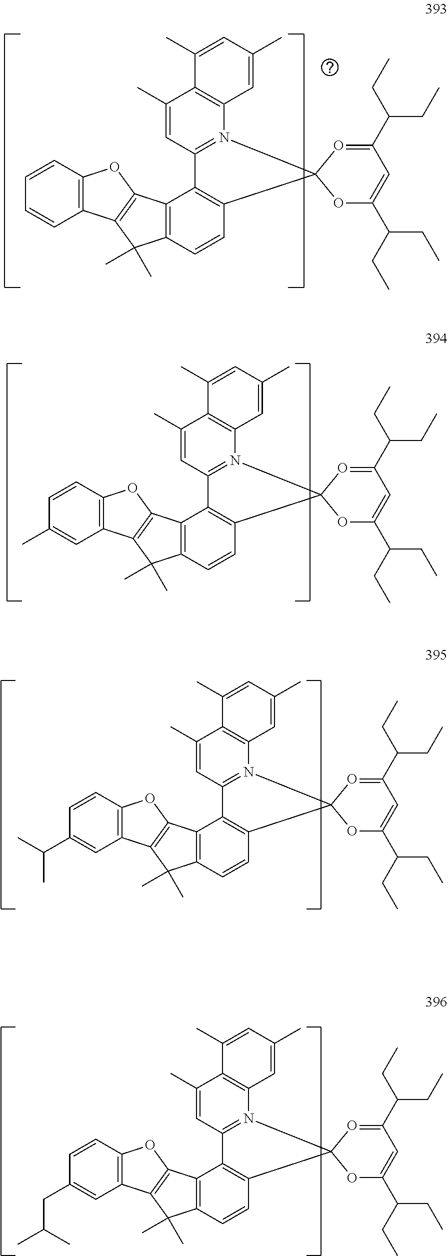

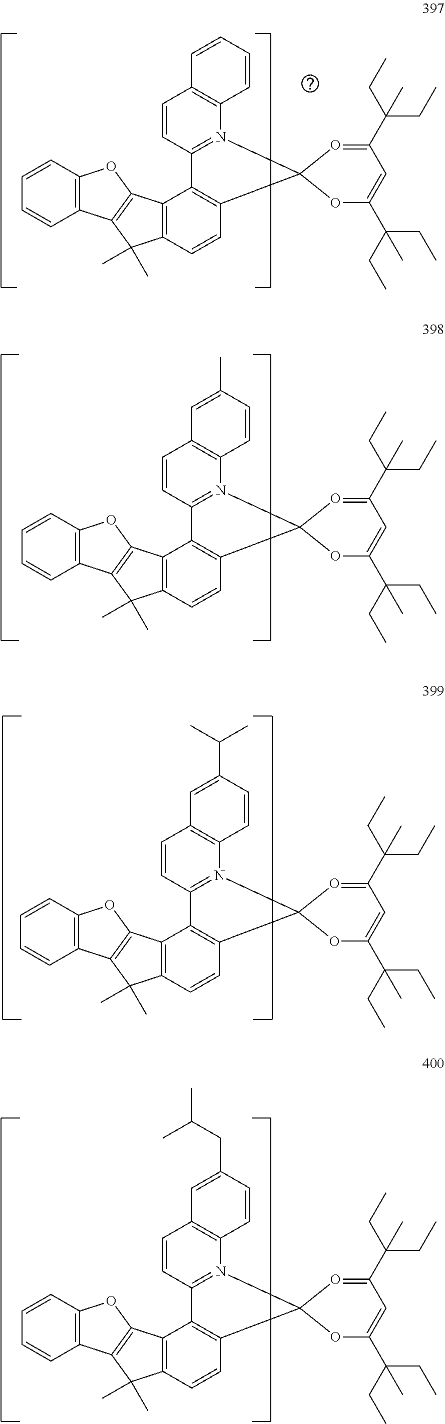

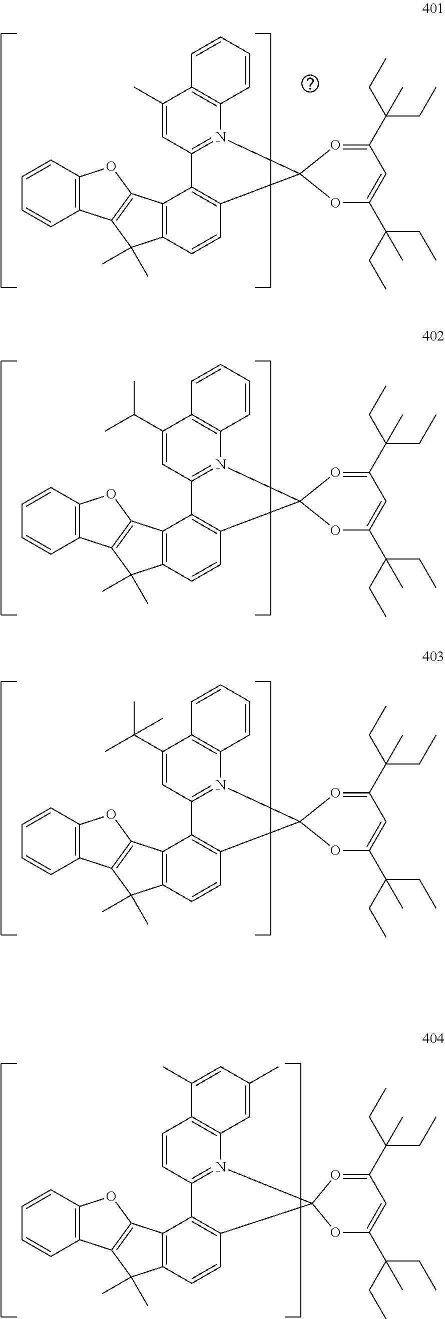

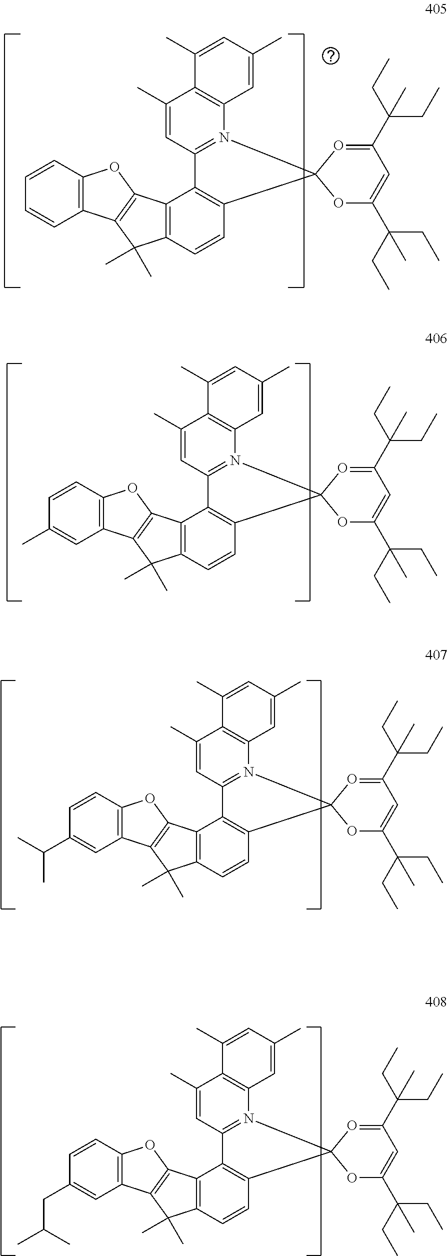

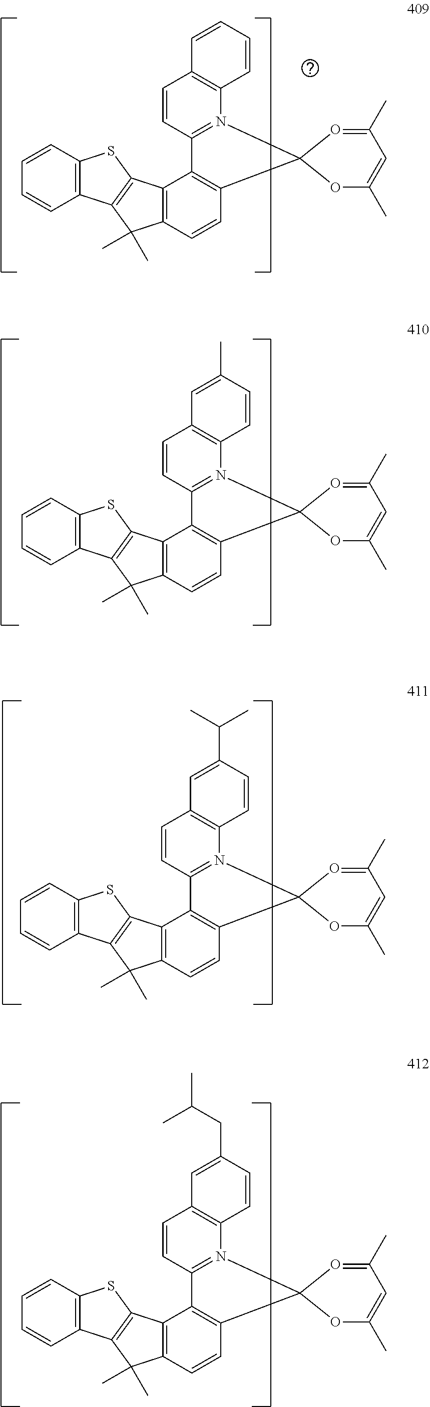

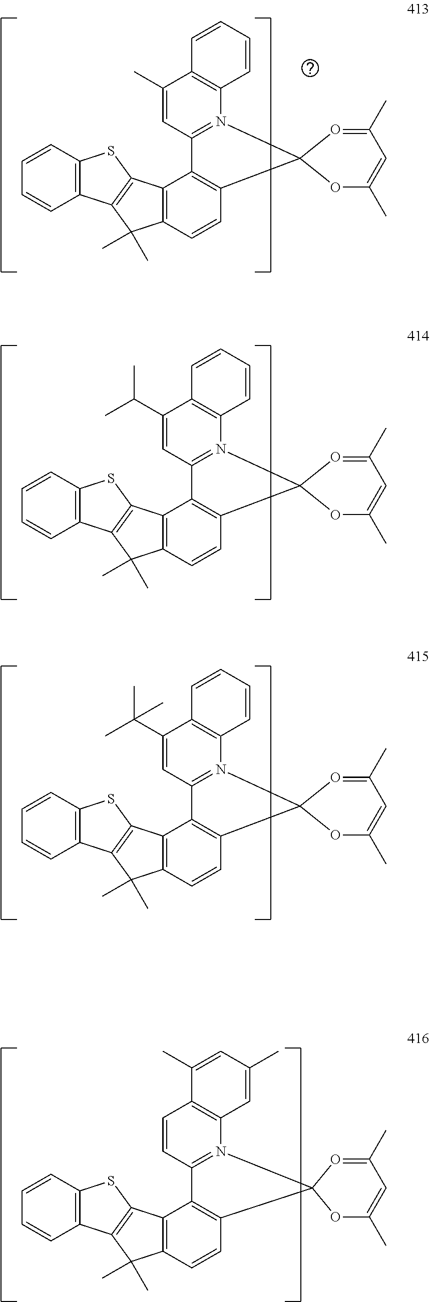

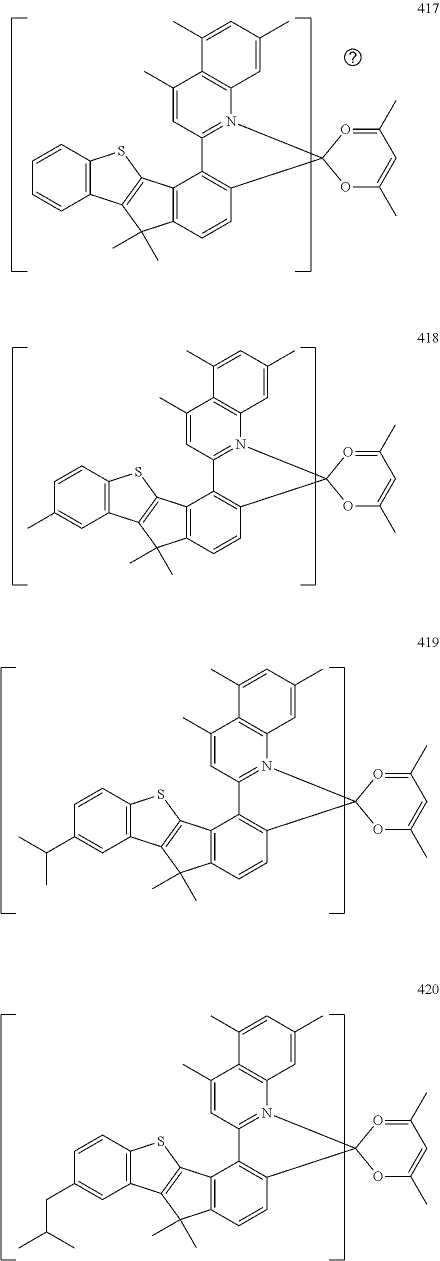

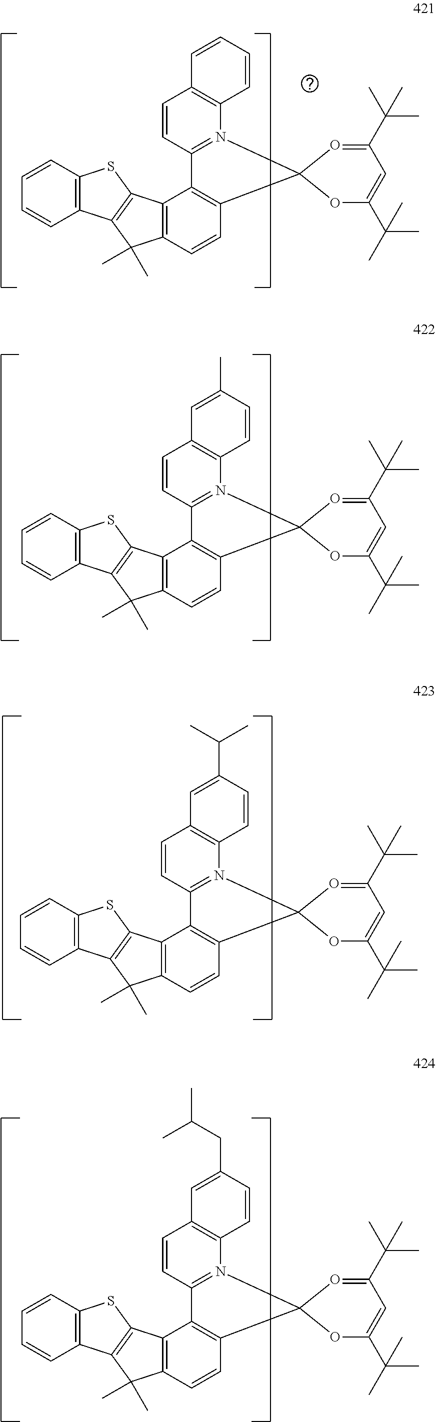

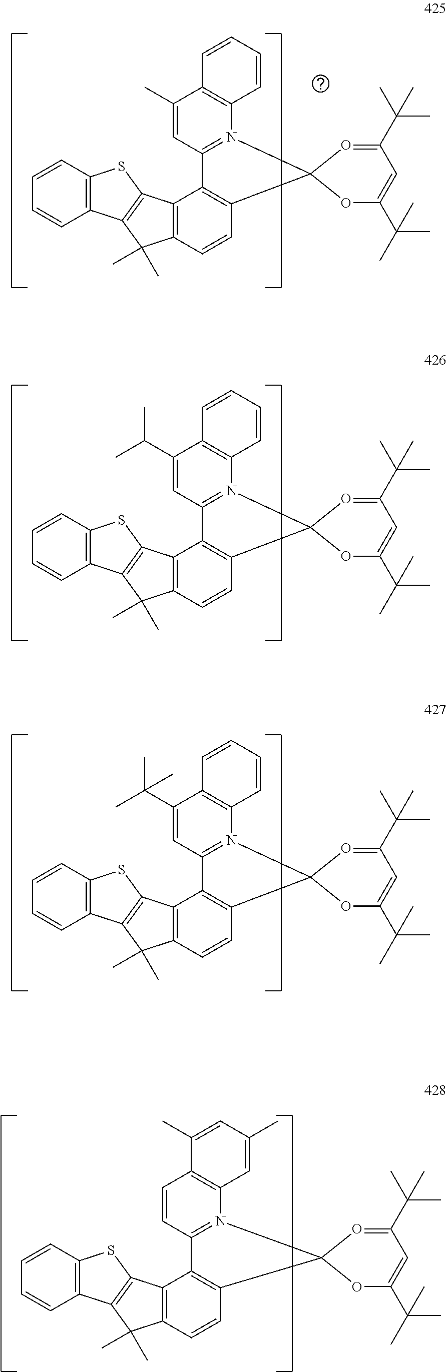

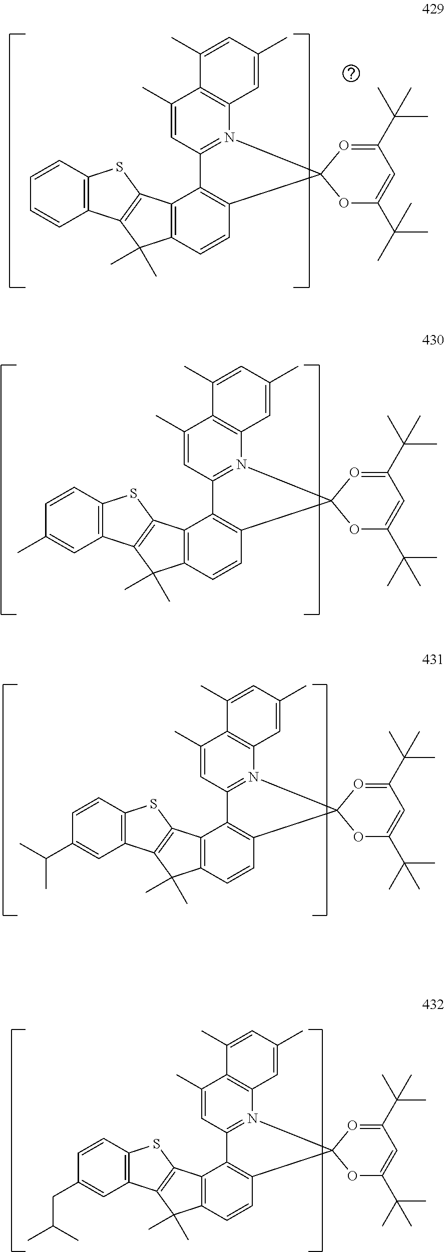

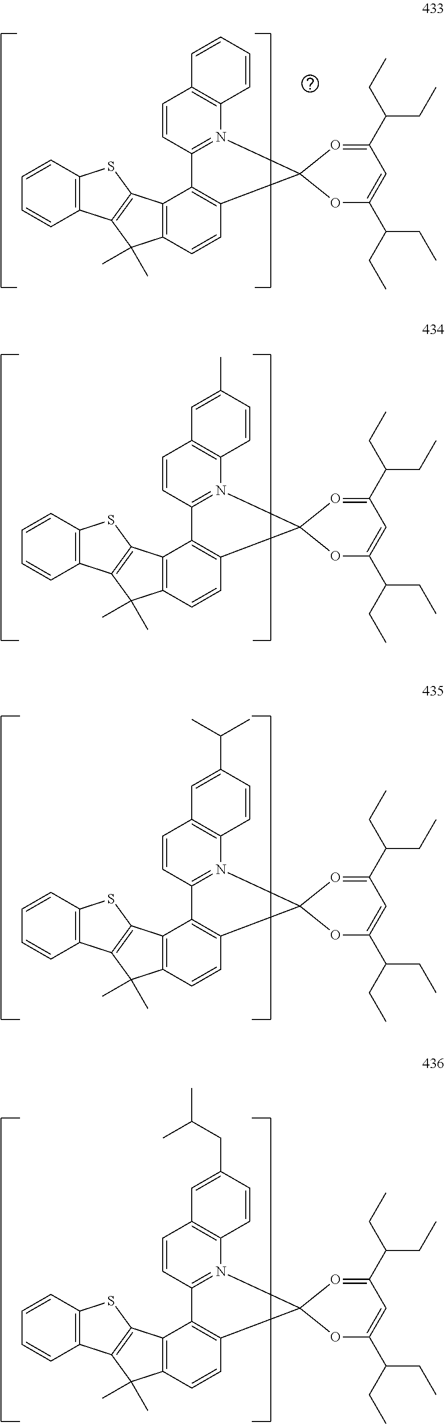

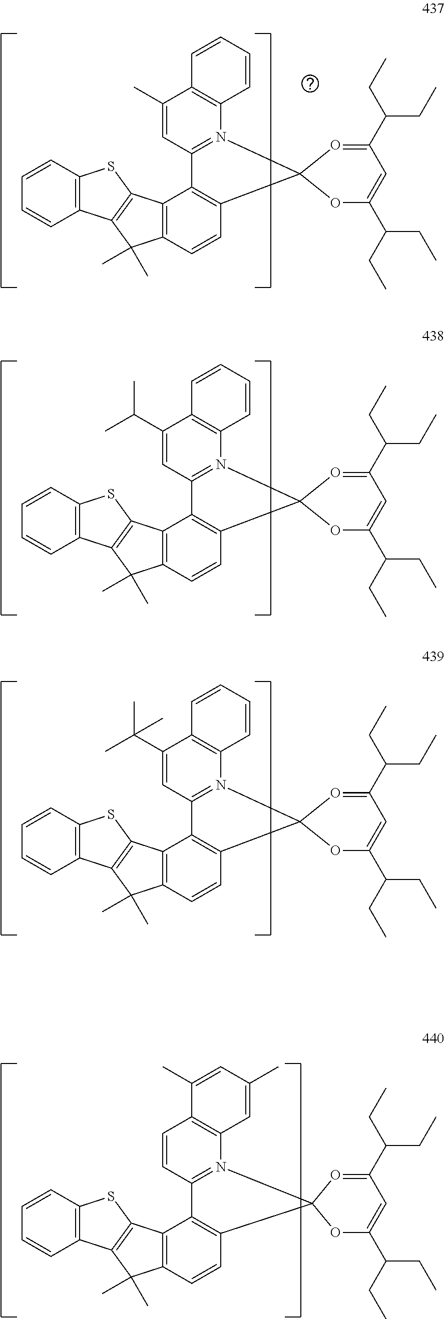

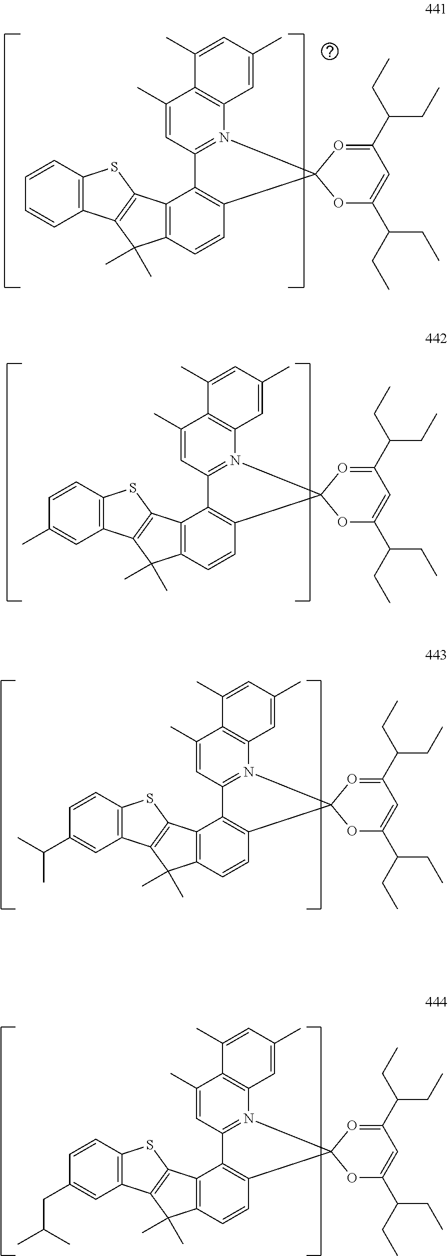

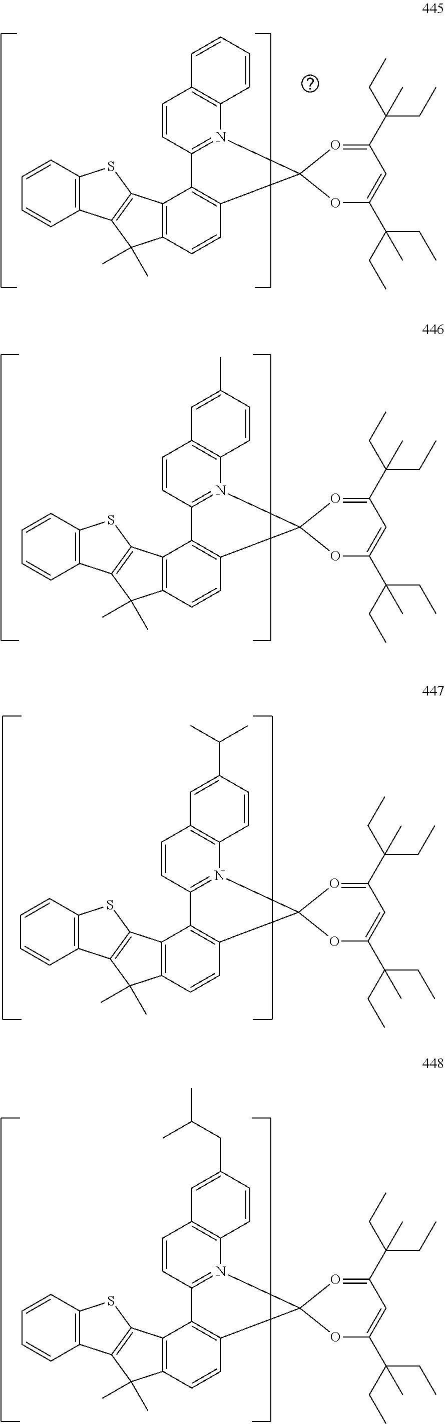

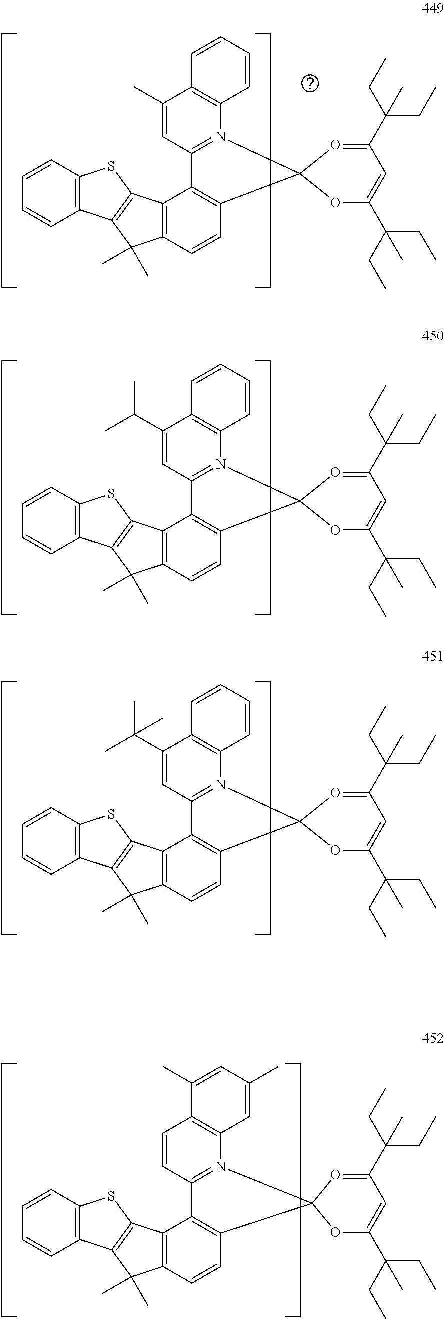

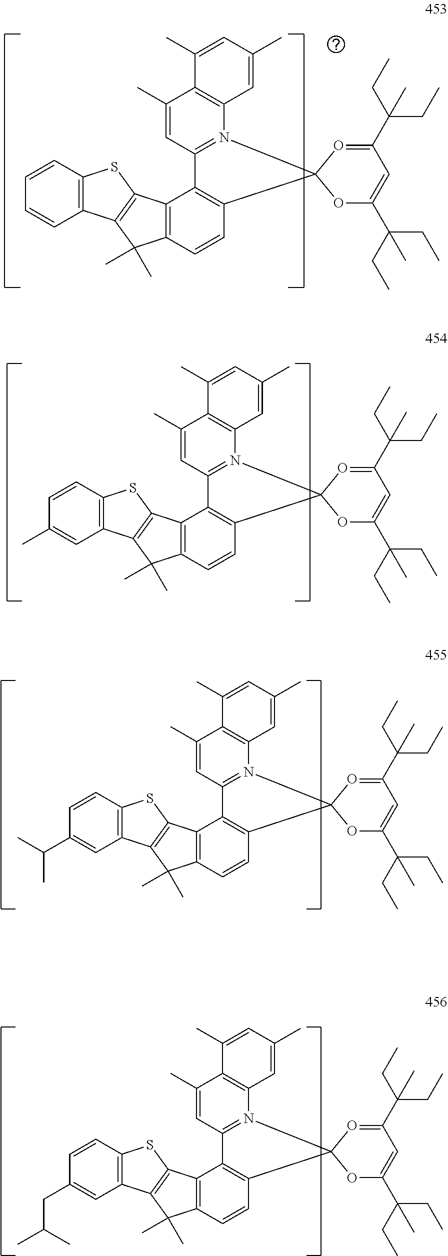

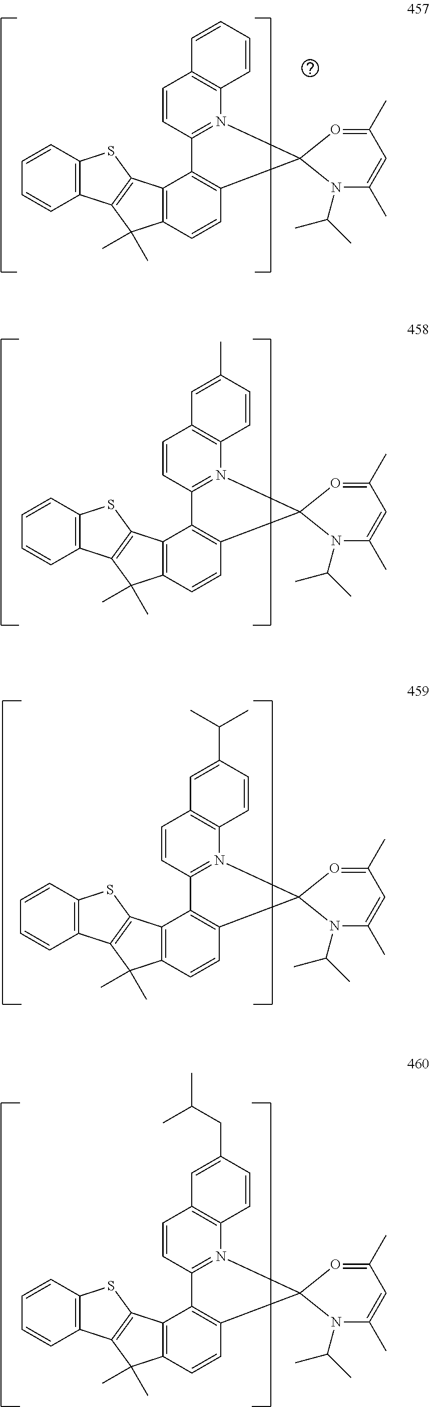

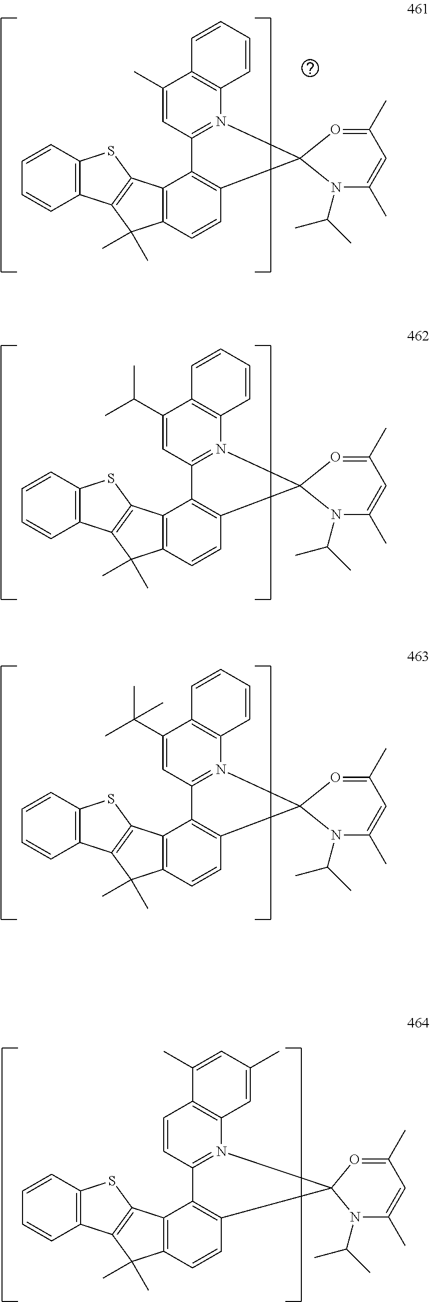

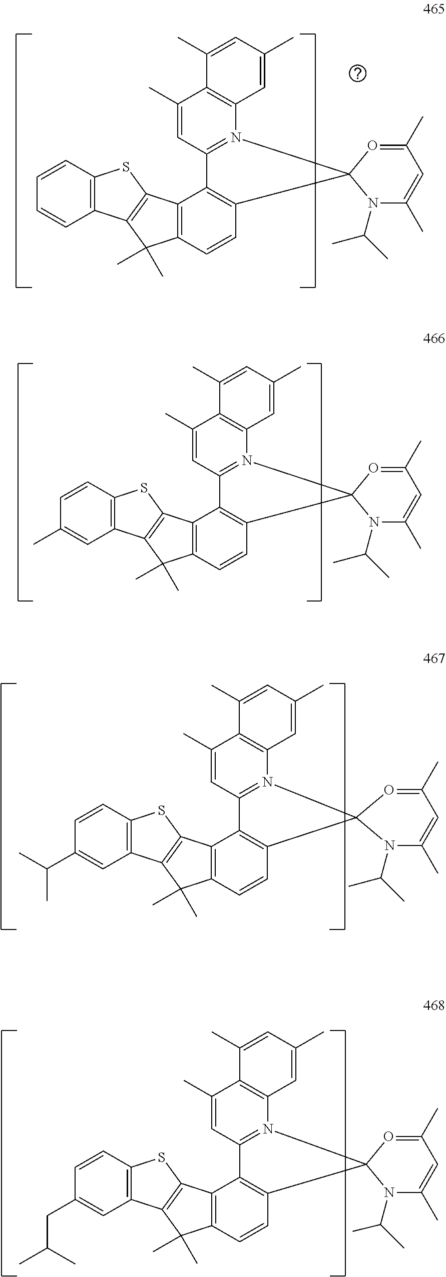

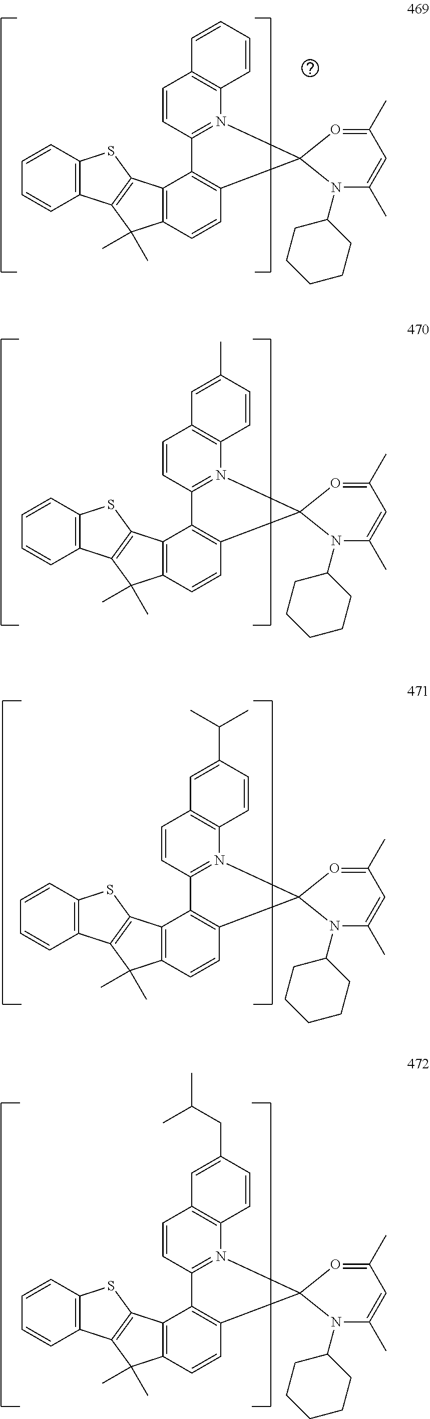

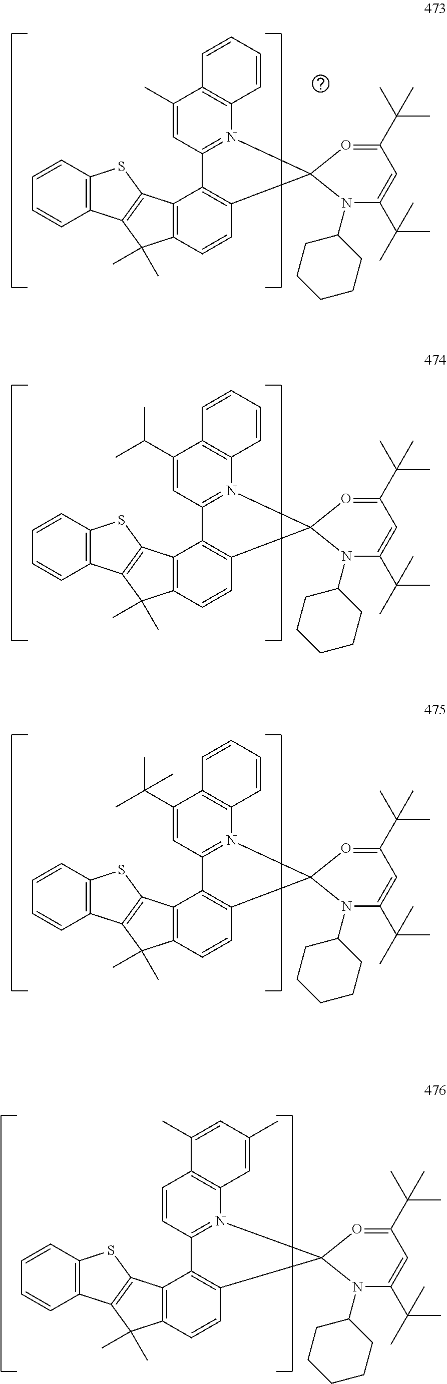

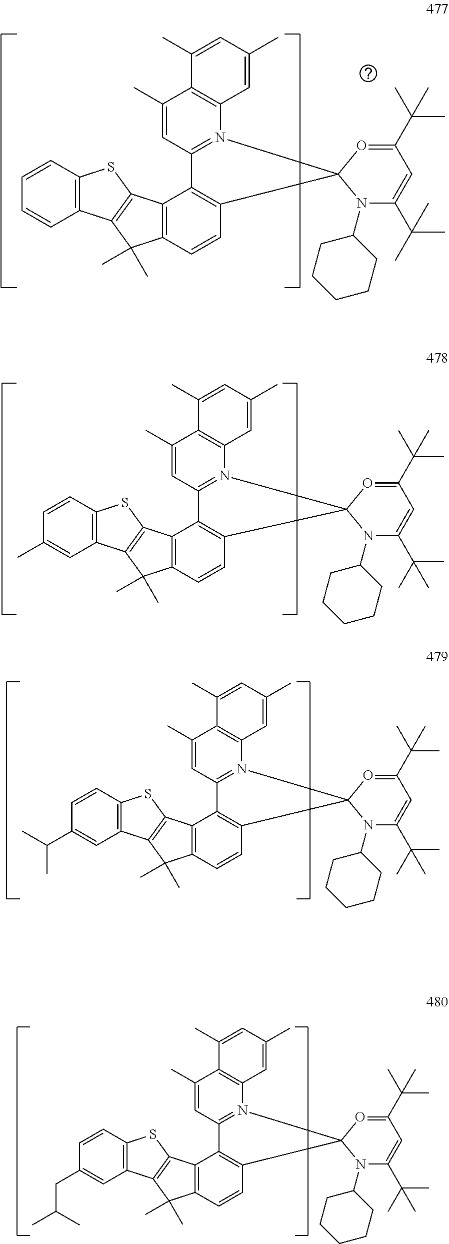

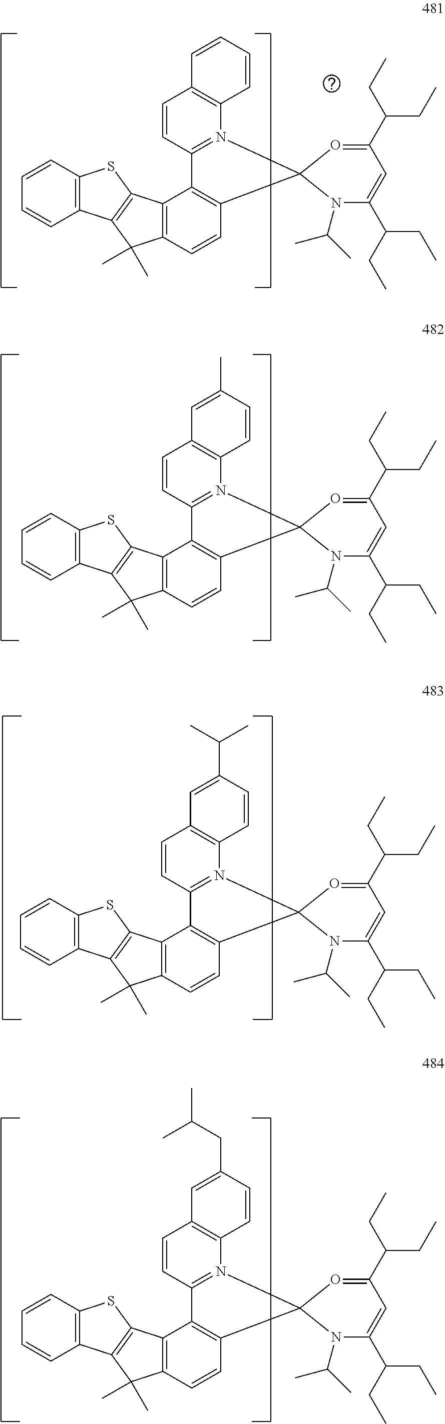

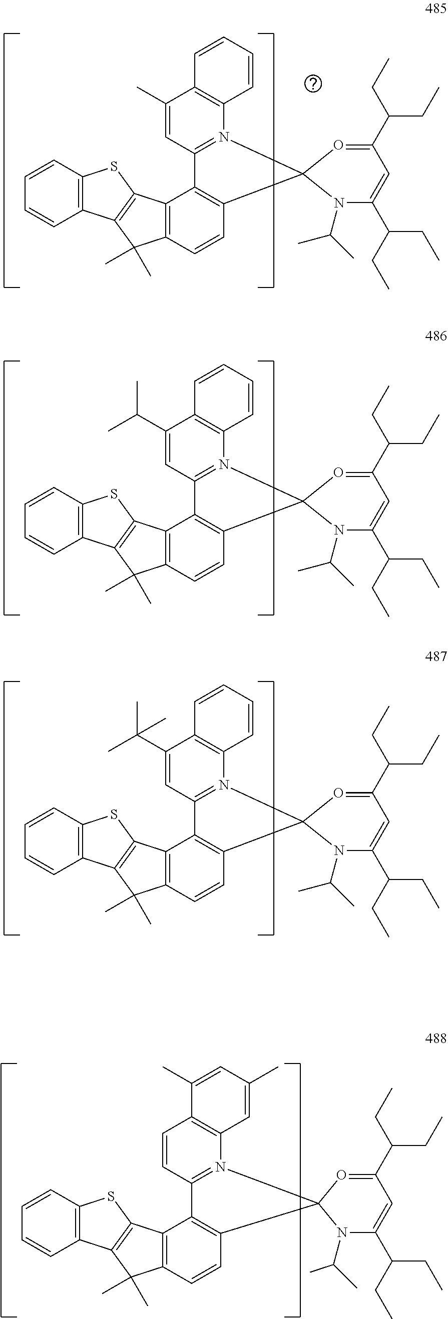

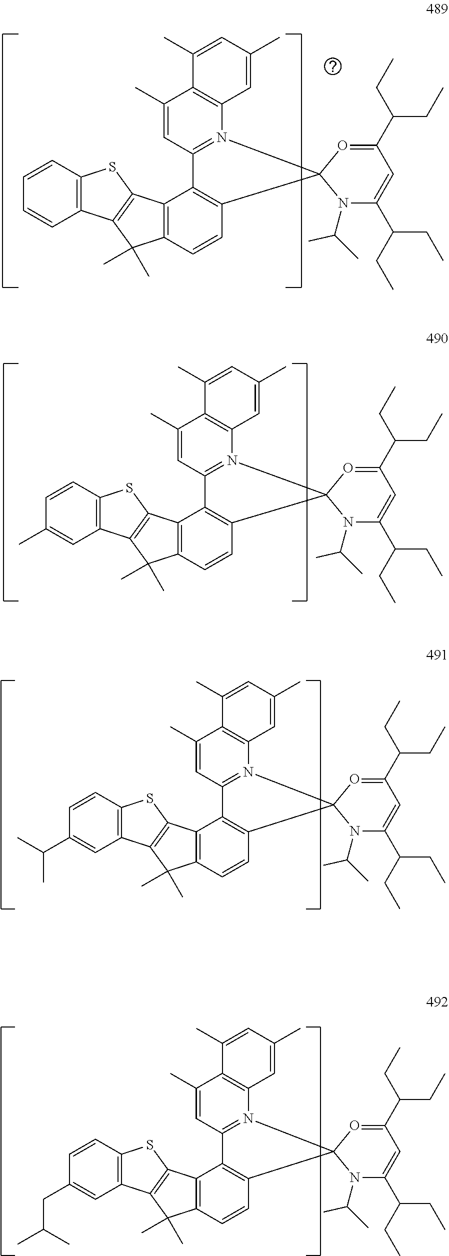

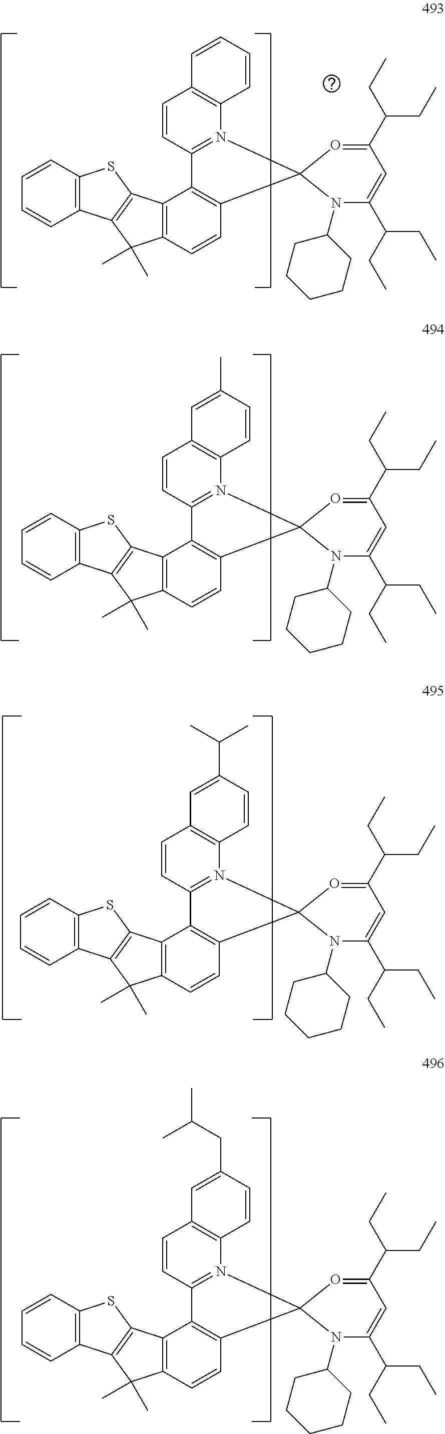

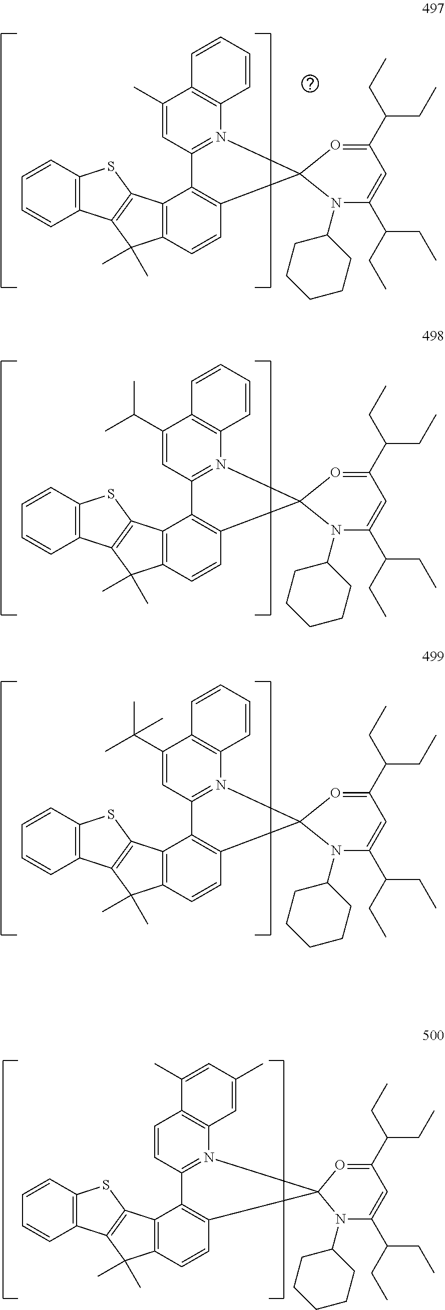

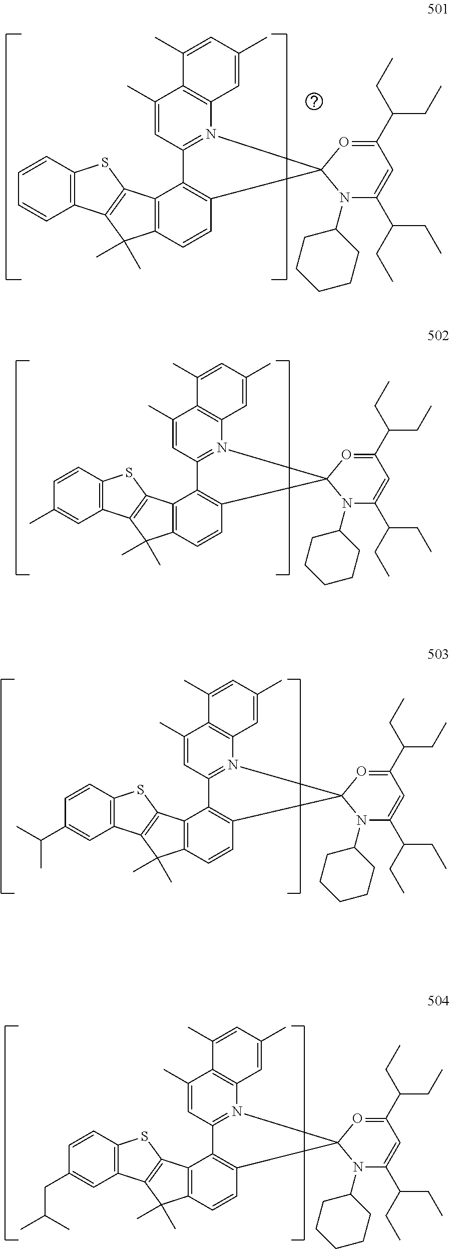

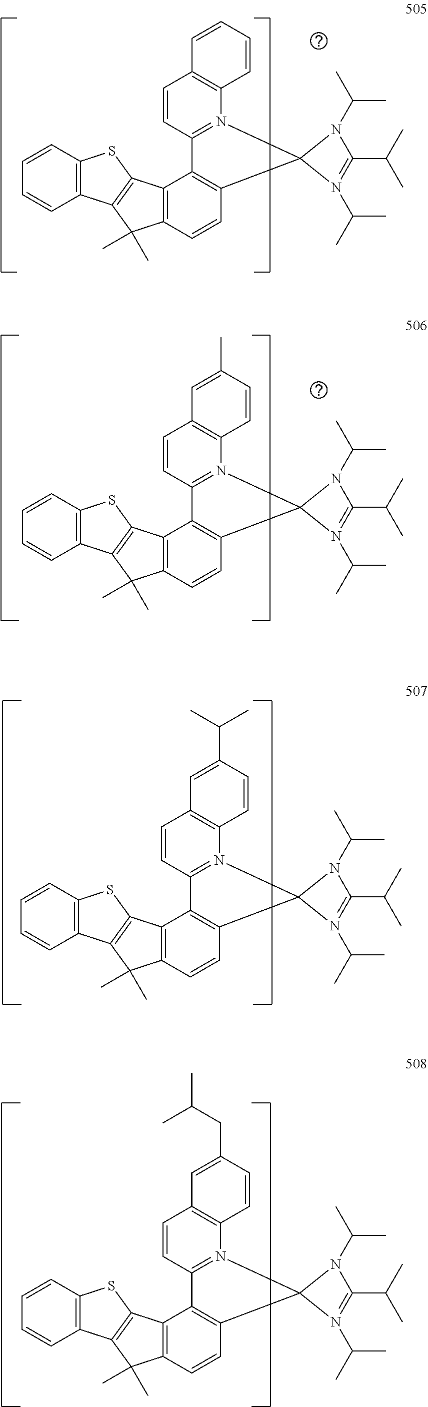

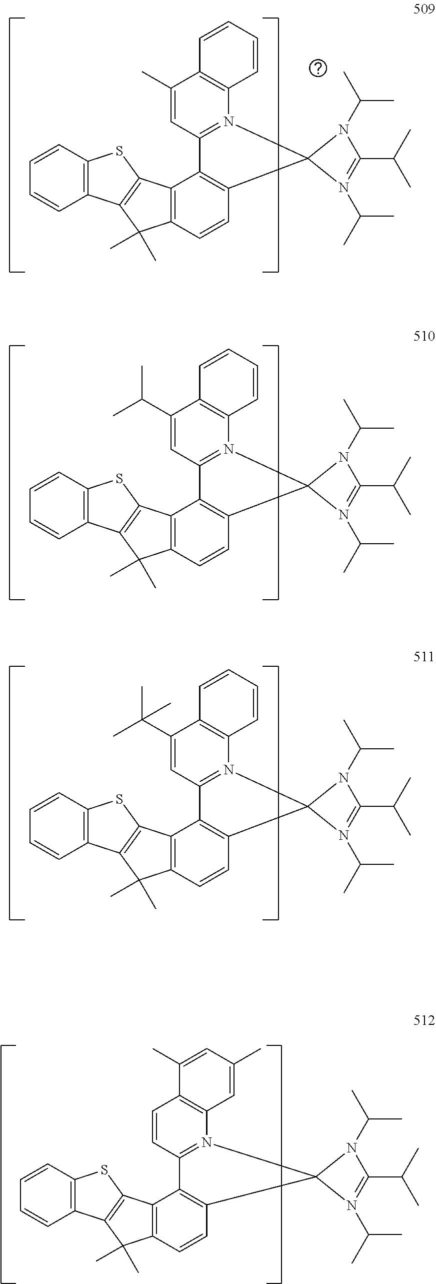

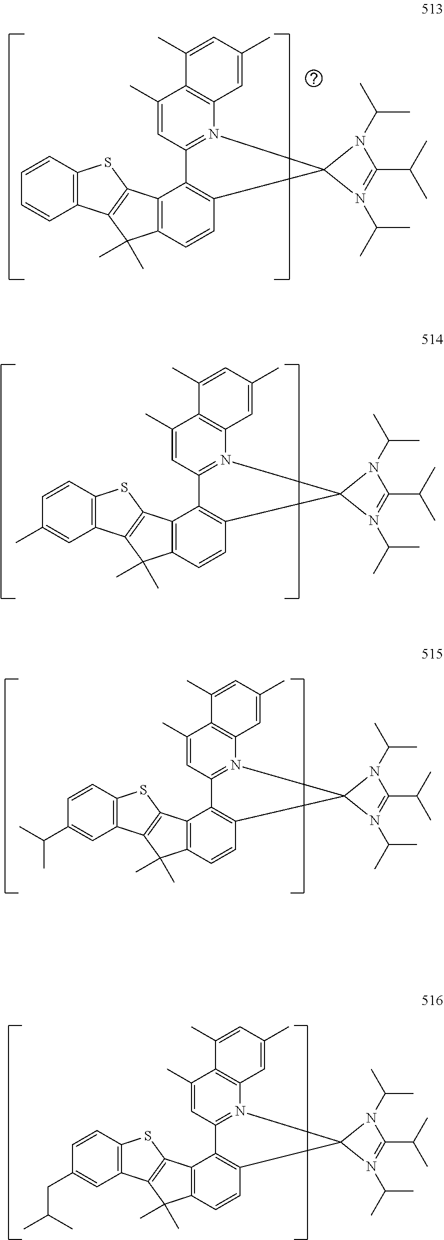

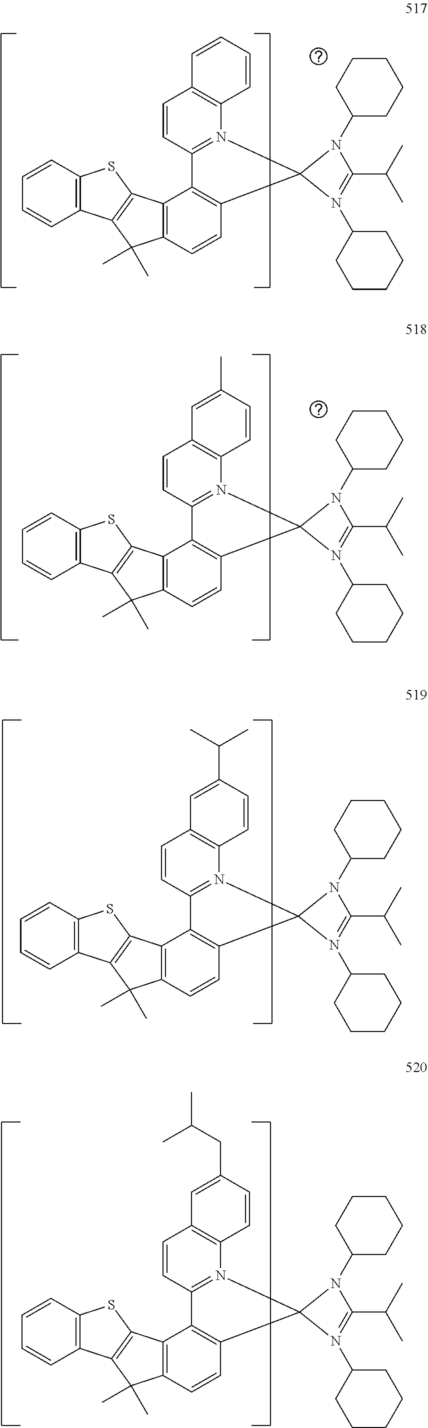

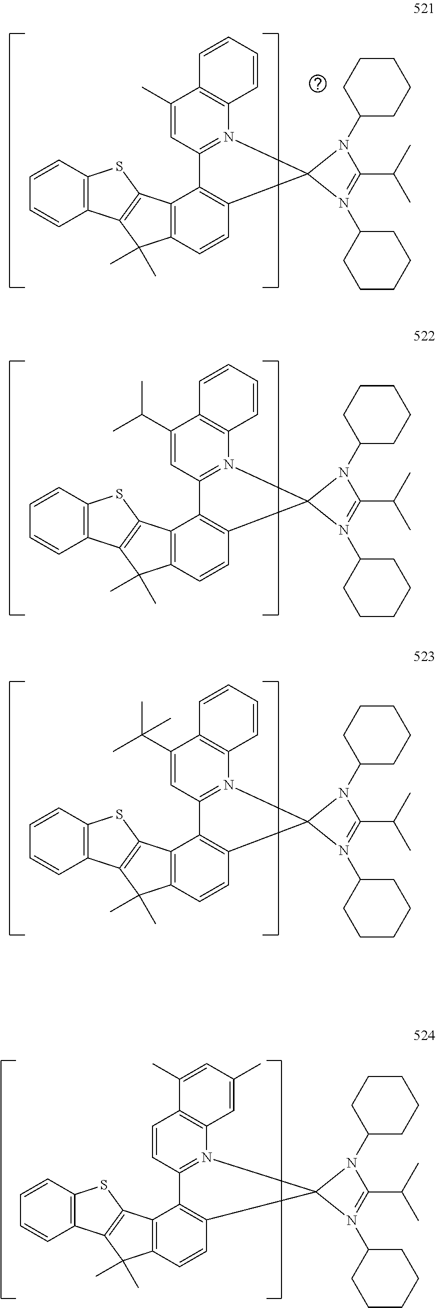

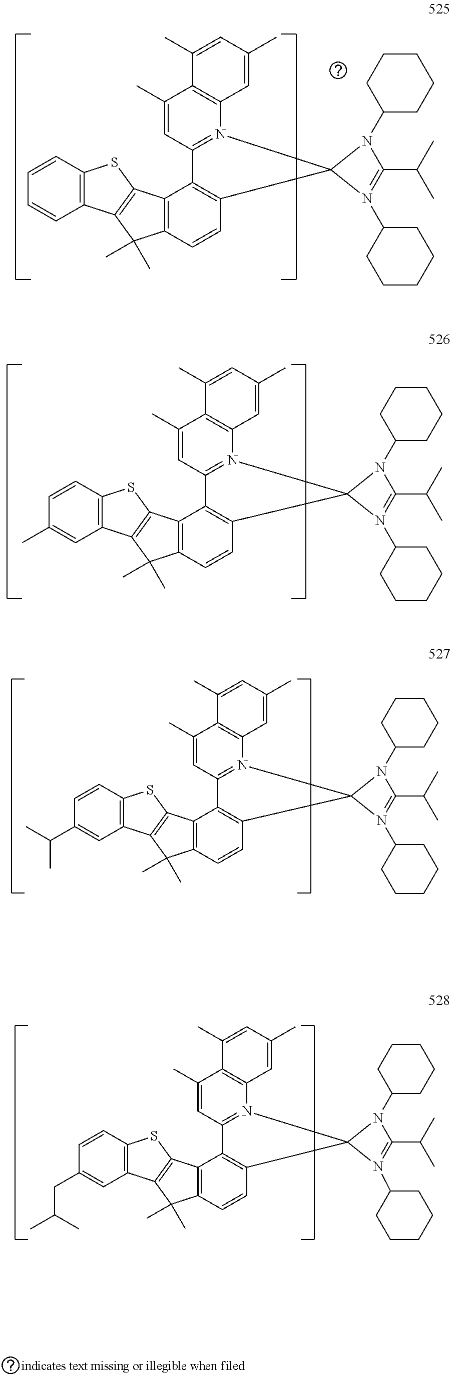

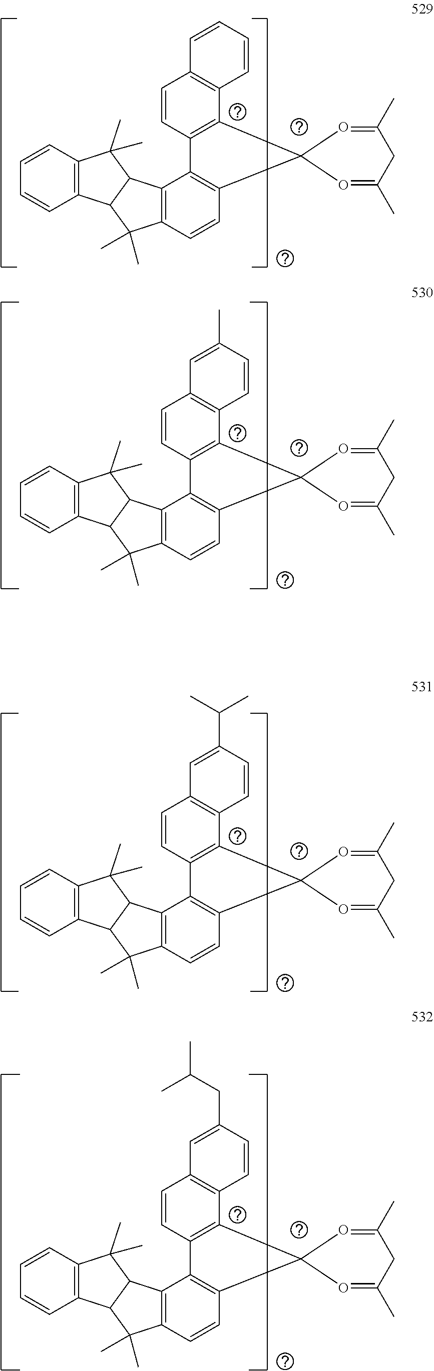

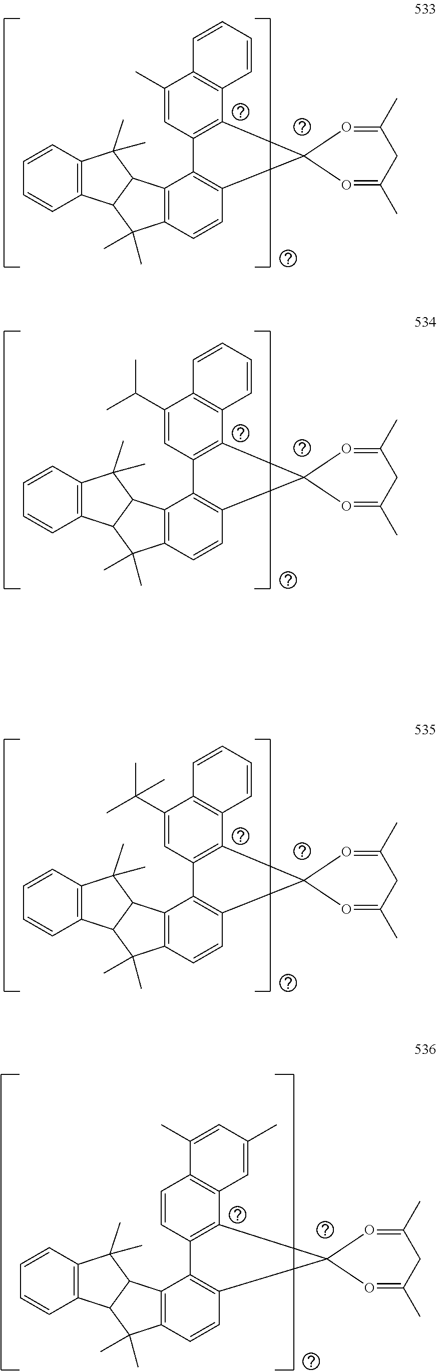

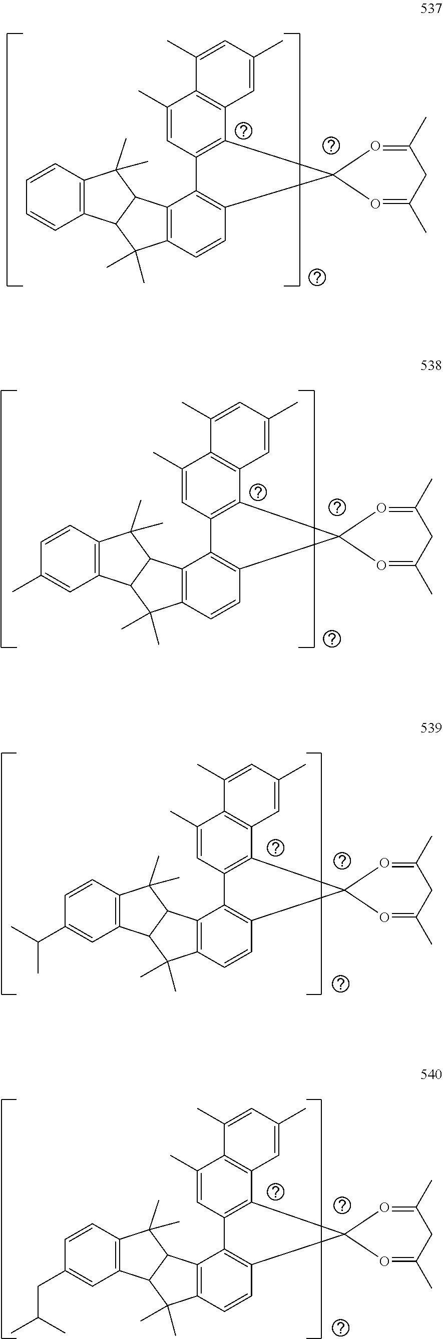

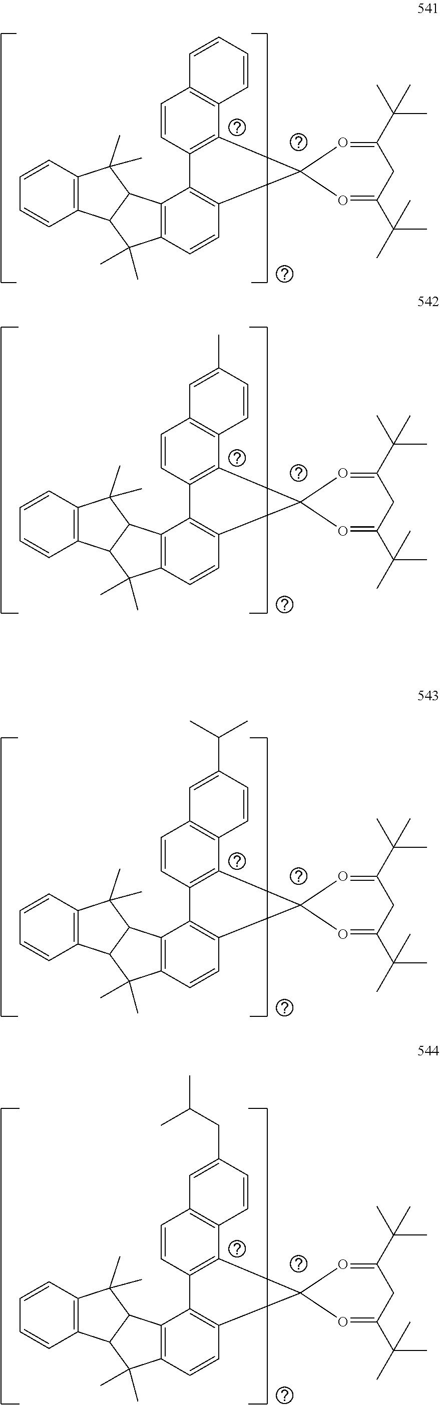

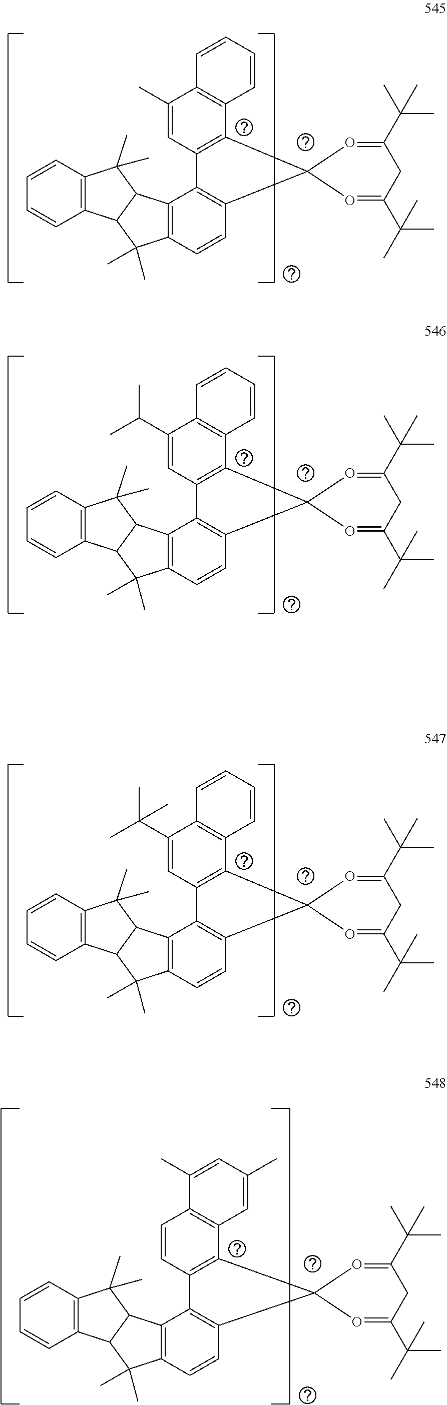

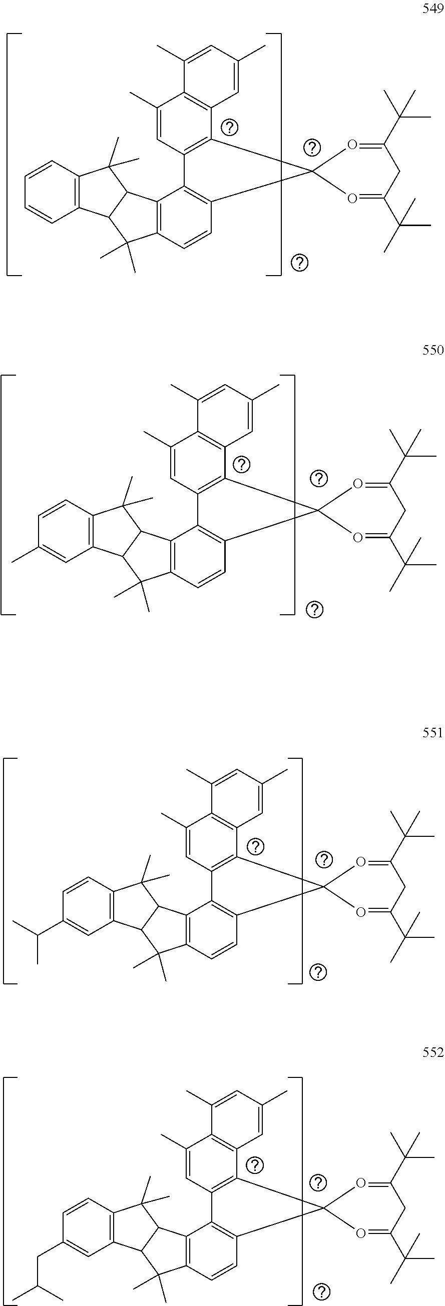

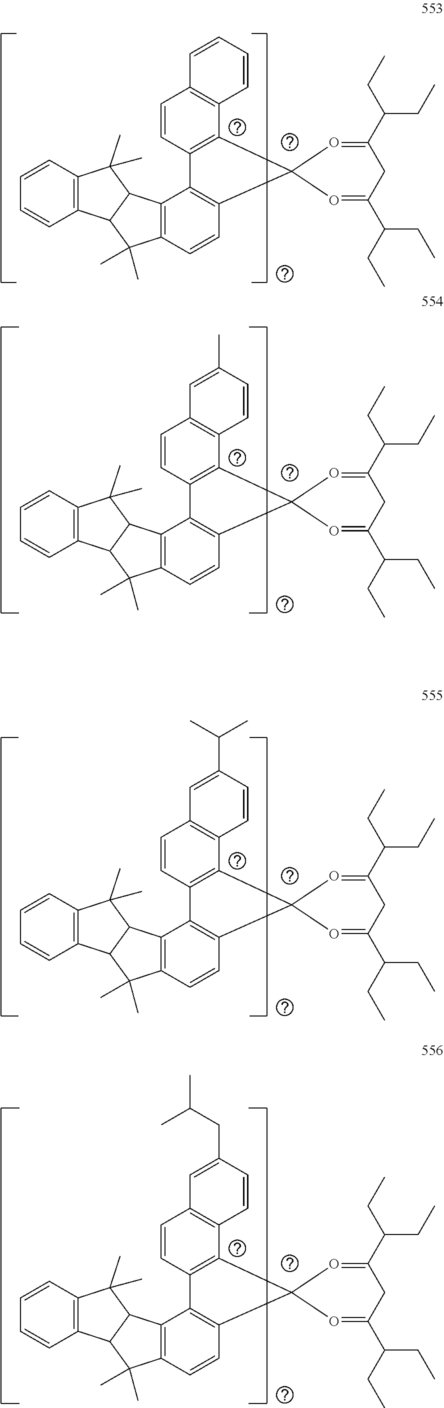

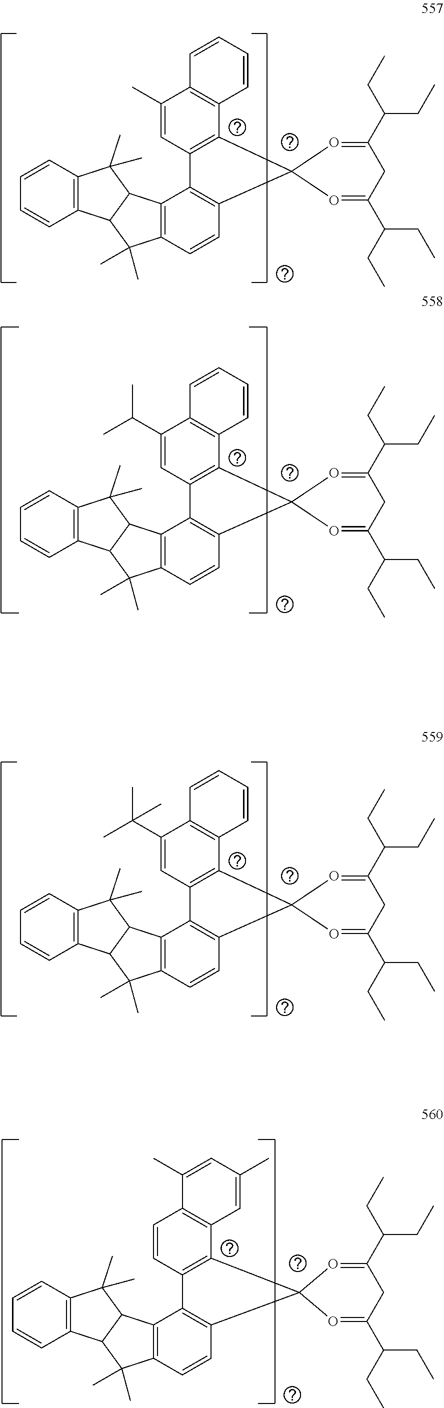

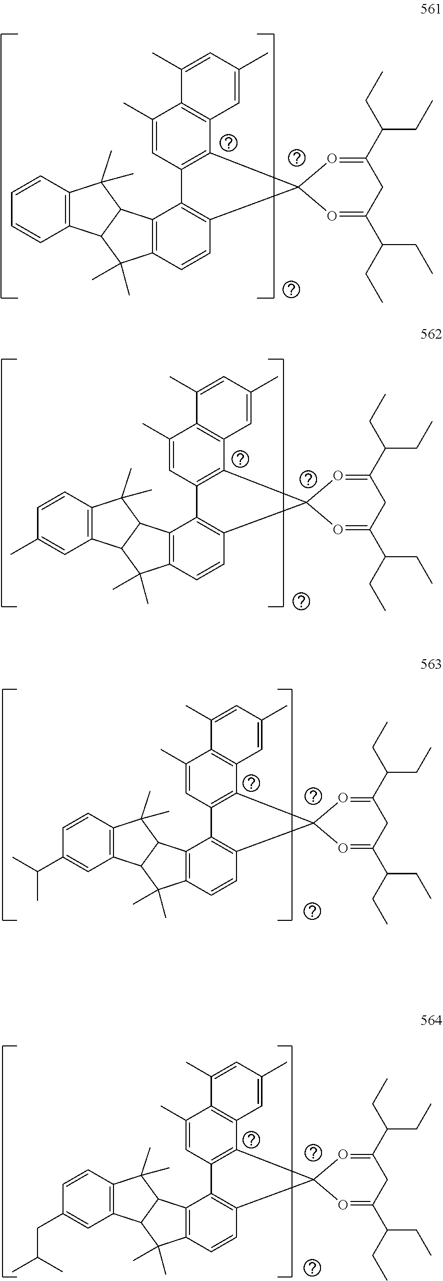

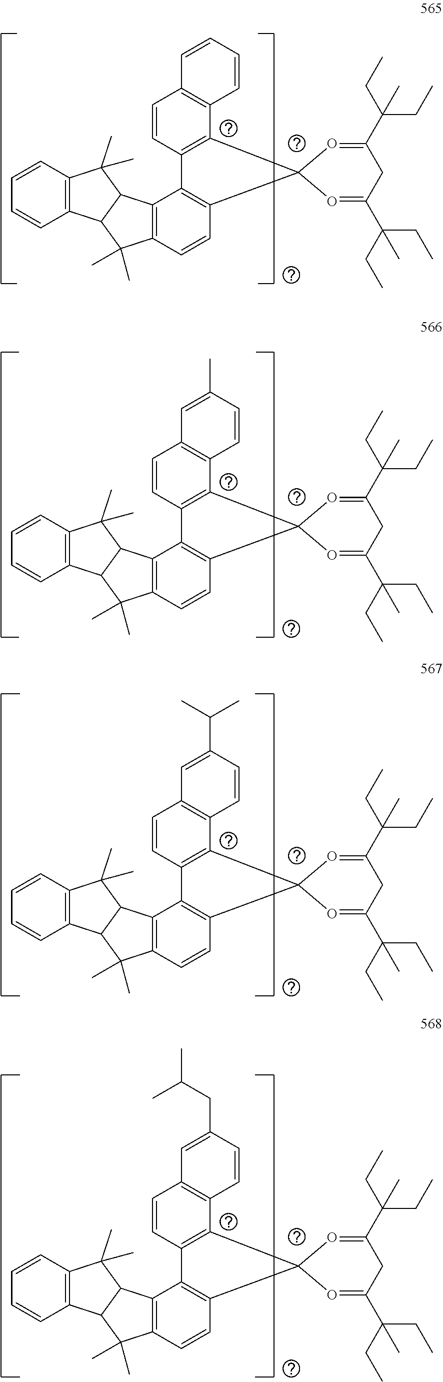

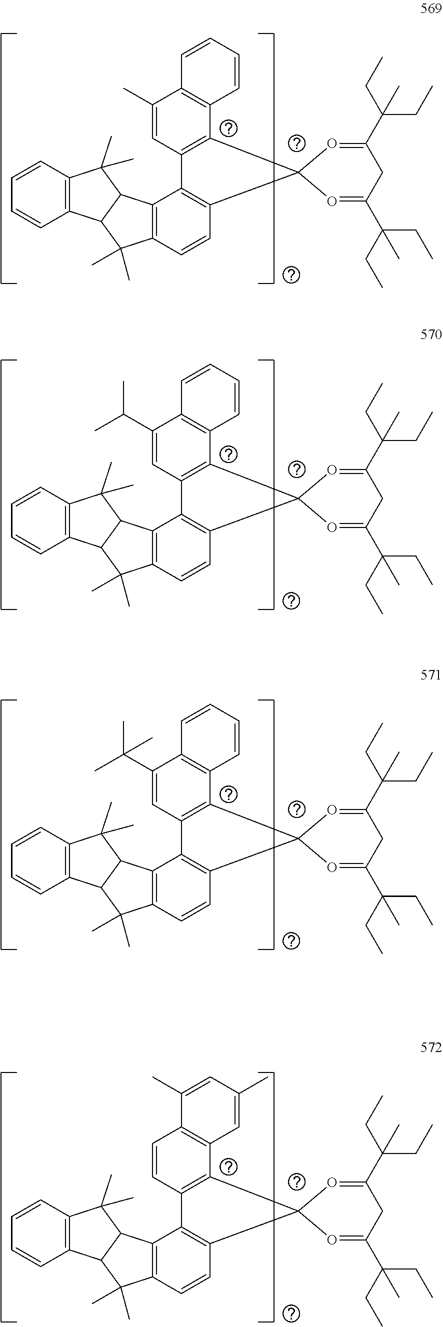

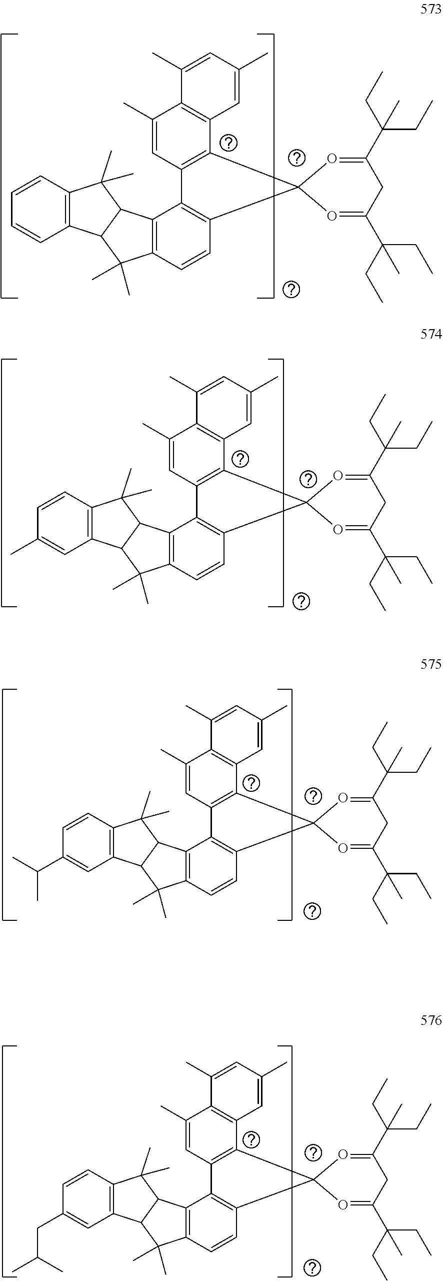

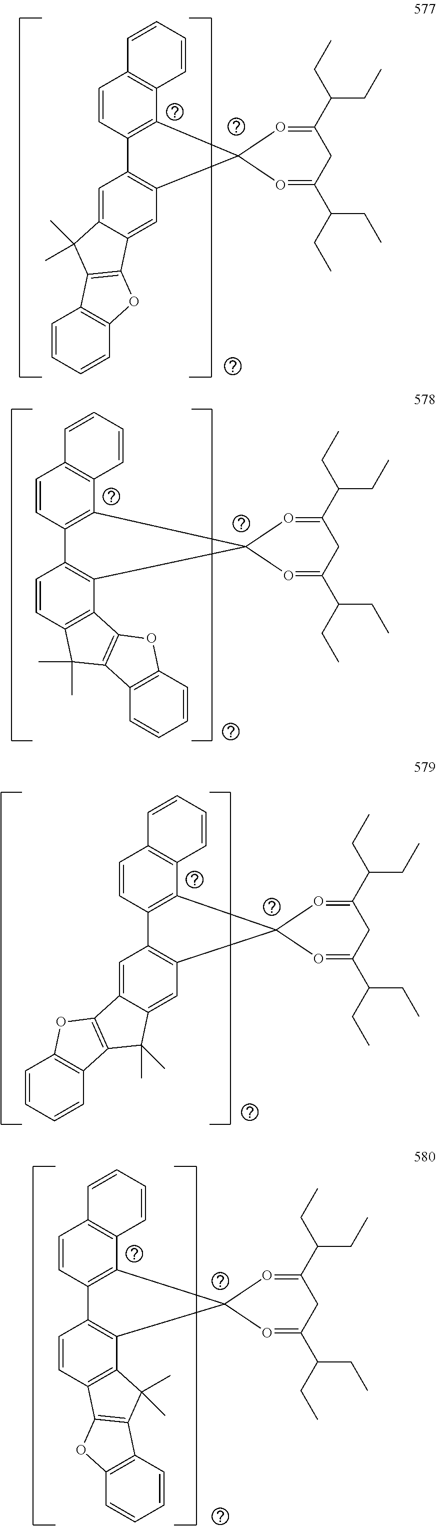

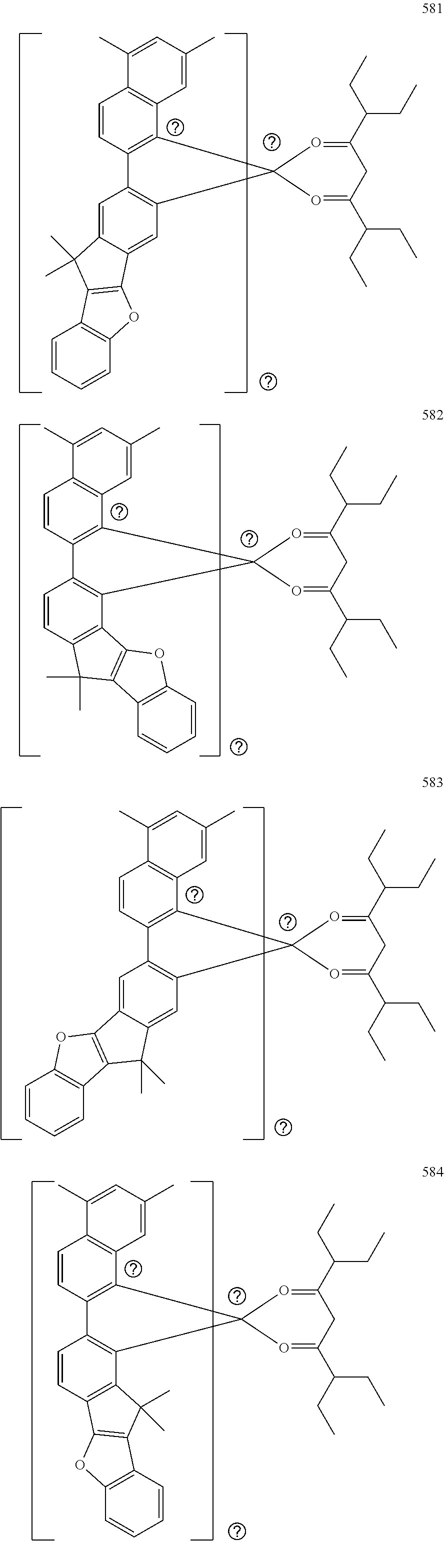

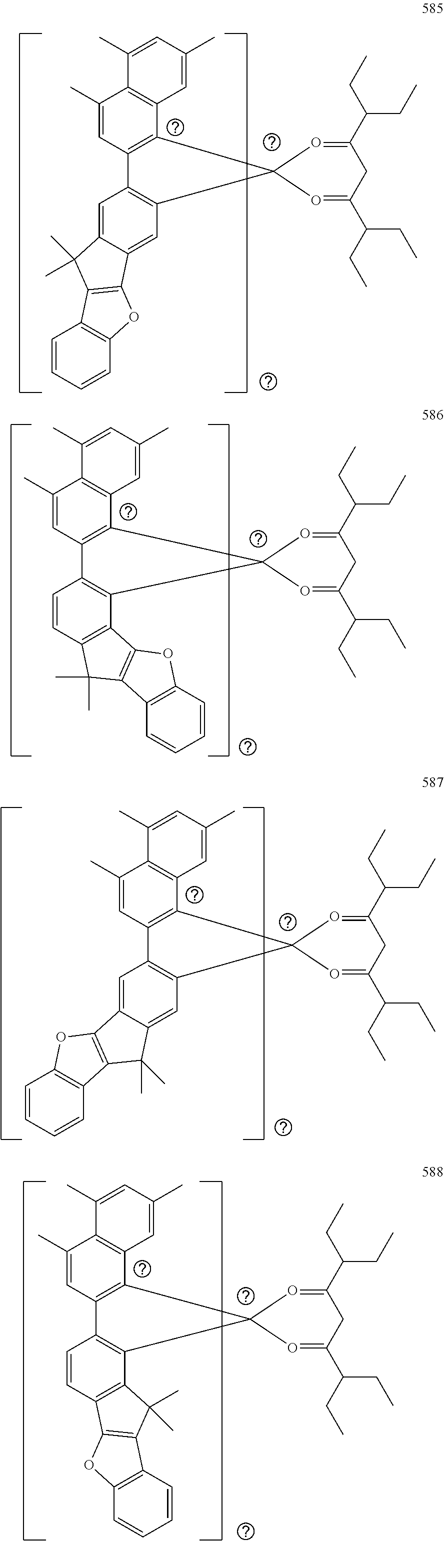

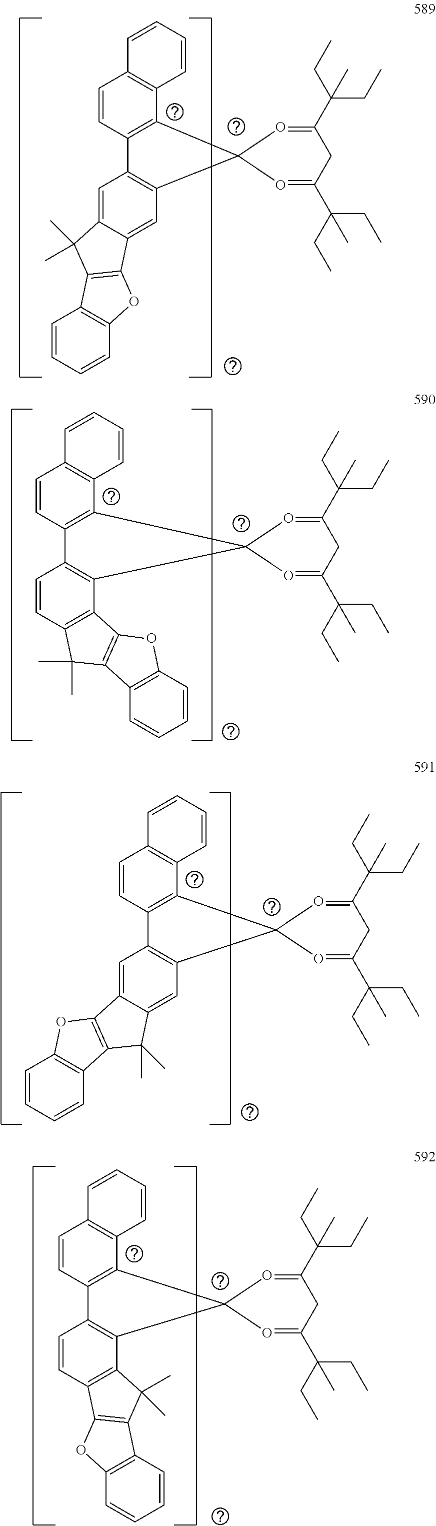

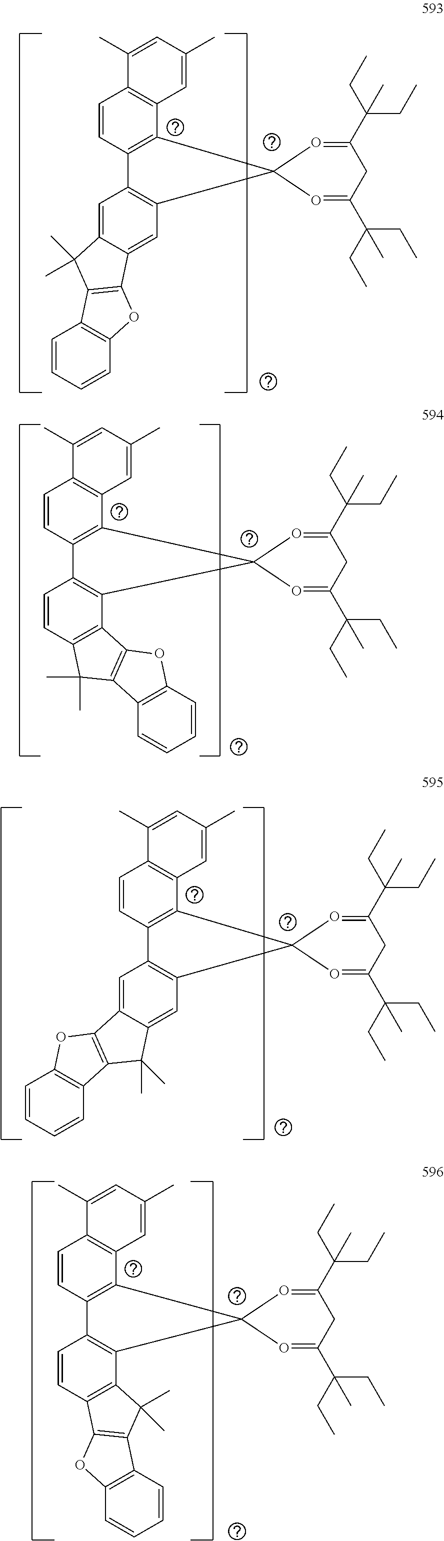

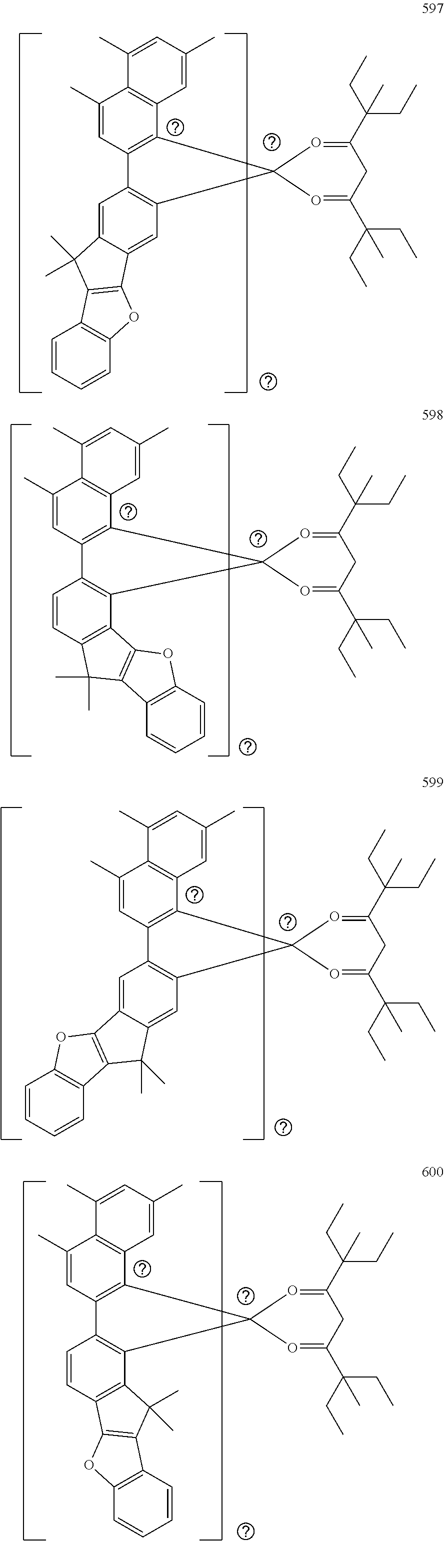

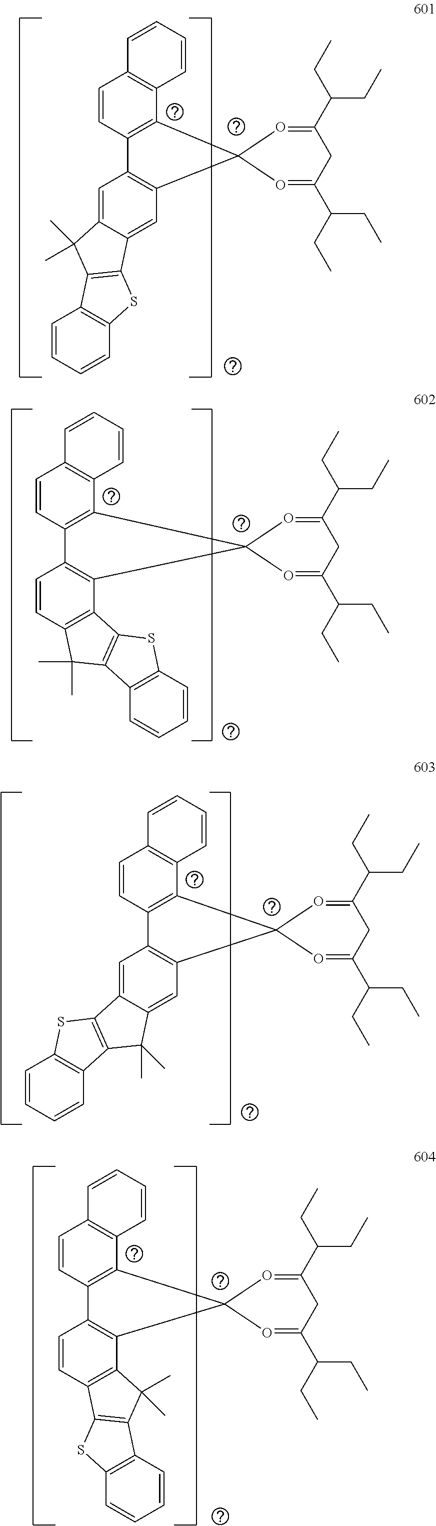

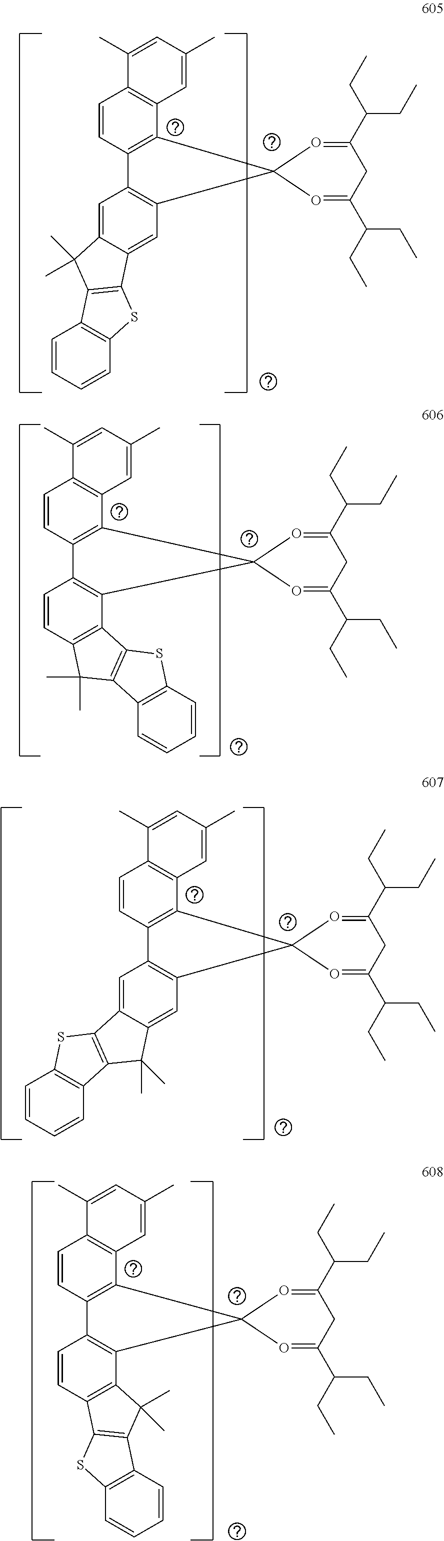

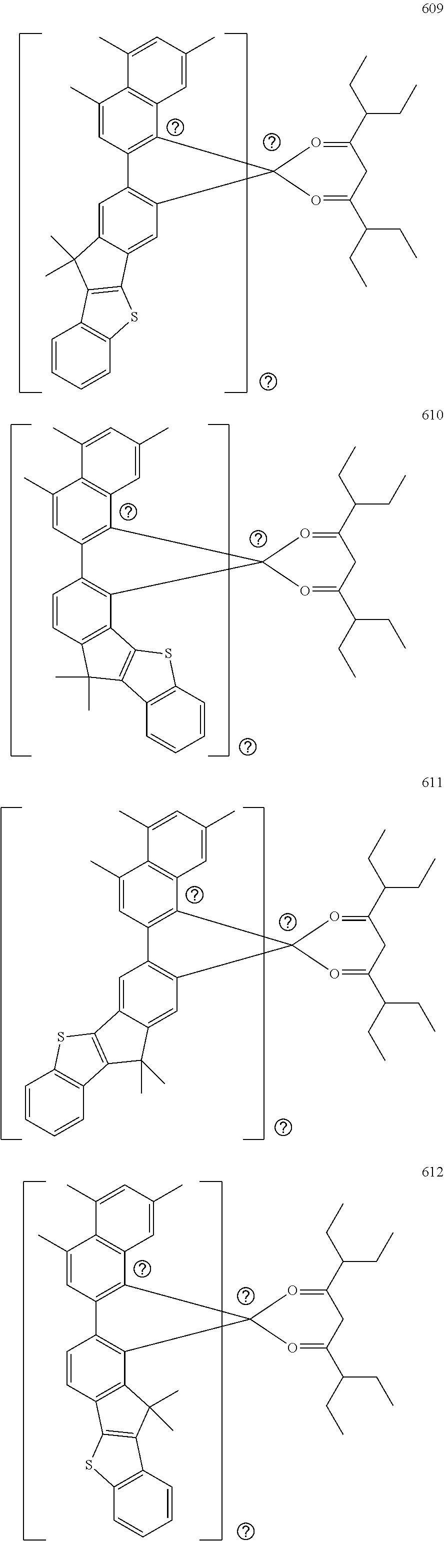

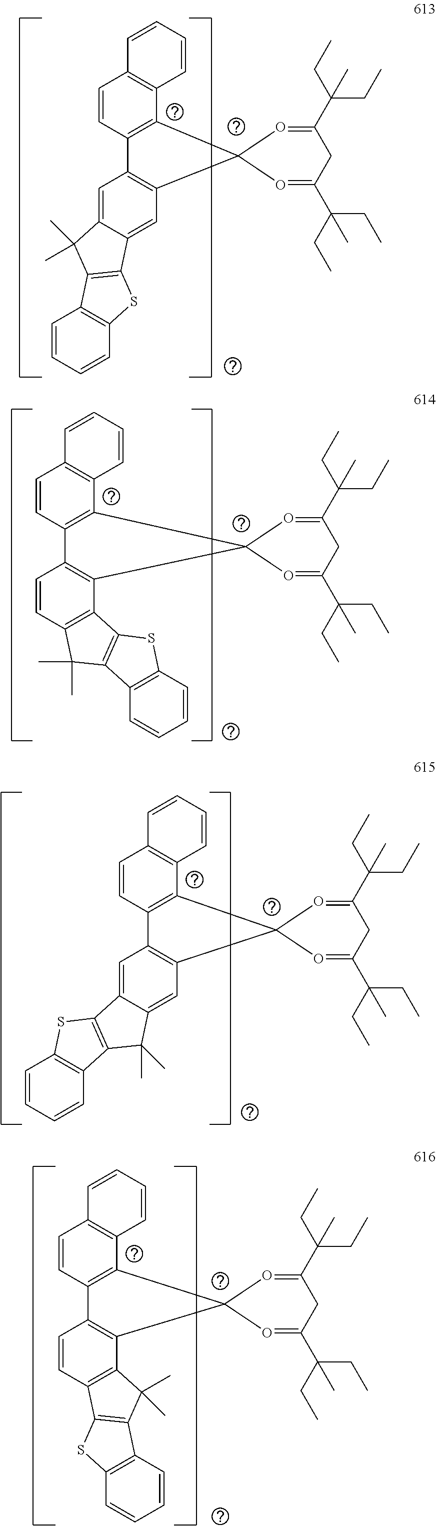

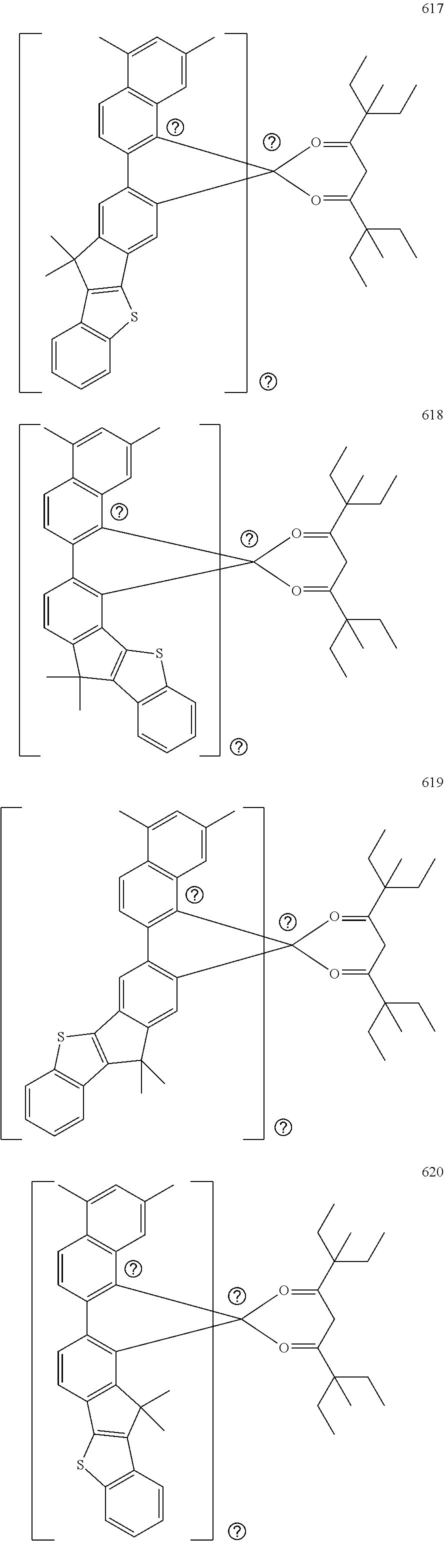

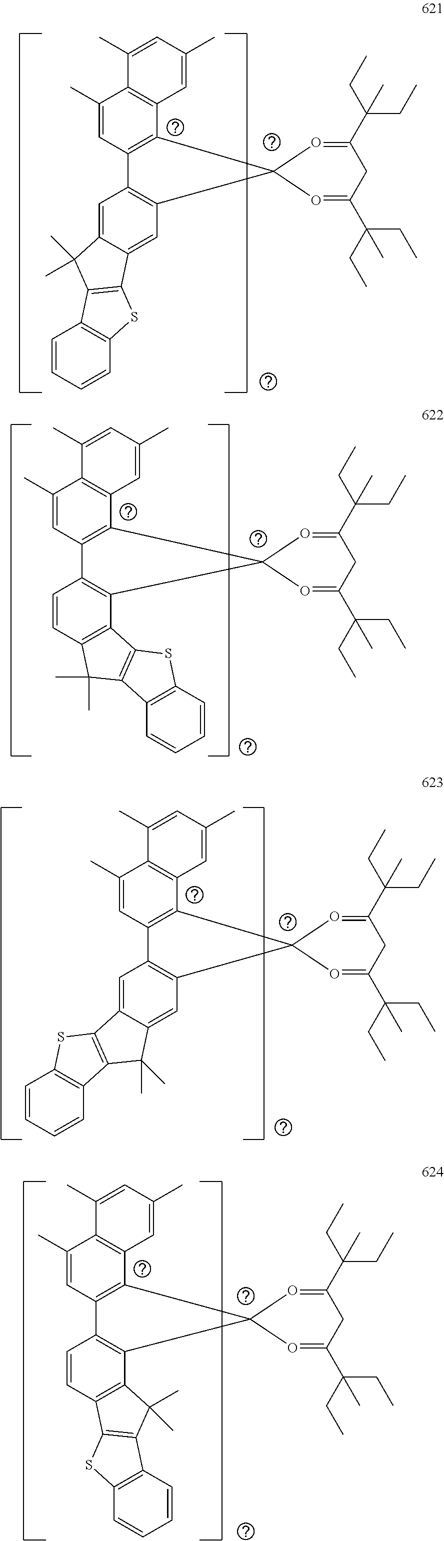

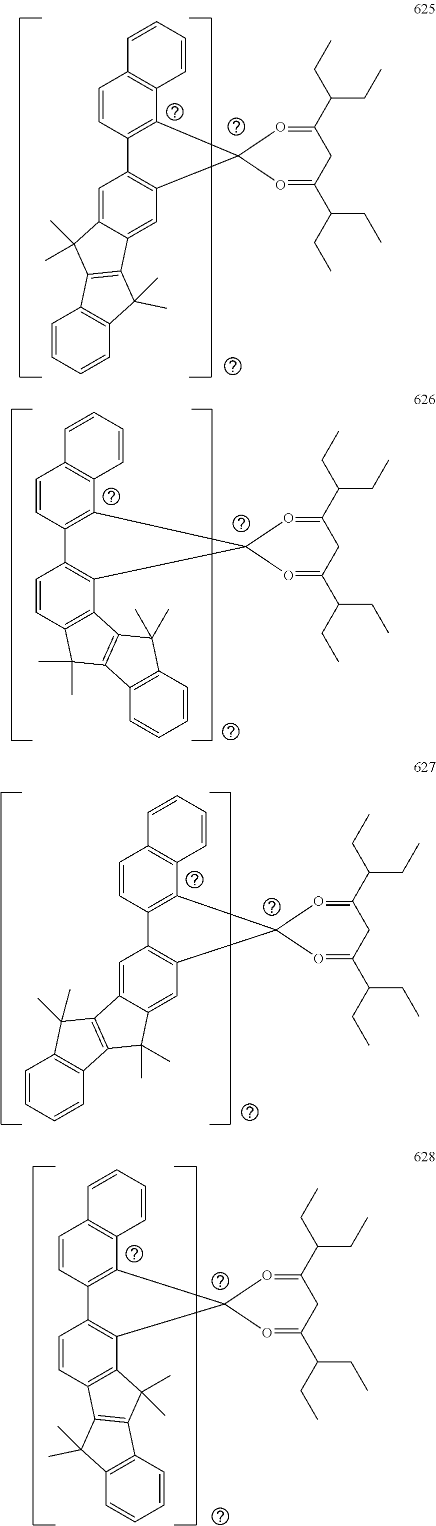

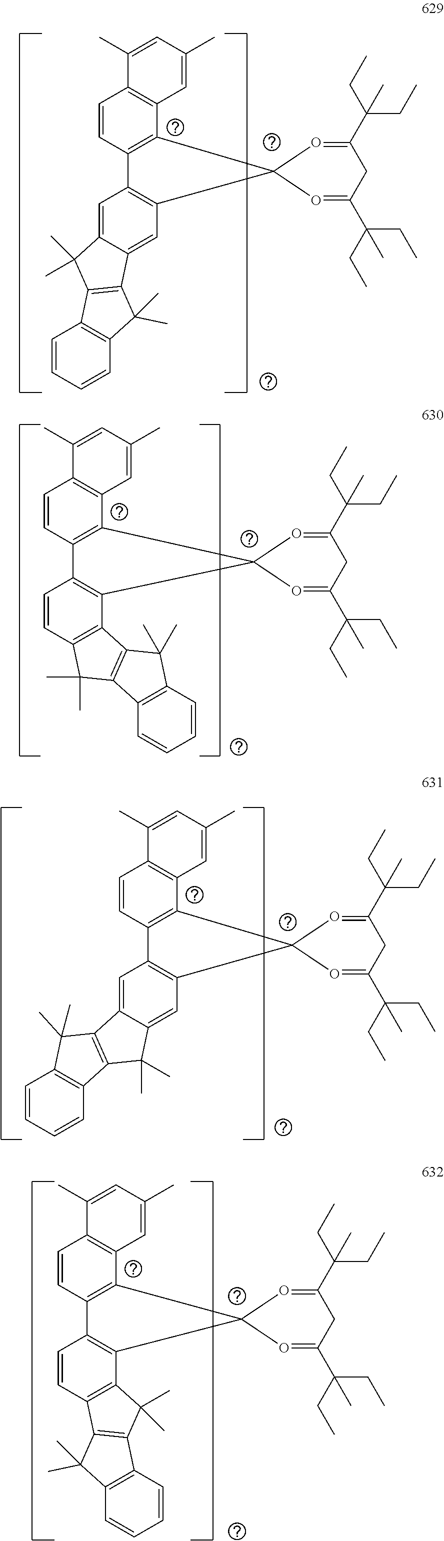

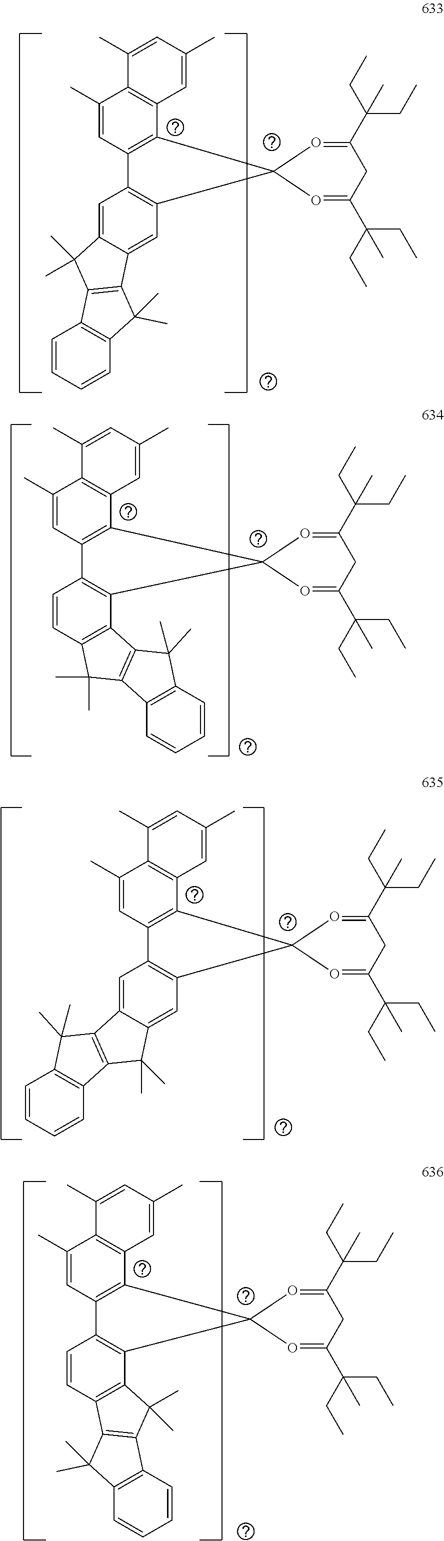

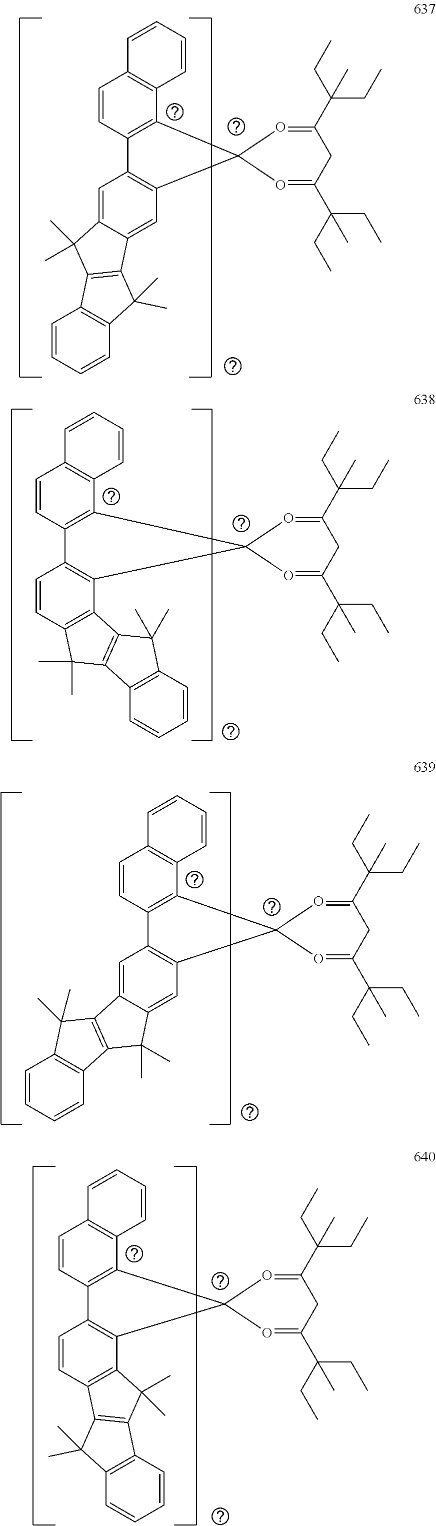

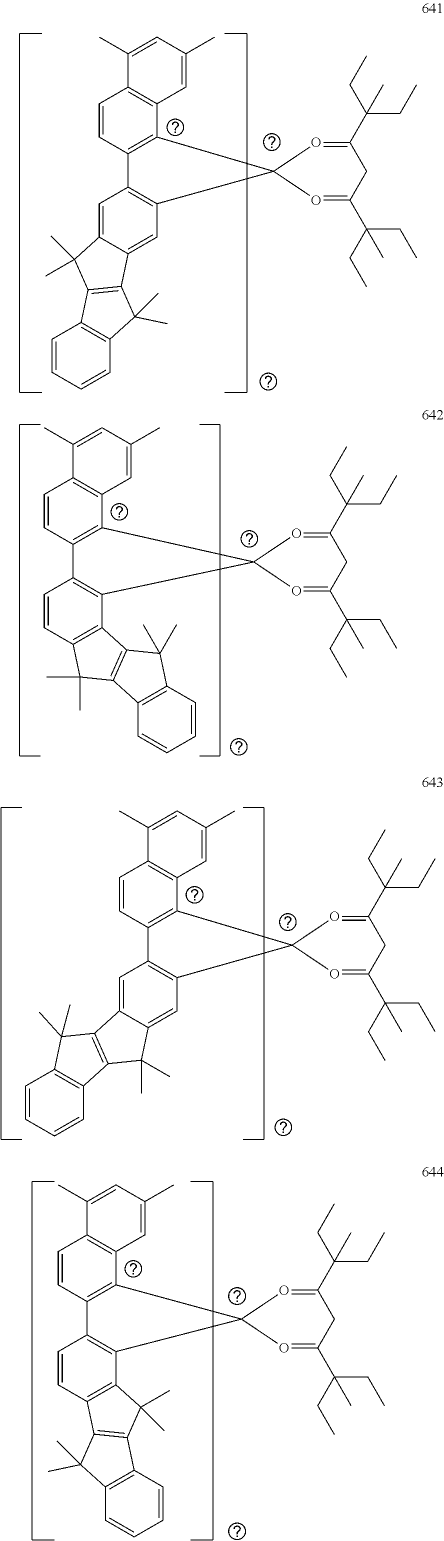

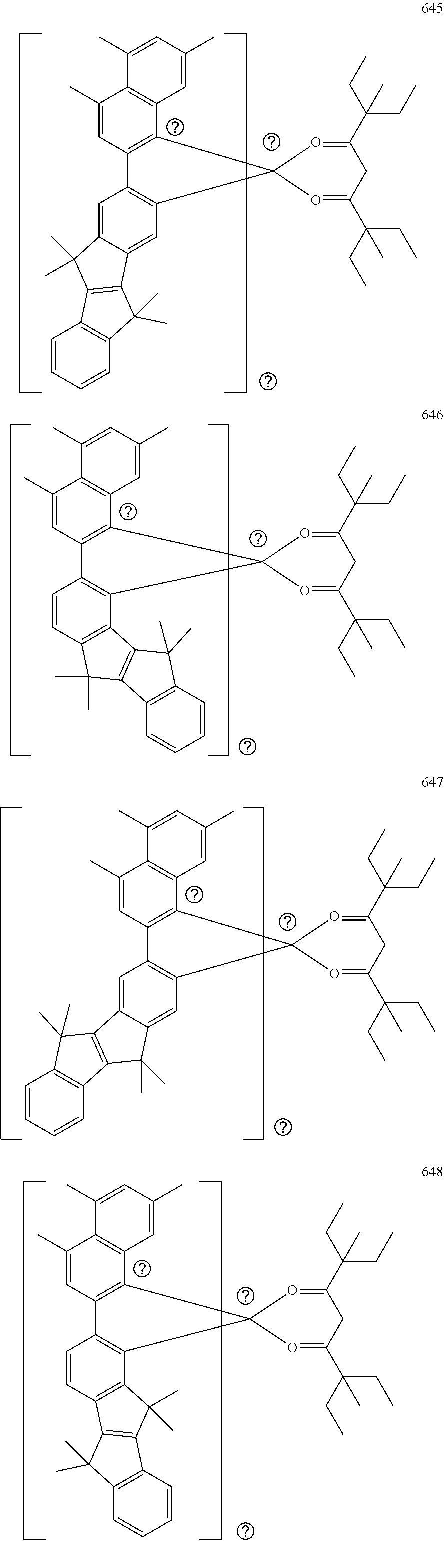

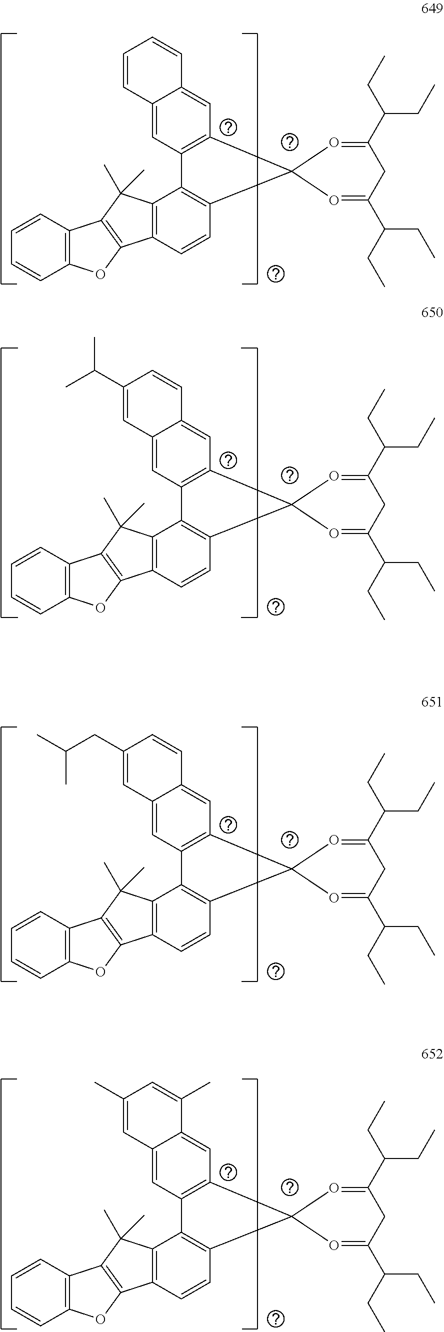

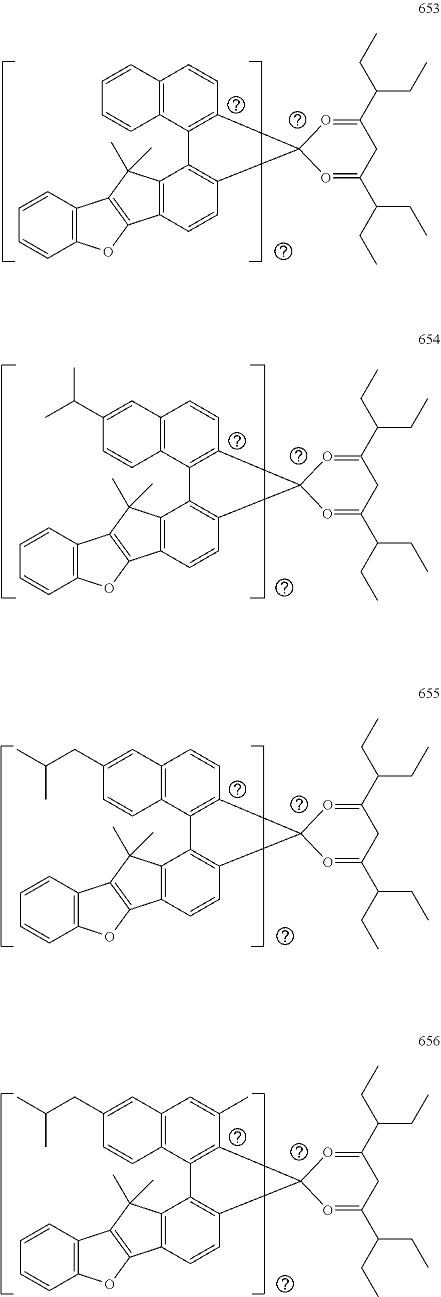

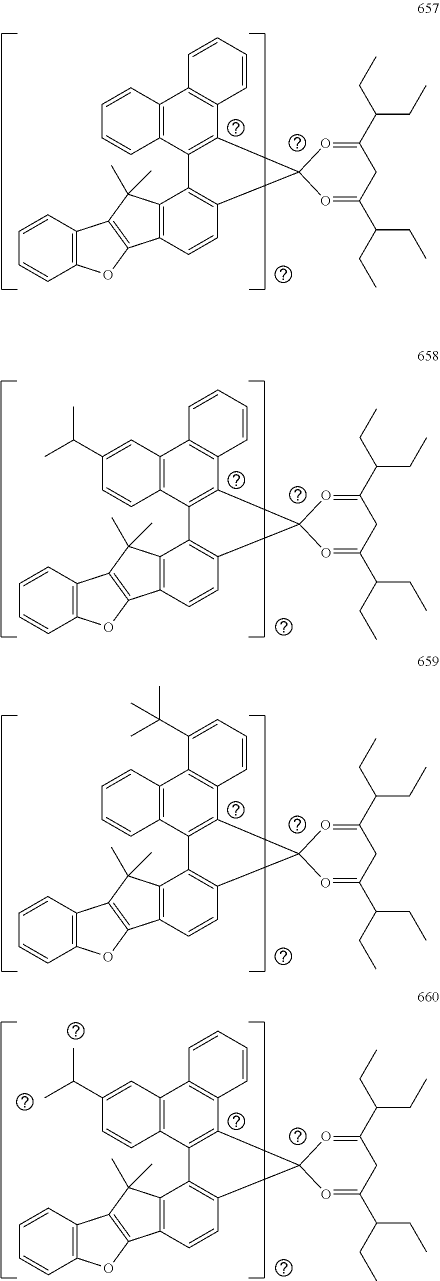

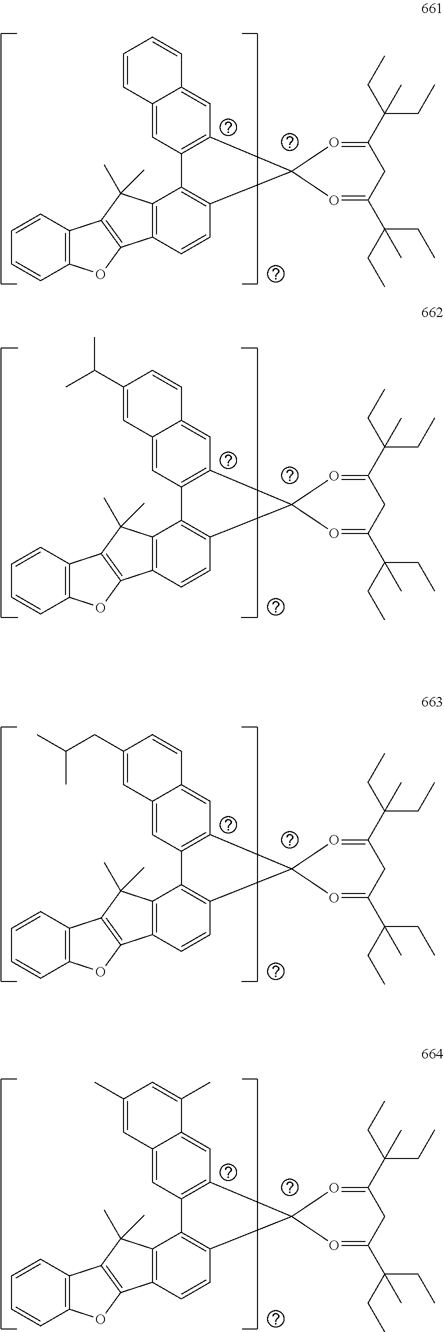

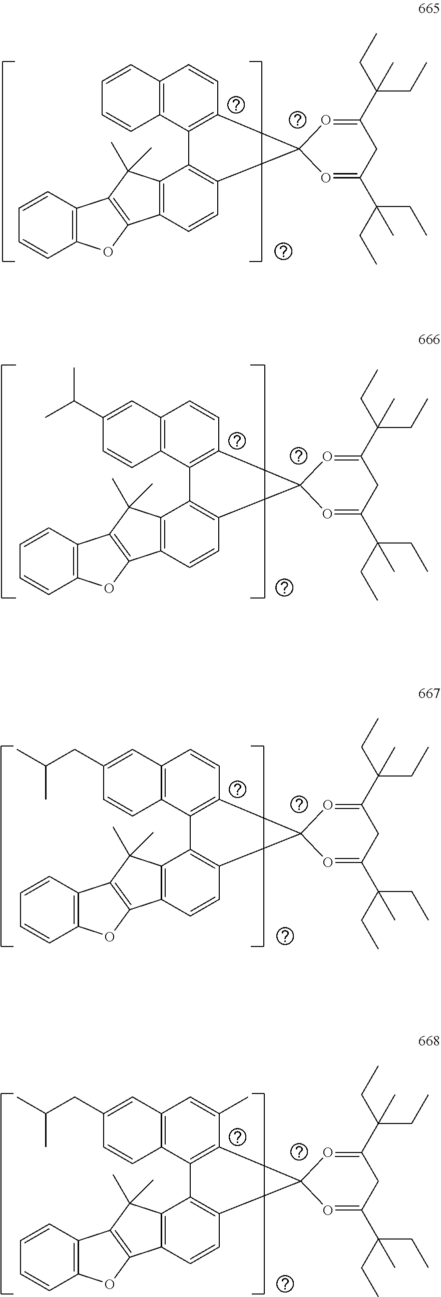

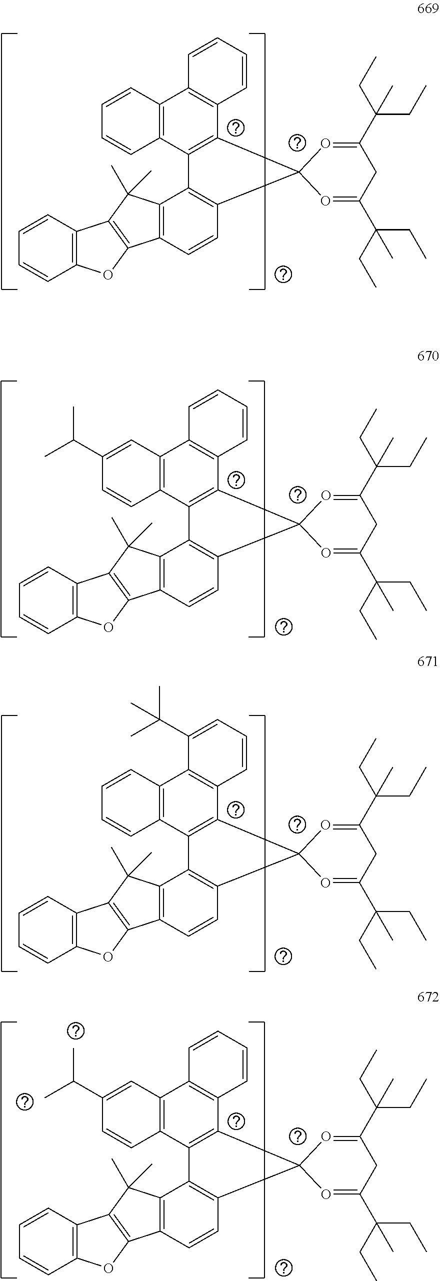

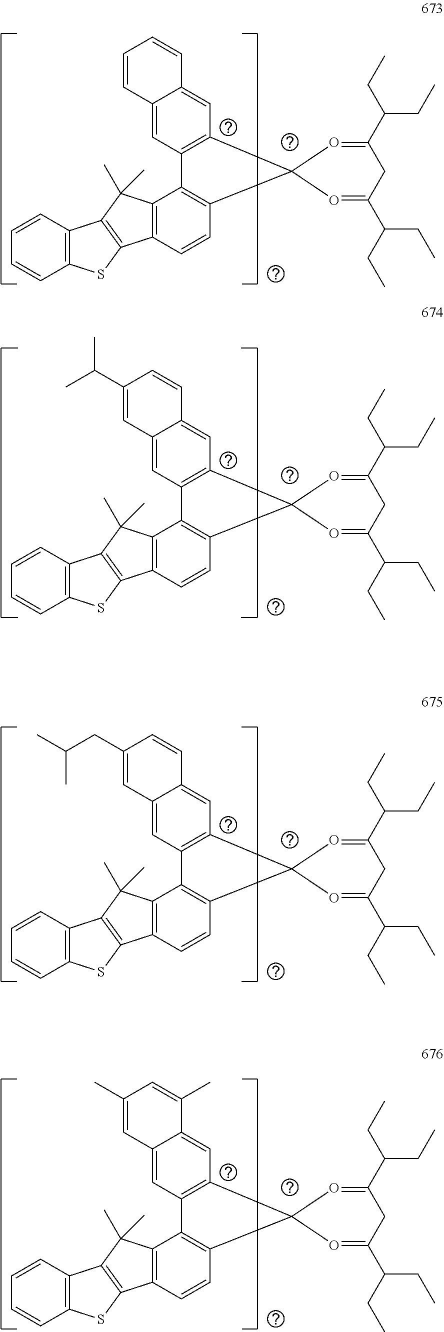

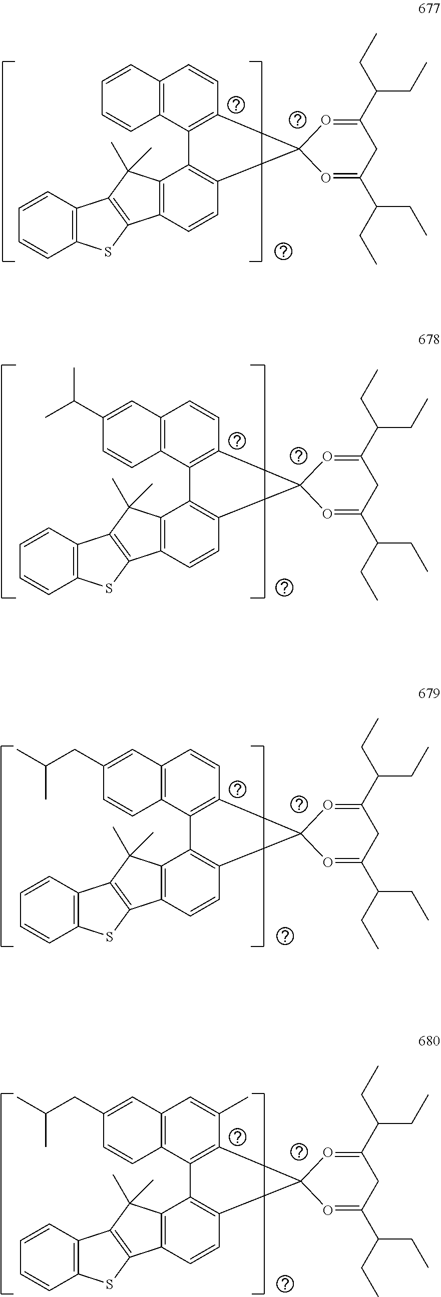

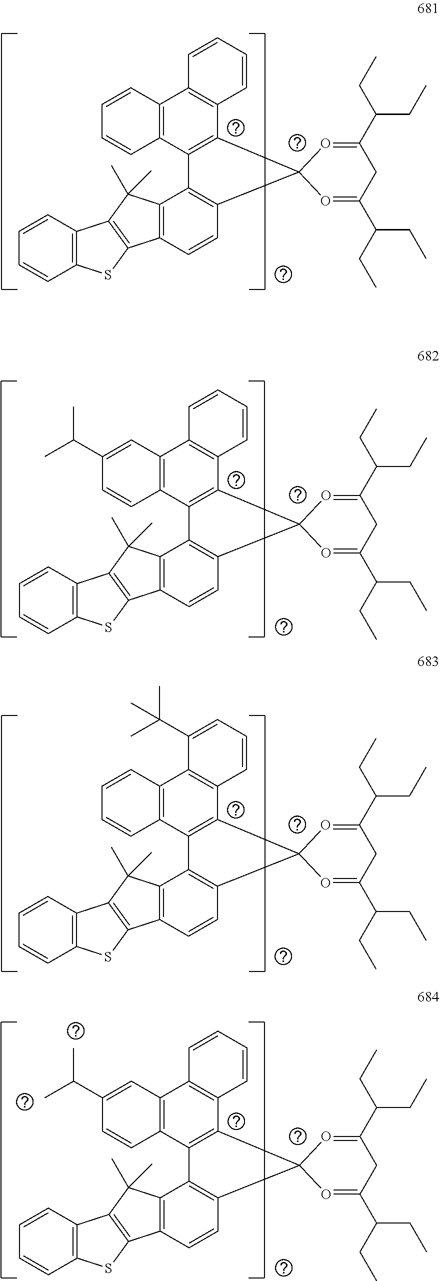

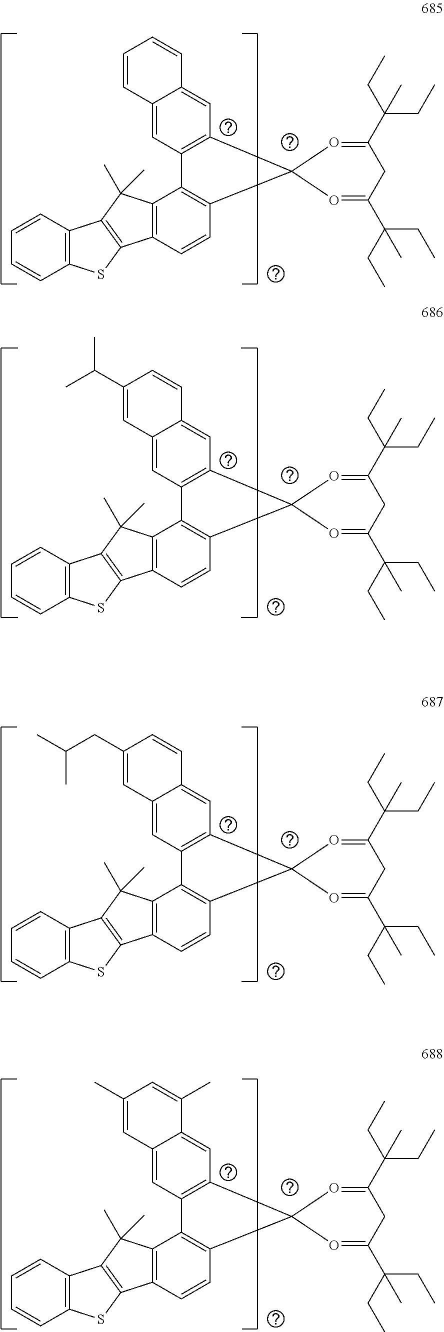

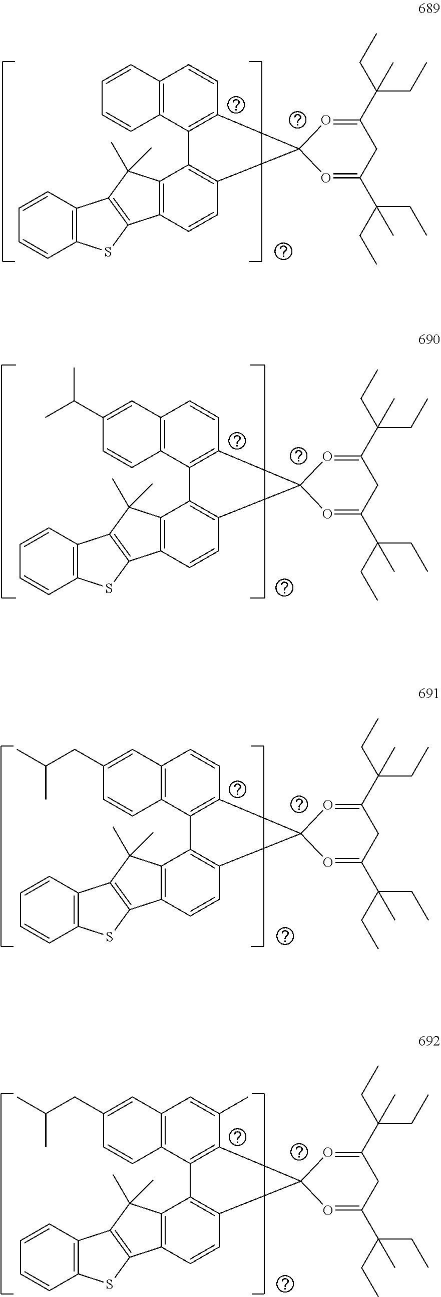

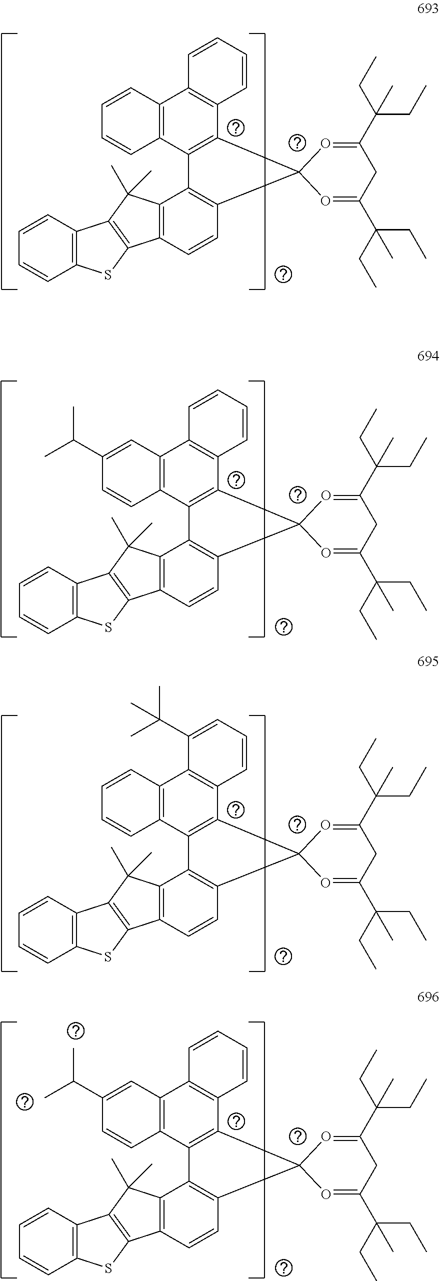

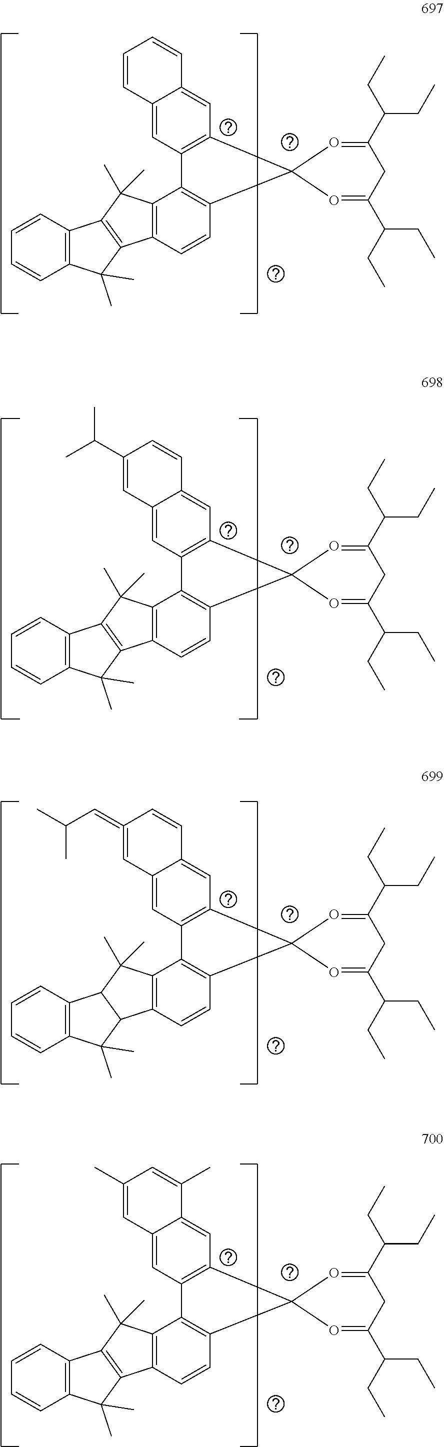

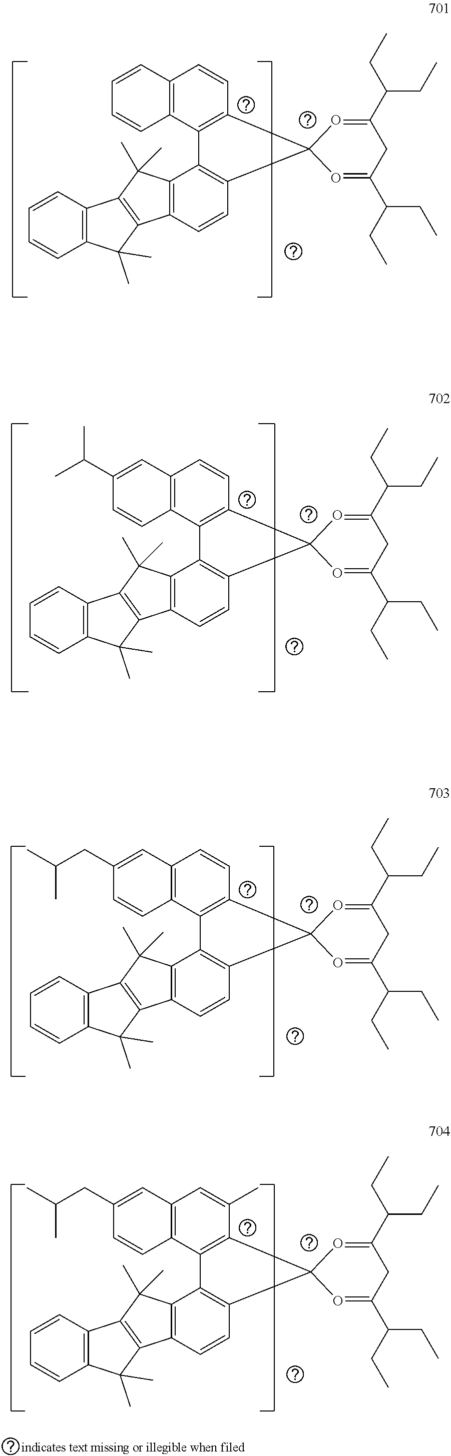

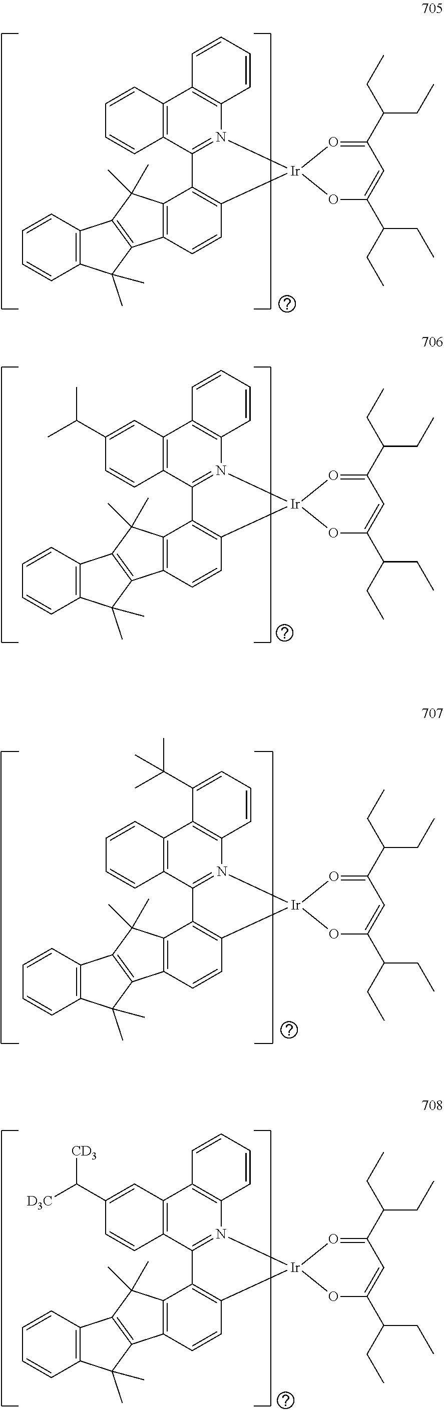

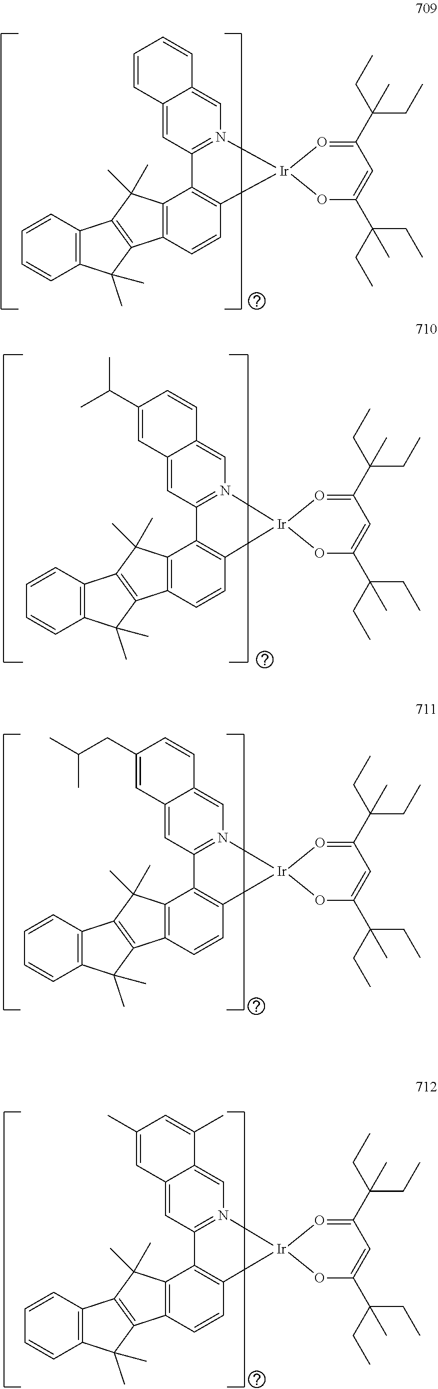

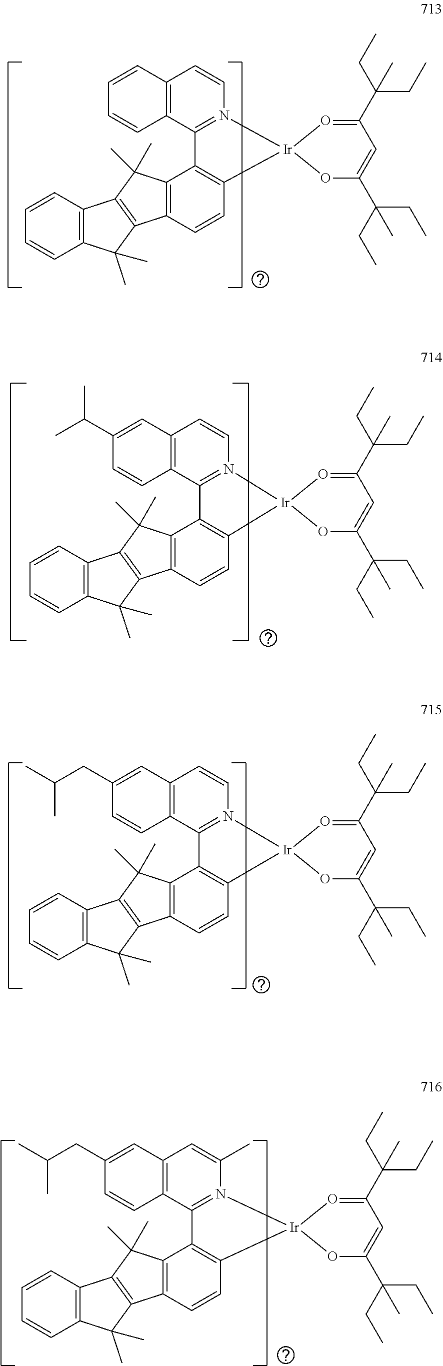

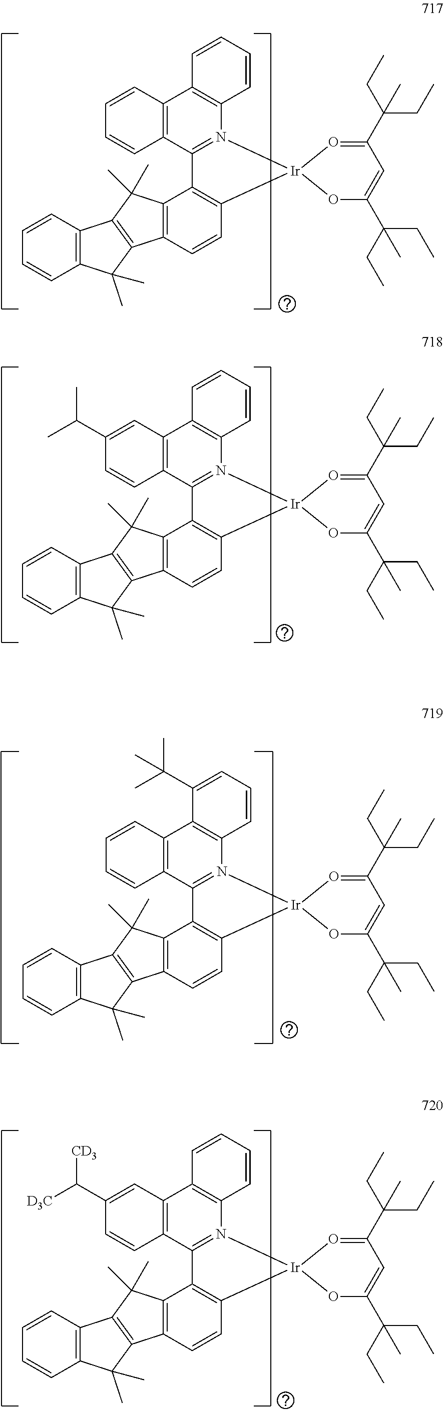

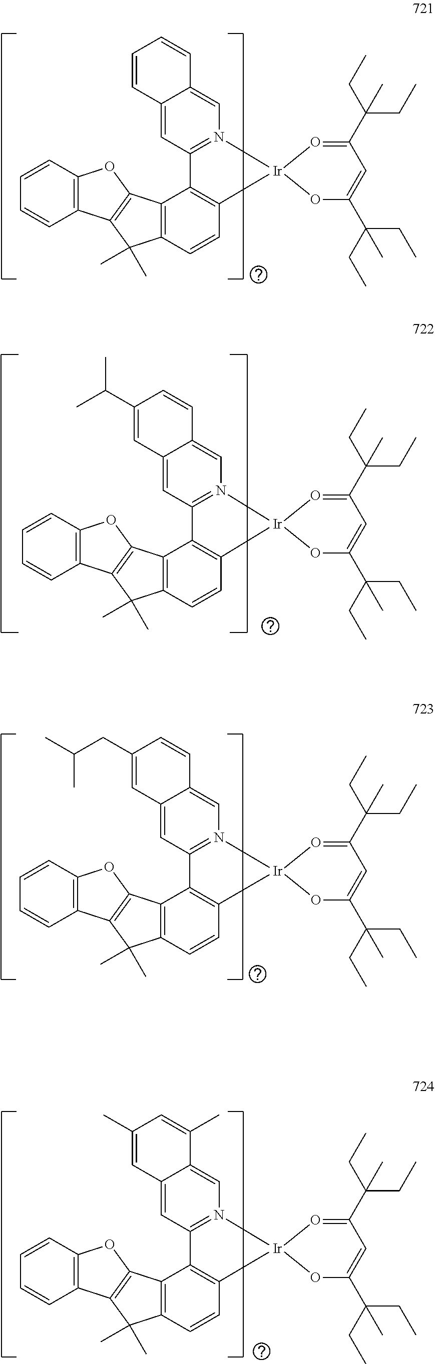

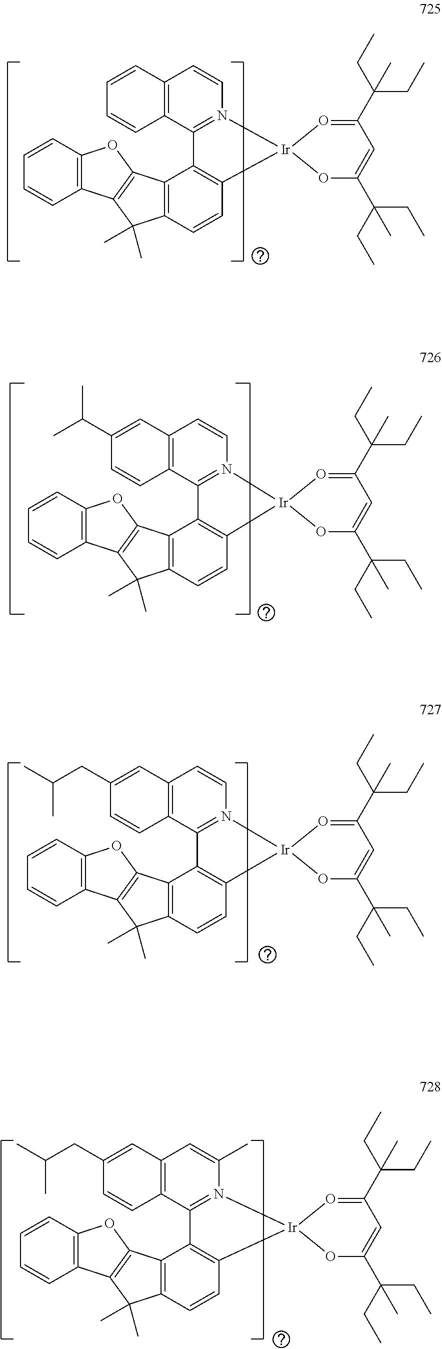

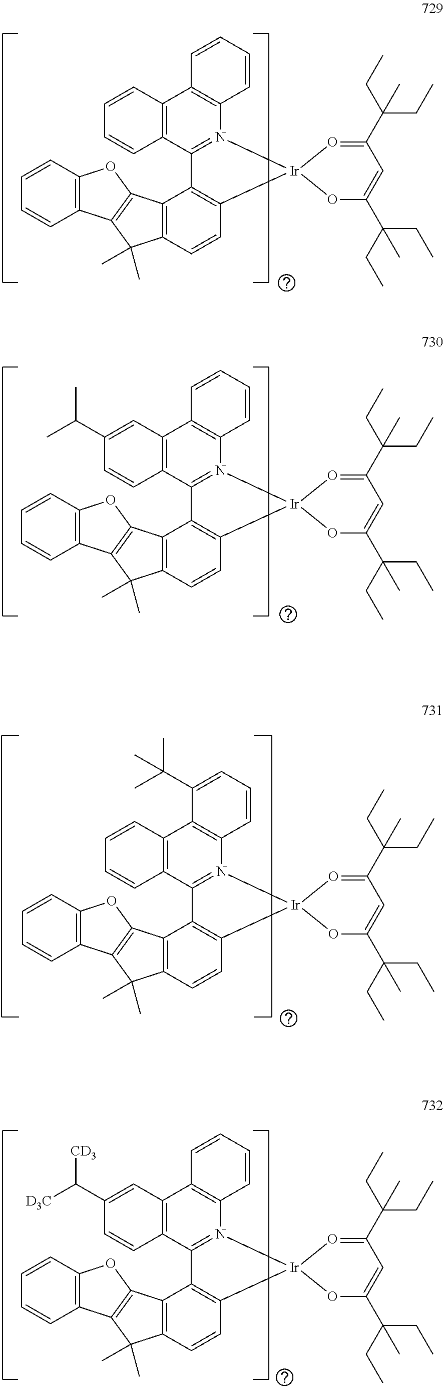

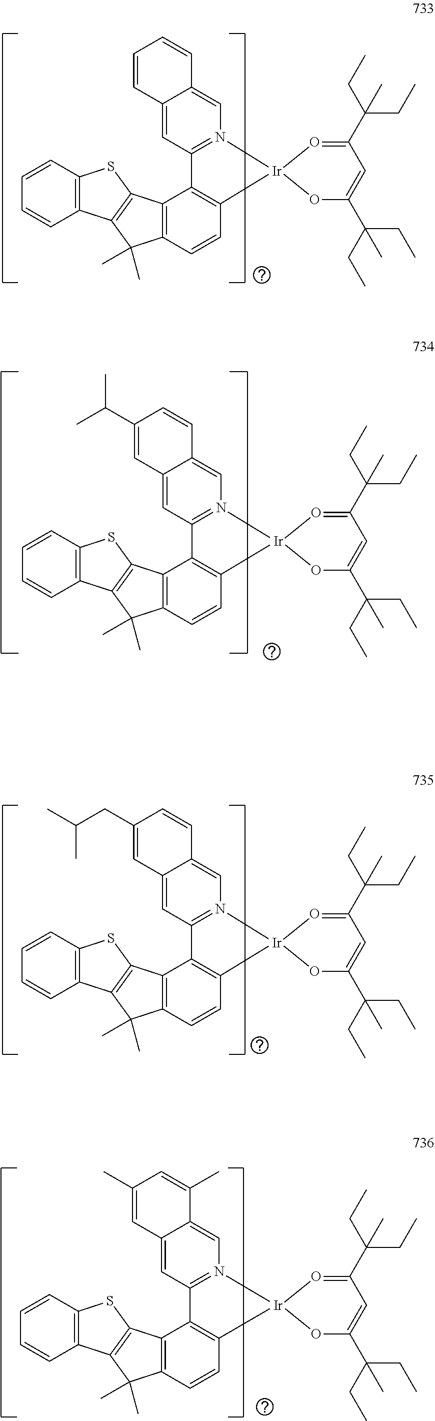

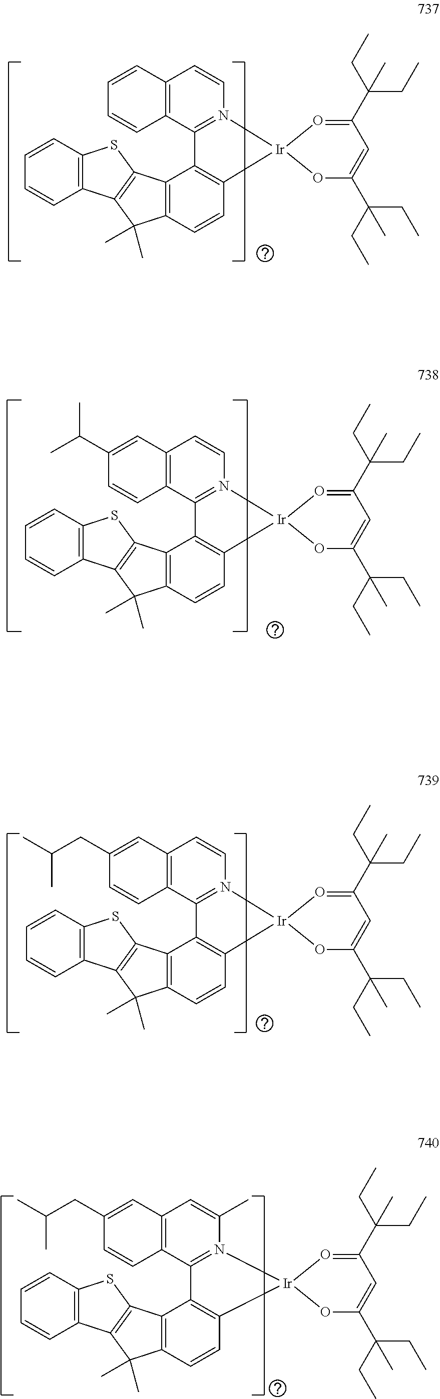

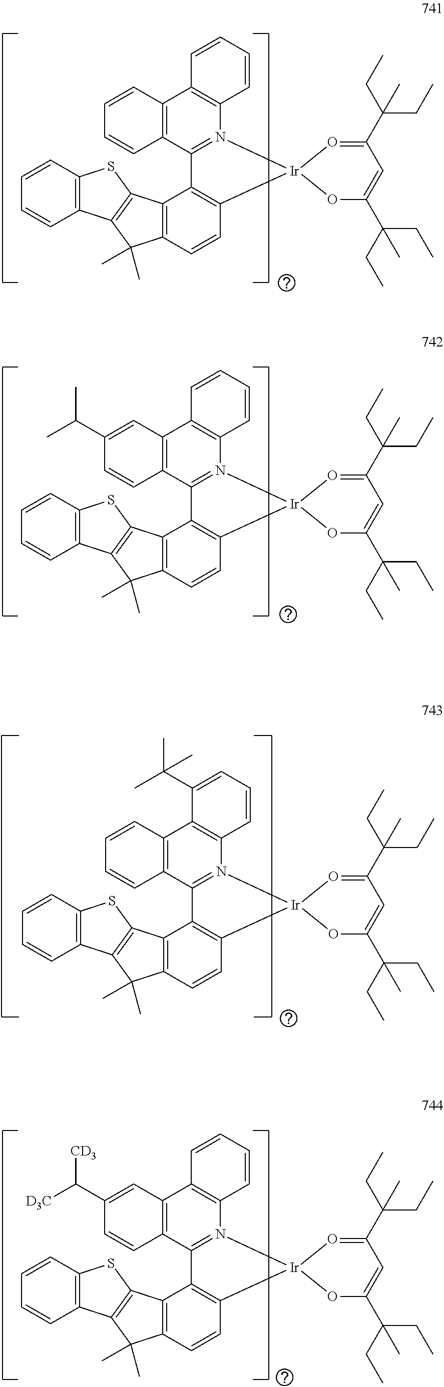

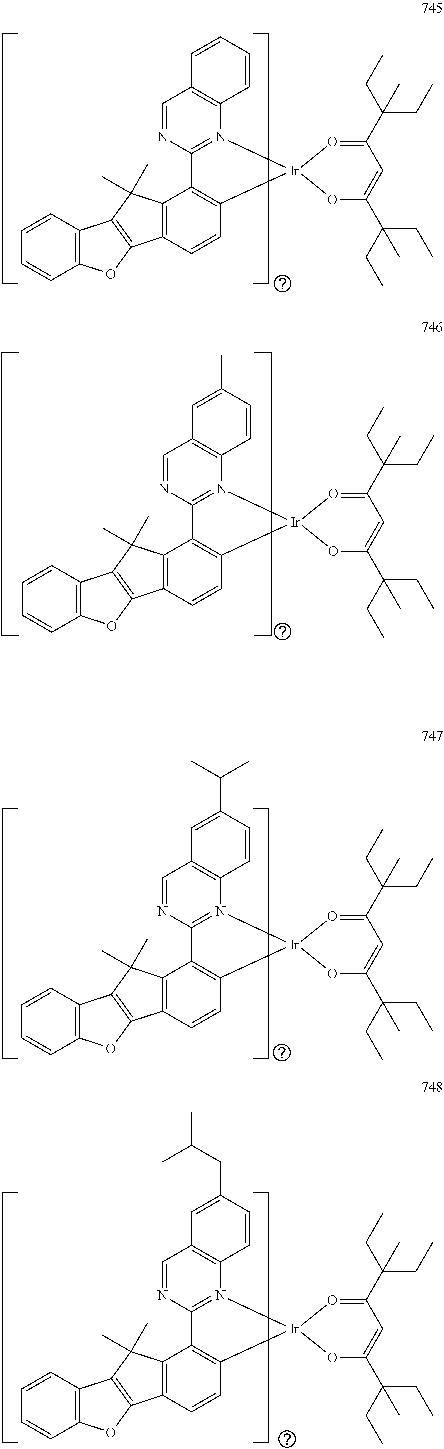

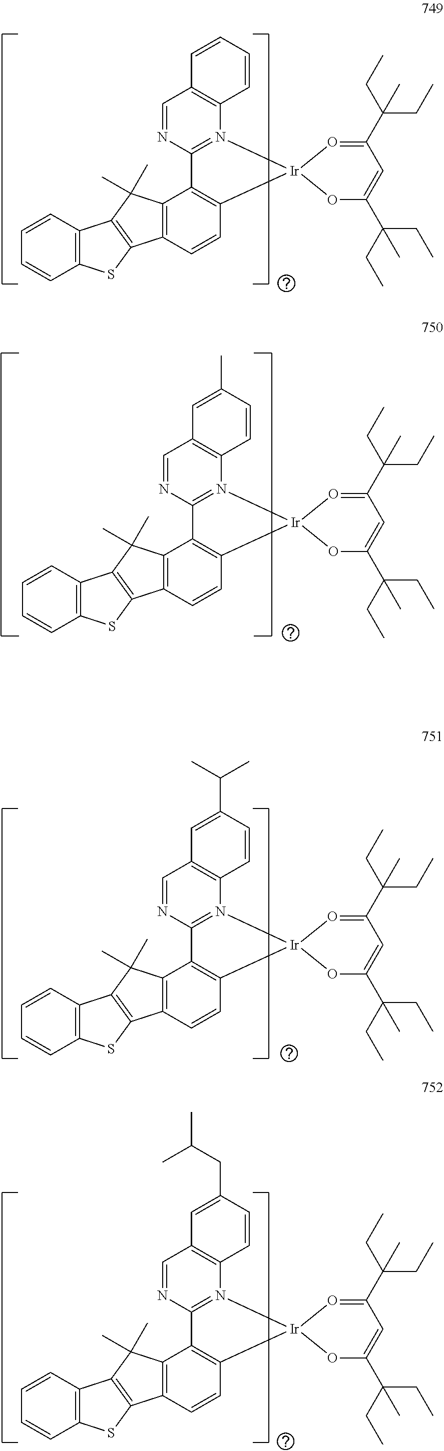

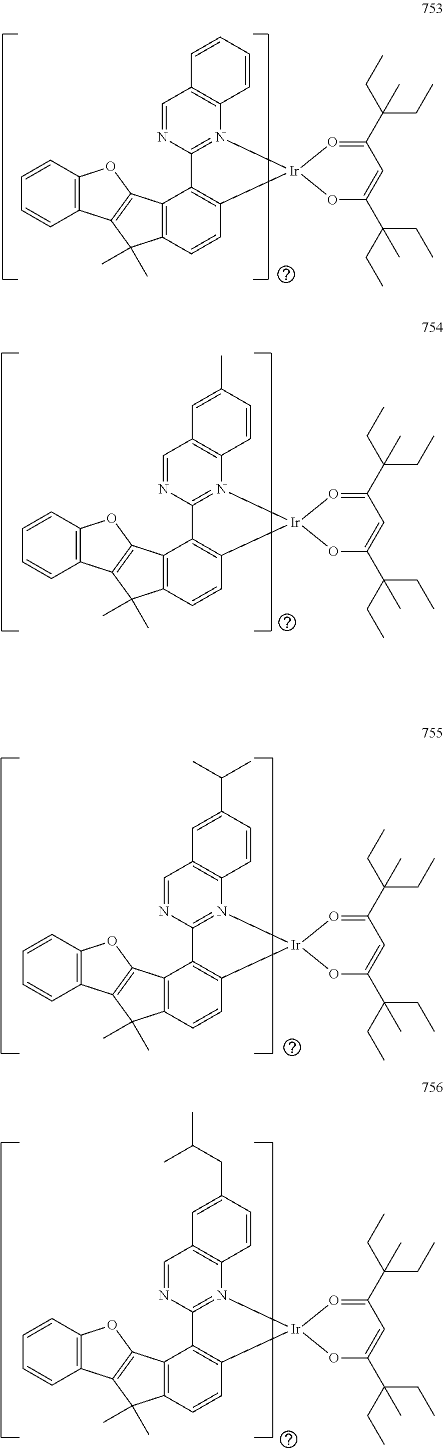

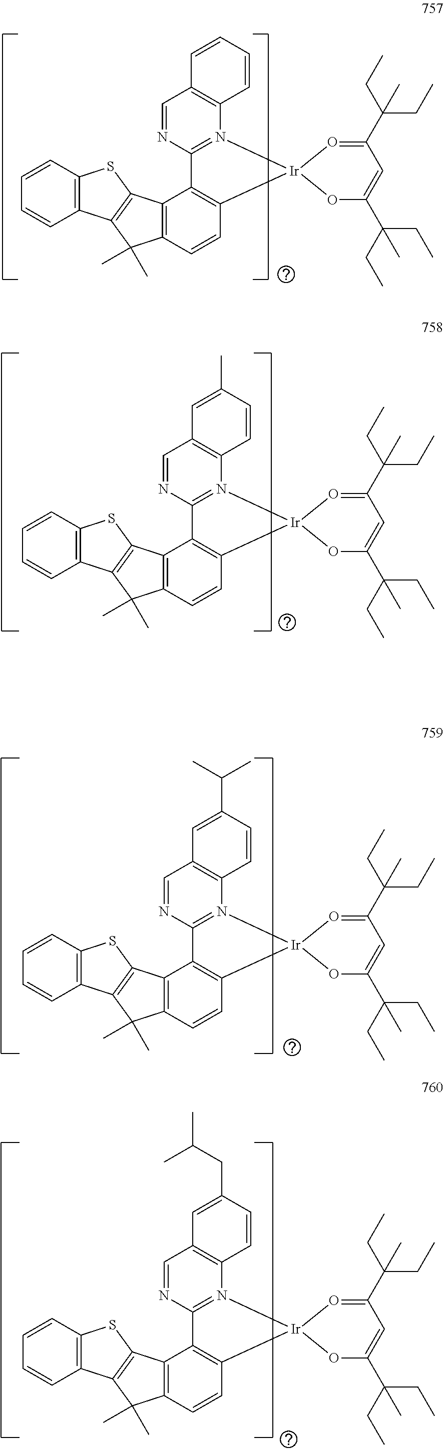

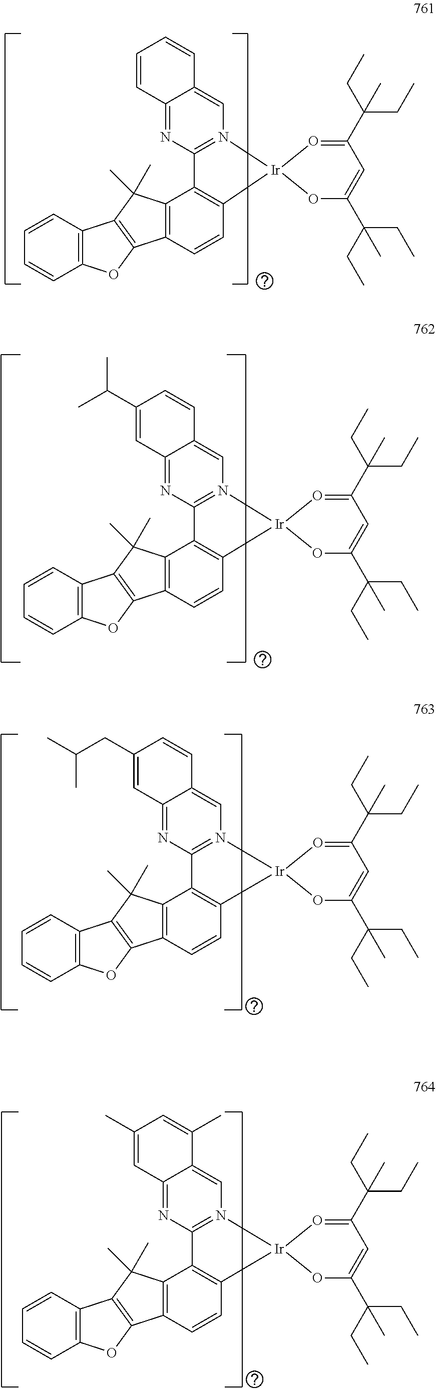

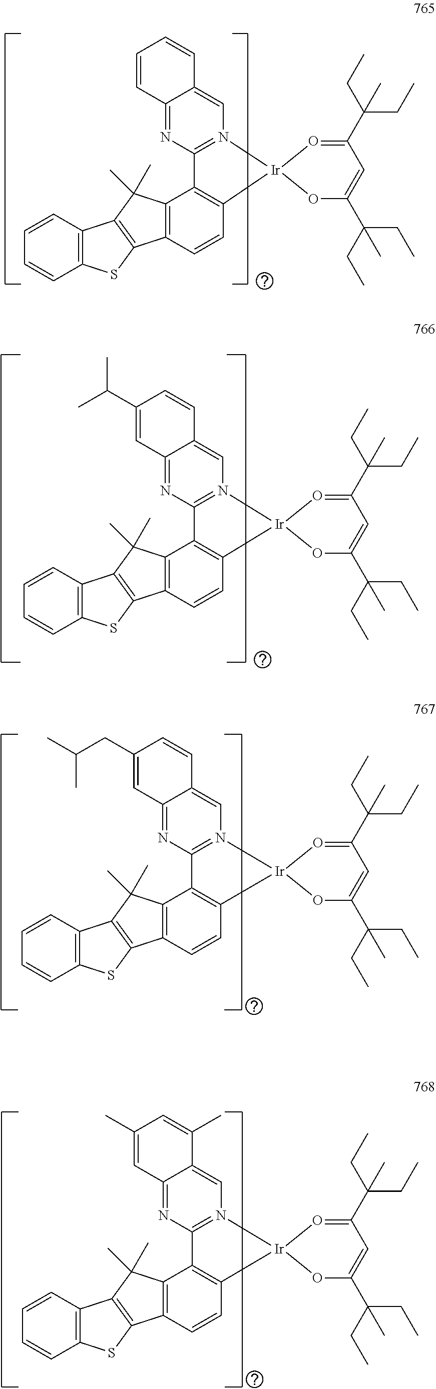

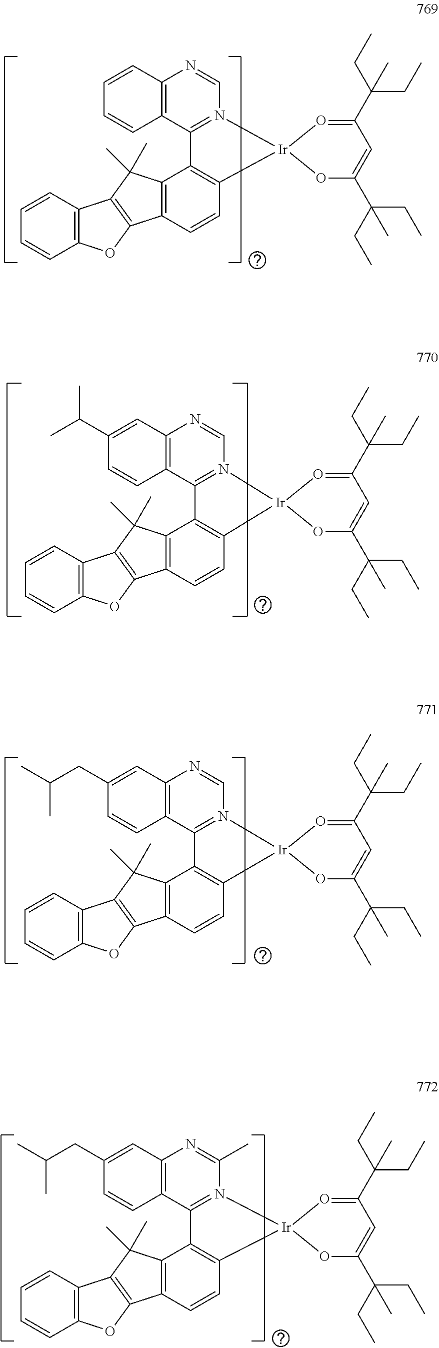

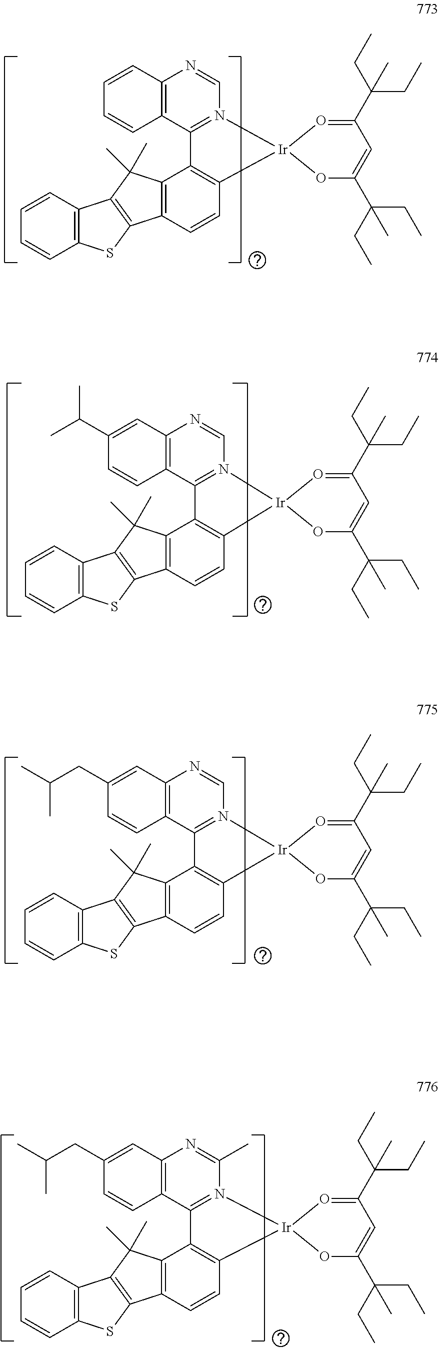

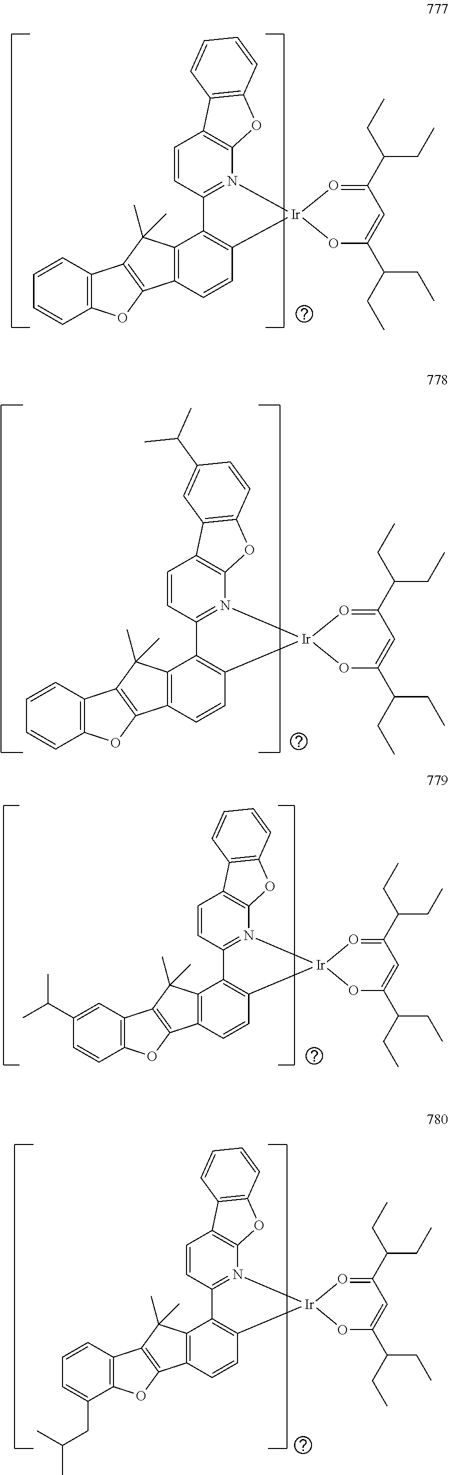

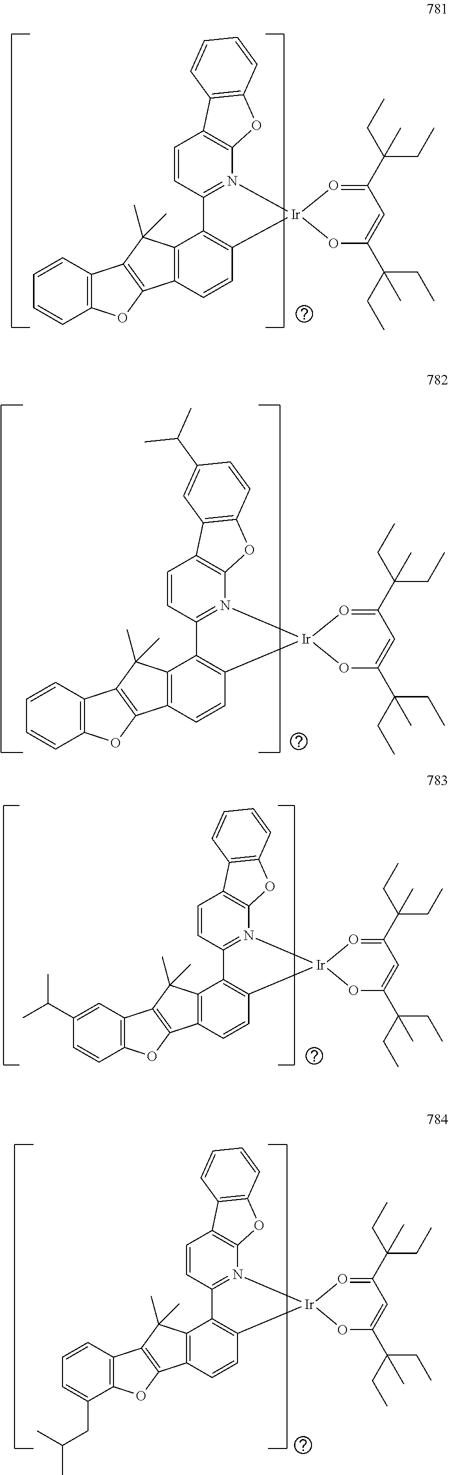

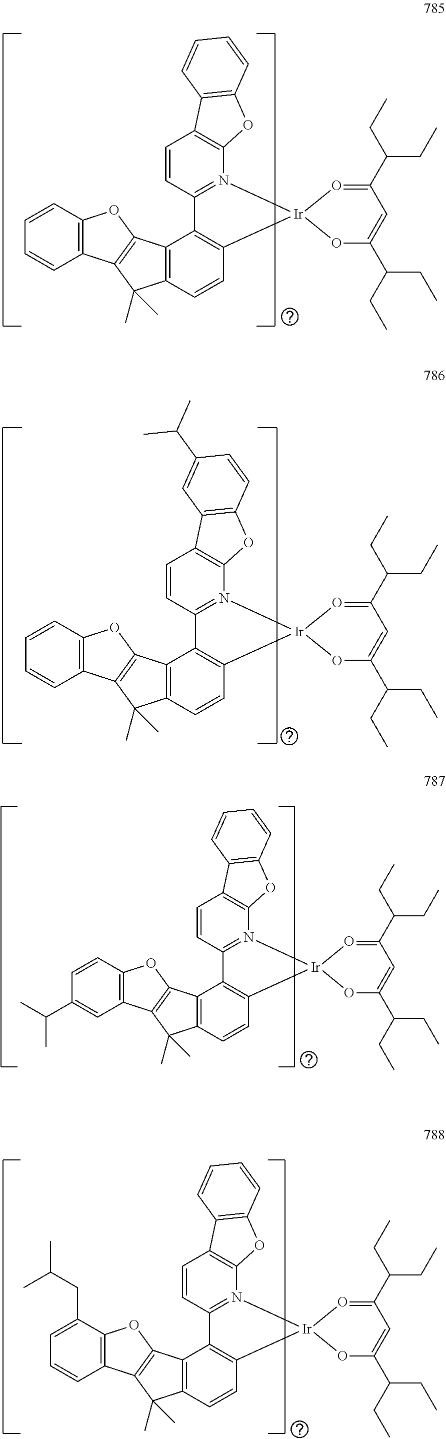

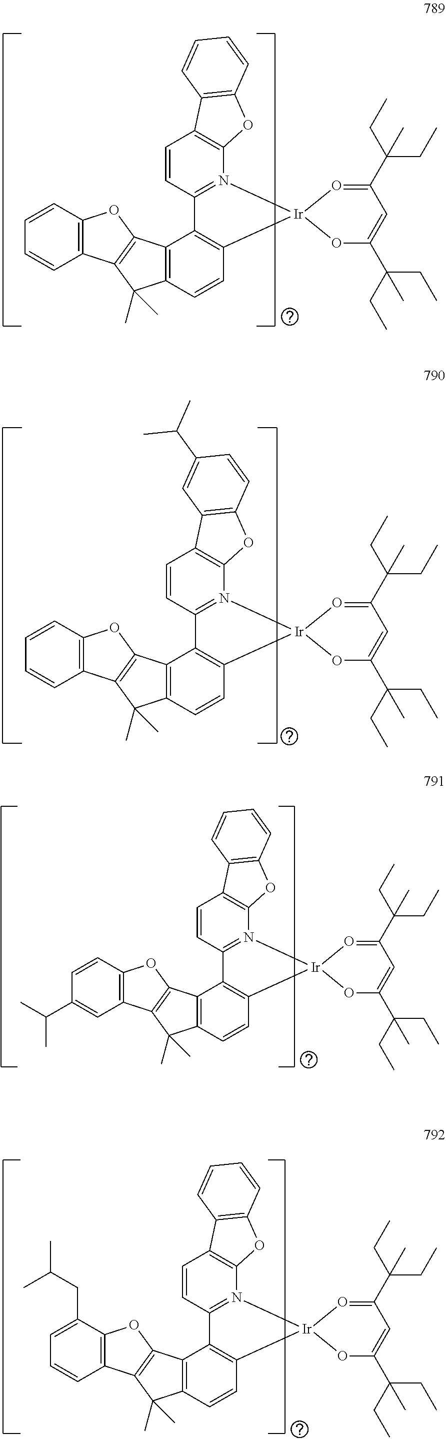

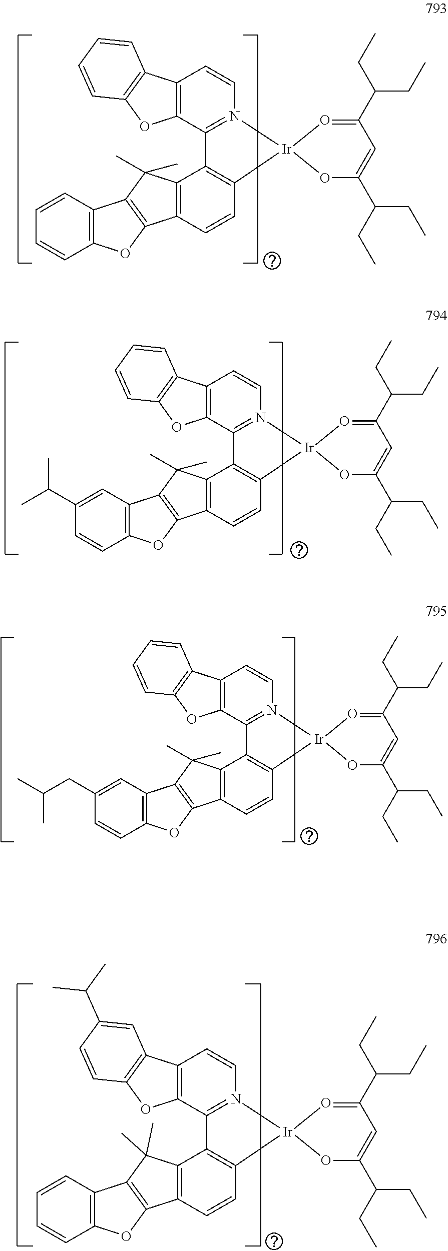

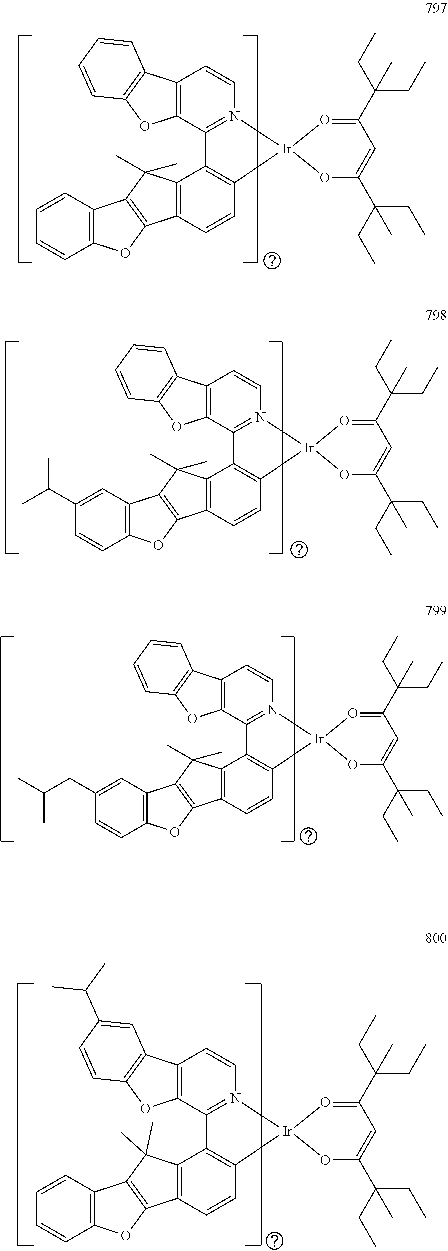

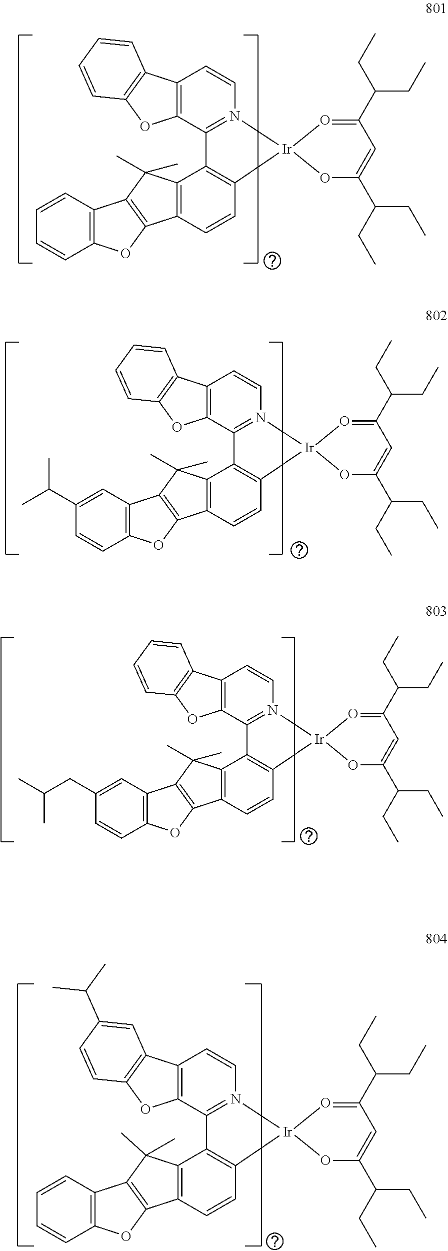

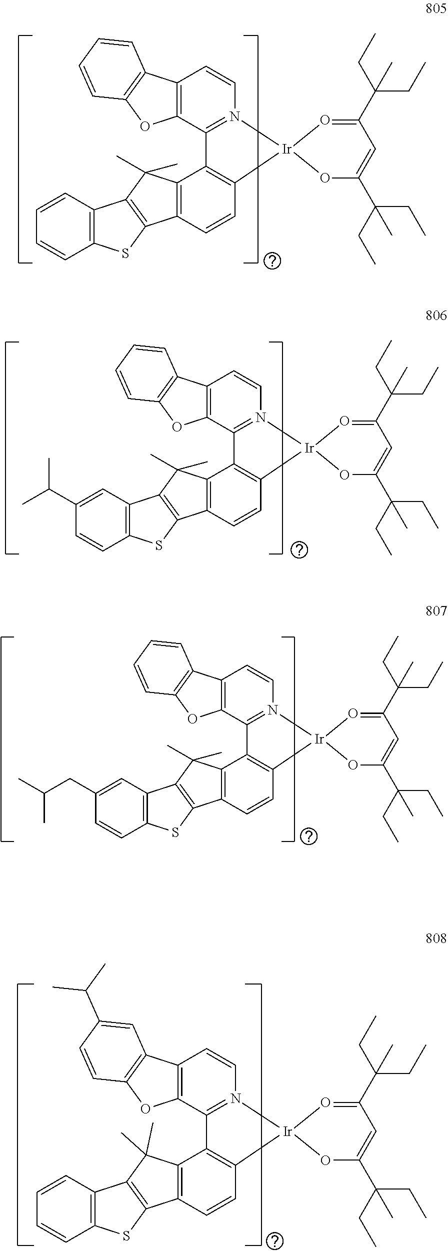

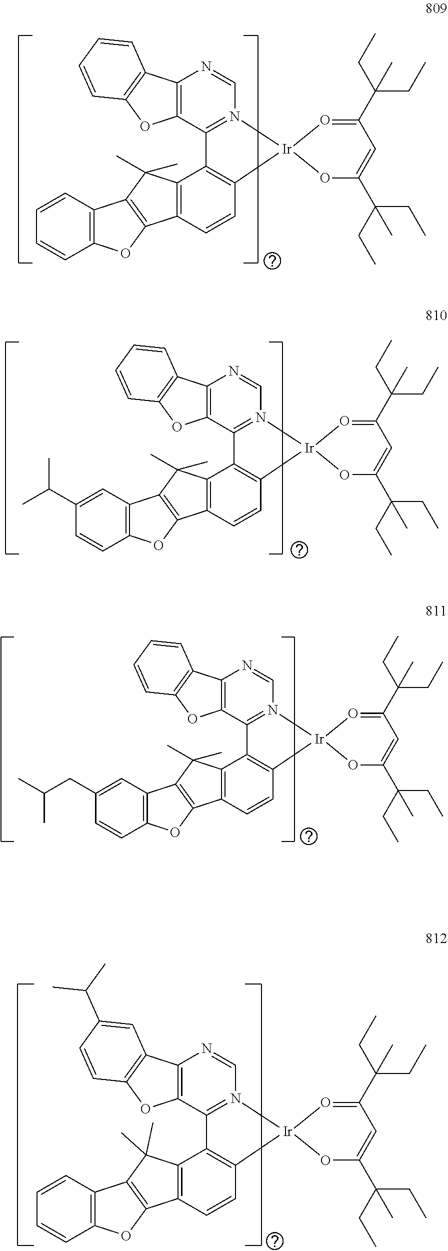

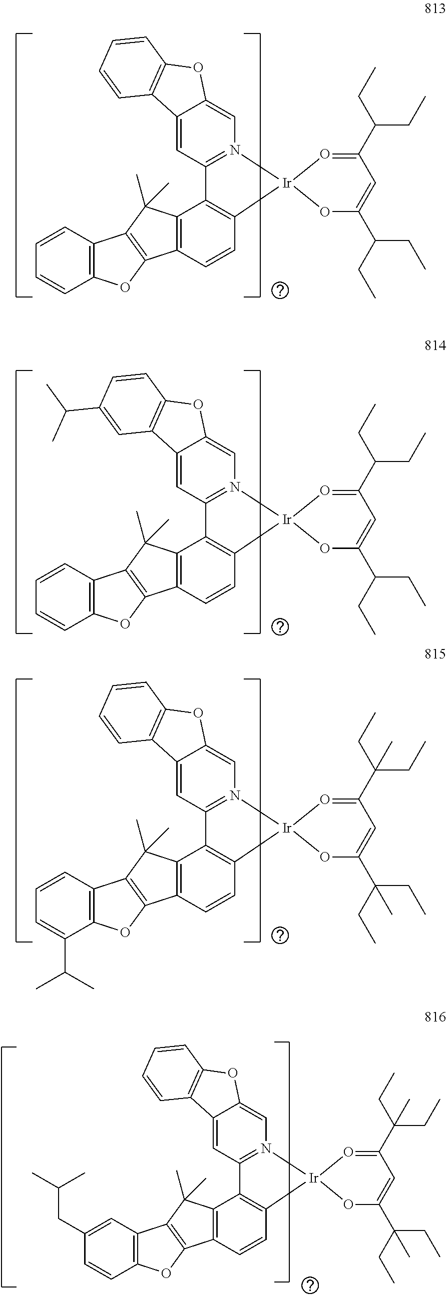

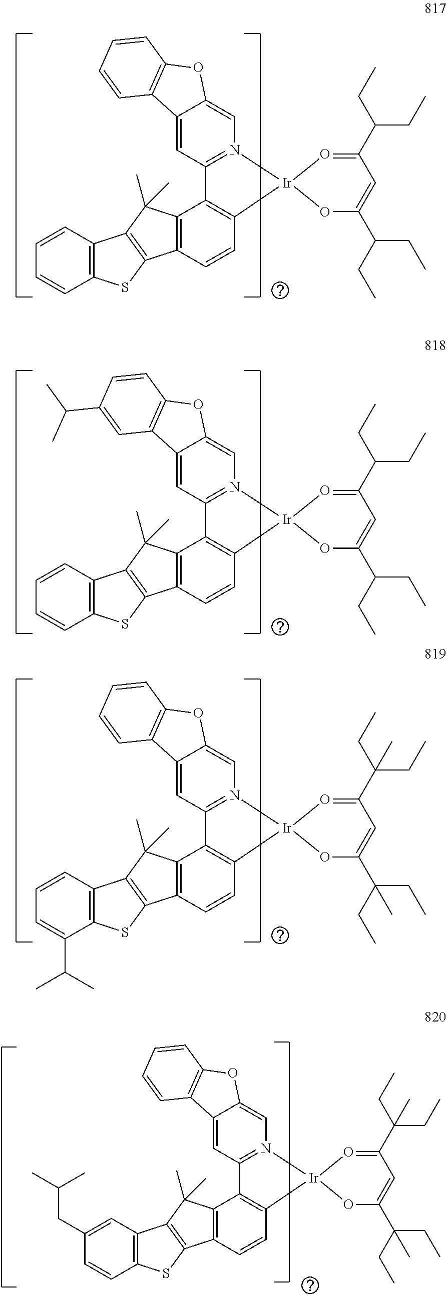

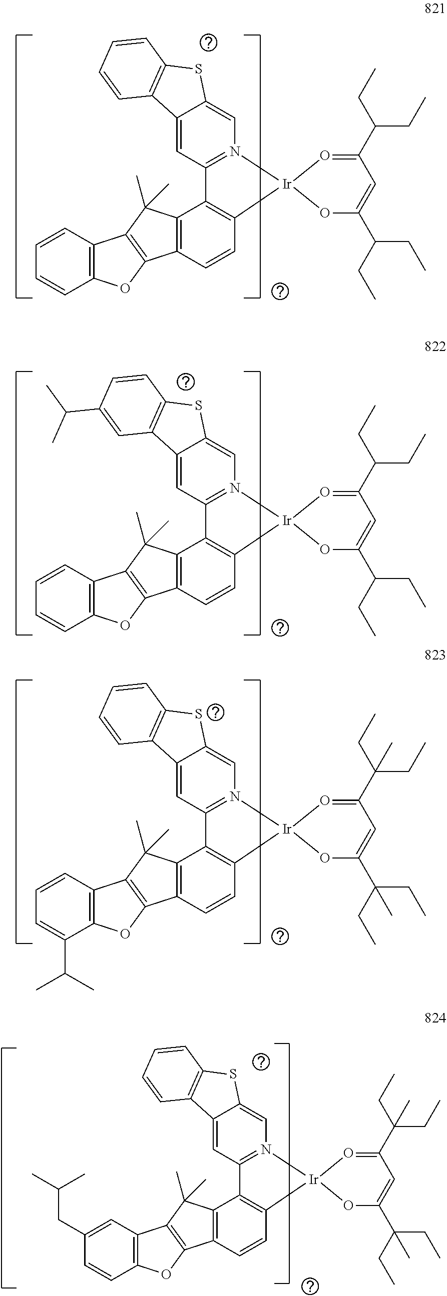

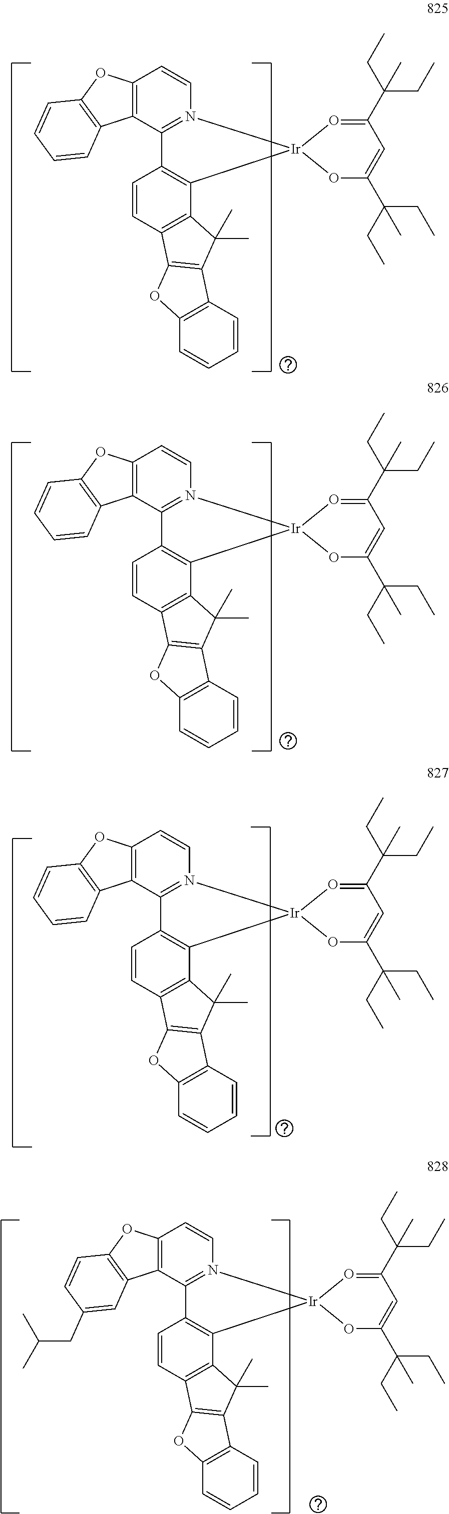

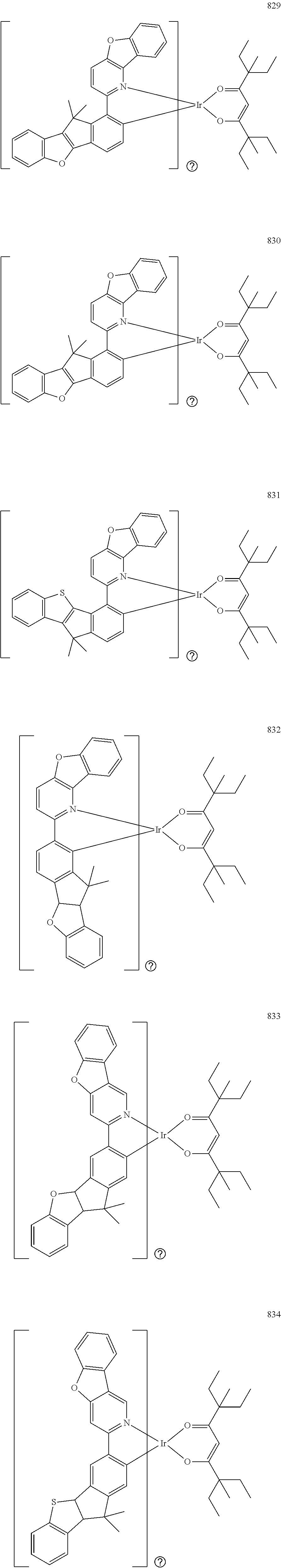

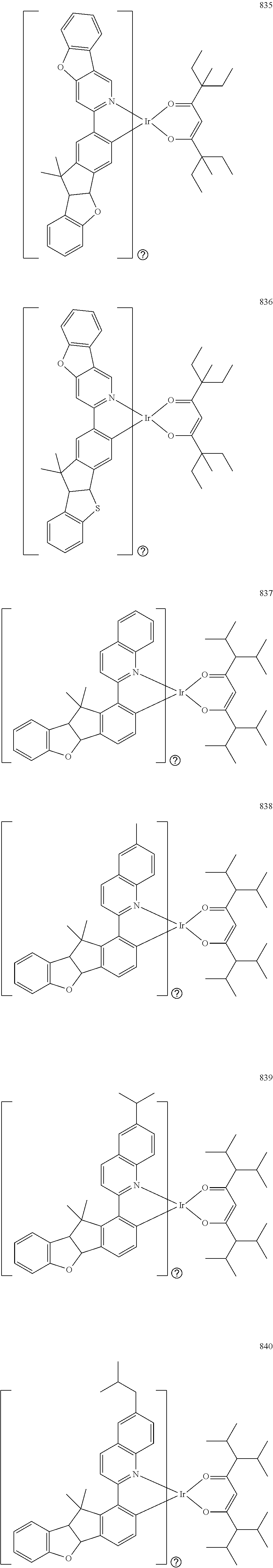

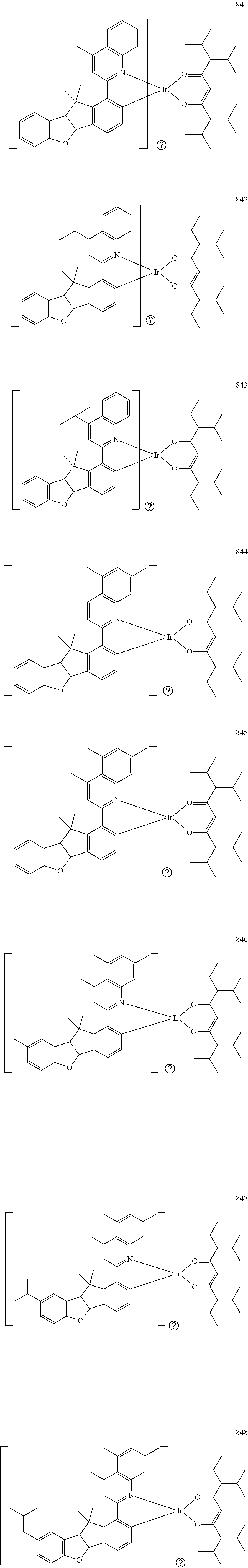

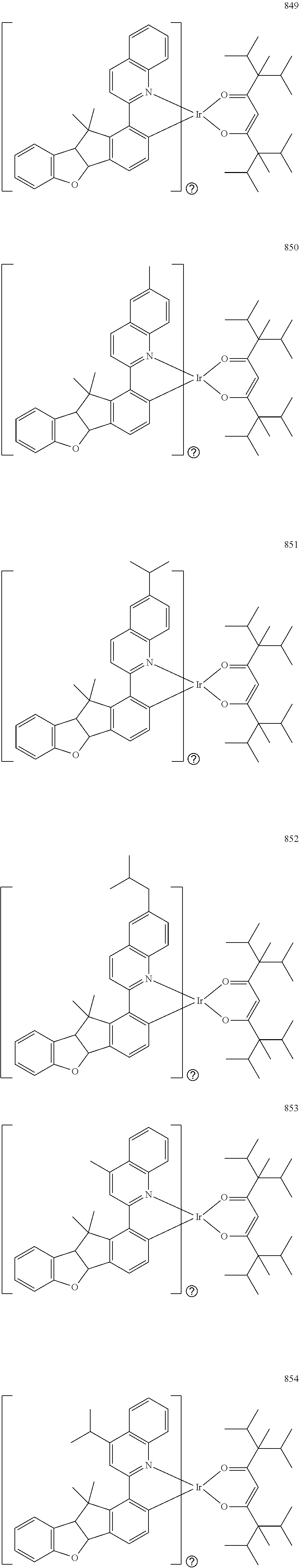

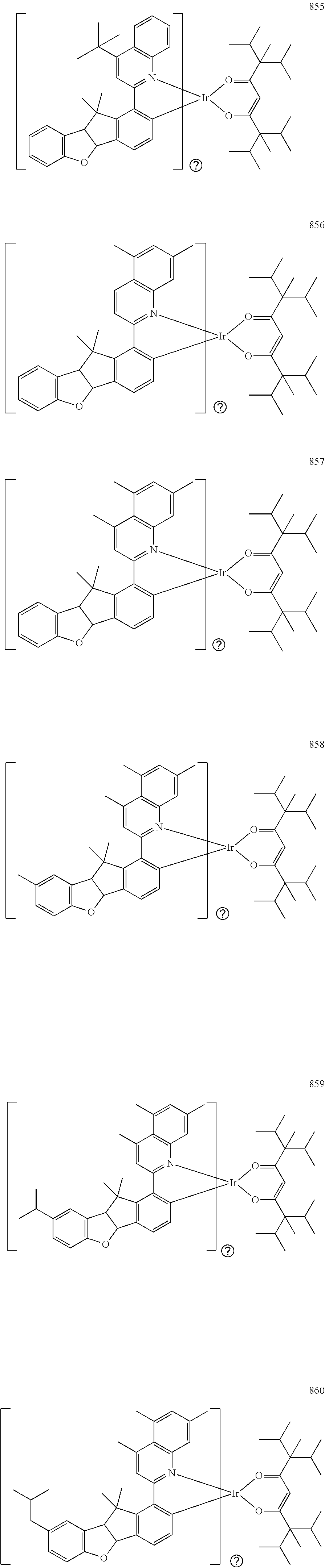

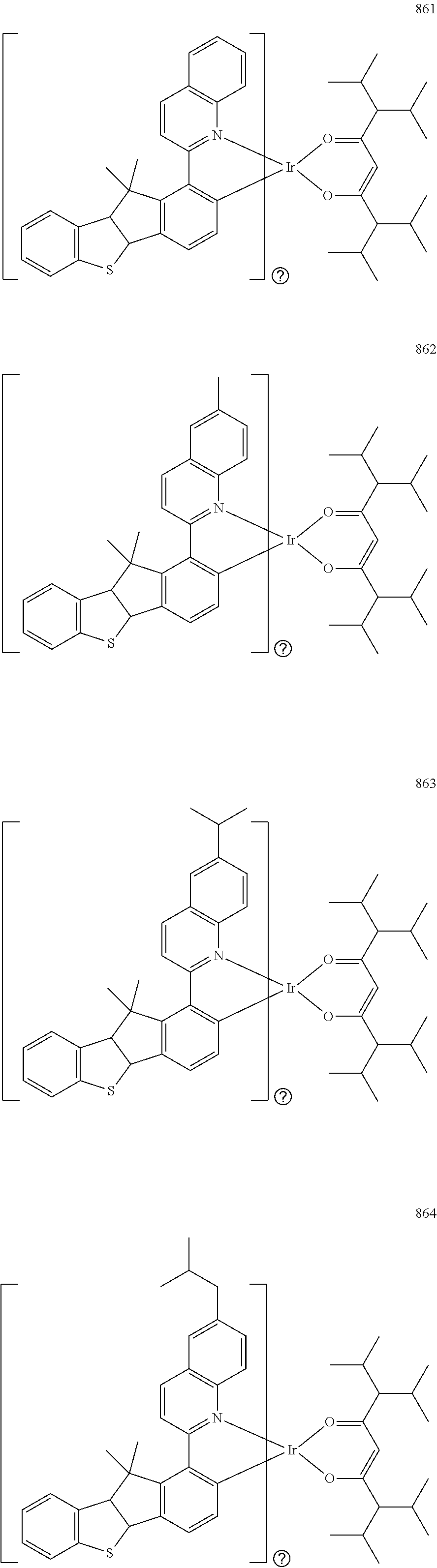

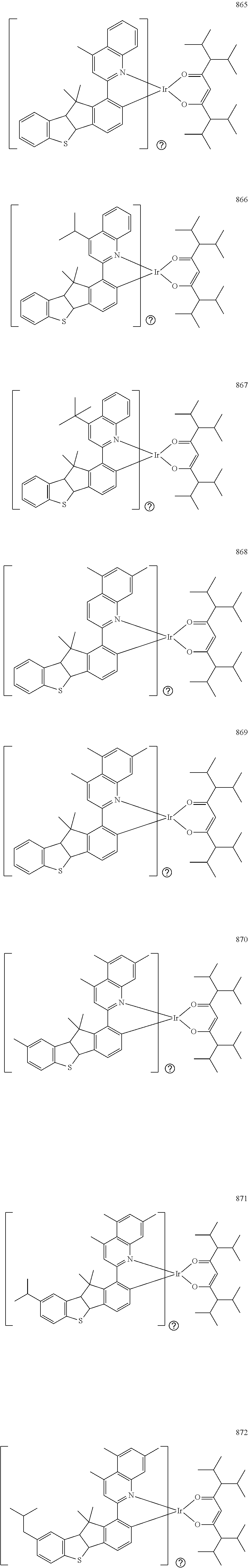

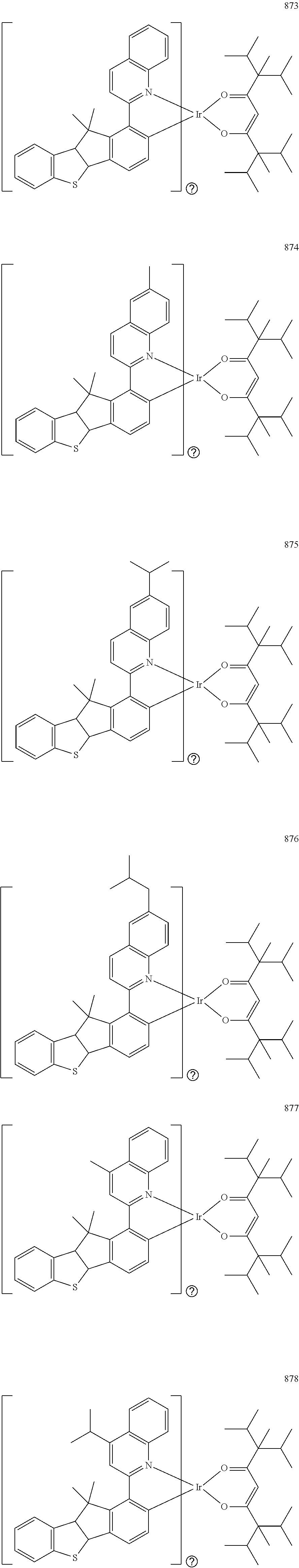

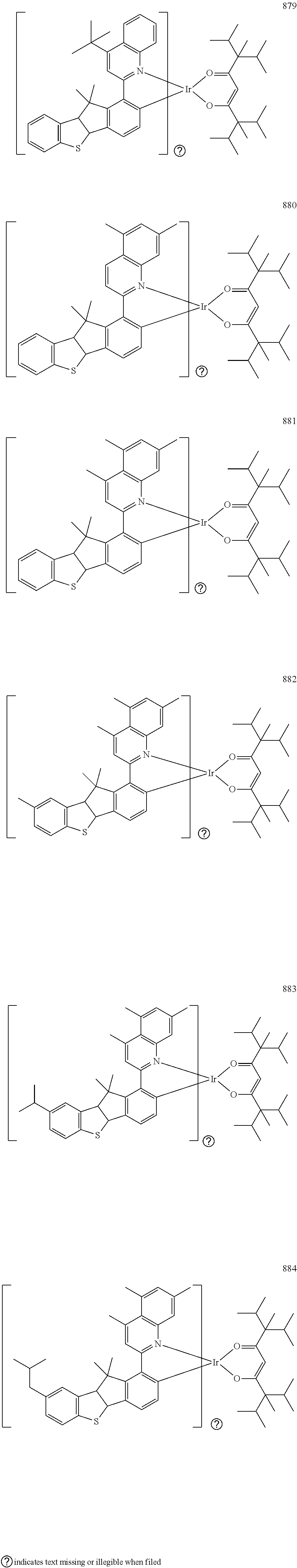

9. An organic light-emitting device comprising:
a first electrode;
a second electrode facing the first electrode; and
an organic layer disposed between the first electrode and the second electrode,
wherein the organic layer includes a light-emitting layer,
wherein the light emitting layer contains a dopant material, and
wherein the dopant material includes the organometallic compound according to claim 1.

10. The organic light-emitting device of claim 9, wherein the light emitting layer is a red light emitting layer.

11. The organic light-emitting device of claim 9, wherein the light emitting layer further contains a host material.

12. The organic light-emitting device of claim 9, wherein the organic layer further includes at least one selected from a group consisting of a hole injection layer, a hole transport layer, an electron transport layer and an electron injection layer.

13. An organic light-emitting device comprising:
a first electrode and a second electrode facing each other; and
a first light-emitting stack and a second light-emitting stack positioned between the first electrode and the second electrode,
wherein each of the first light-emitting stack and the second light-emitting stack includes at least one light emitting layer,
wherein at least one of the light-emitting layers is a red phosphorescent light-emitting layer,
wherein the red phosphorescent light emitting layer contains a dopant material, and
wherein the dopant material includes the organometallic compound according to claim 1.

14. An organic light-emitting device comprising:
a first electrode and a second electrode facing each other; and
a first light-emitting stack, a second light-emitting stack, and a third light-emitting stack positioned between the first electrode and the second electrode,
wherein each of the first light-emitting stack, the second light-emitting stack and the third light-emitting stack includes at least one light emitting layer,
wherein at least one of the light-emitting layers is a red phosphorescent light-emitting layer,
wherein the red phosphorescent light emitting layer contains a dopant material, and
wherein the dopant material includes the organometallic compound according to claim 1.

15. An organic light-emitting display device comprising:
a substrate;
a driving element positioned on the substrate; and
an organic light-emitting element disposed on the substrate and connected to the driving element,
wherein the organic light-emitting element includes the organic light-emitting device according to claim 9.
